(19) United States
(12) Patent Application Publication
(10) Pub. No.: US 2023/0382935 A1
(43) Pub. Date: Nov. 30, 2023

(54) COMPOUND CONTAINING 1,3-DIKETONE LIGAND AND APPLICATION THEREOF, AND ORGANIC ELECTROLUMINESCENT DEVICE

(71) Applicant: Beijing Green Guardee Technology CO.,LTD, Beijing (CN)

(72) Inventors: Yao LYU, Beijing (CN); Hongtao FAN, Beijing (CN); Meijuan FENG, Beijing (CN)

(21) Appl. No.: 18/250,186

(22) PCT Filed: Oct. 25, 2021
(86) PCT No.: PCT/CN2021/126122

§ 371 Date: Apr. 21, 2023

(30) Foreign Application Priority Data
Oct. 23, 2020 (CN) 202011150494.3
May 13, 2021 (CN) 202110522974.6
May 21, 2021 (CN) 202110556895.7
May 24, 2021 (CN) 202110567686.2
May 24, 2021 (CN) 202110567691.3
May 27, 2021 (CN) 202110585083.5
May 28, 2021 (CN) 202110592860.9

(51) Int. Cl. C07F 15/00; H10K 85/30; H10K 85/60; C09K 11/06

(52) U.S. Cl. CPC C07F 15/0033; H10K 85/342; H10K 85/654; C09K 2211/1092; C09K 11/06; C09K 2211/1037; C09K 2211/1033; H10K 85/6574

(57) ABSTRACT

The present invention relates to the field of organic electroluminescent devices. Disclosed are a compound containing a 1,3-diketone ligand and an application thereof, and an organic electroluminescent device. The compound has the structure as represented by formula Ir(LA)(LB)2; LA has the structure as represented by formula (IA); LB has the structure as represented by formula (IB), the structure as represented by LB310, the structure as represented by LB311, the structure as represented by LB312, the structure as represented by LB313, or the structure as represented by LB314. The compound containing a 1,3-diketone ligand provided by the present invention has the advantages of low synthesis difficulty and easy to purify, has excellent illumination performance as an organic electrophosphorescent material, and can prolong the service life of the device, increase the solubility of the phosphorescent material, and decrease the probability of triplet-triplet annihilation.

### CROSS REFERENCE TO RELATED APPLICATIONS

The present application is a National Stage filing of PCT Application No. PCT/CN2021/126122 filed on Oct. 25, 2021, which claims the benefit of Chinese patent applications 202011150494.3, 202110522974.6, 202110592860.9, 202110585083.5, 202110567691.3, 202110567686.2, 202110556895.7 filed on 23 Oct. 2020, 13/05/2021, 28/05/2021, 27/05/2021, 24/05/2021, 24/05/2021, 21/05/2021 respectively, the contents of which are incorporated herein by reference.

### TECHNICAL FIELD

The present invention relates to the field of organic electroluminescent devices, in particular to a compound containing 1,3-diketone ligand and an application thereof, and an organic electroluminescent device.

### BACKGROUND

Compared with the traditional liquid crystal technology, the organic electroluminescence technology does not need backlight source irradiation and a color filter, pixels can emit light and are displayed on a color display panel, and the organic electroluminescence technology has the characteristics of ultrahigh contrast, ultra-wide visual angle, curved surface, thinness and the like.

In 1987, DengQingyun et al of Eastman Kodak Company reported two organic semiconductor materials based on 8-hydroxyquinoline aluminum with high fluorescence efficiency and good electron transport property and aromatic diamine with good hole transport property, and promoted the research of organic electroluminescent materials.

In 1997, professor Forrest of Princeton University, USA, discovered the phenomenon of phosphorescence electroluminescence, and increased the internal quantum efficiency of organic electroluminescent devices from the limit of 25% of fluorescent materials to 100%, so that the research of organic electroluminescent materials entered a new period. The phosphorescence material is a phosphorescence material which is formed by doping small molecules with transition metal complexes, and enables triplet excitons to obtain high emission energy by utilizing a spin-orbit coupling effect caused by heavy metal atoms, so that the quantum efficiency of the organic electroluminescent device is improved. Metal complexes are phosphorescent materials with relatively short excited state lifetime, high luminescence quantum efficiency, excellent color tunable luminescence, and good stability.

The phosphorescent material applied to the organic electroluminescent device at present is easy to generate an aggregation quenching phenomenon under high concentration, and a phenomenon that the efficiency of the device is reduced due to triplet-triplet annihilation in a high-brightness device. In order to meet the increasing demand for device performance, it is of great importance to develop phosphorescent materials having a weak aggregation quenching effect.

### DISCLOSURE OF INVENTION

The present invention aims to solve the problems of large efficiency roll-off and low light-emitting efficiency of the existing organic electroluminescent device.

In order to achieve the above object, the first aspect of the present invention provides a compound containing 1,3-diketone ligand, the compound having a structure represented by Ir (L_{A})(L_{B})₂, wherein L_{A} has a structure represented by formula (IA1), formula (IA2), formula (IA3), formula (IA4), formula (IA5), or formula (IA6), and L_{B} is a structure represented by formula (IB), formula L_{B310}, formula L_{B311}, formula L_{B312}, formula L_{B313}, or formula L_{B314};

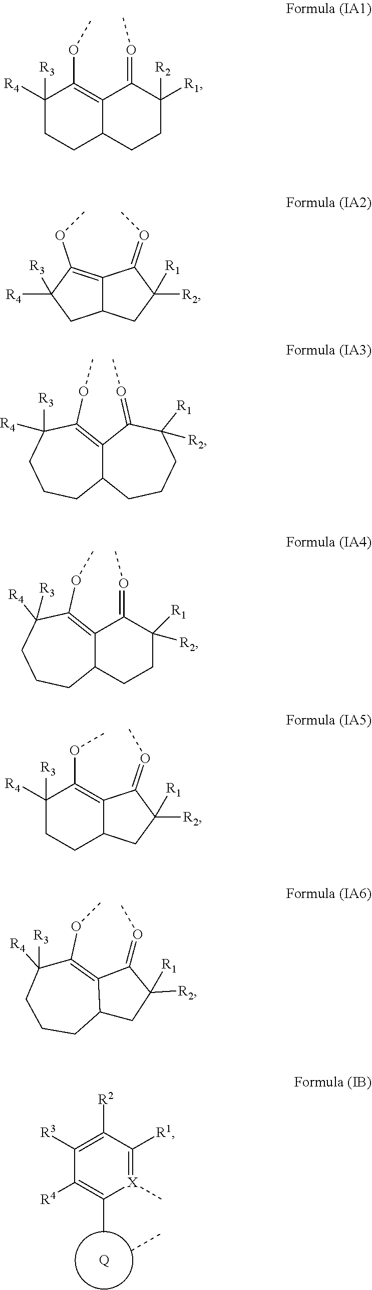

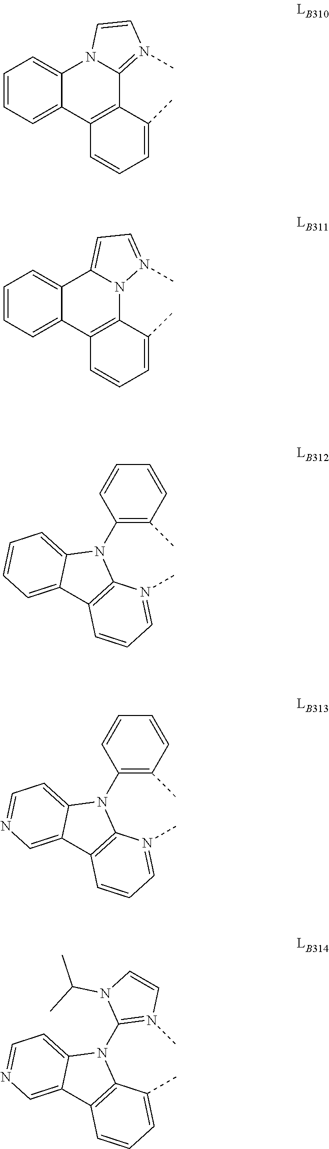

in formula (IA1), formula (IA2), formula (IA3), formula (IA4), formula (IA5) and formula (IA6), R₁, R₂, R₃, and R₄ are independently selected from H, C₁-C₂₀ alkyl, C₆-C₂₀ aryl; or at least one combination of each of R₁ and R₂ and each of R₃ and R₄ cyclized to form a 4-7 membered saturated ring;
in formula (IB), X is C or N,
the ring Q is selected from a substituted or unsubstituted benzene ring, a substituted or unsubstituted quinoline ring, a substituted or unsubstituted isoquinoline ring, a substituted or unsubstituted naphthalene ring, a substituted or unsubstituted phenanthrene ring, a substituted or unsubstituted benzothiophene ring, a substituted or unsubstituted benzofuran ring, a substituted or unsubstituted indole ring, a substituted or unsubstituted benzothiazole ring, a substituted or unsubstituted benzoxazole ring, a substituted or unsubstituted benzimidazole ring, a substituted or unsubstituted dibenzothiophene ring, a substituted or unsubstituted dibenzofuran ring, a substituted or unsubstituted benzofuropyridine ring, a substituted or unsubstituted benzothienopyridine ring, a substituted or unsubstituted benzindolopyridine ring, a substituted or unsubstituted pyridoindolopyridine ring, a substituted or unsubstituted imidazole ring, a substituted or unsubstituted pyrrolidine ring;
R¹, R², R³ and R⁴ are independently selected from H, C₁-C₂₀ alkyl, C₆-C₂₀ aryl; or any two adjacent of R¹, R², R³, and R⁴ are cyclized together to form at least one ring structure selected from a substituted or unsubstituted benzene ring, a substituted or unsubstituted naphthalene ring, a substituted or unsubstituted benzofuran ring, a substituted or unsubstituted pyridofuran ring, a substituted or unsubstituted benzothiophene ring, and a substituted or unsubstituted pyridothiophene ring;
the optional substituents on the Q ring and the optional substituents on R¹, R², R³ and R⁴ are independently selected from at least one of C₁-C₁₀ alkyl and phenyl.

The second aspect of the present invention provides the use of a compound containing 1,3-diketone ligand as described in the first aspect above as an organic electrophosphorescent material.

The third aspect of the present invention provides an organic electroluminescent device comprising at least one of the compounds containing 1,3-diketone ligand described in the first aspect above.

The present invention has the following specific advantages:
(1) The compound containing 1,3-diketone ligand has the advantages of low synthesis difficulty and easy to purify, and can improve the phosphorescence quantum efficiency of a phosphorescence material when being used as an organic electrophosphorescent material, so that the compound has excellent luminescence performance
(2) When the compound containing 1,3-diketone ligand provided by the present invention is used as an organic electrophosphorescent material, the specific concentration quenching phenomenon of the phosphorescent material can be reduced, the thermal stability of the phosphorescent material can be improved, and the service life of a device can be prolonged.
(3) When the compound containing 1,3-diketone ligand provided by the present invention is used as an organic electrophosphorescent material, the probability of triplet-triplet annihilation can be reduced, and the light-emitting efficiency of a device is further improved.

### DETAILED DESCRIPTION

The endpoints of the ranges and any values disclosed herein are not limited to the precise range or value, and these ranges or values should be understood to encompass values close to these ranges or values. For numerical ranges, each range between its endpoints and individual point values, and each individual point value can be combined with each other to give one or more new numerical ranges, and such numerical ranges should be construed as specifically disclosed herein.

In the present invention, without making a contrary explanation, the terms of the present invention are explained as follows:

C₁-C₂₀ alkyl represents an alkyl group having 1-20 total carbon atoms, including straight chain alkyl groups, branched chain alkyl groups and cycloalkyl groups, for example, straight chain alkyl groups, branched chain alkyl groups and cycloalkyl groups having 1, 2, 3, 4, 5, 6, 7, 8, 9, 10, 11, 12, 13, 14, 15, 16, 17, 18, 19 and 20 total carbon atoms, for example, methyl, ethyl, n-propyl, isopropyl, cyclopropyl, cyclobutyl, n-butyl, CH₃CH(CH₃)—CH₂—, CH₃CH₂CH(CH₃)—, t-butyl, n-pentyl, CH₃CH(CH₃)—CH₂CH₂—, cyclopentyl, n-hexyl, cyclohexyl, n-heptyl and the like. The explanations for “C₁-C₁₅ alkyl”, “C₁-C₁₀ alkyl”, “C₁-C₈ alkyl”, “C₁-C₇ alkyl”, “C₁-C₆ alkyl” and the like are similar, except that the total number of carbon atoms is different.

C₆-C₂₀ aryl represents an aryl group having a total number of carbon atoms of 6-20, and the aryl group is directly connected to a C atom of the parent nucleus structure provided by the present invention, including but not limited to phenyl, biphenyl, naphthyl, anthryl, phenanthryl, pyrenyl and the like. The explanations for “C₆-C₁₅ aryl”, “C₆-C₁₂ aryl”, “C₆-C₁₀ aryl” and the like are similar, except that the total number of carbon atoms is different.

At least one combination of each of R₁ and R₂ and each of R₃ and R₄ cyclized to form a 4-7 membered saturated ring, meaning that at least one of the combinations of R₁ and R₂ and the combinations of R₃ and R₄ forms a saturated ring containing 4, 5, 6, or 7 atoms, for example,

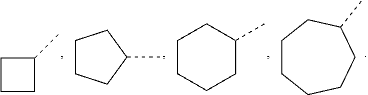

The substituted or unsubstituted benzene ring means that the benzene ring is directly connected to a C atom of the parent nucleus structure provided by the present invention, and any substitutable position on the benzene ring which can be substituted. For example,

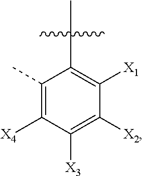

wherein, X₁, X₂, X₃, and X₄ can be replaced, and the wavy line indicates the connection position, that is, the group is connected to the parent nuclear structure through chemical bonds at the location of the wavy line, - - - is a dotted line on the Q ring of formula (IB). Hereinafter, quinoline rings, naphthalene rings, etc. have similar definitions, and the present invention will not be described in detail.

The substituted or unsubstituted quinoline ring means that the quinoline ring is directly connected to a C atom of the parent nucleus structure provided by the present invention, and any substitutable position on the quinoline ring which can be substituted.

The substituted or unsubstituted isoquinoline ring means that the isoquinoline ring is directly connected to a C atom of the parent nucleus structure provided by the present invention, and any substitutable position on the isoquinoline ring which can be substituted.

The substituted or unsubstituted naphthalene ring means that the naphthalene ring is directly connected to a C atom of the parent nucleus structure provided by the present invention, and any substitutable position on the naphthalene ring which can be substituted.

The substituted or unsubstituted phenanthrene ring means that the phenanthrene ring is directly connected to a C atom of the parent nucleus structure provided by the present invention, and any substitutable position on the phenanthrene ring which can be substituted.

The substituted or unsubstituted benzothiophene ring means that the benzothiophene ring is directly connected to a C atom of the parent nucleus structure provided by the present invention, and any substitutable position on the benzothiophene ring which can be substituted.

The substituted or unsubstituted benzofuran ring means that the benzofuran ring is directly connected to a C atom of the parent nucleus structure provided by the present invention, and any substitutable position on the benzofuran ring which can be substituted.

The substituted or unsubstituted indole ring means that the indole ring is directly connected to a C atom of the parent nucleus structure provided by the present invention, and any substitutable position on the indole ring which can be substituted.

The substituted or unsubstituted benzothiazole ring means that the benzothiazole ring is directly connected to a C atom of the parent nucleus structure provided by the present invention, and any substitutable position on the benzothiazole ring which can be substituted.

The substituted or unsubstituted benzoxazole ring means that the benzoxazole ring is directly connected to a C atom of the parent nucleus structure provided by the present invention, and any substitutable position on the benzoxazole ring which can be substituted.

The substituted or unsubstituted benzimidazole ring means that the benzimidazole ring is directly connected to a C atom of the parent nucleus structure provided by the present invention, and any substitutable position on the benzimidazole ring which can be substituted.

The substituted or unsubstituted dibenzothiophene ring means that the dibenzothiophene ring is directly connected to a C atom of the parent nucleus structure provided by the present invention, and any substitutable position on the dibenzothiophene ring which can be substituted.

The substituted or unsubstituted dibenzofuran ring means that the dibenzofuran ring is directly connected to a C atom of the parent nucleus structure provided by the present invention, and any substitutable position on the dibenzofuran ring which can be substituted.

The substituted or unsubstituted benzofuropyridine ring, which means that the benzofuropyridine ring is directly connected to a C atom of the parent nucleus structure provided by the present invention, and any substitutable position on the benzofuropyridine ring which can be substituted.

The substituted or unsubstituted benzothienopyridine ring, means that the benzothienopyridine ring is directly connected to a C atom of the parent nucleus structure provided by the present invention, and any substitutable position on the benzothienopyridine ring which can be substituted.

The substituted or unsubstituted benzindolopyridine ring means that the benzindolopyridine ring is directly connected to a C atom of the parent nucleus structure provided by the present invention, and any substitutable position on the benzindolopyridine ring which can be substituted.

The substituted or unsubstituted pyridoindolopyridine ring, means that the pyridoindolopyridine is directly connected to a C atom of the parent nucleus structure provided by the present invention, and any substitutable position on the pyridoindolopyridine which can be substituted.

The substituted or unsubstituted imidazole ring means that the imidazole ring is directly connected to a C atom of the parent nucleus structure provided by the present invention, and any substitutable position on the imidazole ring which can be substituted.

The substituted or unsubstituted pyrrolidine ring means that the pyrrolidine ring is directly connected to a C atom of the parent nucleus structure provided by the present invention, and any substitutable position on the pyrrolidine ring which can be substituted.

The substituted or unsubstituted pyridofuran ring, means that the pyridofuran ring is directly connected to a C atom of the parent nucleus structure provided by the present invention, and any substitutable position on the pyridofuran ring which can be substituted.

The substituted or unsubstituted pyridothiophene ring means that the pyridothiophene ring is directly connected to a C atom of the parent nucleus structure provided by the present invention, and any substitutable position on the pyridothiophene ring which can be substituted.

C₃ straight chain alkyl is CH₃CH₂CH₂—, C₃ branched chain alkyl is CH₃CH(CH₃)—, and C₃ cycloalkyl is

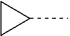

C₄ straight chain alkyl is CH₃CH₂CH₂CH₂—, C₄ branched chain alkyl can be CH₃CH(CH₃)—CH₂—, CH₃CH₂—CH(CH₃)— or (CH₃)₃C—, and C₄ cycloalkyl is

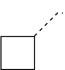

C₅ straight chain alkyl is CH₃CH₂CH₂CH₂CH₂—, C₅ branched chain alkyl can be CH₃CH₂CH(CH₃)—CH₂—, (CH₃)₂CH—CH₂CH₂—, (CH₃)₃C—CH₂—, CH₃CH(CH₃)CH(CH₃)—, (CH₃)₃C—CH₂—, and C₅ cycloalkyl is

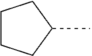

C₆ straight chain alkyl is CH₃CH₂CH₂CH₂CH₂CH₂—, C₆ branched chain alkyl can be CH₃CH₂CH₂CH(CH₃)CH₂—, (CH₃)₂C(CH₂CH₂CH₃)—, (CH₃)₂CHCH(CH₂CH₃)—, (CH₃)₂CHCH₂CH(CH₃)—, (CH₃)₂CHCH₂CH₂CH₂—, CH₃CH₂CH(CH₃)CH₂CH₂—, CH₃CH₂CH(CH₃)CH(CH₃)—, (CH₃CH₂)₂C(CH₃)—, CH₃CH(CH₃)CH(CH₃)CH₂—, (CH₃CH₂)₂CHCH₂—, (CH₃)₂CHC(CH₃)₂—, and C₆ cycloalkyl is

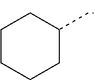

C₇ straight chain alkyl is CH₃CH₂CH₂CH₂CH₂CH₂CH₂—, C₇ branched chain alkyl can be CH₃CH₂CH₂CH₂CH(CH₃)CH₂—, (CH₃)₂CHCH₂CH₂CH₂CH₂—, (CH₃)₂C(CH₂CH₂CH₂CH₃)—, (CH₃)₂CHCH(CH₂CH₂CH₃)—, (CH₃)₂CHCH₂CH(CH₂CH₃)—, (CH₃)₂CHCH₂CH₂CH(CH₃)—, CH₃CH₂CH₂CH(CH₃)CH₂CH₂—, CH₃CH₂CH(CH₃)CH₂CH₂CH₂—, CH₃CH₂CH₂CH(CH₃)CH(CH₃)—, CH₃CH₂CH₂C(CH₃)(CH₂CH₃)—, CH₃CH₂CH(CH₃)CH(CH₂CH₃)—, CH₃CH₂CH(CH₃)CH₂CH(CH₃)—, CH₃CH₂CH₂CHCH₂(CH₂CH₃)—, CH₃CH₂CH₂C(CH₃)₂CH₂—, (CH₃)₃CCH₂CH₂CH₂—, (CH₃)₃CCH(CH₂CH₃)—, (CH₃)₃CCH₂CH(CH₃)—, CH₃CH₂CH(CH₃)CH(CH₃)CH₂—, (CH₃)₂CHCH(CH₃)CH₂CH₂—, CH₃CH₂CH(CH₃)C(CH₃)₂—, (CH₃)₂CHC(CH₃)(CH₂CH₃)—, (CH₃)₂CHCH(CH₃)CH(CH₃)—, (CH₃)₂CHCH(CH₂CH₃)CH₂—, (CH₃)₂CHCH₂CH(CH₃)CH₂—, (CH₃)₂CHCH₂C(CH₃)₂—, (CH₃)₂CHCH(CH(CH₃)₂)—, CH₃CH₂C(CH₃)₂CH₂CH₂—, CH₃CH₂C(CH₃)₂CH(CH₃)—, (CH₃CH₂)₂C(CH₃)CH₂—, (CH₃)₃C—CH(CH₃)CH₂—, (CH₃)₂CHC(CH₃)₂CH₂—, and C₇ cycloalkyl is

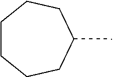

C₈ straight chain alkyl is CH₃CH₂CH₂CH₂CH₂CH₂CH₂CH₂—, C₈ branched chain alkyl can be CH₃CH₂CH₂CH₂CH₂CH(CH₃)CH₂—, (CH₃)₂CHCH₂CH₂CH₂CH₂CH₂—, CH₃CH₂CH₂CH₂CH₂C(CH₃)₂—, CH₃CH₂CH₂CH₂CH(CH(CH₃)₂)—, (CH₃)₂CHCH₂CH(CH₂CH₂CH₃)—, (CH₃)₂CHCH₂CHCH₂(CH₂CH₃)—, (CH₃)₂CHCH₂CH₂CH₂CH(CH₃)—, CH₃CH₂CH₂CH₂CH(CH₃)CH₂CH₂—, CH₃CH₂CH(CH₃)CH₂CH₂CH₂CH₂—, CH₃CH₂CH₂CH₂CH(CH₃)CH(CH₃)—, CH₃CH₂CH₂CH₂C(CH₃)(CH₂CH₃)—, CH₃CH₂CH(CH₃)CH(CH₂CH₂CH₂CH₃)—, CH₃CH₂CH(CH₃)CH₂CH(CH₂CH₃)—, CH₃CH₂CH(CH₃)CH₂CH₂CH(CH₃)—, CH₃CH₂CH₂CH₂CH(CH₂CH₃)CH₂—, CH₃CH₂CH₂CH(CH₃)CH₂CH₂CH₂—, CH₃CH₂CH₂CH(CH₃)CH₂CH(CH₃)—, CH₃CH₂CH₂CH(CH₃)CH(CH₂CH₃)—, (CH₃CH₂CH₂)₂C(CH₃)—, CH₃CH₂CH₂CH(CH₂CH₂CH₃)CH₂—, CH₃CH₂CH₂CH(CH₃)CH(CH₃)CH₂—, (CH₃)₂C(CH₃)(CH₂CH₂CH₃)—, CH₃CH₂CH₂CH(CH₃)C(CH₃)₂—, (CH₃)₂CHCH(CH₃)CH(CH₂CH₃)—, (CH₃)₂CHCH(CH₃)CH₂CH(CH₃)—, (CH₃)₂CH(CH₂CH₂CH₃)CH₂—, CH₃CH₂CH(CH₃)CH₂CH(CH₃)CH₂—, (CH₃)₂CHCH₂CH(CH₃)CH₂CH₂—, CH₃CH₂CH(CH₃)CH₂C(CH₃)₂—, CH₃CH₂CH(CH₃)CH(CH(CH₃)₂)—, (CH₃)₂CHCH₂C(CH₃)(CH₂CH₃)—, (CH₃)₂CHCH₂CH(CH₃)CH(CH₃)—, (CH₃)₂CHCH₂(CH₂CH₃)CH₂—, (CH₃)₂CHCH₂CH₂CH(CH₃)CH₂—, (CH₃)₂CHCH₂CH₂C(CH₃)₂—, (CH₃)₂CHCH₂CH(CH(CH₃)₂)—, (CH₃)₃CCH₂CH₂CH₂CH₂—, (CH₃)₃CCH₂CH₂CH(CH₃)—, (CH₃)₃CCH₂CH(CH₂CH₃)—, (CH₃)₃CCH(CH₂CH₂CH₃)—, CH₃CH₂CH₂CH₂C(CH₃)₂CH₂—, CH₃CH₂CH₂C(CH₃)₂CH₂CH₂—, —CH₃CH₂C(CH₃)₂CH₂CH₂CH₂—, CH₃CH₂CH₂C(CH₃)₂CH(CH₃)—, CH₃CH₂CH₂C(CH₃)(CH₂CH₃)CH₂—, CH₃CH₂C(CH₃)₂CH(CH₂CH₃)—, CH₃CH₂C(CH₃)₂CH₂CH(CH₃)—, CH₃CH₂CH(CH₃)C(CH₃)₂CH₂—, (CH₃)₃CC(CH₃)(CH₂CH₃)—, (CH₃)₃CC(CH₂CH₃)CH₂—, (CH₃)₃CC(CH₃)CH(CH₃)—, (CH₃)₃CCH(CH₃)CH₂CH₂—, (CH₃)₂CHCH(CH₃)CH(CH₃)CH₂—, (CH₃)₂CHCH(CH₃)C(CH₃)₂—, (CH₃)₂CHC(CH₃)(CH(CH₃)₂)—, ((CH₃)₂CH)₂CHCH₂—, CH₃CH₂C(CH₃)₂C(CH₃)CH₂—, CH₃CH₂C(CH₃)₂C(CH₃)₂—, (CH₃)₂CHC(CH₃)(CH₂CH₃)CH₂—, (CH₃)₂CHC(CH₃)₂CH(CH₃)—, (CH₃)₂CHC(CH₃)₂CH₂CH₂—, (CH₃)₃CC(CH₃)₂CH₂—, and C₈ cycloalkyl is

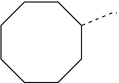

“or any two adjacent of R¹, R², R³, and R⁴ are cyclized together to form at least one ring structure selected from a substituted or unsubstituted benzene ring, a substituted or unsubstituted naphthalene ring, a substituted or unsubstituted benzofuran ring, a substituted or unsubstituted pyridofuran ring, a substituted or unsubstituted benzothiophene ring, and a substituted or unsubstituted pyridothiophene ring” means that any adjacent two of R¹, R², R³, and R⁴ are cyclized together to form at least one ring structure of a substituted or unsubstituted benzene ring, a substituted or unsubstituted naphthalene ring, a substituted or unsubstituted benzofuran ring, a substituted or unsubstituted pyridofuran ring, a substituted or unsubstituted benzothiophene ring and a substituted or unsubstituted pyridothiophene ring, and a condensed ring is formed with the parent nucleus structure through a chemical bond common to any adjacent two of R¹, R², R³, R⁴. For example

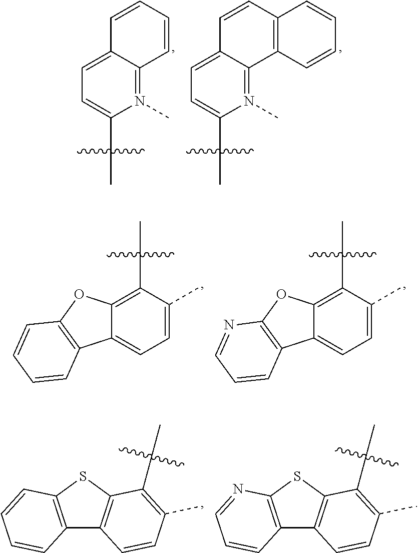

As described above, the first aspect of the present invention provides a compound containing 1,3-diketone ligand, the compound having a structure represented by Ir (L_{A})(L_{B})₂, wherein L_{A} has a structure represented by formula (IA1), formula (IA2), formula (IA3), formula (IA4), formula (IA5), or formula (IA6), and L_{B} is a structure represented by formula (IB), formula L_{B310}, formula L_{B311}, formula L_{B312}, formula L_{B313}, or formula L_{B314};
in formula (IA1), formula (IA2), formula (IA3), formula (IA4), formula (IA5) and formula (IA6), R₁, R₂, R₃, and R₄ are independently selected from H, C₁-C₂₀ alkyl, C₆-C₂₀ aryl; or at least one combination of each of R₁ and R₂ and each of R₃ and R₄ cyclized to form a 4-7 membered saturated ring;
in formula (IB), X is C or N,
the ring Q is selected from a substituted or unsubstituted benzene ring, a substituted or unsubstituted quinoline ring, a substituted or unsubstituted isoquinoline ring, a substituted or unsubstituted naphthalene ring, a substituted or unsubstituted phenanthrene ring, a substituted or unsubstituted benzothiophene ring, a substituted or unsubstituted benzofuran ring, a substituted or unsubstituted indole ring, a substituted or unsubstituted benzothiazole ring, a substituted or unsubstituted benzoxazole ring, a substituted or unsubstituted benzimidazole ring, a substituted or unsubstituted dibenzothiophene ring, a substituted or unsubstituted dibenzofuran ring, a substituted or unsubstituted benzofuropyridine ring, a substituted or unsubstituted benzothienopyridine ring, a substituted or unsubstituted benzindolopyridine ring, a substituted or unsubstituted pyridoindolopyridine ring, a substituted or unsubstituted imidazole ring, a substituted or unsubstituted pyrrolidine ring;
R¹, R², R³ and R⁴ are independently selected from H, C₁-C₂₀ alkyl, C₆-C₂₀ aryl; or any two adjacent of R¹, R², R³, and R⁴ are cyclized together to form at least one ring structure selected from a substituted or unsubstituted benzene ring, a substituted or unsubstituted naphthalene ring, a substituted or unsubstituted benzofuran ring, a substituted or unsubstituted pyridofuran ring, a substituted or unsubstituted benzothiophene ring, and a substituted or unsubstituted pyridothiophene ring;
the optional substituents on the Q ring and the optional substituents on R¹, R², R³ and R⁴ are independently selected from at least one of C₁-C₁₀ alkyl and phenyl.

According to preferred embodiment 1-1, in the structure represented by Ir(L_{A})(L_{B})₂, L_{A} has a structure represented by formula (IA1), formula (IA2), formula (IA3), formula (IA4), formula (IA5), or formula (IA6), and L_{B} is a structure represented by formula (IB), formula L_{B310}, formula L_{B311}, formula L_{B312}, formula L_{B313}, or formula L_{B314};
in formula (IA1), formula (IA2), formula (IA3), formula (IA4), formula (IA5) and formula (IA6), R₁, R₂, R₃, and R₄ are independently selected from H, C₁-C₁₅ alkyl, C₆-C₁₅ aryl; or at least one combination of each of R₁ and R₂ and each of R₃ and R₄ cyclized to form a 4-7 membered saturated ring;
in formula (IB), X is C or N,
the ring Q is selected from a substituted or unsubstituted benzene ring, a substituted or unsubstituted quinoline ring, a substituted or unsubstituted isoquinoline ring, a substituted or unsubstituted naphthalene ring, a substituted or unsubstituted phenanthrene ring, a substituted or unsubstituted benzothiophene ring, a substituted or unsubstituted benzofuran ring, a substituted or unsubstituted indole ring, a substituted or unsubstituted benzothiazole ring, a substituted or unsubstituted benzoxazole ring, a substituted or unsubstituted benzimidazole ring, a substituted or unsubstituted dibenzothiophene ring, a substituted or unsubstituted dibenzofuran ring, a substituted or unsubstituted benzofuropyridine ring, a substituted or unsubstituted benzothienopyridine ring, a substituted or unsubstituted benzindolopyridine ring, a substituted or unsubstituted pyridoindolopyridine ring, a substituted or unsubstituted imidazole ring, a substituted or unsubstituted pyrrolidine ring;
R¹, R², R³ and R⁴ are independently selected from H, C₁-C₁₅ alkyl, C₆-C₁₅ aryl; or any two adjacent of R¹, R², R³, and R⁴ are cyclized together to form at least one ring structure selected from a substituted or unsubstituted benzene ring, a substituted or unsubstituted naphthalene ring, a substituted or unsubstituted benzofuran ring, a substituted or unsubstituted pyridofuran ring, a substituted or unsubstituted benzothiophene ring, and a substituted or unsubstituted pyridothiophene ring;
the optional substituents on the Q ring and the optional substituents on R¹, R², R³ and R⁴ are independently selected from at least one of C₁-C₈ alkyl and phenyl.

According to preferred embodiments 1-2, in the structure represented by Ir(L_{A})(L_{B})₂, L_{A} has a structure represented by formula (IA1), formula (IA2), formula (IA3), formula (IA4), formula (IA5), or formula (IA6), and L_{B} is a structure represented by formula (IB), formula L_{B310}, formula L_{B311}, formula L_{B312}, formula L_{B313}, or formula L_{B314};
in formula (IA1), formula (IA2), formula (IA3), formula (IA4), formula (IA5) and formula (IA6), R₁, R₂, R₃, and R₄ are independently selected from H, C₁-C₁₀ alkyl, C₆-C₁₂ aryl; or at least one combination of each of R₁ and R₂ and each of R₃ and R₄ cyclized to form a 4-7 membered saturated ring;
in formula (IB), X is C or N,
the ring Q is selected from a substituted or unsubstituted benzene ring, a substituted or unsubstituted quinoline ring, a substituted or unsubstituted isoquinoline ring, a substituted or unsubstituted naphthalene ring, a substituted or unsubstituted phenanthrene ring, a substituted or unsubstituted benzothiophene ring, a substituted or unsubstituted benzofuran ring, a substituted or unsubstituted indole ring, a substituted or unsubstituted benzothiazole ring, a substituted or unsubstituted benzoxazole ring, a substituted or unsubstituted benzimidazole ring, a substituted or unsubstituted dibenzothiophene ring, a substituted or unsubstituted dibenzofuran ring, a substituted or unsubstituted benzofuropyridine ring, a substituted or unsubstituted benzothienopyridine ring, a substituted or unsubstituted benzindolopyridine ring, a substituted or unsubstituted pyridoindolopyridine ring, a substituted or unsubstituted imidazole ring, a substituted or unsubstituted pyrrolidine ring;
R¹, R², R³ and R⁴ are independently selected from H, C₁-C₁₀ alkyl, C₆-C₁₂ aryl; or any two adjacent of R¹, R², R³, and R⁴ are cyclized together to form at least one ring structure selected from a substituted or unsubstituted benzene ring, a substituted or unsubstituted naphthalene ring, a substituted or unsubstituted benzofuran ring, a substituted or unsubstituted pyridofuran ring, a substituted or unsubstituted benzothiophene ring, and a substituted or unsubstituted pyridothiophene ring;
the optional substituents on the Q ring and the optional substituents on R¹, R², R³ and R⁴ are independently selected from at least one of C₁-C₆ alkyl and phenyl.

According to a preferred embodiment, in the structure represented by Ir(L_{A})(L_{B})₂ of the present invention,
in the formula (1A), R₁, R₂, R₃, and R₄ are independently selected from H, C₁-C₇ alkyl, C₆-C₁₀ aryl; or at least one combination of each of R₁ and R₂ and each of R₃ and R₄ cyclized to form a 4-6 membered saturated ring.

According to particularly preferred embodiments 1-3, in the structure represented by Ir(L_{A})(L_{B})₂, in formula (IA1), formula (IA2), formula (IA3), formula (IA4), formula (IA5) and formula (IA6), R₁, R₂, R₃, and R₄ are independently selected from H, C₁-C₈ alkyl, C₆-C₁₀ aryl; or at least one combination of each of R₁ and R₂ and each of R₃ and R₄ cyclized to form a 4-7 membered saturated ring.

According to another preferred embodiment, in the structure represented by Ir(L_{A})(L_{B})₂ of the present invention, in formula (IA1), formula (IA2), formula (IA3), formula (IA4), formula (IA5) and formula (IA6), R₁, R₂, R₃, and R₄ are independently selected from H, methyl, ethyl, C₃ straight chain alkyl, C₃ branched chain alkyl, C₃ cycloalkyl, C₄ straight chain alkyl, C₄ branched chain alkyl, C₄ cycloalkyl, C₅ straight chain alkyl, C₅ branched chain alkyl, C₅ cycloalkyl, C₆ straight chain alkyl, C₆ branched chain alkyl, C₆ cycloalkyl, C₇ straight chain alkyl, C₇ branched chain alkyl, C₇ cycloalkyl, C₈ straight chain alkyl, C₈ branched chain alkyl, C₈ cycloalkyl, phenyl; or at least one combination of each of R₁ and R₂ and each of R₃ and R₄ cyclized to form a 4-7 membered saturated ring.

According to particularly preferred embodiments 1-4, in the structure represented by Ir(L_{A})(L_{B})₂, L_{A} is selected from the group consisting of the following structures:

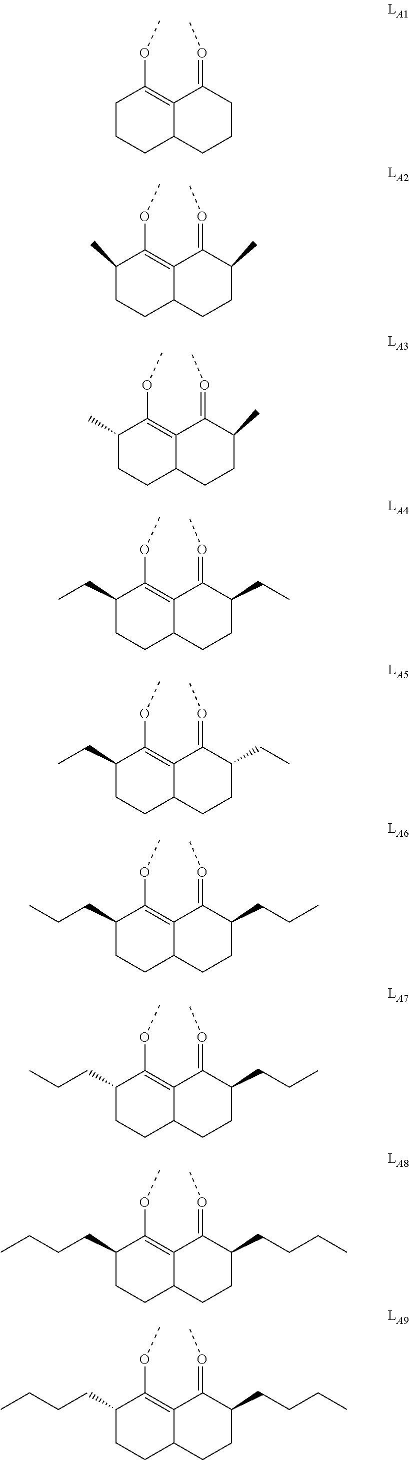

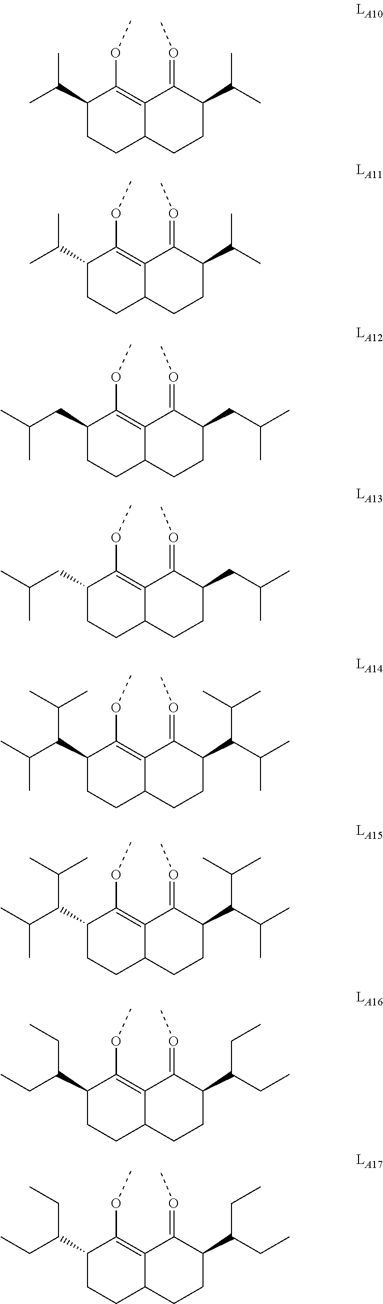

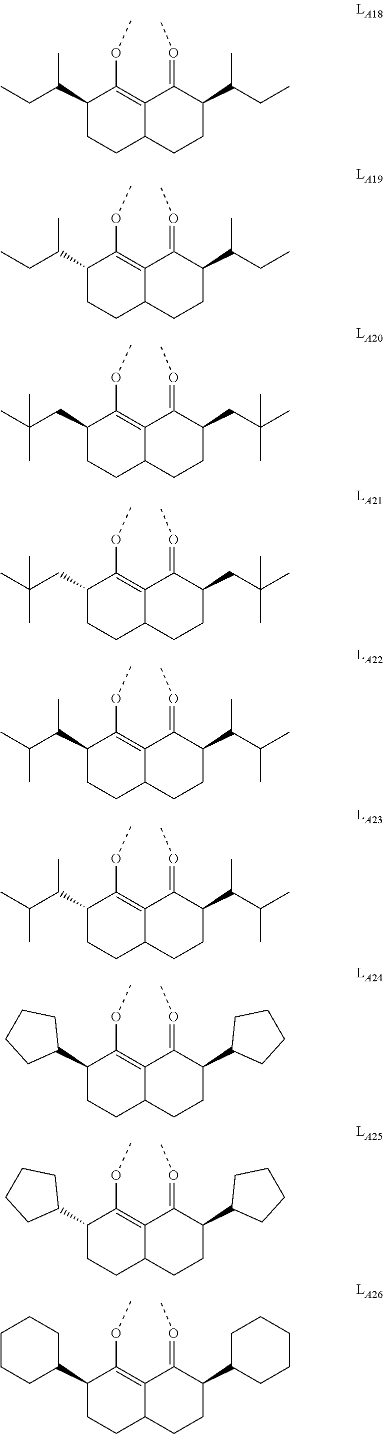

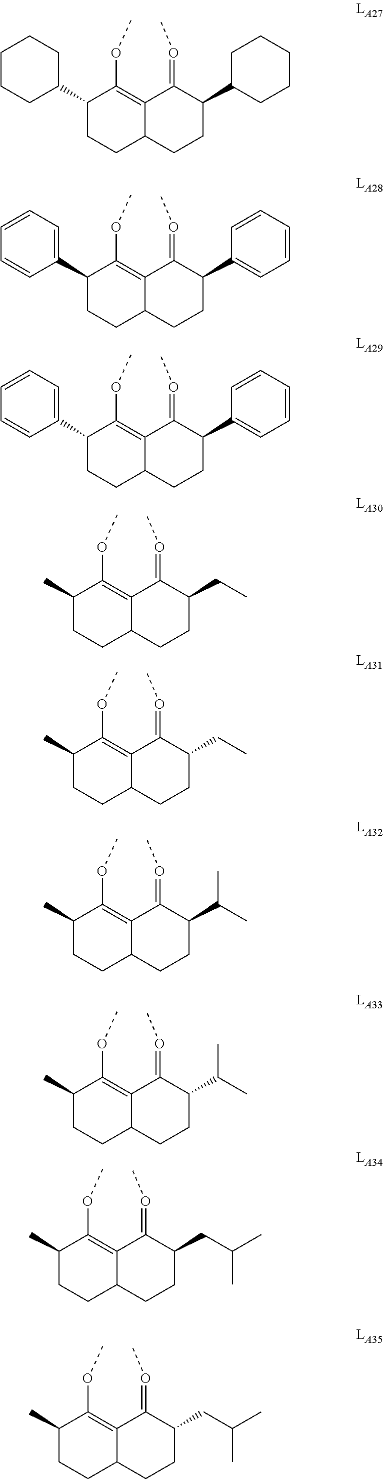

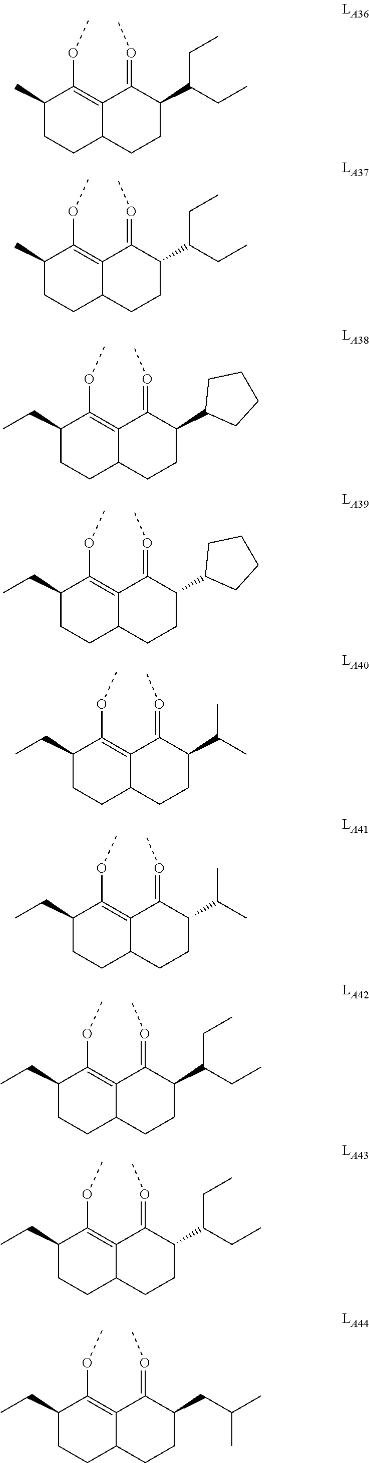

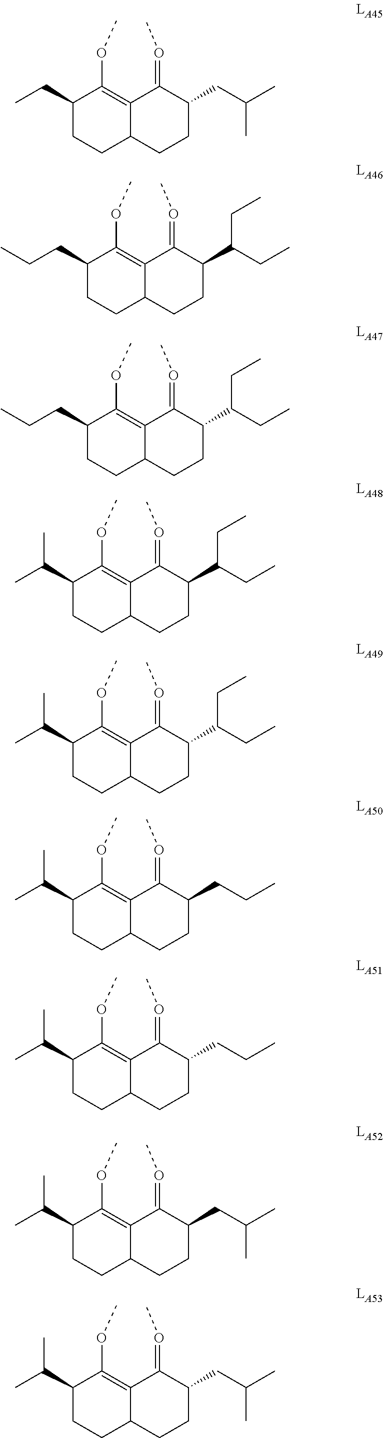

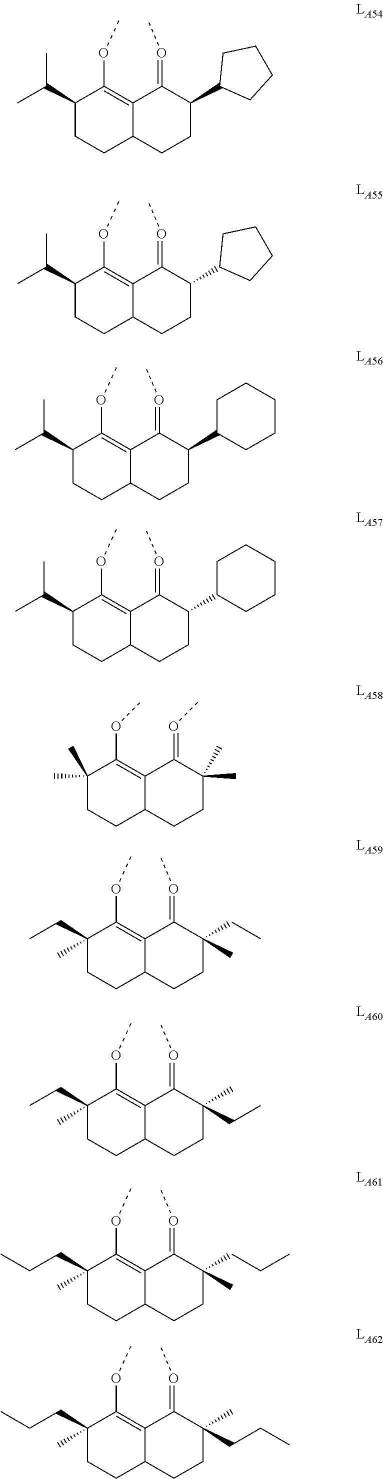

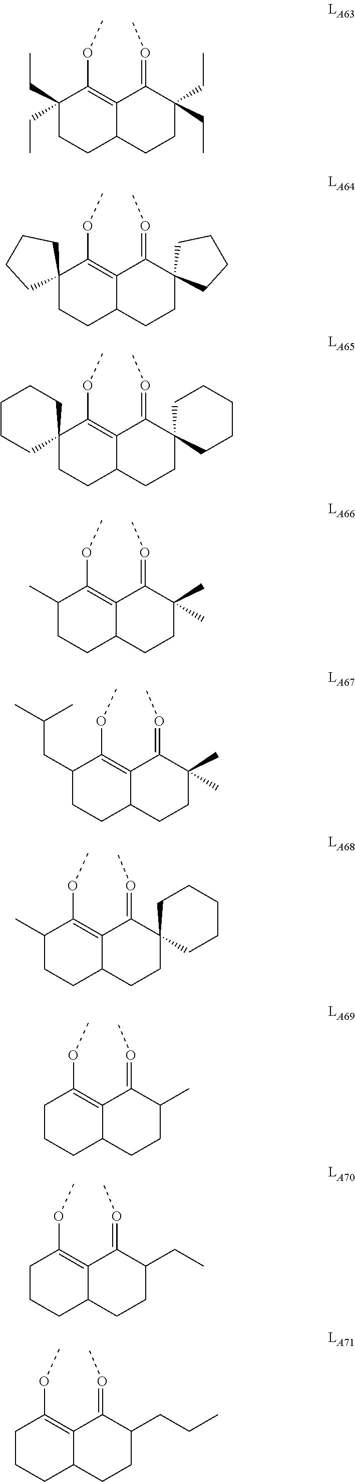

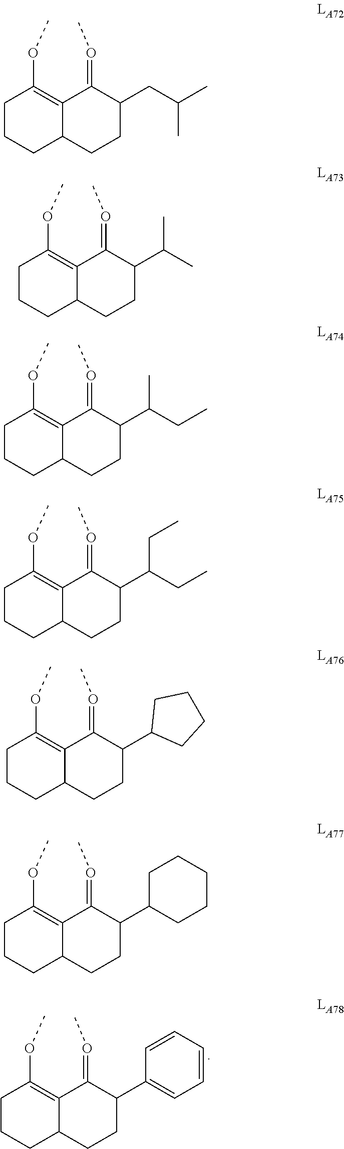

Alternatively, according to particularly preferred embodiments 1-4, in the structure represented by Ir(L_{A})(L_{B})₂, L_{A} is selected from the group consisting of the following structures:

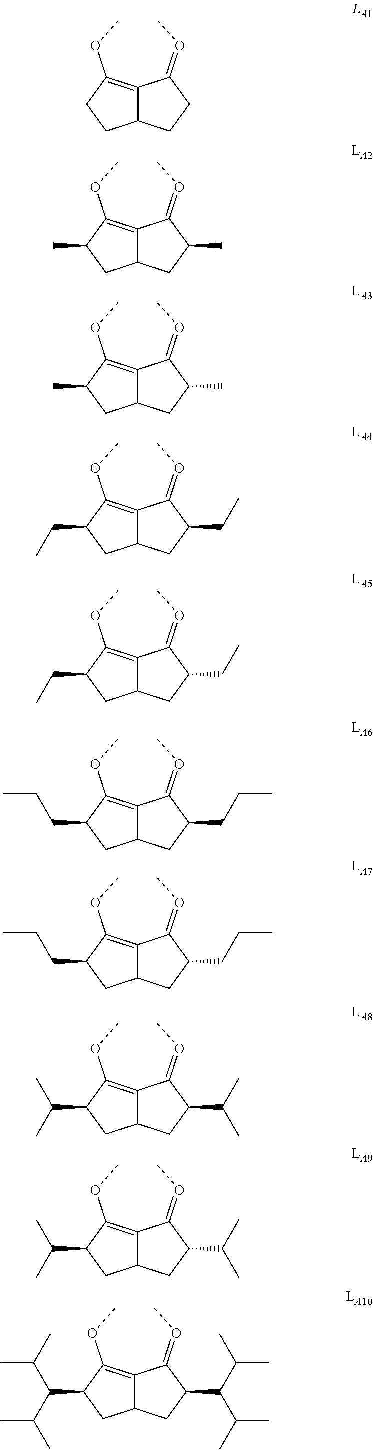

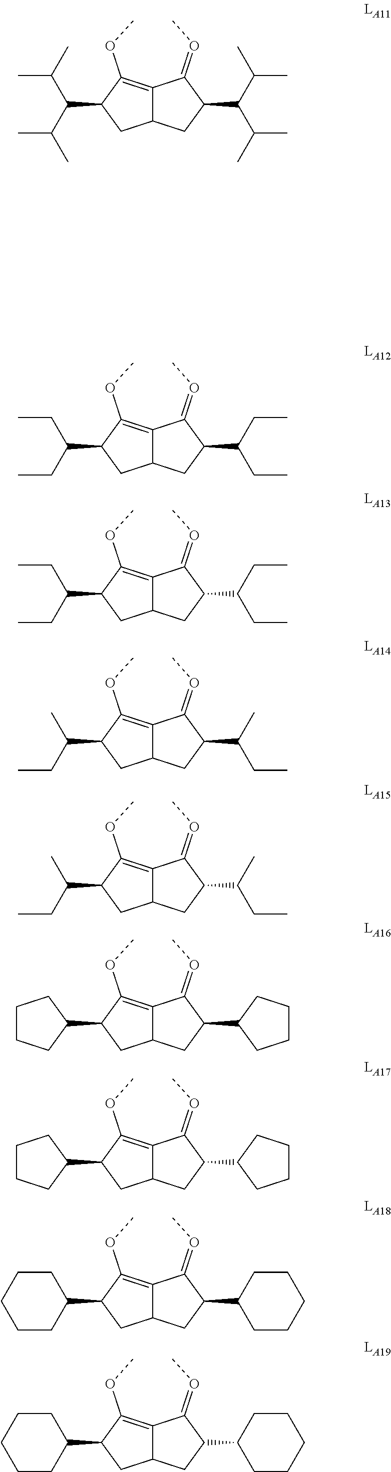

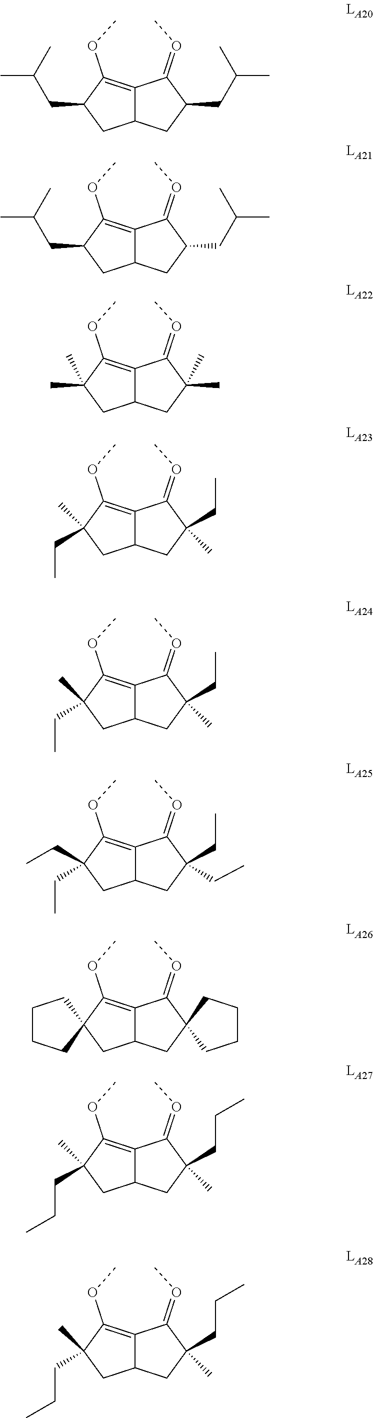

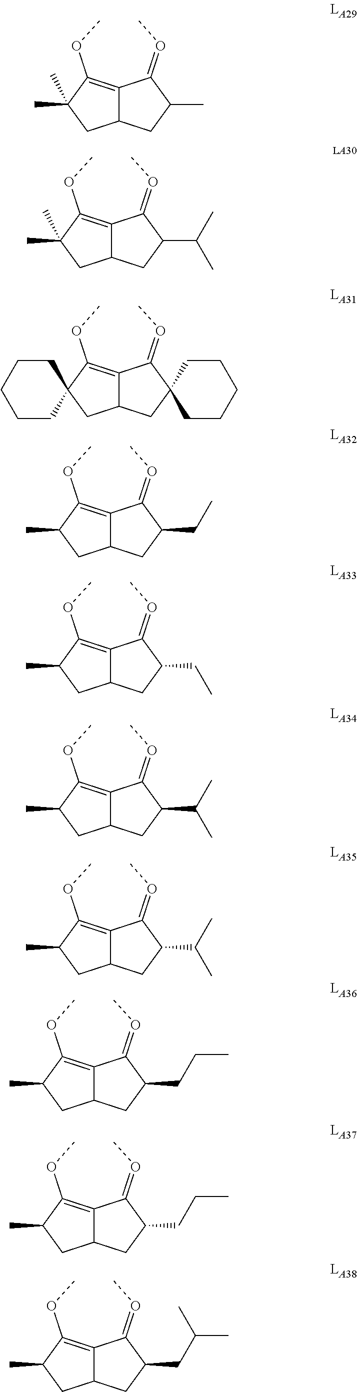

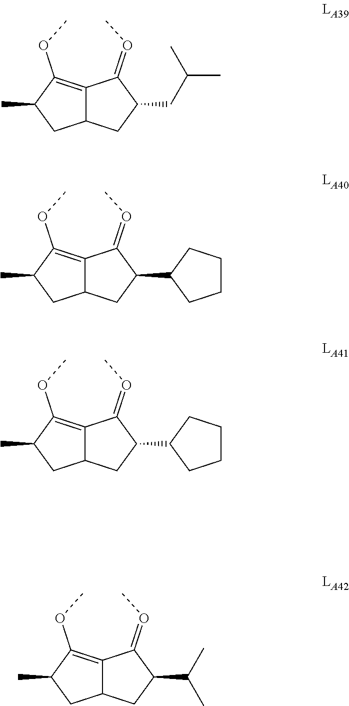

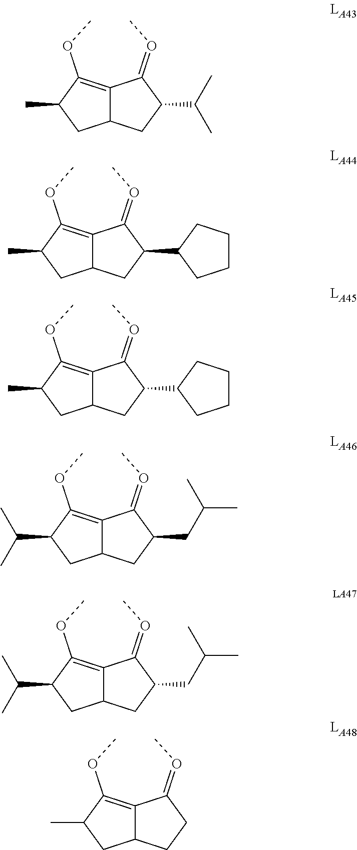

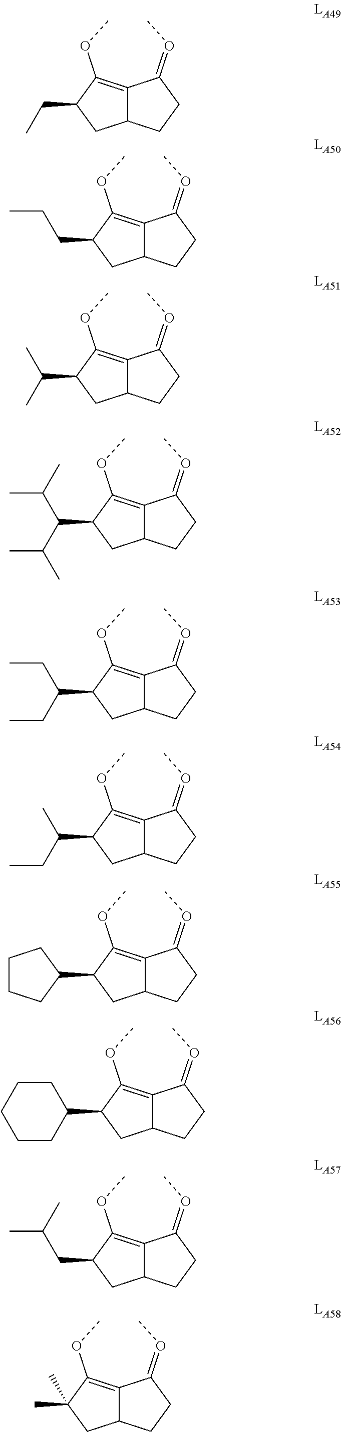

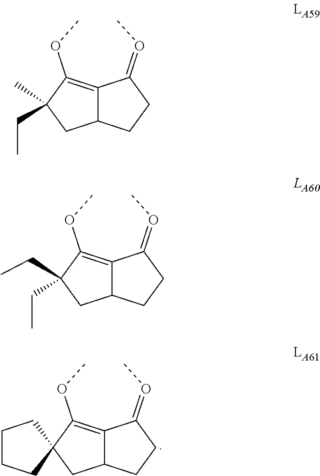

Alternatively, according to particularly preferred embodiments 1-4, in the structure represented by Ir(L_{A})(L_{B})₂, L_{A} is selected from the group consisting of the following structures:

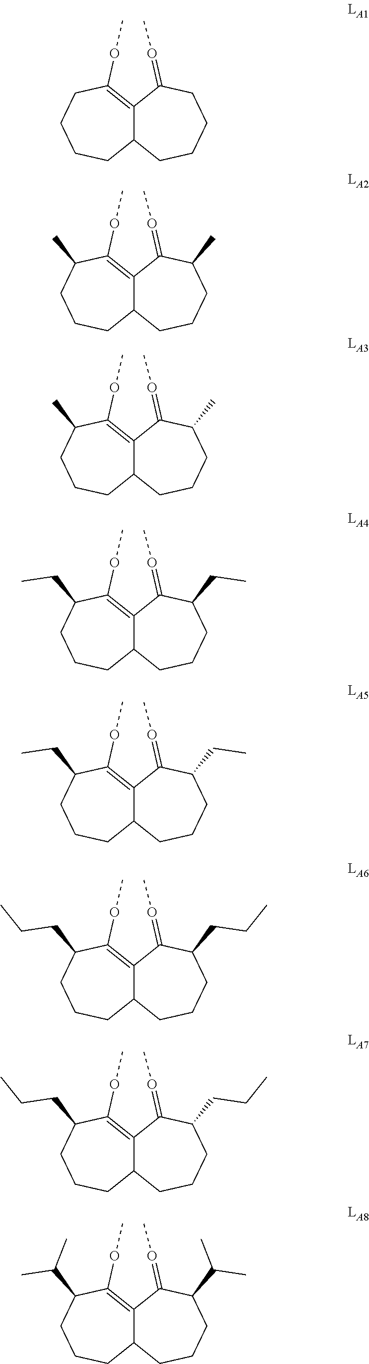

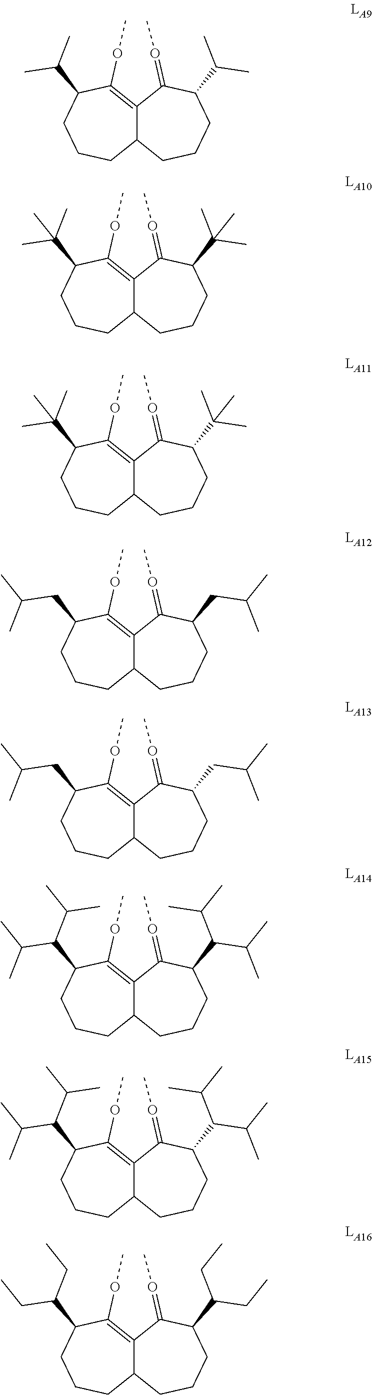

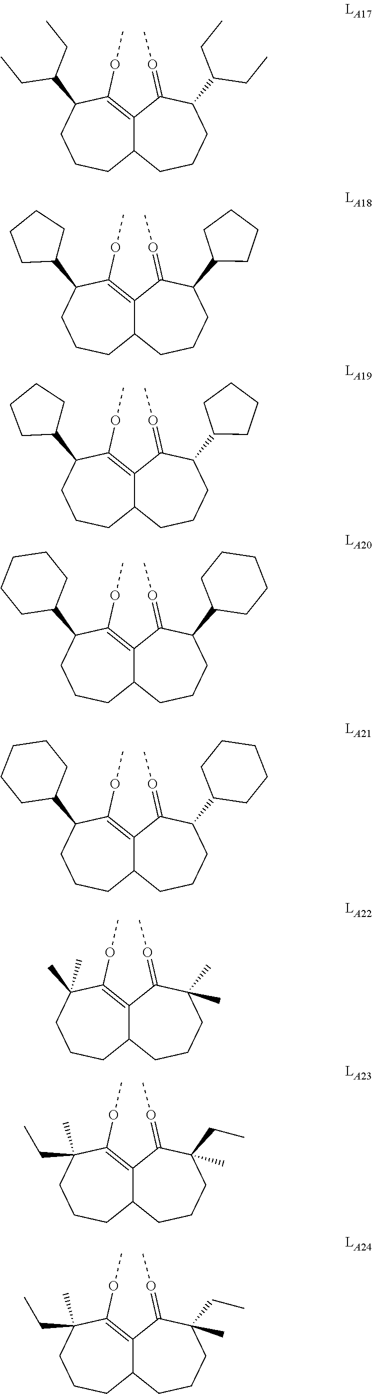

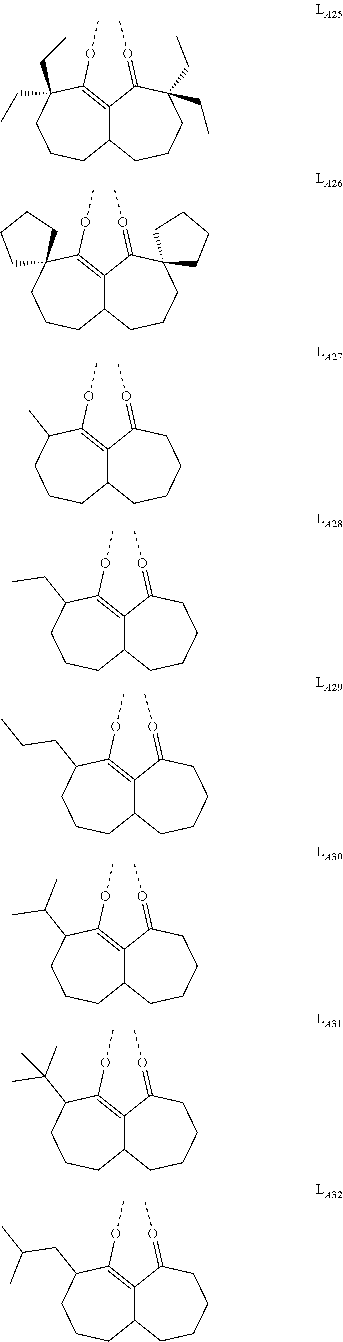

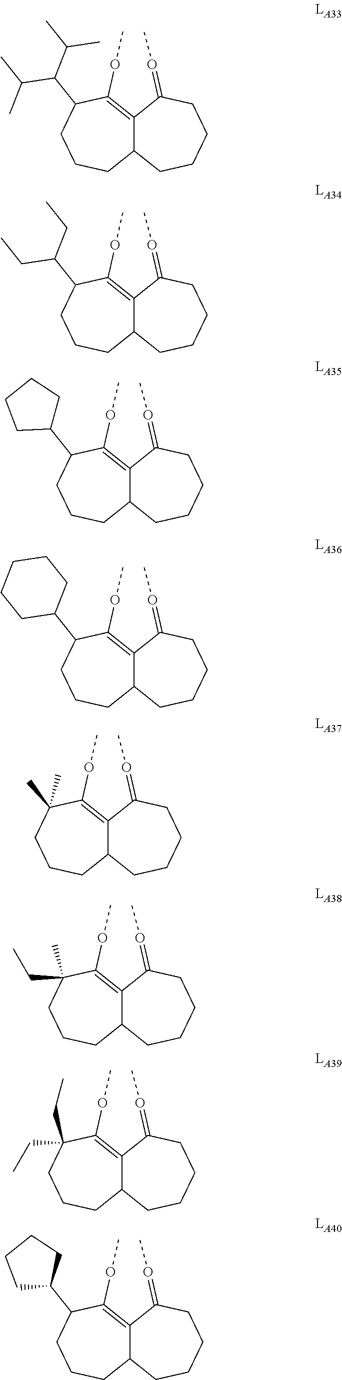

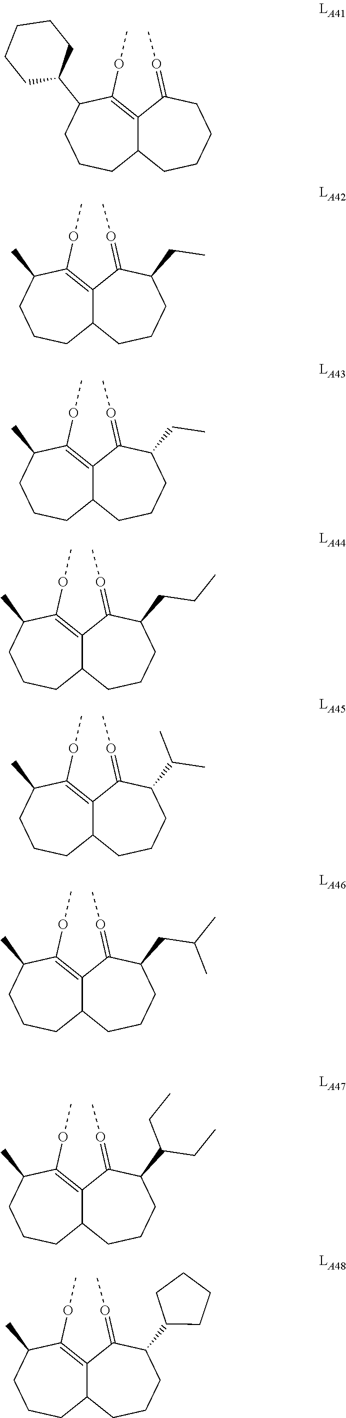

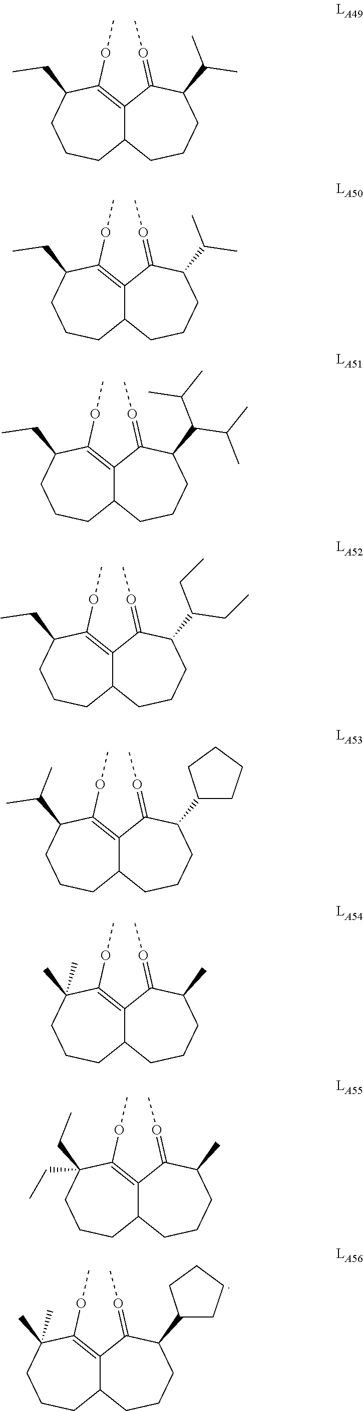

Alternatively, according to particularly preferred embodiments 1-4, in the structure represented by Ir(L_{A})(L_{B})₂, L_{A} is selected from the group consisting of the following structures:

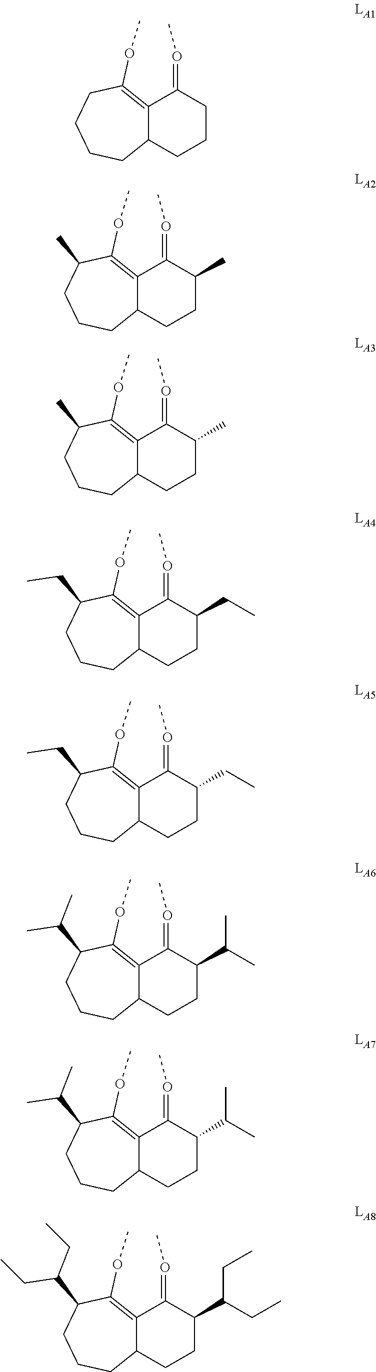

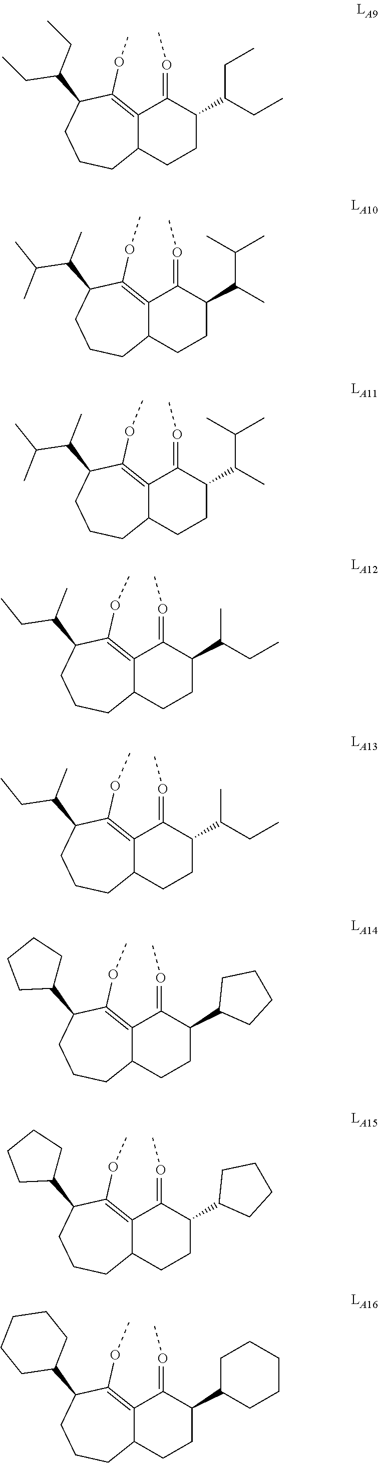

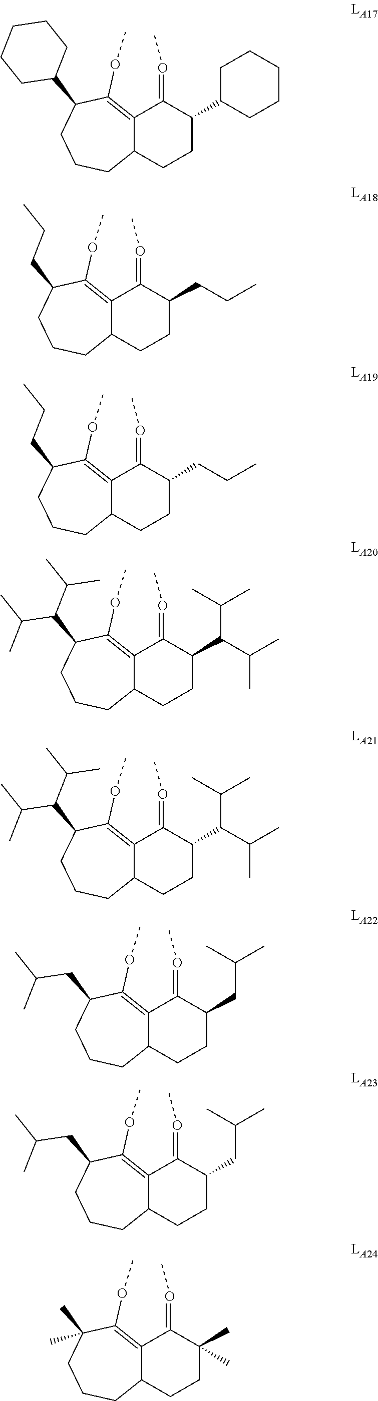

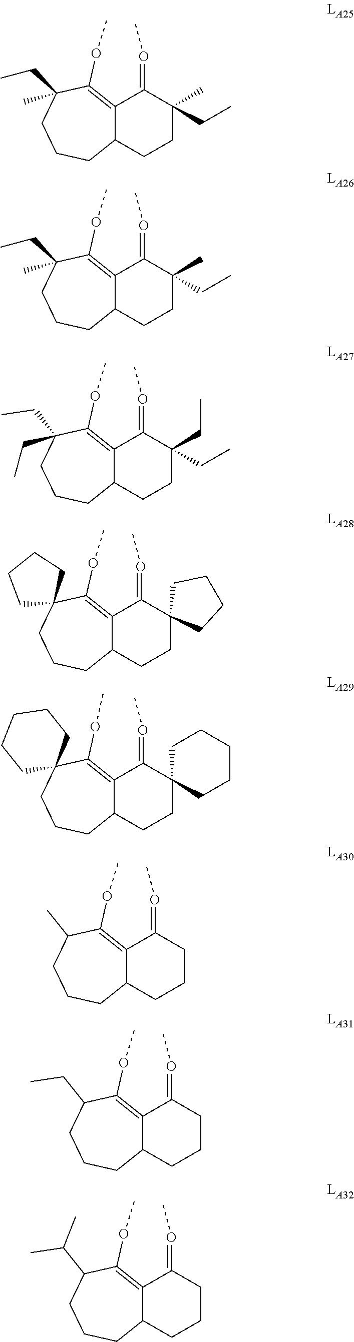

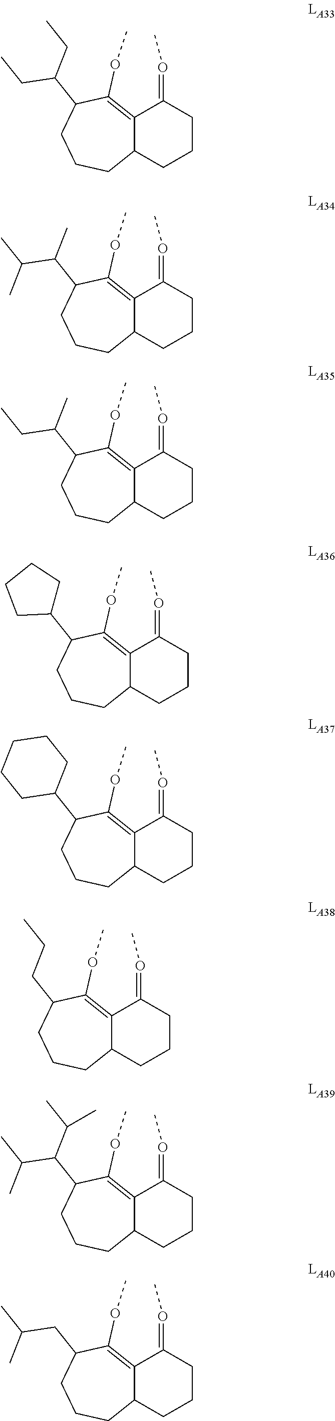

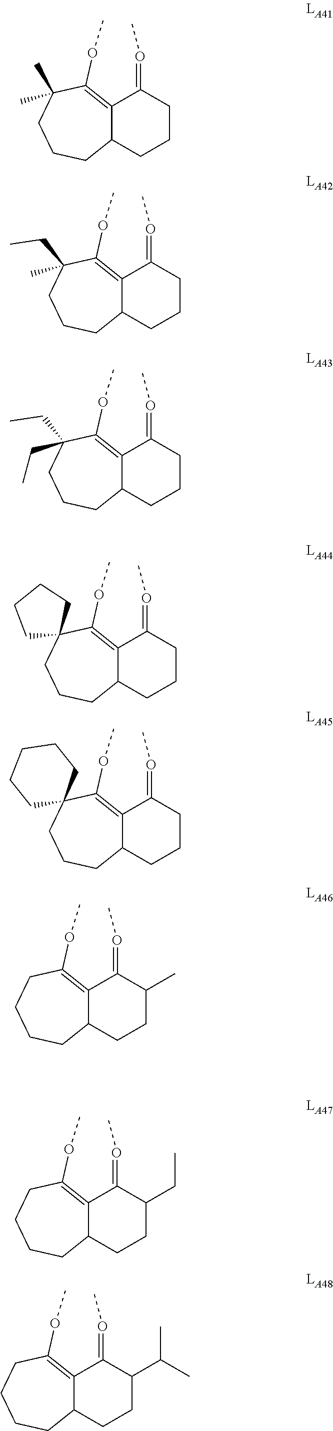

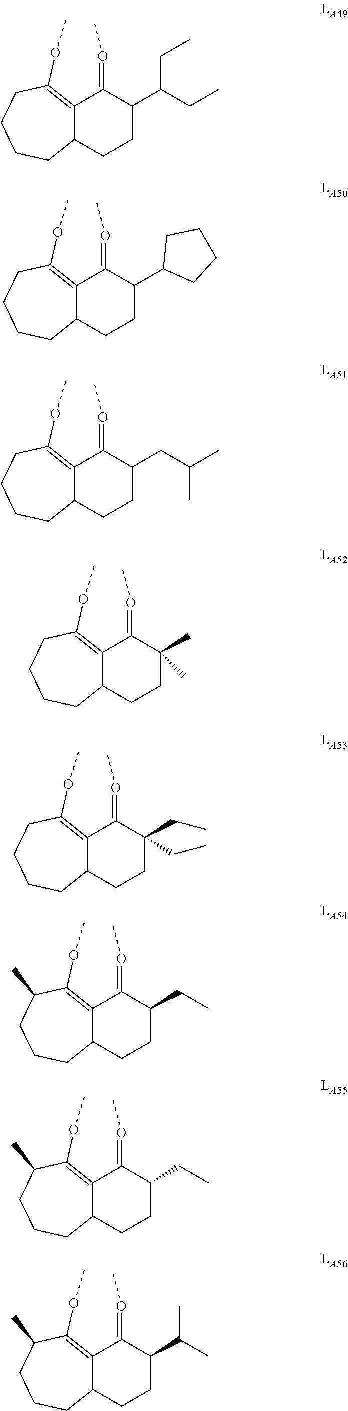

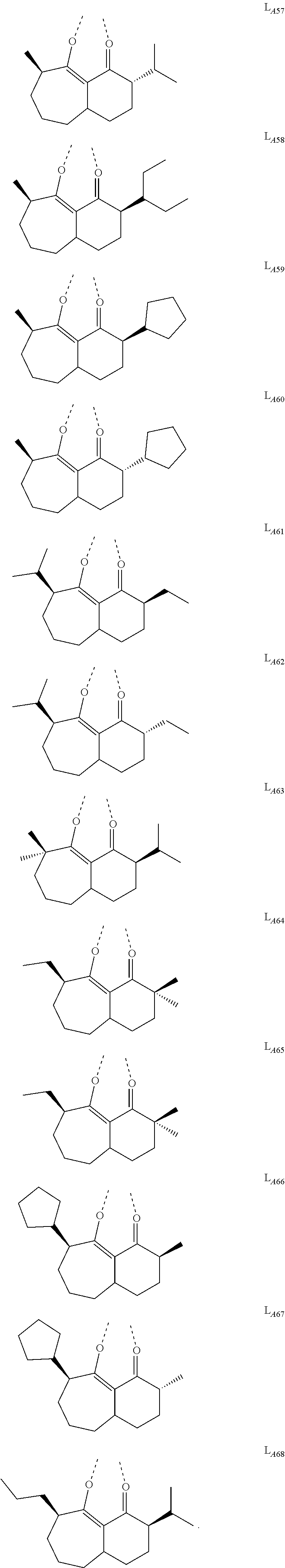

Alternatively, according to particularly preferred embodiments 1-4, in the structure represented by Ir(L_{A})(L_{B})₂, L_{A} is selected from the group consisting of the following structures:

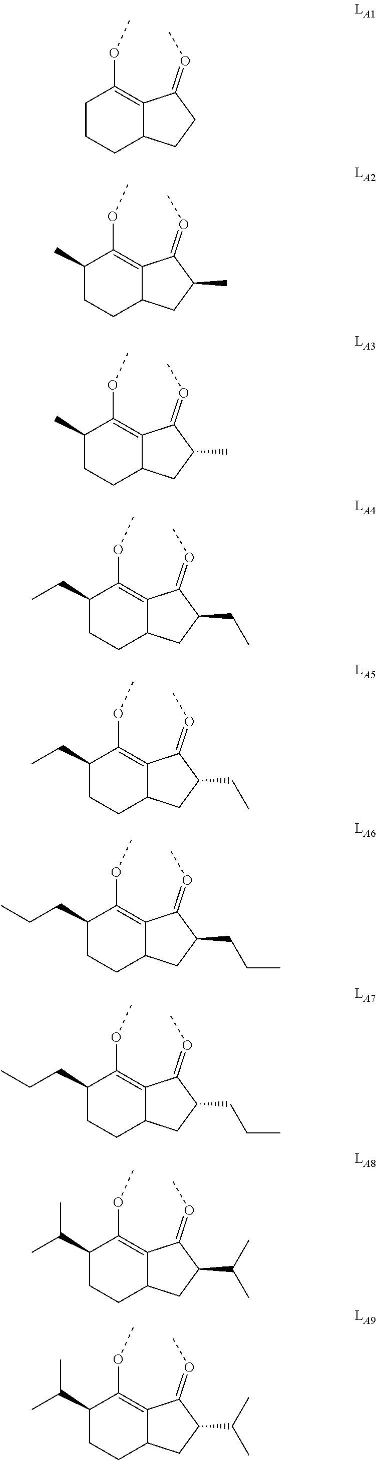

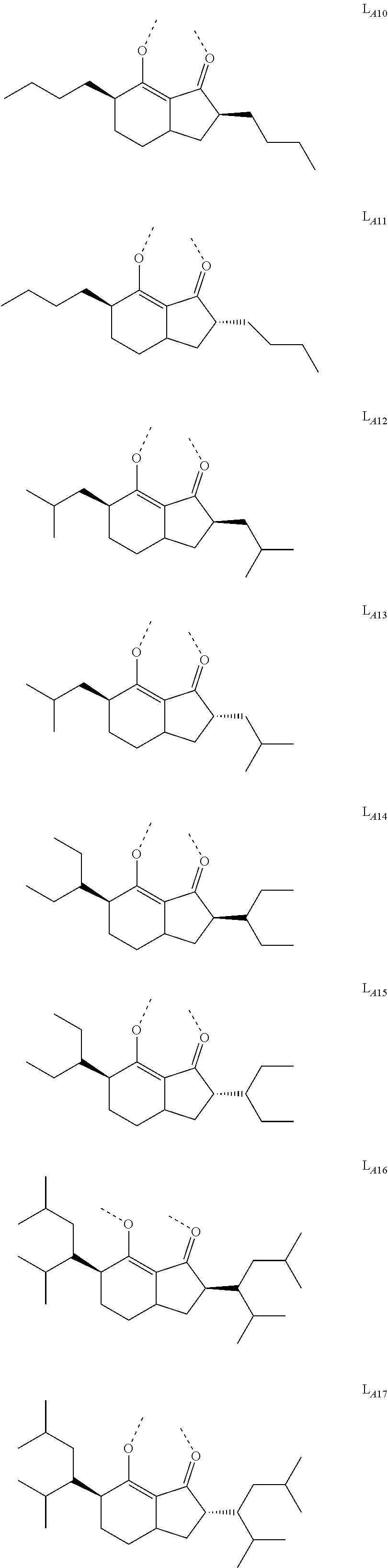

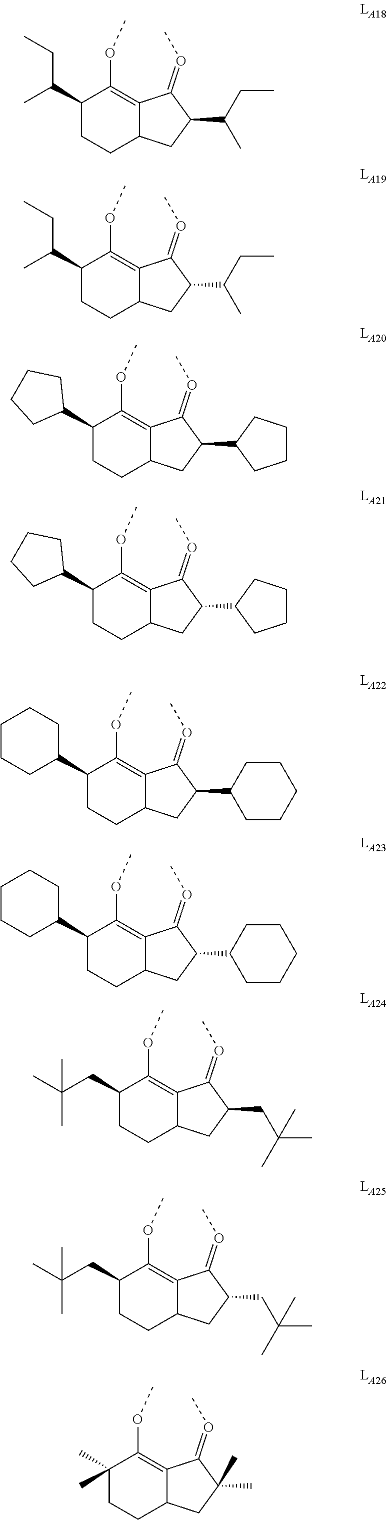

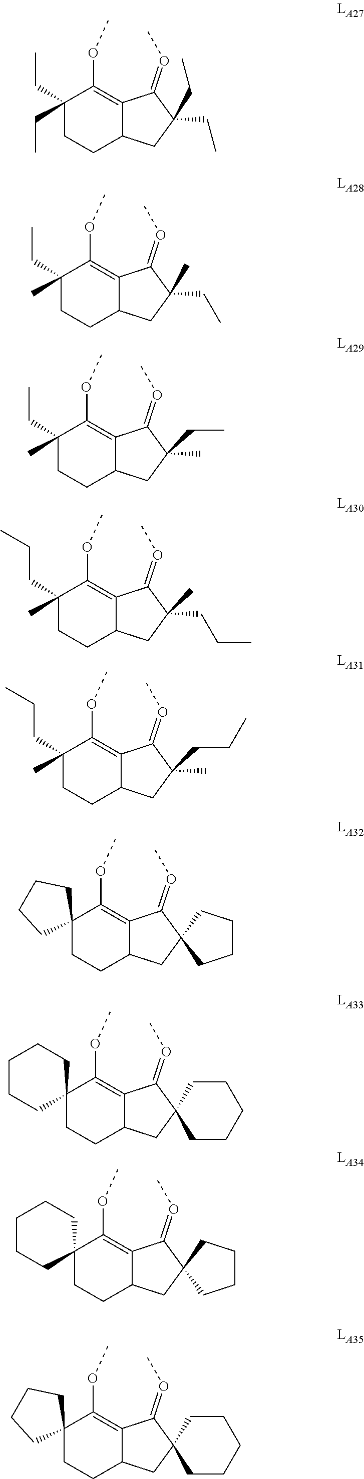

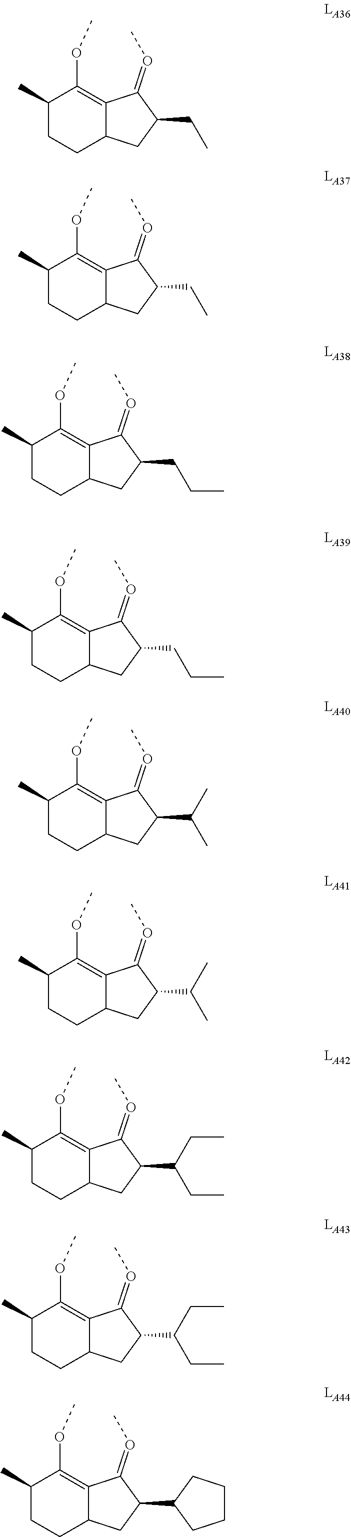

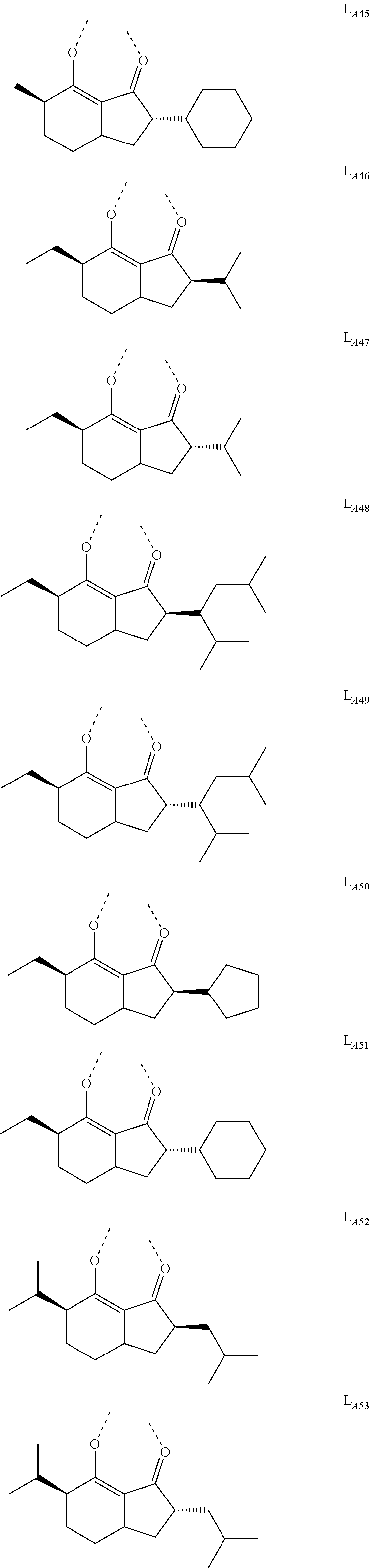

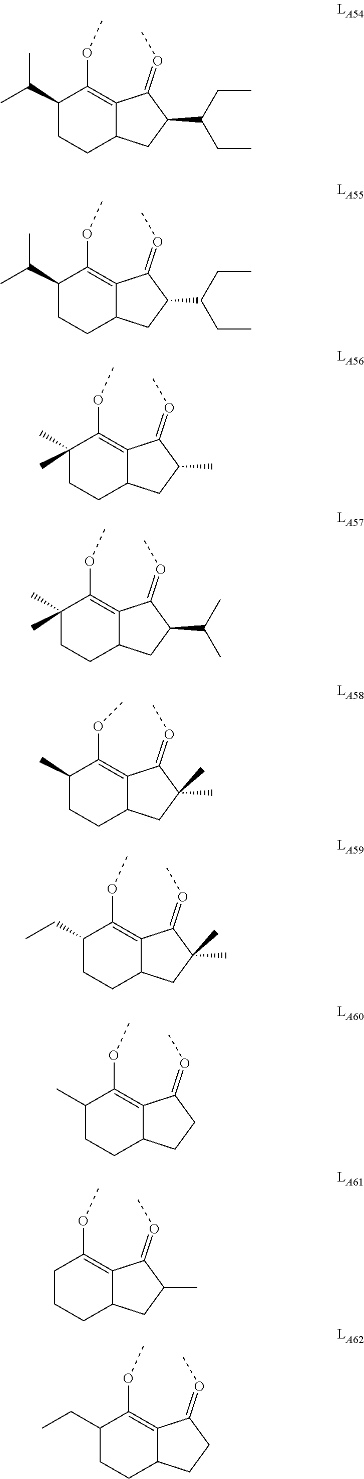

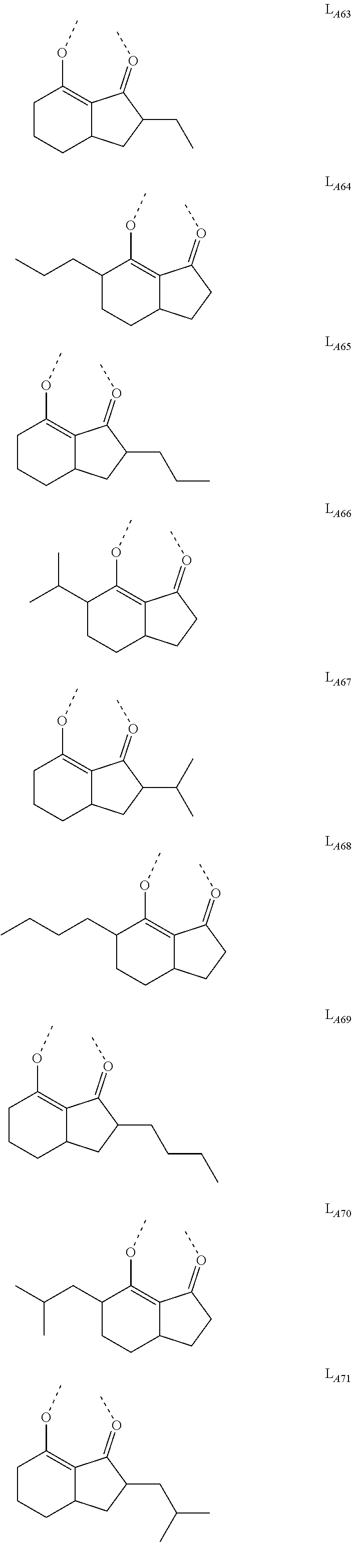

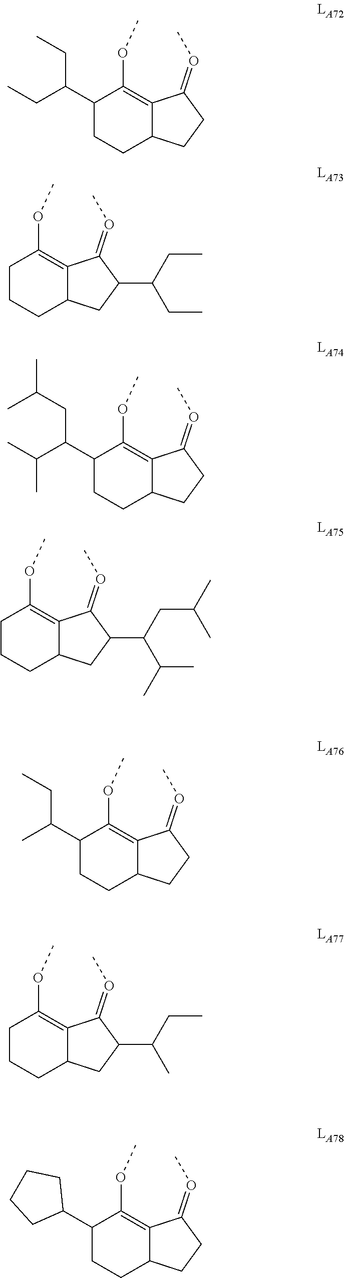

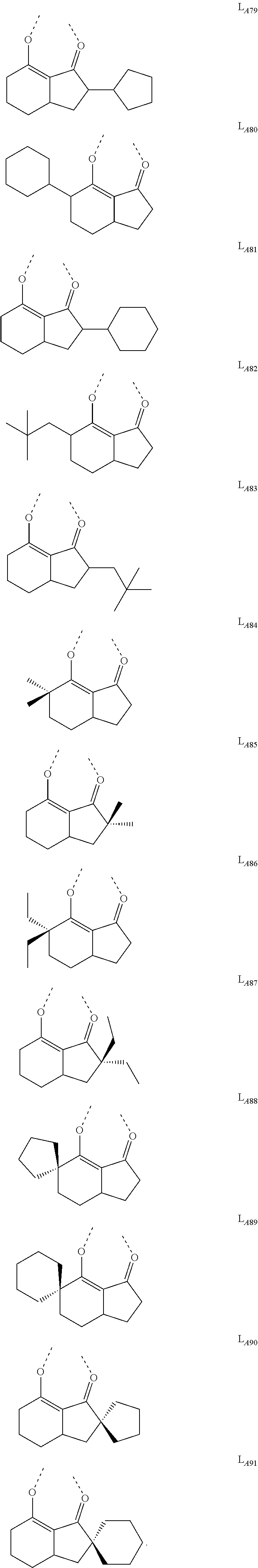

Alternatively, according to particularly preferred embodiments 1-4, in the structure represented by Ir(L_{A})(L_{B})₂, L_{A} is selected from the group consisting of the following structures:

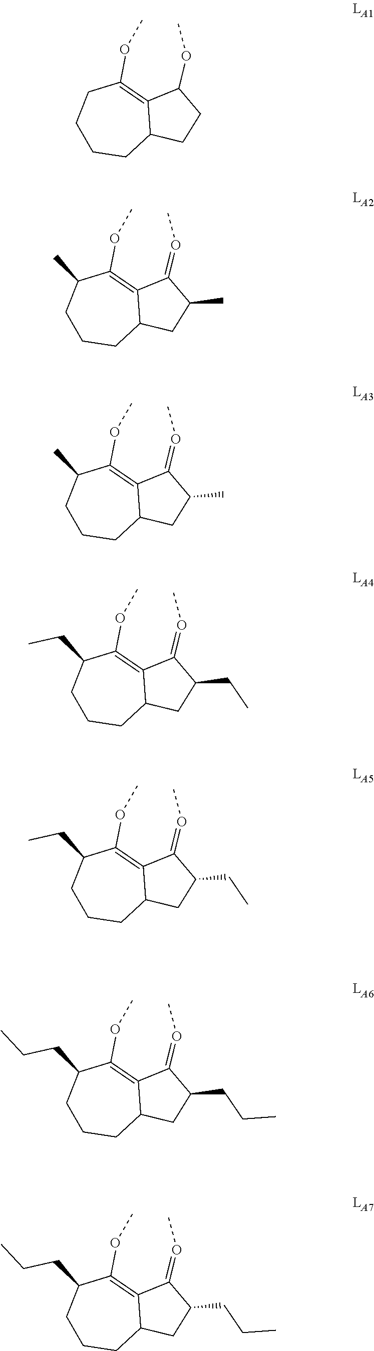

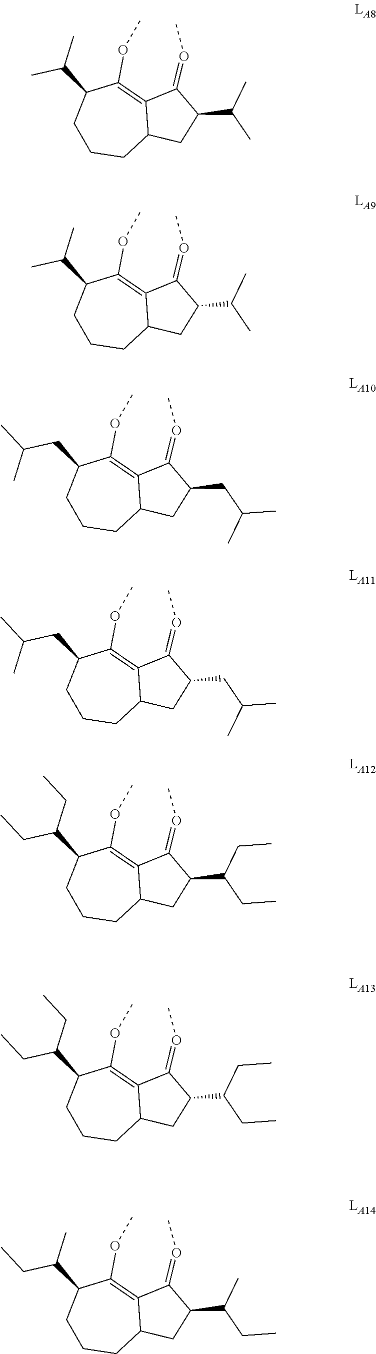

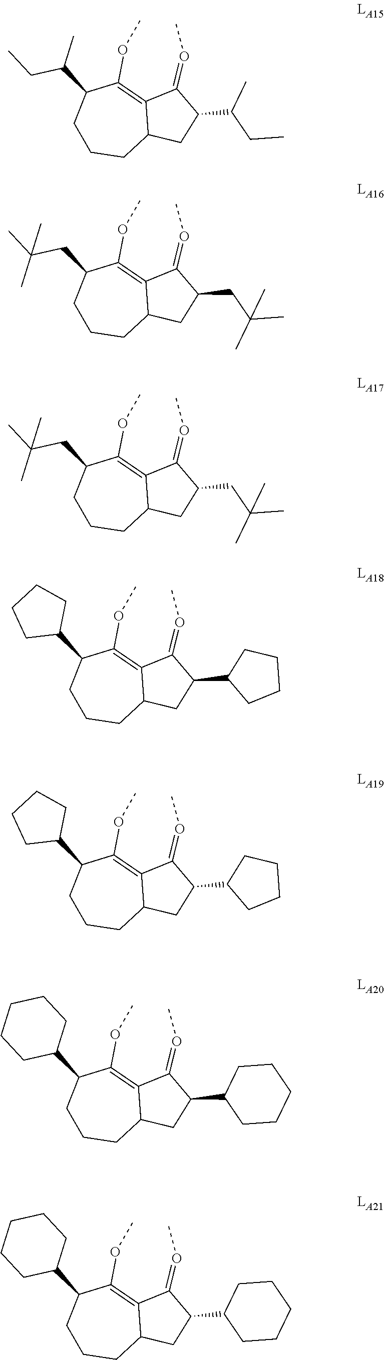

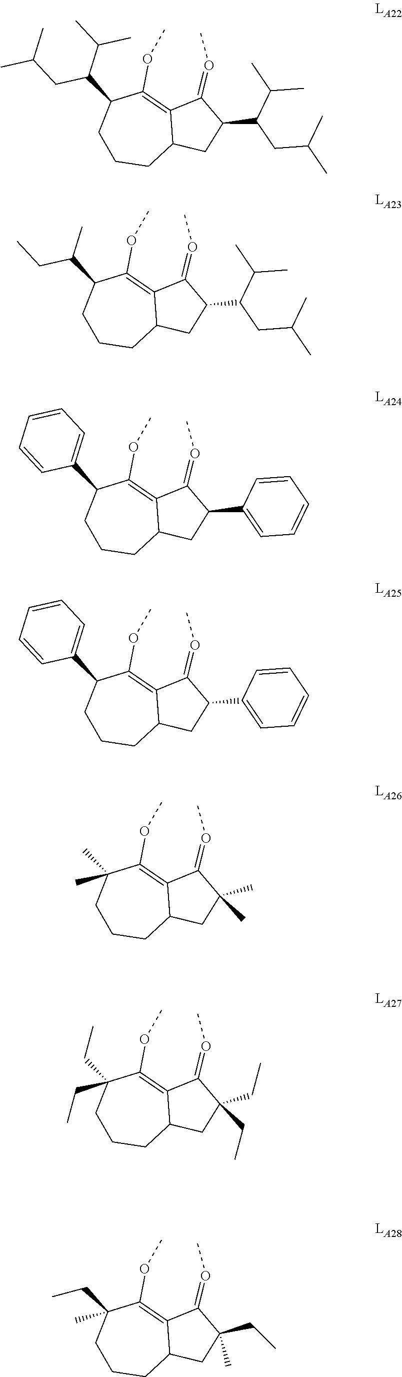

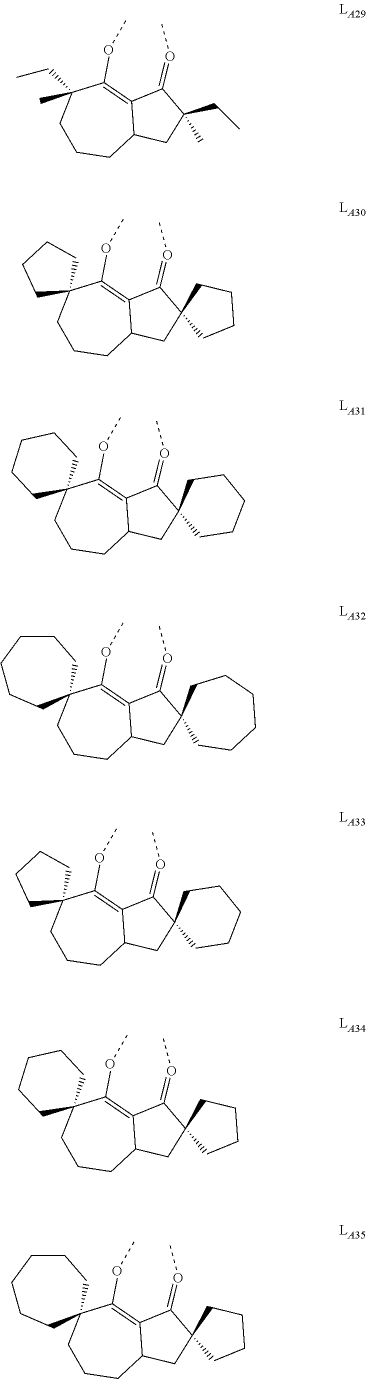

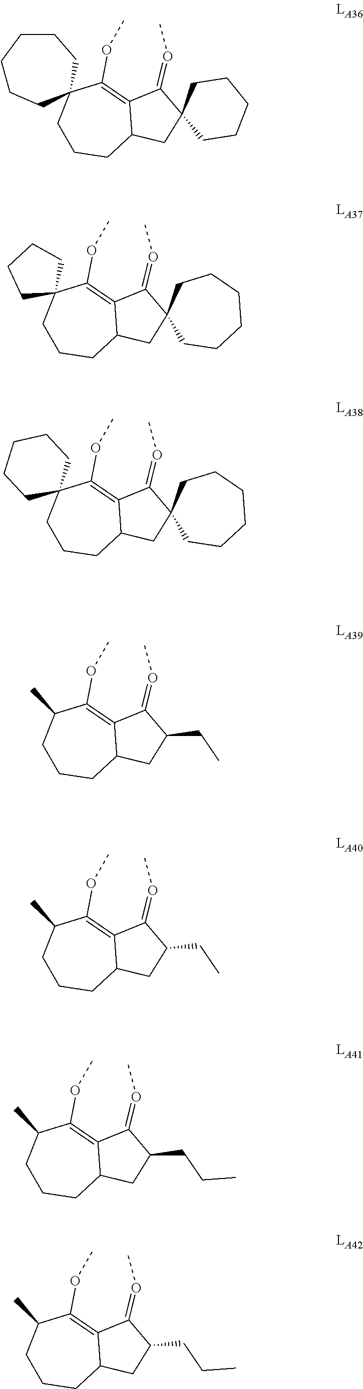

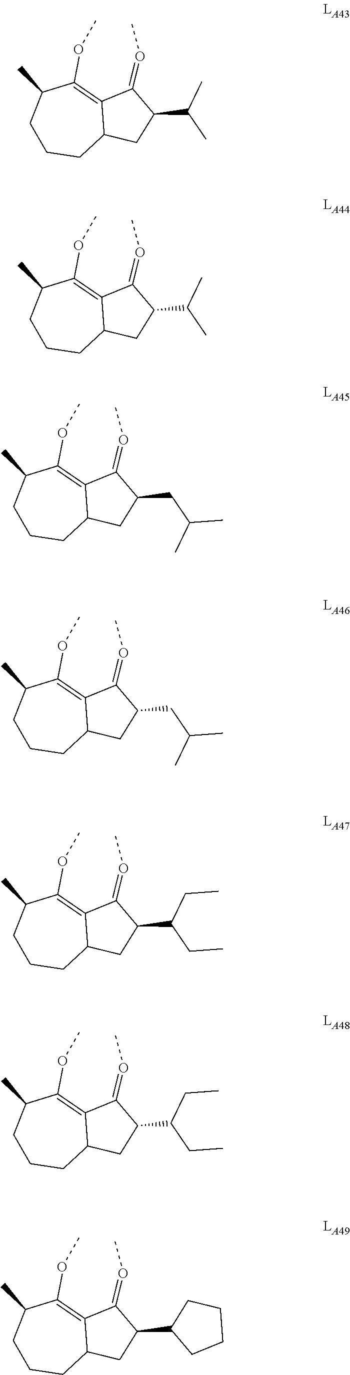

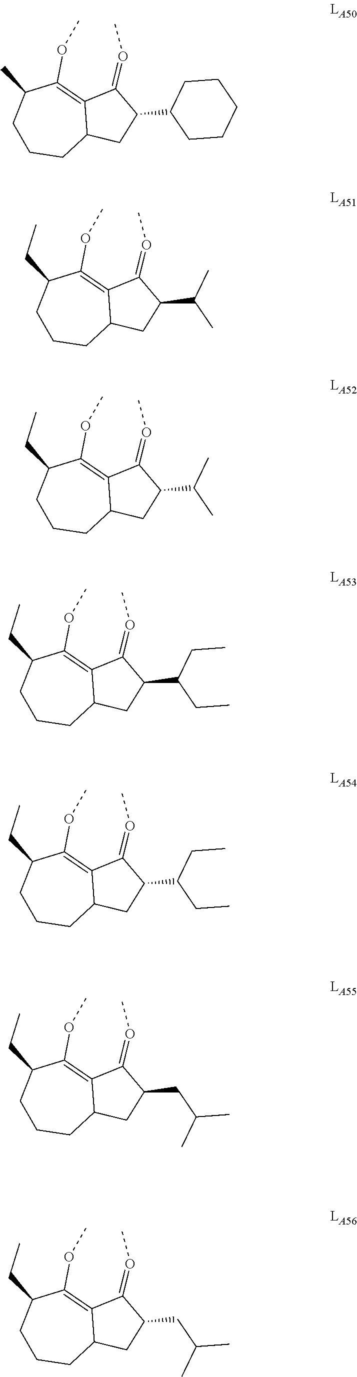

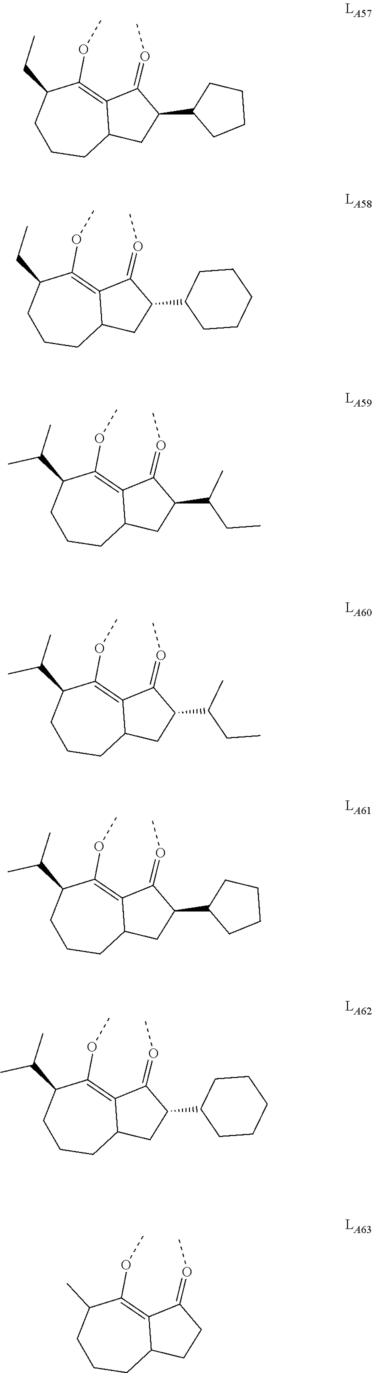

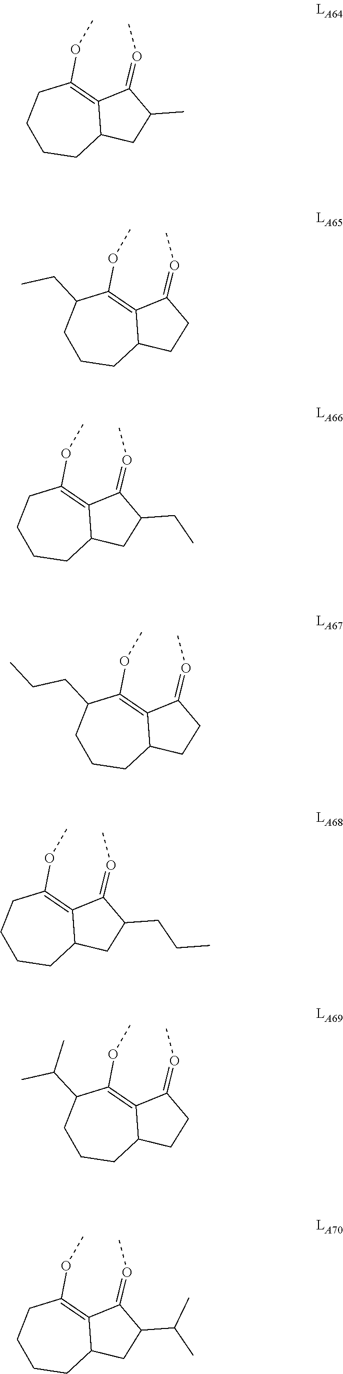

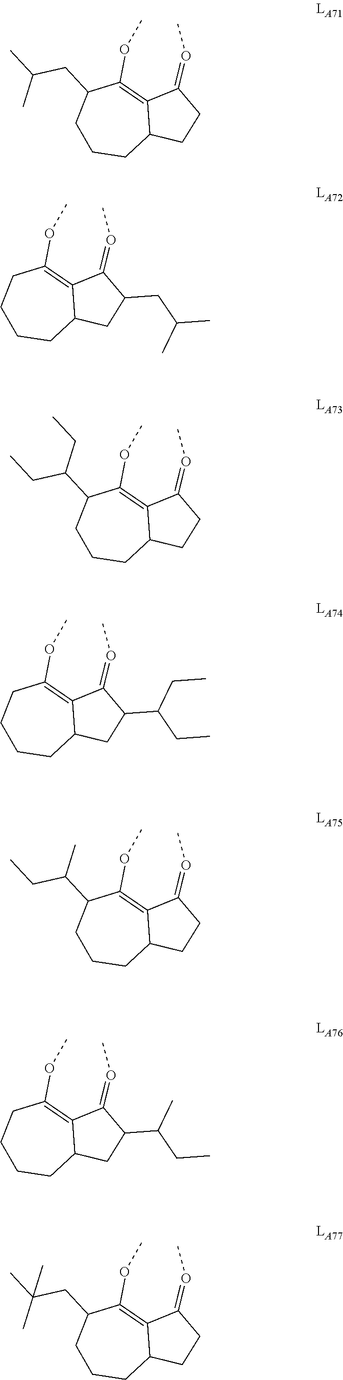

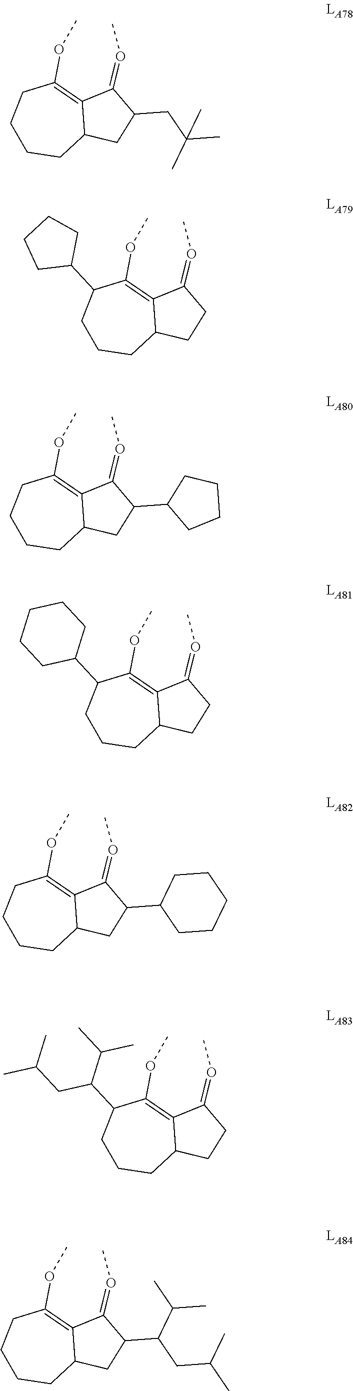

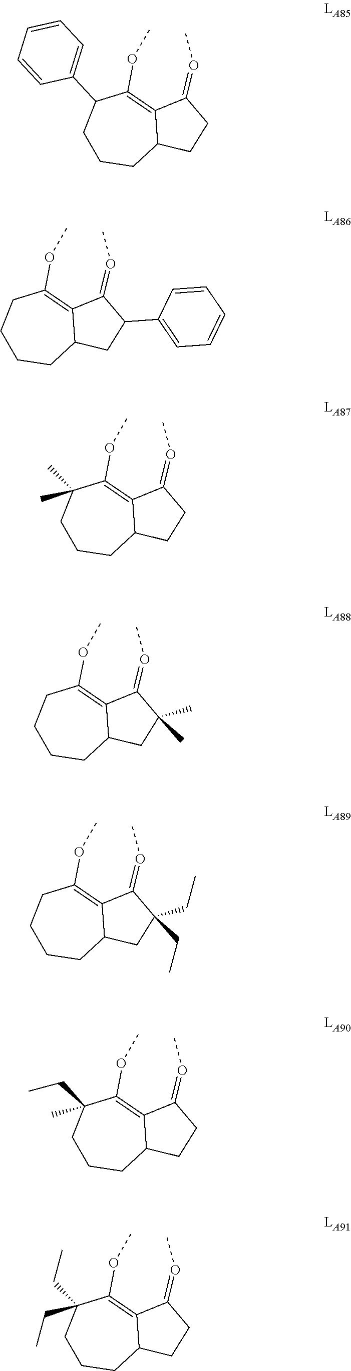

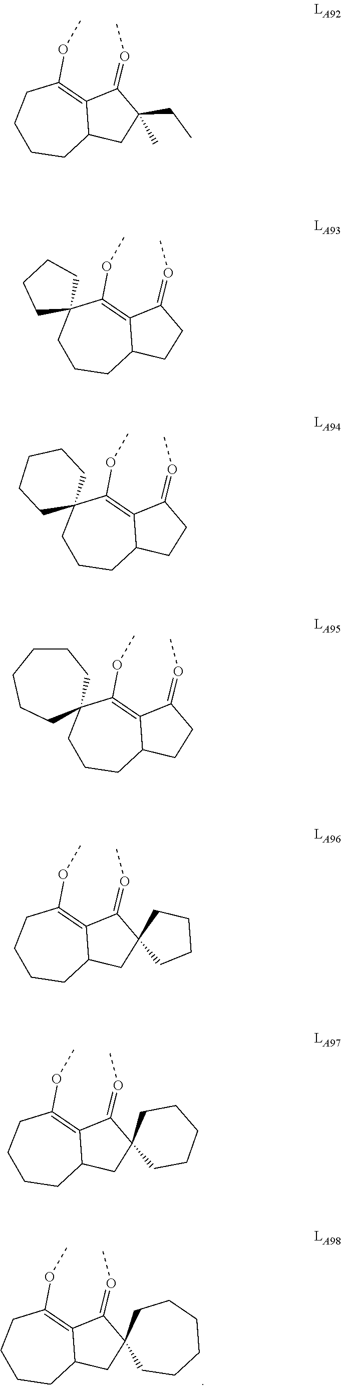

According to particularly preferred embodiments 1-5, in the structure represented by Ir(L_{A})(L_{B})₂, L_{B} is selected from the group consisting of the following structures:

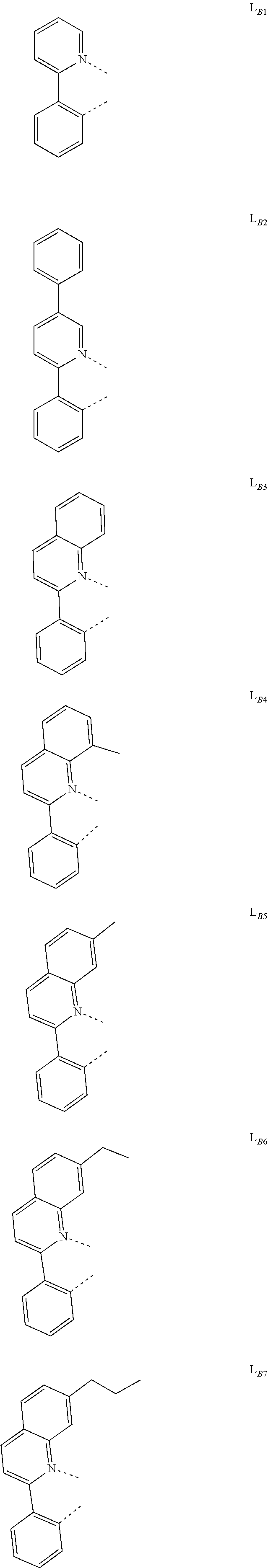

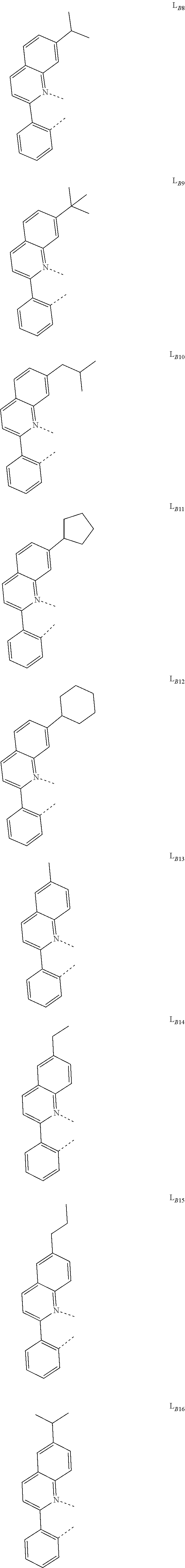

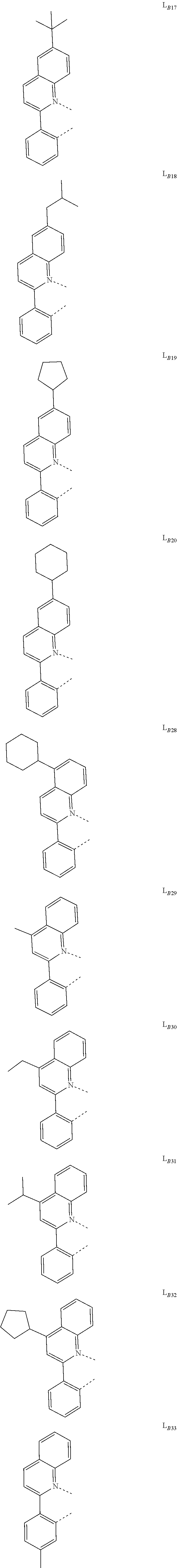

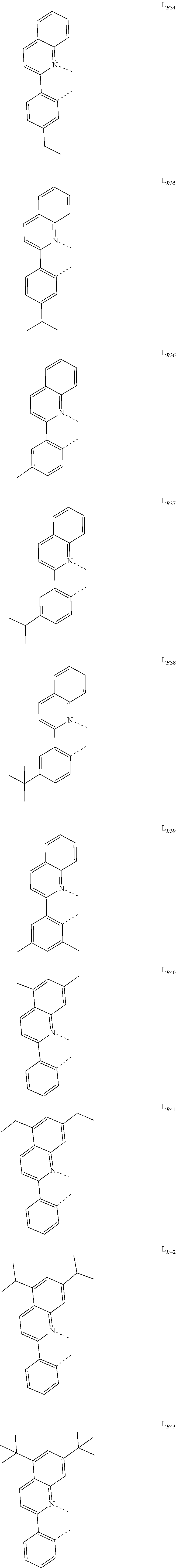

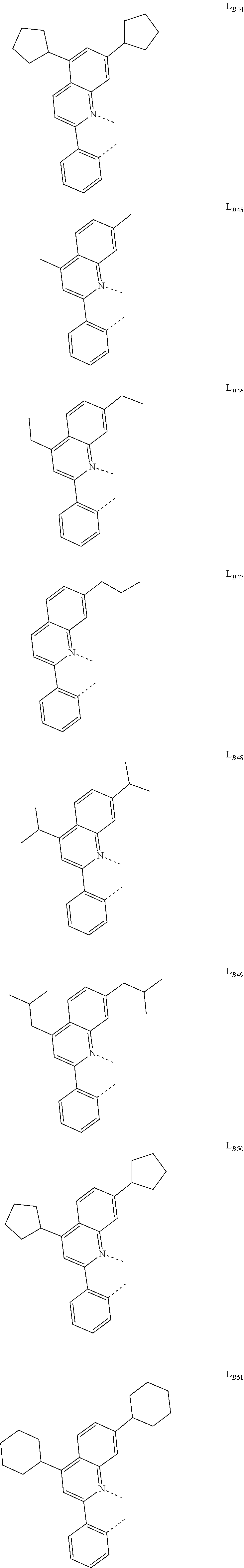

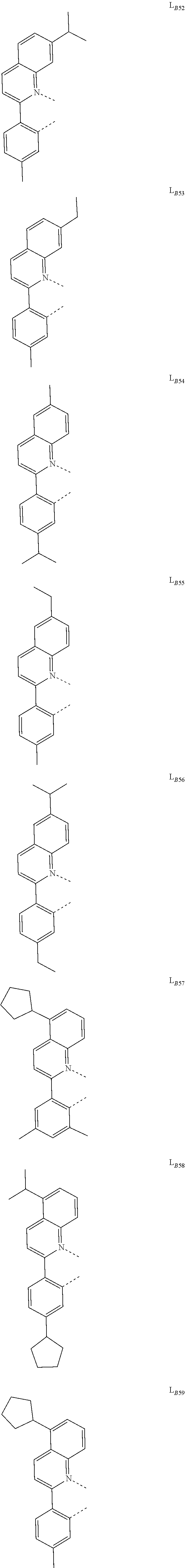

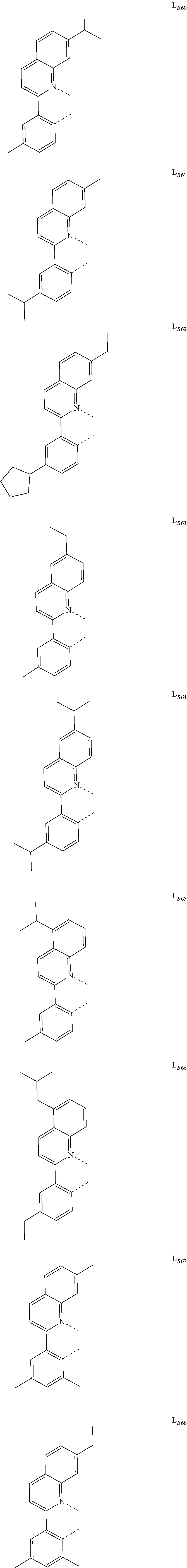

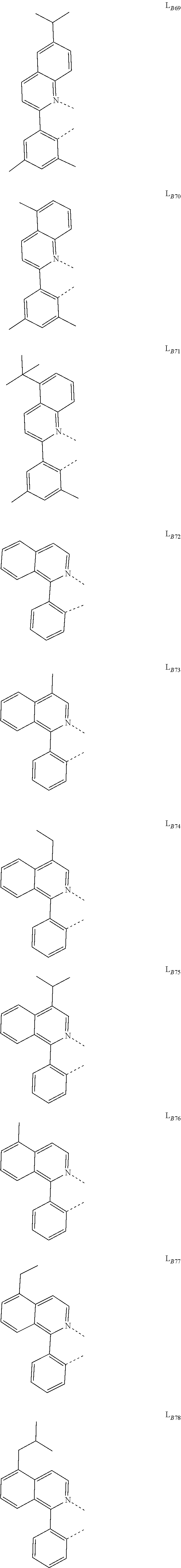

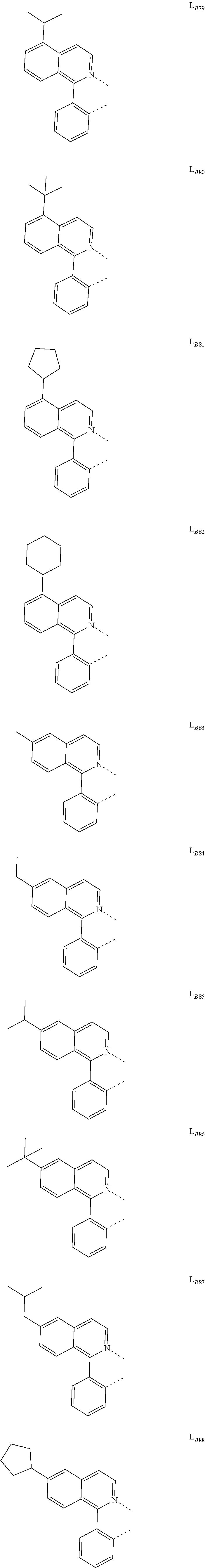

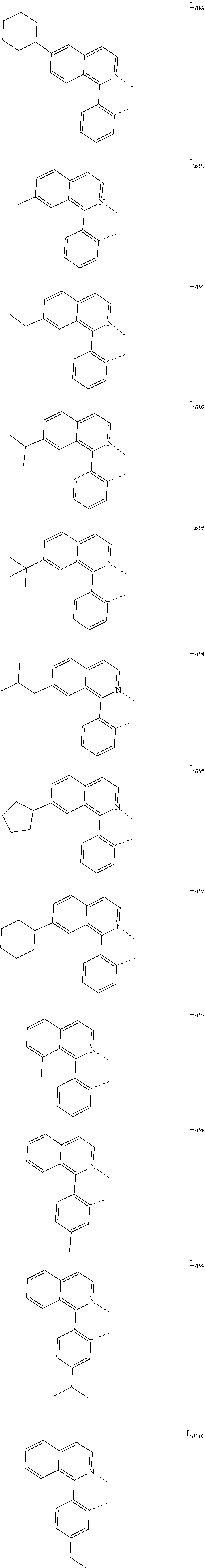

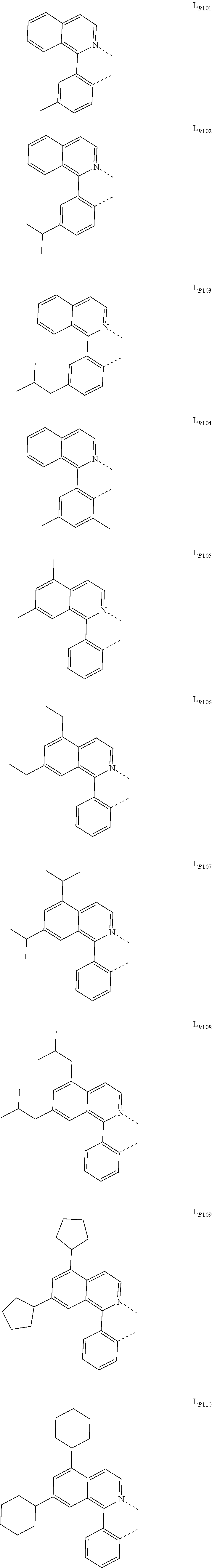

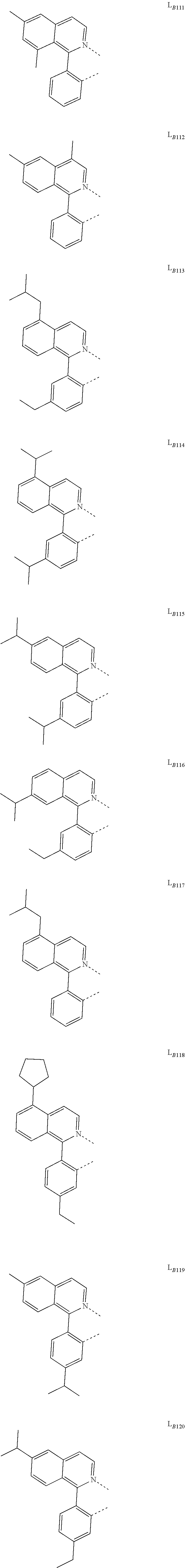

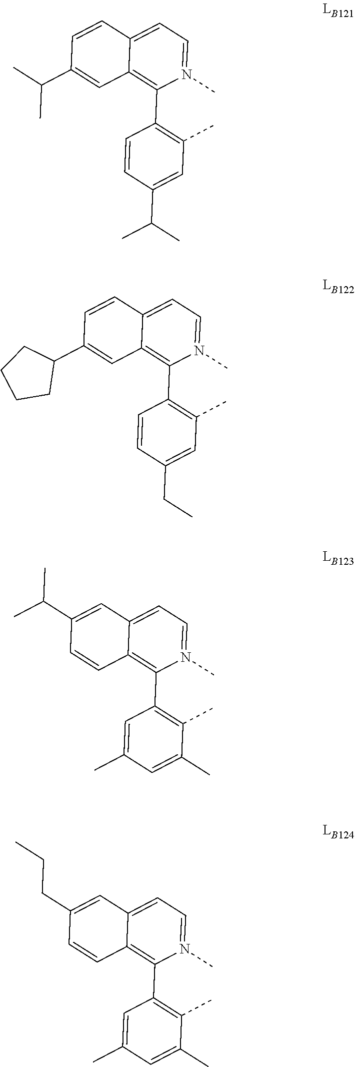

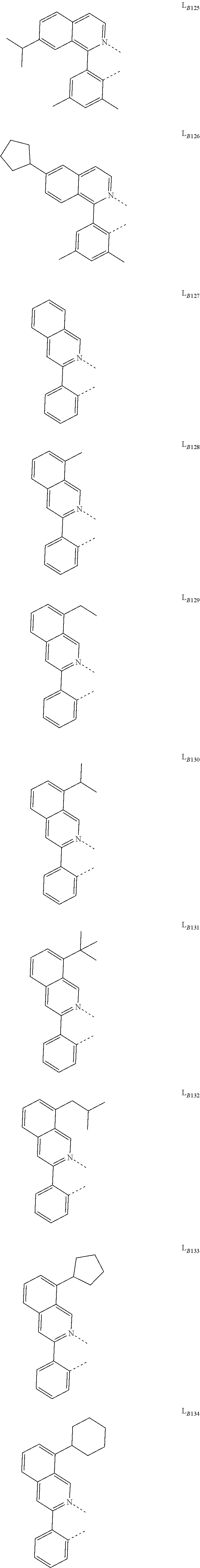

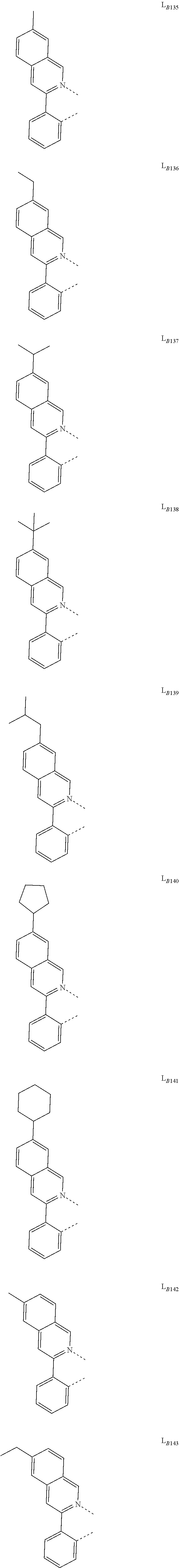

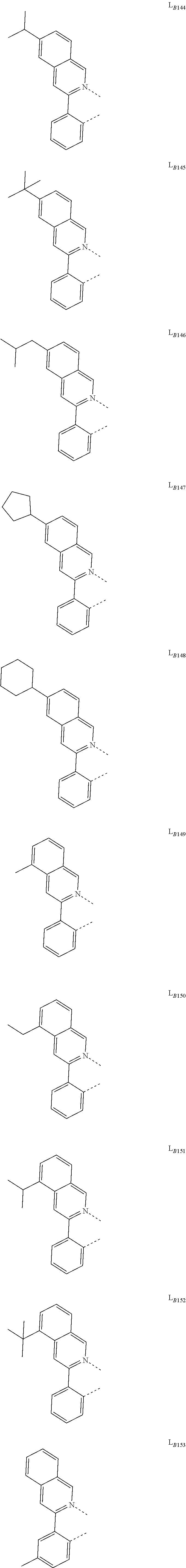

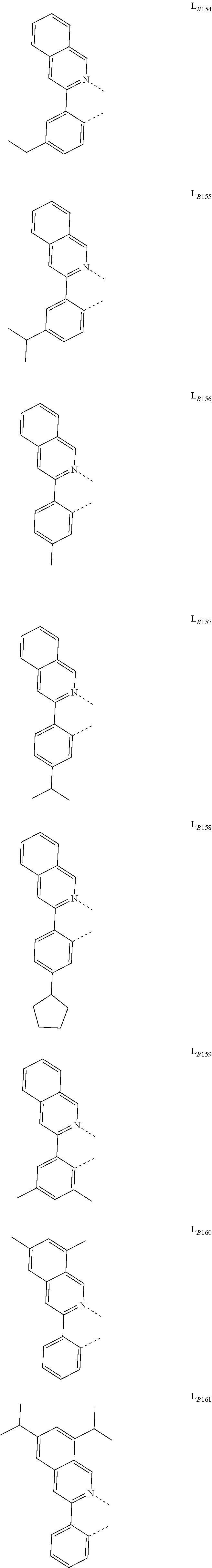

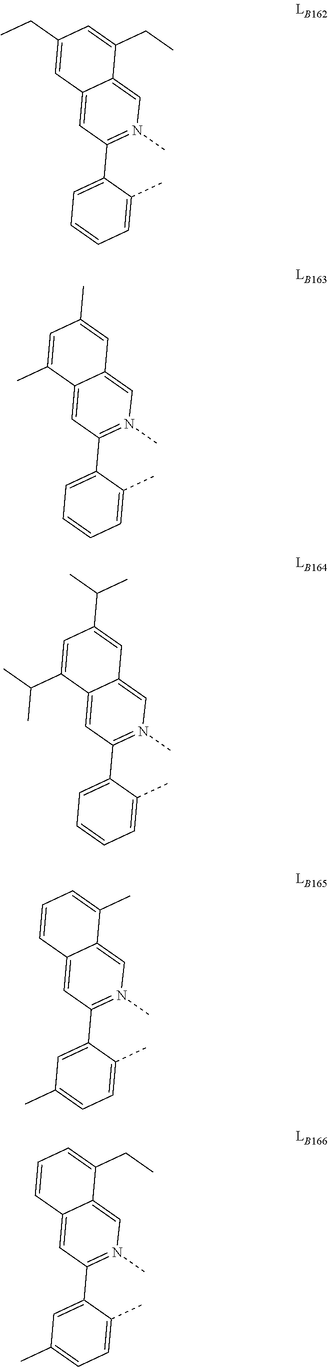

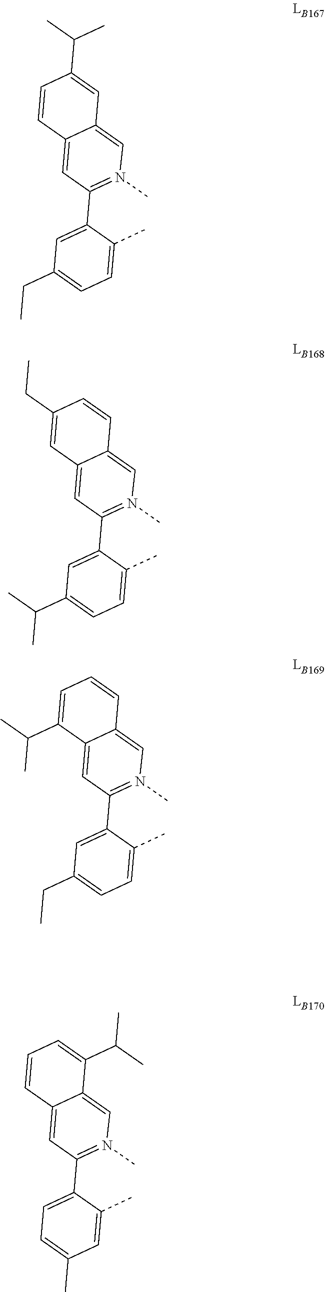

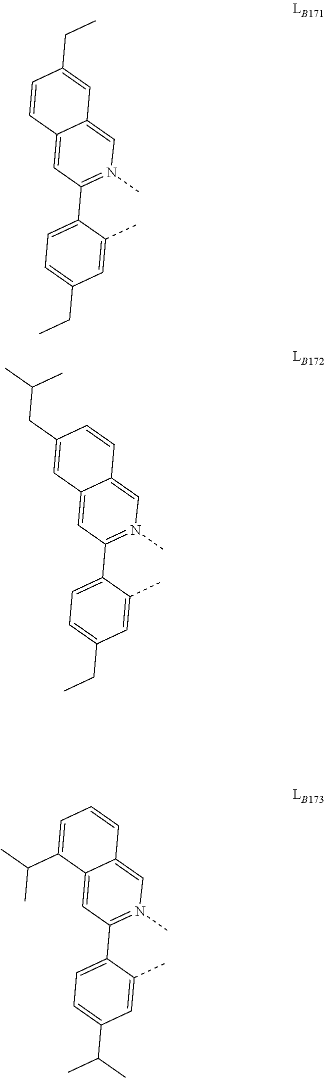

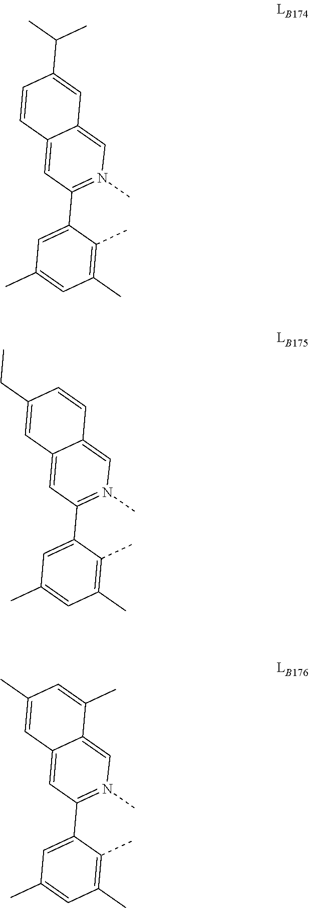

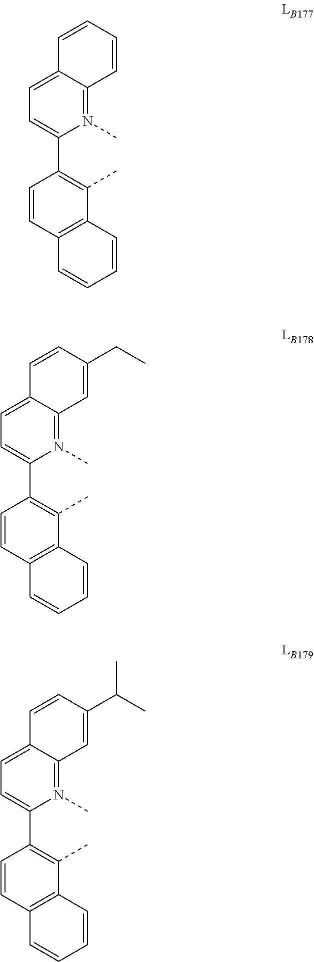

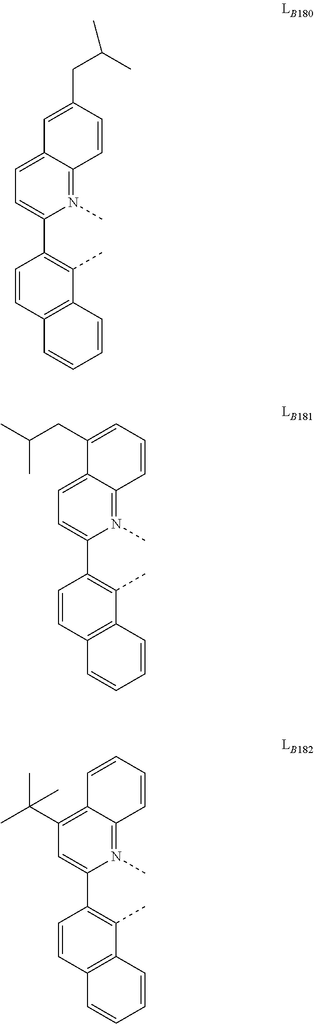

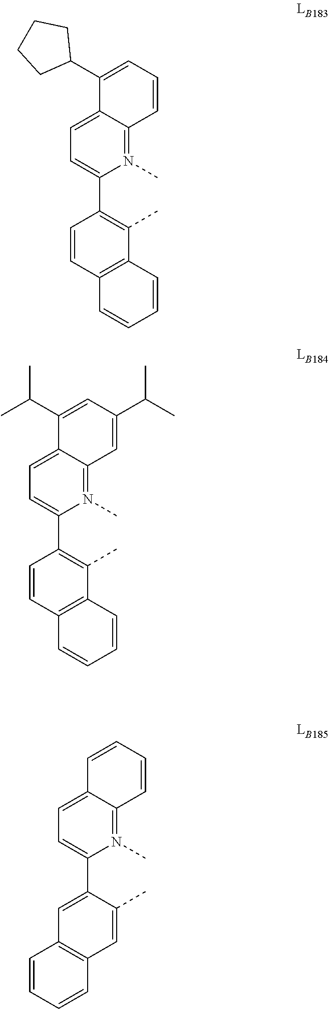

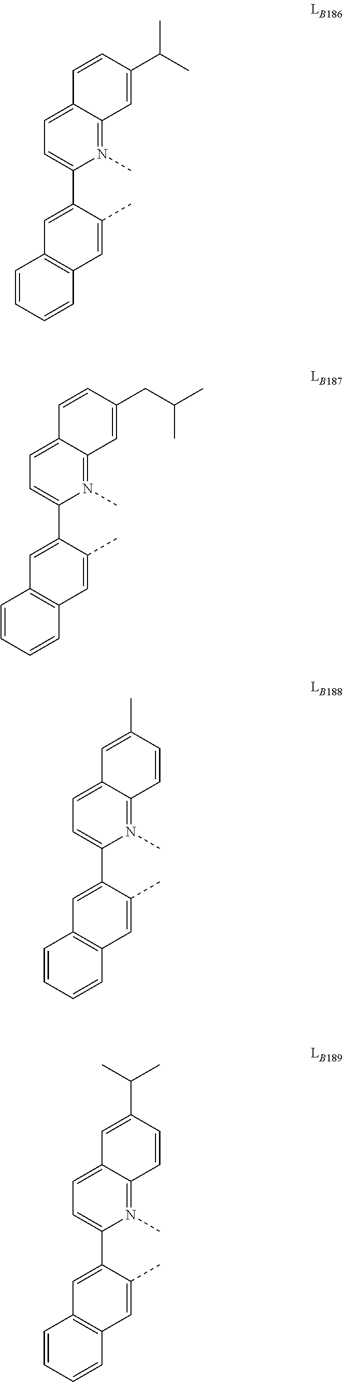

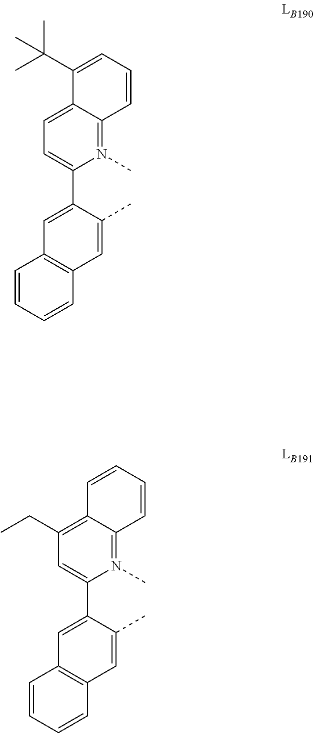

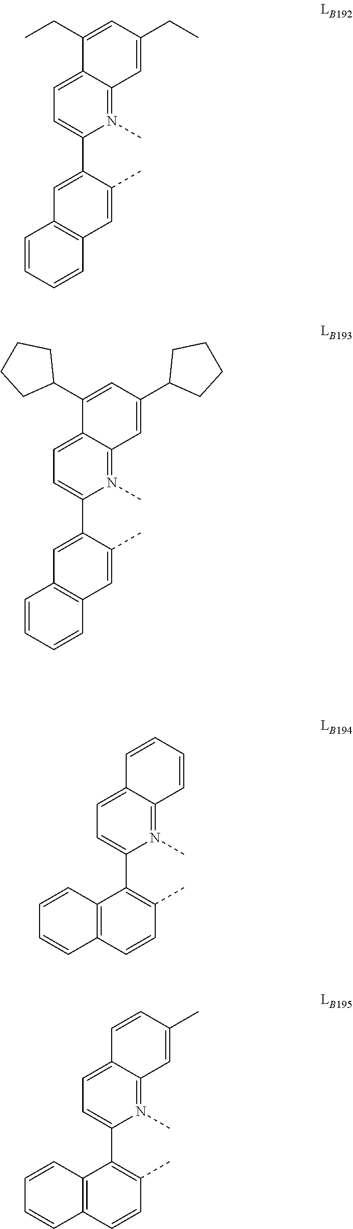

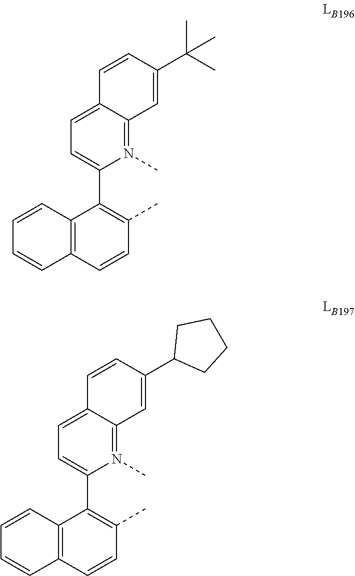

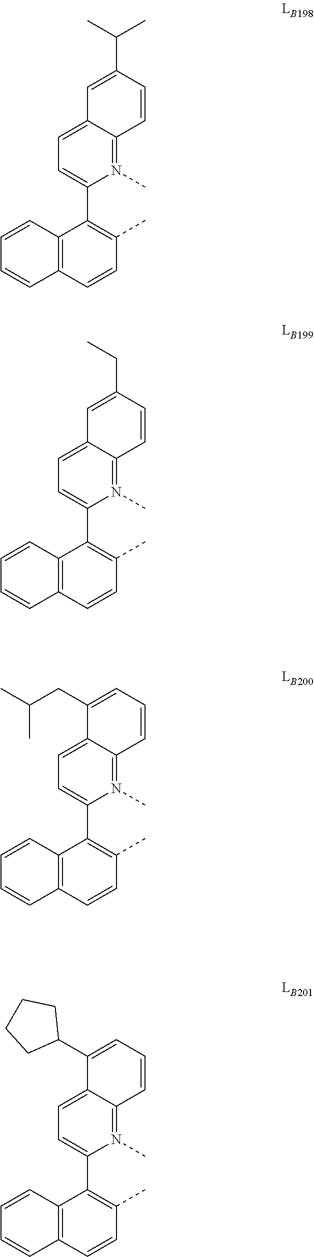

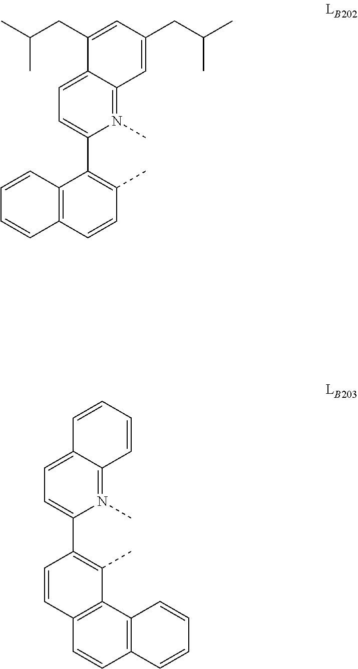

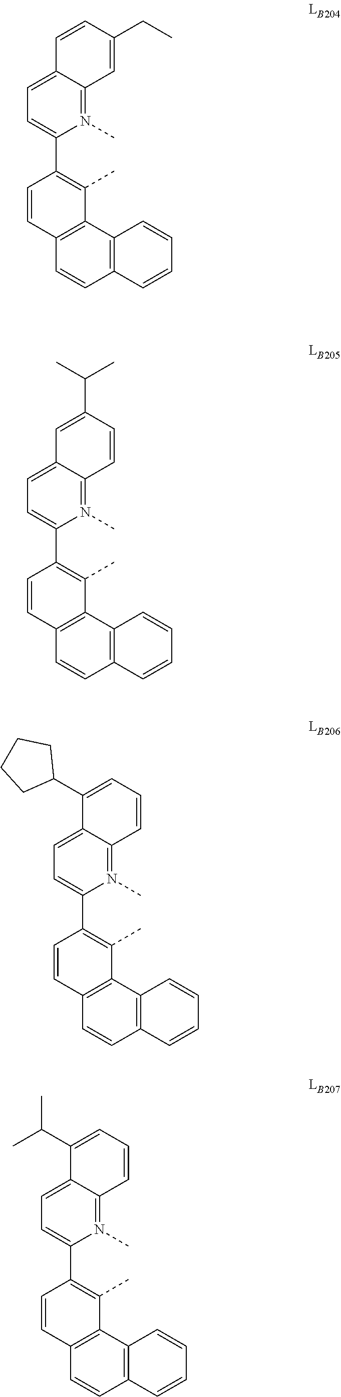

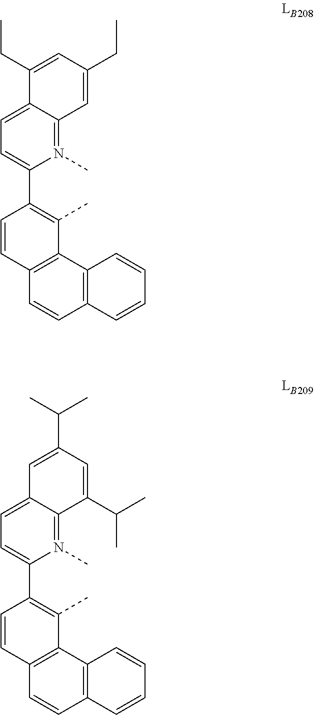

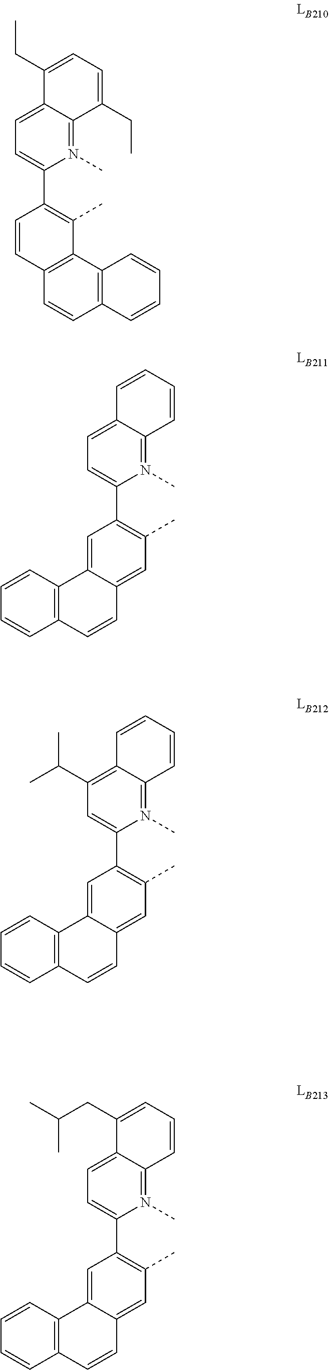

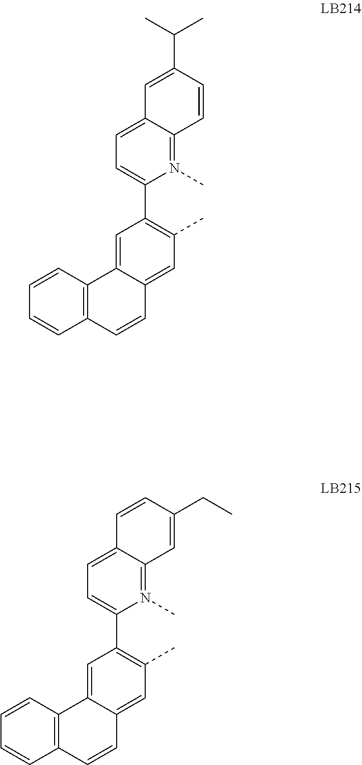

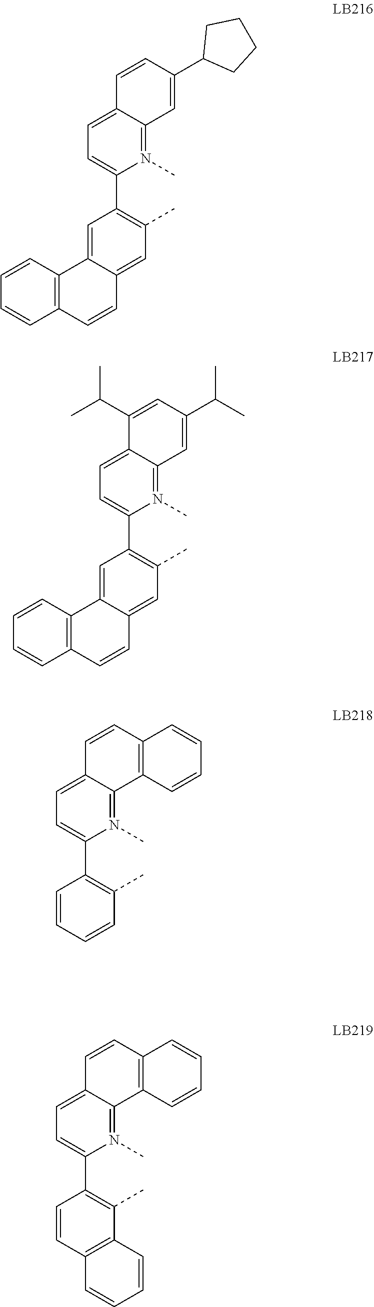

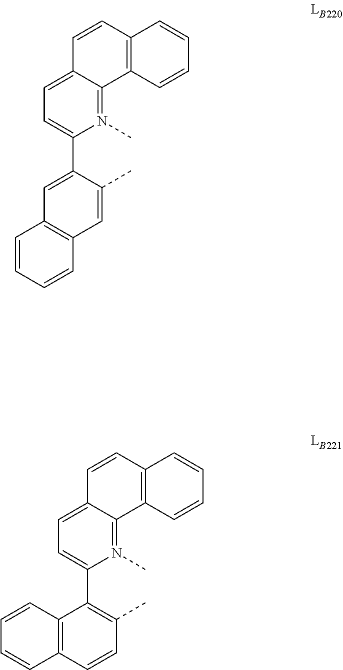

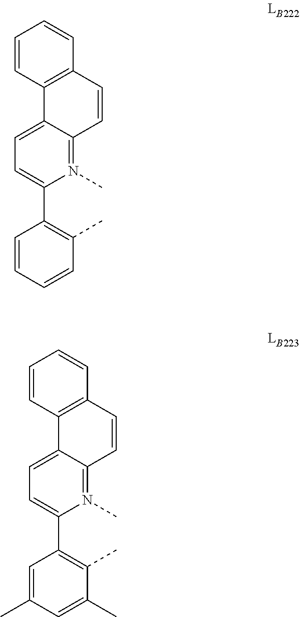

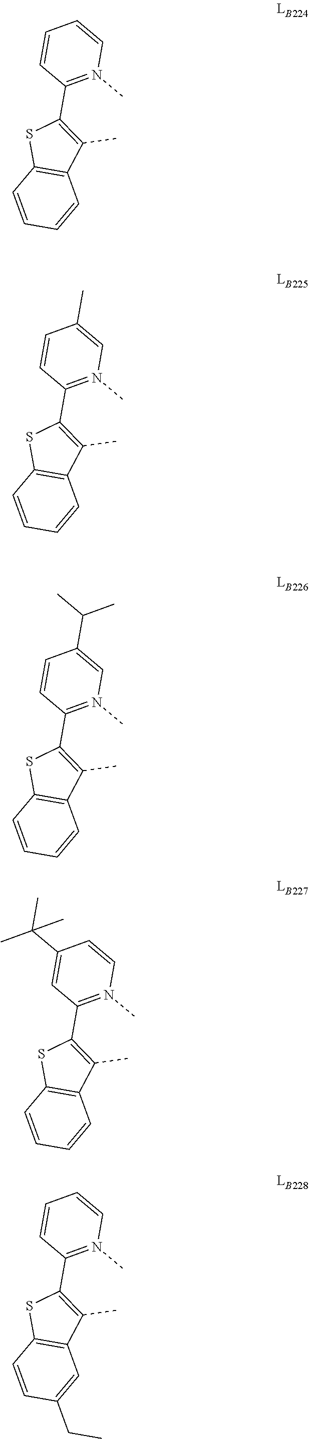

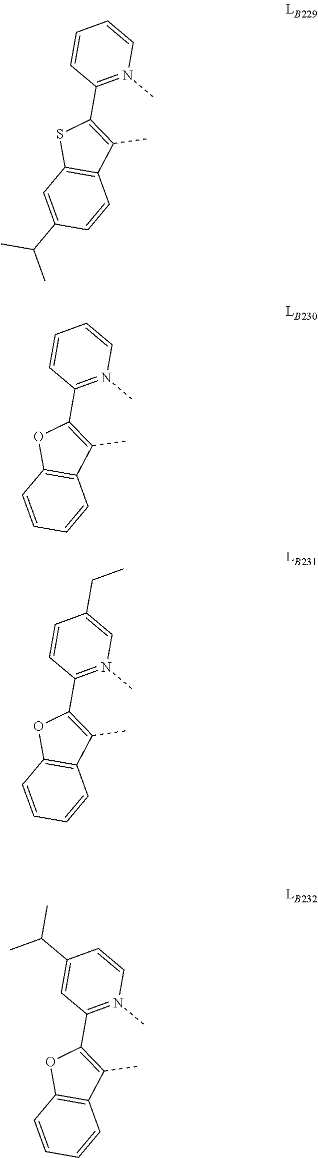

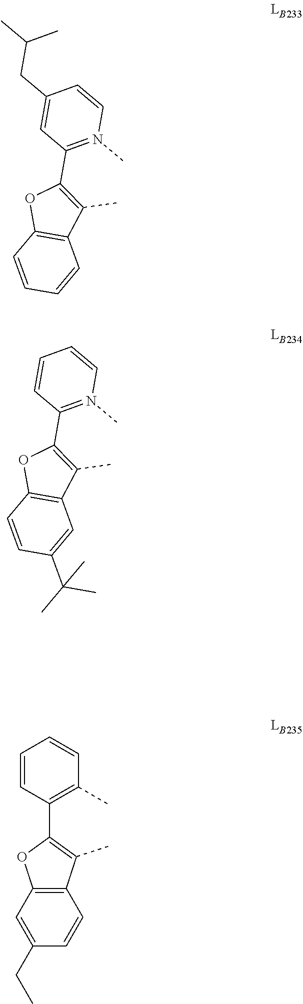

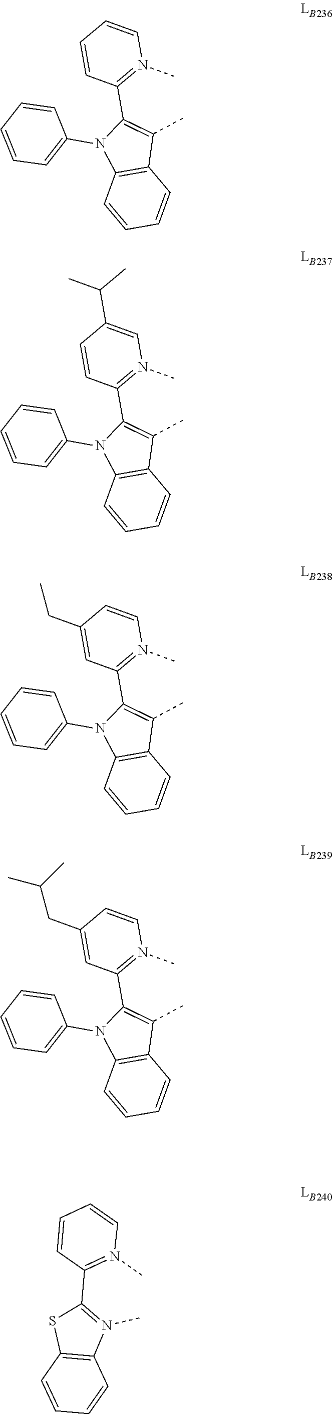

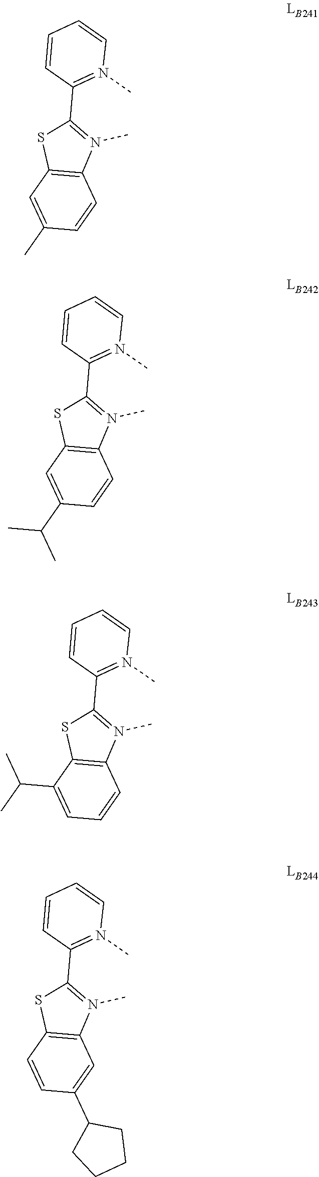

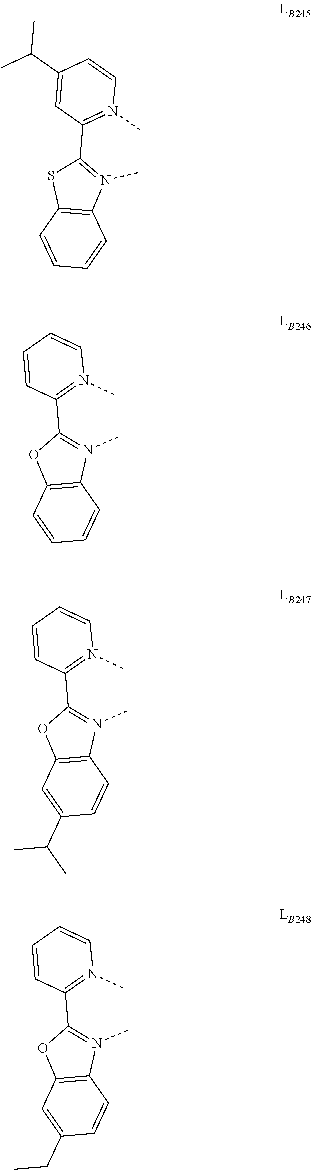

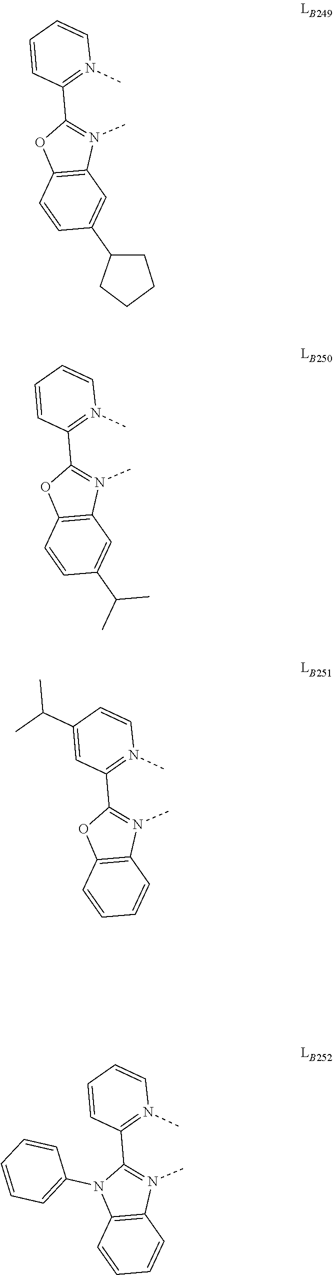

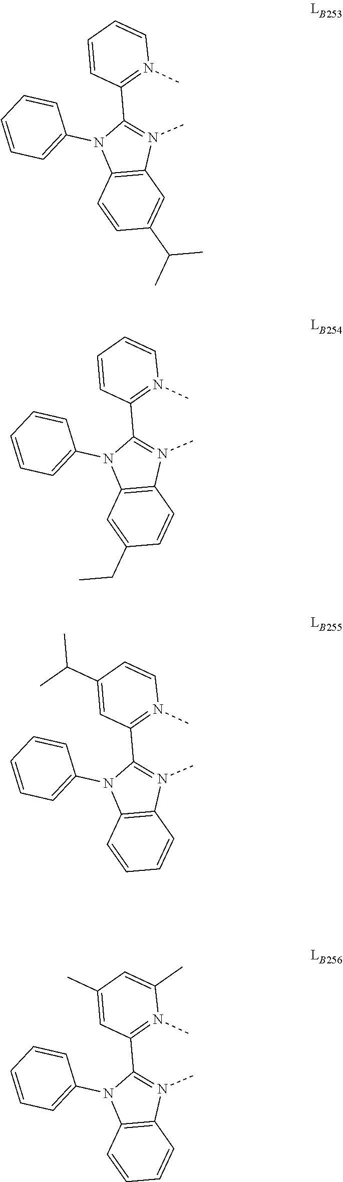

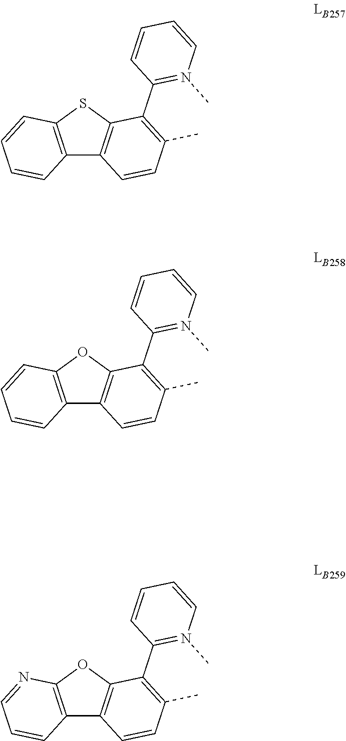

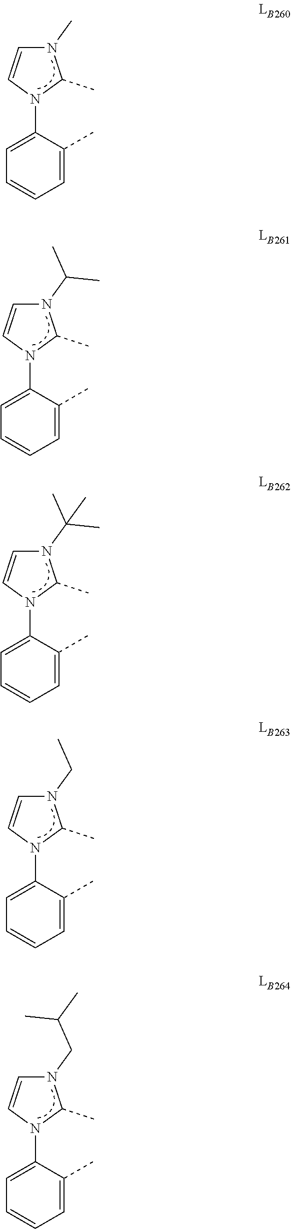

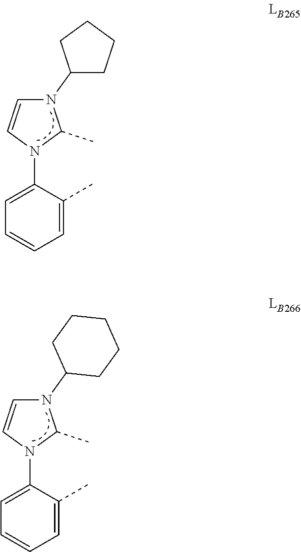

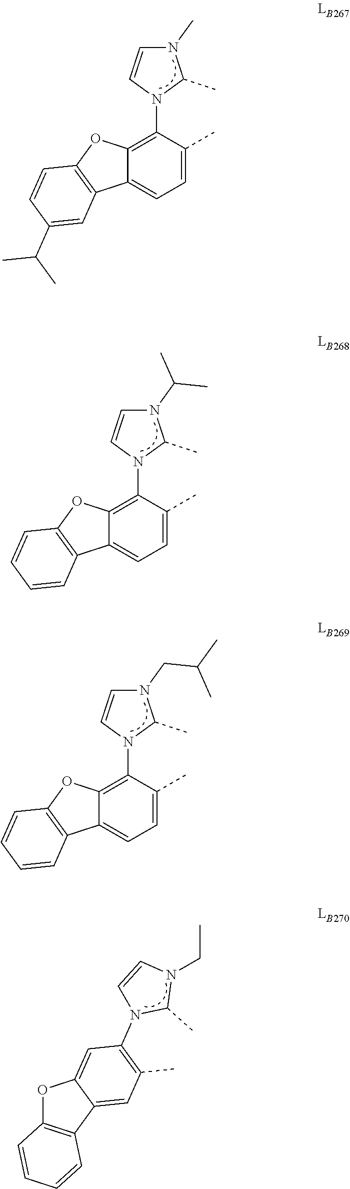

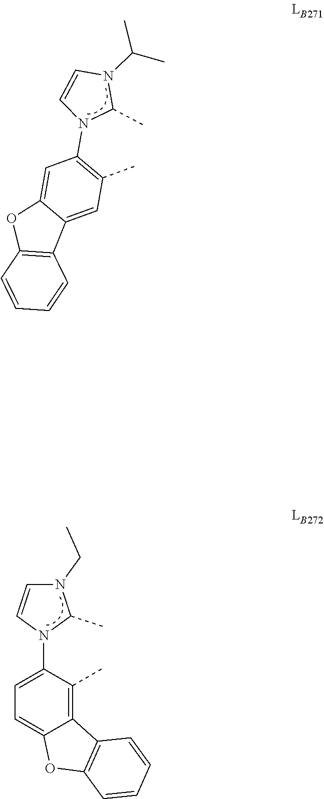

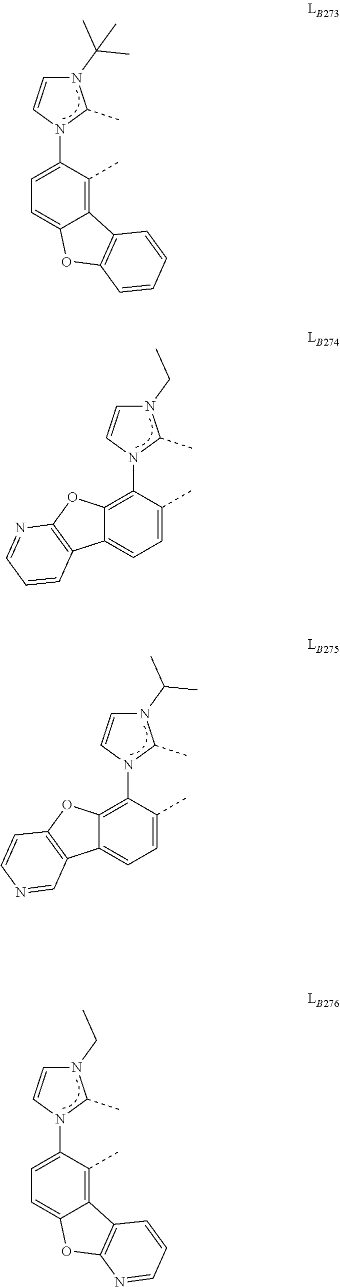

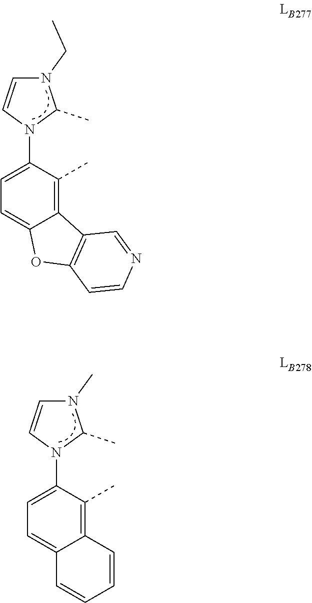

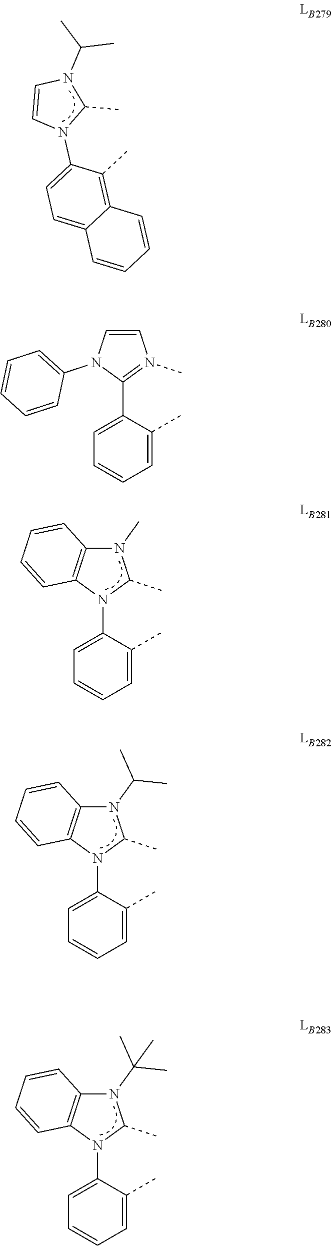

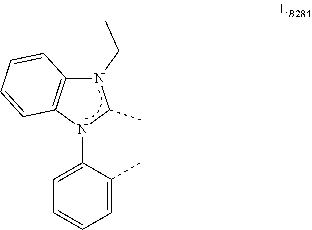

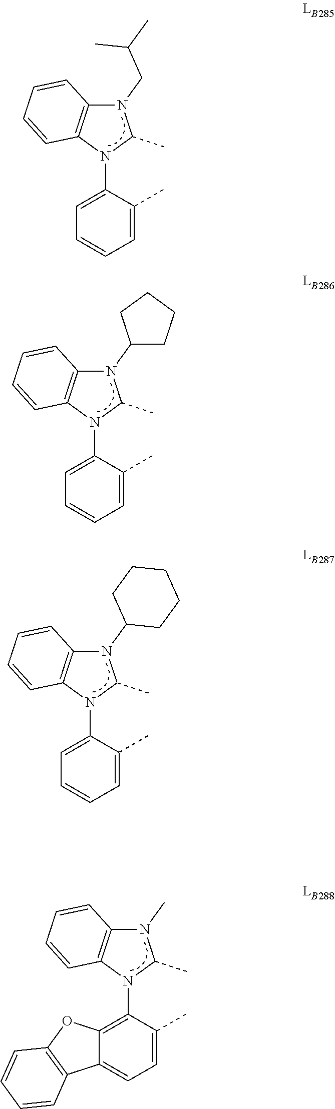

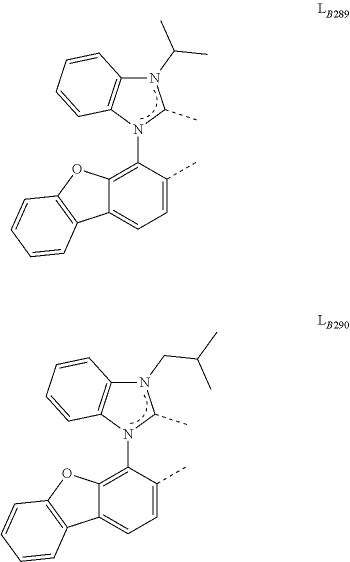

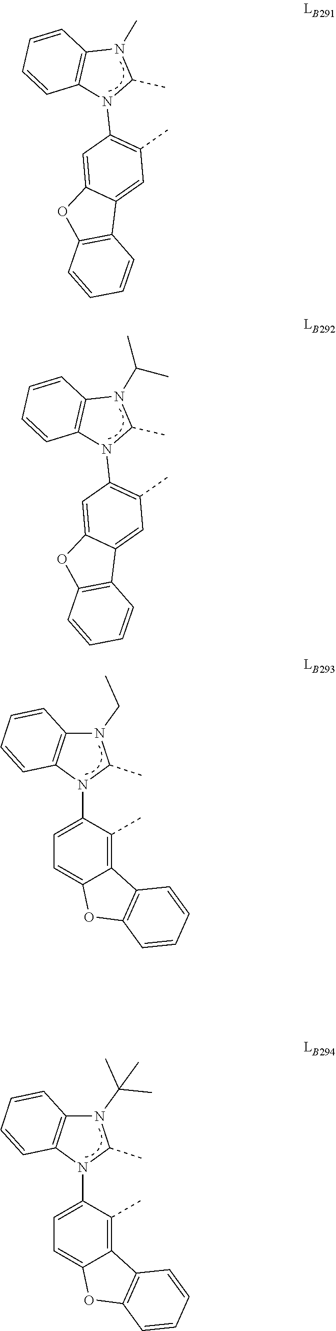

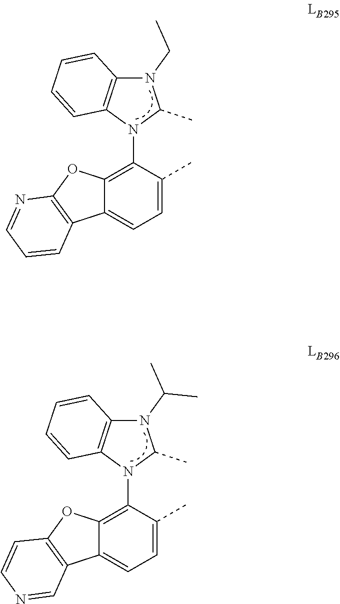

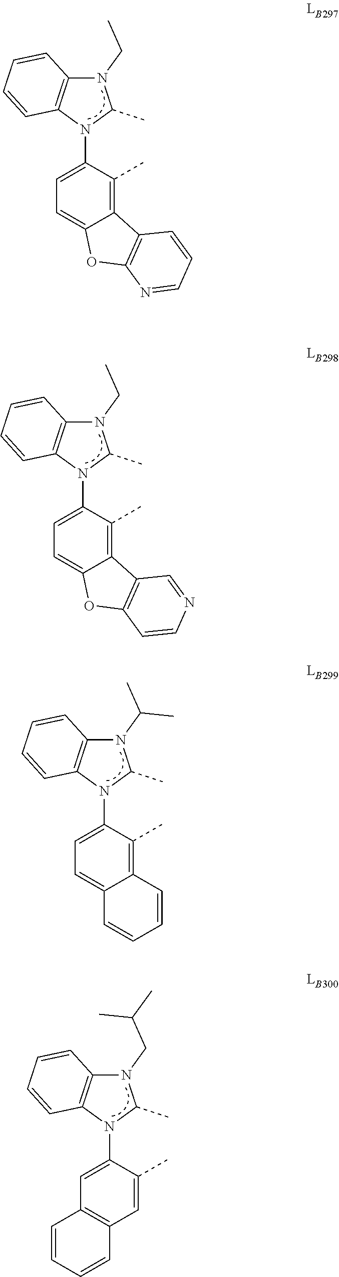

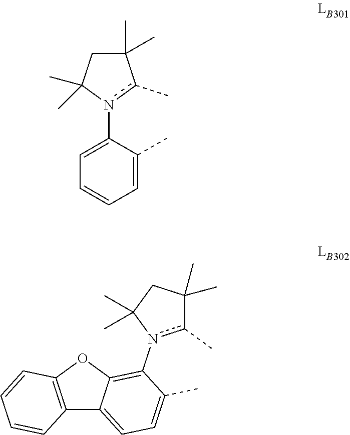

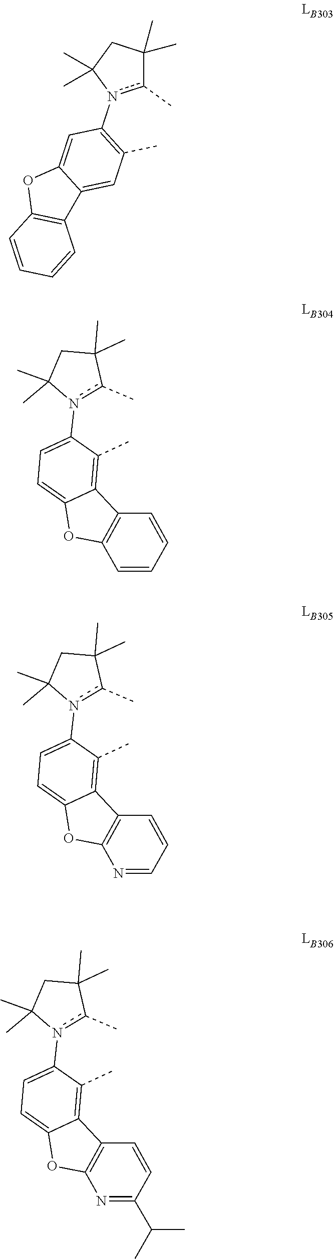

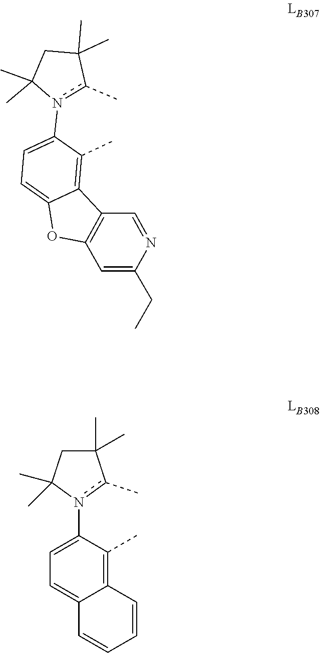

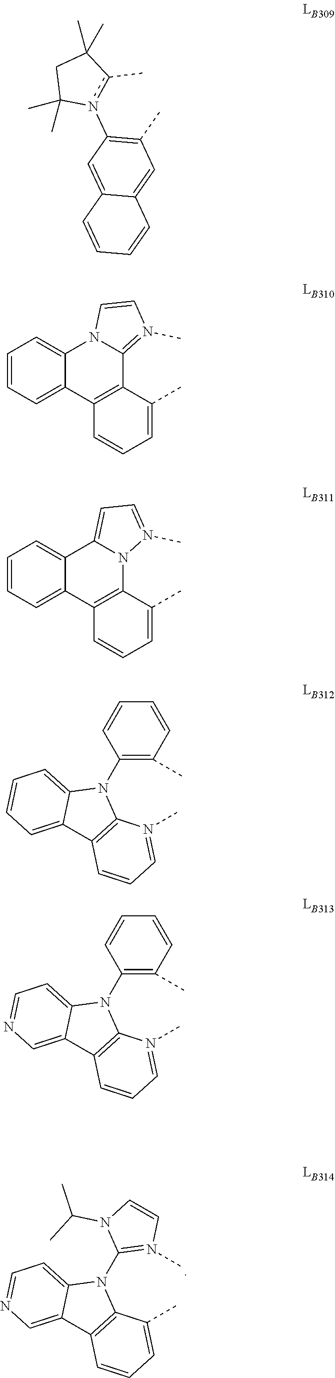

According to particularly preferred embodiments 1-6, the structures represented by Ir(L_{A})(L_{B})₂ is selected from the group consisting of the following structures:

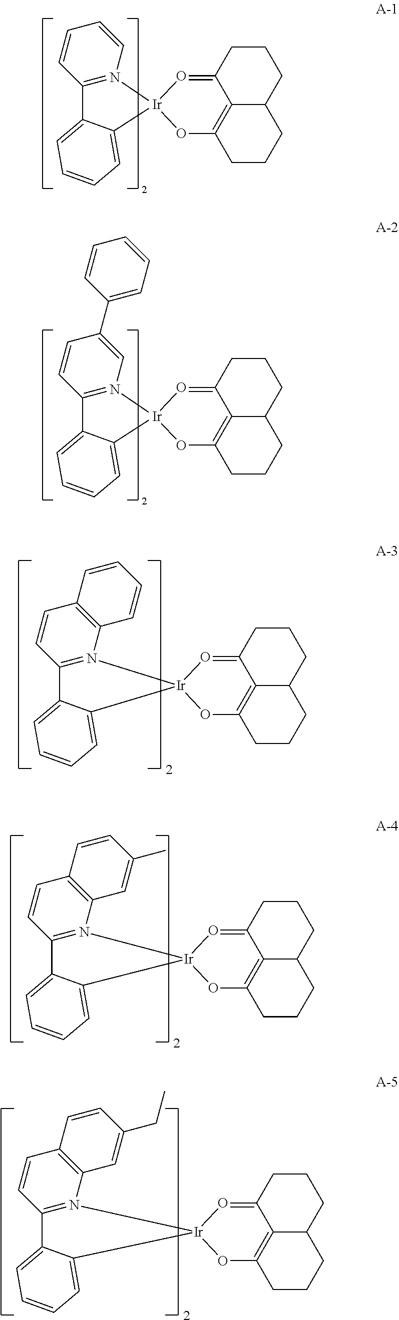

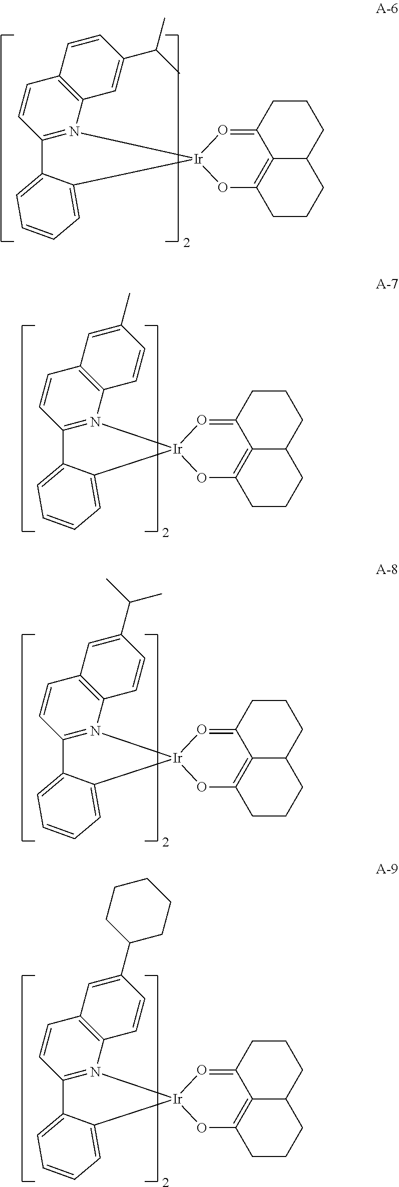

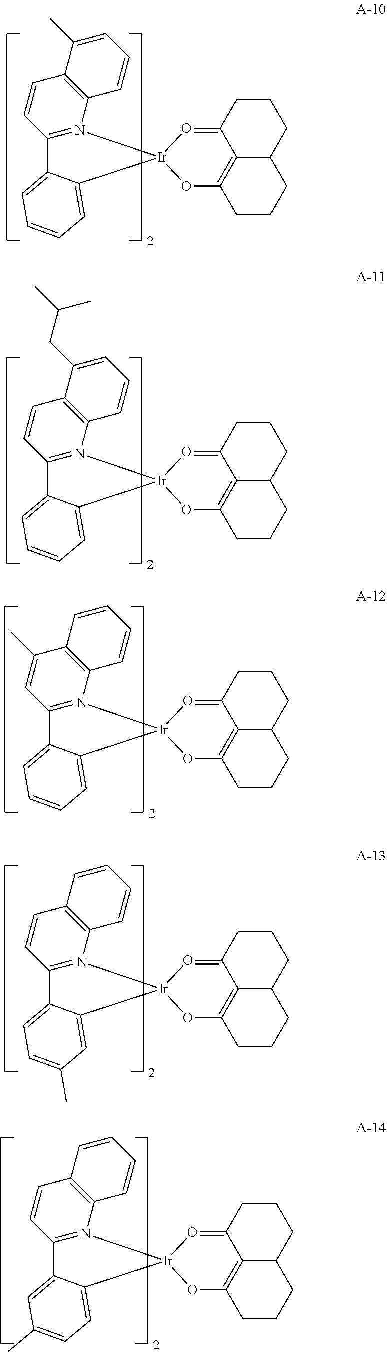

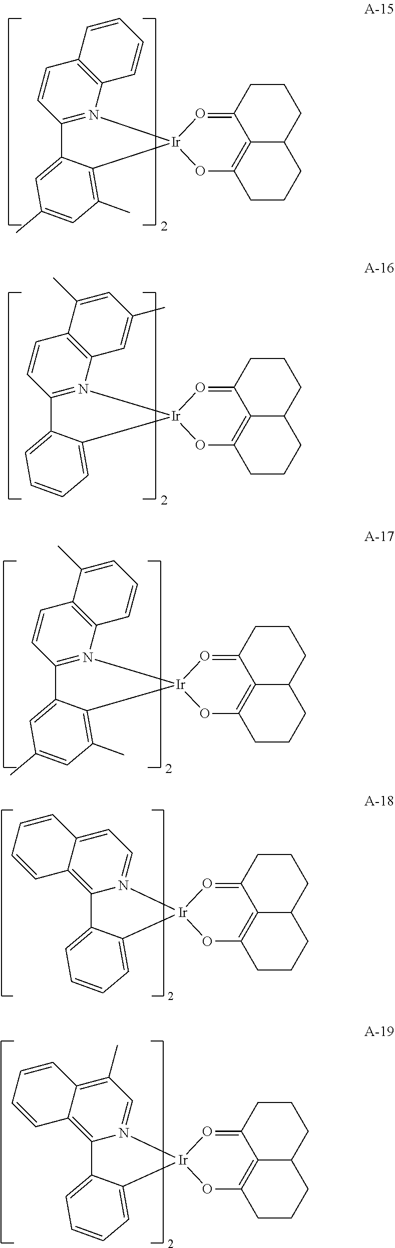

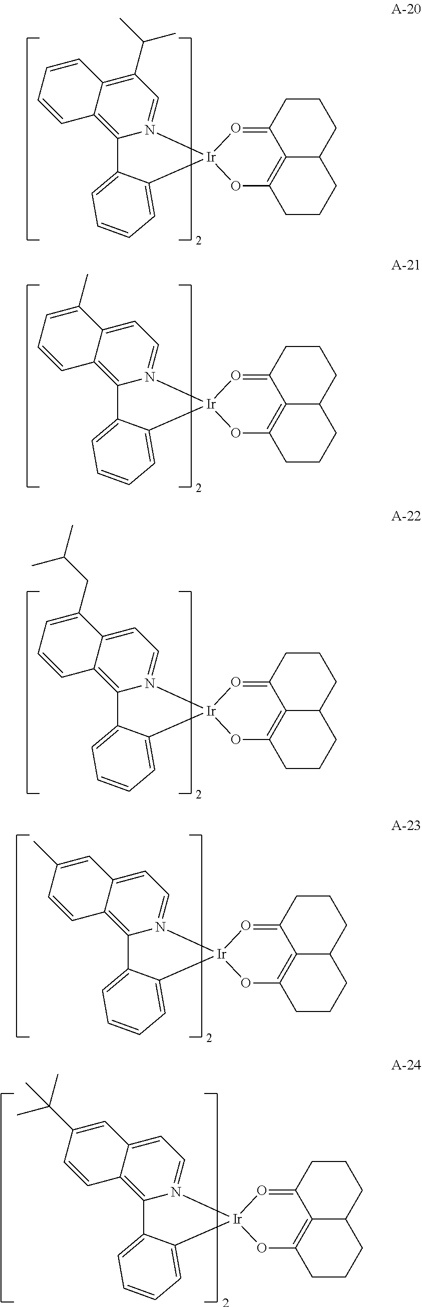

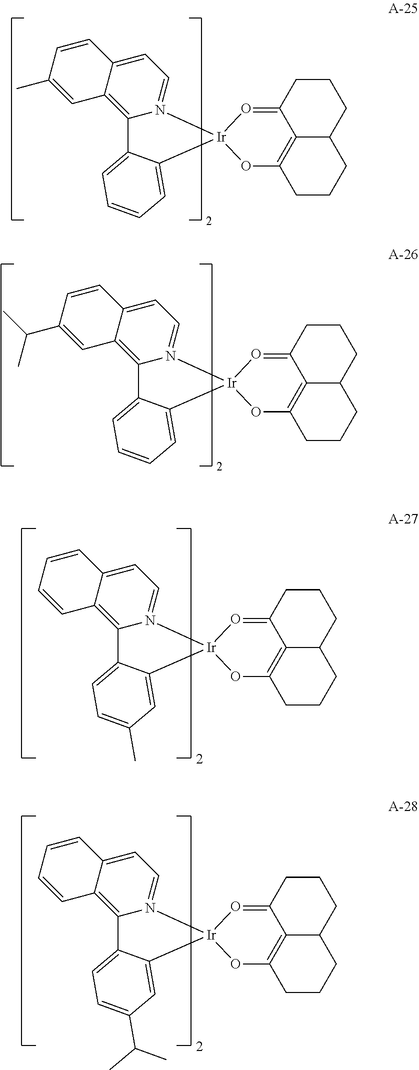

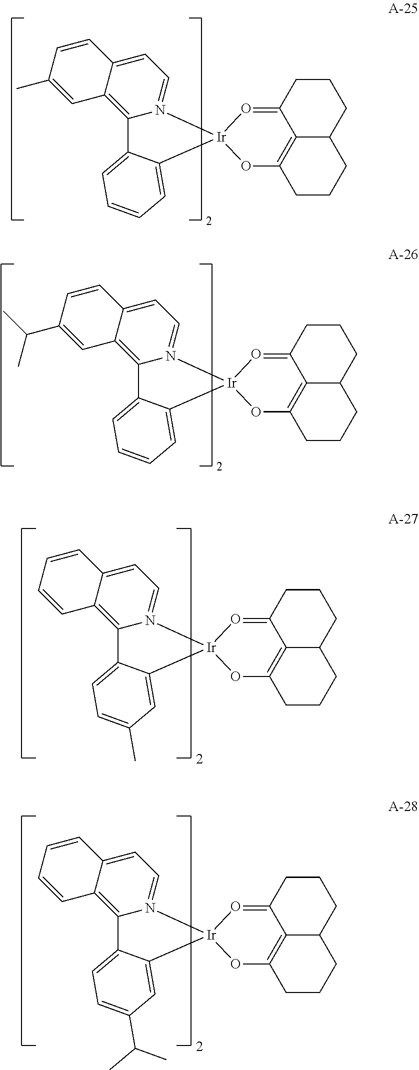

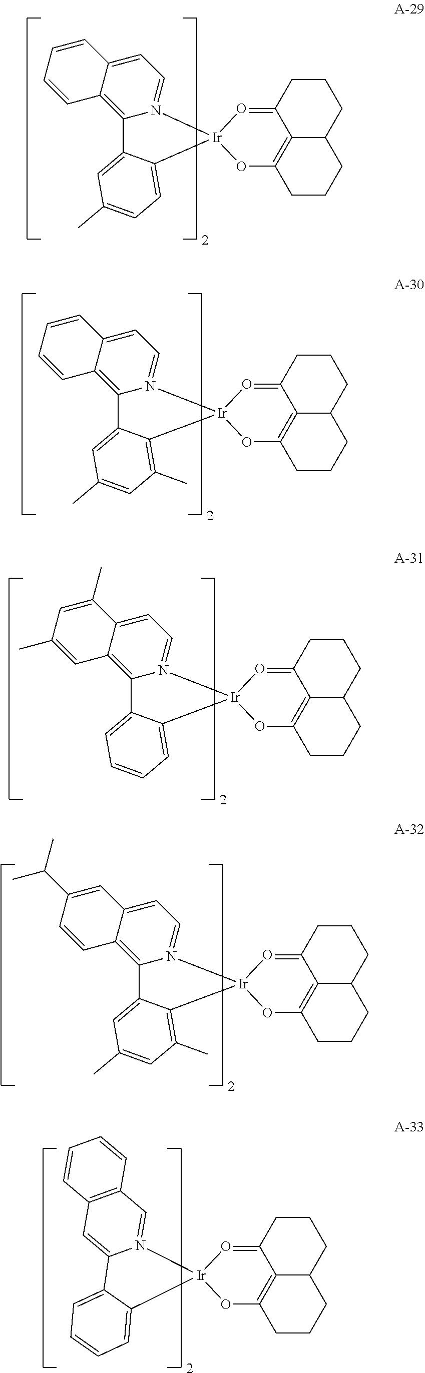

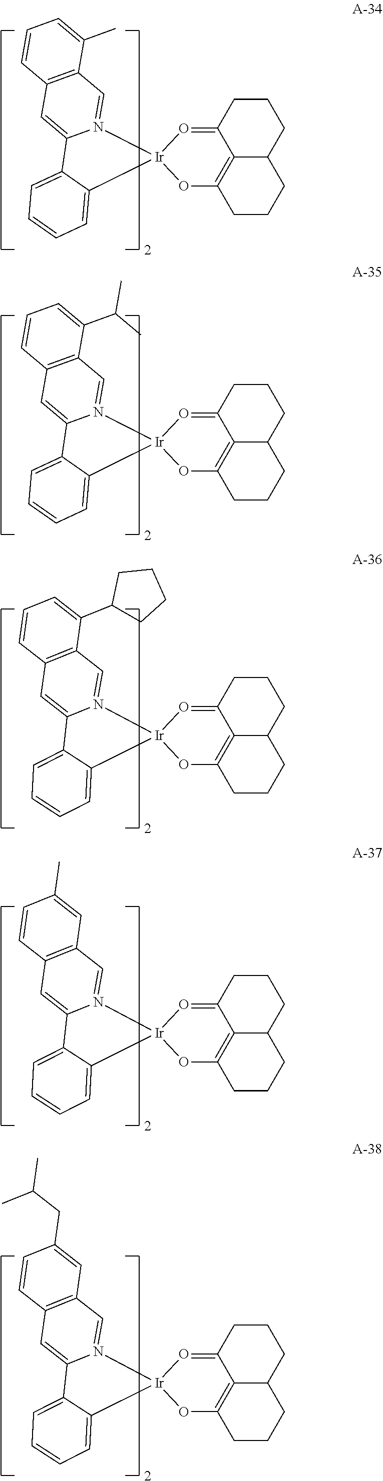

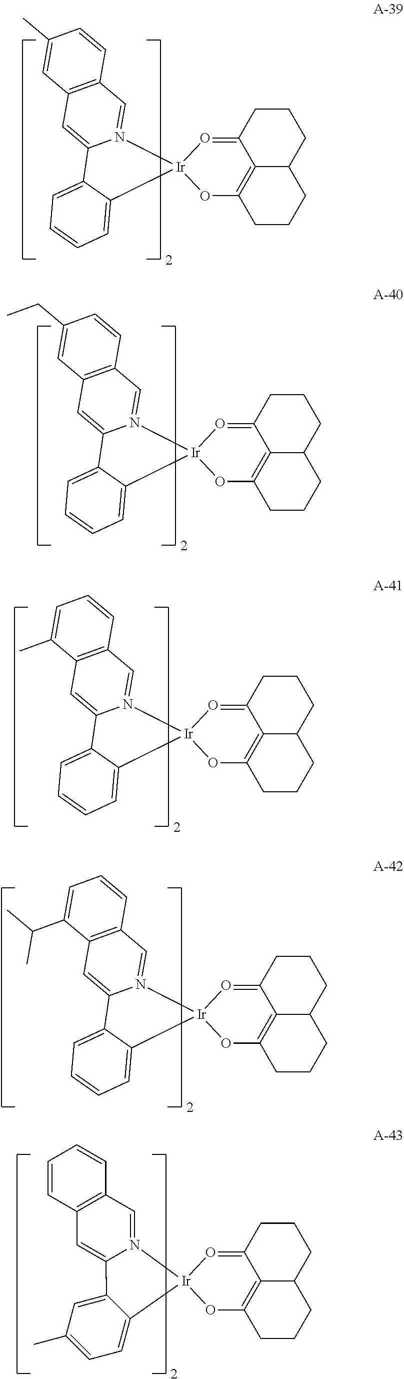

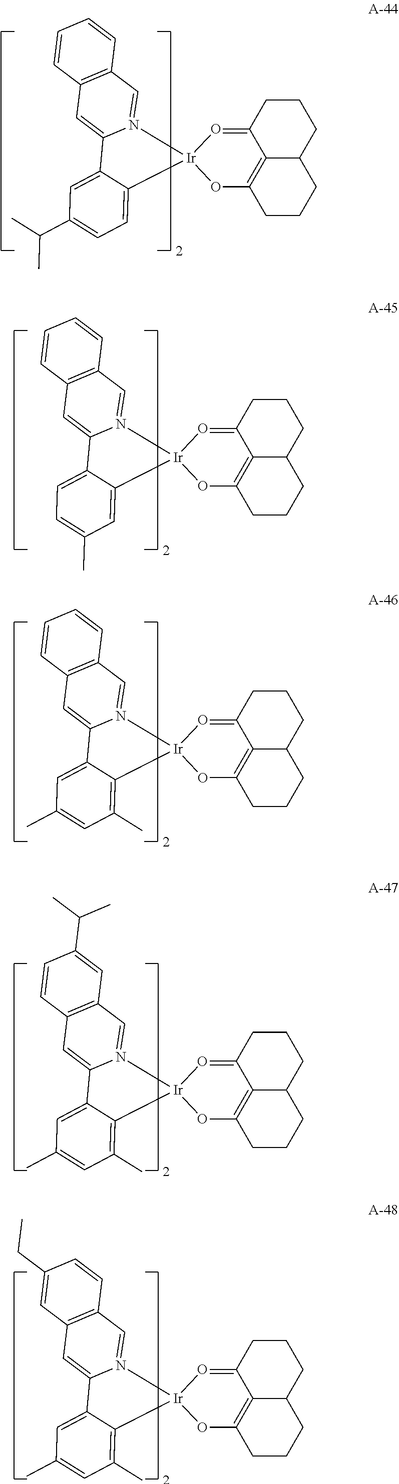

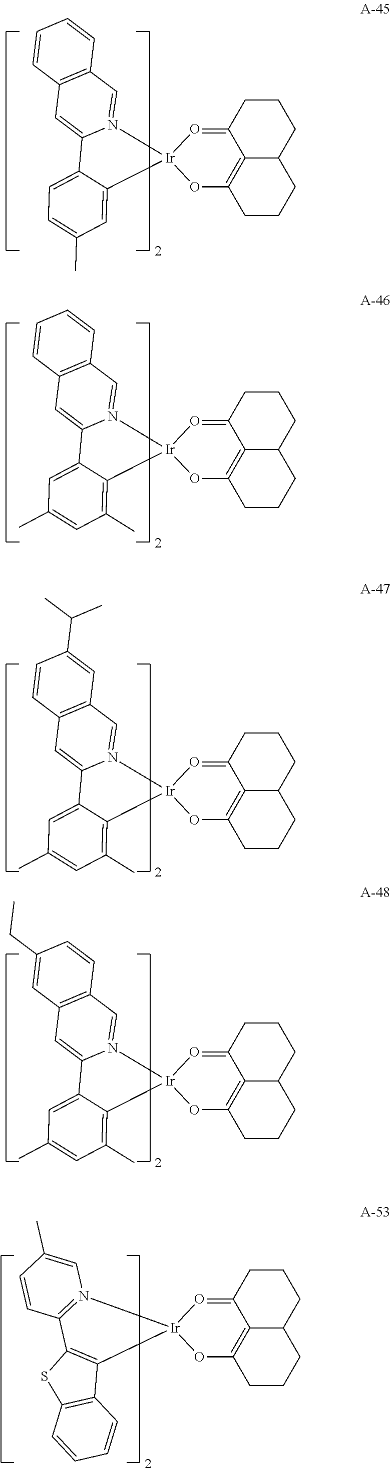

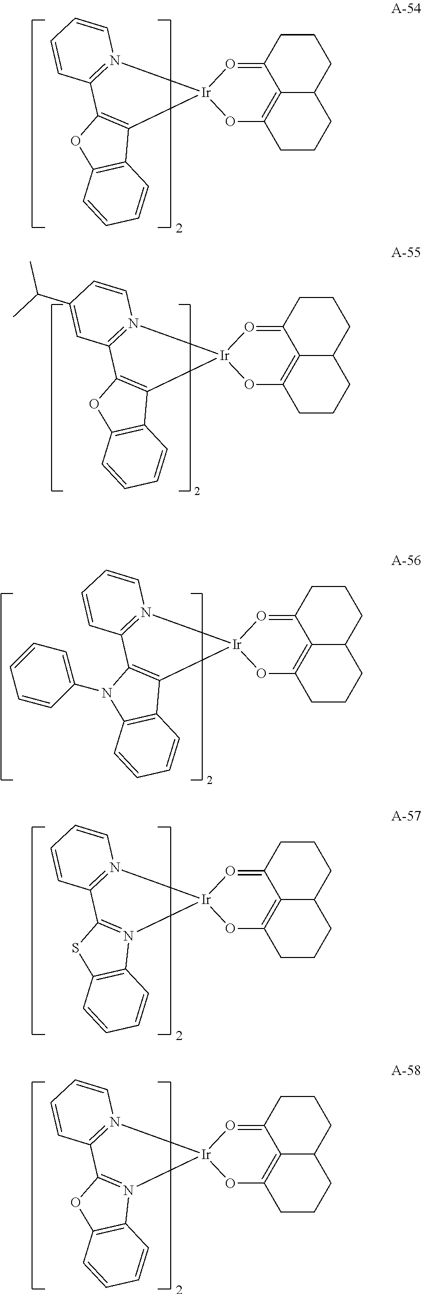

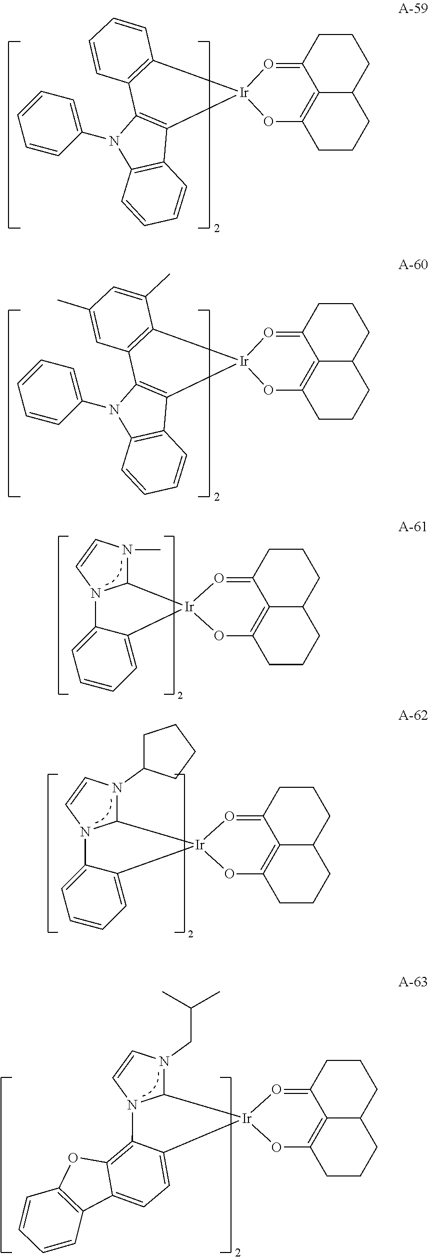

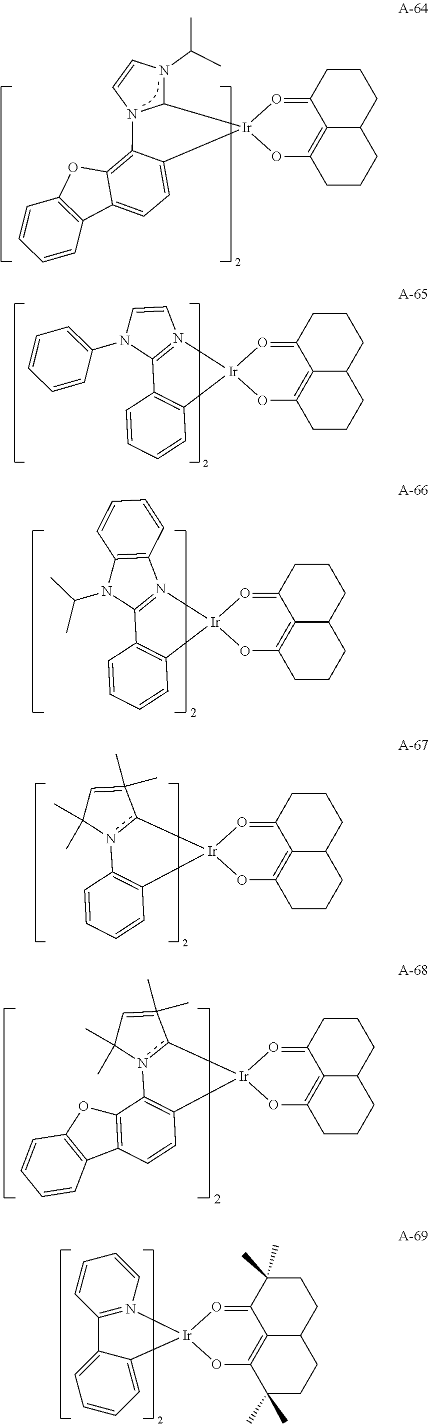

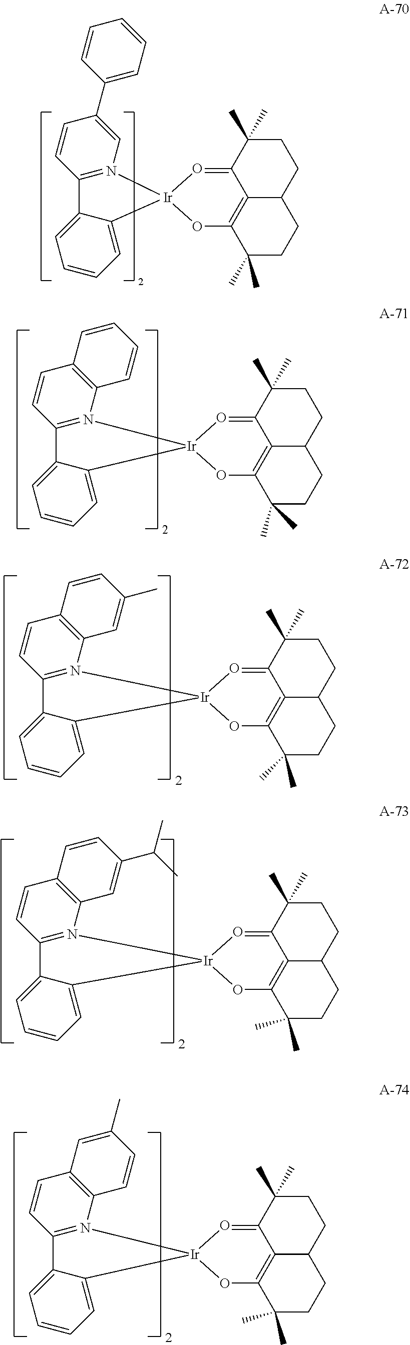

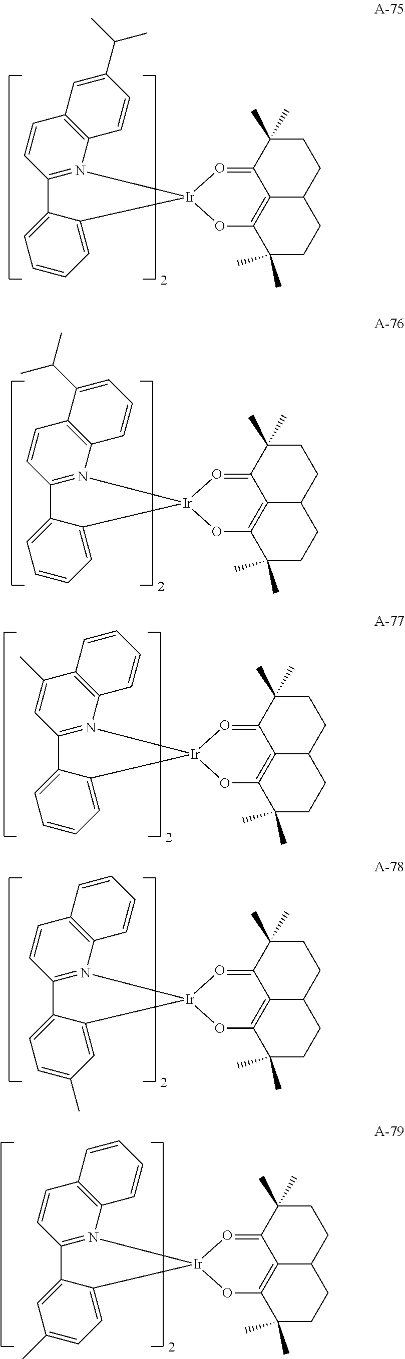

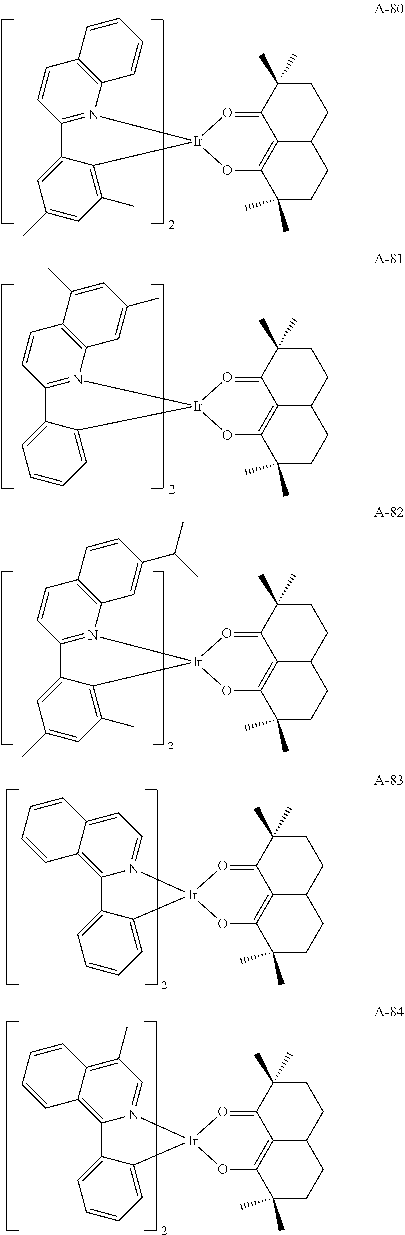

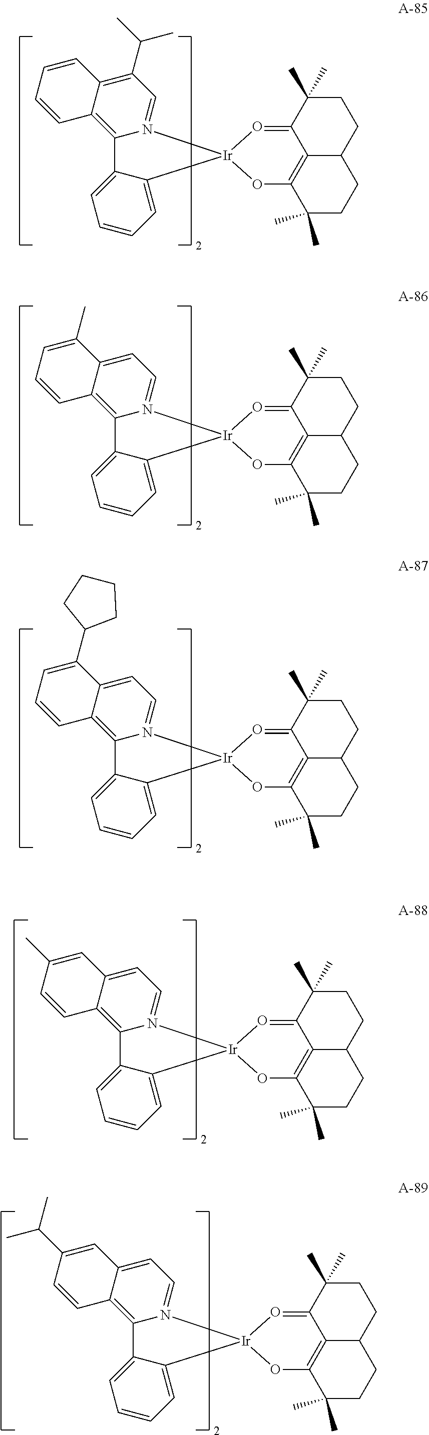

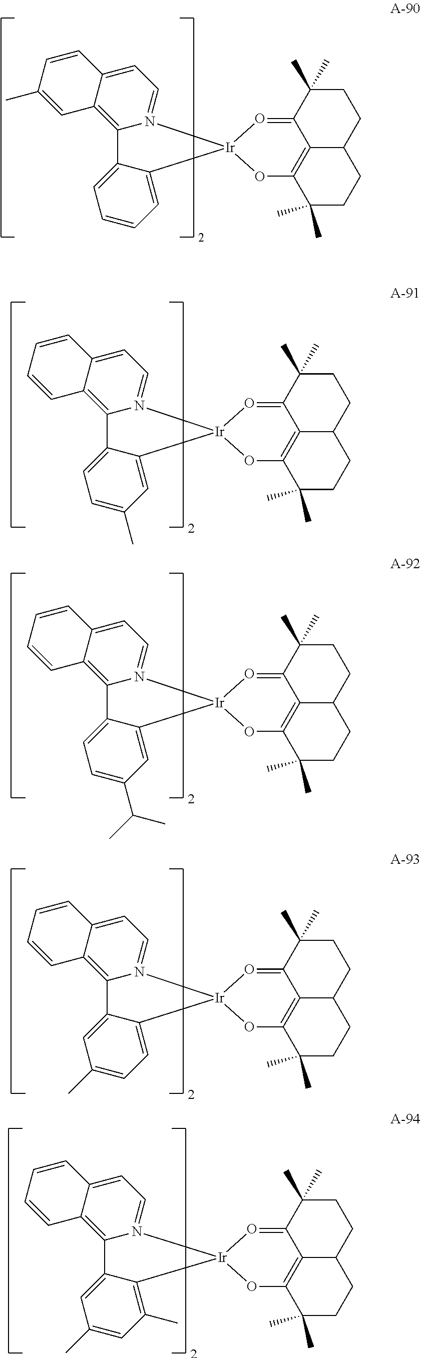

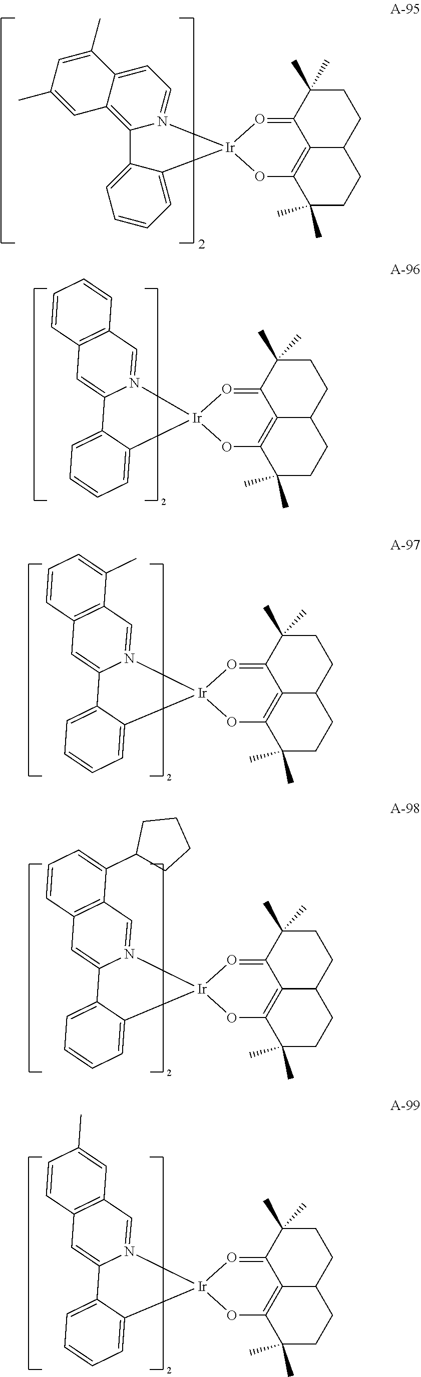

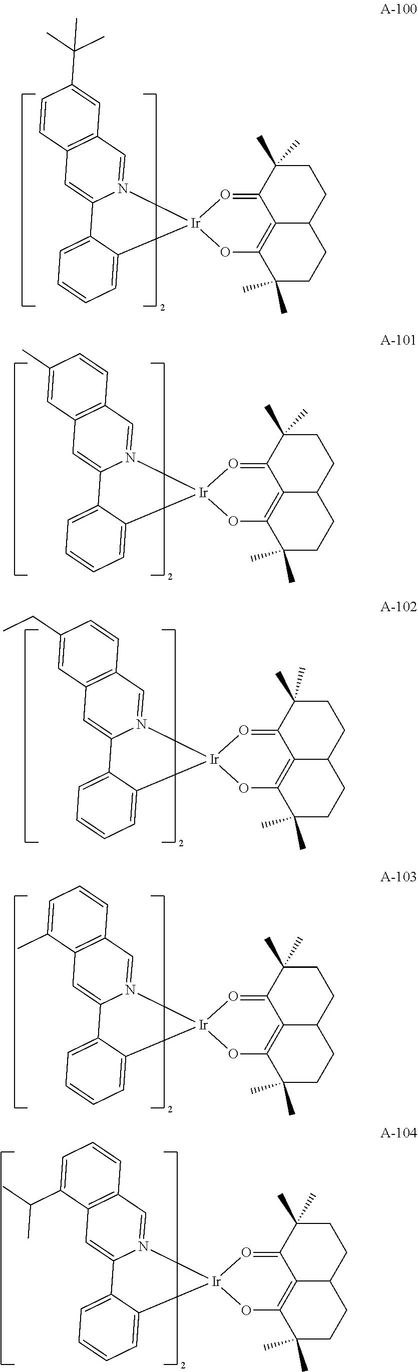

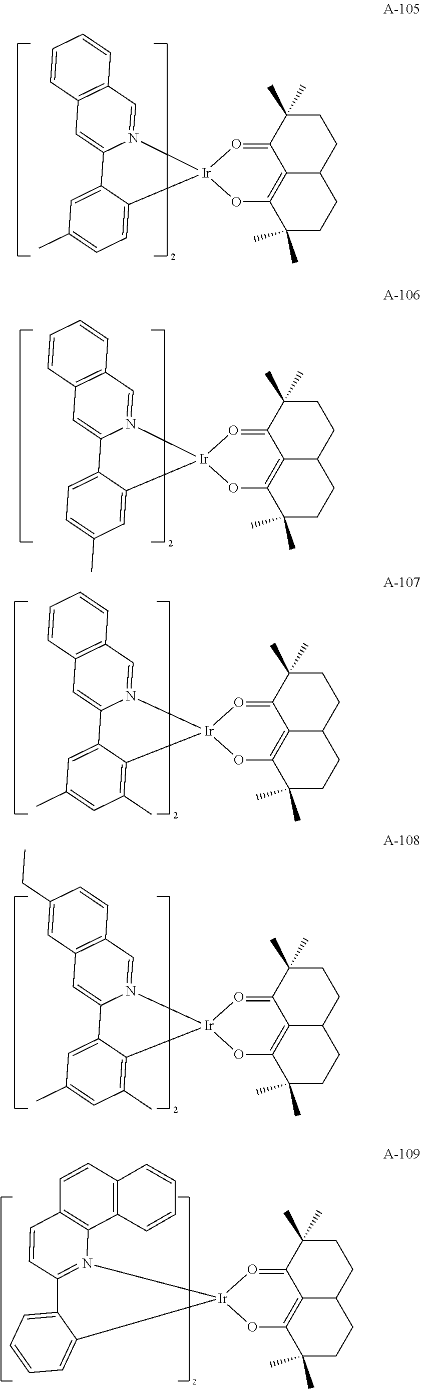

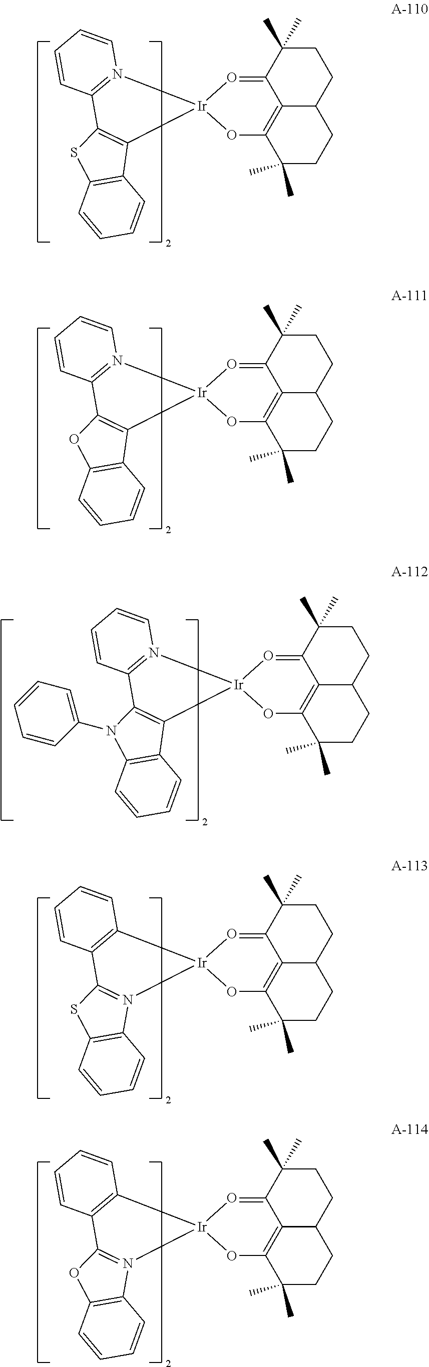

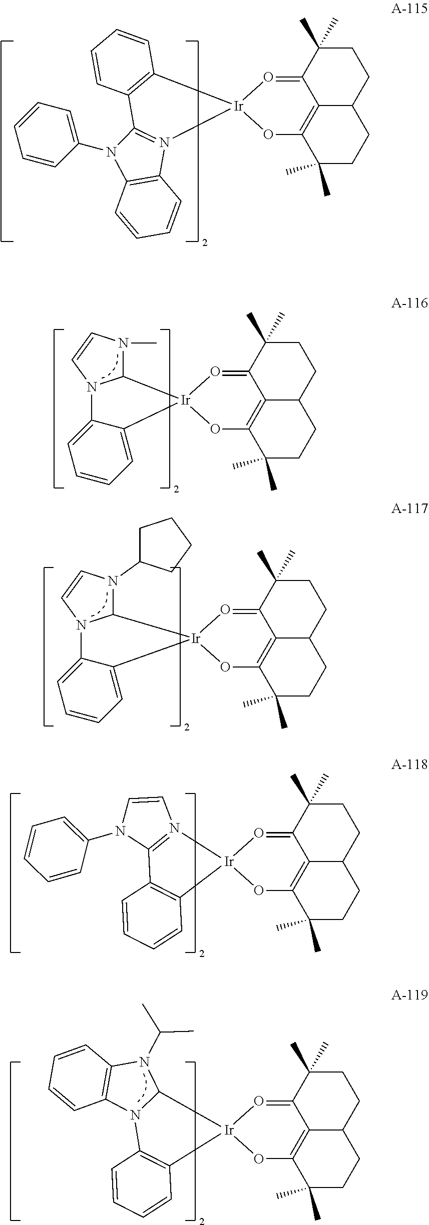

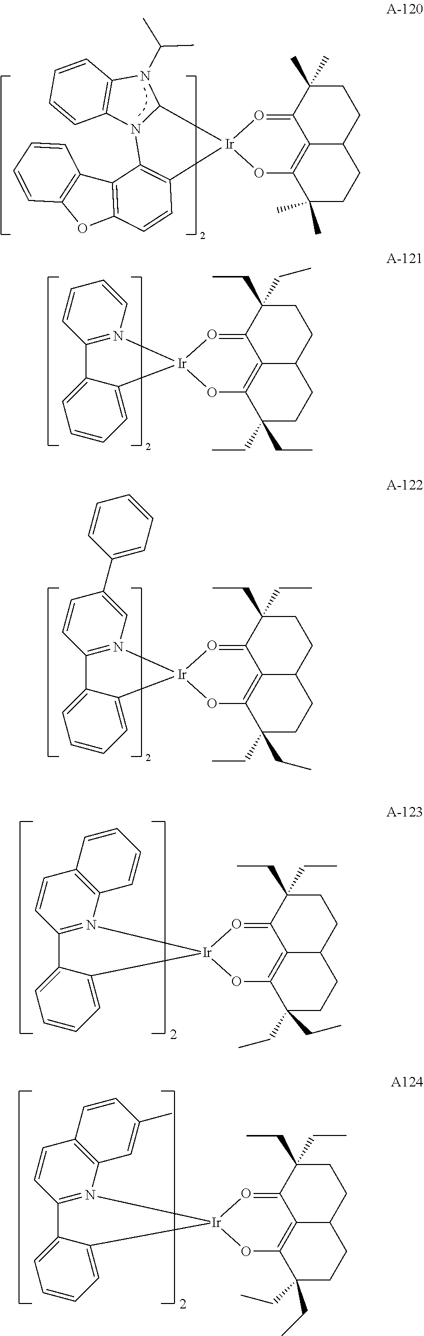

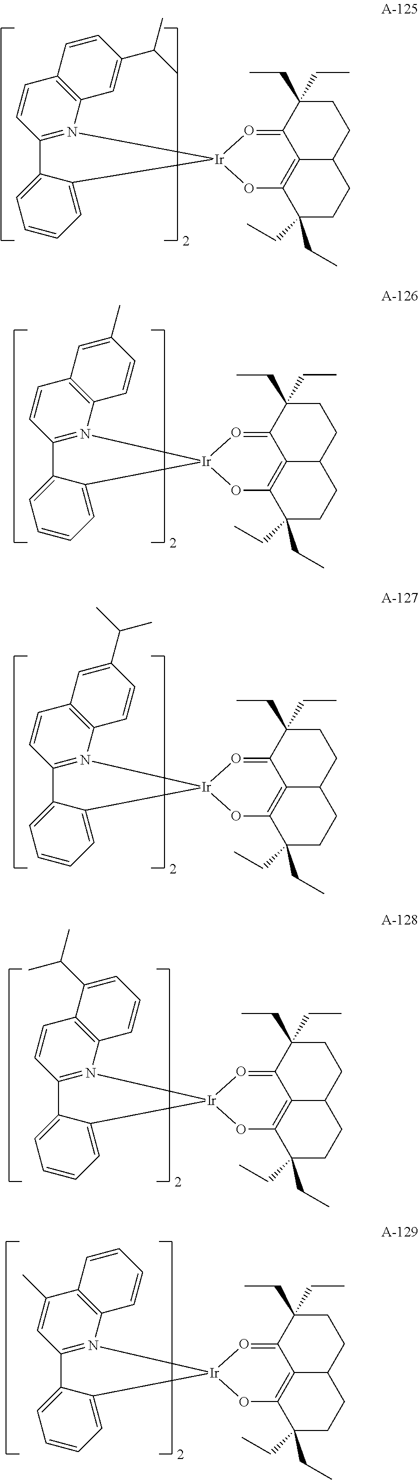

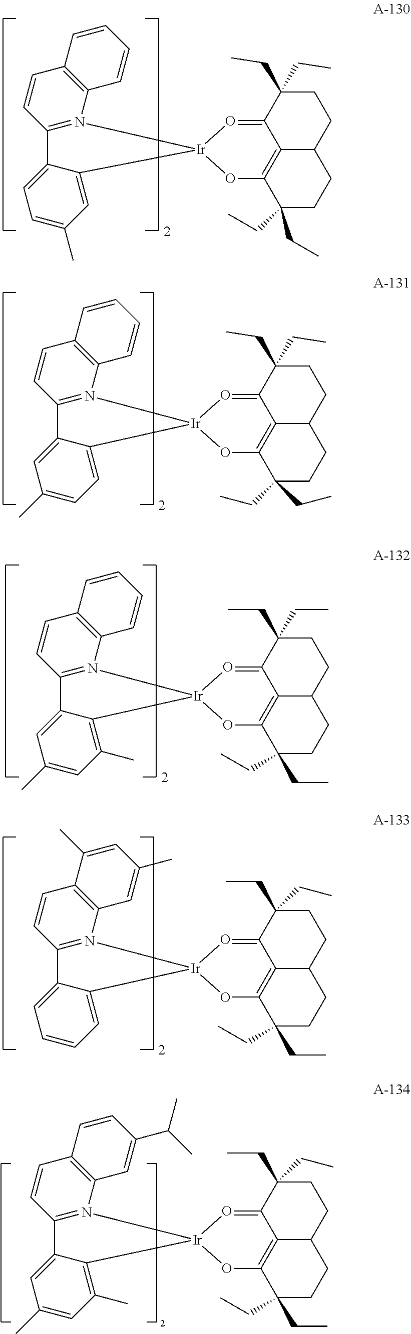

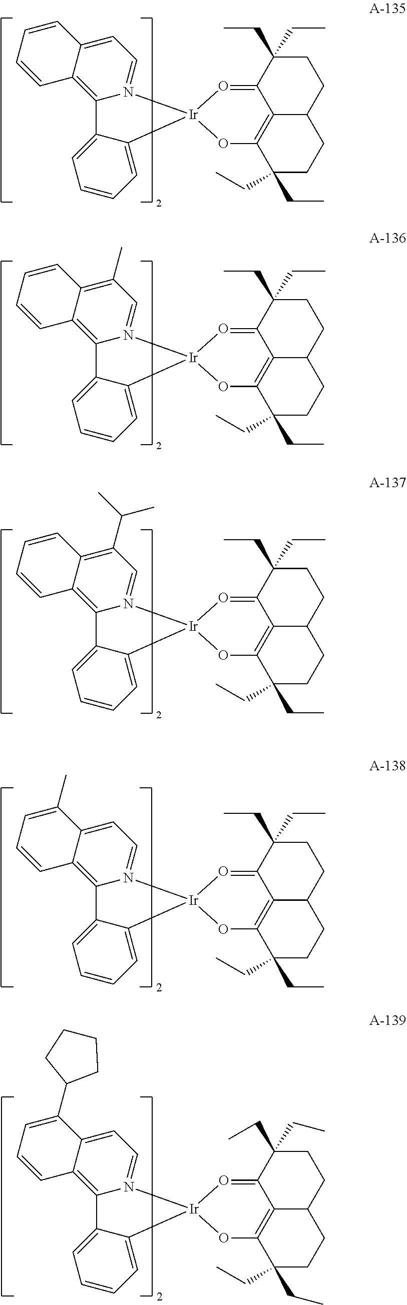

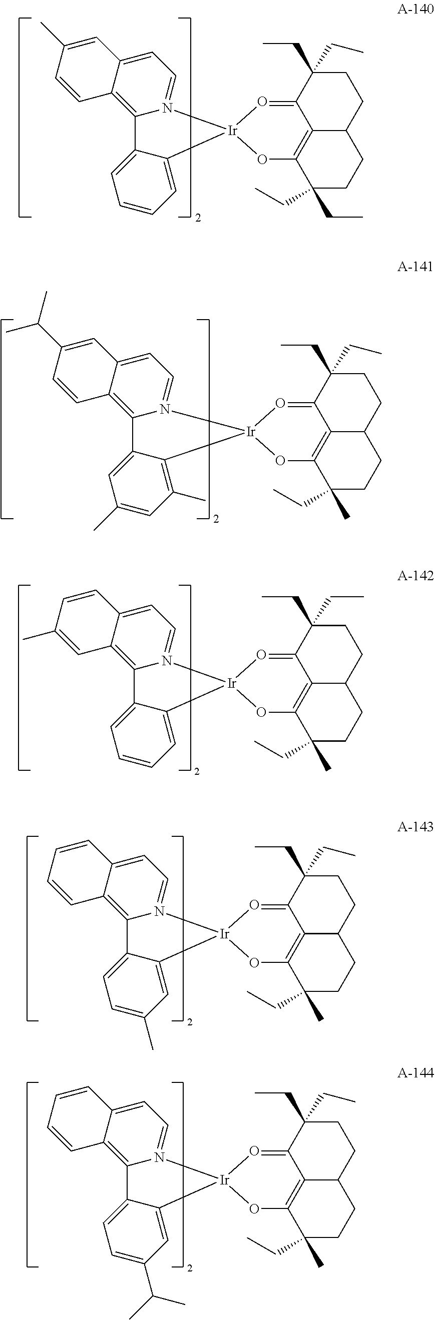

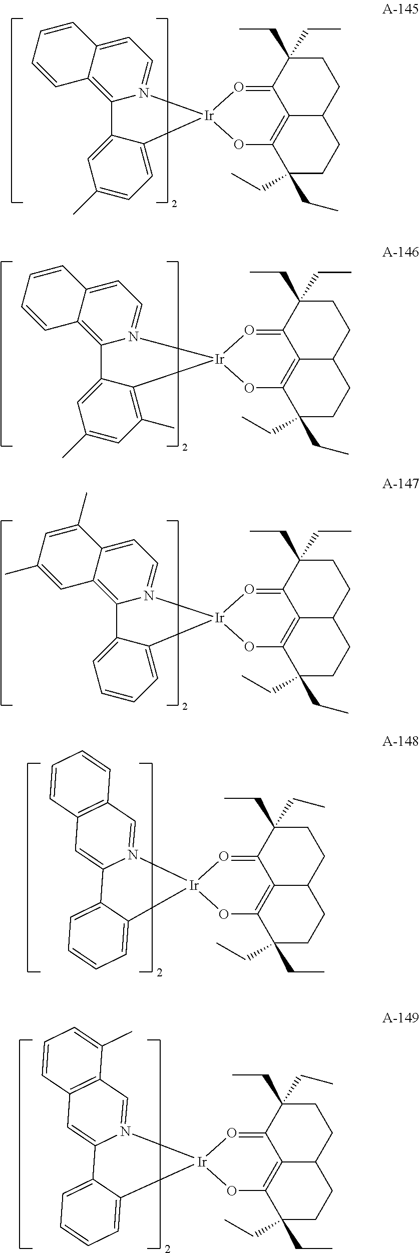

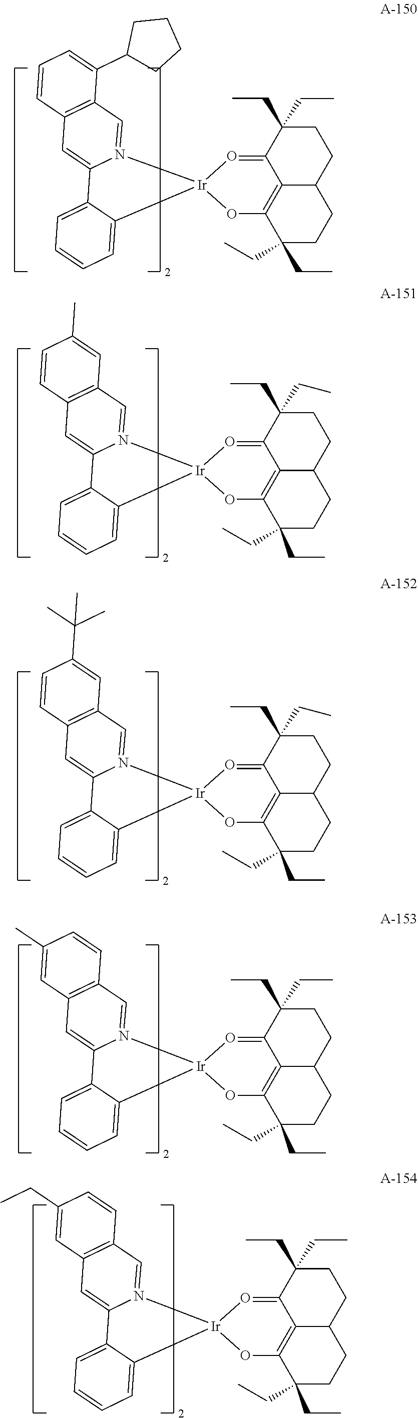

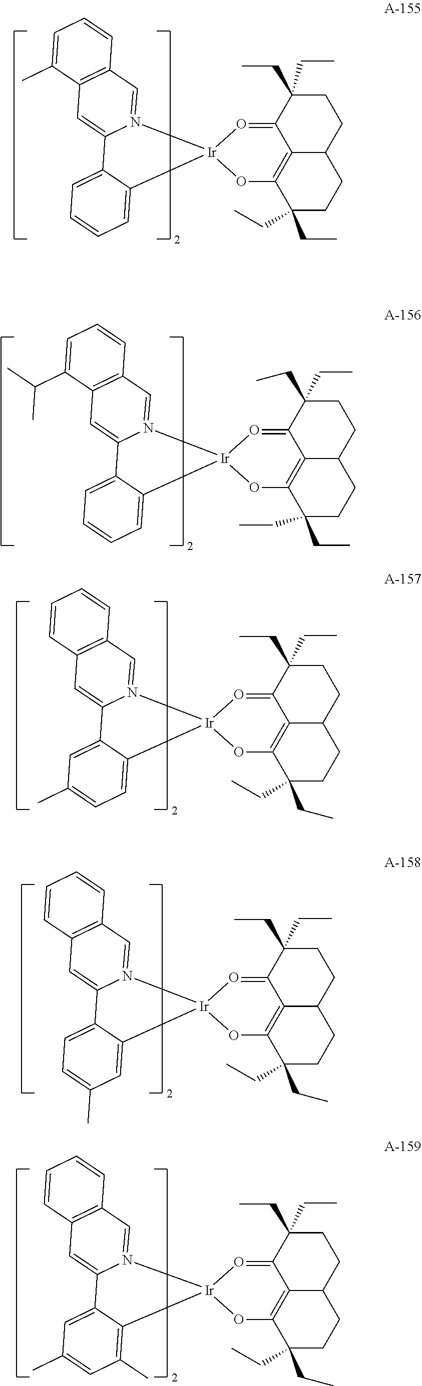

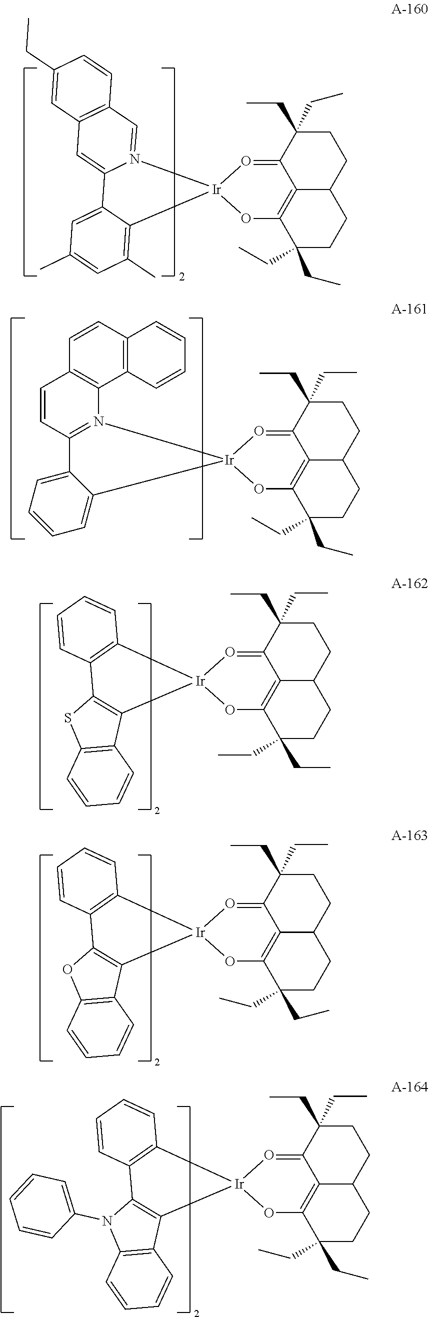

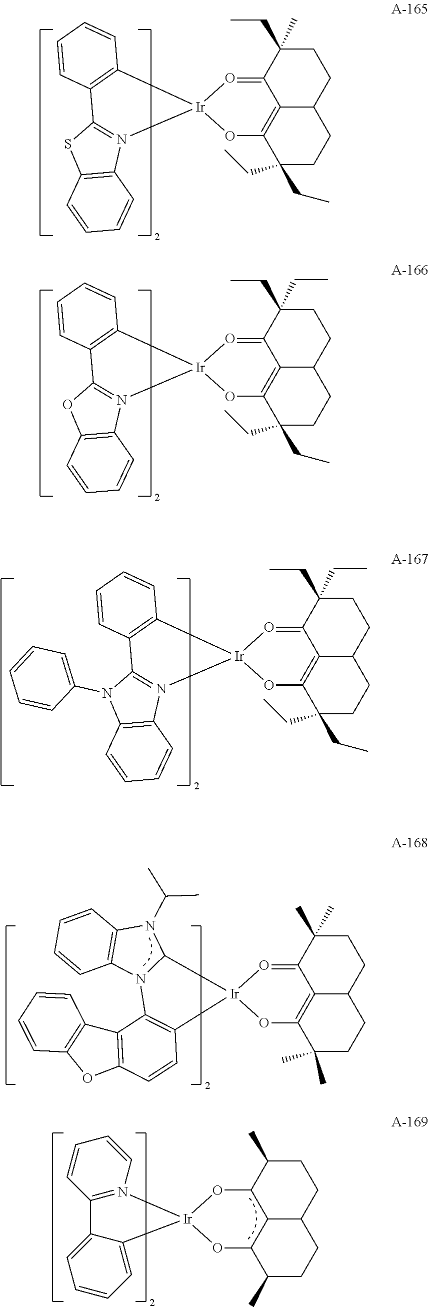

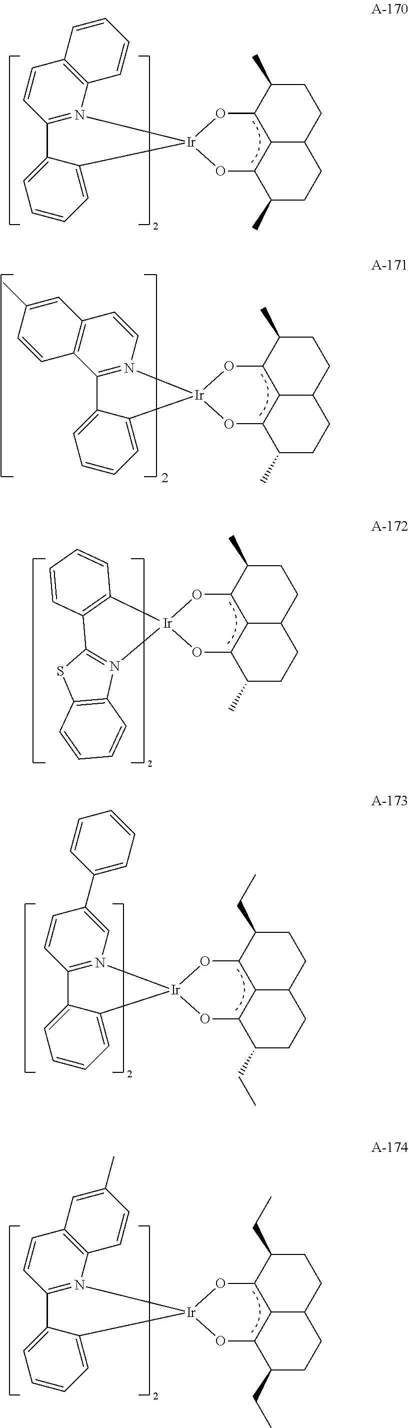

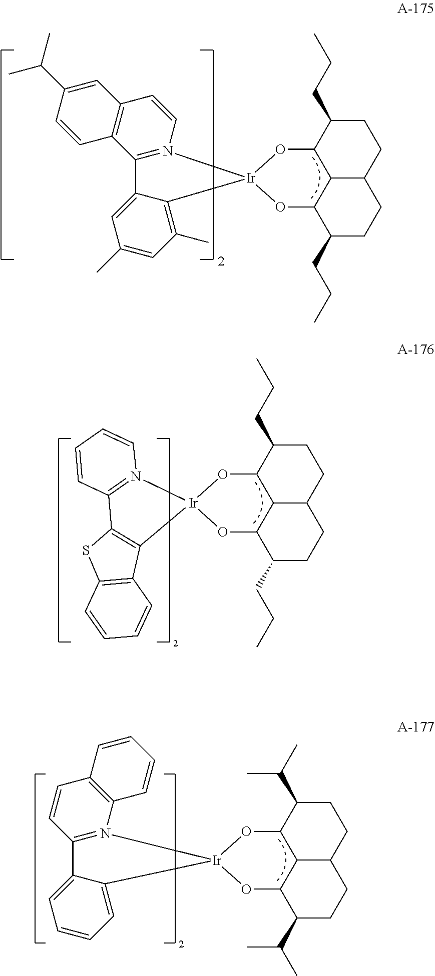

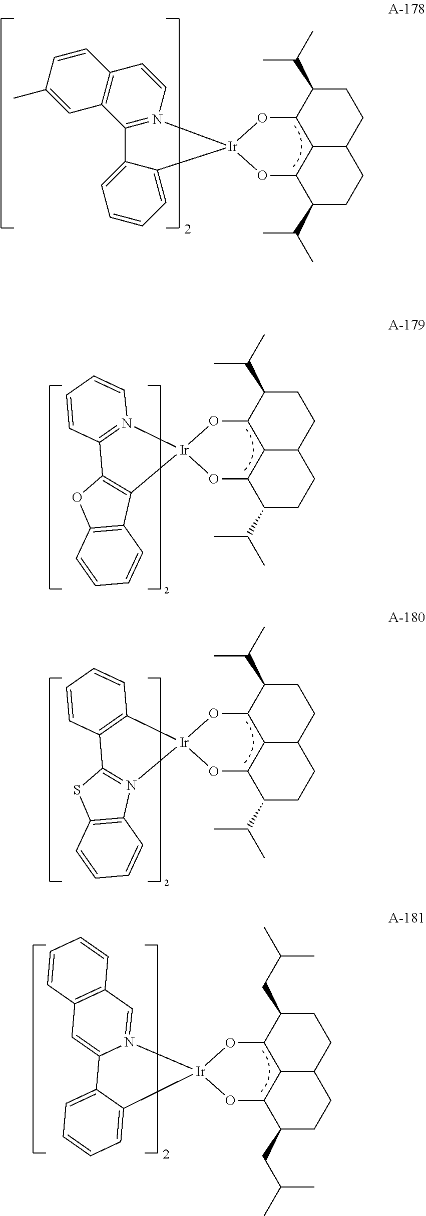

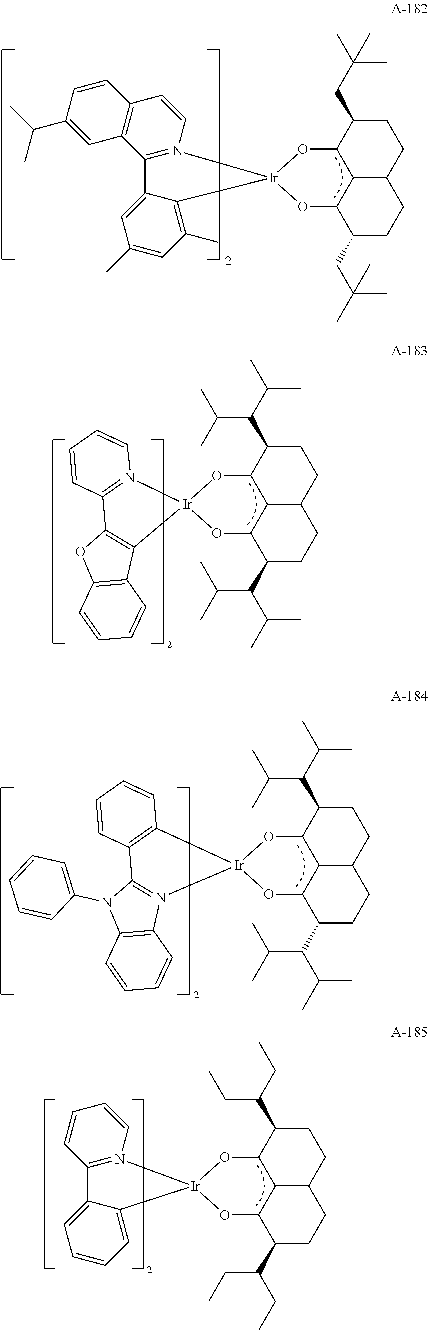

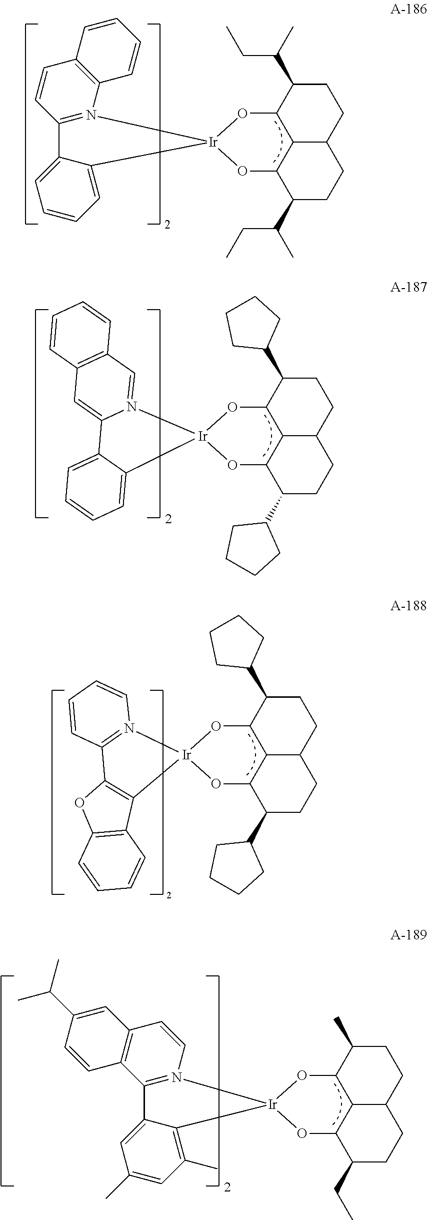

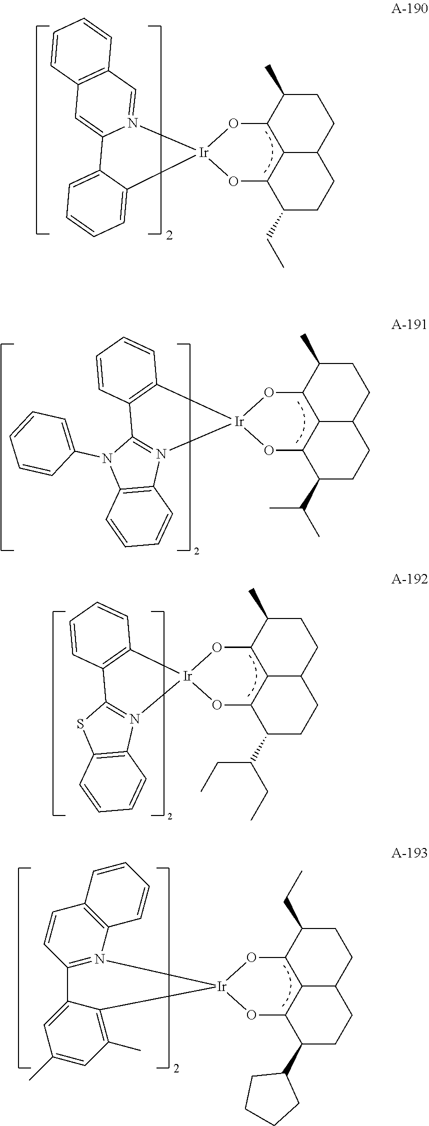

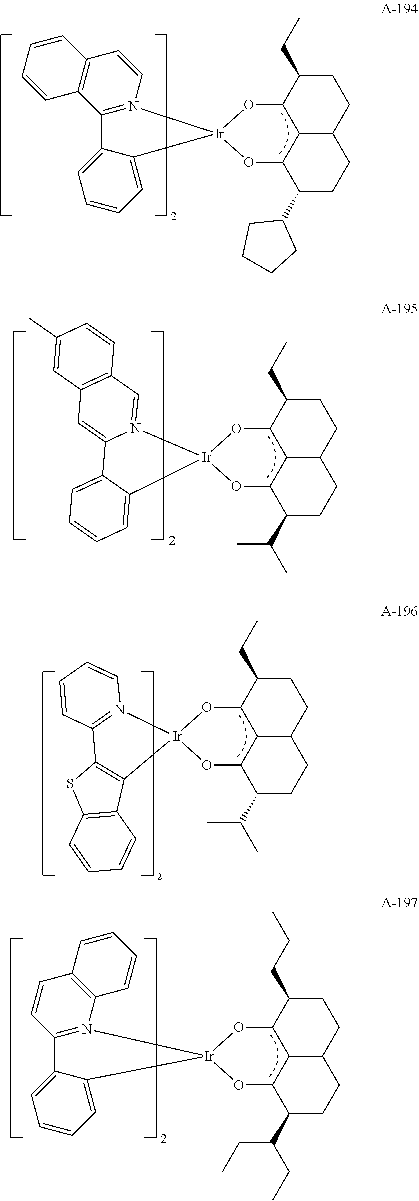

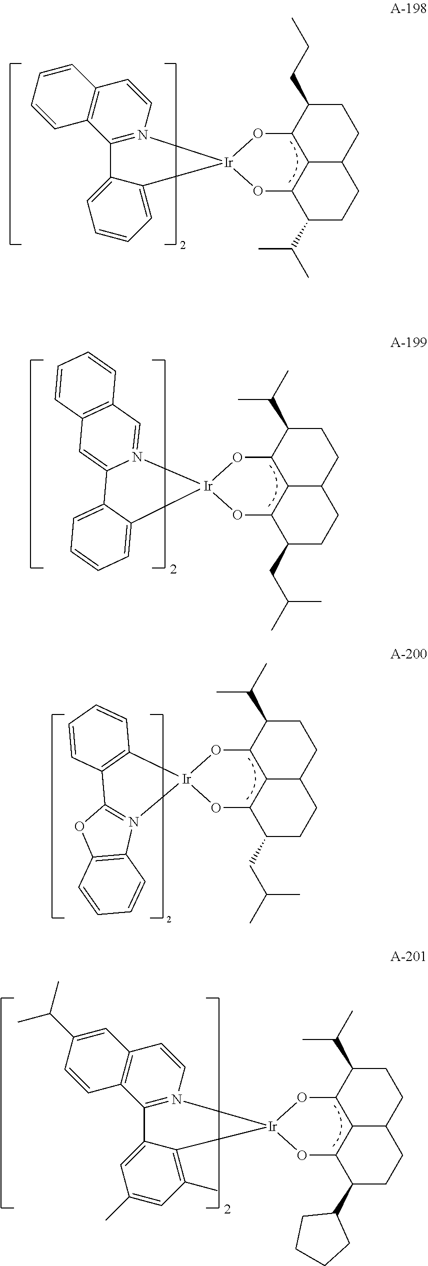

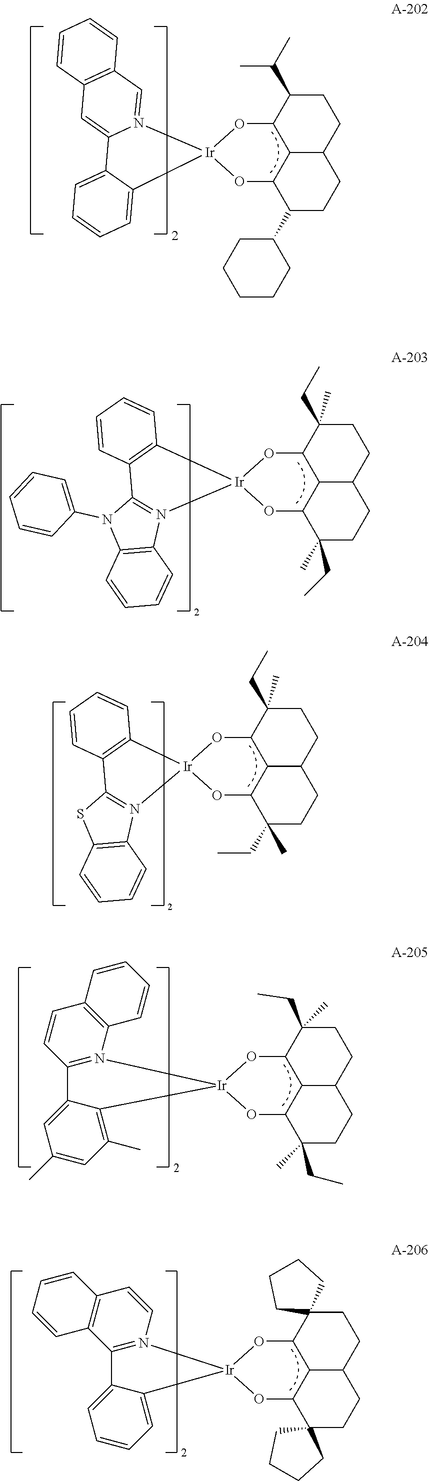

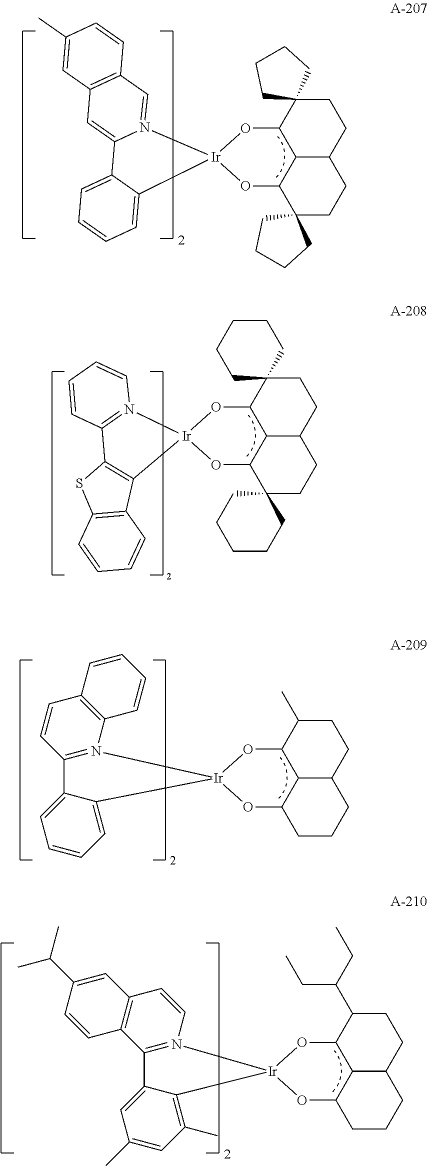

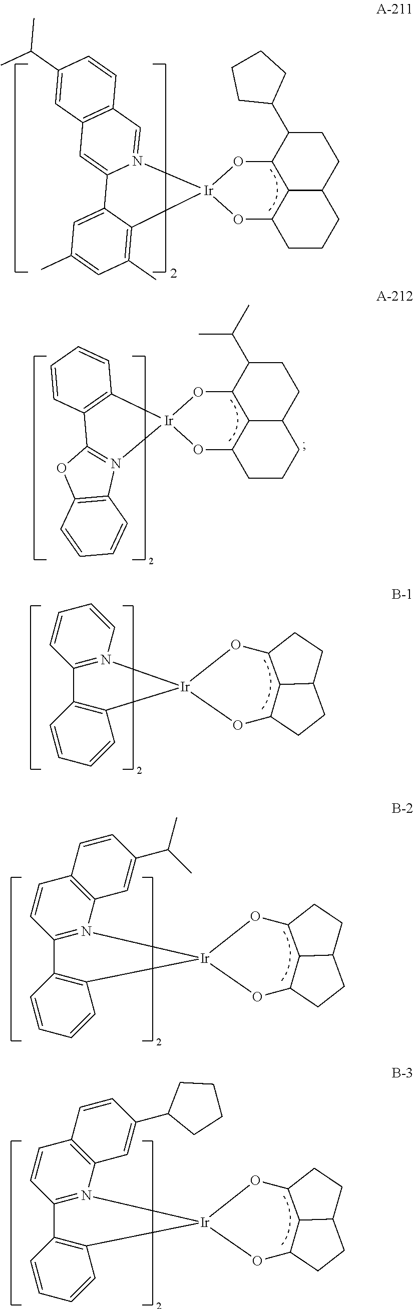

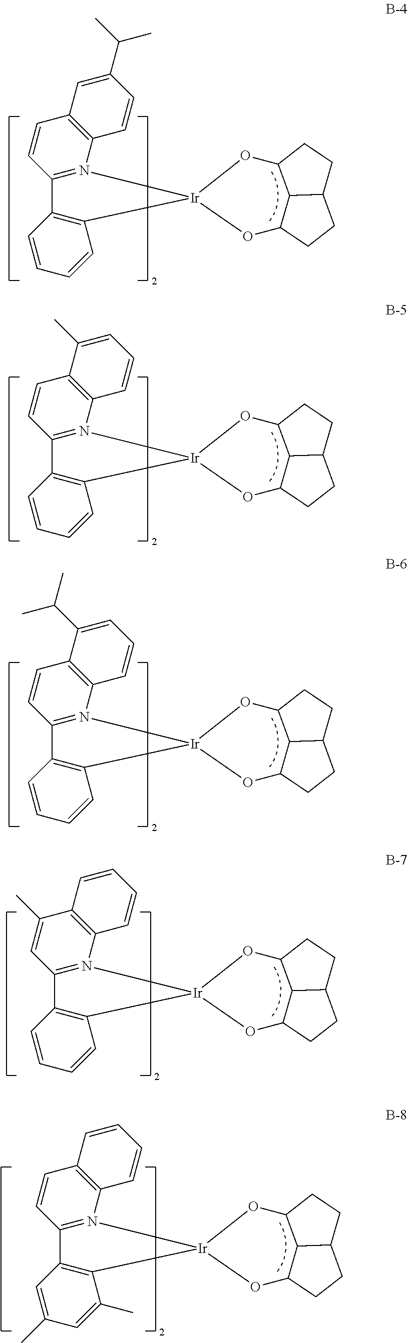

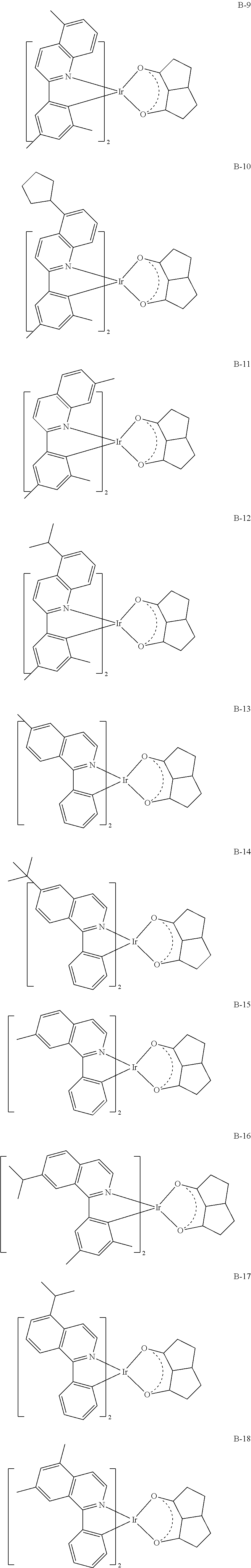

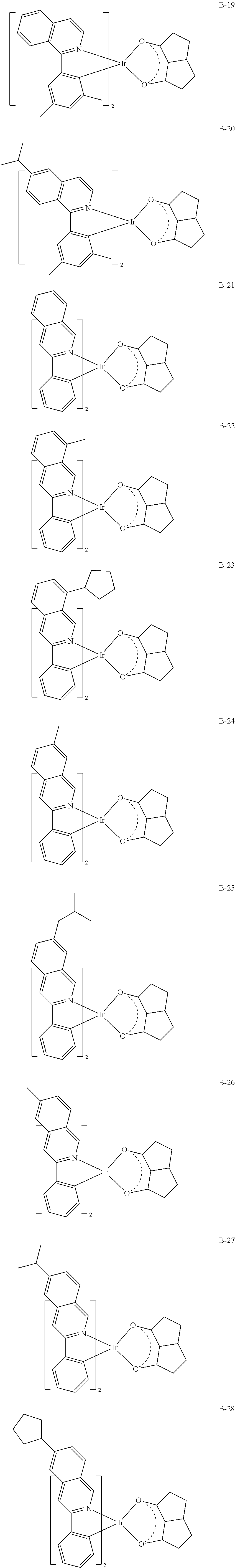

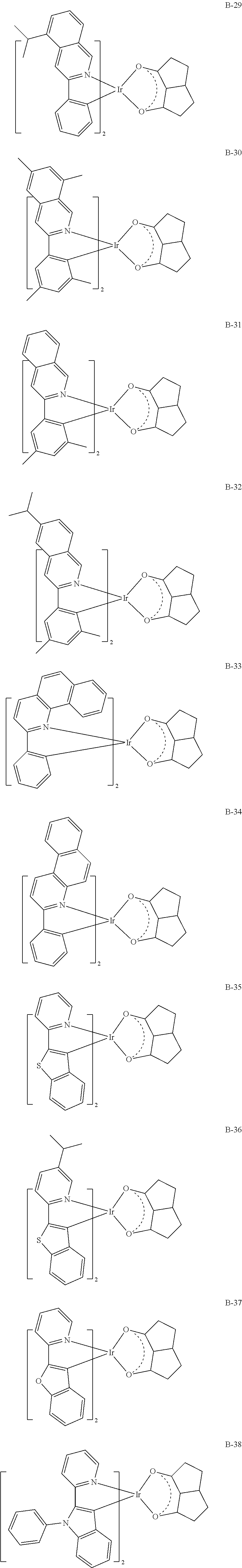

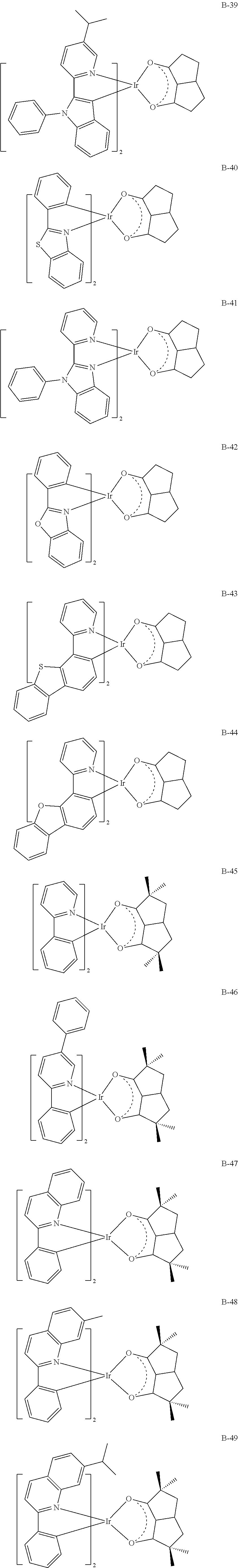

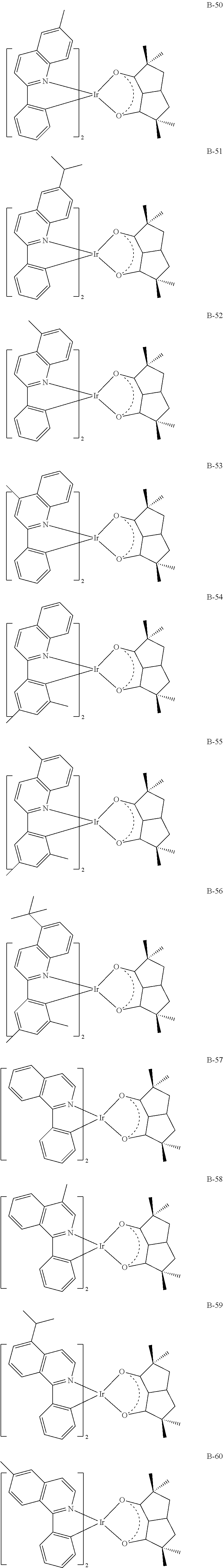

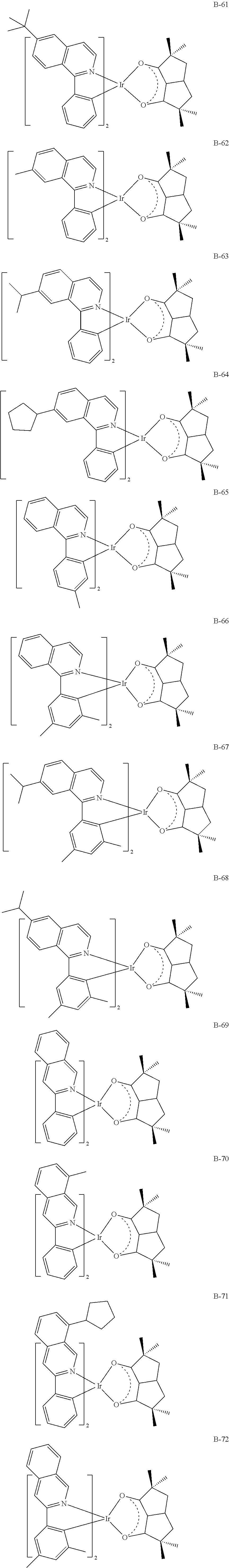

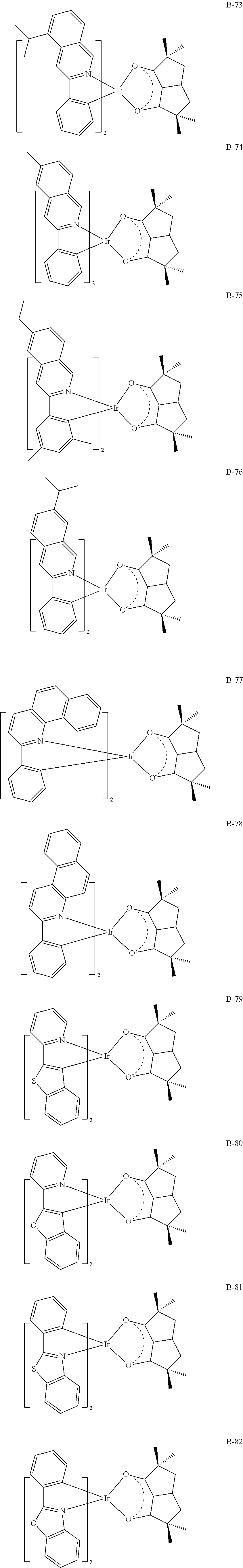

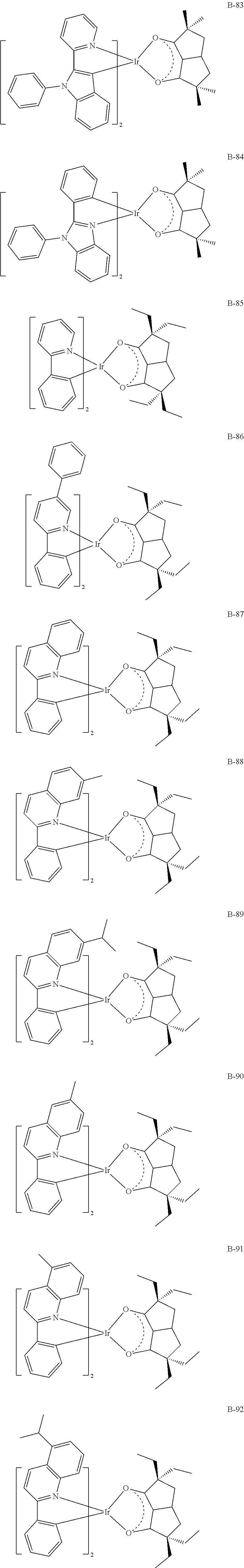

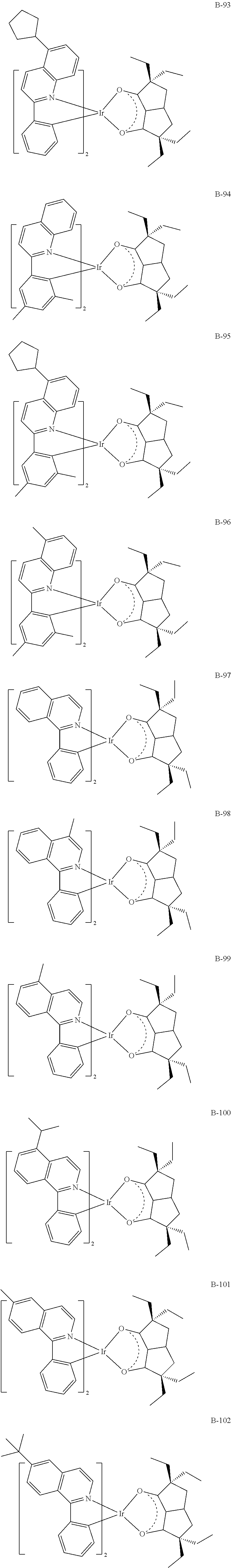

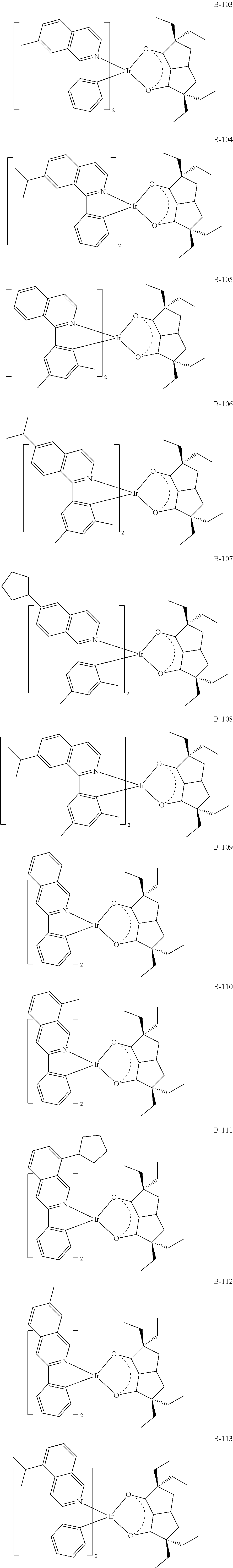

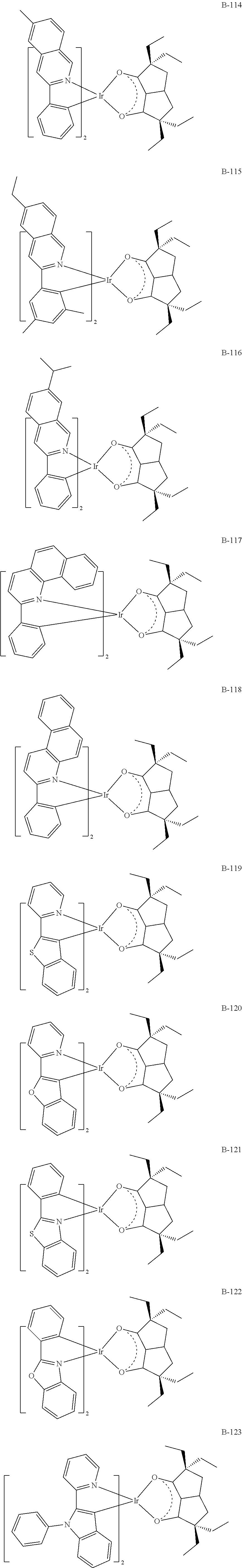

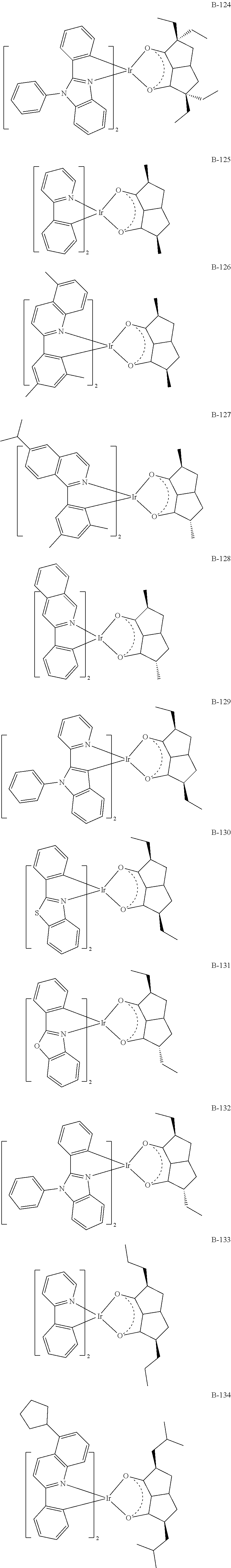

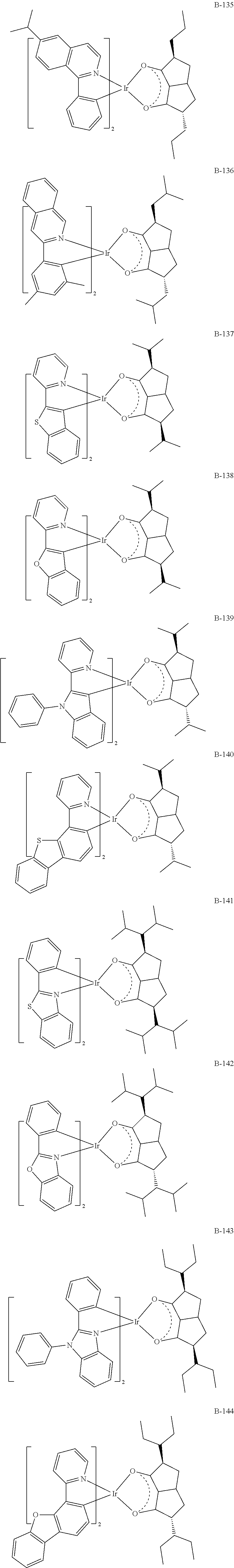

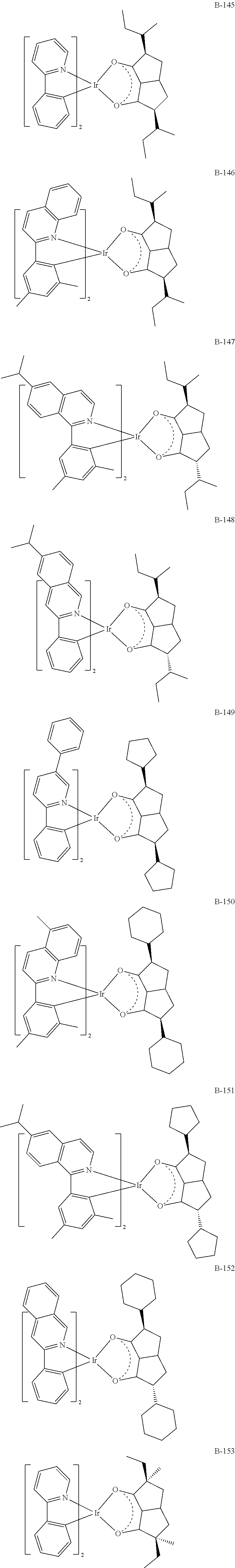

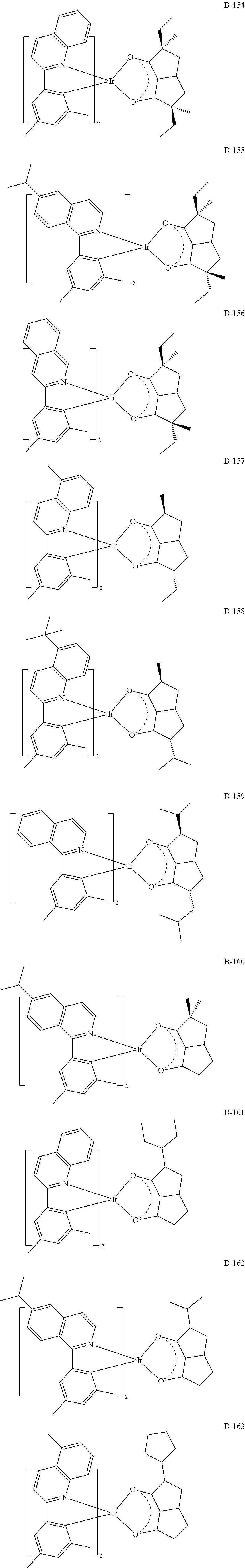

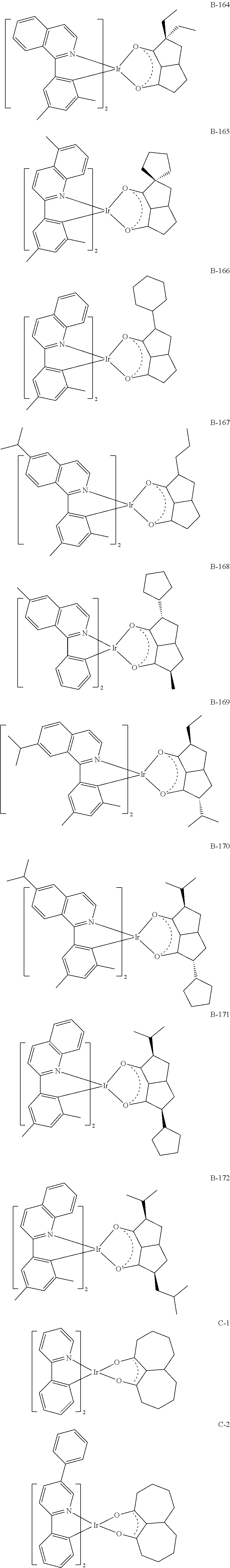

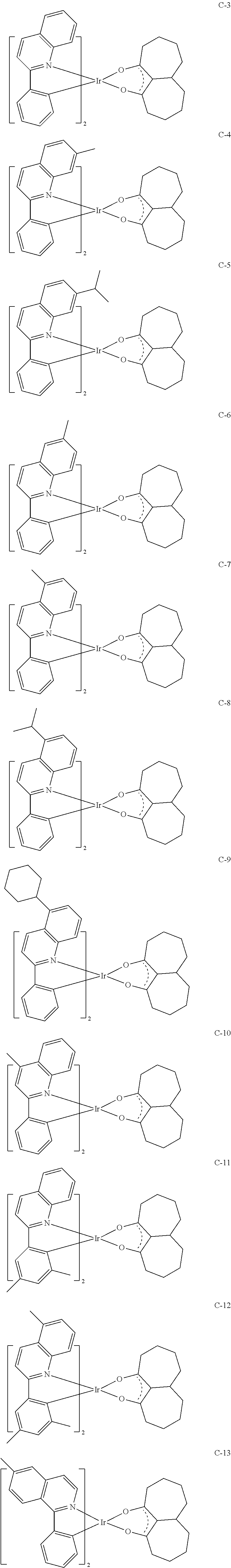

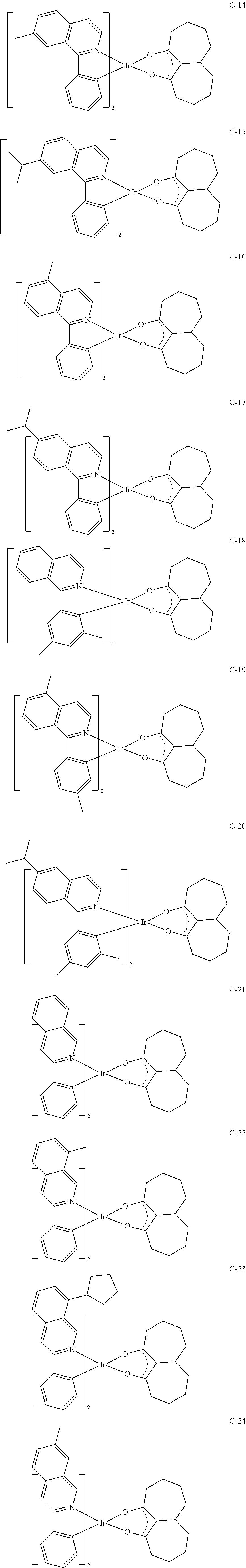

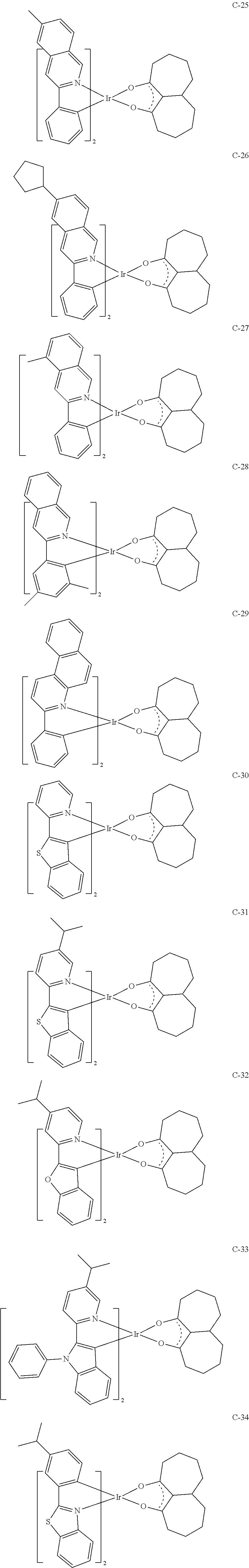

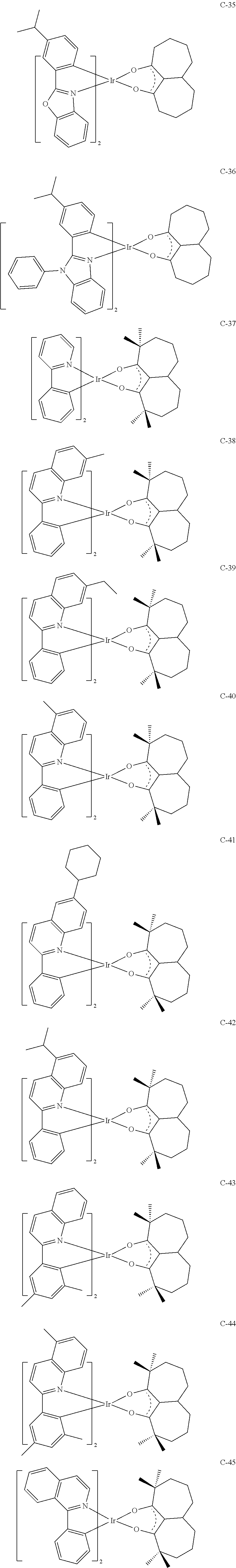

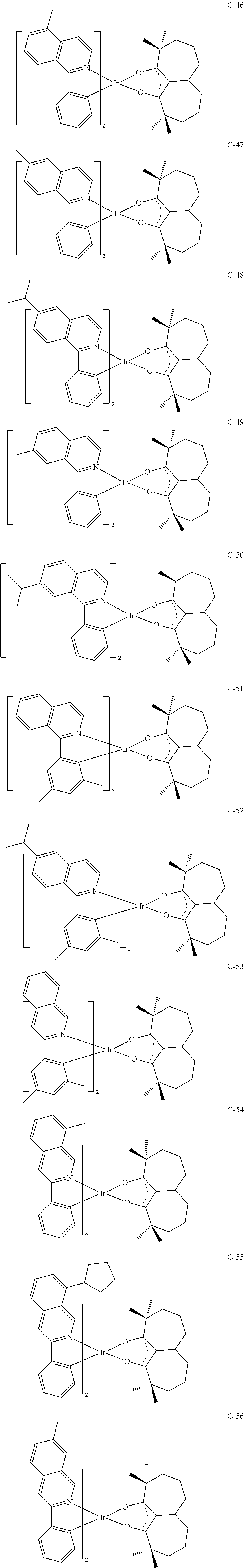

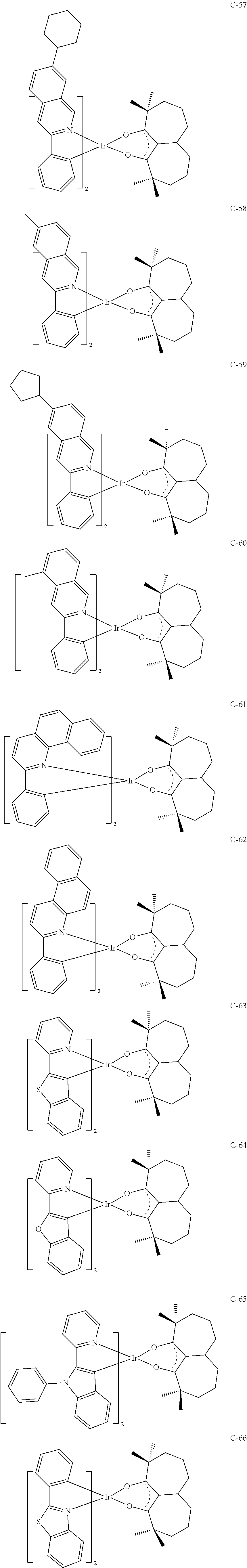

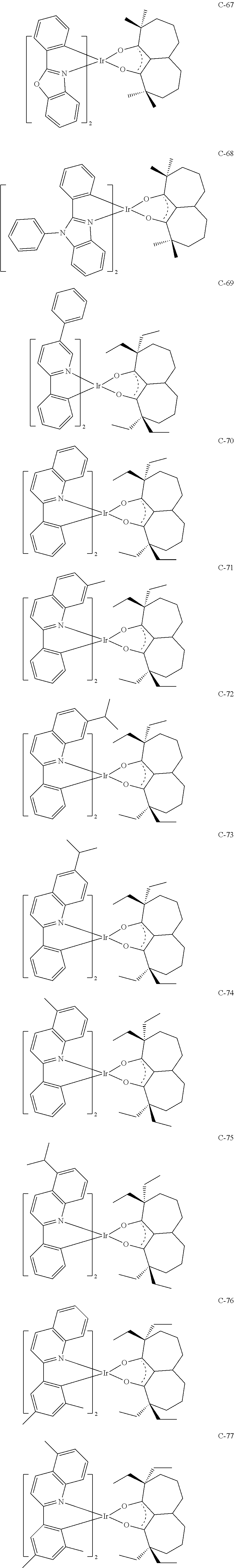

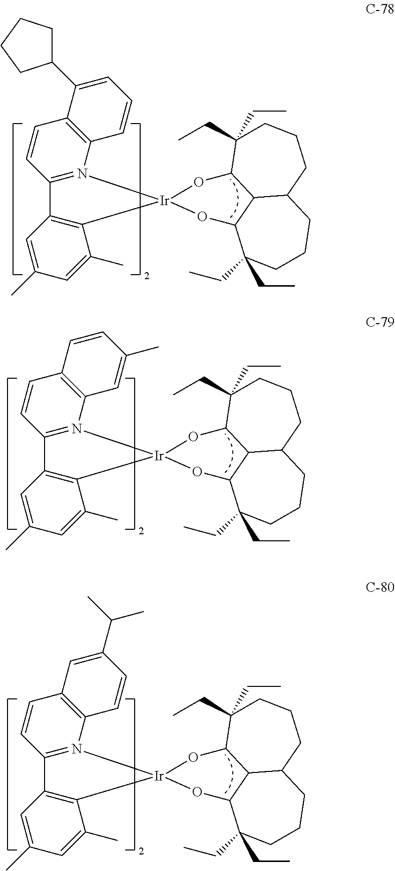

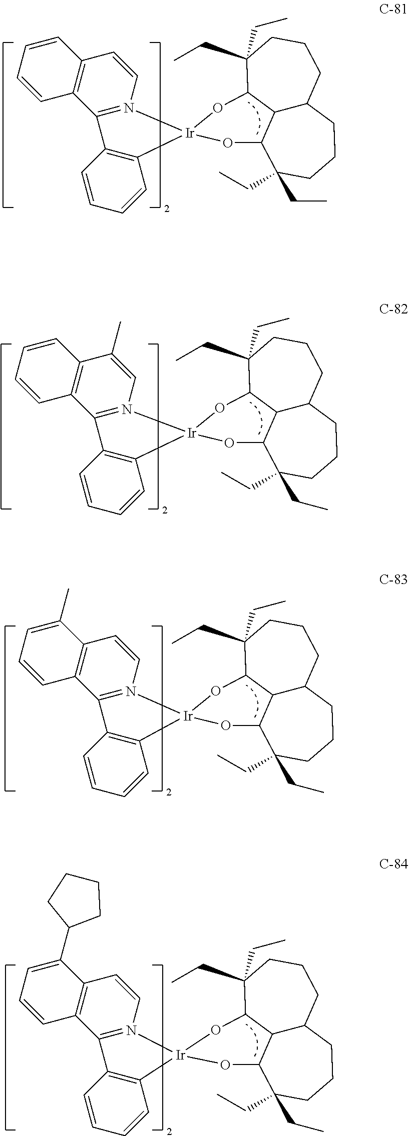

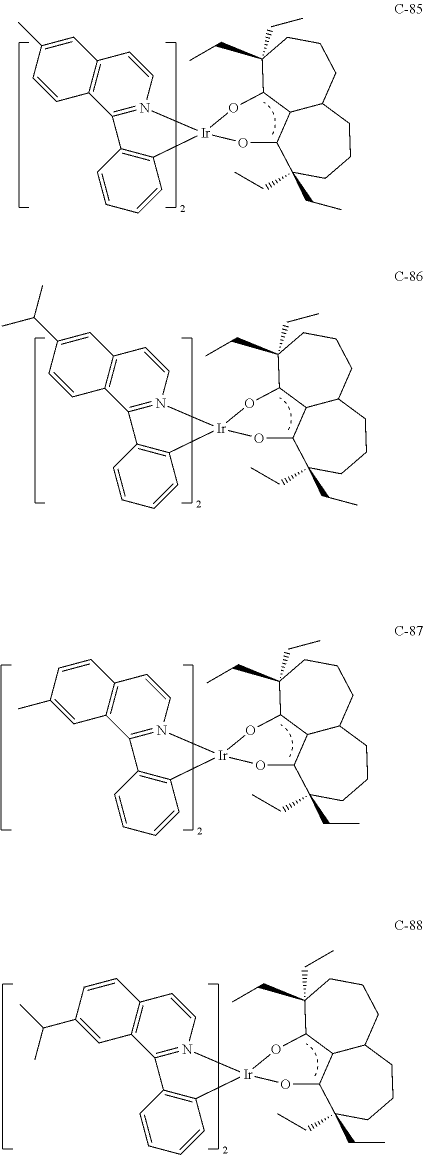

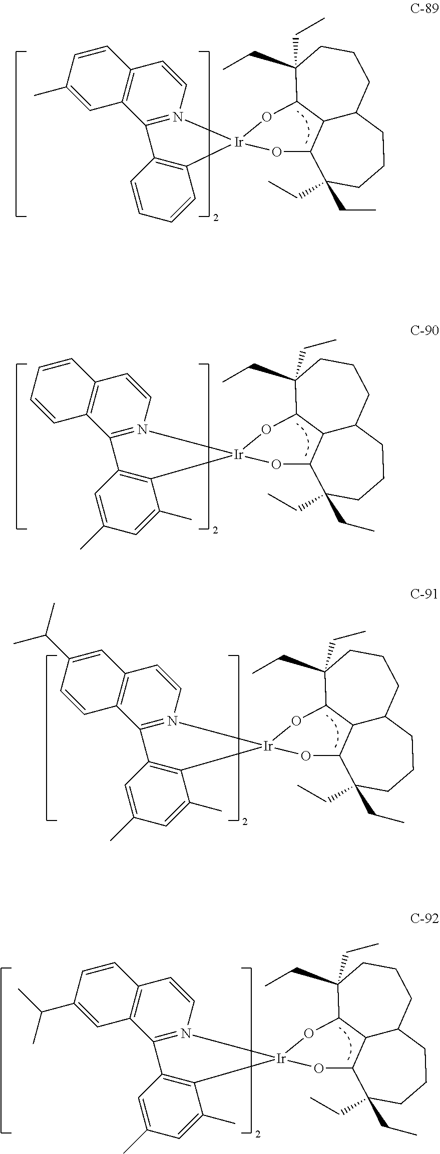

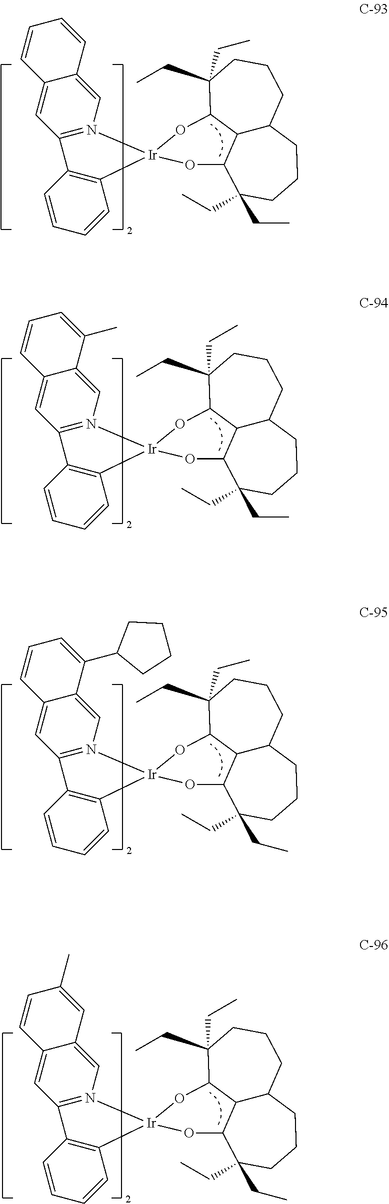

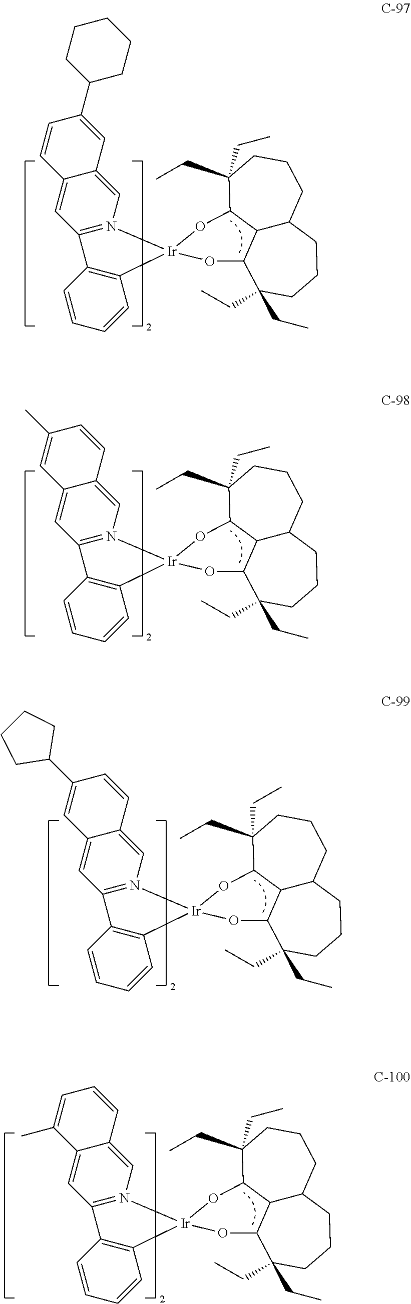

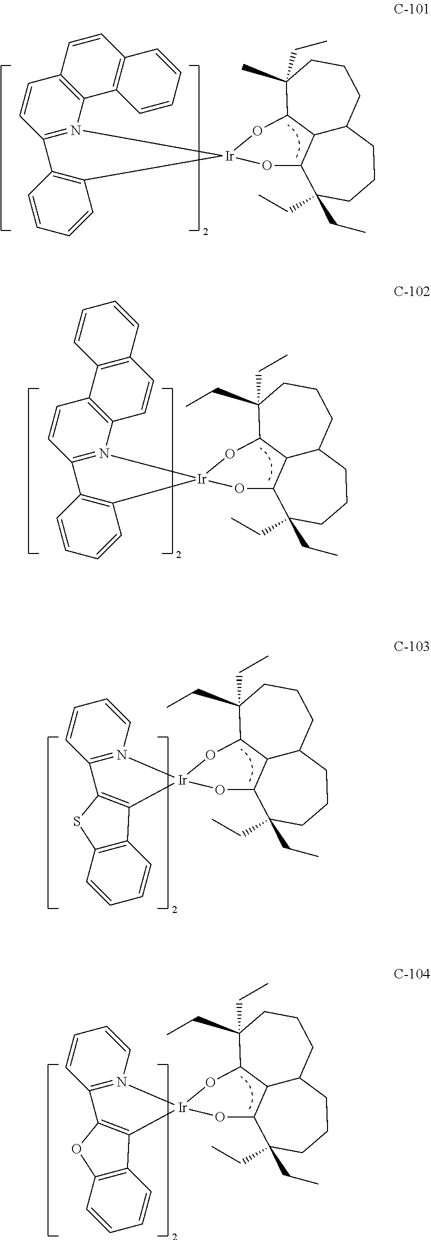

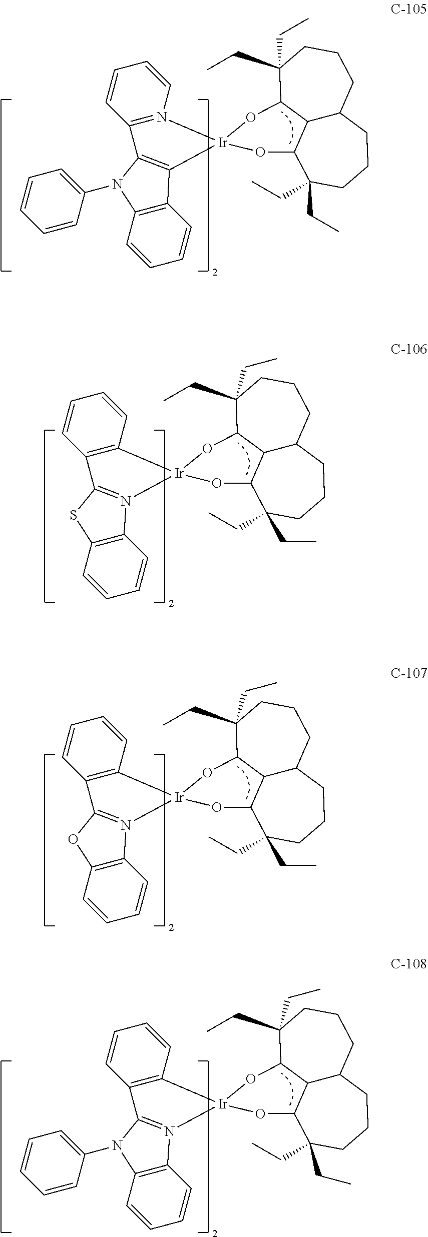

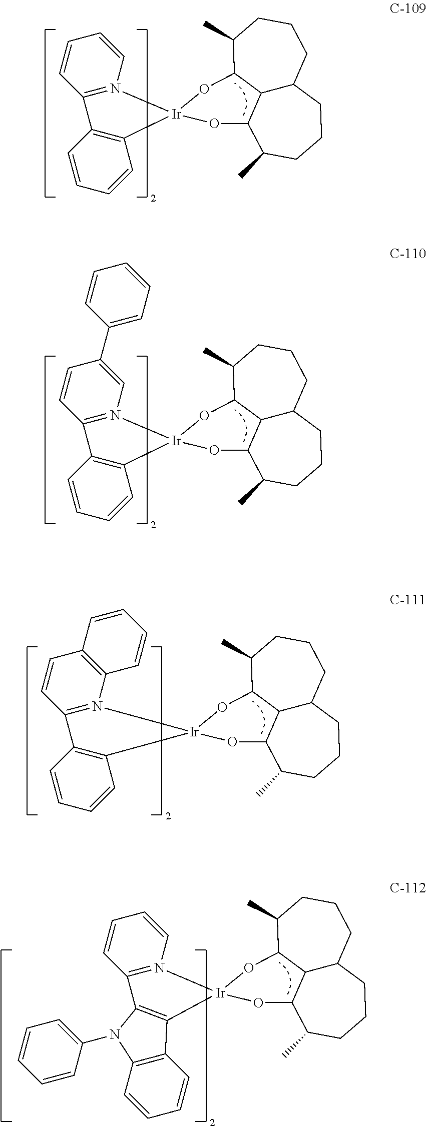

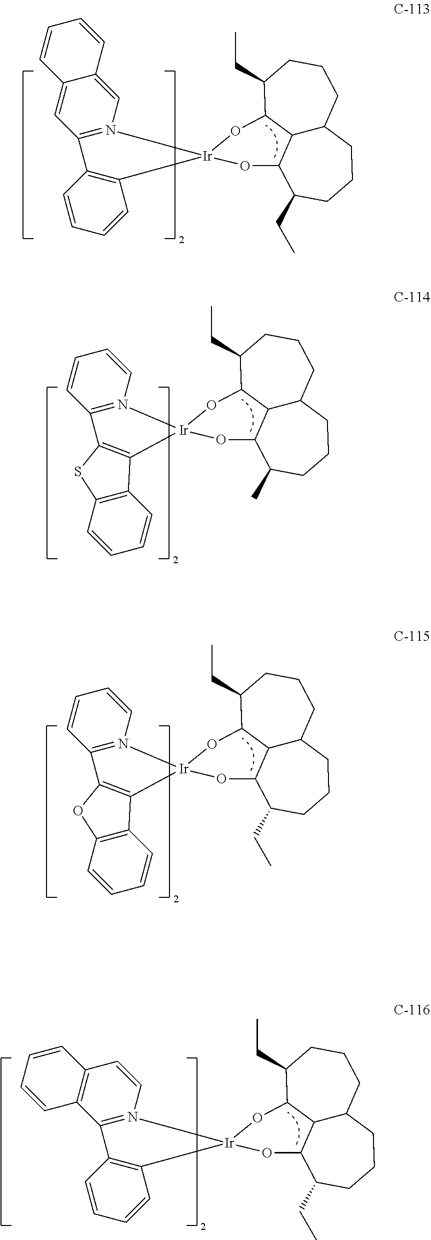

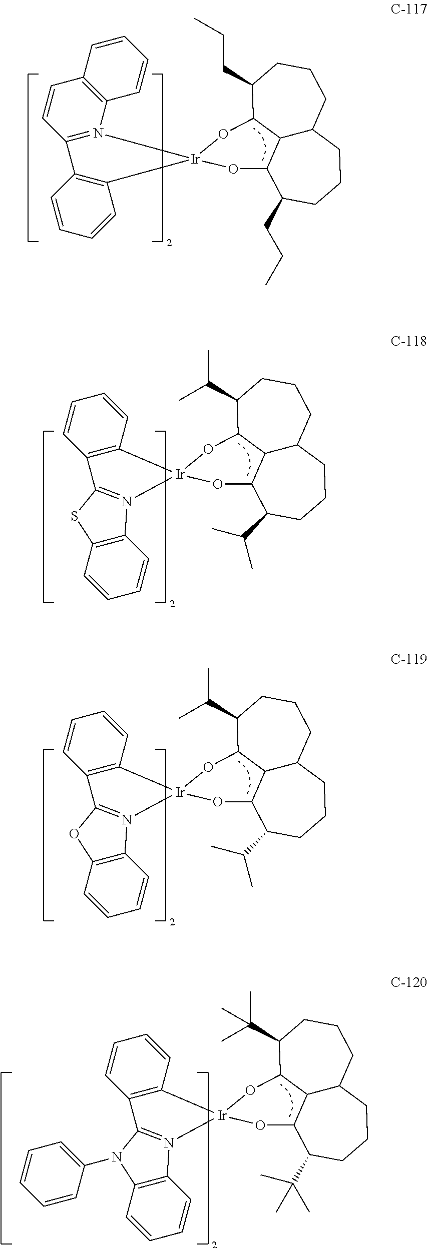

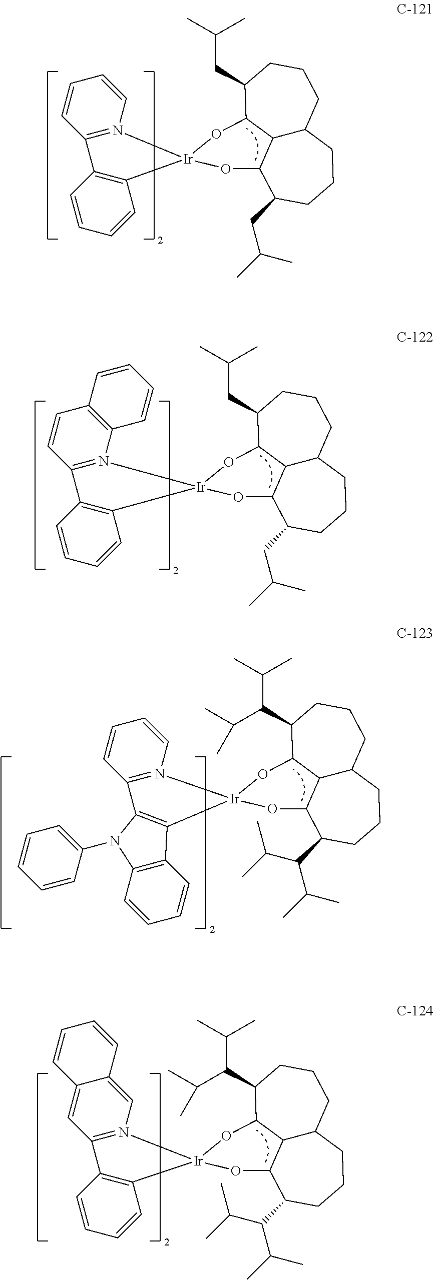

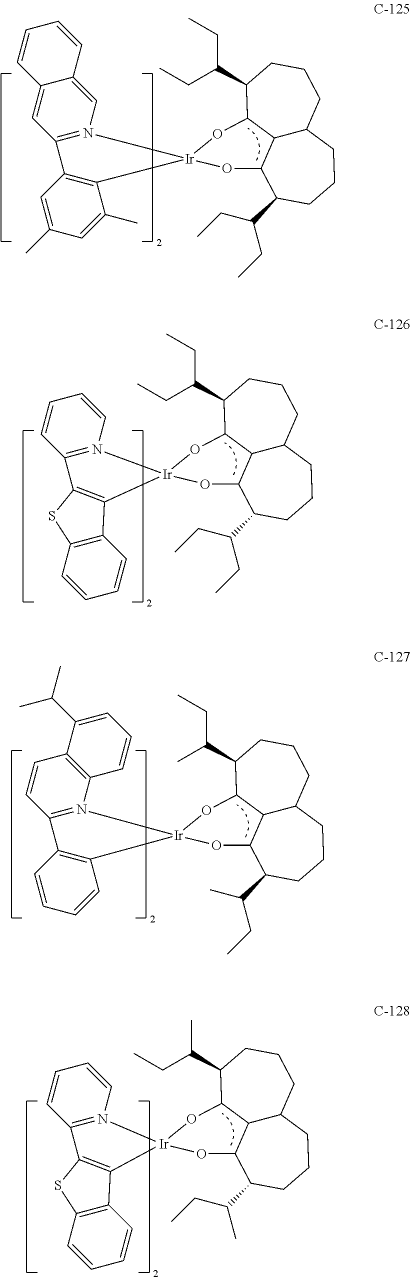

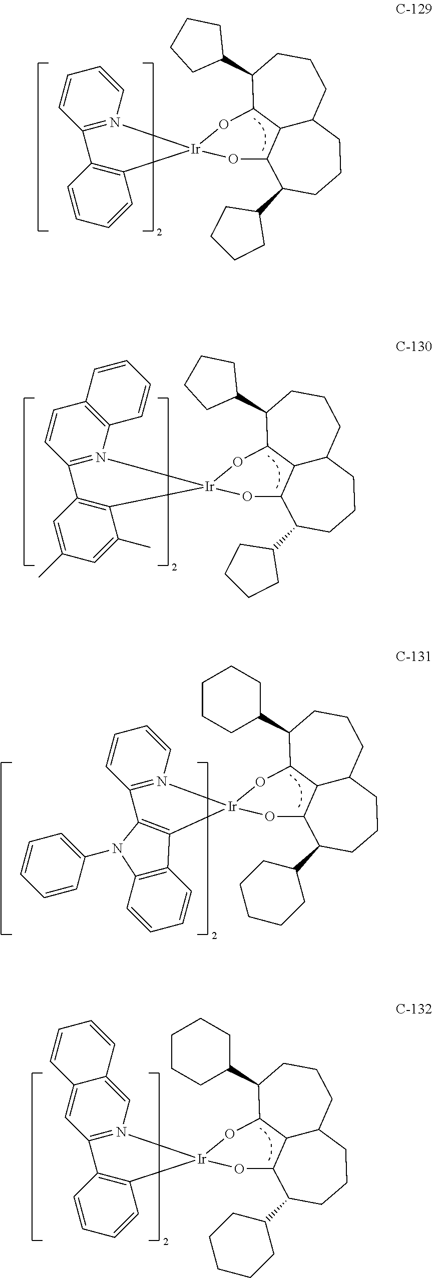

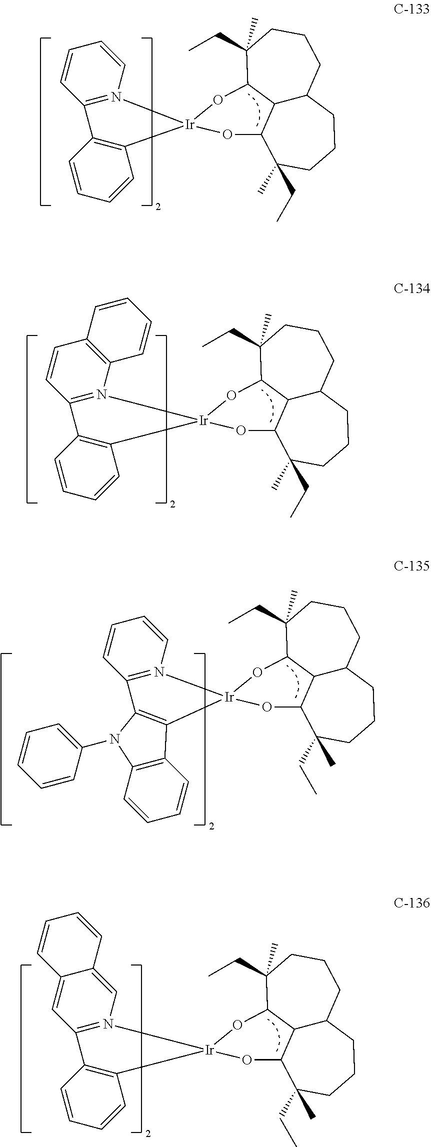

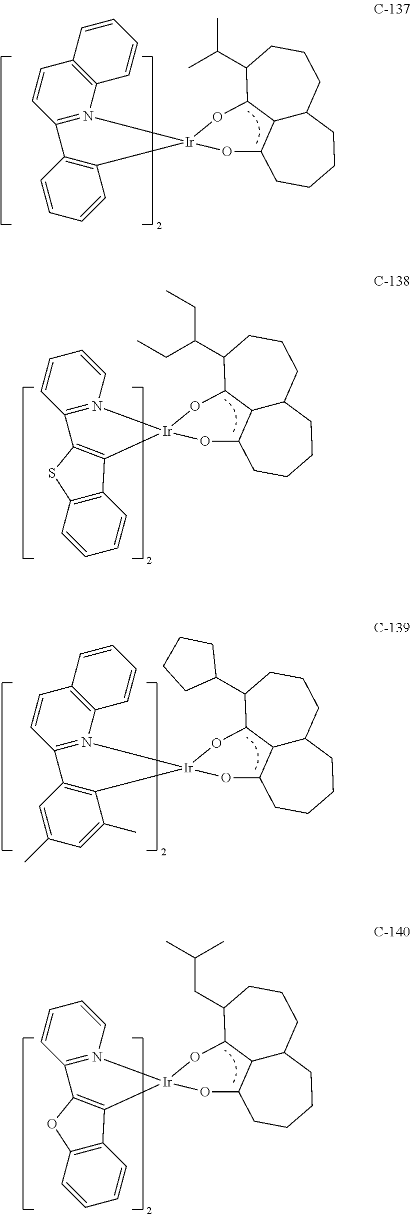

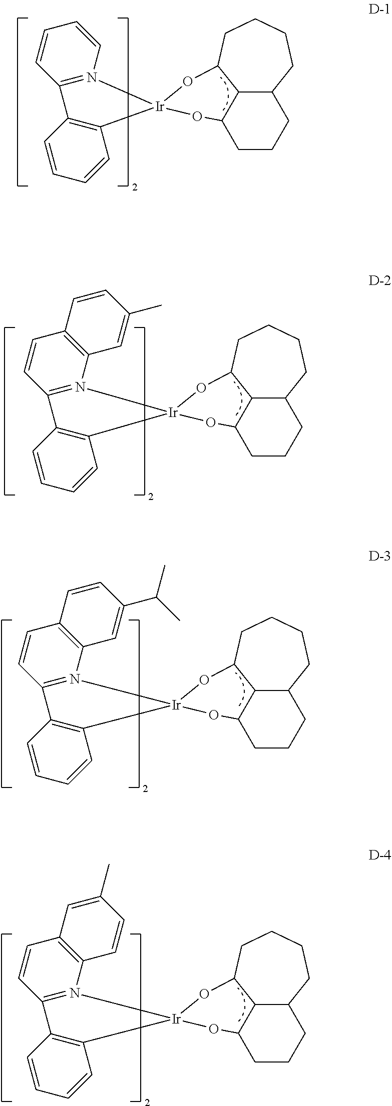

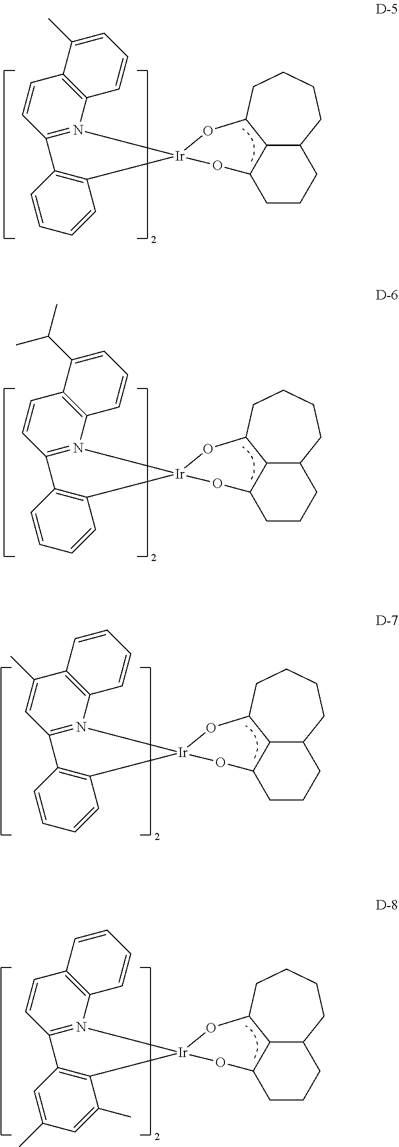

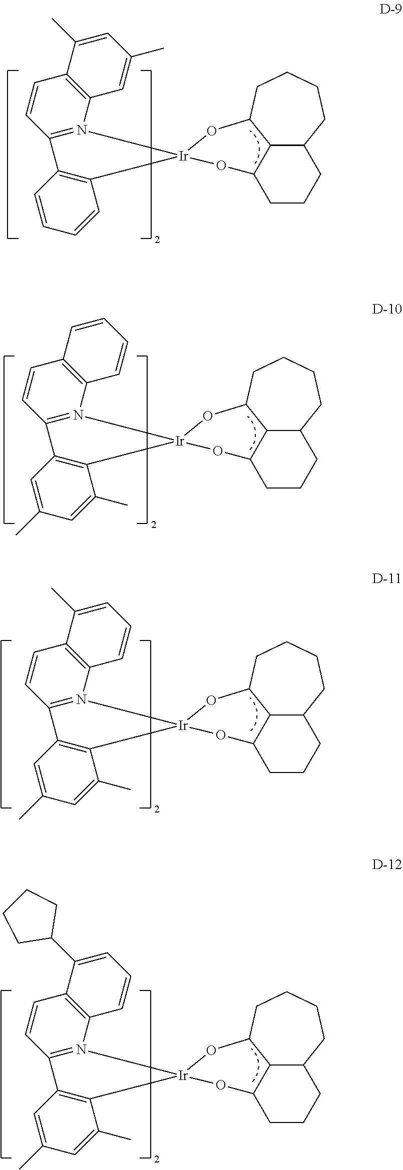

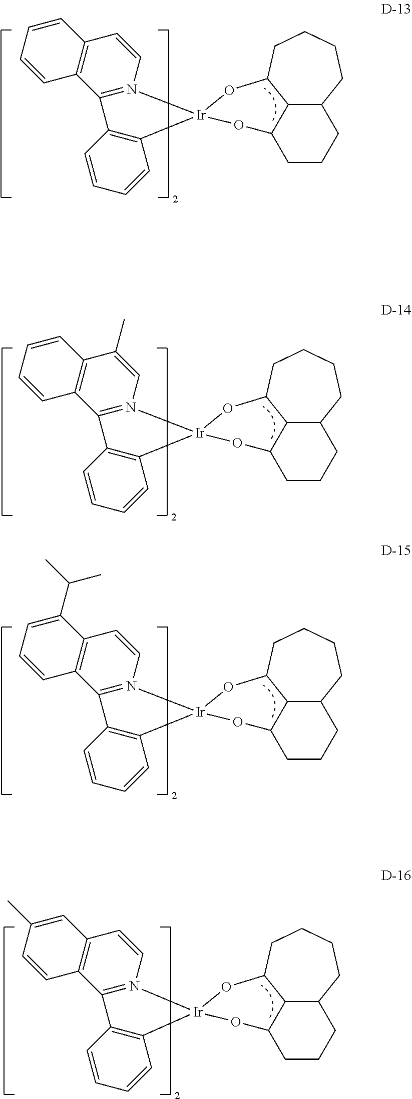

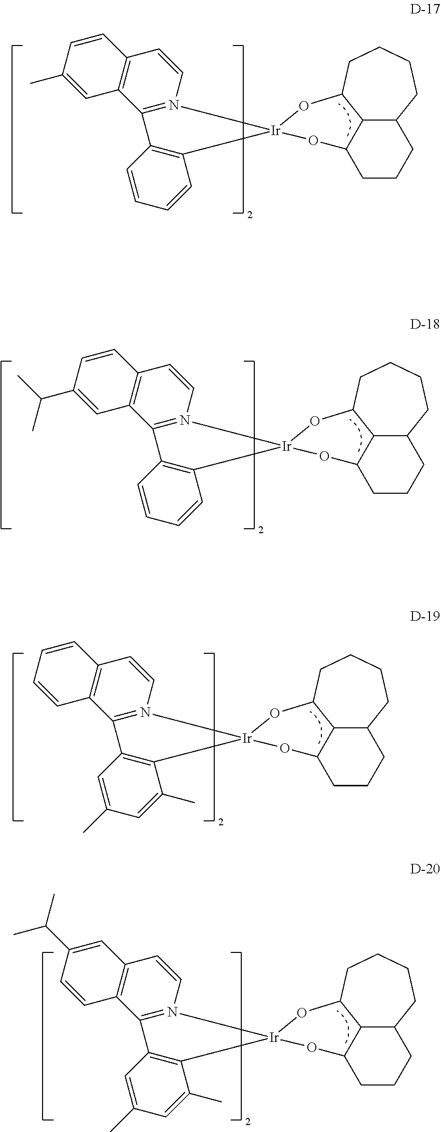

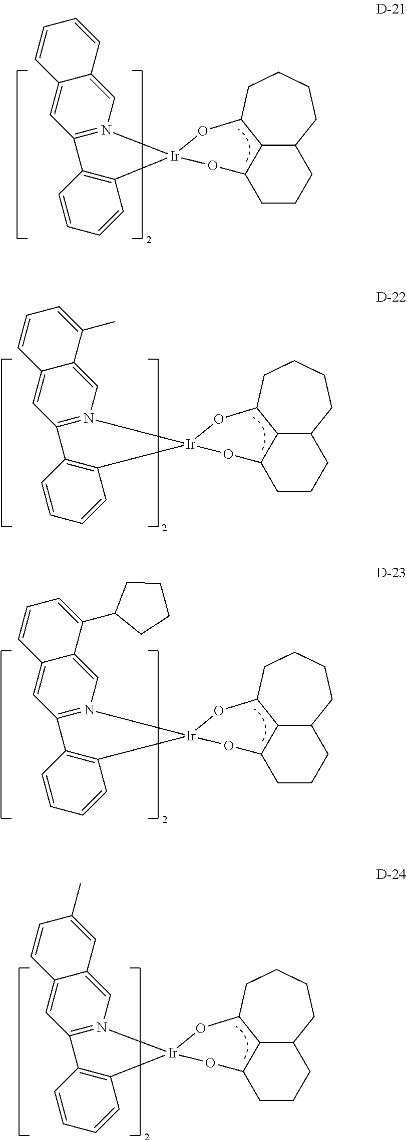

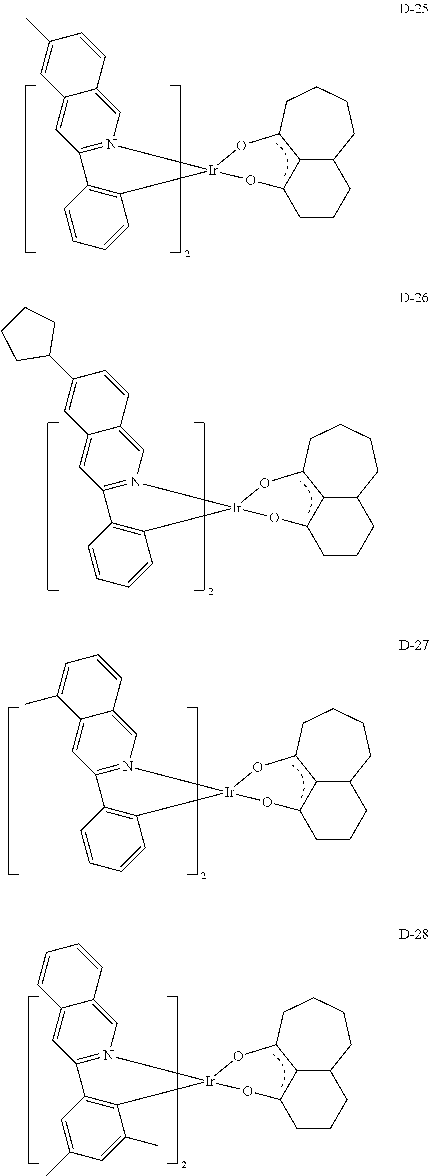

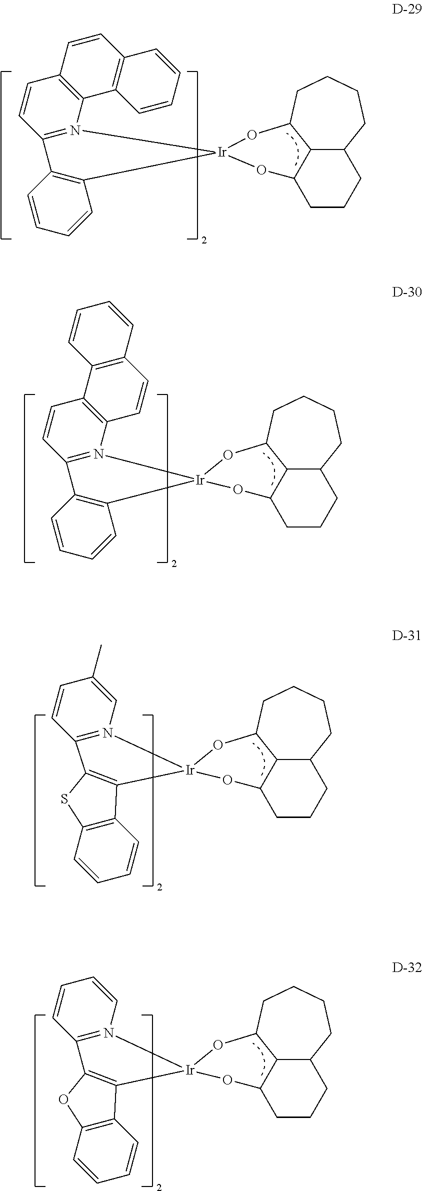

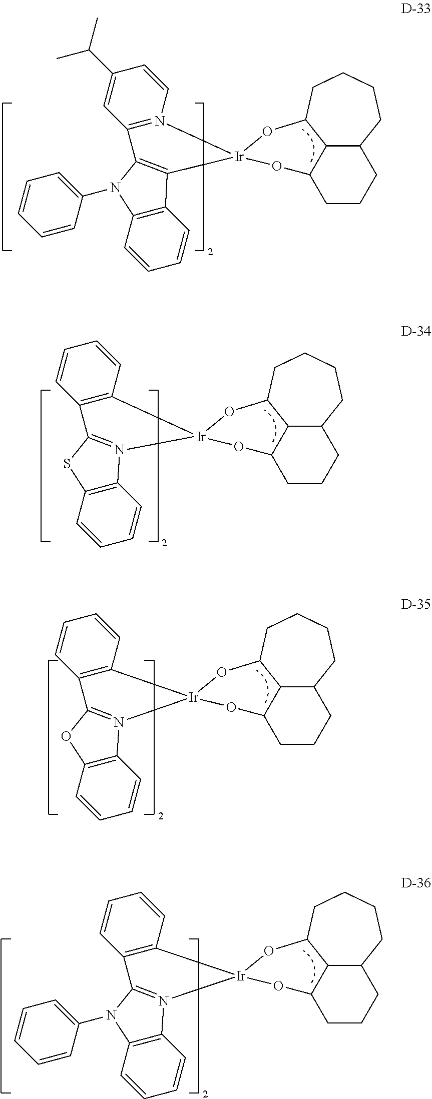

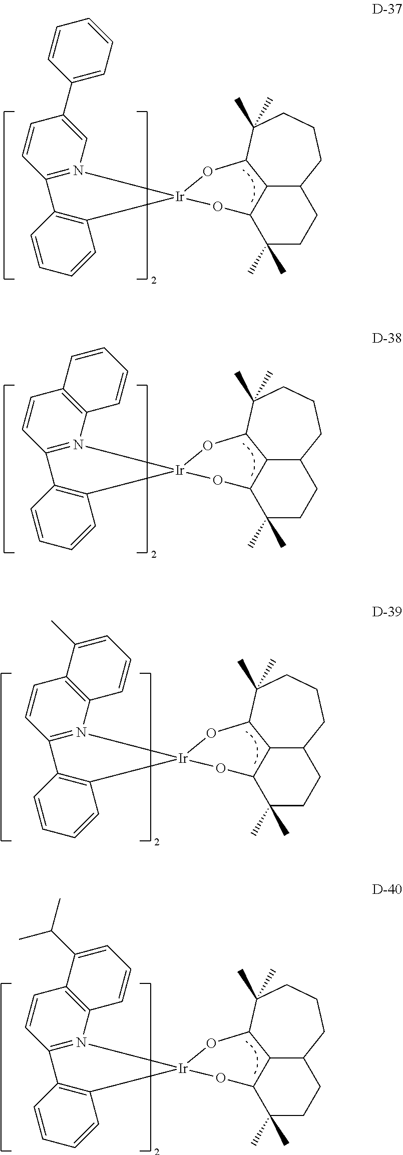

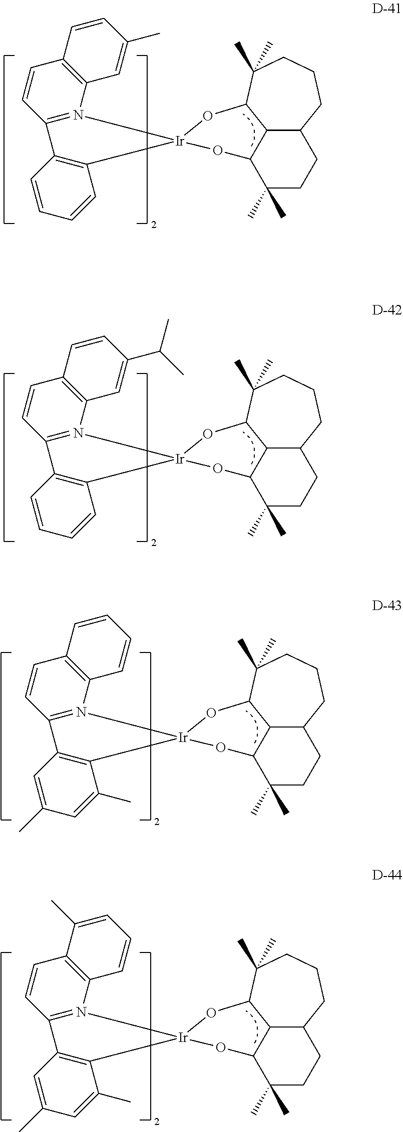

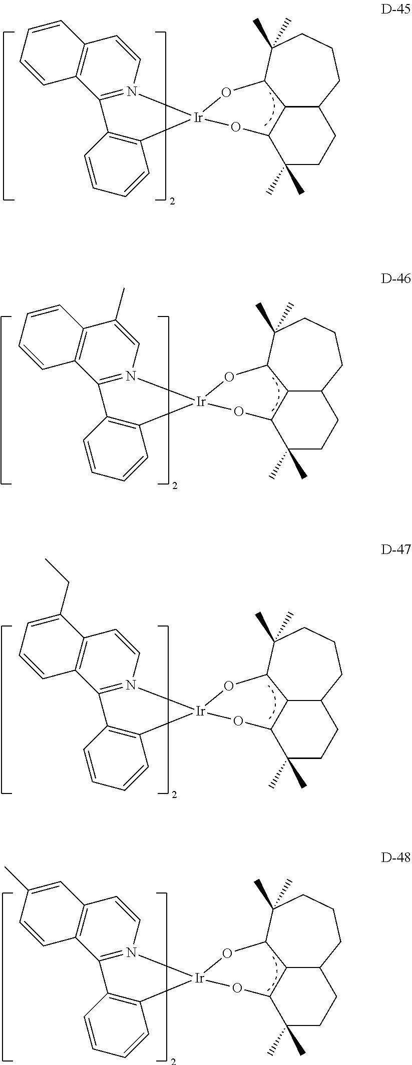

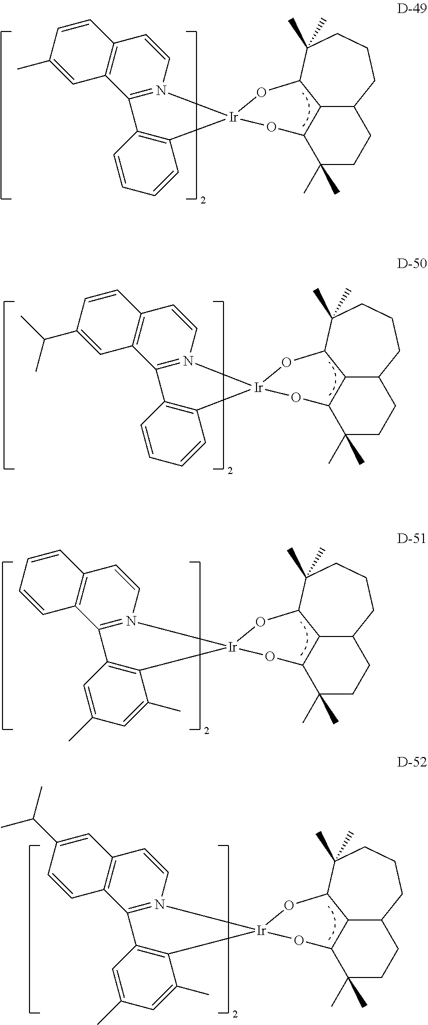

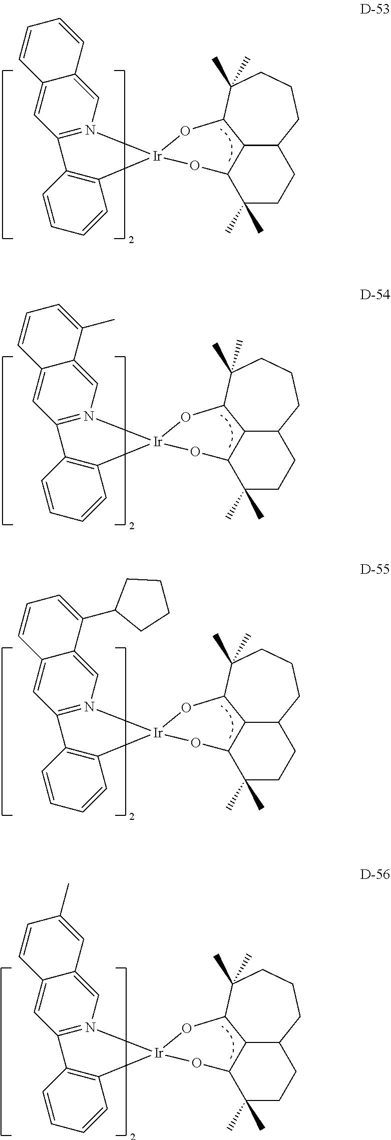

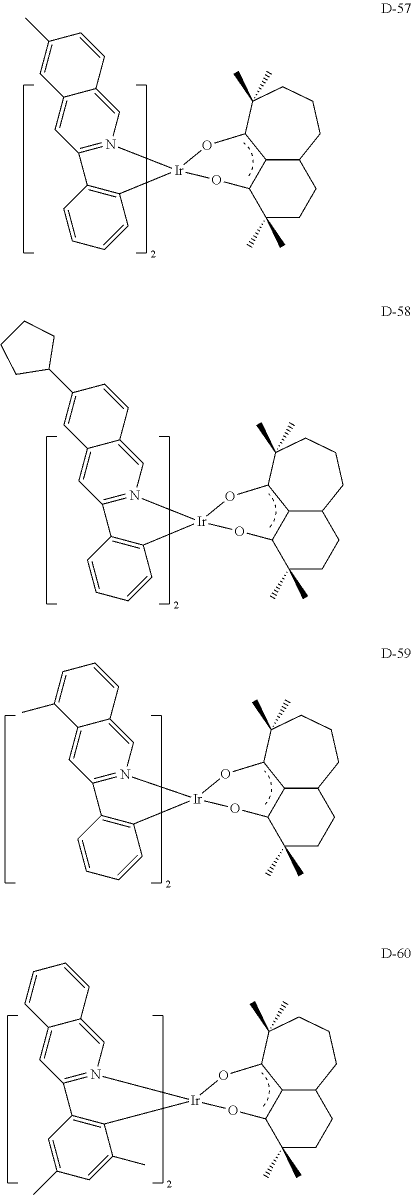

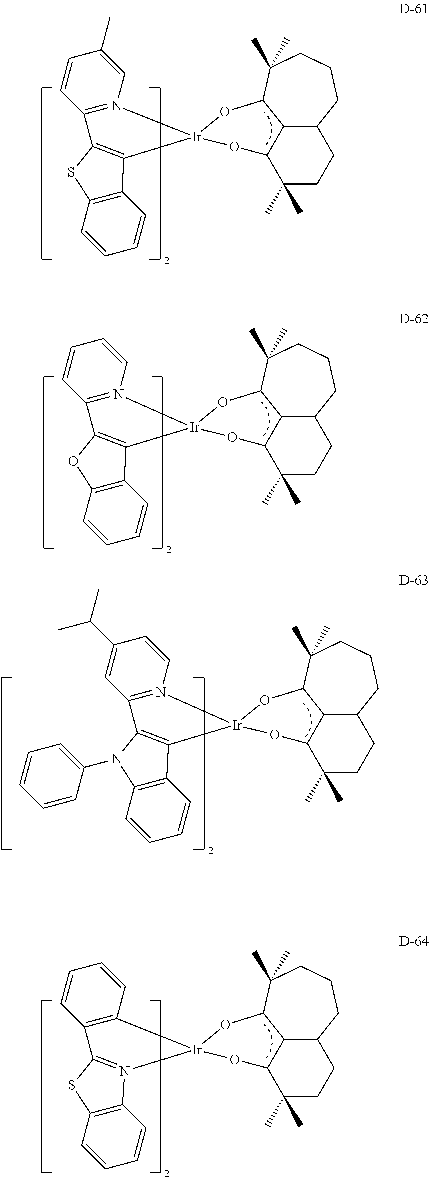

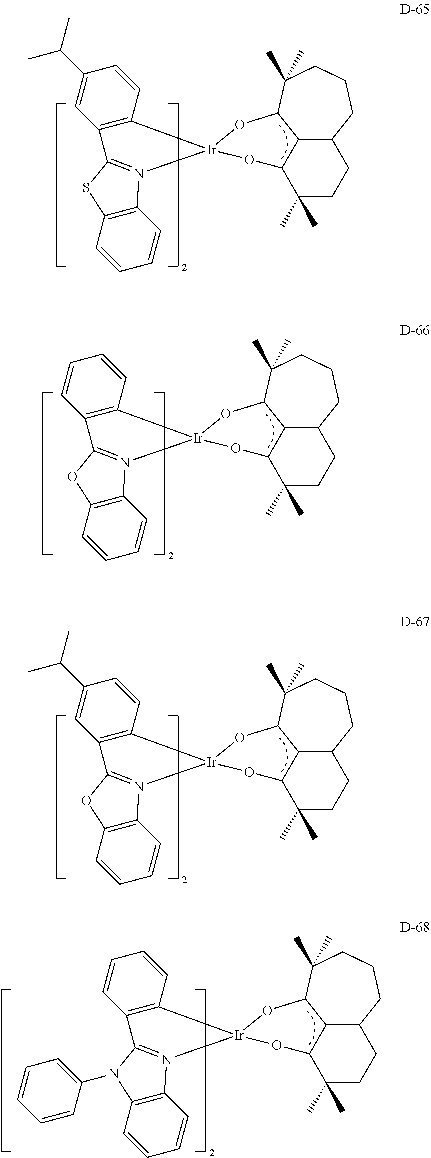

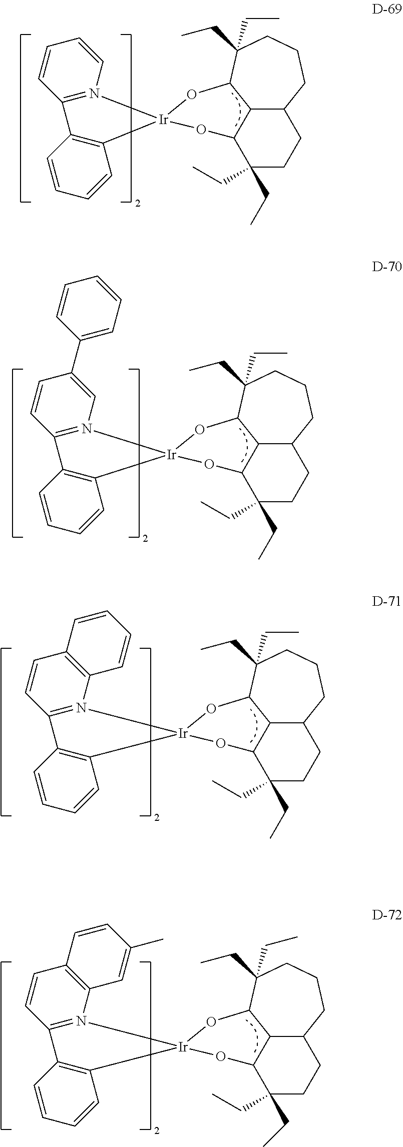

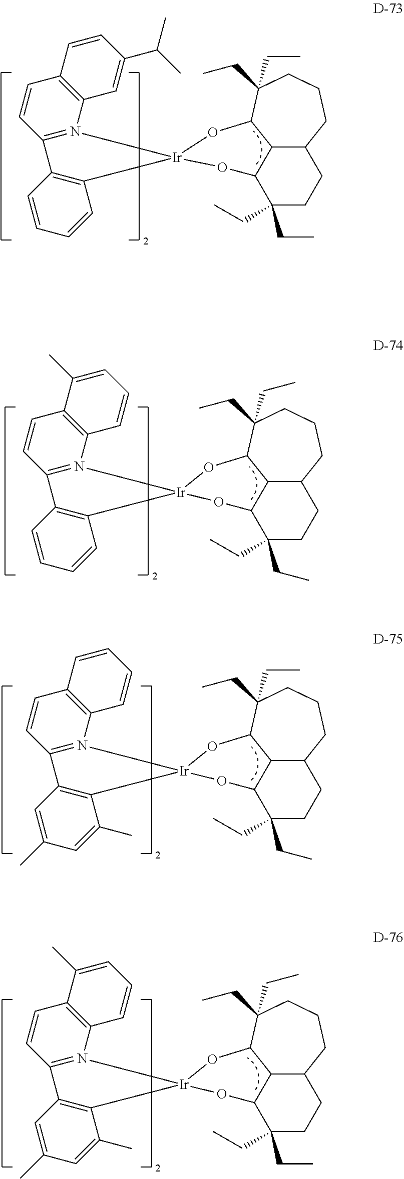

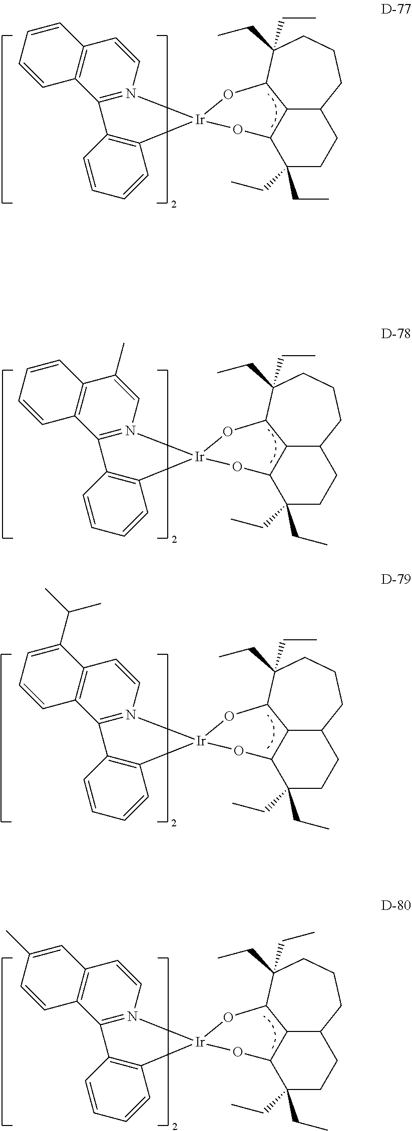

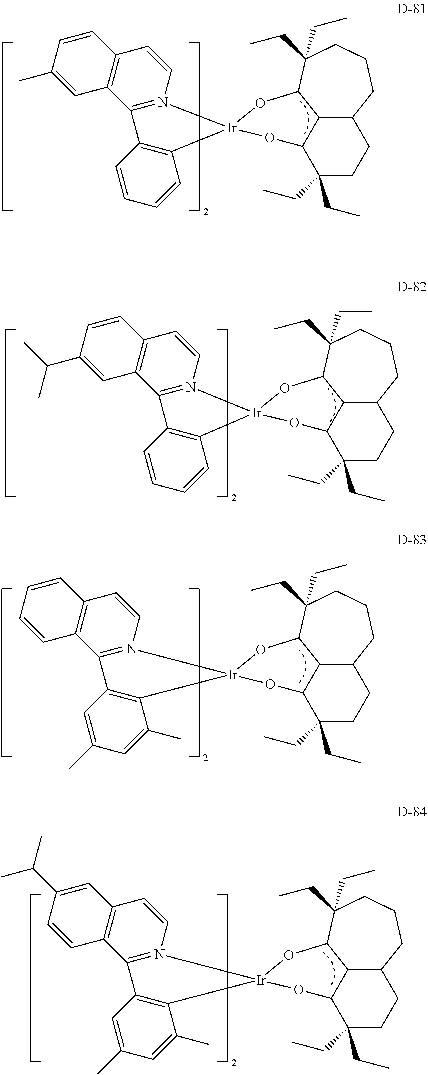

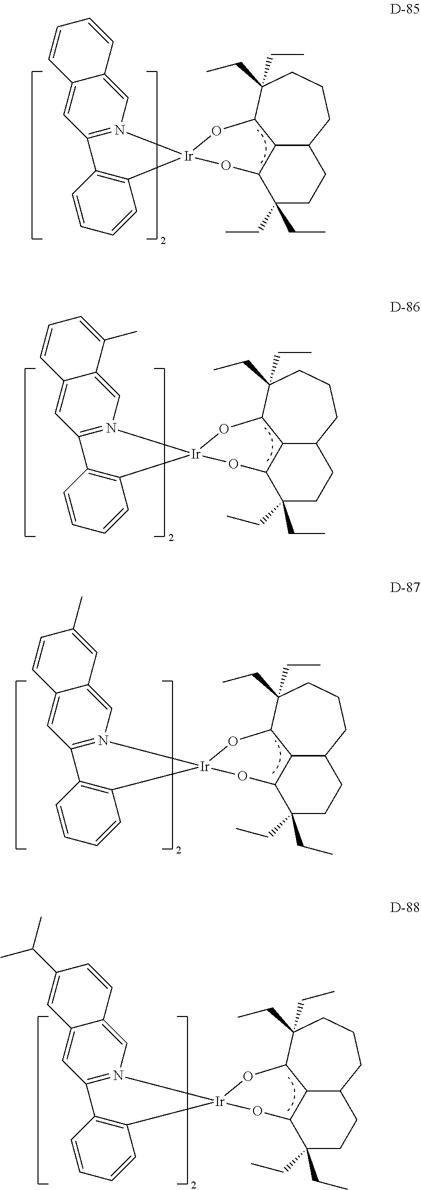

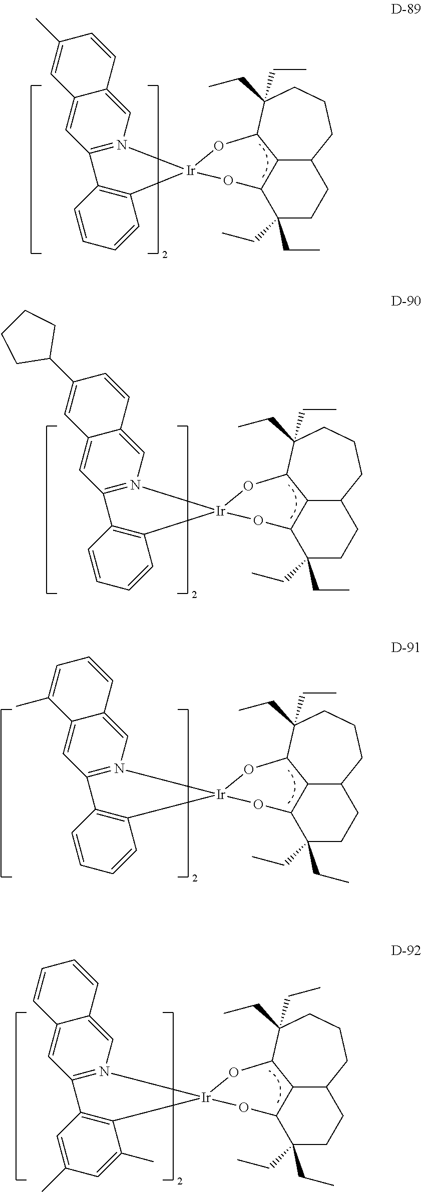

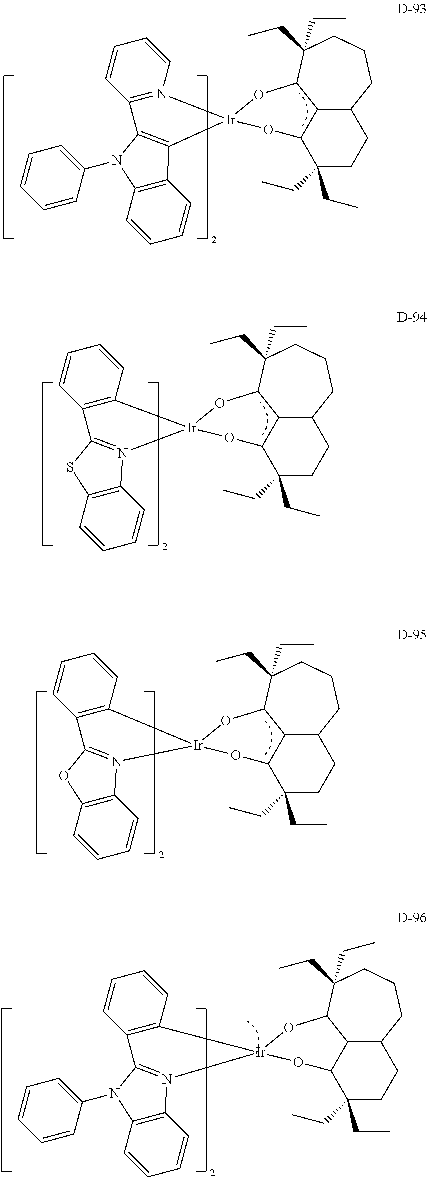

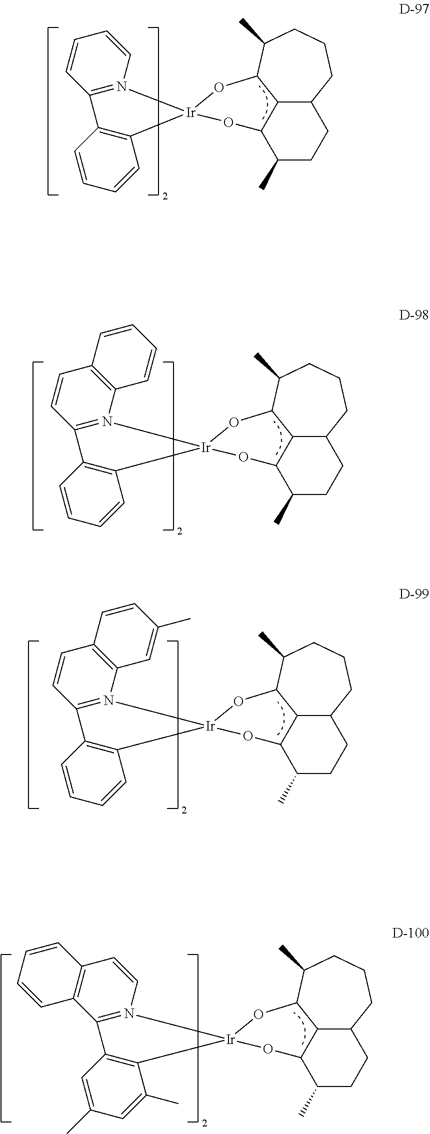

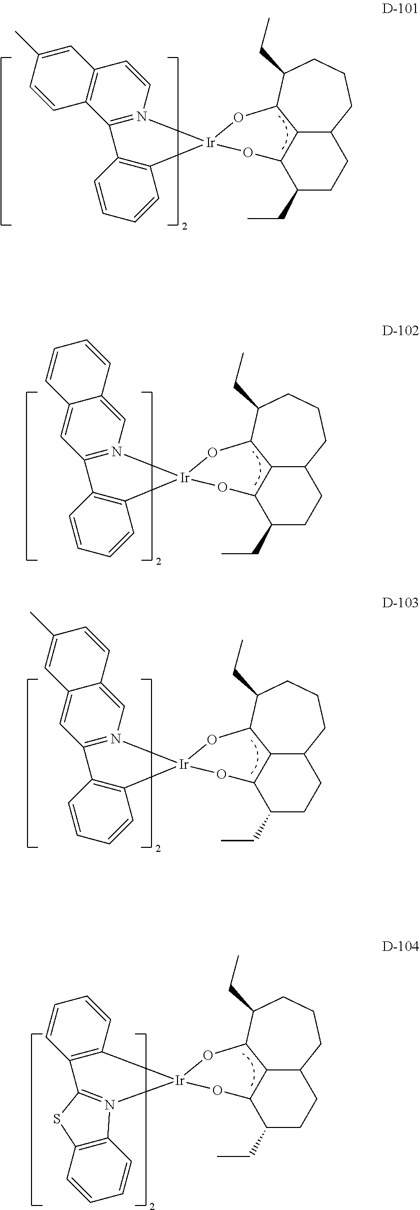

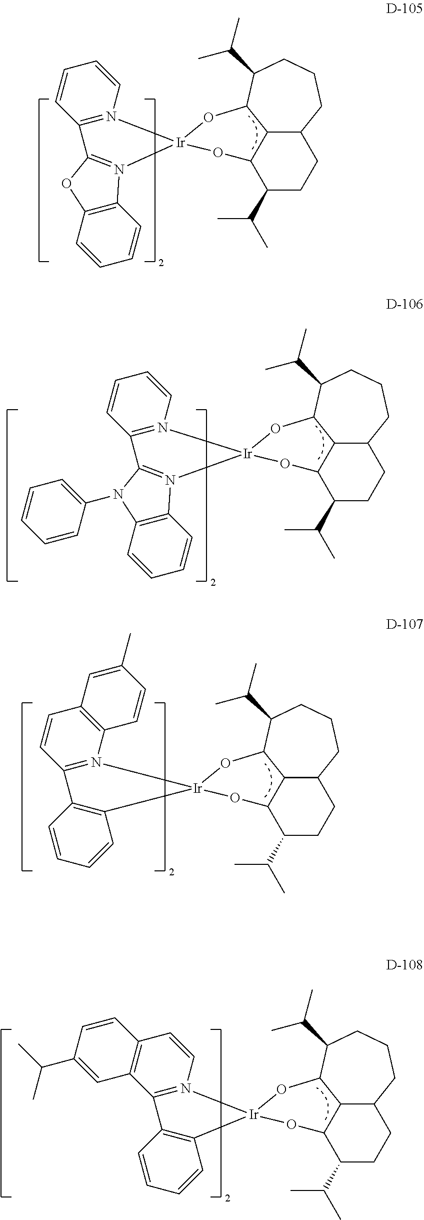

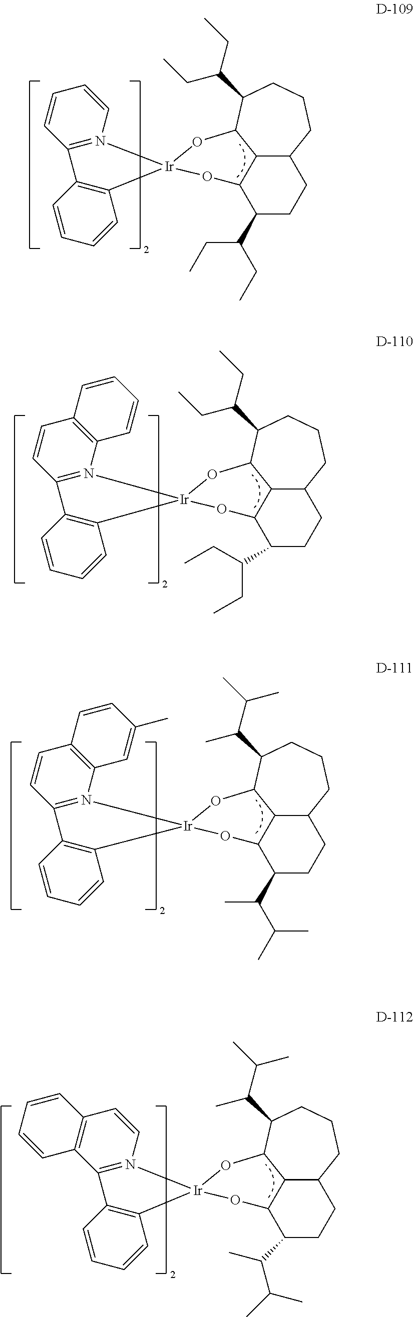

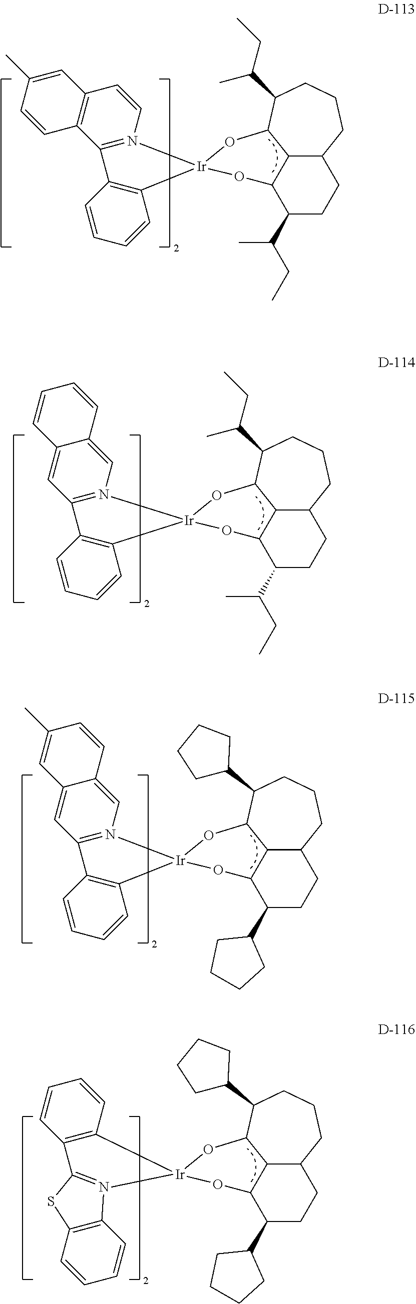

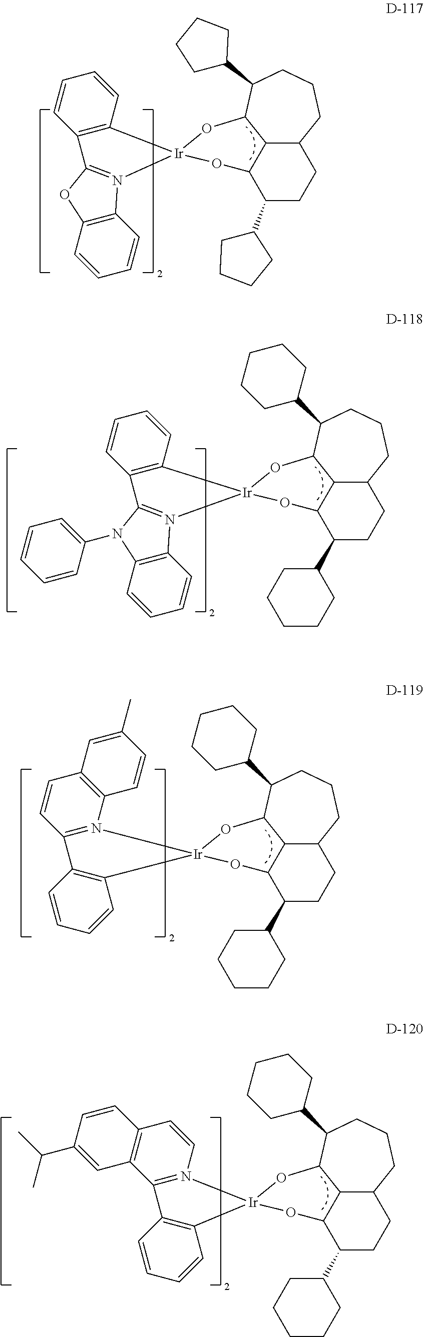

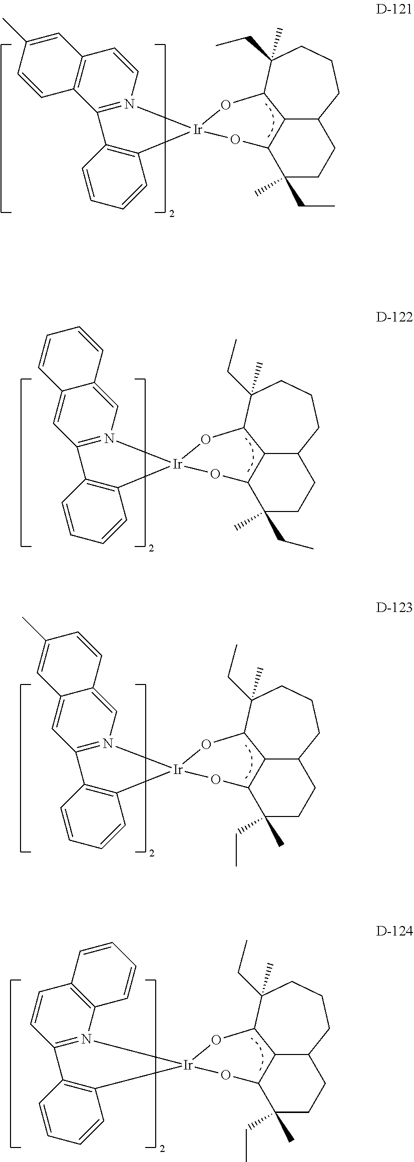

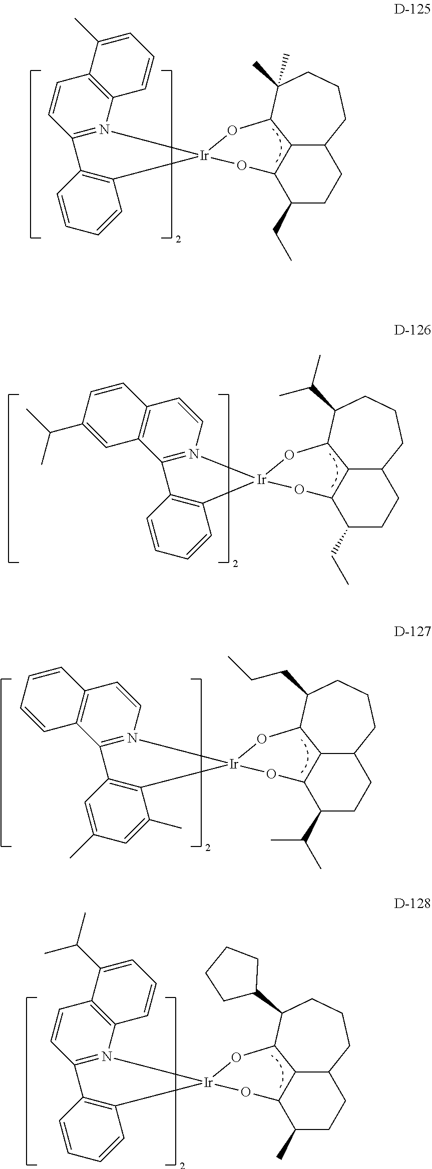

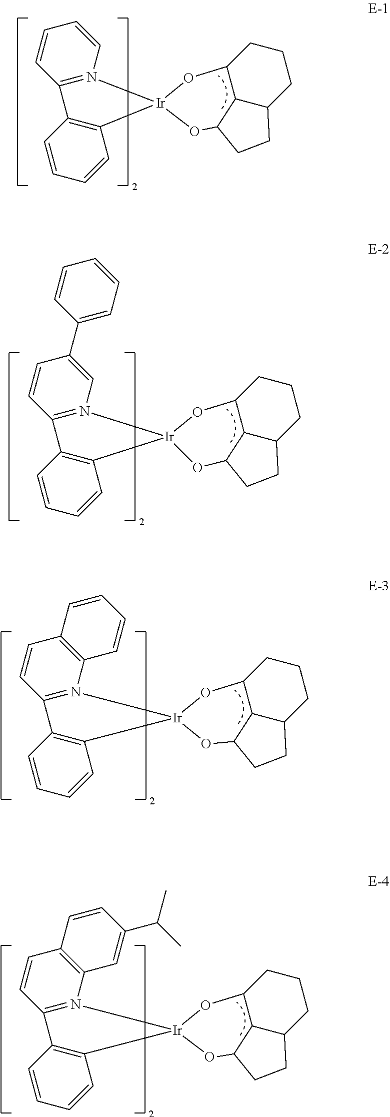

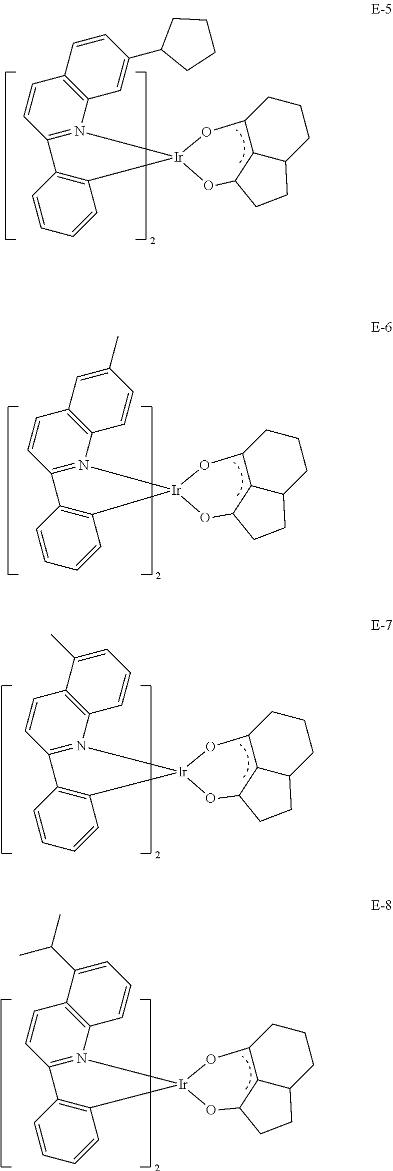

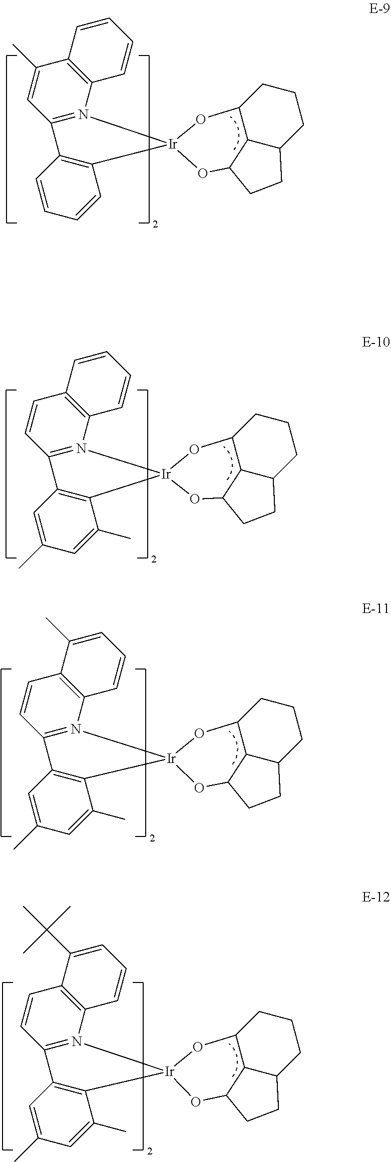

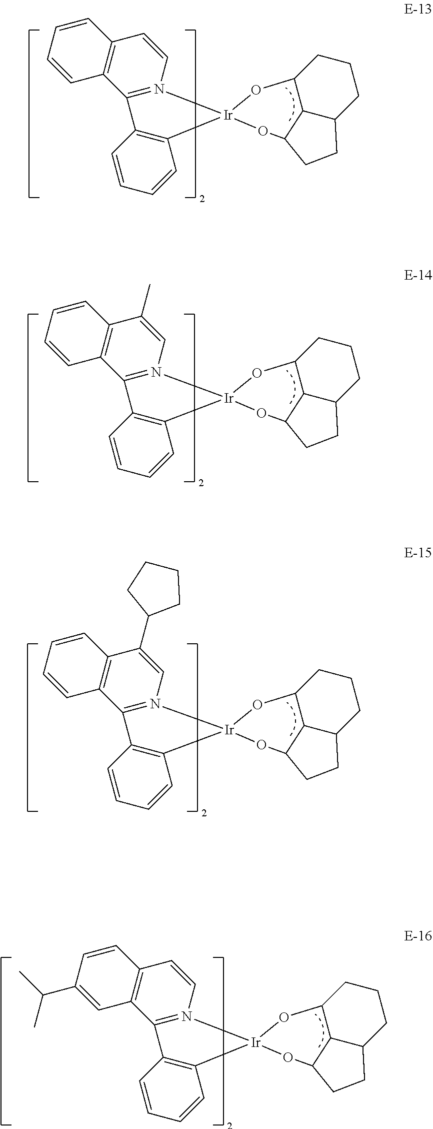

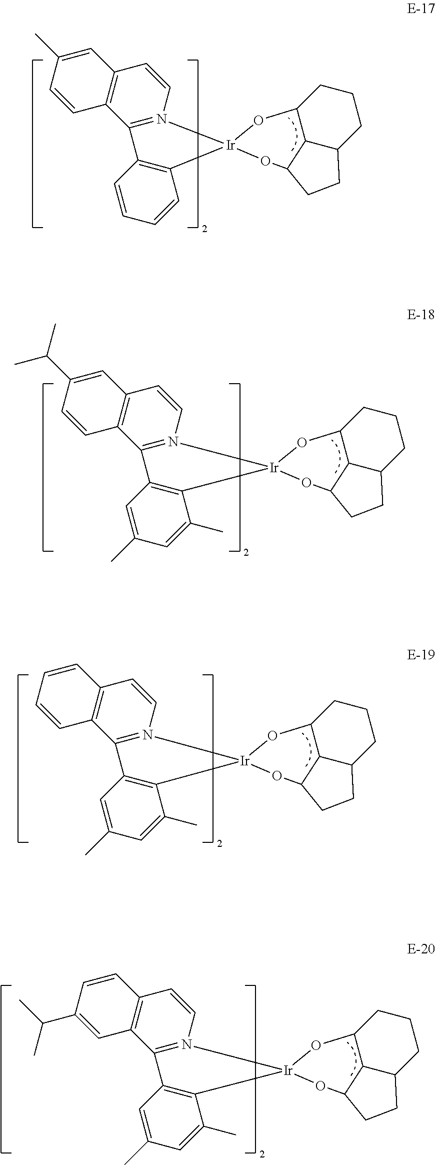

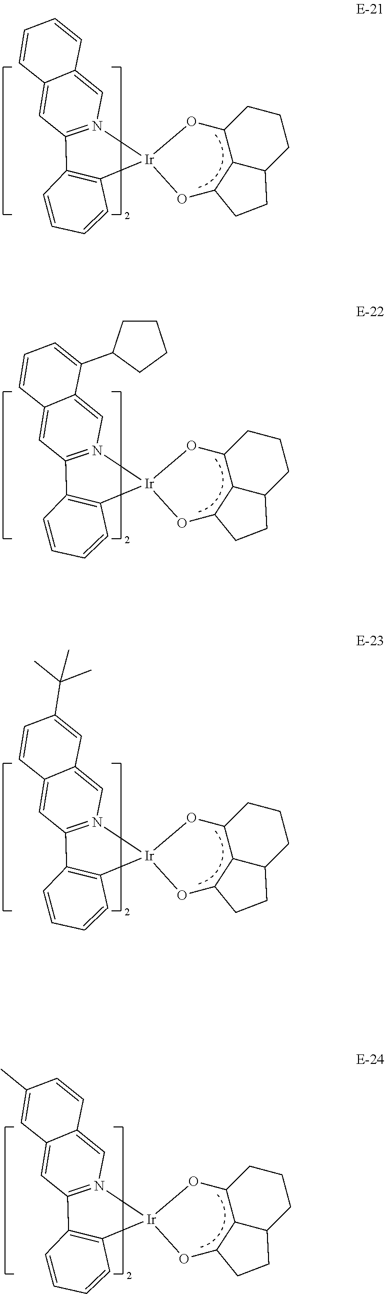

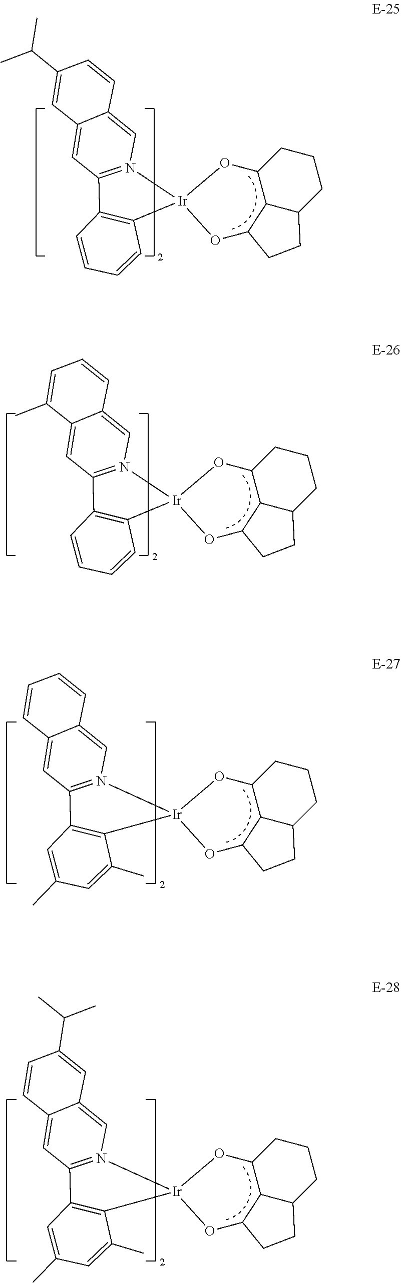

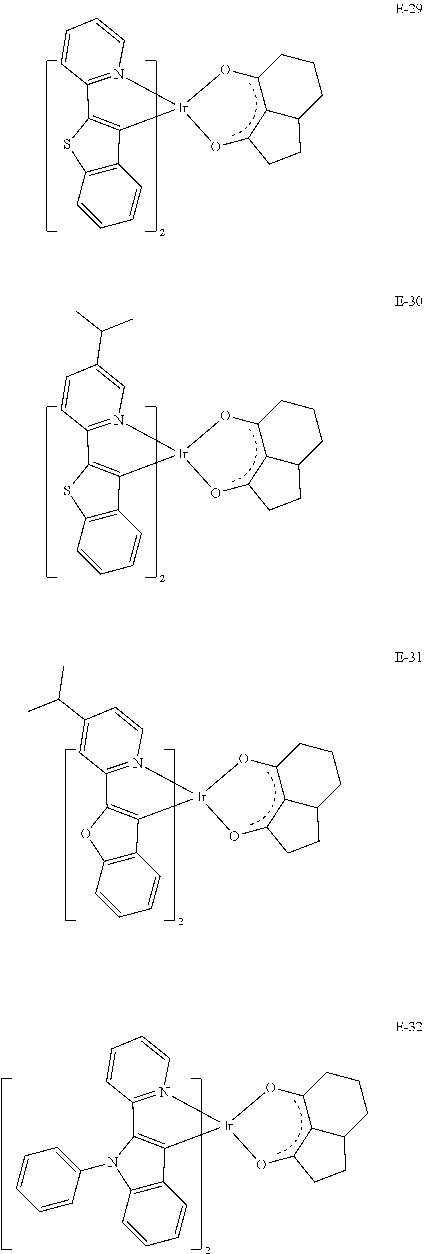

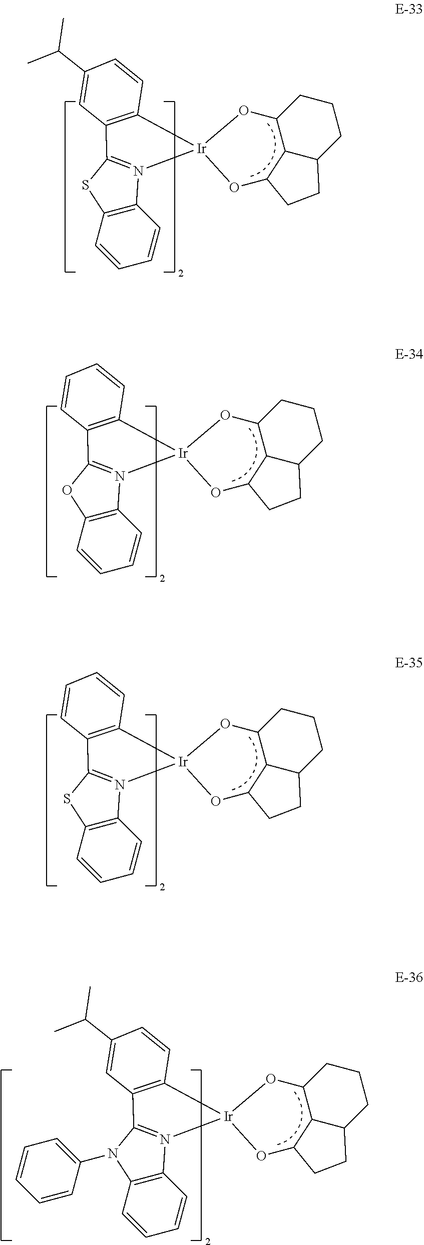

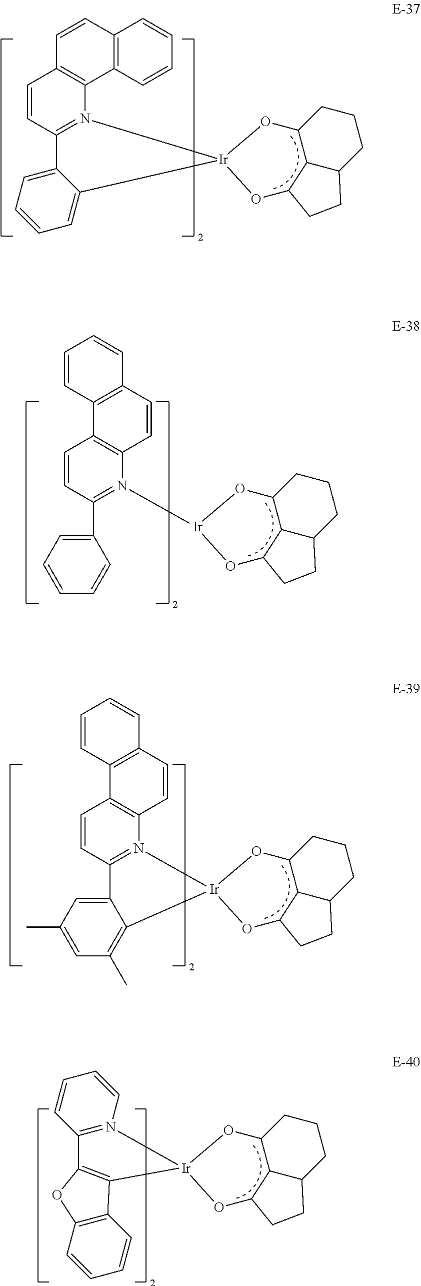

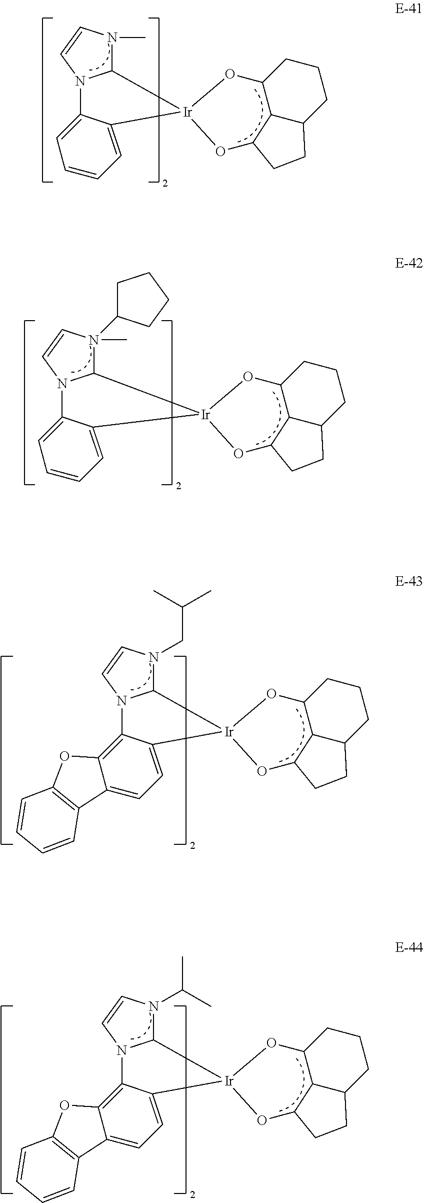

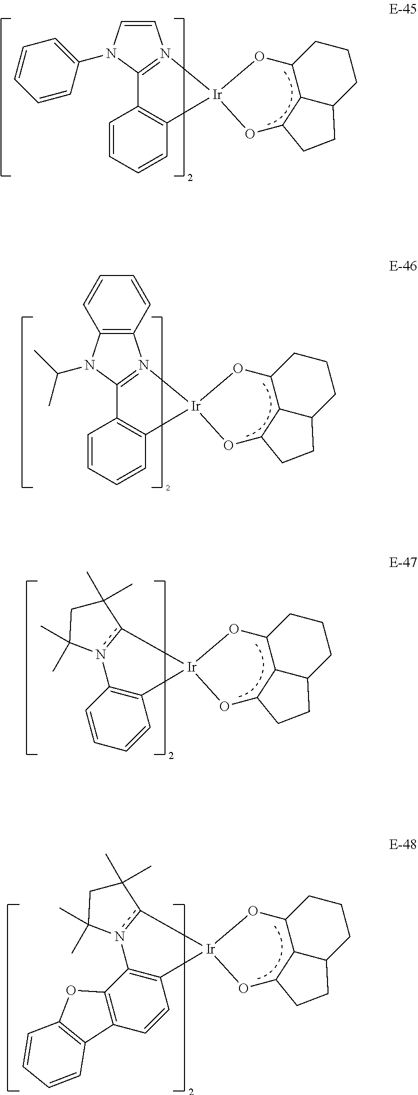

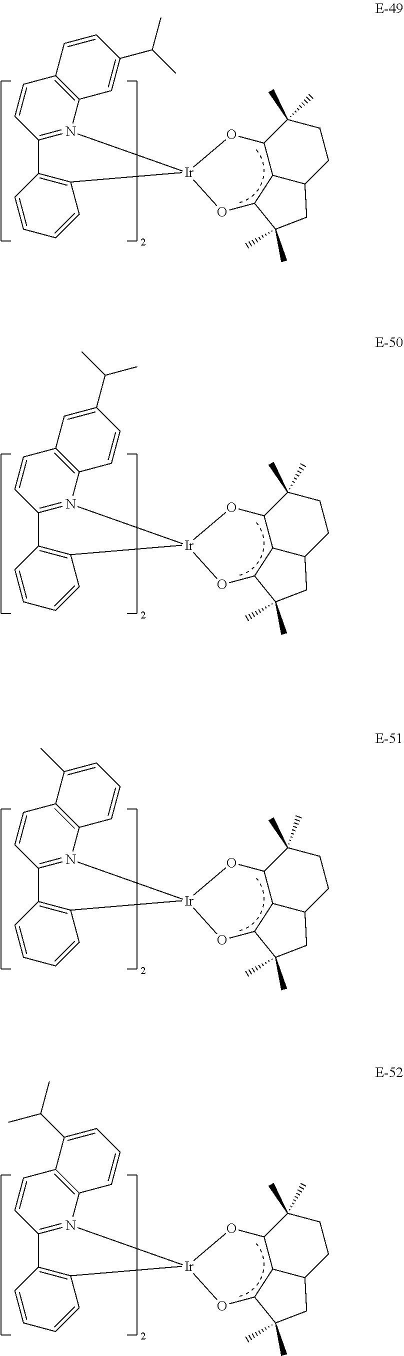

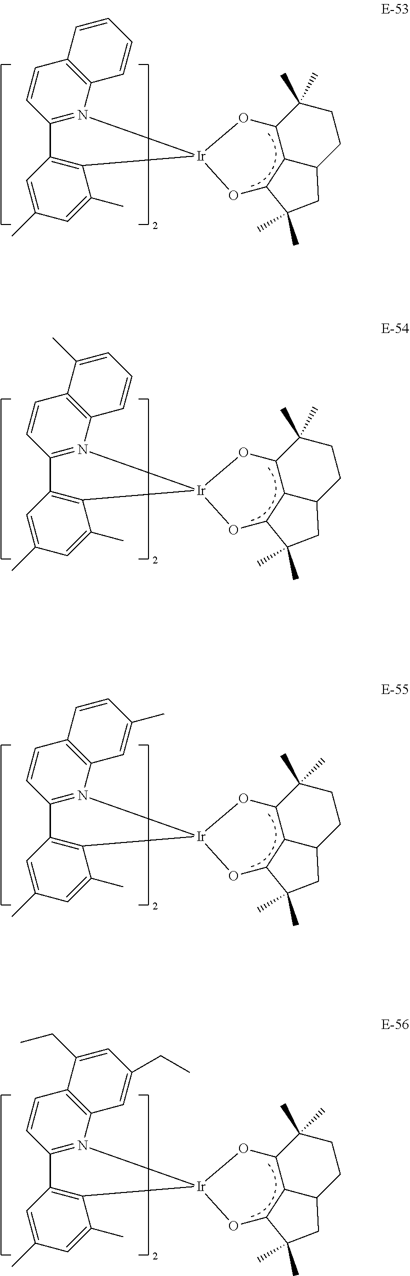

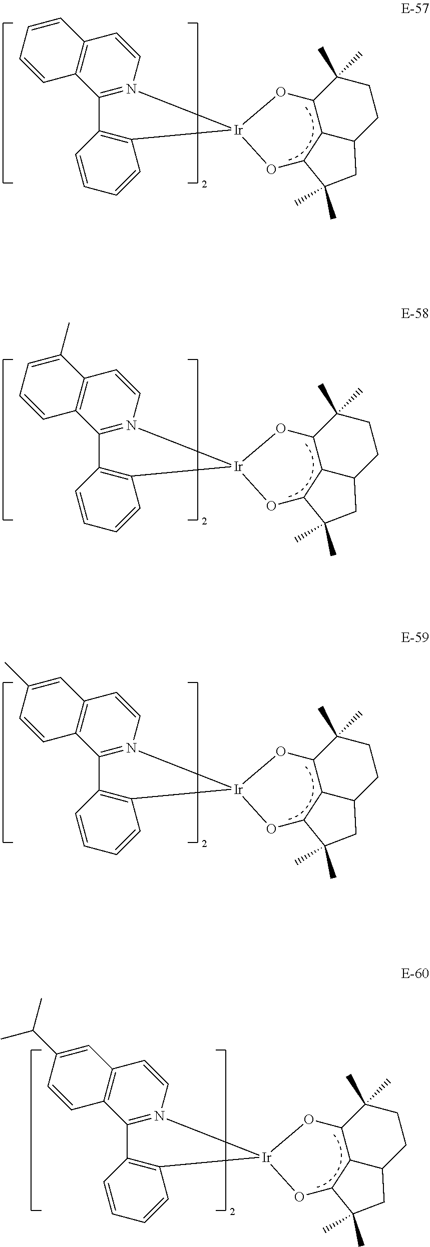

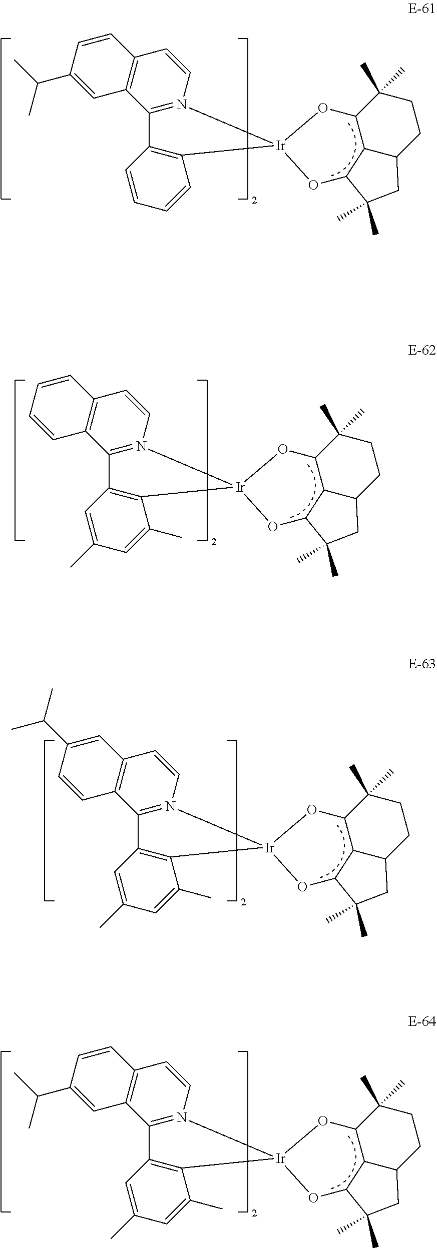

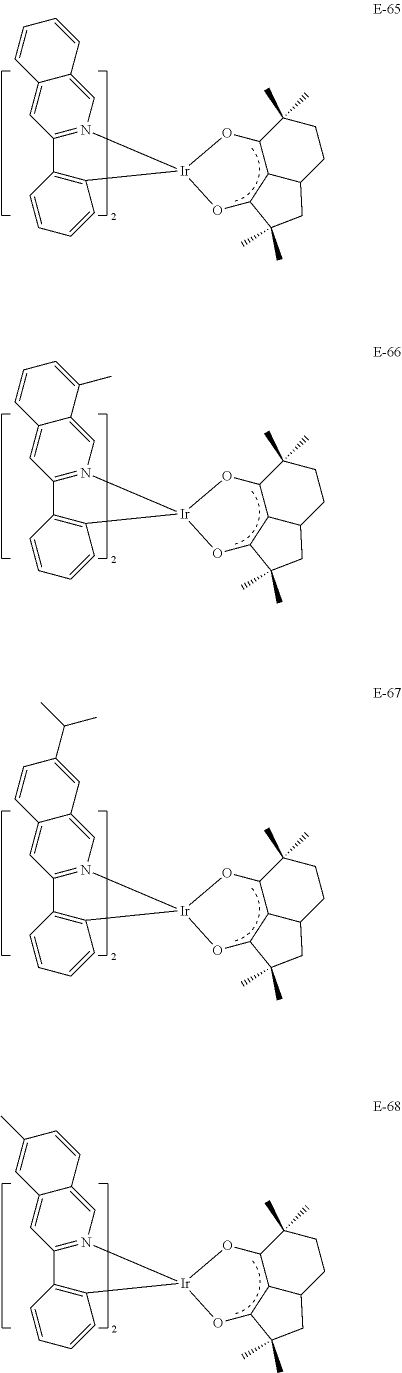

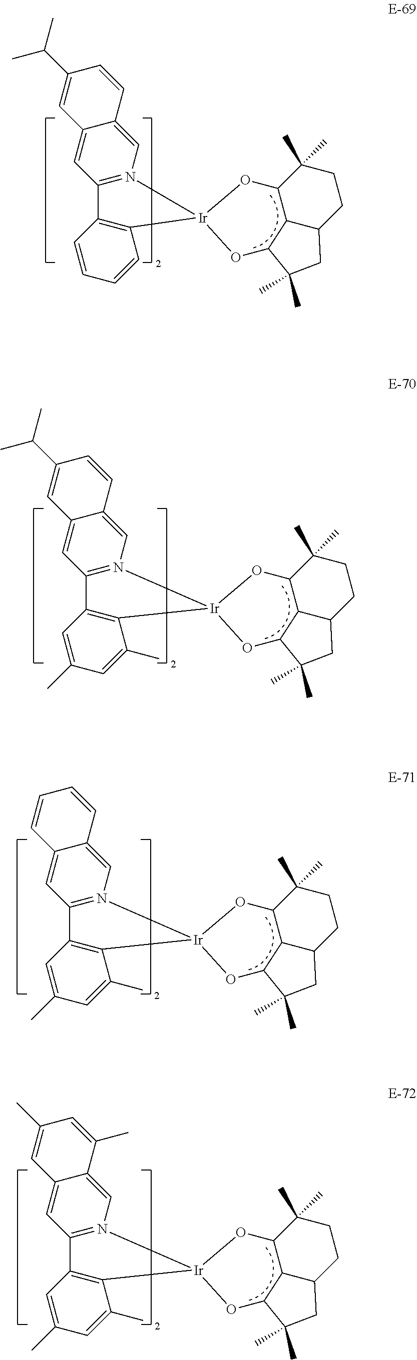

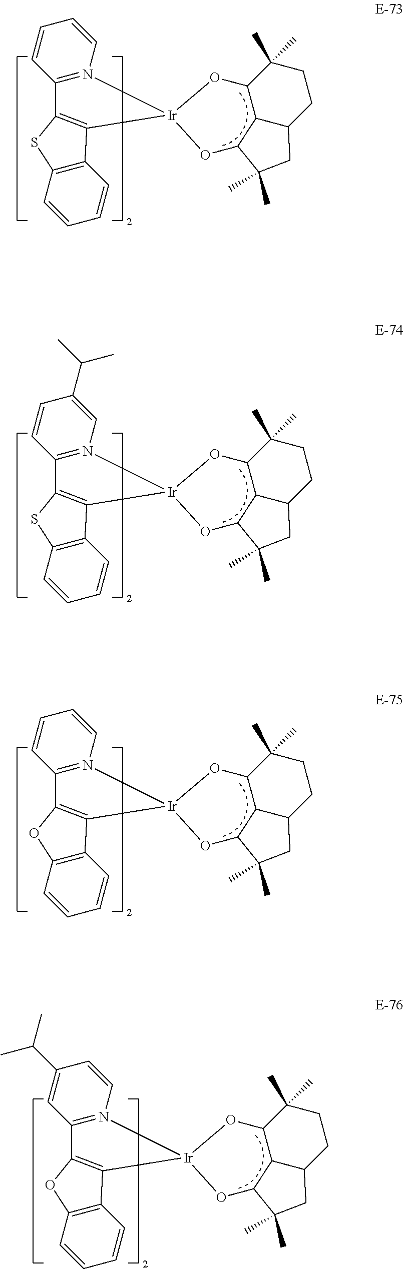

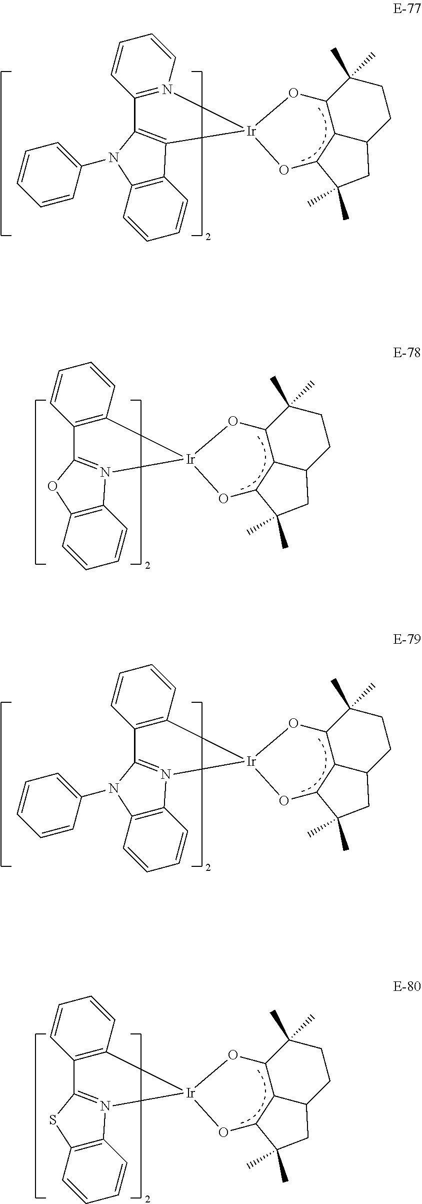

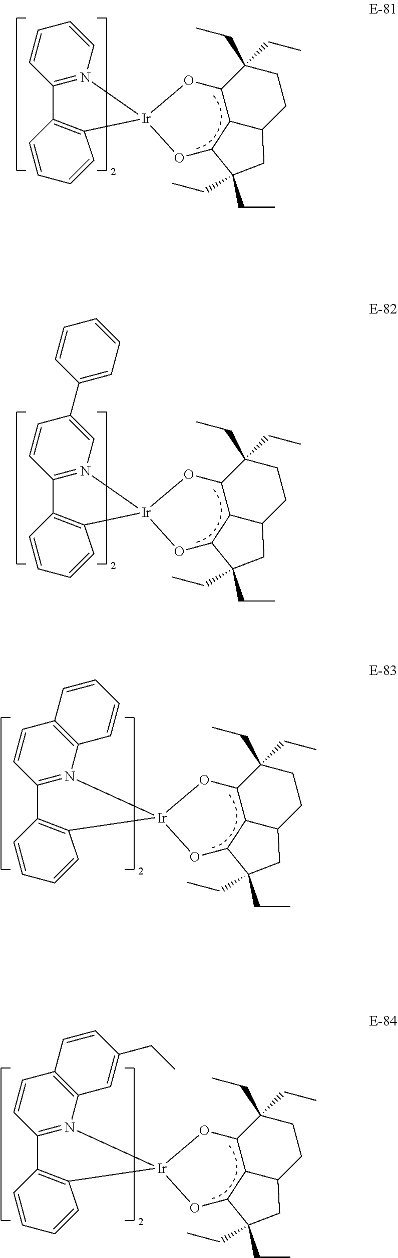

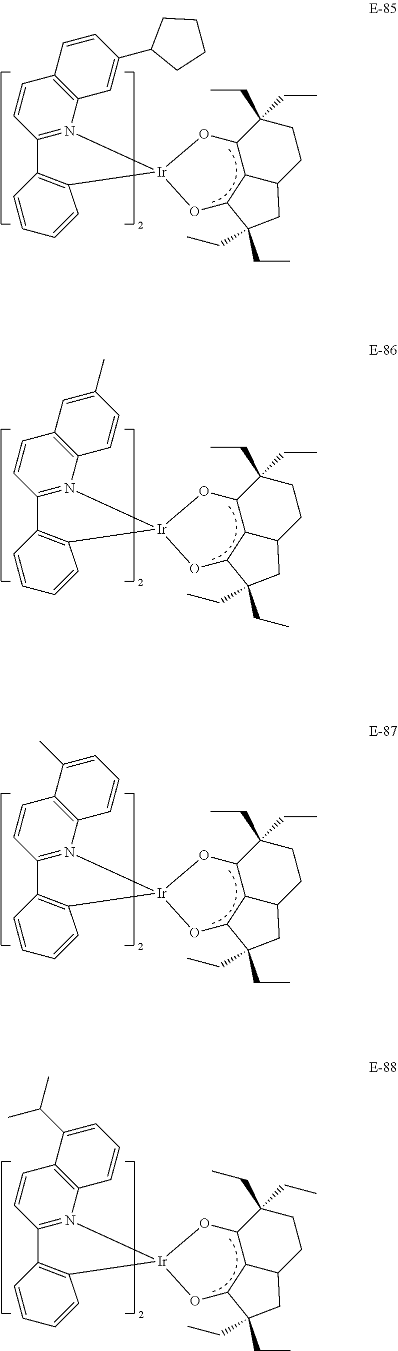

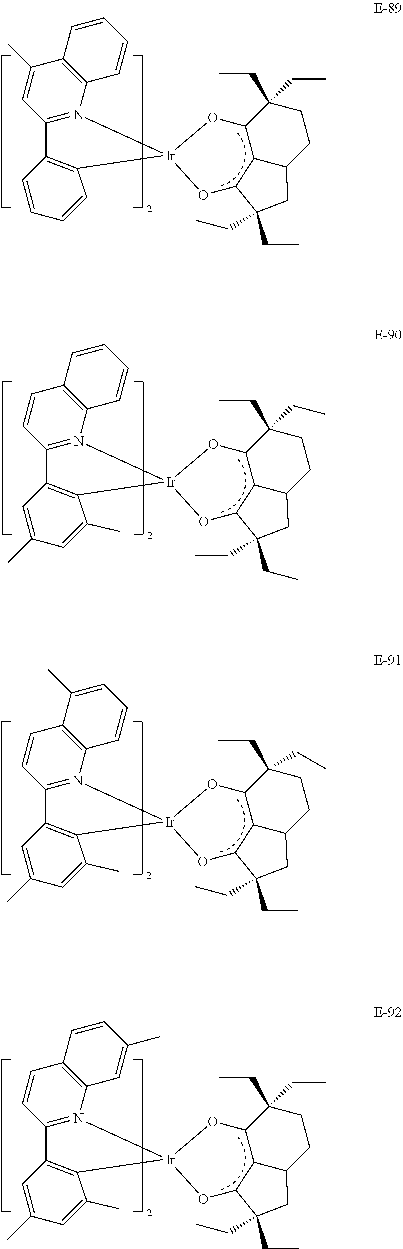

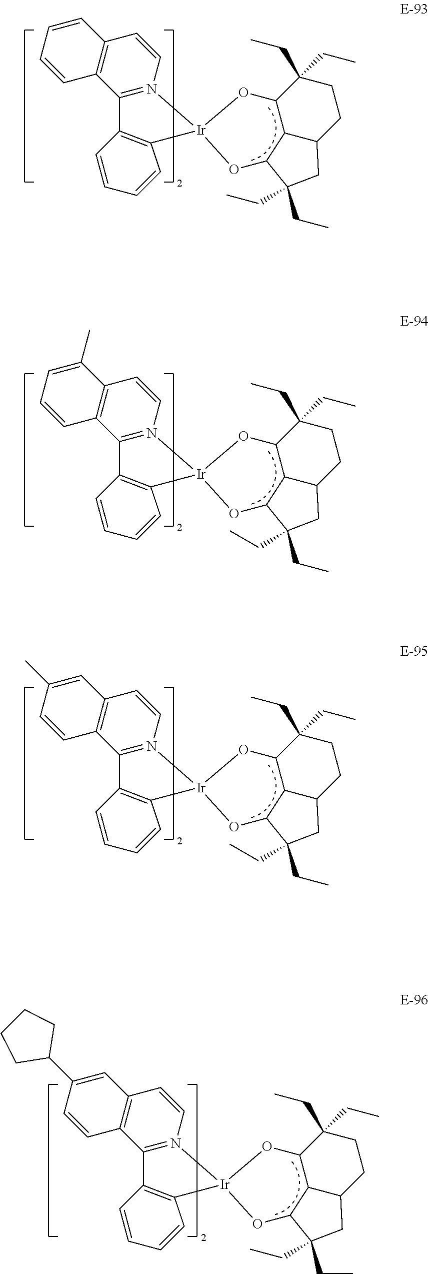

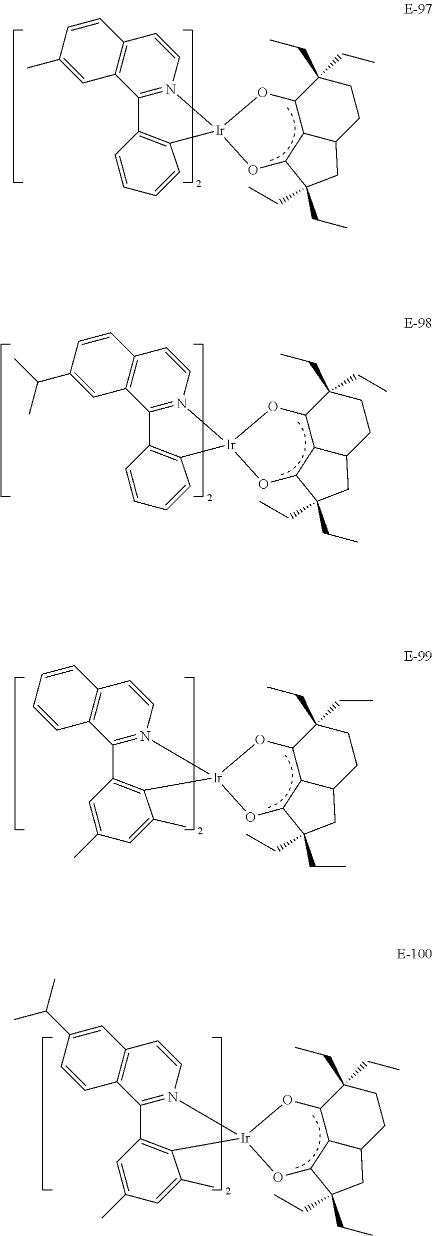

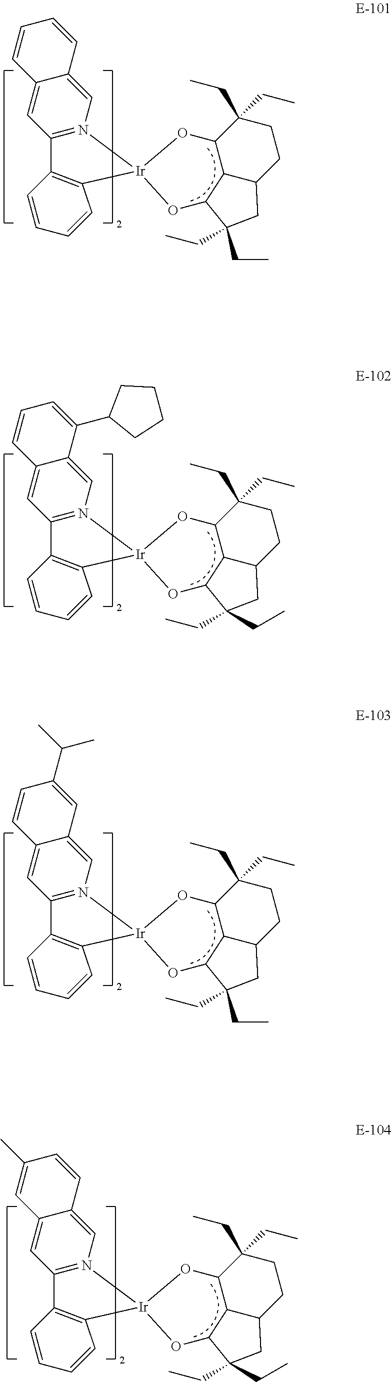

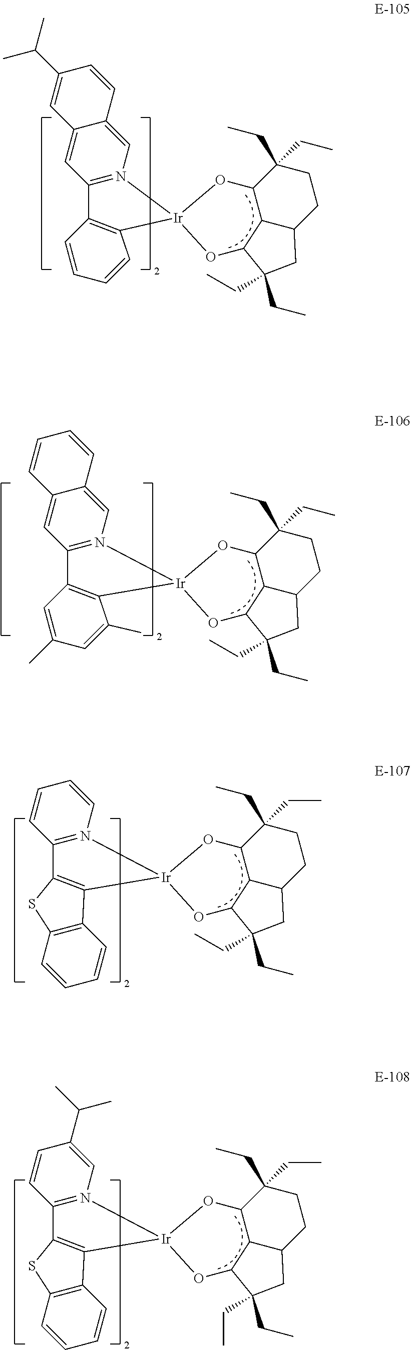

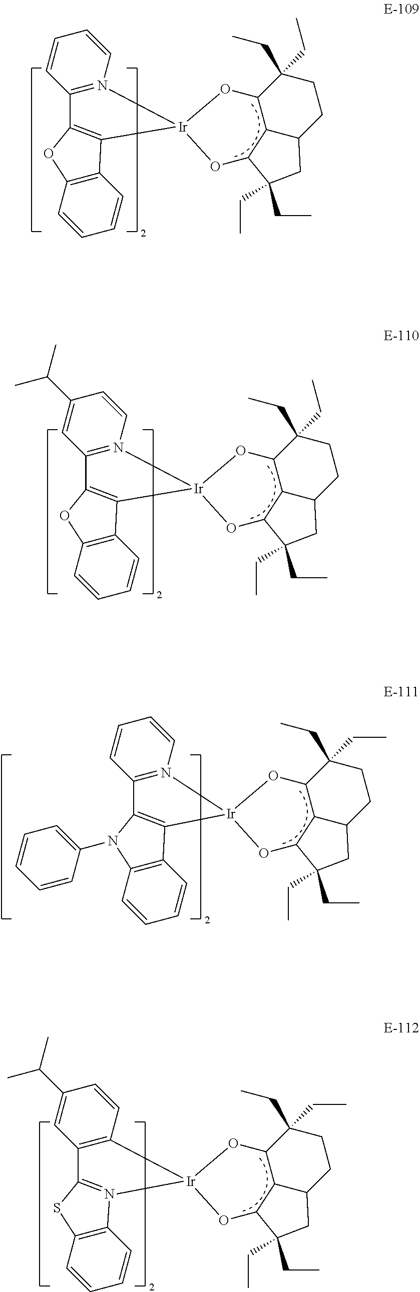

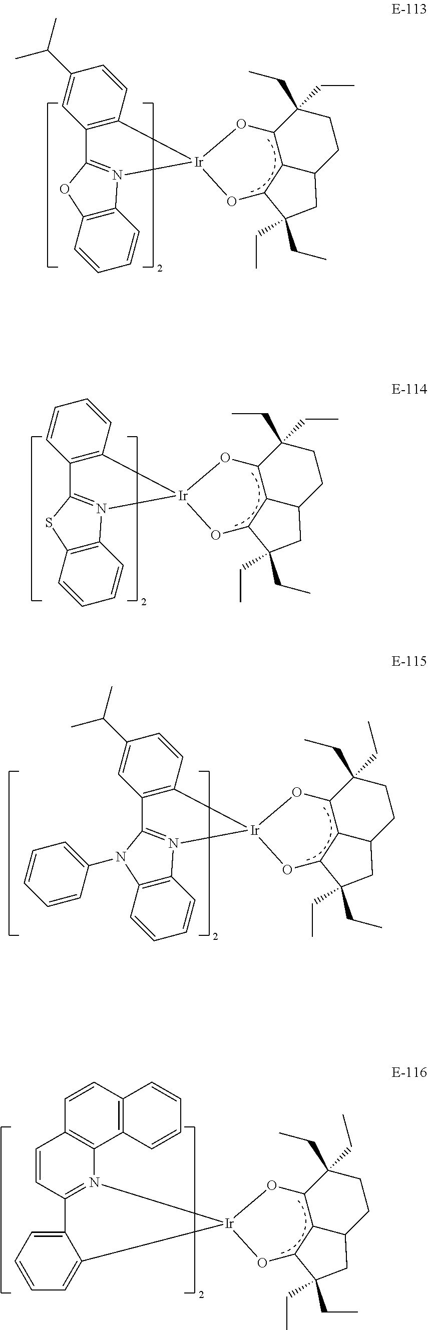

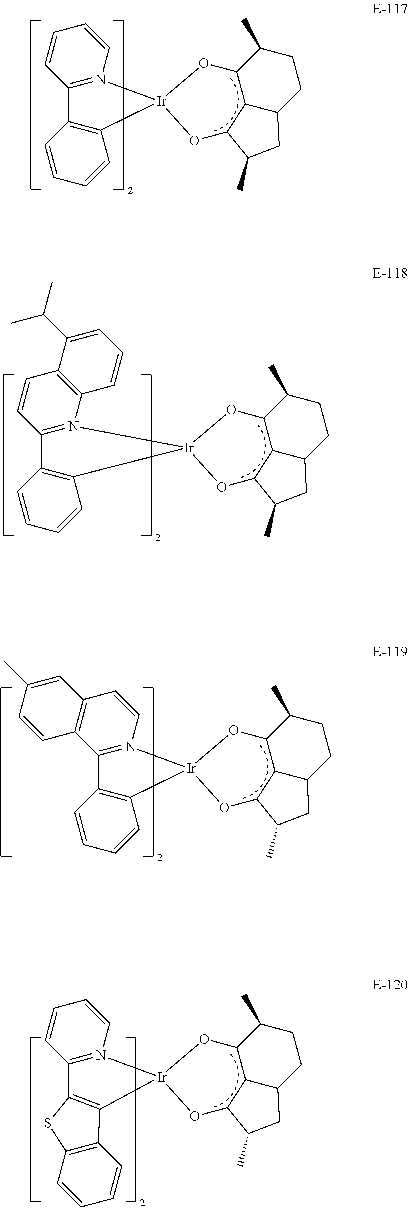

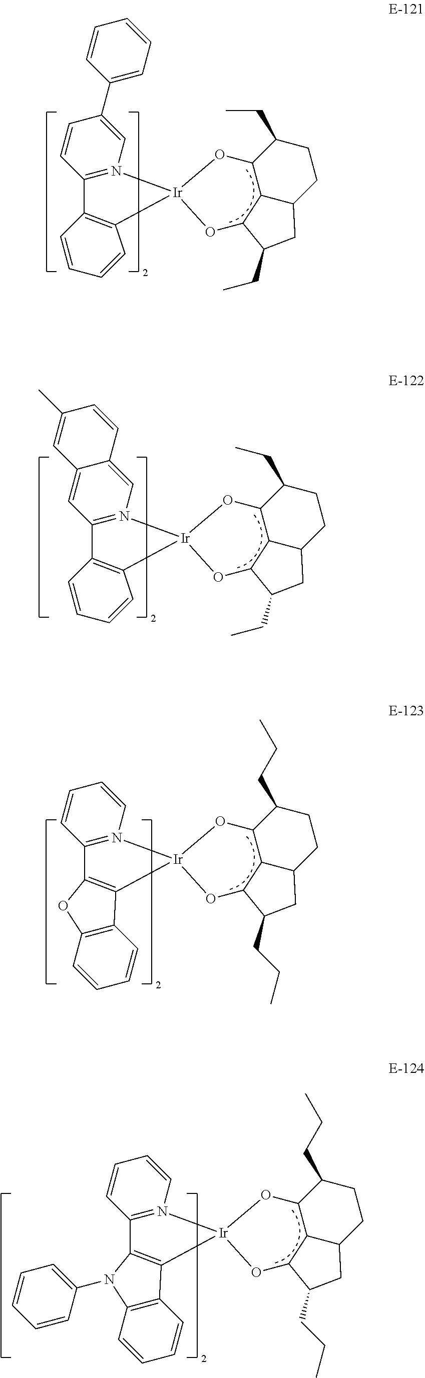

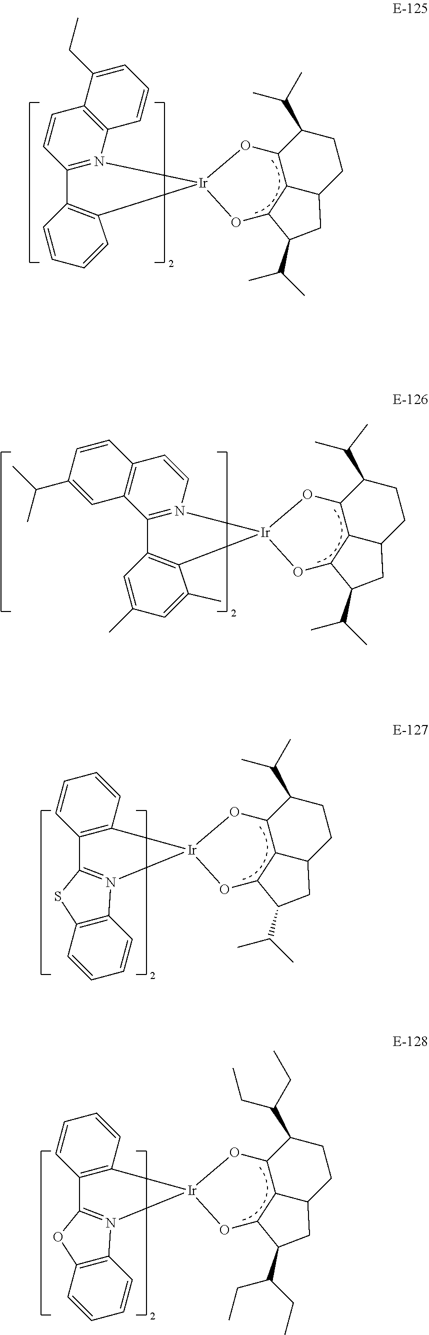

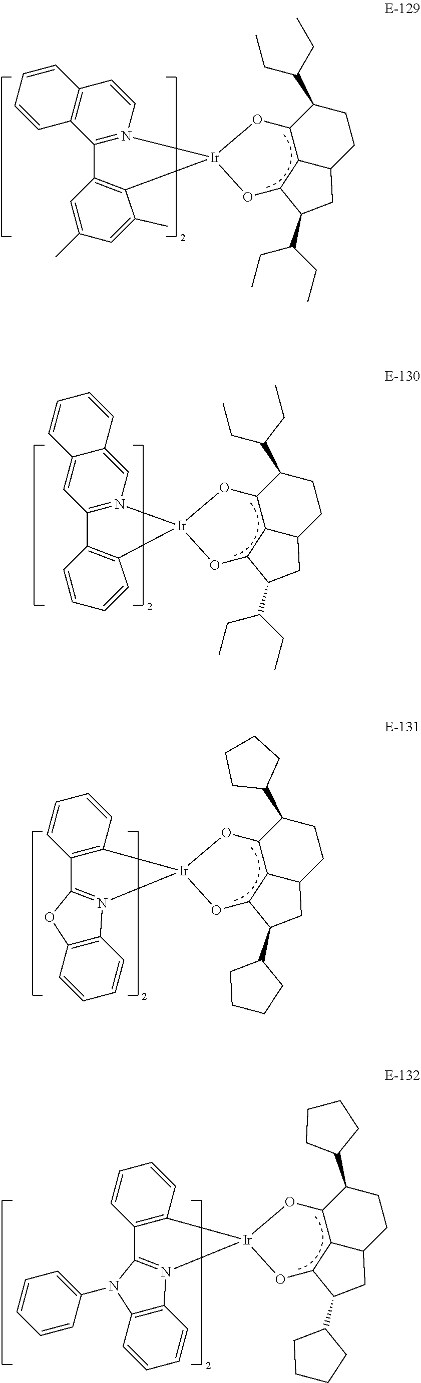

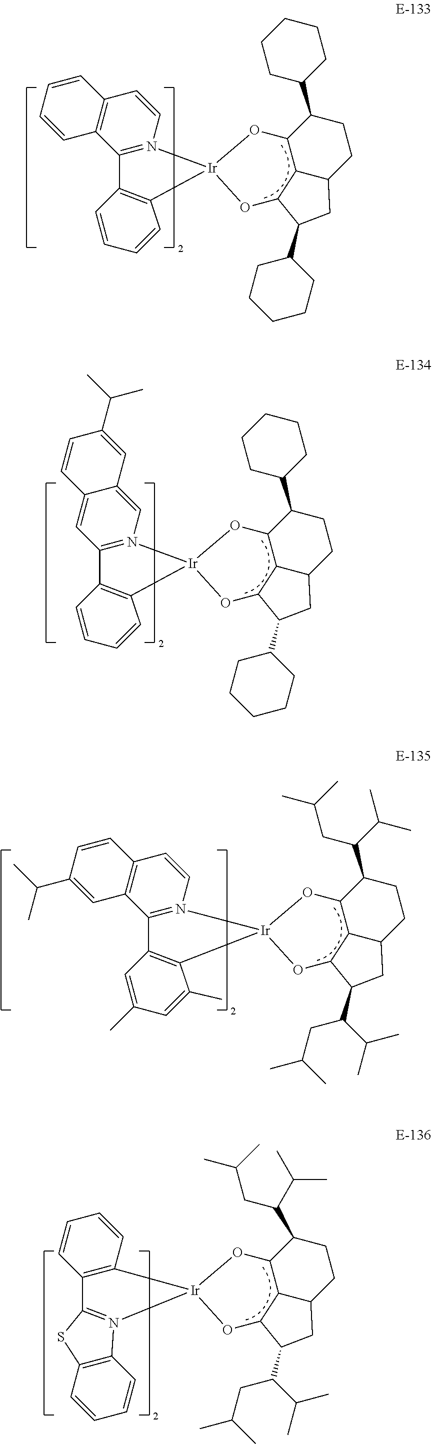

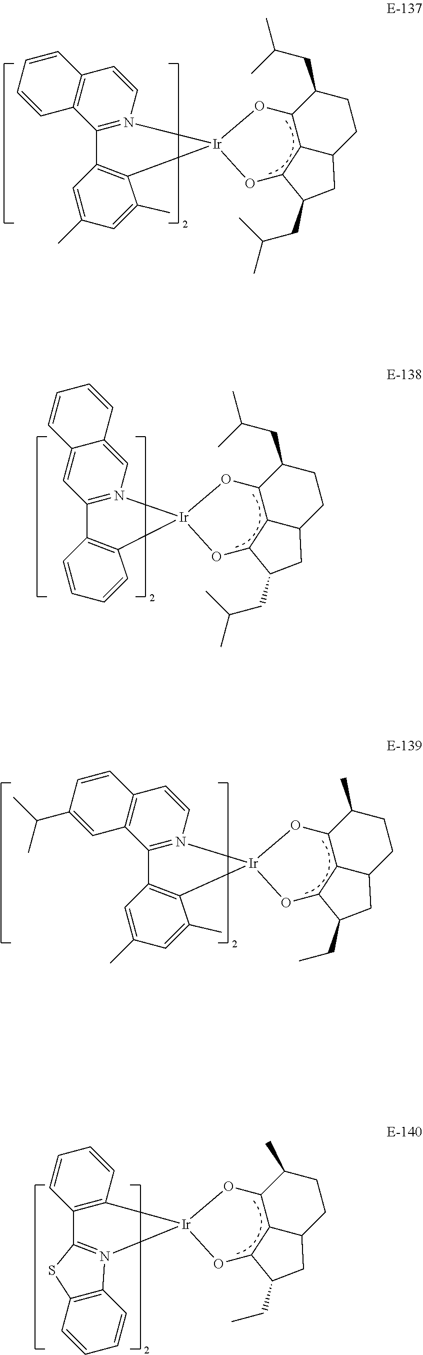

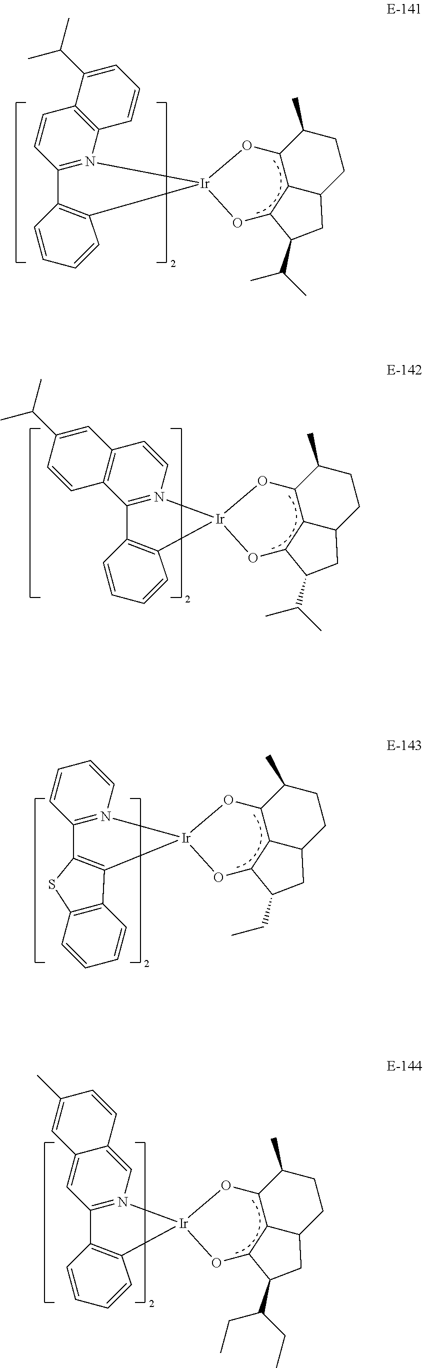

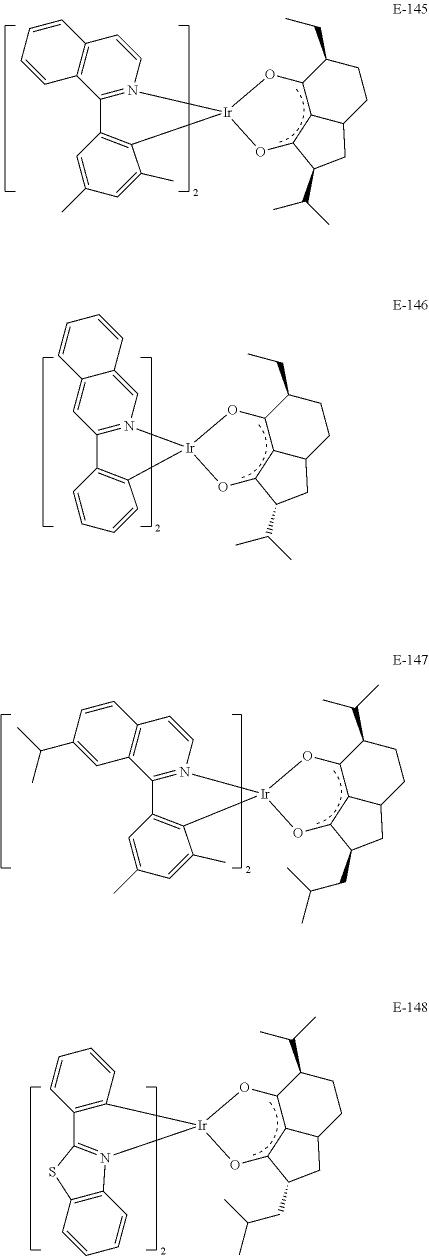

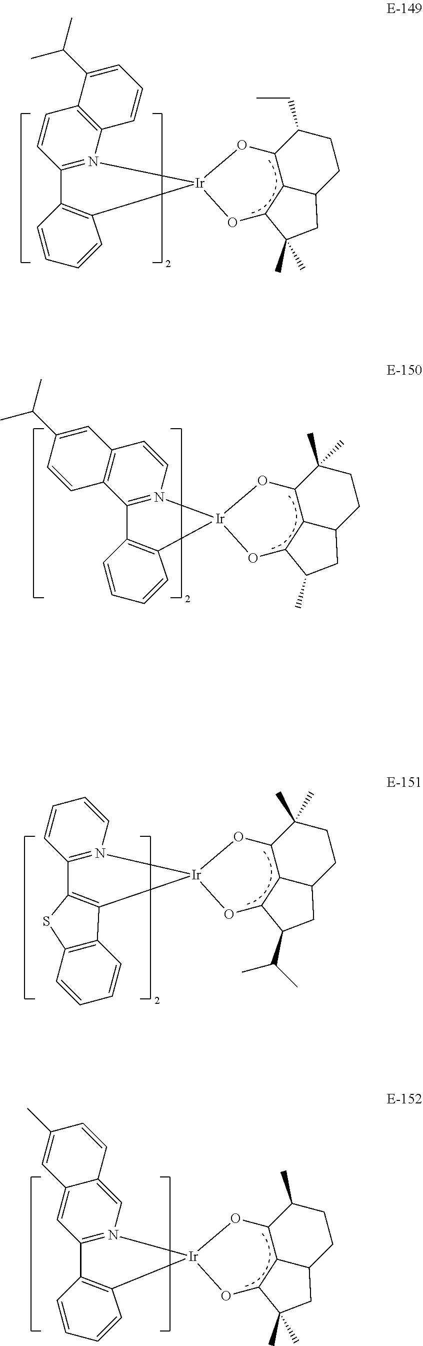

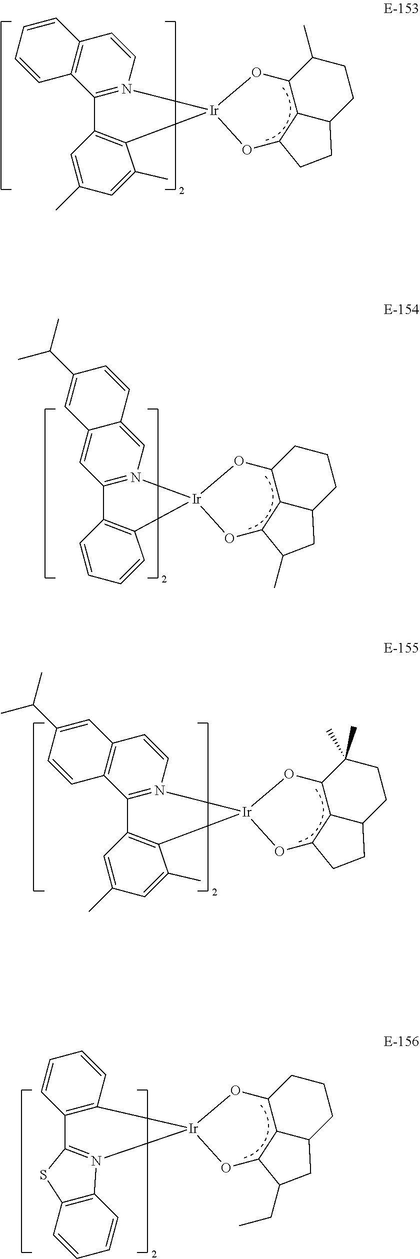

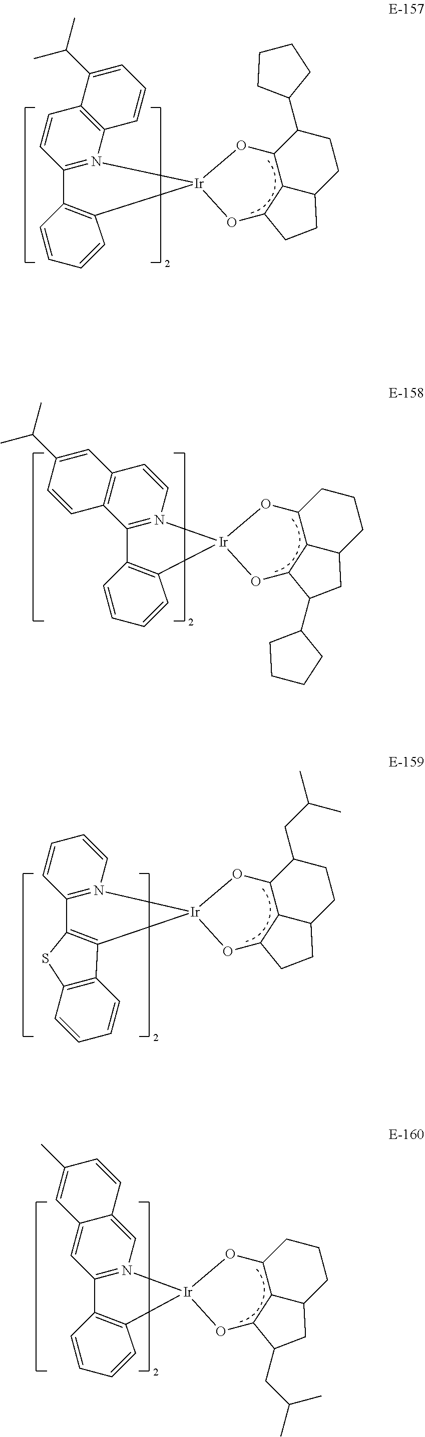

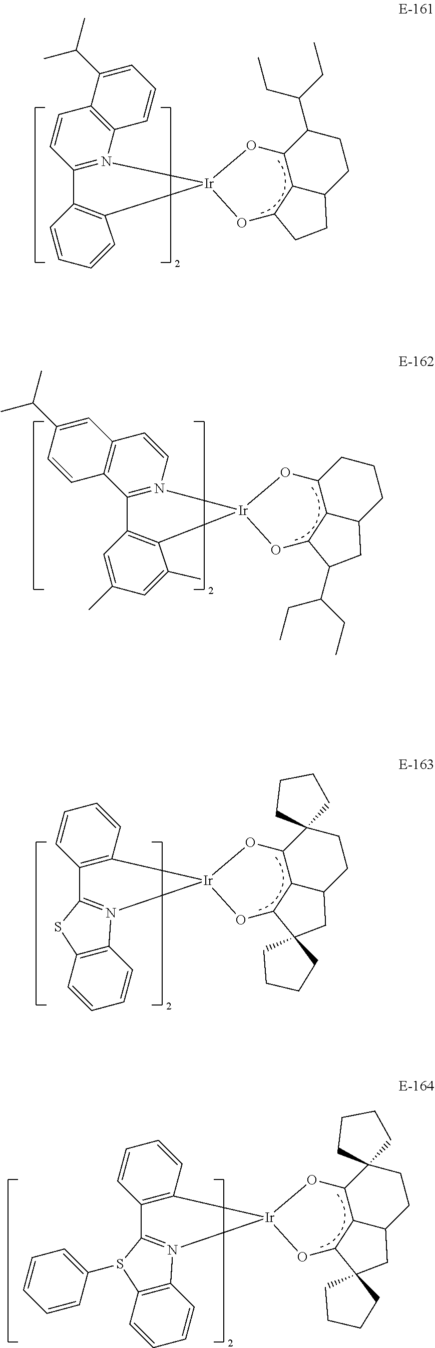

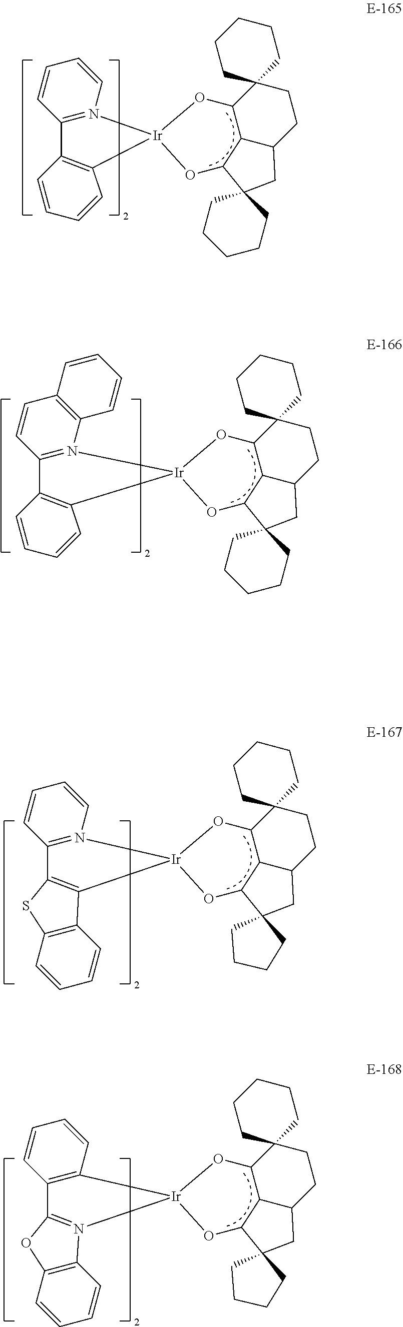

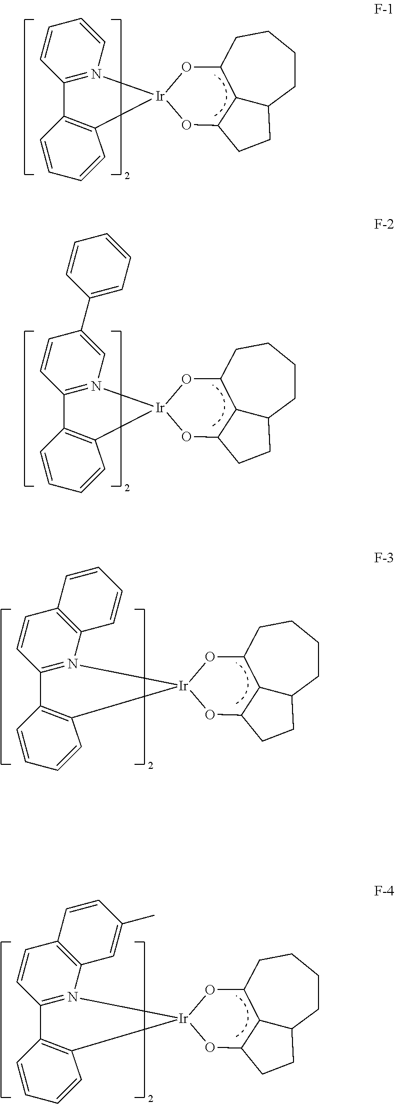

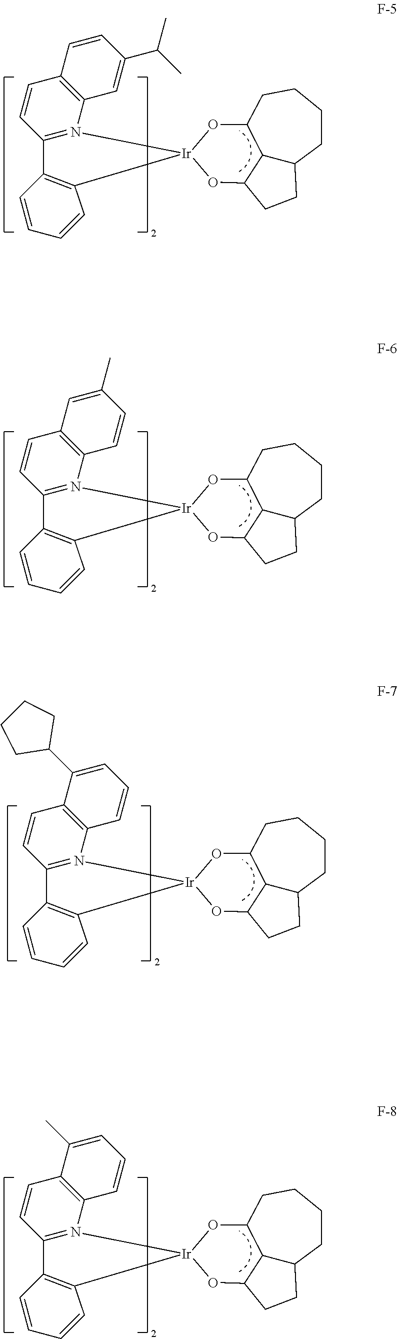

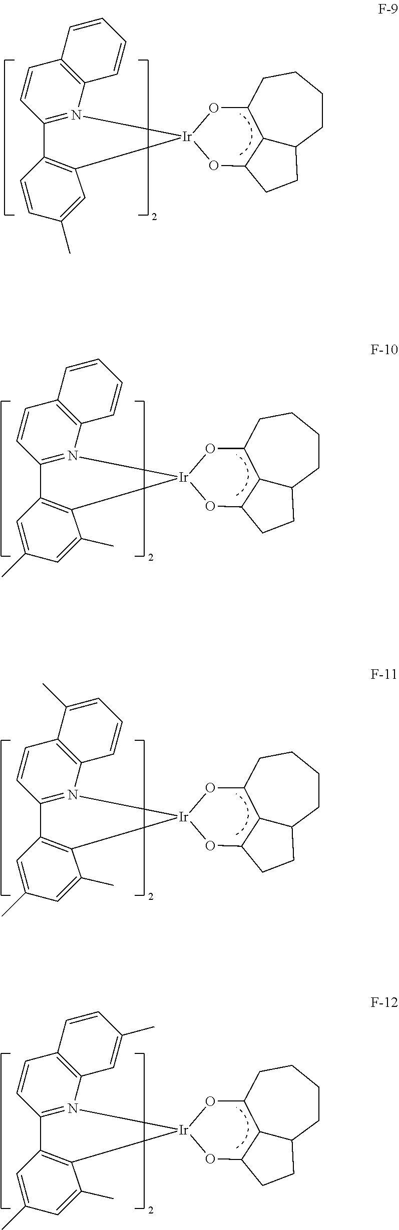

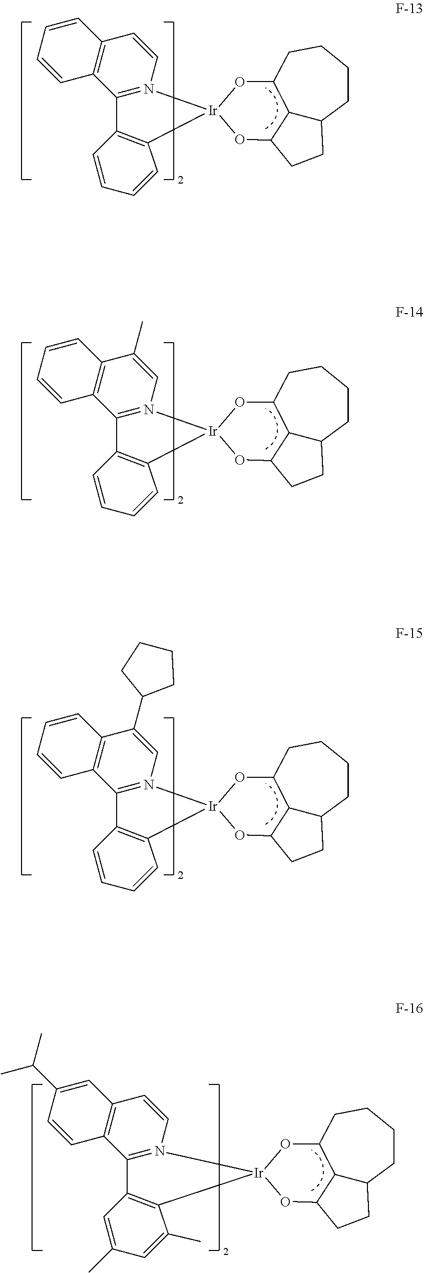

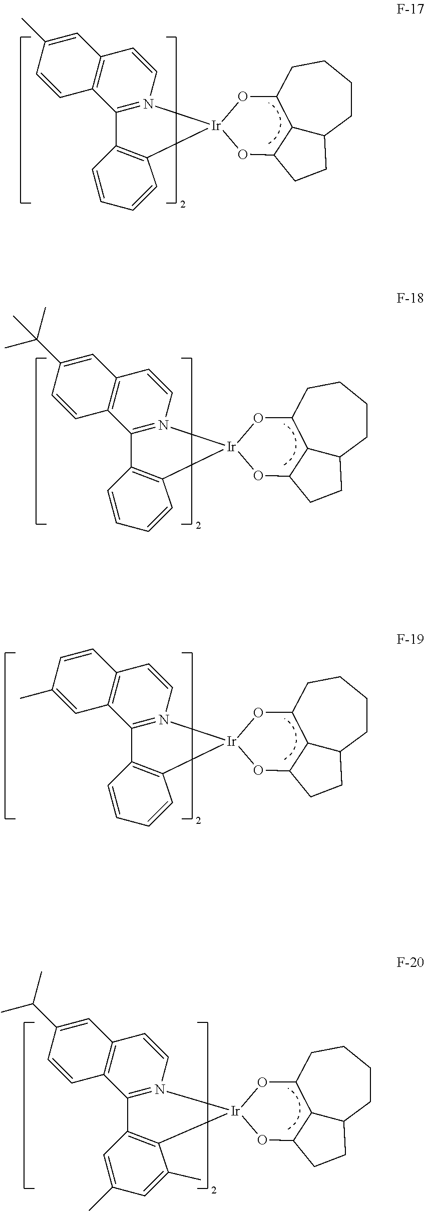

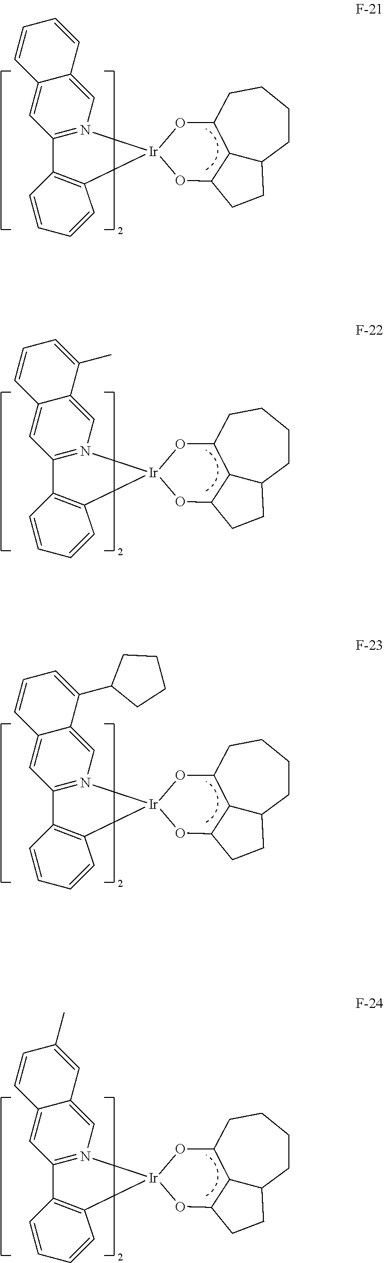

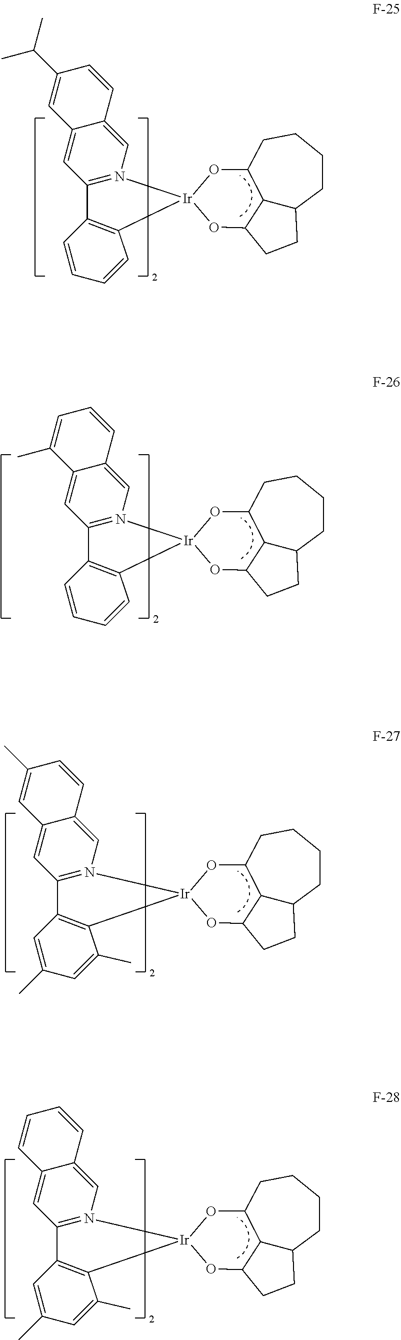

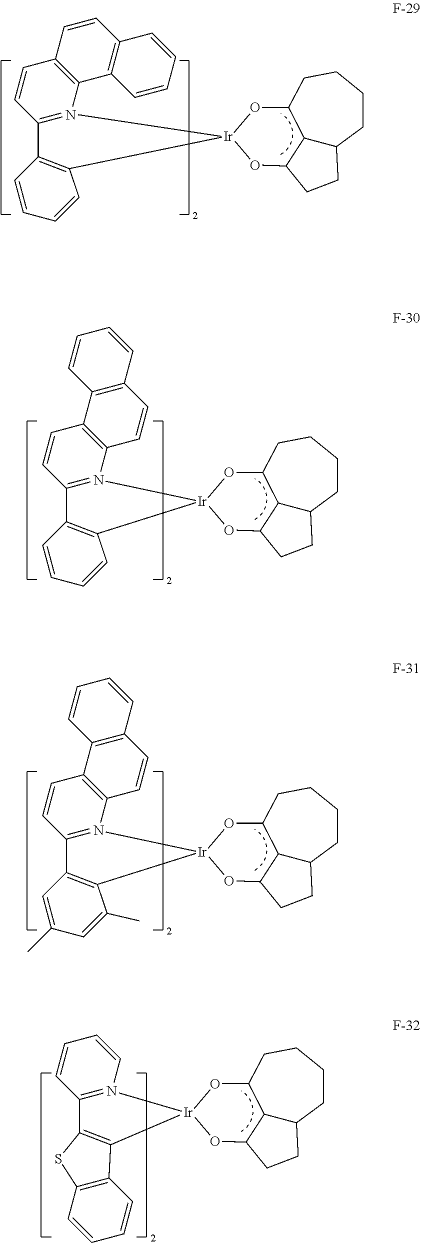

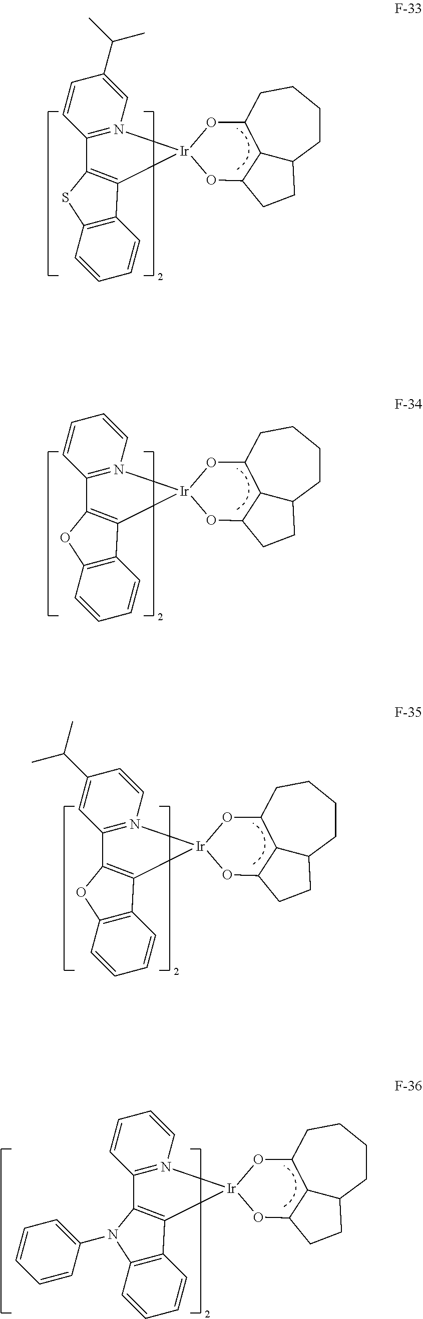

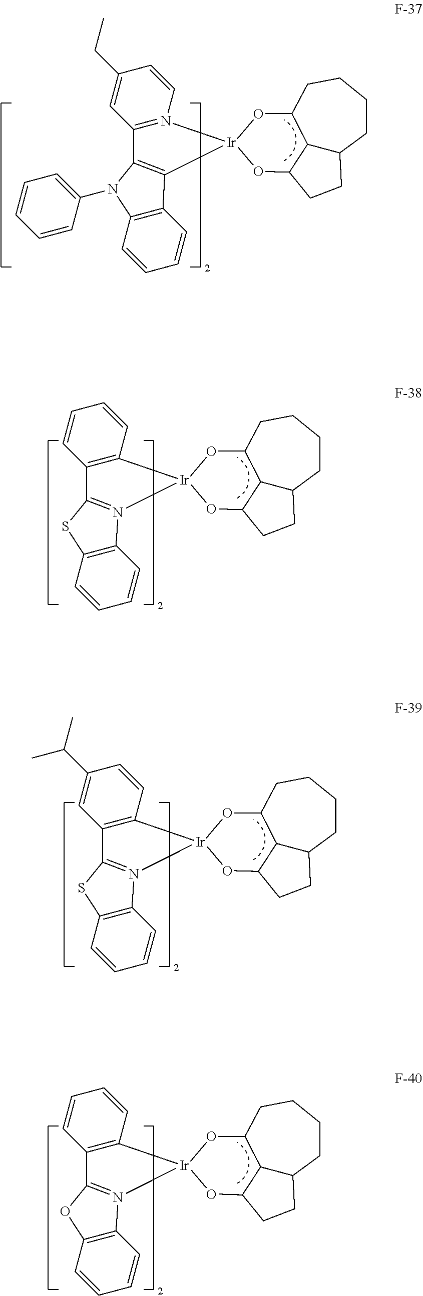

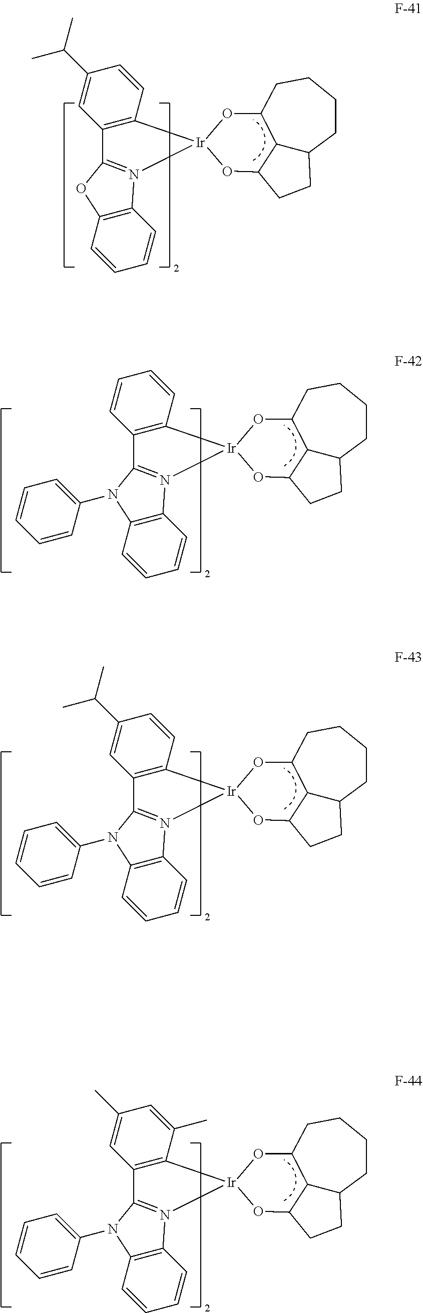

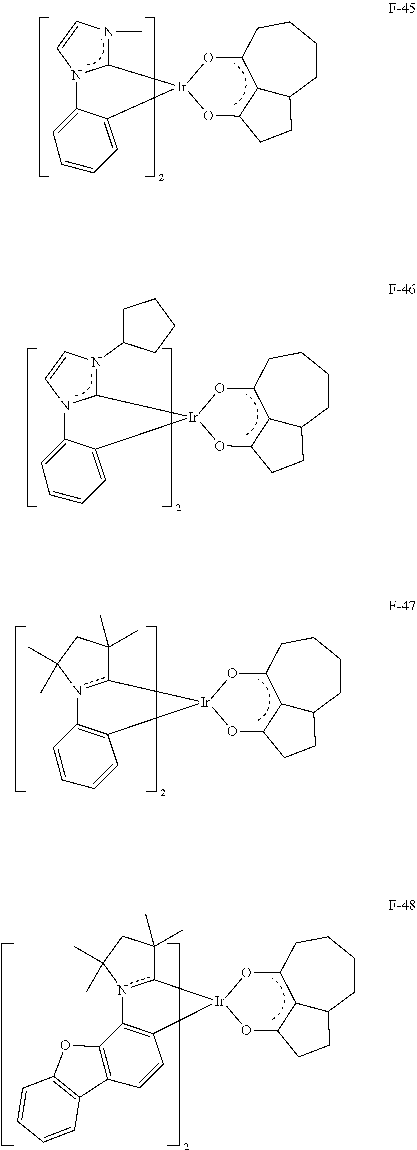

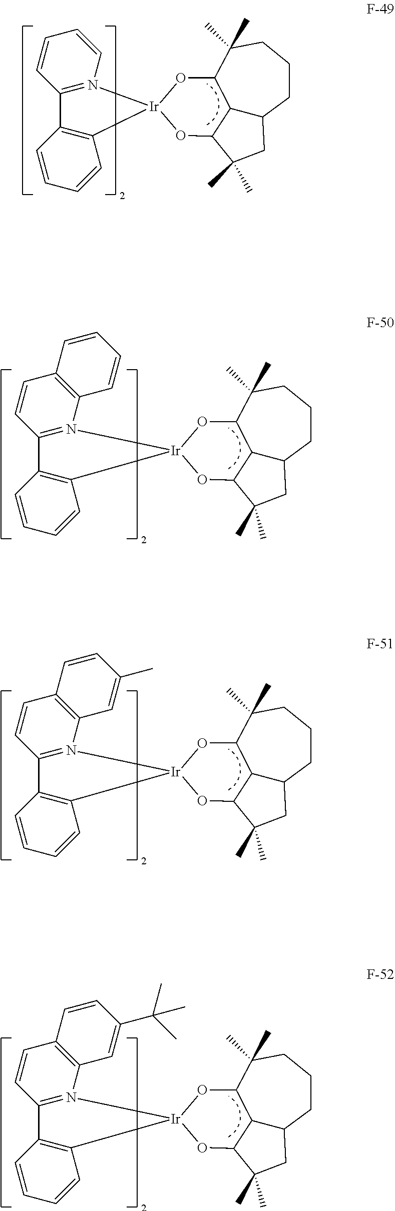

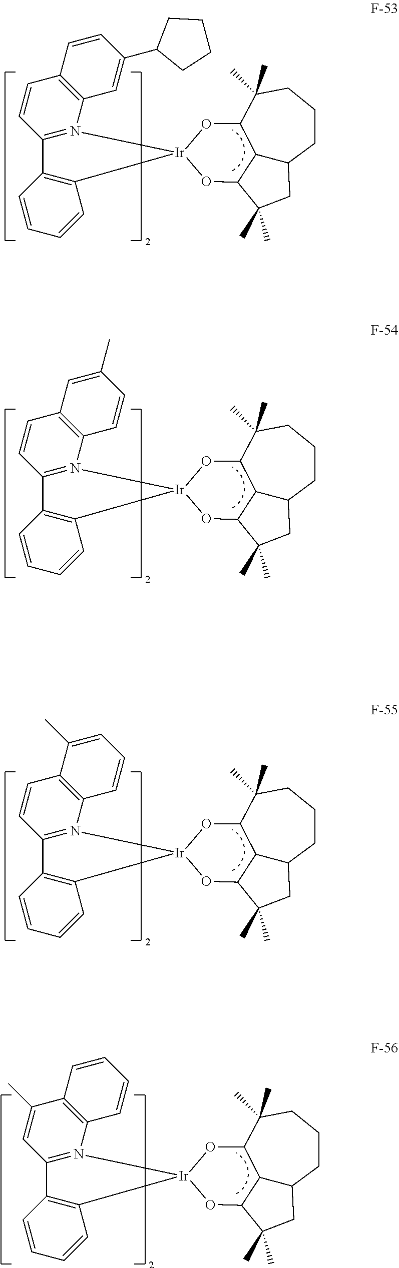

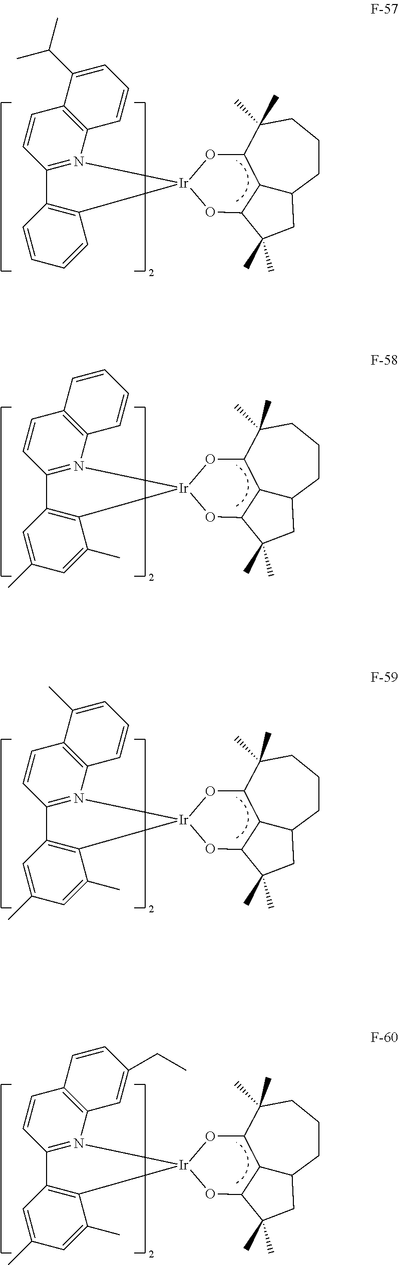

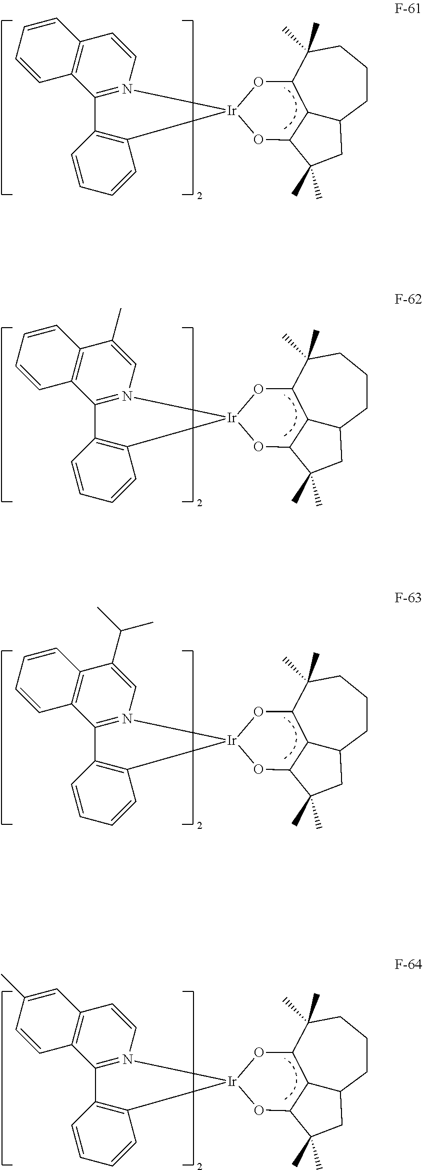

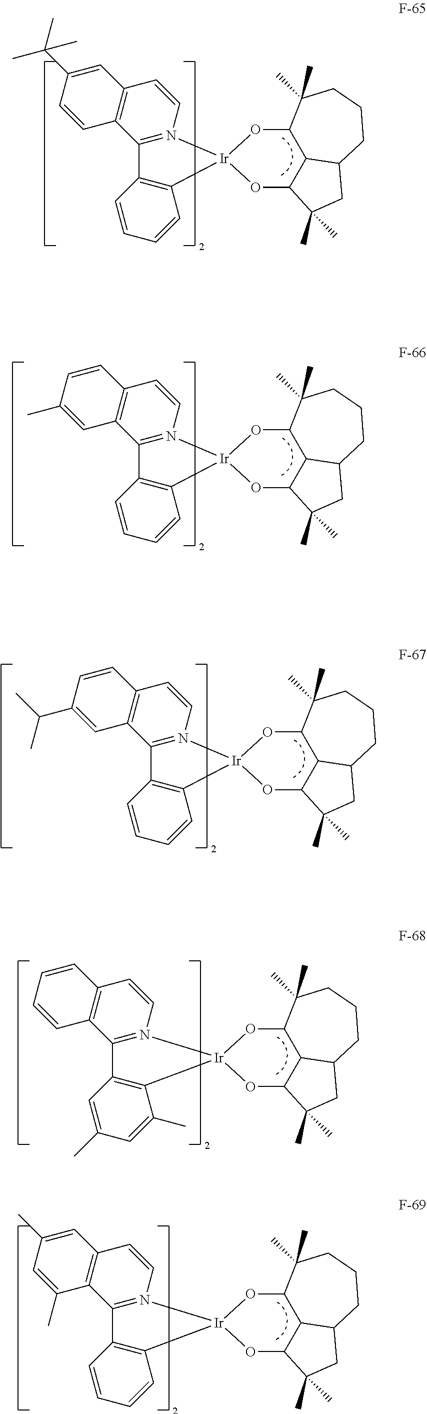

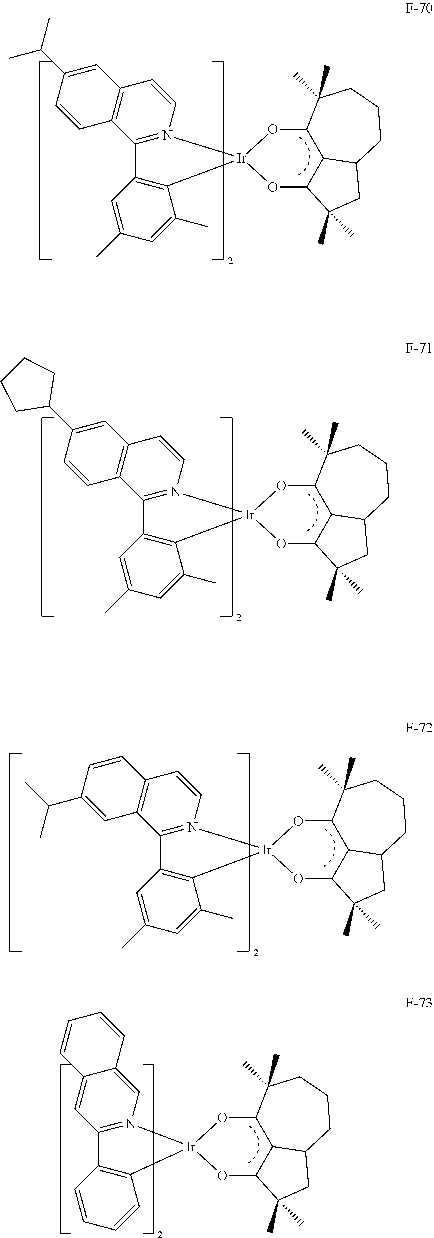

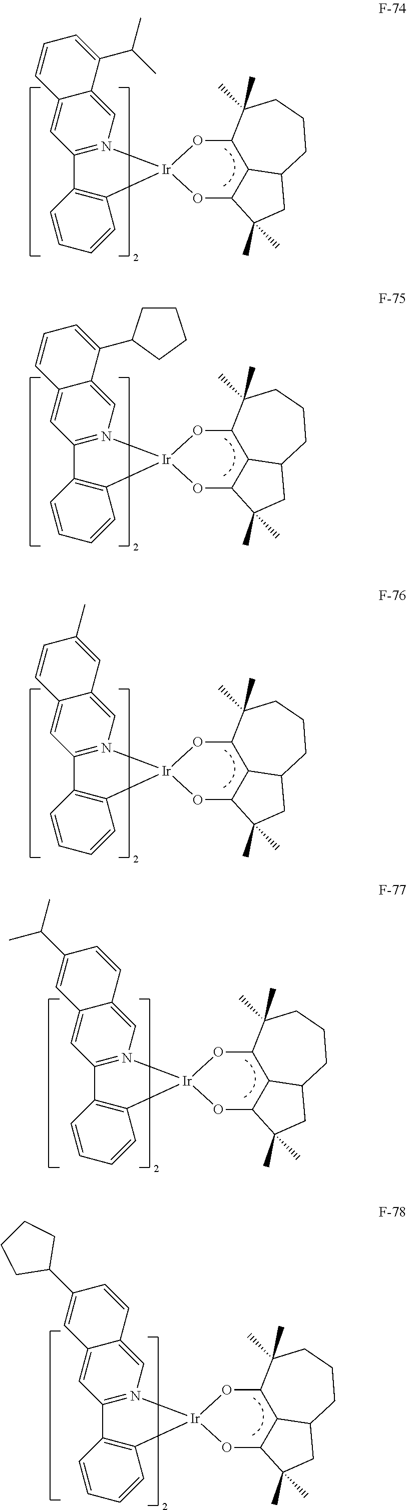

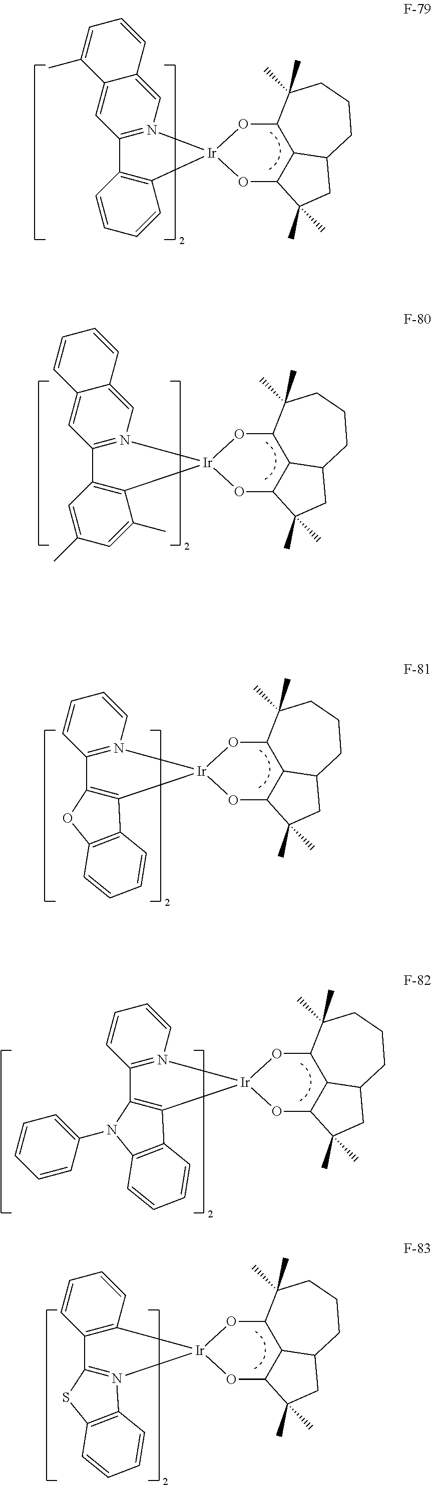

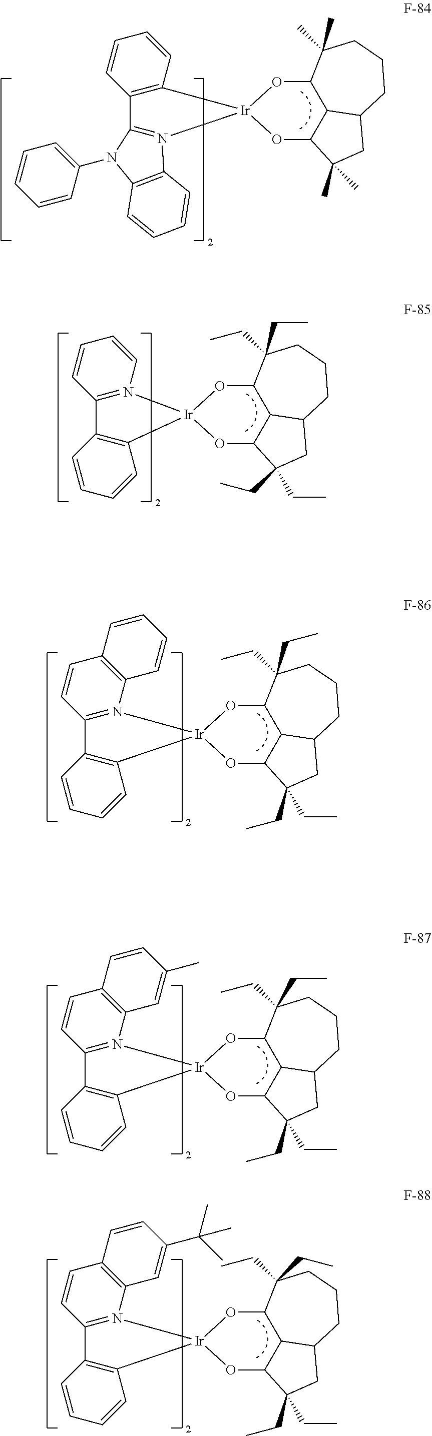

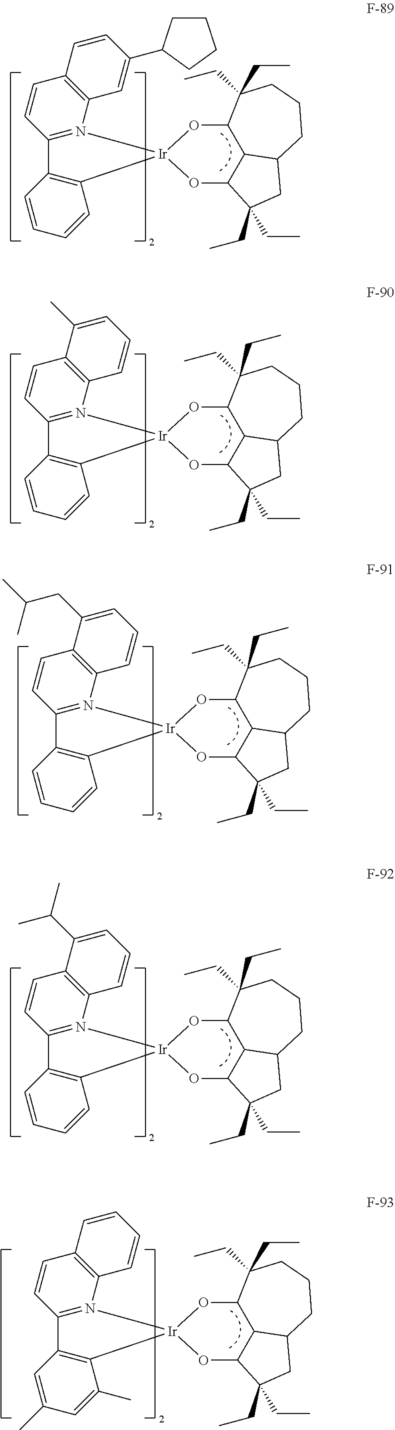

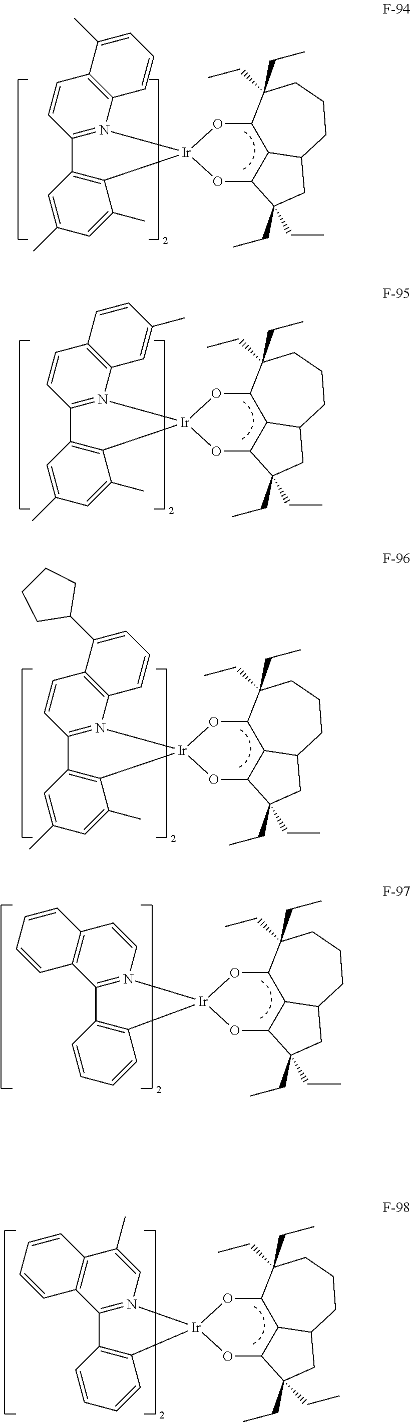

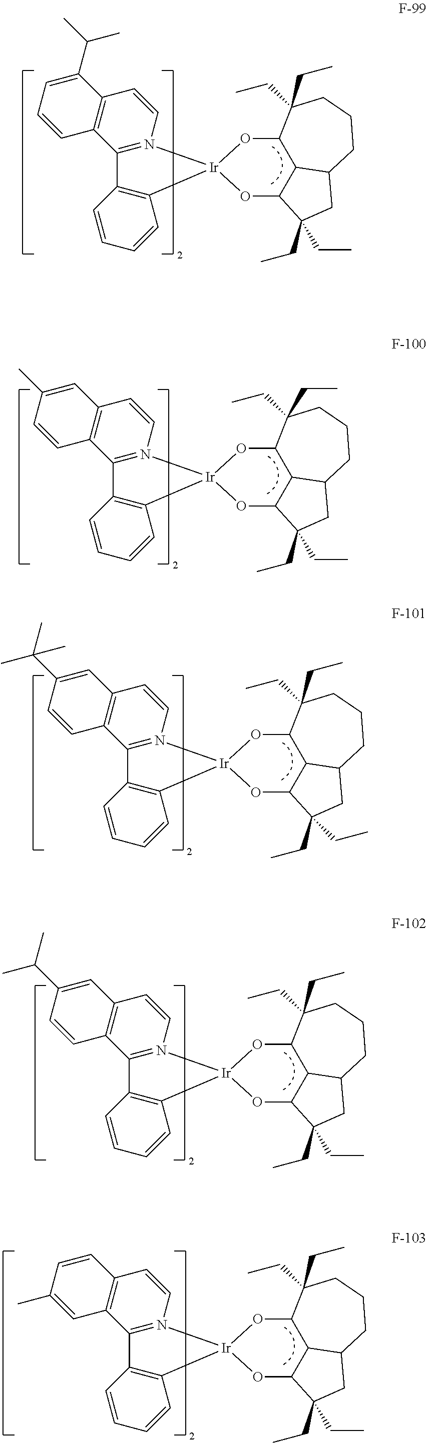

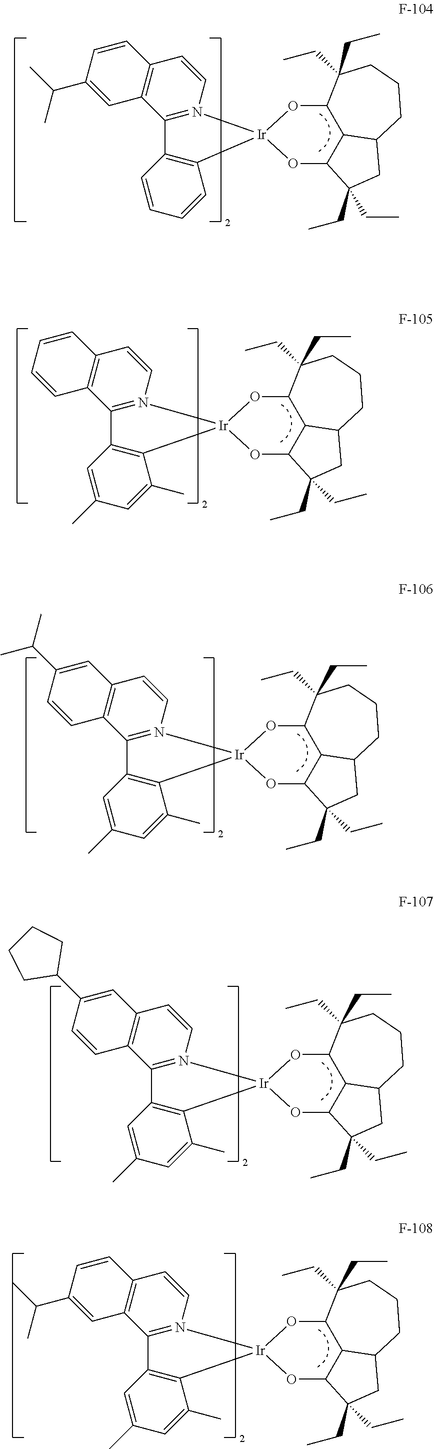

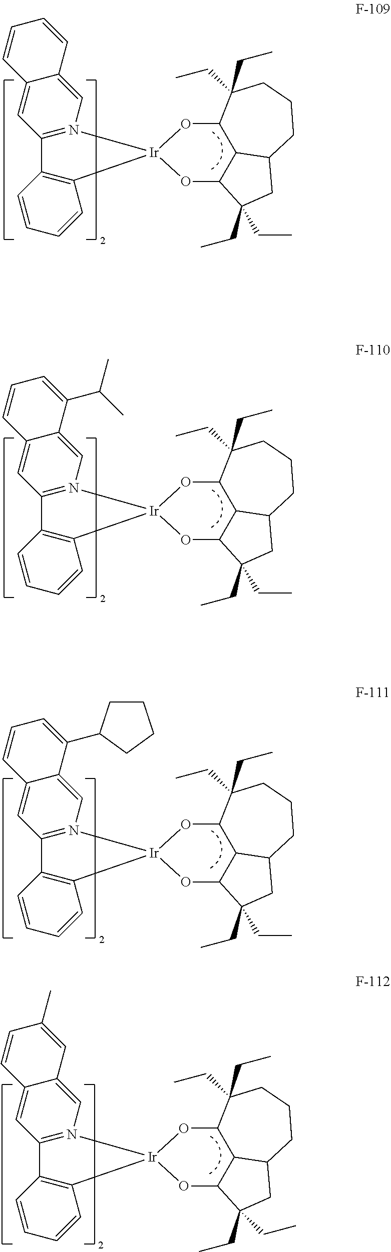

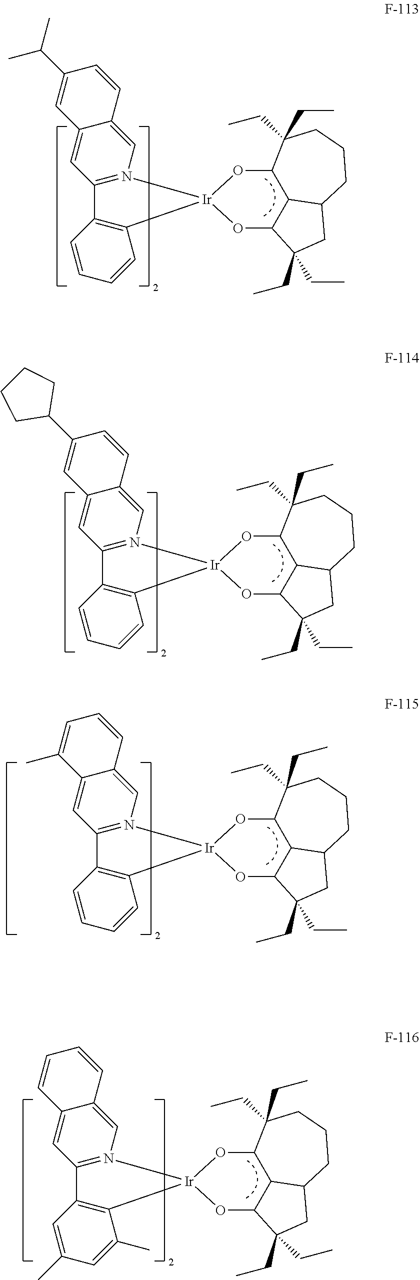

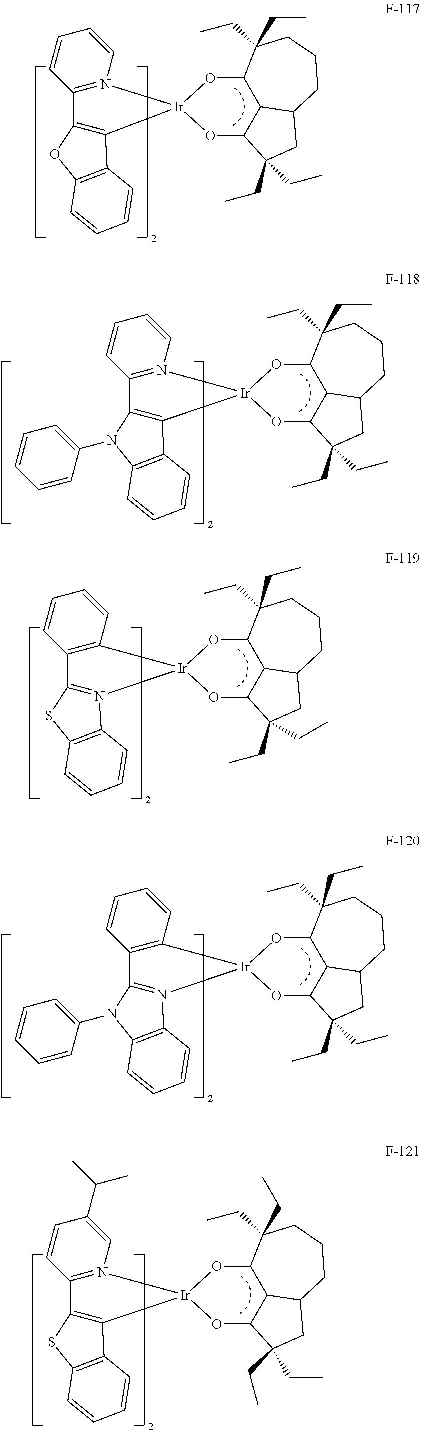

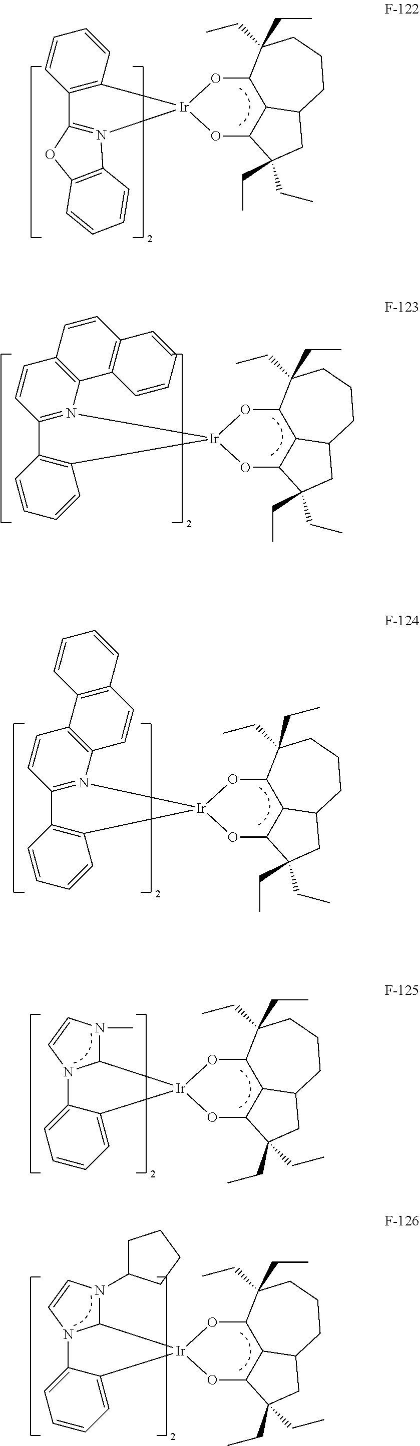

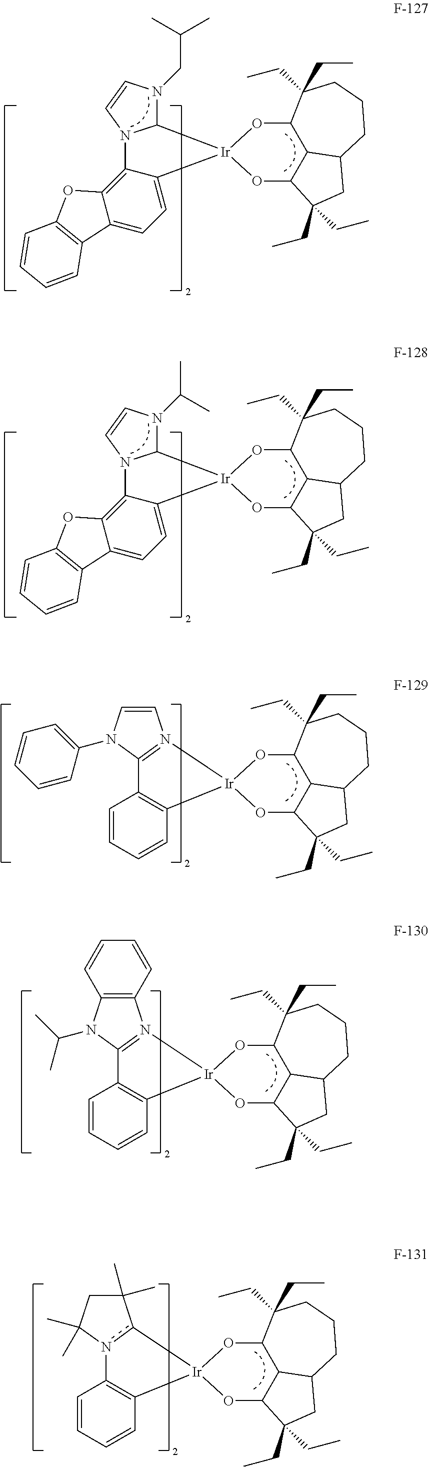

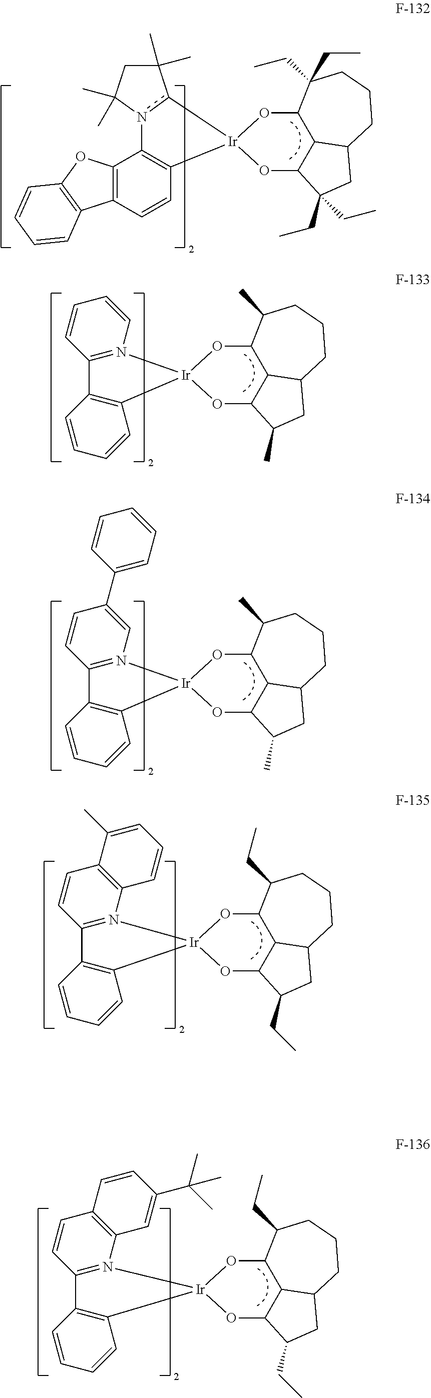

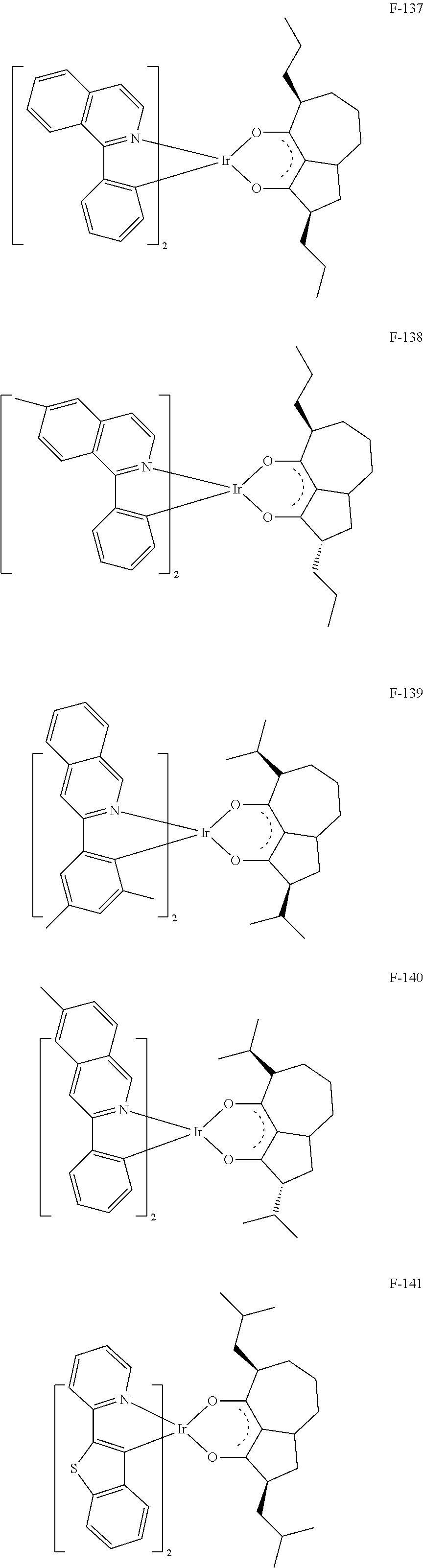

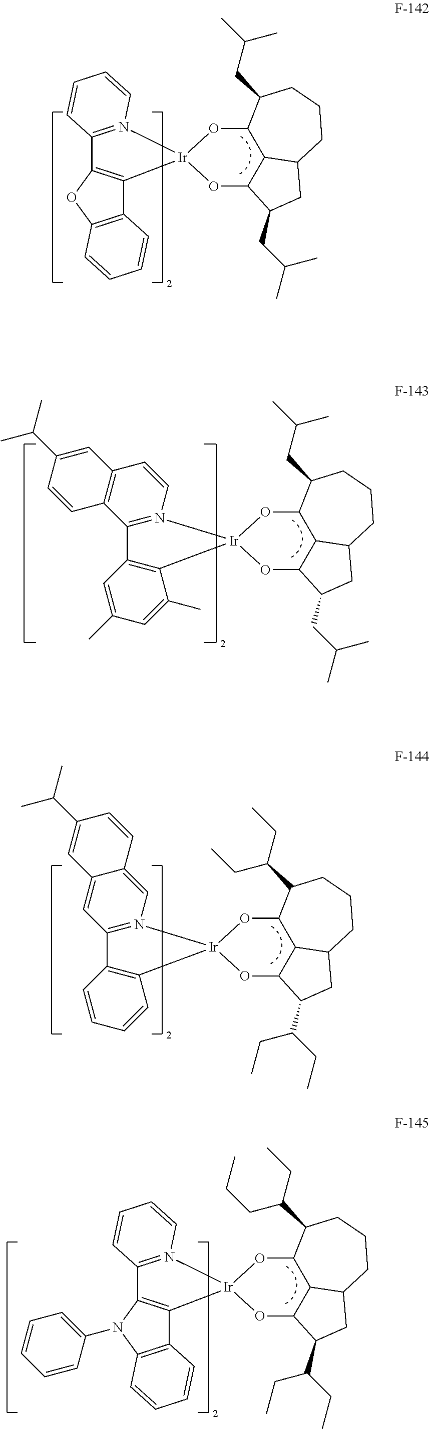

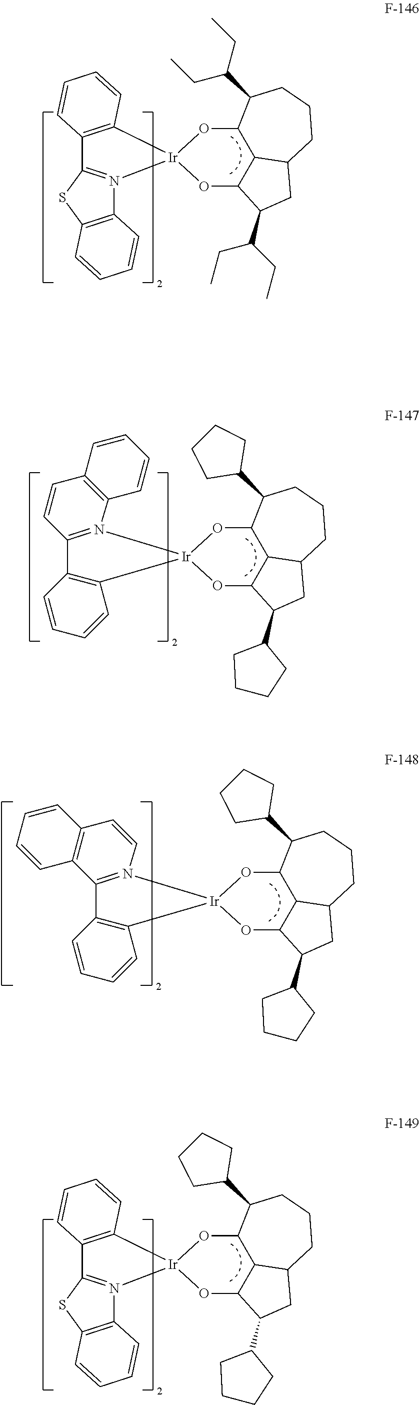

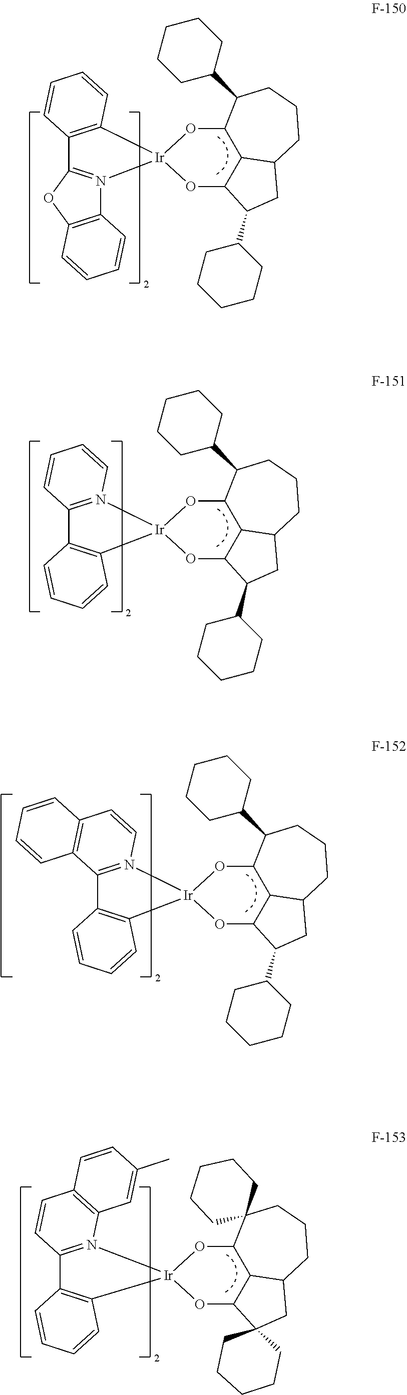

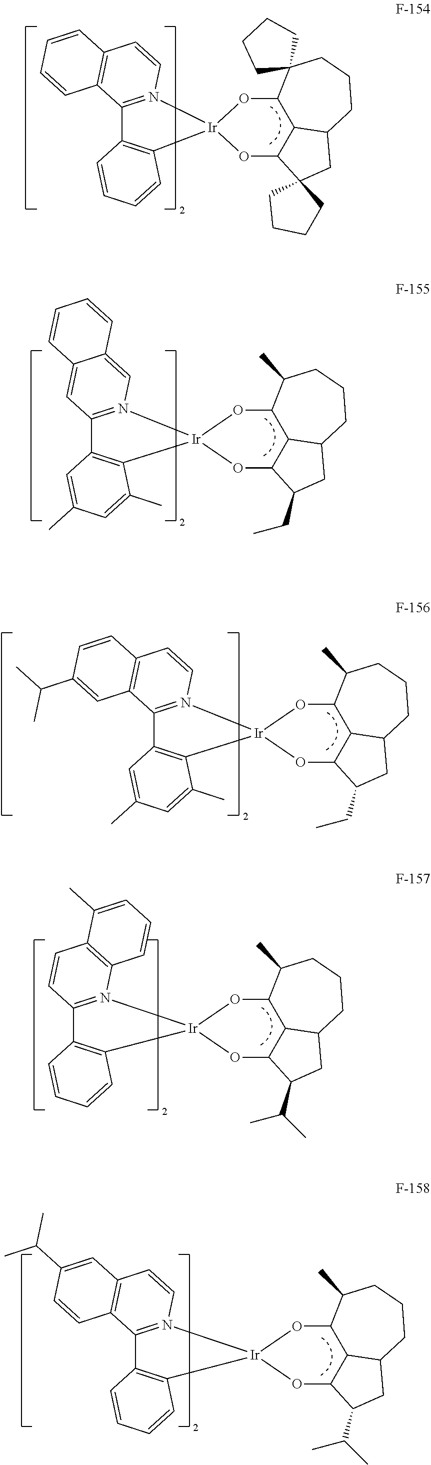

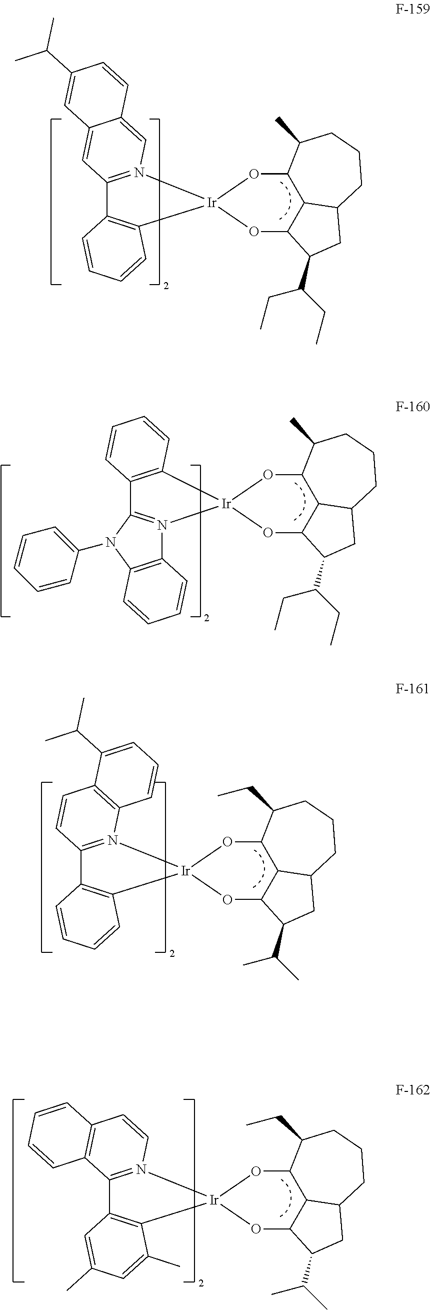

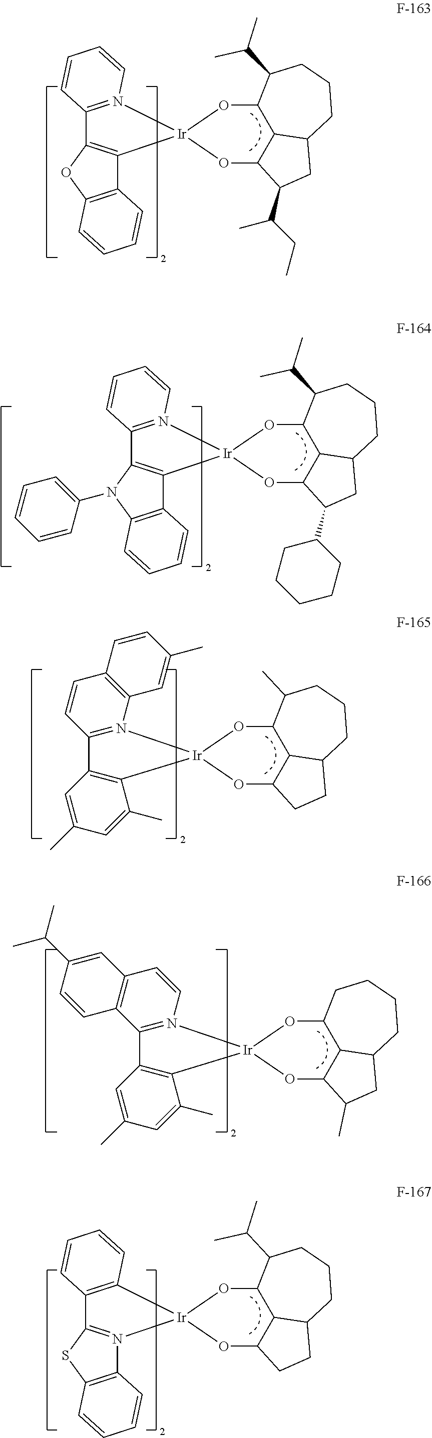

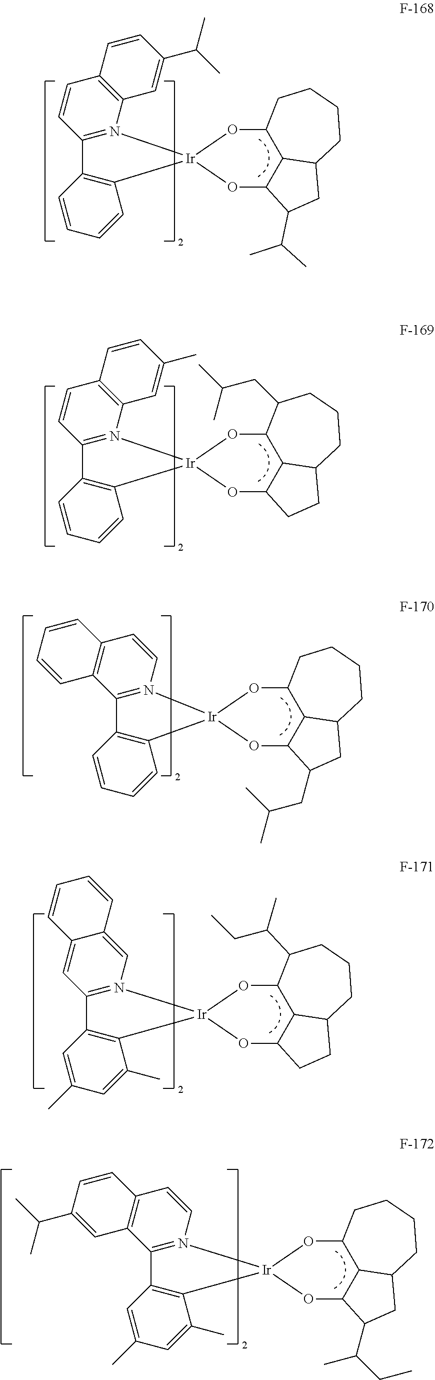

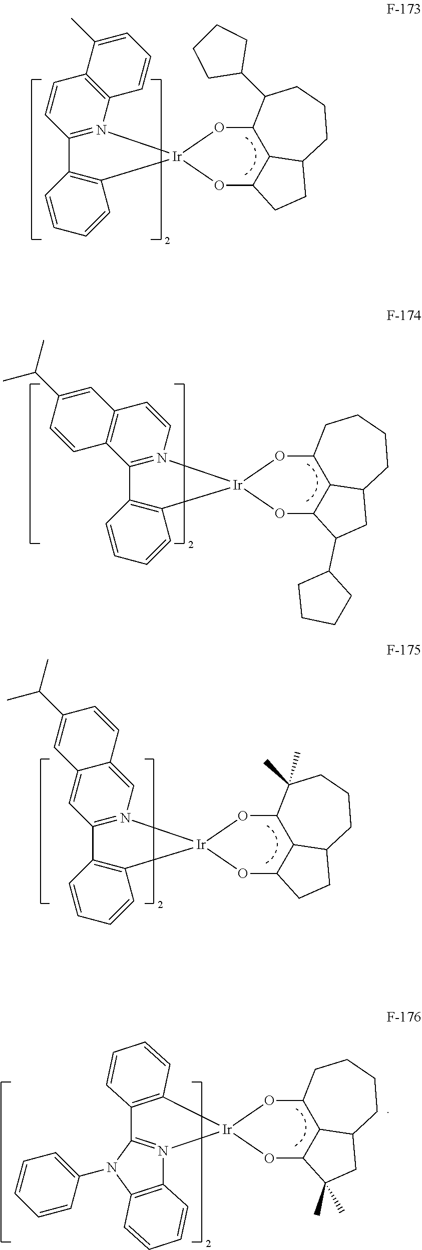

The present invention is not particularly limited to the method for preparing the compound containing 1,3-diketone ligand described in the foregoing first aspect, and a person skilled in the art can determine a suitable reaction route according to the structural formula in combination with a method known in the art of organic synthesis. The present invention is hereinafter exemplified by several methods for preparing the compounds containing 1,3-diketone ligand described in the foregoing first aspect, and those skilled in the art should not be construed as limiting the invention.

As mentioned above, the second aspect of the present invention provides the use of the compound containing 1,3-diketone ligand as described in the first aspect above as an organic electrophosphorescent material.

As described above, the third aspect of the present invention provides an organic electroluminescent device comprising at least one of the compounds containing 1,3-diketone ligand described in the first aspect.

Preferably, the compound containing 1,3-diketone ligand is present in the light-emitting layer of the organic electroluminescent device.

Further preferably, the compound containing 1,3-diketone ligand is a guest material in a light-emitting layer of the organic electroluminescent device.

According to a preferred embodiment, the organic electroluminescent device comprises an anode, a hole injection layer, a hole transport layer, an electron blocking layer, a light-emitting layer, a hole blocking layer, an electron transport layer, an electron injection layer and a cathode.

In the present invention, there is no particular requirement for the material forming the anode, the material forming the hole injection layer, the material forming the hole transport layer, the material forming the electron blocking layer, the host material and the guest material of the light emitting layer, the material forming the hole blocking layer, the material forming the electron injection layer, and the material forming the cathode, and those skilled in the art may select the materials by combining the techniques known in the art, or may adopt the schemes described in paragraphs 0093 to 0126 of CN112745339A, and the present invention incorporates CN112745339A in its entirety.

Preferably, the guest material is the compound containing 1,3-diketone ligand that produces emission via at least one of phosphorescence, fluorescence, TADF (thermally activated delayed fluorescence), MLCT (metal to ligand charge transfer), HLCT (with hybrid CT states), and triplet-triplet annihilation methods.

The present invention will be described in detail below by way of examples.

In the present invention, the room temperature is 25±2° C. unless otherwise specified.

Wherein, the structural formulas of some compounds involved in the following examples are as follows:

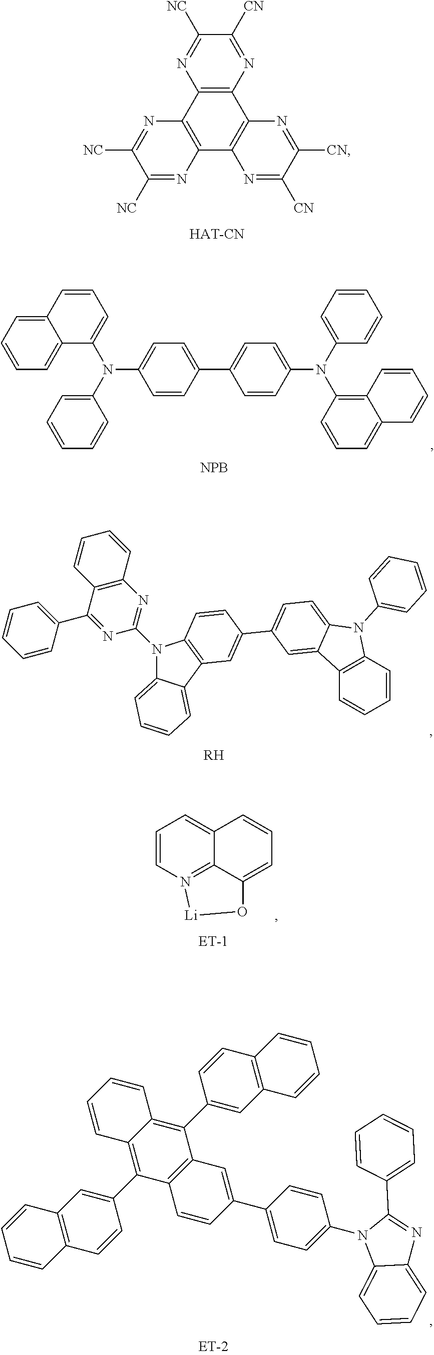

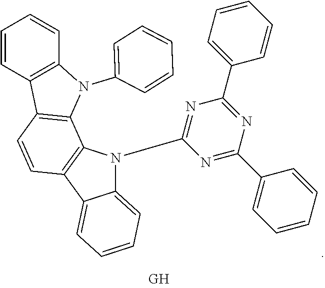 [SMILES: c1ccc(-c2nc(-c3ccccc3)nc(-n3c4ccccc4c4ccc5c6ccccc6n(-c6ccccc6)c5c43)n2)cc1]

Evaluation: Evaluation of Characteristics of Organic Electroluminescent Devices

The color coordinates of the materials are tested by using a german edinburgh FLS980 fluorescence spectrometer.

### Preparation Example A1: Preparation of Compound of Formula AM1

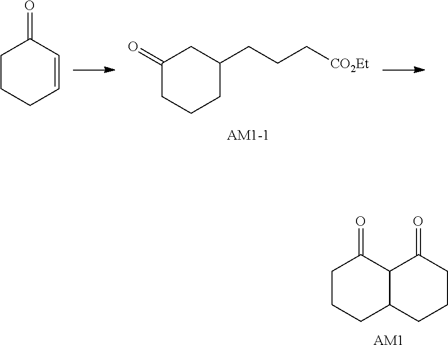

Synthesis of AM1-1: activated zinc powder (0.4 mol) were dissolved in 30 ml of nitrogen degassed THF solution, trimethylchlorosilane (25 ml) were added, stirred for 15 min, then added 4-iodobutyric acid ethyl ester (0.4 mol), stirred at 30° C. for 12 h, chilled to −10° C., then added copper cyanide (0.2 mol) and lithium chloride (0.4 mol) in THF (200 ml), heated to 0° C. and stirred for 10 min, chilled to −78° C., the mixture was solution 1.

2-cyclohexene-1-ketone (0.28 mol) and trimethylchlorosilane (0.66 mol) which dissolved in diethyl ether (250 ml) were slowly added into solution 1, stirred at −78° C. for 3 h, then heated to room temperature, and stirred for 12 h. The reaction was quenched by saturated NH₄Cl (450 ml) and saturated NH₄OH (50 ml), extracted with ethyl acetate three times. The organic phase was combined, the solvent was removed by rotary evaporation, and the residue was recrystallized with methanol to gave white AM1-1 of solid (yield: 75%).

Synthesis of AM1: AM1-1 (75 mmol), potassium tert-butoxide (0.19 mol) were dissolved in nitrogen degassed THF (160 ml), heated to reflux reaction, TLC monitored that the reaction was essentially complete, chilled to room temperature. The extracts was evaporated under reduced pressure, chromatographed on a silica gel column and gave AM1 of white solid (yield: 72%).

MS for C₁₀H₁₄O₂: 166.10; found: 166.0.

Anal. calcd. for C₁₀H₁₄O₂: C: 72.26%, H: 8.49%; found: C: 72.29%, H: 8.52%.

### Preparation Example A2: Preparation of Compound of Formula AM2

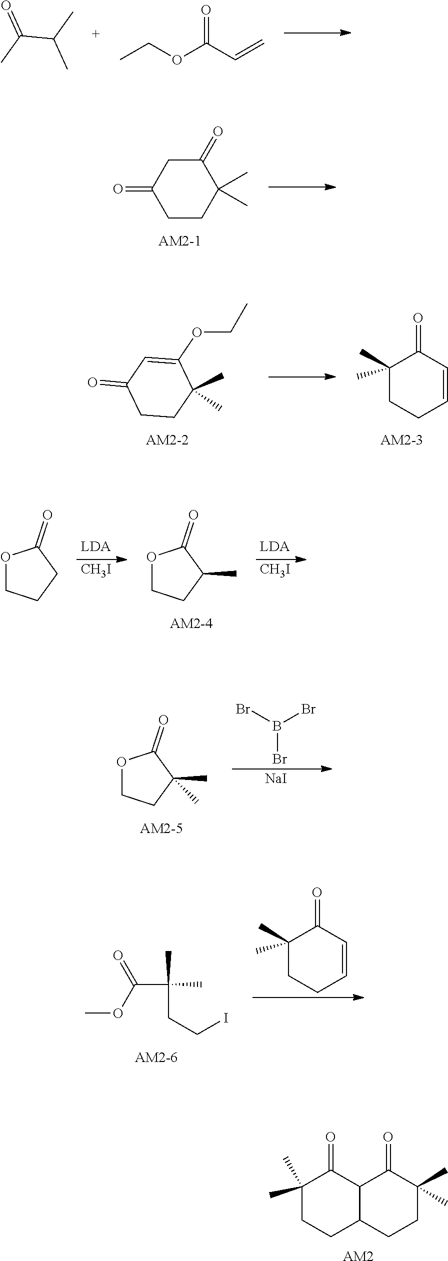

Synthesis of AM2-1: 3-methyl-2-butanone (100 mmol) and potassium tert-butoxide (100 mmol) were dissolved in THF (100 ml) at room temperature, chilled to 0° C. and stirred for 30 min, added ethyl acrylate (100 mmol), heated to room temperature and stirred for 1.5 h. Saturated NH₄C₁ (50 ml) was added to quench the reaction, magnesium sulfate was added for drying. The extracts was evaporated under reduced pressure, chromatographed on a silica gel column and gave AM2-1 of white solid (yield: 82%).

Synthesis of AM2-2: AM2-1 (80 mmol) and p-toluenesulfonic acid (2 mmol) were dissolved in ethanol (240 mmol) and benzene (120 ml), stirred under nitrogen, heated to reflux reaction, TLC monitored that the reaction was essentially complete, chilled to room temperature. The extracts was evaporated under reduced pressure, chromatographed on a silica gel column and gave AM2-2 of white solid (yield: 35%).

Synthesis of AM2-3: AM2-2 (28 mmol) and LiAlH (10 mmol) were dissolved in ether (100 ml), stirred at room temperature for 8 h, TLC monitored that the reaction was substantially complete, added water (30 ml) and 10 wt % sulfuric acid aqueous solution (30 ml) to the reaction liquid sequentially, the organic layer was separated, washed three times with saturated sodium carbonate solution, magnesium sulfate was added for drying. The extracts was evaporated under reduced pressure, chromatographed on a silica gel column and gave AM2-3 of white solid (yield: 93%).

Synthesis of AM2-4: γ-butyrolactone (0.1 mol) was dissolved in THF (100 ml), chilled to −30° C. after complete dissolution, then slowly added 1M lithium diisopropylamide (LDA) (120 ml), stirred at −20° C. for 4 h, then added iodomethane (0.15 mol), heated to room temperature and stirred for 4 h, The reaction was quenched by saturated aqueous sodium bisulfite, extracted with dichloromethane three times. The extracts was evaporated under reduced pressure, chromatographed on a silica gel column and gave AM2-4 of white solid (yield: 66%).

Synthesis of AM2-5: the synthesis method was the same as that of AM2-4 and gave AM2-5 of white solid (yield: 60%).

Synthesis of AM2-6: boron tribromide (60 mmol) and sodium iodide (90 mmol) were dissolved in acetonitrile (150 ml) and stirred uniformly, the mixture was solution 2.

AM2-2 (66 mmol) which dissolved in acetonitrile (80 ml) was slowly added into solution 2, stirred at room temperature for 24 h. The reaction was quenched by ice/water and dichloromethane (120 ml), extracted with saturated aqueous sodium bicarbonate (150 ml), saturated aqueous sodium thiosulfate (150 ml) and water (150 ml), magnesium sulfate was added for drying. The extracts was evaporated under reduced pressure, chromatographed on a silica gel column and gave AM2-6 of white solid (yield: 75%).

Synthesis of AM2: activated zinc powder (50 mmol) were dissolved in nitrogen degassed THF (30 ml) and dibromoethane (2 ml), heated to 65° C., stirred for 5 min, chilled to 25° C. and stirred for 20 min, then added trimethylchlorosilane (2 ml), and stirred for 30 min, the mixture was solution 3.

AM2-6 (45 mmol) was dissolved in THF (120 ml), heated to 30° C., slowly added into solution 3, stirred for 20 h and chilled to −10° C., added copper cyanide (45 mmol) and lithium chloride (90 mmol), heated to 0° C. and stirred for 20 min, and chilled to −78° C., the mixture was solution 4.

AM2-3 (45 mmol) and trimethylchlorosilane (90 mmol) which dissolved in diethyl ether (80 ml) were slowly added into solution 4, stirred at −78° C. for 5 h, then heated to room temperature, and stirred for 20 h. The reaction was quenched by saturated NH₄Cl (20 ml), extracted with diethyl ether, combined organic phases, added deionized water (200 ml) to wash, magnesium sulfate was added for drying. The extracts was evaporated under reduced pressure, chromatographed on a silica gel column and gave white solid I (yield: 50%).

White solid I and potassium tert-butoxide (66 mmol) were dissolved in nitrogen degassed THF (80 mL), heated to reflux reaction, TLC monitored for substantial completion of the reaction, chilled to room temperature, the reaction was dried under reduced pressure and the residue recrystallized to gave AM2 of white solid (yield: 75%).

MS for C₁₄H₂₂O₂: 222.16; found: 222.2.

Anal. calcd. for C₁₄H₂₂O₂: C: 75.63%, H: 9.97%; found: C: 75.60%, H: 9.95%.

### Preparation Example A3: Preparation of Compound of Formula AM3

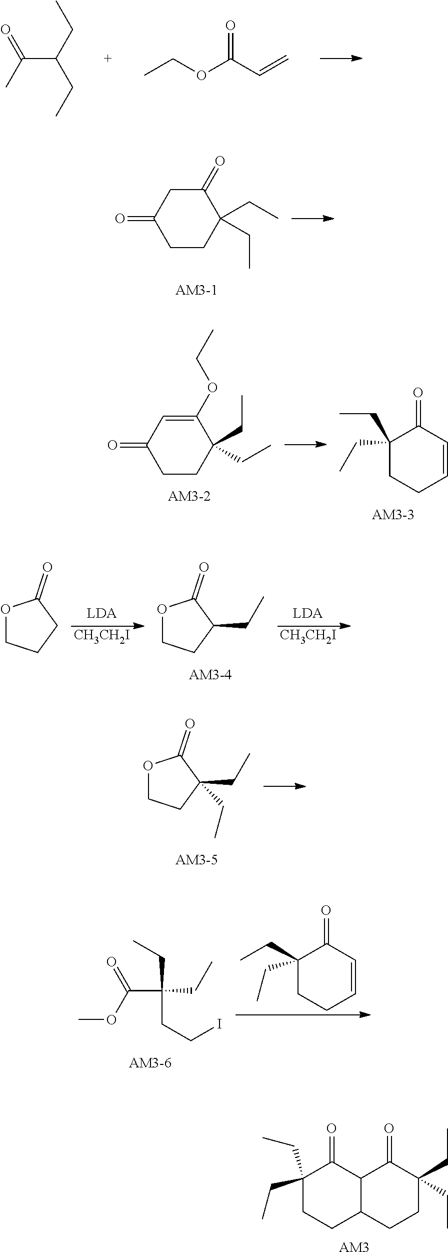

The synthesis method of AM3-1 to AM3 was the same as that of AM2-1 to AM2, except that the raw materials were different.

MS for C₁₈H₃₀O₂: 278.22; found: 278.2.

Anal. calcd. for C₁₈H₃₀O₂: C: 77.65%, H: 10.86%; found: C: 77.63%, H: 10.88%.

### Preparation Example A4: Preparation of Compound of Formula AM4

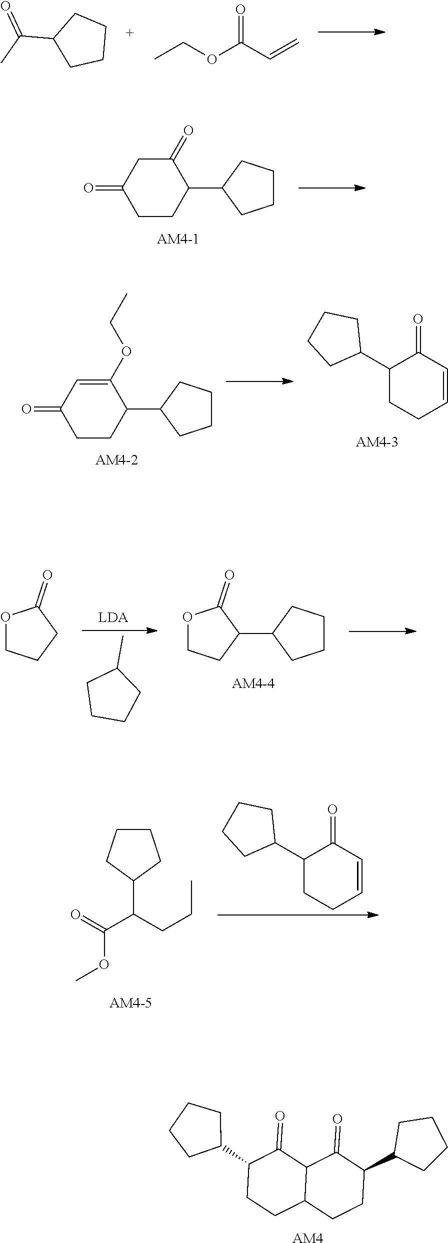

The synthesis method of AM4-1 to AM4-4 was the same as that of AM2-1 to AM2-4, except that the raw materials were different.

The synthesis method of AM4-5 to AM4 was the same as that of AM2-6 to AM2, except that the raw materials were different.

MS for C₂₀H₃₀O₂: 302.22; found: 302.2.

Anal. calcd. for C₂₀H₃₀O₂: C: 79.42%, H: 10.00%; found: C: 79.45%, H: 10.03%.

### Preparation Example A5: Preparation of Compound of Formula AM5

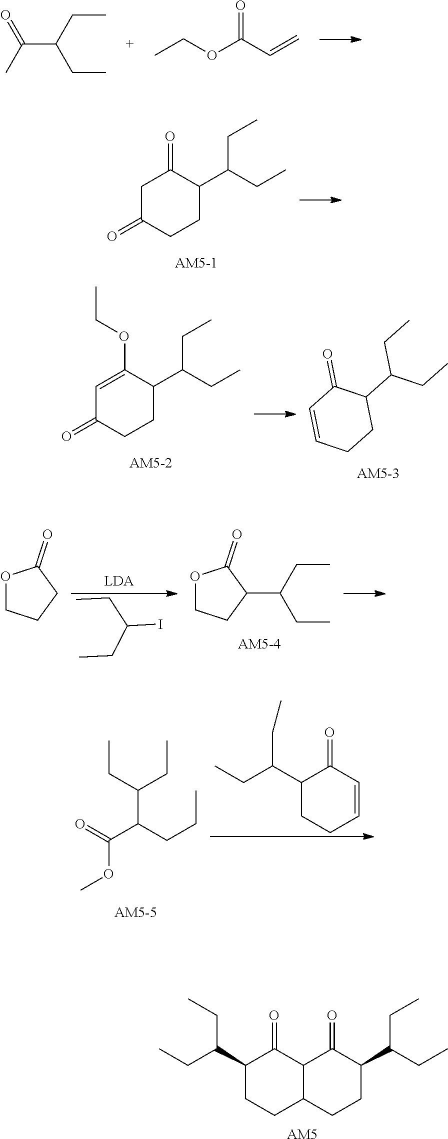

The synthesis method of AM5-1 to AM5-4 was the same as that of AM2-1 to AM2-4, except that the raw materials were different.

The synthesis method of AM5-5 to AM5 was the same as that of AM2-6 to AM2, except that the raw materials were different.

MS for C₂₀H₃₄O₂: 306.26; found: 306.3.

Anal. calcd. for C₂₀H₃₄O₂: C: 78.38%, H: 11.18%; found: C: 78.42%, H: 11.15%.

### Preparation Example A6: Preparation of Compound of Formula AM6

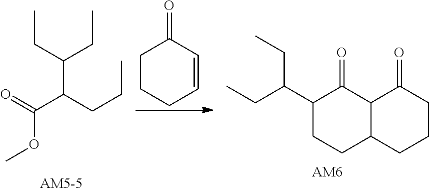

The synthesis method of AM6 was the same as that of AM2, except that the raw materials were different.

MS for C₁₅H₂₄O₂: 236.18; found: 236.2.

Anal. calcd. for C₁₅H₂₄O₂: C: 76.23%, H: 10.24%; found: C: 76.26%, H: 10.27%.

### Preparation Example A7: Preparation of Compound A-10

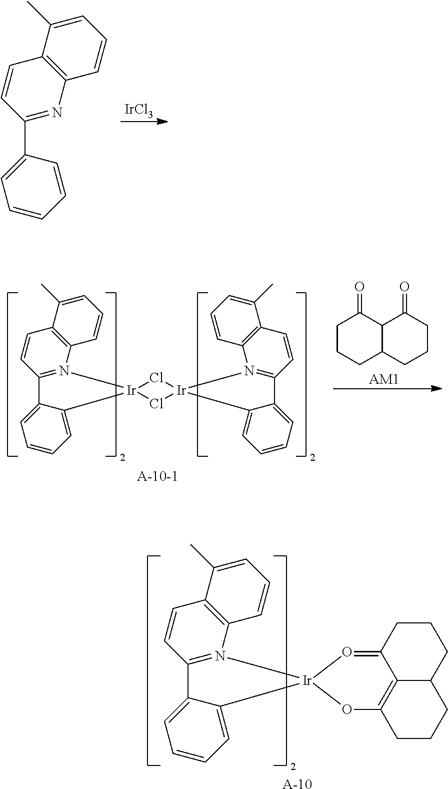

Synthesis of A-10-1: 5-phenyl-2-methylquinoline (40 mmol) and iridium trichloride (10 mmol) were dissolved in a mixed solution of ethoxyethanol (60 ml) and water (30 ml), stirred under nitrogen, heated to 100° C. and stirred for 28 h, chilled to room temperature, performed suction filtration, and washed with deionized water, ethanol and petroleum ether in sequence to gave a crude product. The crude product was refluxed and pulped with ethanol (100 ml) and petroleum ether (100 ml) in turn, and filtered to gave A-10-1 (yield: 55%).

Synthesis of A-10: A-10-1 (12 mmol), AM1 (96 mmol) and sodium carbonate (96 mmol) were dissolved in 2-ethoxyethanol (170 ml), stirred under nitrogen, heated to reflux reaction, chilled to room temperature and filtered, chromatographed on a silica gel column and gave A-10 of orange-red solid (yield: 42%).

Anal. calcd.: C: 63.53%, H: 4.70%, N: 3.53%; found: C: 63.55%, H: 4.75%, N: 3.46%.

### Preparation Example A8: Preparation of Compound A-52

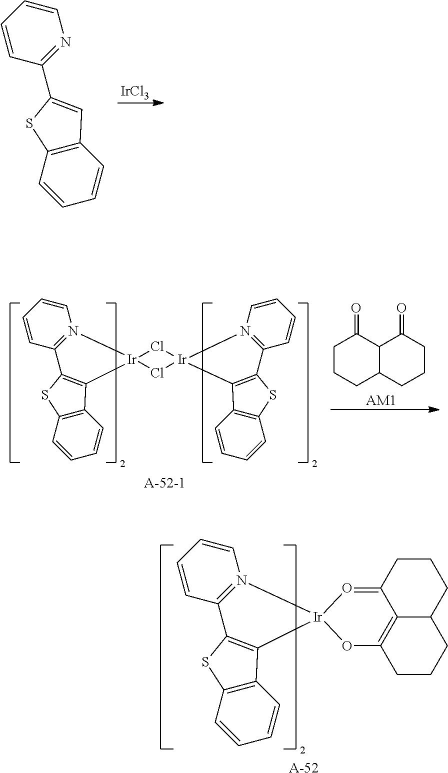

Synthesis of A-52-1: the synthesis method of A-52-1 was the same as that of A-10-1, except that 5-phenyl-2-methylquinoline was replaced with 2-(2-pyridyl)benzothiophene, and filtered to gave A-52-1 (yield: 57%).

Synthesis of A-52: the synthesis method of A-52 was the same as that of A-10, except that the A-10-1 was replaced with A-52-1 to gave A-52 of yellow-green solid (yield: 40%).

Anal. calcd.: C: 55.58%, H: 3.76%, N: 3.60%; found: C: 55.54%, H: 3.78%, N: 3.58%.

### Preparation Example A9: Preparation of Compound A-114

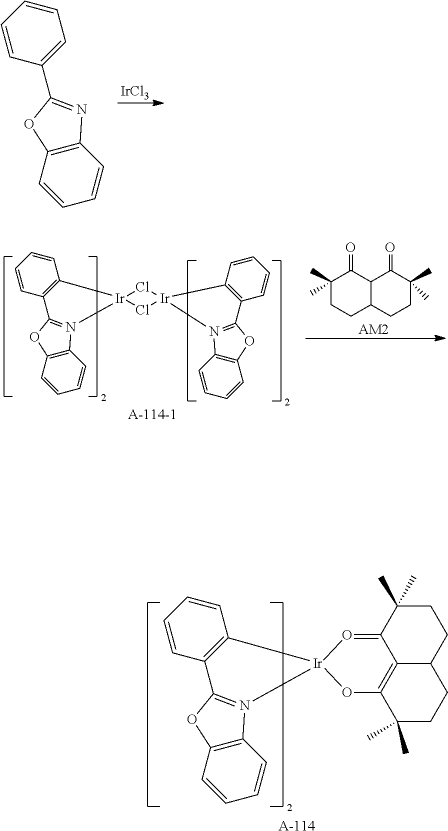

Synthesis of A-114-1: the synthesis method of A-114-1 was the same as that of A-10-1, except that 5-phenyl-2-methylquinoline was replaced with 2-phenylbenzoxazole to gave A-114-1 (yield: 52%).

Synthesis of A-114: the synthesis method of A-114 was the same as that of A-10, except that A-10-1 and AM1 were replaced with A-114-1 and AM2 to gave A-114 of yellow-green solid (yield: 38%).

Anal. calcd.: C: 59.91%, H: 4.65%, N: 3.49%; found: C: 59.93%, H: 4.62%, N: 3.52%.

### Preparation Example A10: Preparation of Compound A-141

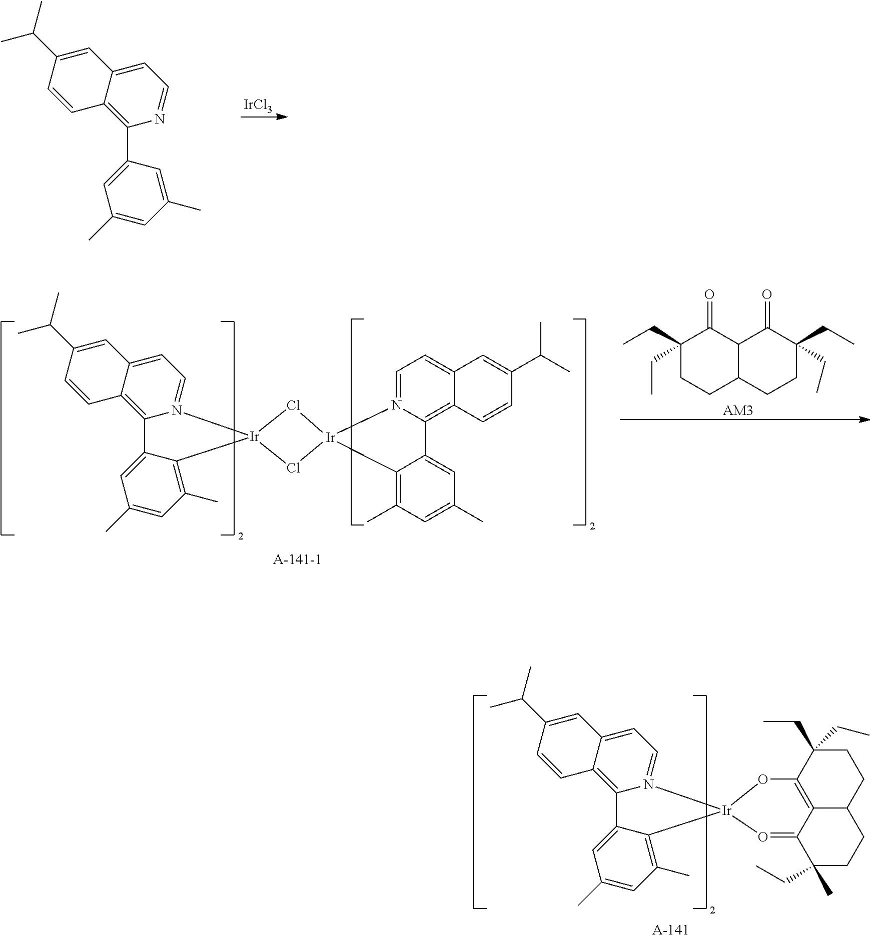

Synthesis of A-141-1: the synthesis method of A-141-1 was the same as that of A-10-1, except that 5-phenyl-2-methylquinoline was replaced with 1-(3,5-dimethylphenyl)-6-isopropylisoquinoline to gave A-141-1 (yield: 58%).

Synthesis of A-141: the synthesis method of A-141 was the same as that of A-10, except that A-10-1 and AM1 were replaced with A-141-1 and AM3 to gave A-141 of deep red solid (yield: 39%).

Anal. calcd.: C: 68.16%, H: 6.72%, N: 2.79%; found: C: 68.18%, H: 6.70%, N: 2.81%.

### Preparation Example A11: Preparation of Compound A-185

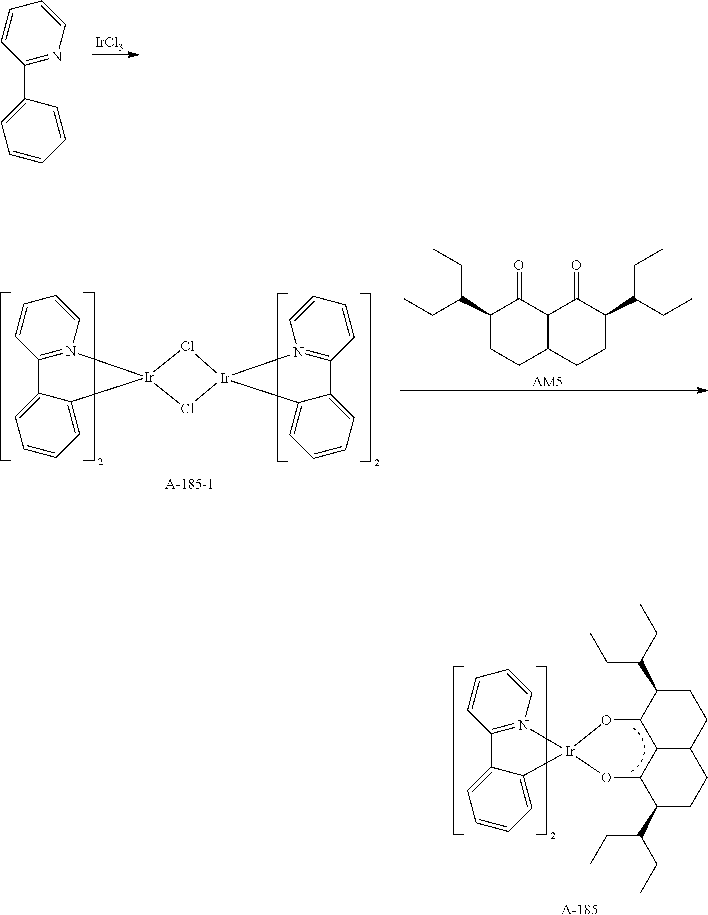

Synthesis of A-185-1: the synthesis method of A-185-1 was the same as that of A-10-1, except that 5-phenyl-2-methylquinoline was replaced with 2-phenylpyridine to gave A-185-1 (yield: 55%).

Synthesis of A-185: the synthesis method of A-185 was the same as that of A-10, except that A-10-1 and AM1 were replaced with A-185-1 and AM5 to gave A-185 of yellow solid (yield: 41%).

Anal. calcd.: C: 62.58%, H: 6.13%, N: 3.48%; found: C: 62.55%, H: 6.17%, N: 3.47%.

### Preparation Example A12: Preparation of Compound A-187

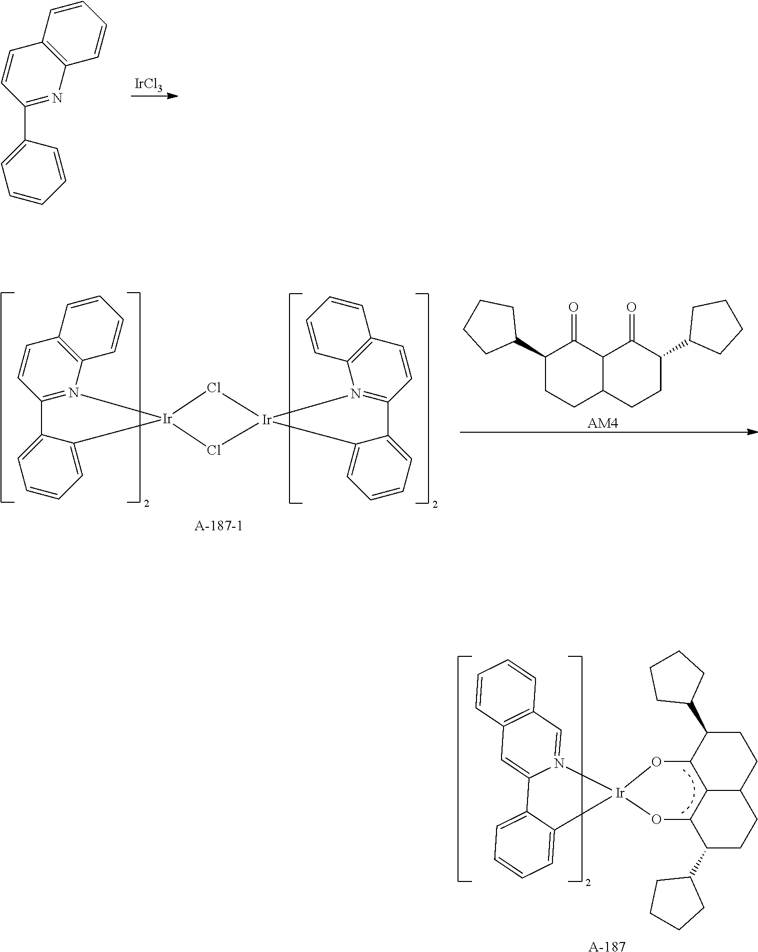

Synthesis of A-187-1: the synthesis method of A-187-1 was the same as that of A-10-1, except that 5-phenyl-2-methylquinoline was replaced with 2-phenylquinoline to gave A-187-1 (yield: 55%).

Synthesis of A-187: the synthesis method of A-187 was the same as that of A-10, except that A-10-1 and AM1 were replaced with A-187-1 and AM4 to gave A-187 of orange-yellow solid (yield: 43%).

Anal. calcd.: C: 66.57%, H: 5.47%, N: 3.11%; found: C: 66.55%, H: 5.48%, N: 3.14%.

### Preparation Example A13: Preparation of Compound A-210

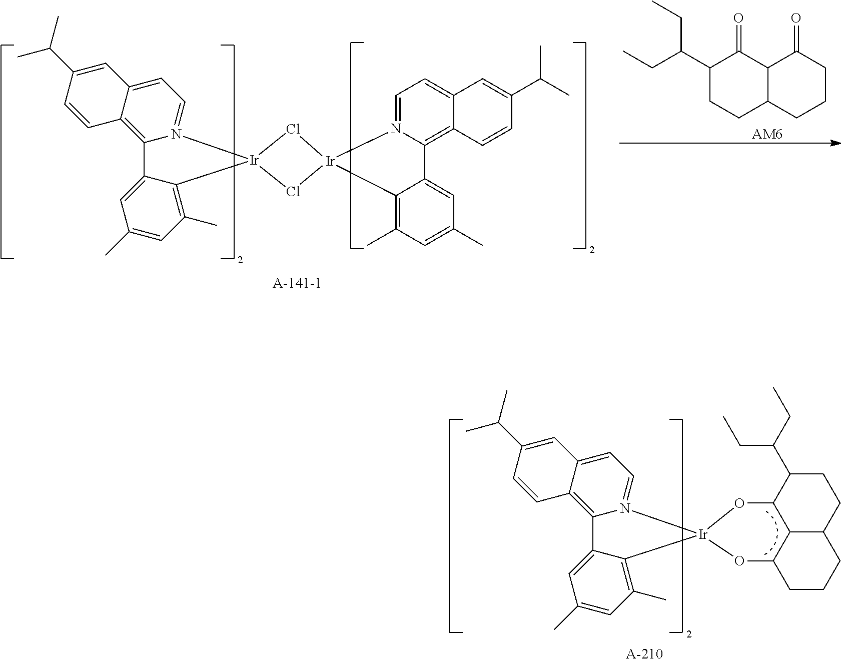

Synthesis of A-210: the synthesis method of A-210 was the same as that of A-10, except that A-10-1 and AM1 were replaced with A-141-1 and AM6 to gave A-210 of deep red solid (yield: 44%).

Anal. calcd.: C: 67.45%, H: 6.79%, N: 2.86%; found: C: 67.49%, H: 6.77%, N: 2.88%.

The following compounds were prepared in a similar manner to the synthesis of compound A-10, except that the raw materials were replaced as appropriate.

Compound A-1: Anal. calcd.: C: 57.73%, H: 4.39%, N: 4.21%; found: C: 57.76%, H: 4.40%, N: 4.23%.

Compound A-6: Anal. calcd.: C: 64.99%, H: 5.34%, N: 3.30%; found: C: 64.97%, H: 5.38%, N: 3.33%.

Compound A-15: Anal. calcd.: C: 64.29%, H: 5.03%, N: 3.41%; found: C: 64.33%, H: 5.05%, N: 3.42%.

Compound A-17: Anal. calcd.: C: 64.99%, H: 5.34%, N: 3.30%; found: C: 64.95%, H: 5.32%, N: 3.30%.

Compound A-23: Anal. calcd.: C: 63.53%, H: 4.70%, N: 3.53%; found: C: 63.57%, H: 4.74%, N: 3.44%.

Compound A-32: Anal. calcd.: C: 66.27%, H: 5.90%, N: 3.09%; found: C: 66.29%, H: 5.93%, N: 3.04%.

Compound A-33: Anal. calcd.: C: 62.73%, H: 4.34%, N: 3.66%; found: C: 62.70%, H: 4.36%, N: 3.62%.

Compound A-46: Anal. calcd.: C: 64.29%, H: 5.03%, N: 3.41%; found: C: 64.32%, H: N: 3.44%.

Compound A-65: Anal. calcd.: C: 60.05%, H: 4.91%, N: 7.00%; found: C: 60.02%, H: 4.93%, N: 7.02%.

Compound A-69: Anal. calcd.: C: 59.89%, H: 5.17%, N: 3.88%; found: C: 59.93%, H: N: 3.89%.

Compound A-73: Anal. calcd.: C: 66.27%, H: 5.90%, N: 3.09%; found: C: 66.30%, H: N: 3.07%.

Compound A-76: Anal. calcd.: C: 66.27%, H: 5.90%, N: 3.09%; found: C: 66.32%, H: N: 3.02%.

Compound A-80: Anal. calcd.: C: 65.65%, H: 5.62%, N: 3.19%; found: C: 65.67%, H: N: 3.22%.

Compound A-119: Anal. calcd.: C: 62.49%, H: 5.81%, N: 6.34%; found: C: 62.52%, H: N: 6.31%.

Compound A-122: Anal. calcd.: C: 67.14%, H: 5.74%, N: 3.01%; found: C: 67.16%, H: N: 3.03%.

Compound A-127: Anal. calcd.: C: 67.40%, H: 6.39%, N: 2.91%; found: C: 67.42%, H: 6.37%, N: 2.92%.

Compound A-132: Anal. calcd.: C: 66.85%, H: 6.15%, N: 3.00%; found: C: 66.83%, H: 6.18%, N: 3.02%.

Compound A-139: Anal. calcd.: C: 68.68%, H: 6.46%, N: 2.76%; found: C: 68.67%, H: 6.45%, N: 2.73%.

Compound A-160: Anal. calcd.: C: 67.92%, H: 6.62%, N: 2.83%; found: C: 67.90%, H: 6.65%, N: 2.84%.

Compound A-165: Anal. calcd.: C: 59.37%, H: 5.10%, N: 3.15%; found: C: 59.39%, H: N: 3.16%.

Compound A-173: Anal. calcd.: C: 65.96%, H: 5.19%, N: 3.20%; found: C: 65.98%, H: N: 3.18%.

Compound A-177: Anal. calcd.: C: 64.99%, H: 5.34%, N: 3.30%; found: C: 64.97%, H: N: 3.33%.

Compound A-182: Anal. calcd.: C: 68.87%, H: 7.03%, N: 2.68%; found: C: 68.85%, H: 7.04%, N: 2.66%.

Compound A-82: Anal. calcd.: C: 67.40%, H: 6.39%, N: 2.91%; found: C: 67.36%, H: 6.41%, N: 2.93%.

Compound A-89: Anal. calcd.: C: 67.40%, H: 6.39%, N: 2.91%; found: C: 67.38%, H: 6.43%, N: 2.90%.

### Preparation Example B1: Preparation of Compound of Formula BM1

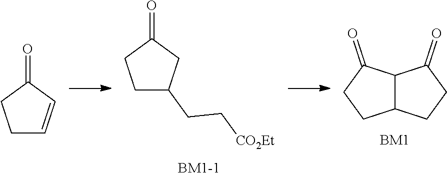 [SMILES: O=C1C=CCC1 ; CCOC(=O)CCC1CCC(=O)C1 ; O=C1CCC2CCC(=O)C12]

Synthesis of BM1-1: the synthesis method of BM1-1 was the same as that of AM1-1, except that ethyl 4-iodobutyrate and 2-cyclohexen-1-one were replaced with ethyl 3-iodopropionate and 2-cyclopentenone to gave BM1-1 of white solid (yield: 78%).

Synthesis of BM1: the synthesis method of BM1 was the same as that of AM1, except that AM1-1 was replaced with BM1-1 to gave BM1 of white solid (yield: 71%).

MS for C₈H₁₀O₂: 138.07, found: 138.0.

Anal. calcd. for C₈H₁₀O₂: C: 69.54%, H: 7.30%; found: C: 69.58%, H: 7.26%.

### Preparation Example B2: Preparation of Compound of Formula BM2

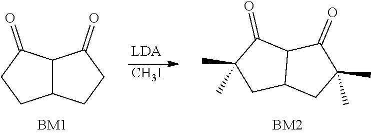

Synthesis of BM2: BM1 (30 mmol) was dissolved in THE (60 ml) and after complete dissolution, the mixture was chilled to −30° C. and then 1M lithium diisopropylamide (LDA) (60 ml) was added slowly and stirred at −20° C. for 2 h, then iodomethane (30 mmol) was added, warmed slowly to room temperature and stirred for 2 h.

The obtained mixture was chilled to −30° C. and then 1M LDA solution (30 ml) was added slowly and stirred at −20° C. for 2 h, then iodomethane (30 mmol) was added, warmed slowly to room temperature and stirred for 2 h.

The obtained mixture was chilled to −30° C. and then 1M LDA solution (30 ml) was added slowly and stirred at −20° C. for 2 h, then iodomethane (30 mmol) was added, warmed slowly to room temperature and stirred for 2 h.

The obtained mixture was chilled to −30° C. and then 1M LDA solution (30 ml) was added slowly and stirred at −20° C. for 2 h, then iodomethane (30 mmol) was added, warmed slowly to room temperature and stirred for 2 h. The reaction was quenched by saturated aqueous sodium bisulfite solution, extracted three times with dichloromethane, the organic phases were combined, The extracts was evaporated under reduced pressure, chromatographed on a silica gel column and gave BM2 of white solid (yield: 61%).

MS for C₁₂H₁₈O₂: 194.13; found: 194.1.

Anal. calcd. for C₁₂H₁₈O₂: C: 74.19%, H: 9.34%; found: C: 74.22%, H: 9.32%.

### Preparation Example B3: Preparation of Compound of Formula BM3

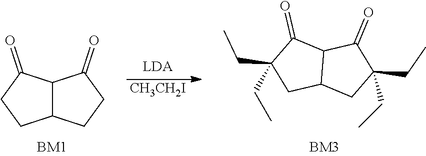

Synthesis of BM3: the synthesis method of BM3 was the same as that of BM2, except that iodomethane was replaced with iodoethane to gave BM3 of white solid (yield: 53%).

MS for C₁₆H₂₆O₂: 250.19; found: 250.2.

Anal. calcd. for C₁₆H₂₆O₂: C: 76.75%, H: 10.47%; found: C: 76.77%, H: 10.48%.

### Preparation Example B4: Preparation of Compound of Formula BM4

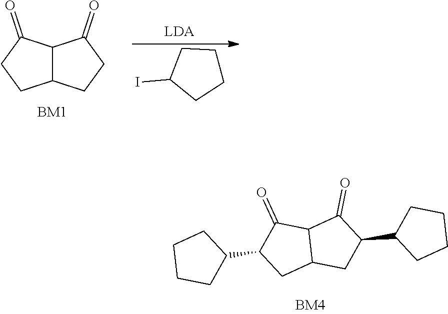

Synthesis of BM4: BM1 (20 mmol) was dissolved in THF (60 ml) and after complete dissolution, the mixture was chilled to −30° C. and 1M LDA solution (40 ml) was added slowly and stirred at −20° C. for 2 h, then iodocyclopentane (20 mmol) was added, warmed slowly to room temperature and stirred for 2 h.

The obtained mixture was chilled to −30° C. and then 1M LDA solution (40 ml) was added slowly and stirred at −20° C. for 2 h, then iodocyclopentane (20 mmol) was added, warmed slowly to room temperature and stirred for 2 h. The reaction was quenched by saturated aqueous sodium bisulfite solution, extracted three times with dichloromethane, the organic phases were combined, The extracts was evaporated under reduced pressure, chromatographed on a silica gel column and gave BM4 of white solid (yield: 60%).

MS for C₁₈H₂₆O₂: 274.19; found: 274.2.

Anal. calcd. for C₁₈H₂₆O₂: C: 78.79%, H: 9.55%; found: C: 78.76%, H: 9.54%.

### Preparation Example B5: Preparation of Compound of Formula BM5

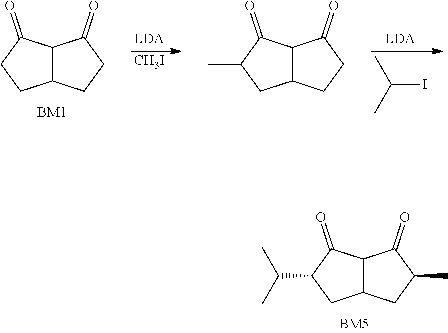

Synthesis of BM5: BM1 (40 mmol) was dissolved in THF (80 ml) and after complete dissolution, the mixture was chilled to −30° C. and 1M LDA solution (80 ml) was added slowly and stirred at −20° C. for 3 h, then iodomethane (40 mmol) was added, warmed slowly to room temperature and stirred for 3 h.

The obtained mixture was chilled to −30° C., then 1M LDA solution (40 ml) was slowly added, after complete dissolution, stirred for 2 h at −20° C., then 2-iodopropane (40 mmol) was added, warmed to the room temperature, stirred for 2 h, The reaction was quenched by saturated aqueous sodium bisulfite solution, extracted three times with dichloromethane, the organic phases were combined, The extracts was evaporated under reduced pressure, chromatographed on a silica gel column and gave BM5 of white solid (yield: 57%).

MS for C₁₂H₁₈O₂: 194.13; found: 194.1.

Anal. calcd. for C₁₂H₁₈O₂: C: 74.19%, H: 9.34%; found: C: 74.15%, H: 9.39%.

### Preparation Example B6: Preparation of Compound of Formula BM6

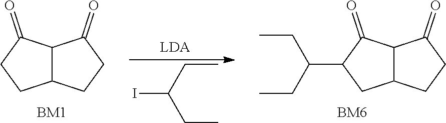

Synthesis of BM6: BM1 (30 mmol) was dissolved in THE (60 ml) and after complete dissolution, the mixture was chilled to −30° C. and 1M LDA solution (60 ml) was added slowly and stirred at −20° C. for 2 h, then 3-iodopentane (30 mmol) was added, warmed to the room temperature, stirred for 2 h. The reaction was quenched by saturated aqueous sodium bisulfite solution, extracted three times with dichloromethane, the organic phases were combined, The extracts was evaporated under reduced pressure, chromatographed on a silica gel column and gave BM6 of white solid (yield: 61%).

MS for C₁₃H₂₀O₂: 208.15; found: 208.1.

Anal. calcd. for C₁₃H₂₀O₂: C: 74.96%, H: 9.68%; found: C: 74.92%, H: 9.70%.

### Preparation Example B7: Preparation of Compound B-12

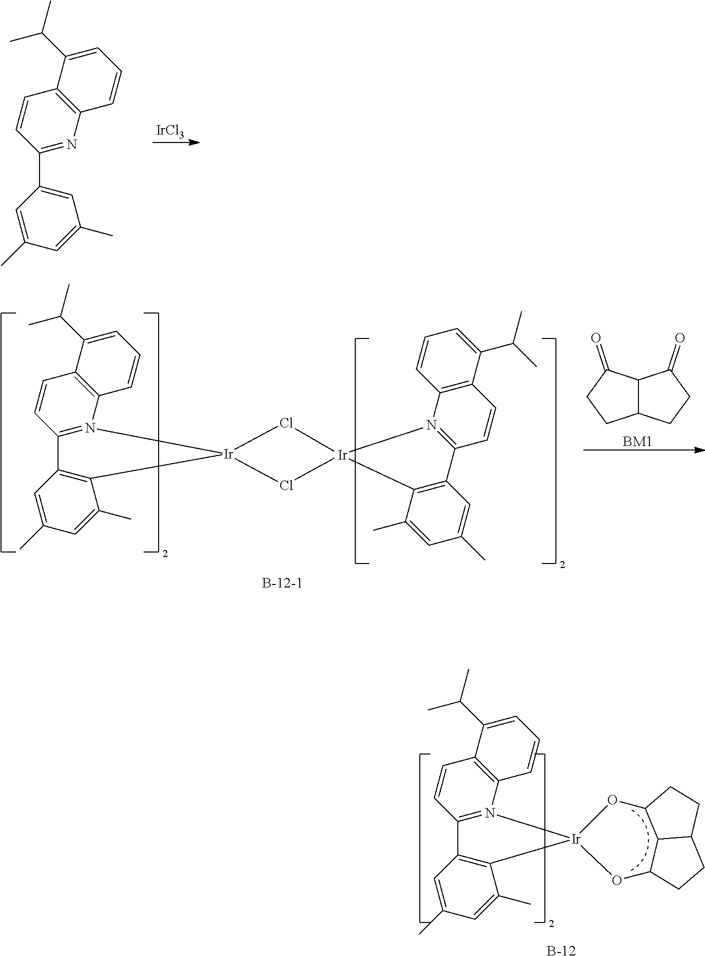

Synthesis of B-12-1: the synthesis method of B-12-1 was the same as that of A-10-1, except that 5-phenyl-2-methylquinoline was replaced with 2-(3,5-dimethylphenyl)-5-isopropylquinoline to gave B-12-1 (yield: 58%).

Synthesis of B-12: the synthesis method of B-12 was the same as that of A-10, except that A-10-1 and AM1 were replaced with B-12-1 and BM1 to gave B-12 of orange-red solid (yield: 43%).

Anal. calcd.: C: 65.65%, H: 5.62%, N: 3.19%; found: C: 65.63%, H: 5.65%, N: 3.17%.

### Preparation Example B8: Preparation of Compound B-35

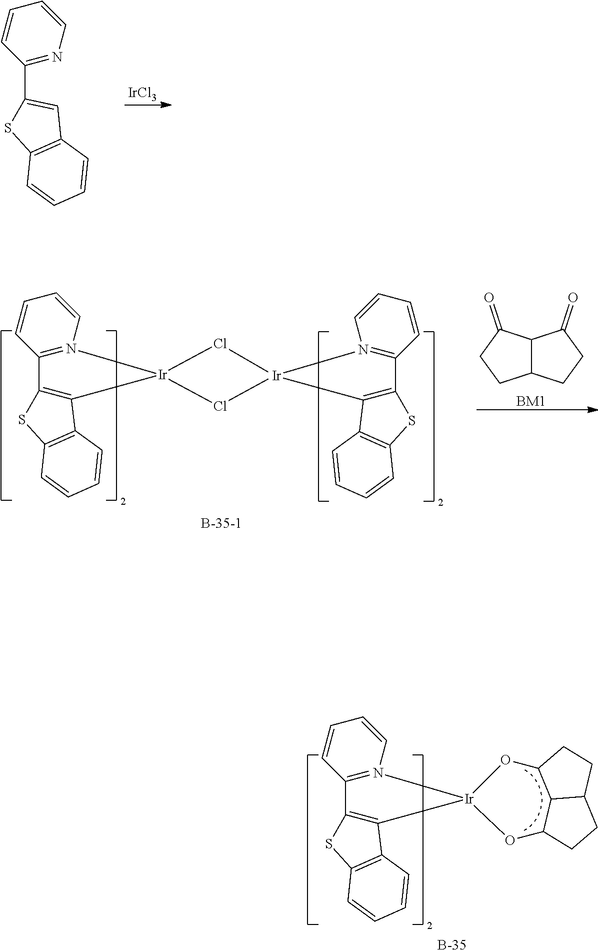

Synthesis of B-35-1: the synthesis method of B-35-1 was the same as that of A-10-1, except that 5-phenyl-2-methylquinoline was replaced with 2-(benzo[b]thiophen-2-yl)pyridine to gave B-35-1 (yield: 56%).

Synthesis of B-35: the synthesis method of B-35 was the same as that of A-10, except that A-10-1 and AM1 were replaced with B-35-1 and BM1 to gave B-35 of yellow-green solid (yield: 45%).

Anal. calcd.: C: 54.45%, H: 3.36%, N: 3.74%; found: C: 54.43%, H: 3.38%, N: 3.75%.

### Preparation Example B9: Preparation of Compound B-55

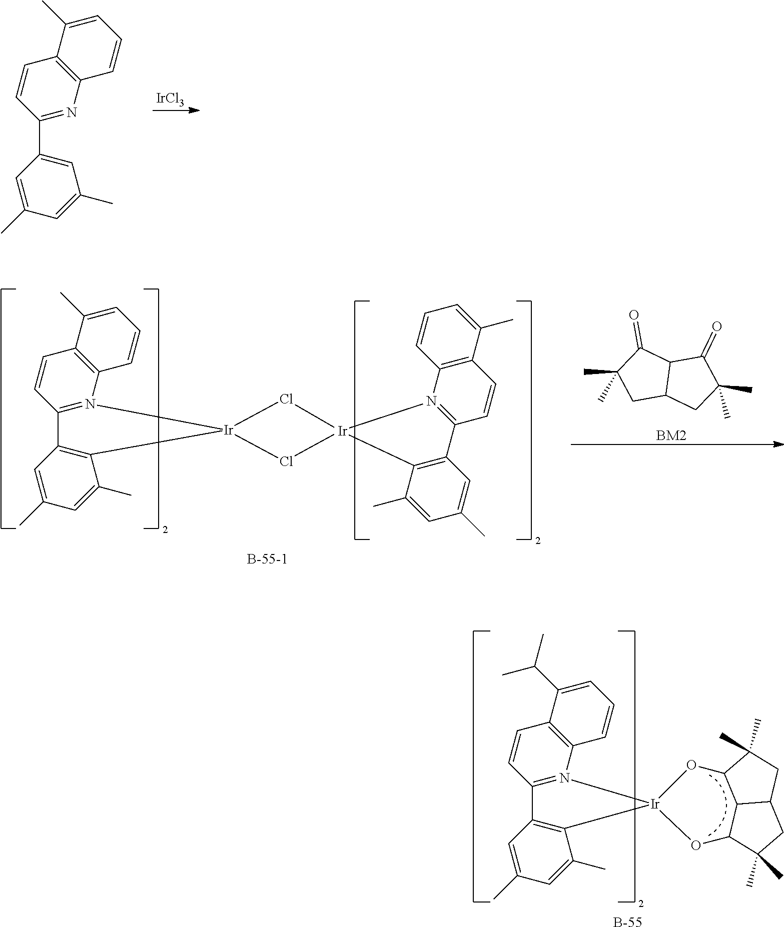

Synthesis of B-55-1: the synthesis method of B-55-1 was the same as that of A-10-1, except that 5-phenyl-2-methylquinoline was replaced with 2-(3,5-dimethylphenyl)-5-methylquinoline to gave B-55-1 (yield: 51%).

Synthesis of B-55: the synthesis method of B-55 was the same as that of A-10, except that A-10-1 and AM1 were replaced with B-55-1 and BM2 to gave B-55 of orange-red solid (yield: 46%).

Anal. calcd.: C: 65.65%, H: 5.62%, N: 3.19%; found: C: 65.66%, H: 5.61%, N: 3.17%.

### Preparation Example B10: Preparation of Compound B-106

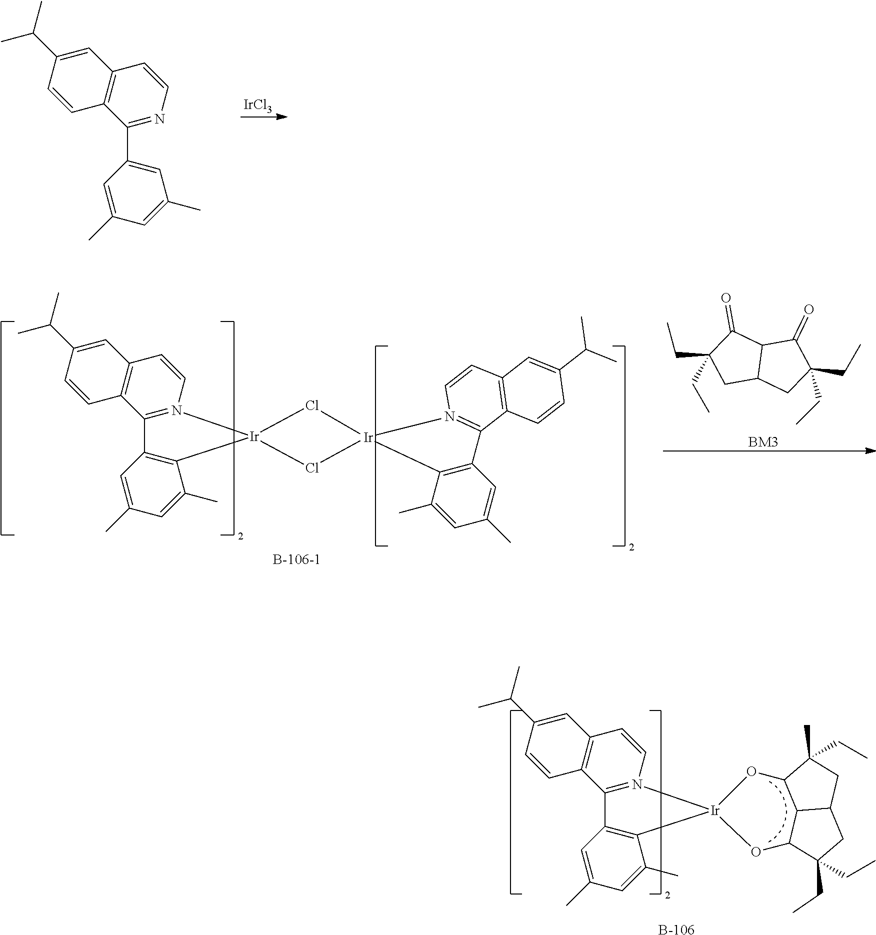

Synthesis of B-106-1: the synthesis method of B-106-1 was the same as that of A-10-1, except that 5-phenyl-2-methylquinoline was replaced with 1-(3,5-dimethylphenyl)-6-isopropylisoquinoline to gave B-106-1 (yield: 58%).

Synthesis of B-106: the synthesis method of B-106 was the same as that of A-10, except that A-10-1 and AM1 were replaced with B-106-1 and BM3 to gave B-106 of deep red solid (yield: 47%).

Anal. calcd.: C: 67.92%, H: 6.62%, N: 2.83%; found: C: 67.95%, H: 6.66%, N: 2.87%.

### Preparation Example B11: Preparation of Compound B-151

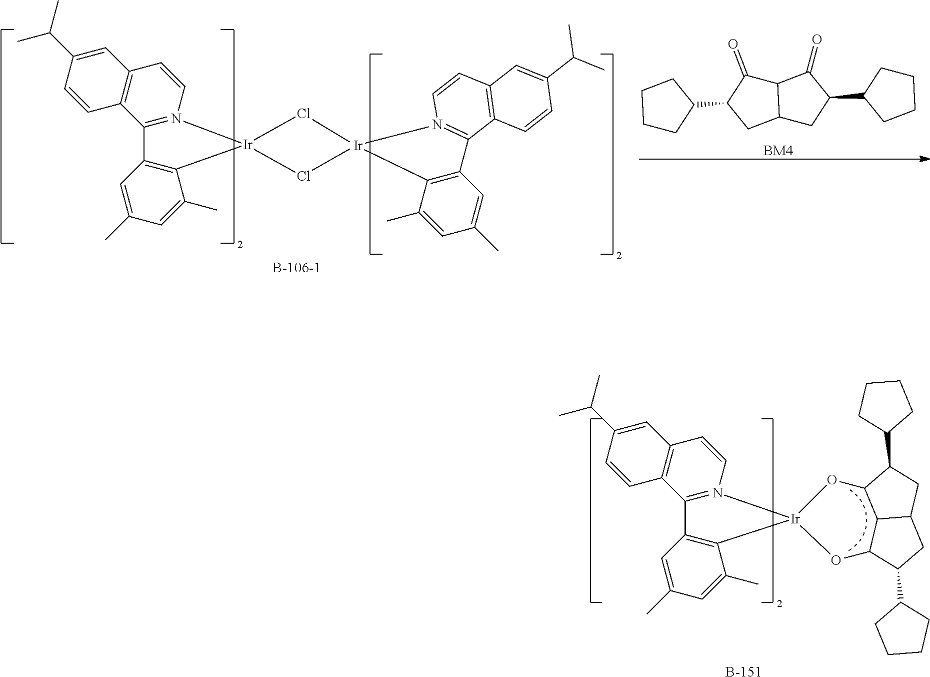

Synthesis of B-151: the synthesis method of B-151 was the same as that of A-10, except that A-10-1 and AM1 were replaced with B-106-1 and BM4 to gave B-151 of deep red solid (yield: 44%).

Anal. calcd.: C: 68.68%, H: 6.46%, N: 2.76%; found: C: 68.66%, H: 6.47%, N: 2.78%.

### Preparation Example B12: Preparation of Compound B-158

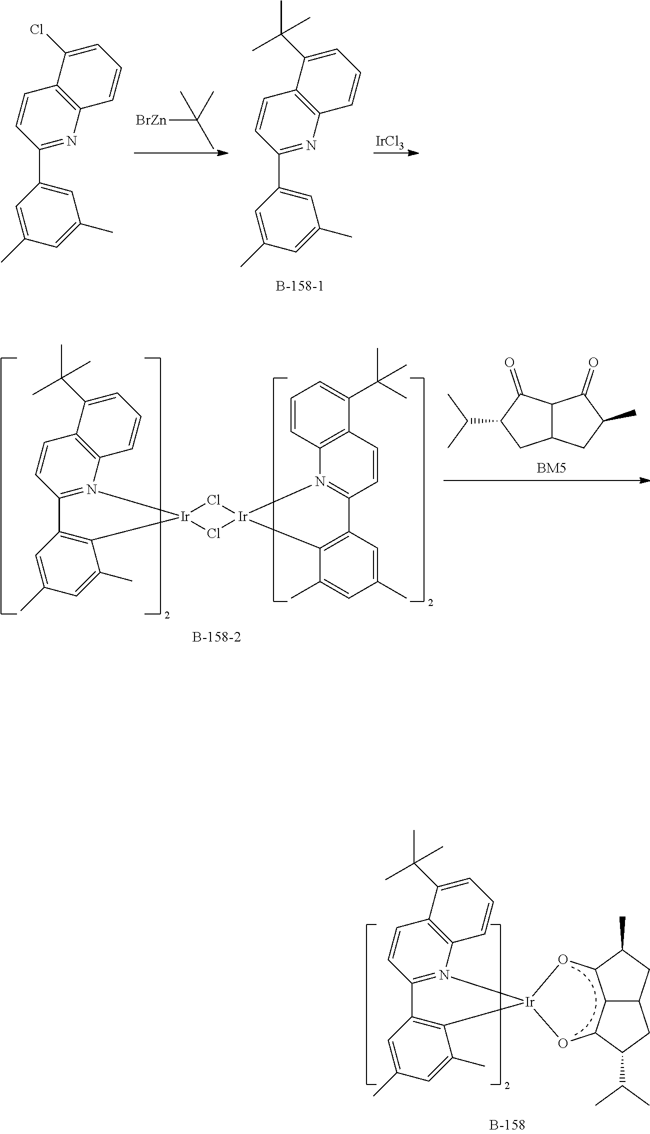

Synthesis of B-158-1: 5-chloro-2-(3,5-dimethylphenyl)quinoline (30 mmol), 2′-(dicyclohexylphosphino)-N2,N2,N6,N6-tetramethyl-[1,1′-biphenyl]-2,6-diamine (CPhos) (0.12 mmol), and diacetoxypalladium (0.6 mmol) were dissolved in nitrogen degassed THF (80 ml), the mixture was solution 1.

Tert-butyl zinc bromide (45 mmol) which dissolved in THE was slowly added to solution 1, and stirred at room temperature for 6 h. Diluted with ethyl acetate, washed with brine, added sodium sulfate for drying, The extracts was evaporated under reduced pressure, chromatographed on a silica gel column and gave B-158-1 (yield: 75%).

Synthesis of B-158-2: the synthesis method of B-158-2 was the same as that of A-10-1, except that 5-phenyl-2-methylquinoline was replaced with B-158-1 to gave B-158-2 (yield: 60%).

Synthesis of B-158: the synthesis method of B-158 was the same as that of A-10, except that A-10-1 and AM1 were replaced with B-158-1 and BM5 to gave B-158 of orange-red solid (yield: 47%).

Anal. calcd.: C: 67.40%, H: 6.39%, N: 2.91%; found: C: 67.42%, H: 6.37%, N: 2.92%.

### Preparation Example B13: Preparation of Compound B-161

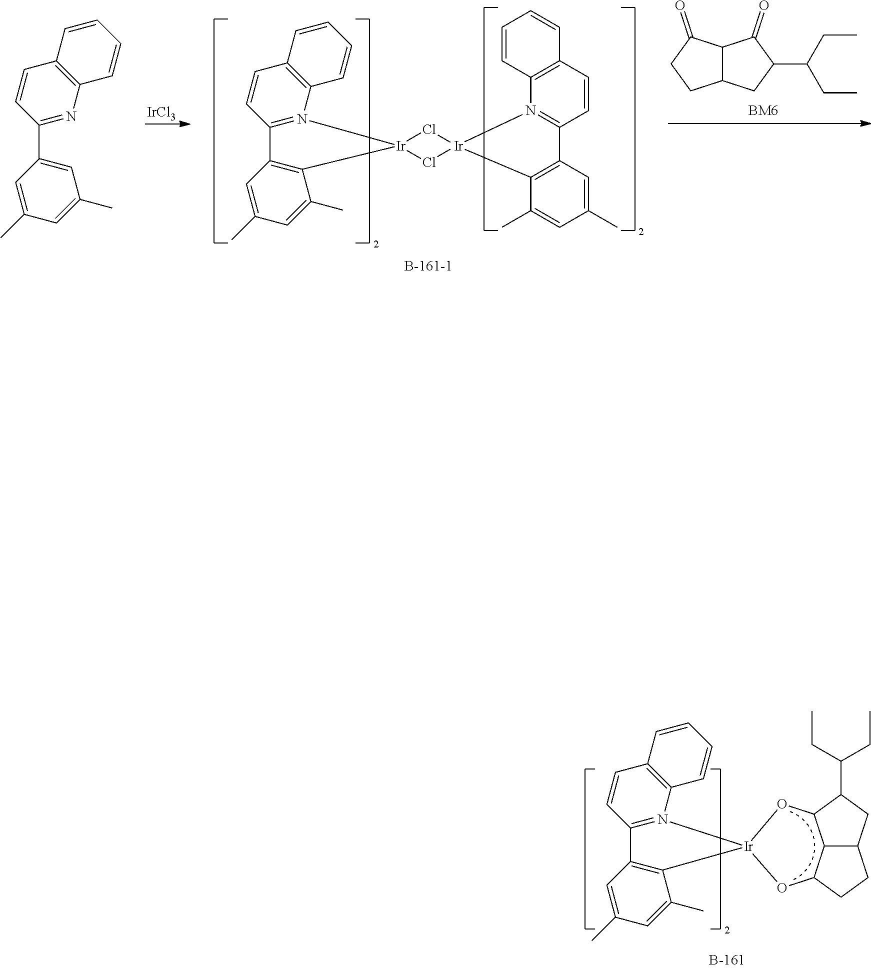

Synthesis of B-161-1: the synthesis method of B-161-1 was the same as that of A-10-1, except that 5-phenyl-2-methylquinoline was replaced with 2-(3,5-dimethylphenyl)quinoline to gave B-161-1 (yield: 55%).

Synthesis of B-161: the synthesis method of B-161 was the same as that of A-10, except that A-10-1 and AM1 were replaced with B-161-1 and BM6 to gave B-161 of orange-red solid (yield: 48%).

Anal. calcd.: C: 65.33%, H: 5.48%, N: 3.24%; found: C: 65.37%, H: 5.52%, N: 3.28%.

The following compounds were prepared in a similar manner to the synthesis of compound B-12, except that the raw materials were replaced as appropriate.

Compound B-1: Anal. calcd.: C: 56.50%, H: 3.95%, N: 4.39%; found: C: 56.54%, H: 3.95%, N: 4.37%.

Compound B-16: Anal. calcd.: C: 65.65%, H: 5.62%, N: 3.19%; found: C: 65.66%, H: 5.64%, N: 3.14%.

Compound B-31: Anal. calcd.: C: 63.53%, H: 4.70%, N: 3.53%; found: C: 63.55%, H: 4.71%, N: 3.54%.

Compound B-45: Anal. calcd.: C: 56.50%, H: 3.95%, N: 4.39%; found: C: 56.53%, H: 3.92%, N: 4.40%.

Compound B-46: Anal. calcd.: C: 65.30%, H: 4.88%, N: 3.31%; found: C: 65.33%, H: 4.89%, N: 3.30%.

Compound B-49: Anal. calcd.: C: 65.65%, H: 5.62%, N: 3.19%; found: C: 65.68%, H: 5.63%, N: 3.12%.

Compound B-63: Anal. calcd.: C: 65.65%, H: 5.62%, N: 3.19%; found: C: 65.69%, H: 5.64%, N: 3.16%.

Compound B-68: Anal. calcd.: C: 66.85%, H: 6.15%, N: 3.00%; found: C: 66.87%, H: 6.16%, N: 3.04%.

Compound B-72: Anal. calcd.: C: 64.99%, H: 5.34%, N: 3.30%; found: C: 65.02%, H: 5.33%, N: 3.32%.

Compound B-84: Anal. calcd.: C: 64.98%, H: 4.69%, N: 6.06%; found: C: 64.95%, H: 4.72%, N: 6.03%.

Compound B-85: Anal. calcd.: C: 60.86%, H: 5.51%, N: 3.74%; found: C: 60.84%, H: 5.50%, N: 3.76%.

Compound B-91: Anal. calcd.: C: 65.43%, H: 5.95%, N: 3.18%; found: C: 65.45%, H: 5.94%, N: 3.16%.

Compound B-95: Anal. calcd.: C: 68.93%, H: 6.94%, N: 2.68%; found: C: 68.95%, H: 6.96%, N: 2.65%.

Compound B-102: Anal. calcd.: C: 67.19%, H: 6.68%, N: 2.90%; found: C: 67.23%, H: 6.66%, N: 2.93%.

Compound B-114: Anal. calcd.: C: 65.65%, H: 5.62%, N: 3.19%; found: C: 65.67%, H: 5.63%, N: 3.18%.

Compound B-122: Anal. calcd.: C: 60.78%, H: 4.98%, N: 3.38%; found: C: 60.75%, H: 4.97%, N: 3.42%.

Compound B-145: Anal. calcd.: C: 60.86%, H: 5.51%, N: 3.74%; found: C: 60.84%, H: 5.53%, N: 3.74%.

### Preparation C1: Preparation of Compound of Formula CM1

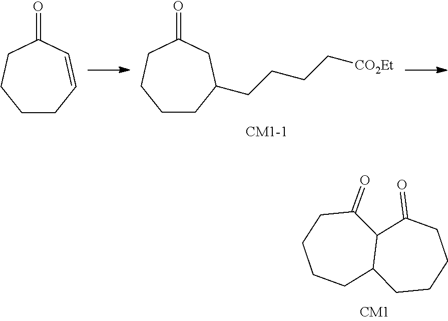 [SMILES: O=C1C=CCCCC1 ; CCOC(=O)CCCCC1CCCCC(=O)C1 ; O=C1CCCCC2CCCCC(=O)C12]

Synthesis of CM1-1: the synthesis method of CM1-1 was the same as that of AM1-1, except that ethyl 4-iodobutyrate and 2-cyclohexen-1-one were replaced with ethyl 4-iodovalerate and 2-cyclohepten-1-one to gave CM1-1 of white solid (yield: 77%).

Synthesis of CM1: the synthesis of CM1 was the same as that of AM1, except that AM1-1 was replaced with CM1-1 to gave CM1 of white solid (yield: 70%).

MS for C₁₂H₁₈O₂: 194.13; found: 194.1.

Anal. calcd. for C₁₂H₁₈O₂: C: 74.19%, H: 9.34%; found: C: 74.22%, H: 9.33%.

### Preparation C2: Preparation of Compound of Formula CM2

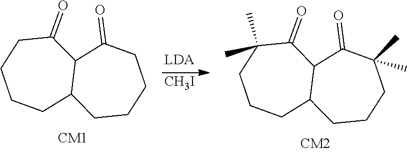

Synthesis of CM2: the synthesis of the CM2 was the same as that of BM2, except that BM1 was replaced with CM1 to gave CM2 of white solid (yield: 56%).

MS for C₁₆H₁₆O₂: 250.19; found: 250.2.

Anal. calcd. for C₁₆H₁₆O₂: C: 76.75%, H: 10.47%; found: C: 76.77%, H: 10.45%.

### Preparation C3: Preparation of Compound of Formula CM3

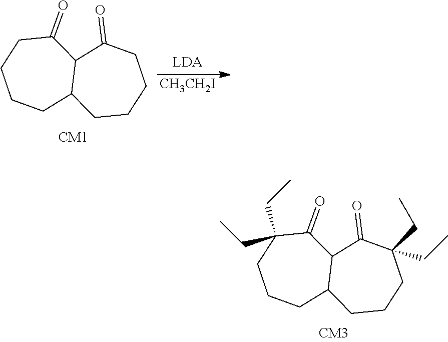

Synthesis of CM 3: the synthesis method of CM 3 was the same as that of BM2, except that BM1 and methyl iodide were replaced with CM1 and ethyl iodide to gave CM3 of white solid (yield: 55%).

MS for C₂₀H₃₄O₂: 306.26; found: 306.3.

Anal. calcd. for C₂₀H₃₄O₂: C: 78.38%, H: 11.18%; found: C: 78.41%, H: 11.19%.

### Preparation C4: Preparation of Compound of Formula CM4

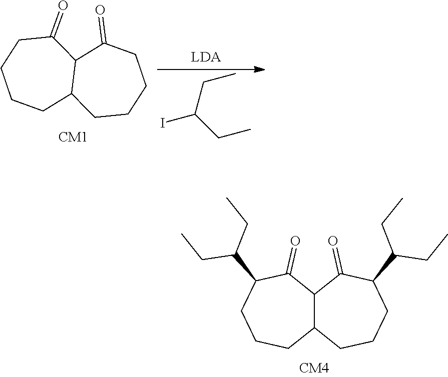

Synthesis of CM4: the synthesis method of CM4 was the same as that of BM4, except that BM1 and iodocyclopentane were replaced with CM1 and 3-iodopentane to gave CM4 of white solid (yield: 52%).

MS for C₂₂H₃₈O₂: 334.29; found: 334.3.

Anal. calcd. for C₂₂H₃₈O₂: C: 78.99%, H: 11.45%; found: C: 78.97%, H: 11.46%.

### Preparation C5: Preparation of Compound of Formula CM5

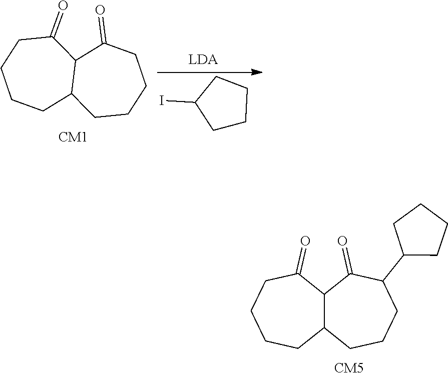

Synthesis of CM5: the synthesis method of CM5 was the same as that of BM6, except that BM1 and 3-iodopentane were replaced with CM1 and iodocyclopentane to gave CM5 of white solid (yield: 64%).

MS for C₁₇H₂₆O₂: 262.19; found: 262.2.

Anal. calcd. for C₁₇H₂₆O₂: C: 77.82%, H: 9.99%; found: C: 77.85%, H: 9.96%.

### Preparation C6: Preparation of Compound C-8

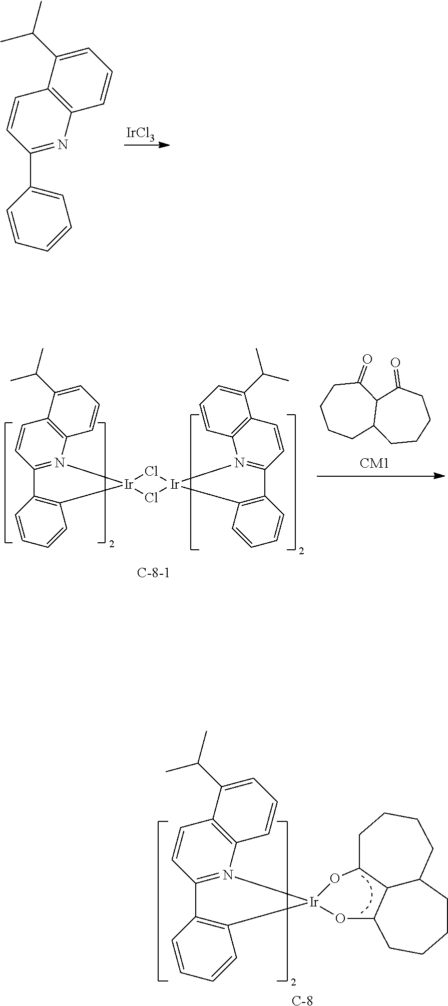

Synthesis of C-8-1: the synthesis method of C-8-1 was the same as that of A-10-1, except that 5-phenyl-2-methylquinoline was replaced with 5-isopropyl-2-phenylquinoline to gave C-8-1 (yield: 60%).

Synthesis of C-8: the synthesis method of C-8 was the same as that of A-10, except that A-10-1 and AM1 were replaced with C-8-1 and CM1 to gave C-8 of orange-yellow solid (yield: 46%).

Anal. calcd.: C: 65.65%, H: 5.62%, N: 3.19%; found: C: 65.67%, H: 5.60%, N: 3.16%.

### Preparation C7: Preparation of Compound C-52

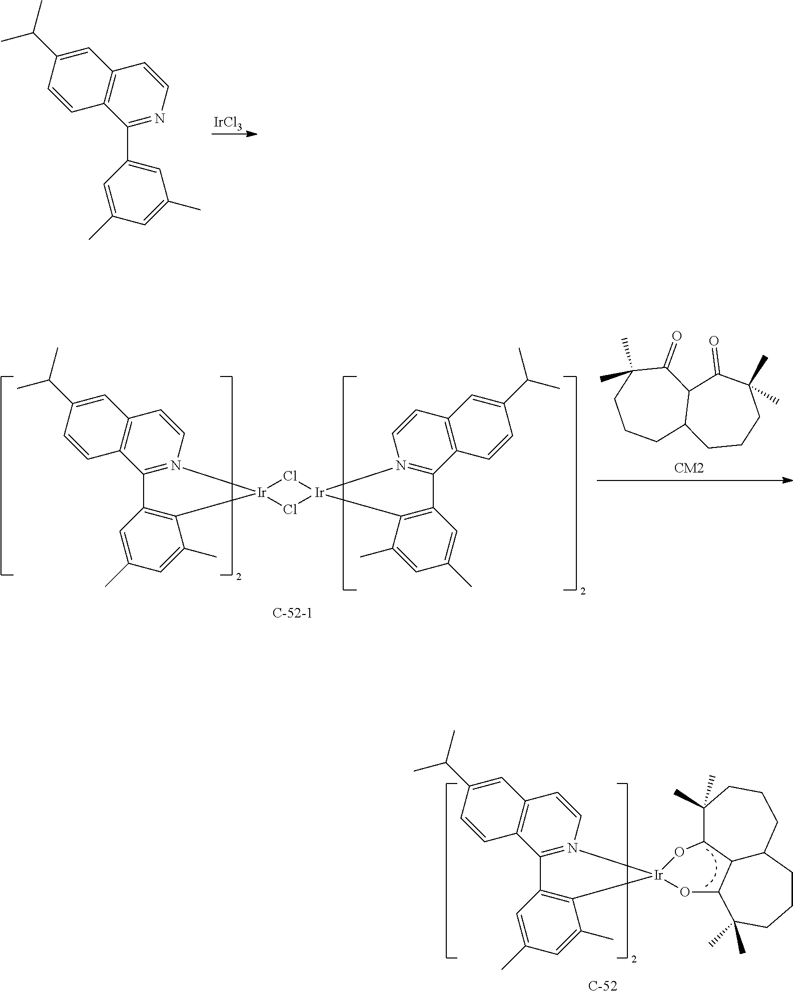

Synthesis of C-52-1: the synthesis method of C-52-1 was the same as that of A-10-1, except that 5-phenyl-2-methylquinoline was replaced with 1-(3,5-dimethylphenyl)-6-isopropylisoquinoline to gave C-52-1 (yield: 58%).

Synthesis of C-52: the synthesis method of C-52 was the same as that of A-10, except that A-10-1 and AM1 were replaced with C-52-1 and CM2 to gave C-52 of dark red black solid (yield: 42%).

Anal. calcd.: C: 67.92%, H: 6.62%, N: 2.83%; found: C: 67.94%, H: 6.65%, N: 2.81%.

### Preparation C8: Preparation of Compound C-66

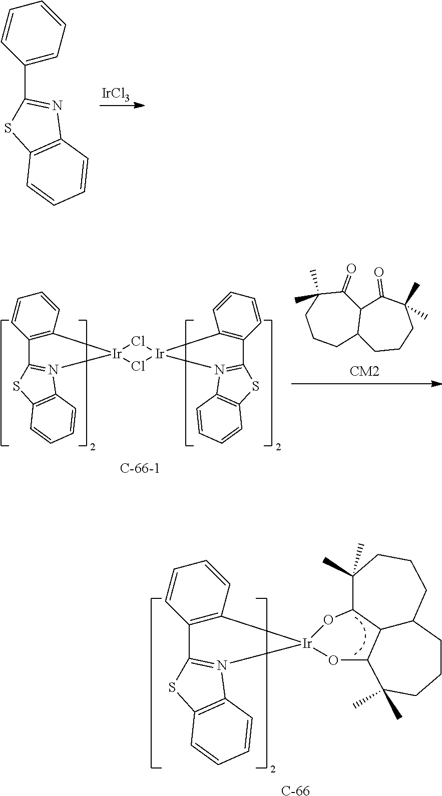

Synthesis of C-66-1: the synthesis method of C-66-1 was the same as that of A-10-1, except that 5-phenyl-2-methylquinoline was replaced with 2-phenylbenzo[d]thiazole to gave C-66-1 (yield: 57%).

Synthesis of C-66: the synthesis method of C-66 was the same as that of A-10, except that A-10-1 and AM1 were replaced with C-66-1 and CM2 to gave C-66 of yellow solid (yield: 49%).

Anal. calcd.: C: 58.51%, H: 4.79%, N: 3.25%; found: C: 58.53%, H: 4.76%, N: 3.27%.

### Preparation C9: Preparation of Compound C-77

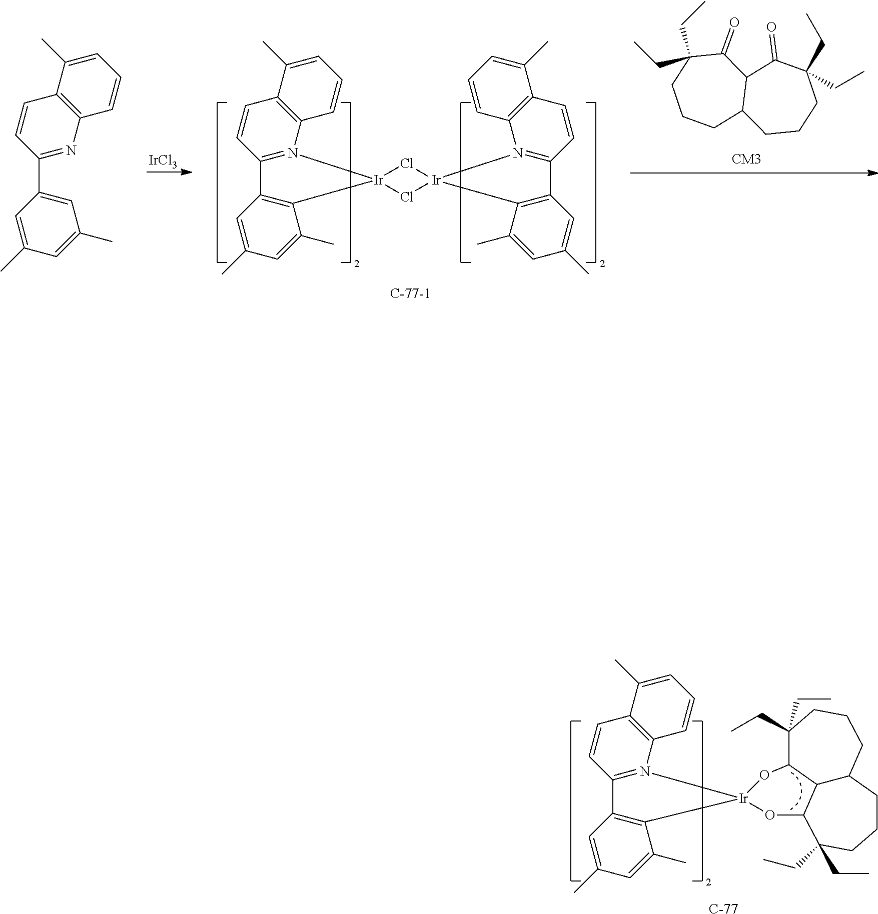

Synthesis of C-77-1: the synthesis method of C-77-1 was the same as that of A-10-1, except that 5-phenyl-2-methylquinoline was replaced with 2-(3,5-dimethylphenyl)-5-methylquinoline to gave C-77-1 (yield: 53%).

Synthesis of C-77: the synthesis method of C-77 was the same as that of A-10, except that A-10-1 and AM1 were replaced with C-77-1 and CM3 to gave C-77 of orange-red solid (yield: 47%).

Anal. calcd.: C: 67.92%, H: 6.62%, N: 2.83%; found: C: 67.90%, H: 6.63%, N: 2.86%.

### Preparation C10: Preparation of Compound C-102

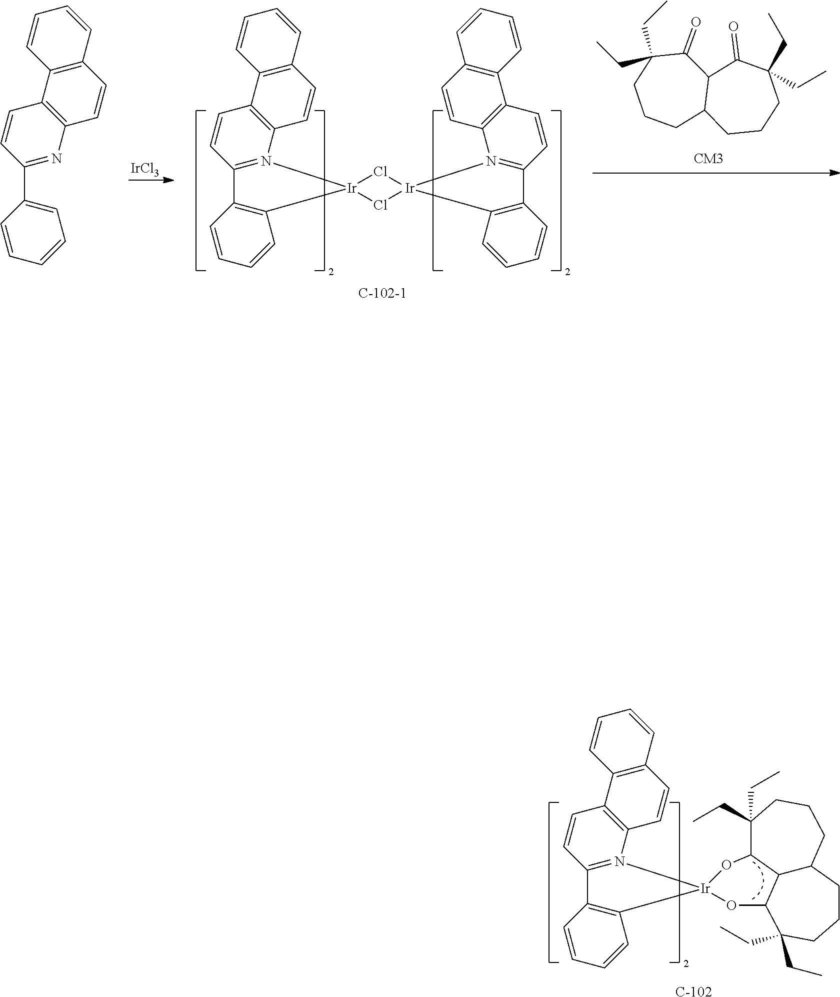

Synthesis of C-102-1: the synthesis method of C-102-1 was the same as that of A-10-1, except that 5-phenyl-2-methylquinoline was replaced with 3-phenylbenzo[f]quinoline to gave C-102-1 (yield: 58%).

Synthesis of C-102: the synthesis method of C-102 was the same as that of A-10, except that A-10-1 and AM1 were replaced with C-102-1 and CM3 to gave C-102 of orange yellow solid (yield: 43%).

Anal. calcd.: C: 69.23%, H: 5.71%, N: 2.78%; found: C: 69.26%, H: 5.74%, N: 2.76%.

### Preparation C11: Preparation of Compound C-125

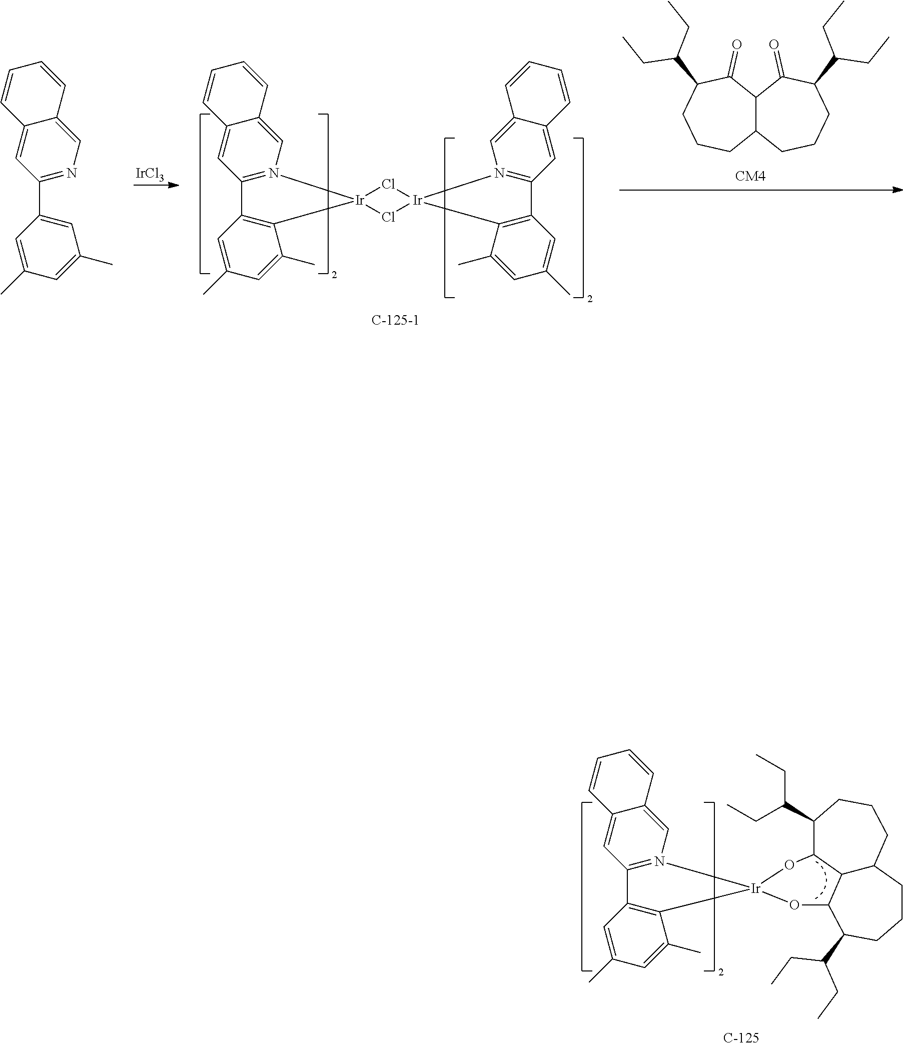

Synthesis of C-125-1: the synthesis method of C-125-1 was the same as that of A-10-1, except that 5-phenyl-2-methylquinoline was replaced with 3-(3,5-dimethylphenyl) isoquinoline to gave C-125-1 (yield: 55%).

Synthesis of C-125: the synthesis method of C-125 was the same as that of A-10, except that A-10-1 and AM1 were replaced with C-125-1 and CM4 to gave C-125 of yellow solid (yield: 43%).

Anal. calcd.: C: 67.92%, H: 6.62%, N: 2.83%; found: C: 67.96%, H: 6.60%, N: 2.81%.

### Preparation C12: Preparation of Compound C-139

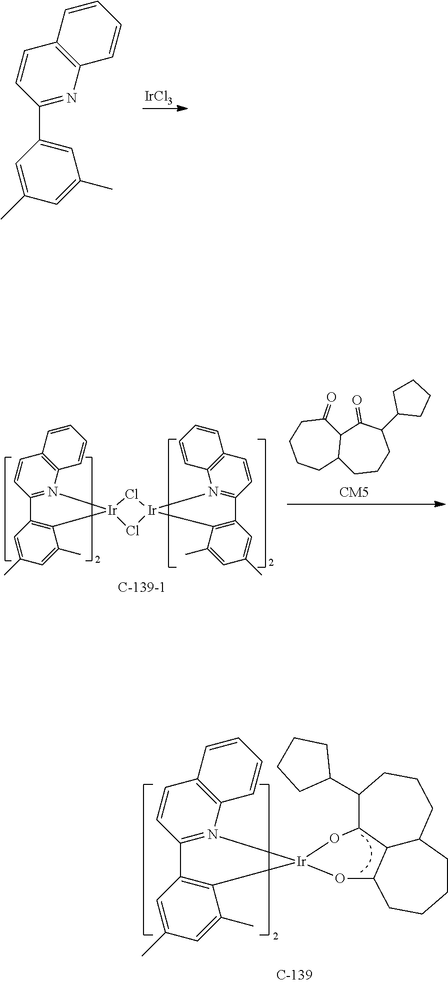

Synthesis of C-139-1: the synthesis method of C-139-1 was the same as that of A-10-1, except that 5-phenyl-2-methylquinoline was replaced with 2-(3,5-dimethylphenyl)quinoline to gave C-139-1 (yield: 55%).

Synthesis of C-139: the synthesis method of C-139 was the same as that of A-10, except that A-10-1 and AM1 were replaced with C-139 and CM5 to gave C-139 of orange-red solid (yield: 49%).

Anal. calcd.: C: 66.71%, H: 5.82%, N: 3.05%; found: C: 66.74%, H: 5.85%, N: 3.01%.

The following compounds were prepared in a similar manner to the synthesis of compound C-8, except that the raw materials were replaced as appropriate.

Compound C-11: Anal. calcd.: C: 64.99%, H: 5.34%, N: 3.30%; found: C: 64.96%, H: 5.37%, N: 3.32%.

Compound C-12: Anal. calcd.: C: 65.65%, H: 5.62%, N: 3.19%; found: C: 65.62%, H: 5.65%, N: 3.14%.

Compound C-20: Anal. calcd.: C: 66.85%, H: 6.15%, N: 3.00%; found: C: 66.82%, H: 6.14%, N: 3.05%.

Compound C-21: Anal. calcd.: C: 63.53%, H: 4.70%, N: 3.53%; found: C: 63.55%, H: 4.73%, N: 3.50%.

Compound C-37: Anal. calcd.: C: 60.86%, H: 6.51%, N: 3.74%; found: C: 60.84%, H: 6.51%, N: 3.76%.

Compound C-42: Anal. calcd.: C: 66.85%, H: 6.15%, N: 3.00%; found: C: 66.82%, H: 6.16%, N: 3.02%.

Compound C-51: Anal. calcd.: C: 66.27%, H: 5.90%, N: 3.09%; found: C: 66.25%, H: 5.88%, N: 3.06%.

Compound C-59: Anal. calcd.: C: 68.19%, H: 6.23%, N: 2.84%; found: C: 68.21%, H: 6.26%, N: 2.81%.

Compound C-69: Anal. calcd.: C: 67.68%, H: 6.00%, N: 2.92%; found: C: 67.69%, H: 6.03%, N: 2.91%.

Compound C-72: Anal. calcd.: C: 67.92%, H: 6.62%, N: 2.83%; found: C: 67.96%, H: 6.57%, N: 2.85%.

Compound C-92: Anal. calcd.: C: 68.87%, H: 7.03%, N: 2.68%; found: C: 68.88%, H: 7.05%, N: 2.67%.

Compound C-96: Anal. calcd.: C: 66.85%, H: 6.15%, N: 3.00%; found: C: 66.87%, H: 6.18%, N: 3.03%.

Compound C-108: Anal. calcd.: C: 67.22%, H: 5.74%, N: 5.41%; found: C: 67.25%, H: 5.73%, N: 5.40%.

Compound C-119: Anal. calcd.: C: 61.59%, H: 5.29%, N: 3.26%; found: C: 61.57%, H: 5.30%, N: 3.27%.

### Preparation D1: Preparation of Compound of Formula DM1

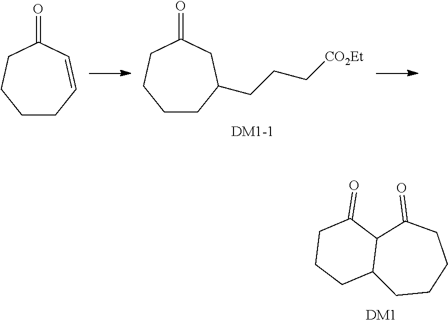

Synthesis of DM1-1: the synthesis method of DM1-1 was the same as that of AM1-1, except that the 2-cyclohexen-1-one was replaced with 2-cyclohepten-1-one to gave DM1-1 of white solid (yield: 75%).

Synthesis of DM1: the synthesis method of DM1 was the same as that of AM1, except that AM1-1 was replaced with DM1-1 to gave DM1 of white solid (yield: 70%).

MS for C₁₁H₁₆O₂: 180.12; found: 180.1.

Anal. calcd. for C₁₁H₁₆O₂: C: 73.30%, H: 8.95%; found: C: 73.33%, H: 8.97%.

### Preparation D2: Preparation of Compound of Formula DM2

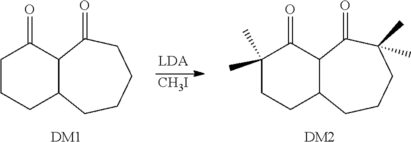

Synthesis of DM2: the synthesis method of DM2 was the same as that of BM2, except that BM1 was replaced with DM1 to gave DM2 of white solid (yield: 55%).

MS for C₁₅H₂₄O₂: 236.18; found: 236.2.

Anal. calcd. for C₁₅H₂₄O₂: C: 76.23%, H: 10.24%; found: C: 76.27%, H: 10.25%.

### Preparation D3: Preparation of Compound of Formula DM3

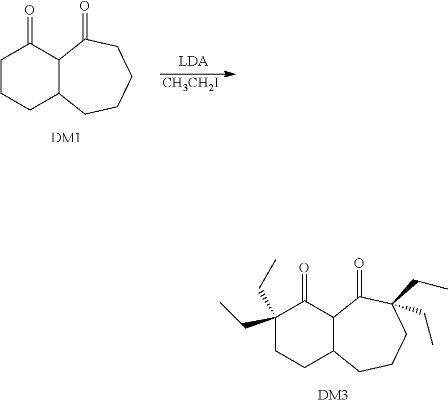

Synthesis of DM3: the synthesis method of DM3 was the same as that of BM2, except that BM1 and methyl iodide were replaced with DM1 and ethyl iodide to gave DM3 of white solid (yield: 58%).

MS for C₁₉H₃₂O₂: 292.24; found: 292.2.

Anal. calcd. for C₁₉H₃₂O₂: C: 78.03%, H: 11.03%; found: C: 78.05%, H: 11.00%.

### Preparation D4: Preparation of Compound of Formula DM4

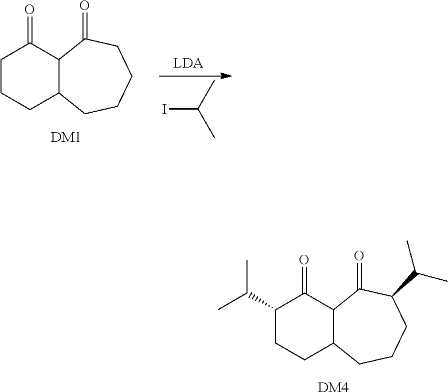

Synthesis of DM4: the synthesis method of DM4 was the same as that of BM4, except that BM1 and iodocyclopentane were replaced with DM1 and 2-iodopropane to gave DM4 of white solid (yield: 67%).

MS for C₁₇H₂₈O₂: 264.21; found: 264.2.

Anal. calcd. for C₁₇H₂₈O₂: C: 77.22%, H: 10.67%; found: C: 77.25%, H: 10.66%.

### Preparation D5: Preparation of Compound D-11

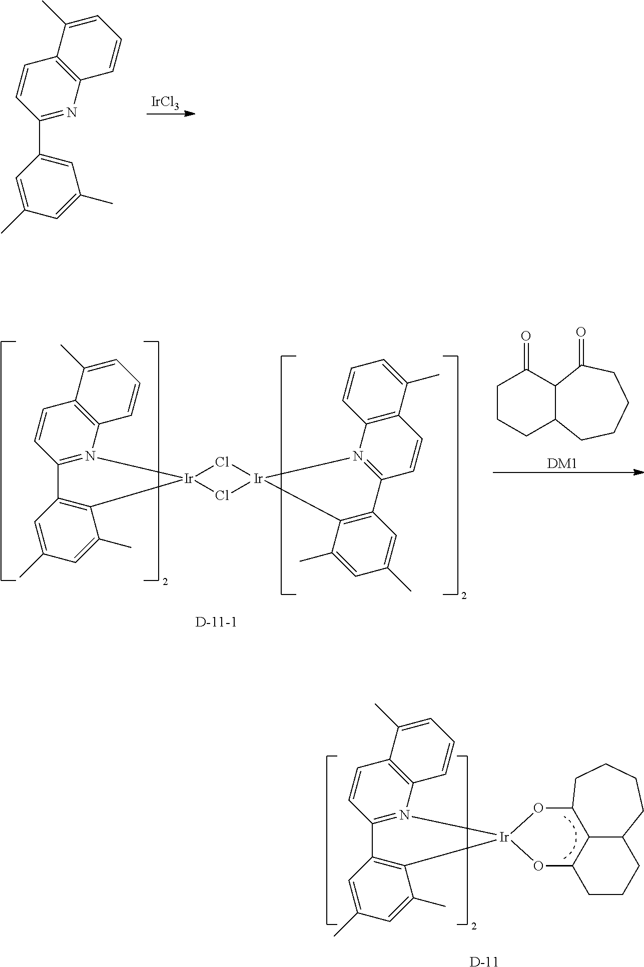

Synthesis of D-11-1: the synthesis method of D-11-1 was the same as that of A-10-1, except that 5-phenyl-2-methylquinoline was replaced with 2-(3,5-dimethylphenyl)-5-methylquinoline to gave D-11-1 (yield: 51%).

Synthesis of D-11: the synthesis method of D-11 was the same as that of A-10, except that A-10-1 and AM1 were replaced with D-11-1 and DM1 to gave D-11 of orange-red solid (yield: 45%).

Anal. calcd.: C: 65.65%, H: 5.62%, N: 3.19%; found: C: 65.63%, H: 5.65%, N: 3.17%.

### Preparation D6: Preparation of Compound D-52

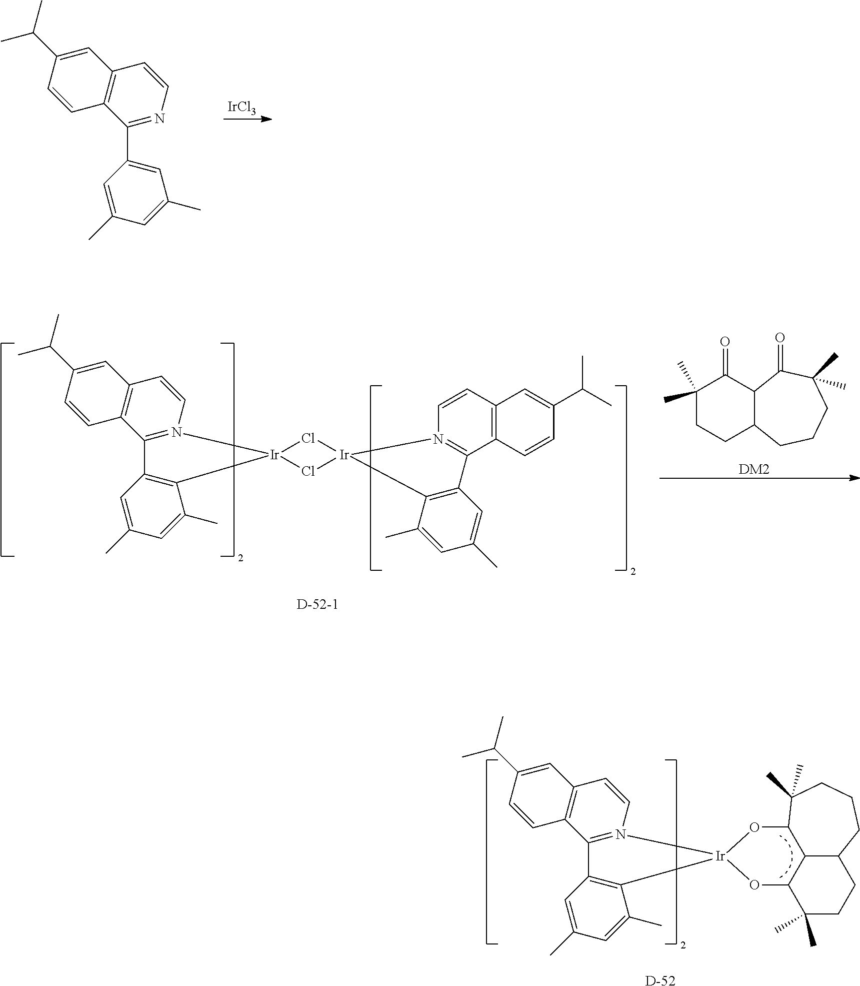

Synthesis of D-52-1: the synthesis method of D-52-1 was the same as that of A-10-1, except that 5-phenyl-2-methylquinoline was replaced with 1-(3,5-dimethylphenyl)-6-isopropylisoquinoline to gave D-52-1 (yield: 58%).

Synthesis of D-52: the synthesis method of D-52 was the same as that of A-10, except that A-10-1 and AM1 were replaced with D-52-1 and DM2 to gave D-52 of deep red solid (yield: 48%).

Anal. calcd.: C: 54.45%, H: 3.36%, N: 3.74%; found: C: 54.43%, H: 3.38%, N: 3.75%.

### Preparation D7: Preparation of Compound D-84

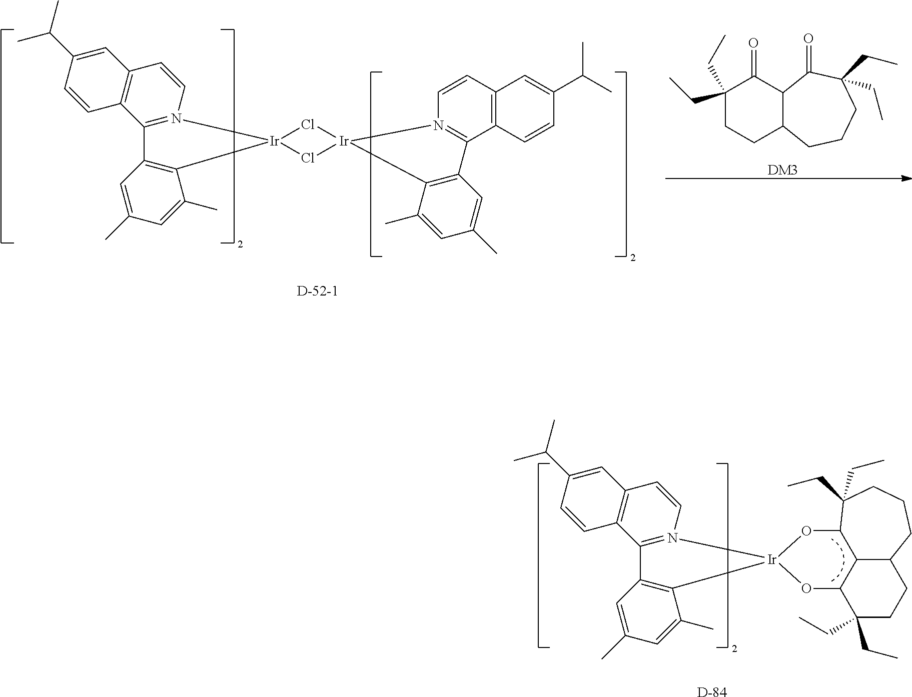

Synthesis of D-84: the synthesis method of D-84 was the same as that of A-10, except that A-10-1 and AM1 were replaced with D-52-1 and DM3 to gave D-84 of deep red solid (yield: 44%).

Anal. calcd.: C: 68.68%, H: 6.46%, N: 2.76%; found: C: 68.66%, H: 6.47%, N: 2.78%.

### Preparation D8: Preparation of Compound D-92

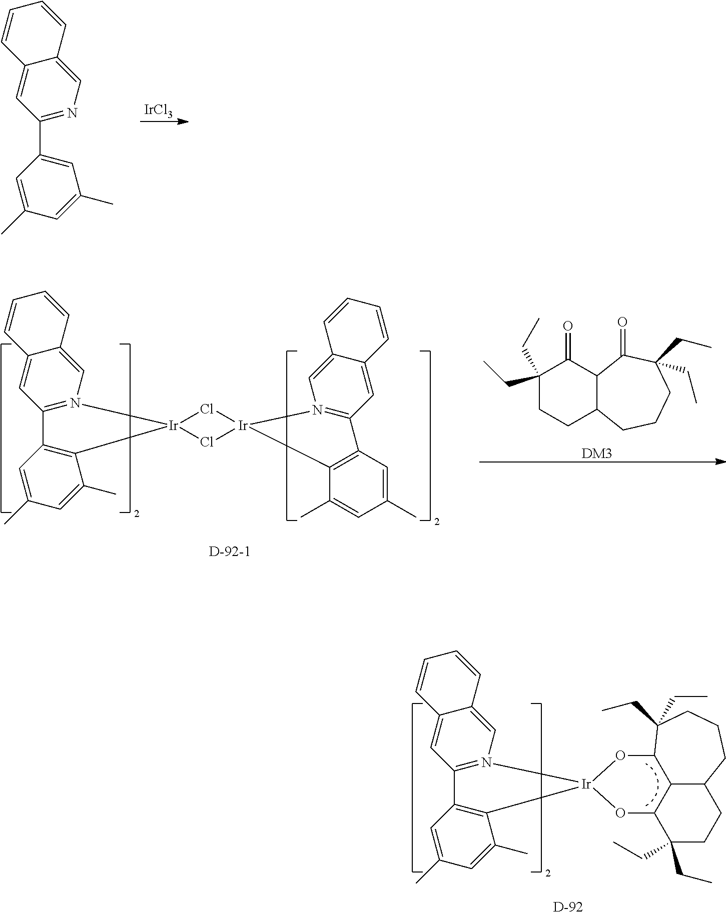

Synthesis of D-92-1: the synthesis method of D-92-1 was the same as that of A-10-1, except that 5-phenyl-2-methylquinoline was replaced with 3-(3,5-dimethylphenyl)isoquinoline to gave D-92-1 (yield: 56%).

Synthesis of D-92: the synthesis method of D-92 was the same as that of A-10, except that A-10-1 and AM1 were replaced with D-92-1 and DM3 to gave D-92 of deep red solid (yield: 47%).

Anal. calcd.: C: 67.92%, H: 6.62%, N: 2.83%; found: C: 67.95%, H: 6.66%, N: 2.87%.

### Preparation D9: Preparation of Compound D-96

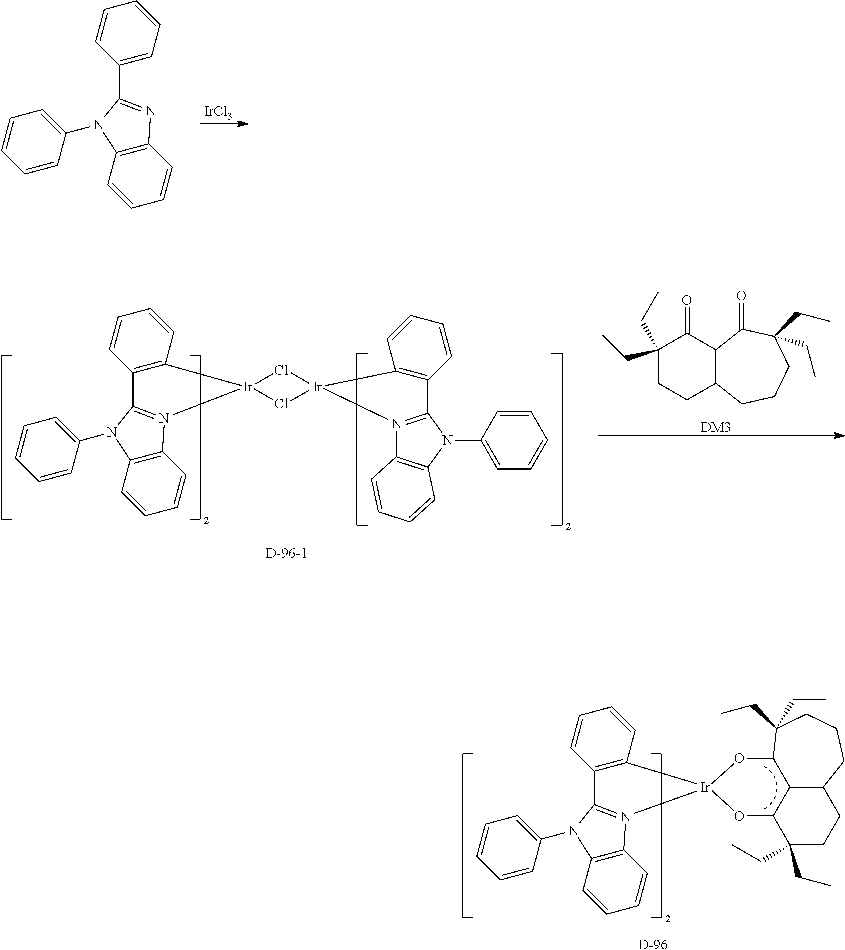

Synthesis of D-96-1: the synthesis method of D-96-1 was the same as that of A-10-1, except that 5-phenyl-2-methylquinoline was replaced with 1,2-diphenyl-1H-benzo[d]imidazole to gave D-96-1 (yield: 54%).

Synthesis of D-96: the synthesis method of D-96 was the same as that of A-10, except that A-10-1 and AM1 were replaced with D-96-1 and DM3 to gave D-96 of deep red solid (yield: 43%).

Anal. calcd.: C: 67.92%, H: 6.62%, N: 2.83%; found: C: 67.95%, H: 6.66%, N: 2.87%.

### Preparation D10: Preparation of Compound D-108

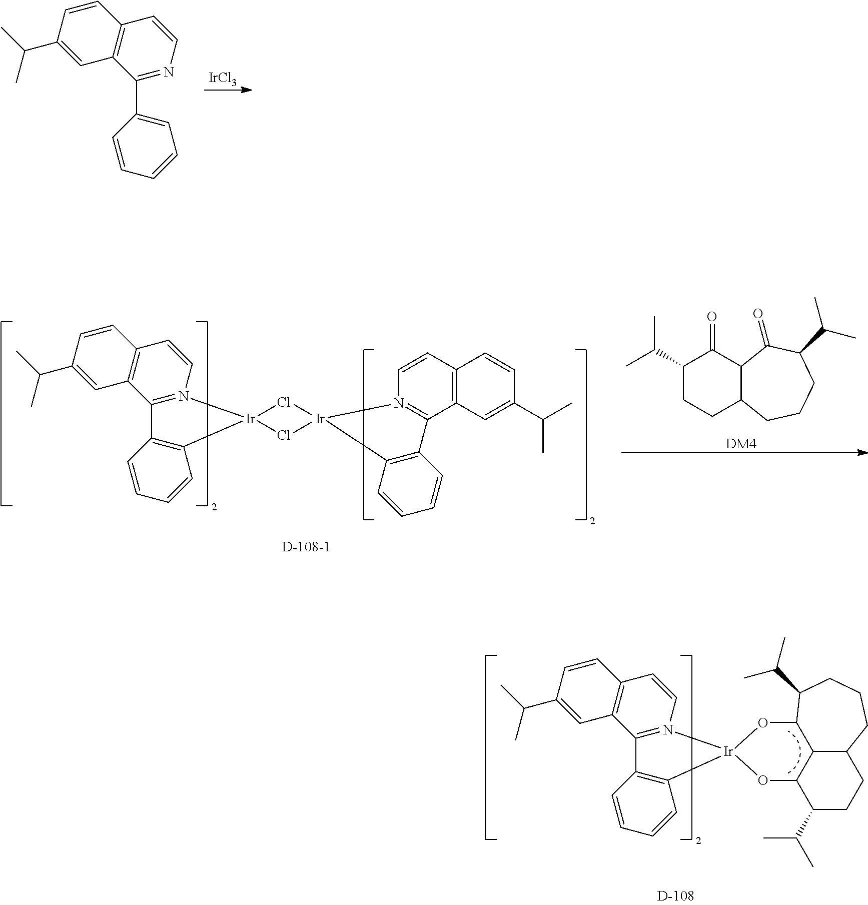

Synthesis of D-108-1: the synthesis method of D-108-1 was the same as that of A-10-1, except that 5-phenyl-2-methylquinoline was replaced with 7-isopropyl-1-phenylisoquinoline to gave D-108-1 (yield: 51%).

Synthesis of D-108: the synthesis method of D-108 was the same as that of A-10, except that A-10-1 and AM1 were replaced with the D-108-1 and DM4 to gave D-108 of deep red solid (yield: 48%).

Anal. calcd.: C: 67.92%, H: 6.62%, N: 2.83%; found: C: 67.95%, H: 6.66%, N: 2.87%.

The following compounds were prepared in a similar manner to the synthesis of compound D-11, except that the raw materials were replaced as appropriate.

Compound D-17: Anal. calcd.: C: 63.92%, H: 4.87%, N: 3.47%; found: C: 63.97%, H: 4.88%, N: 3.44%.

Compound D-20: Anal. calcd.: C: 66.57%, H: 6.02%, N: 3.04%; found: C: 66.55%, H: 6.04%, N: 3.04%.

Compound D-28: Anal. calcd.: C: 64.65%, H: 5.18%, N: 3.35%; found: C: 64.63%, H: 5.19%, N: 3.32%.

Compound D-37: Anal. calcd.: C: 66.27%, H: 5.33%, N: 3.15%; found: C: 66.29%, H: 5.35%, N: 3.16%.

Compound D-40: Anal. calcd.: C: 66.57%, H: 6.02%, N: 3.04%; found: C: 66.59%, H: 6.07%, N: 3.01%.

Compound D-43: Anal. calcd.: C: 65.97%, H: 5.76%, N: 3.14%; found: C: 65.94%, H: 5.76%, N: 3.18%.

Compound D-61: Anal. calcd.: C: 58.59%, H: 4.95%, N: 3.20%; found: C: 58.57%, H: 4.94%, N: 3.24%.

Compound D-66: Anal. calcd.: C: 60.35%, H: 4.82%, N: 3.43%; found: C: 60.37%, H: 4.82%, N: 3.43%.

Compound D-69: Anal. calcd.: C: 62.17%, H: 5.98%, N: 3.54%; found: C: 62.19%, H: 5.99%, N: 3.53%.

Compound D-73: Anal. calcd.: C: 67.66%, H: 6.50%, N: 2.87%; found: C: 67.65%, H: 6.56%, N: 2.88%.

Compound D-74: Anal. calcd.: C: 66.57%, H: 6.02%, N: 3.04%; found: C: 66.58%, H: 6.06%, N: 3.02%.

Compound D-75: Anal. calcd.: C: 67.13%, H: 6.27%, N: 2.95%; found: C: 67.17%, H: 6.25%, N: 2.93%.

Compound D-76: Anal. calcd.: C: 67.66%, H: 6.50%, N: 2.87%; found: C: 67.68%, H: 6.48%, N: 2.92%.

Compound D-83: Anal. calcd.: C: 67.13%, H: 6.27%, N: 2.95%; found: C: 67.12%, H: 6.24%, N: 2.96%.

Compound D-94: Anal. calcd.: C: 59.77%, H: 5.24%, N: 3.10%; found: C: 59.76%, H: 5.24%, N: 3.11%.

Compound D-128: Anal. calcd.: C: 67.27%, H: 6.07%, N: 2.96%; found: C: 67.29%, H: 6.05%, N: 2.97%.

Compound D-130: Anal. calcd.: C: 68.30%, H: 6.54%, N: 2.79%; found: C: 68.33%, H: 6.53%, N: 2.77%.

### Preparation E1: Preparation of the Compound of Formula EM1

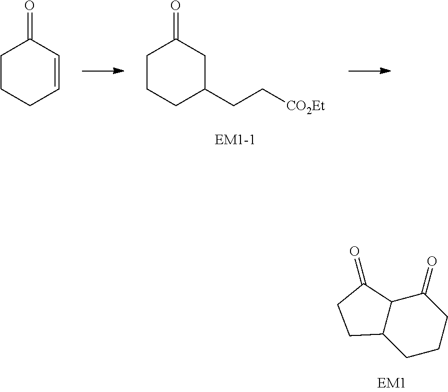 [SMILES: O=C1C=CCCC1 ; CCOC(=O)CCC1CCCC(=O)C1 ; O=C1CCCC2CCC(=O)C12]

Synthesis of EM1-1: the synthesis method of EM1-1 was the same as that of AM1-1, except that ethyl 4-iodobutyrate was replaced with ethyl 3-iodopropionate to gave M1-1 of white solid (yield: 78%).

Synthesis of EM1: the synthesis method of EM1 was the same as that of AM1, except that AM1-1 was replaced with EM1-1 to gave EM1 of white solid (yield: 70%).

MS for C₉H₁₂O₂: 152.08; found: 152.1.

Anal. calcd. for C₉H₁₂O₂: C: 71.03%, H: 7.95%; found: C: 71.05%, H: 7.92%.

### Preparation E2: Preparation of the Compound of Formula EM2

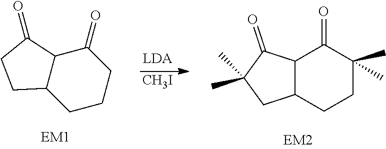

Synthesis of EM2: the synthesis method of EM2 was the same as that of BM2, except that BM1 was replaced with EM1 to gave EM2 of white solid (yield: 53%).

MS for C₁₃H₂₀O₂: 208.15; found: 208.2.

Anal. calcd. for C₁₃H₂₀O₂: C: 74.96%, H: 9.68%; found: C: 74.98%, H: 9.64%.

### Preparation E3: Preparation of the Compound of Formula EM3

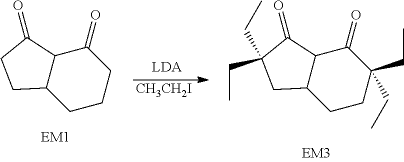

Synthesis of EM3: the synthesis method of EM3 was the same as that of BM2, except that BM1 and methyl iodide were replaced with EM1 and ethyl iodide to gave EM3 of white solid (yield: 57%).

MS for C₁₇H₂₈O₂: 264.21; found: 264.2.

Anal. calcd. for C₁₇H₂₈O₂: C: 77.22%, H: 10.67%; found: C: 77.25%, H: 10.68%.

### Preparation E4: Preparation of the Compound of Formula EM4

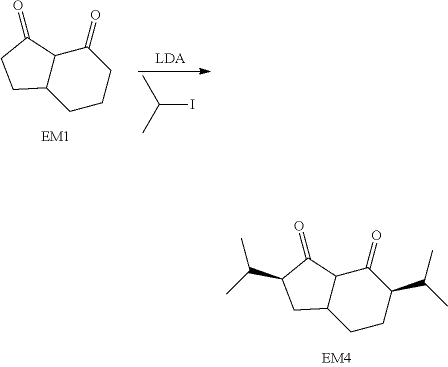

Synthesis of EM4: the synthesis method of EM4 was the same as that of BM4, except that BM1 and iodocyclopentane were replaced with EM1 and 2-iodopropane to gave EM4 of white solid (yield: 57%).

MS for C₁₅H₂₄O₂: 236.18; found: 236.2.

Anal. calcd. for C₁₅H₂₄O₂: C: 76.23%, H: 10.24%; found: C: 76.27%, H: 10.26%.

### Preparation E5: Preparation of Compound E-4

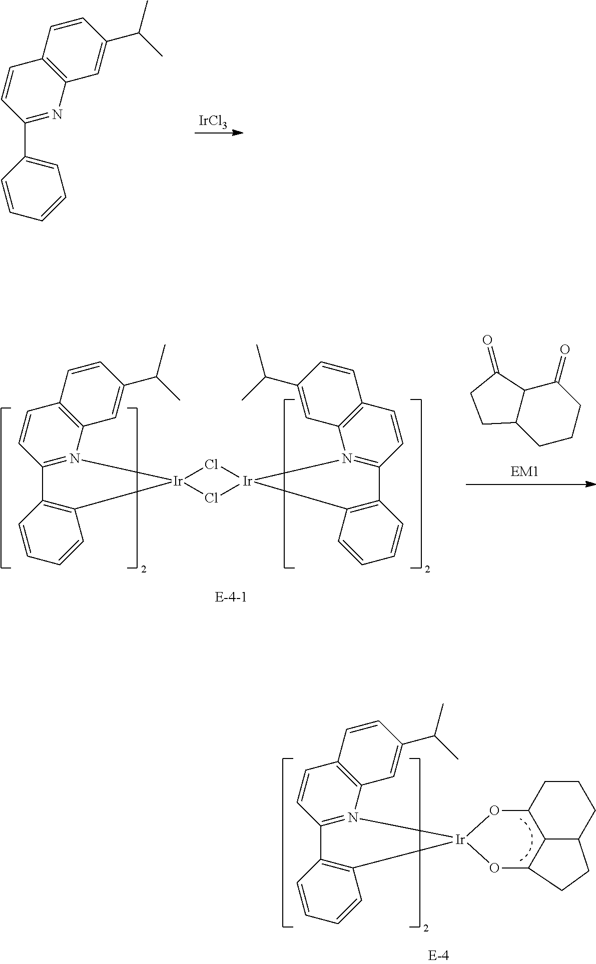

Synthesis of E-4-1: the synthesis method of E-4-1 was the same as that of A-10-1, except that 5-phenyl-2-methylquinoline was replaced with 7-isopropyl-2-phenylquinoline to gave E-4-1 (yield: 56%).

Synthesis of E-4: the synthesis method of E-4 was the same as that of A-10, except that A-10-1 and AM1 were replaced with E-4-1 and EM1 to gave E-4 (yield: 46%).

Anal. calcd.: C: 64.65%, H: 5.18%, N: 3.35%; found: C: 64.64%, H: 5.16%, N: 3.35%.

### Preparation E6: Preparation of Compound E-63

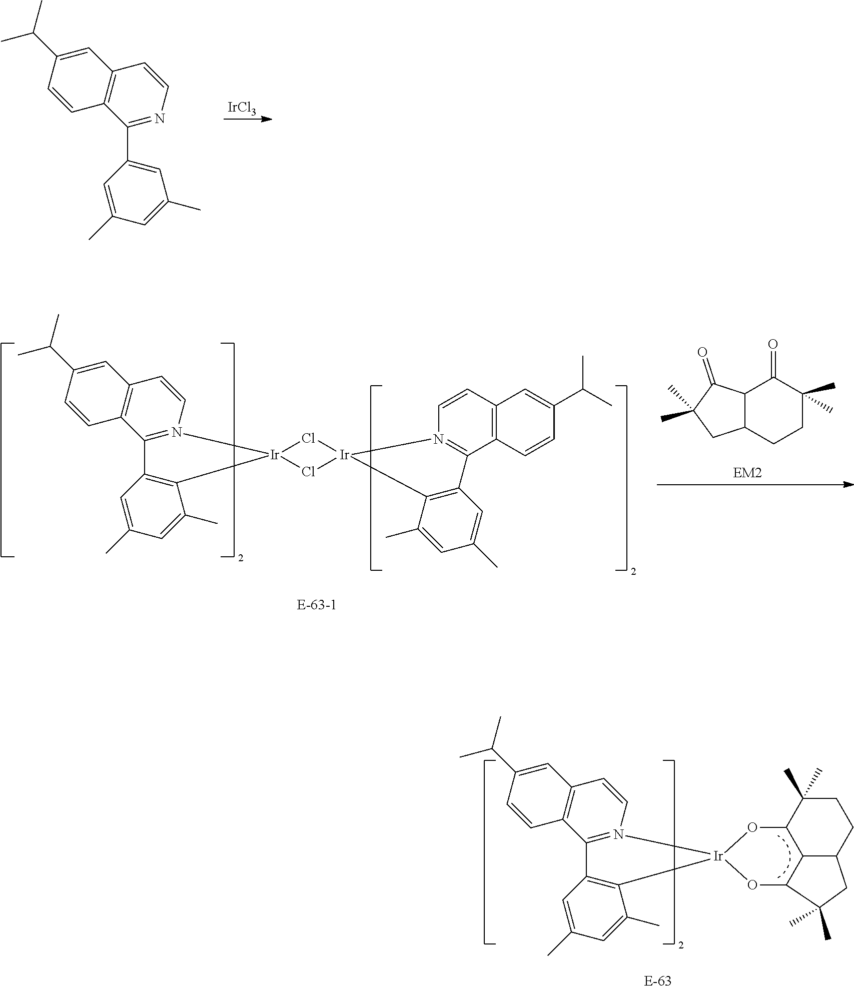

Synthesis of E-63-1: the synthesis method of E-63-1 was the same as that of A-10-1, except that 5-phenyl-2-methylquinoline was replaced with 1-(3,5-dimethylphenyl)-6-isopropylisoquinoline to gave E-63-1 (yield: 58%).

Synthesis of E-63: the synthesis method of E-63 was the same as that of A-10, except that A-10-1 and AM1 were replaced with E-63-1 and EM2 to gave E-63 (yield: 49%).

Anal. calcd.: C: 67.13%, H: 6.27%, N: 2.95%; found: C: 67.11%, H: 6.29%, N: 2.92%.

### Preparation E7: Preparation of Compound E-78

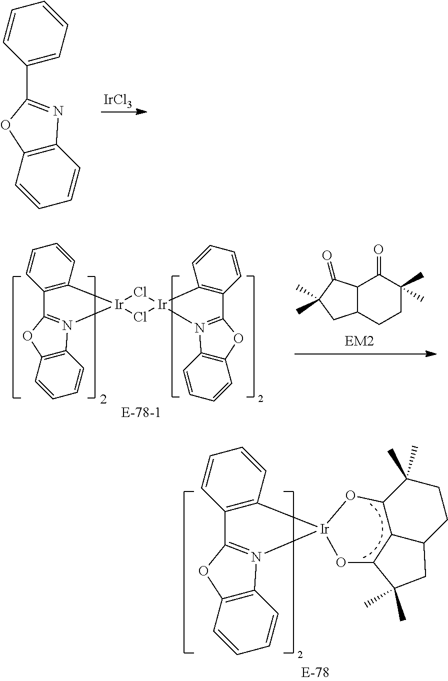

Synthesis of E-78-1: the synthesis method of E-78-1 was the same as that of A-10-1, except that 5-phenyl-2-methylquinoline was replaced with 2-phenylbenzoxazole to gave E-78-1 (yield: 52%).

Synthesis of E-78: the synthesis method of E-78 was the same as that of A-10, except that A-10-1 and AM1 were replaced with E-78-1 and EM2 to gave E-78 (yield: 50%).

Anal. calcd.: C: 59.45%, H: 4.48%, N: 3.56%; found: C: 59.48%, H: 4.43%, N: 3.55%.

### Preparation E8: Preparation of Compound E-91

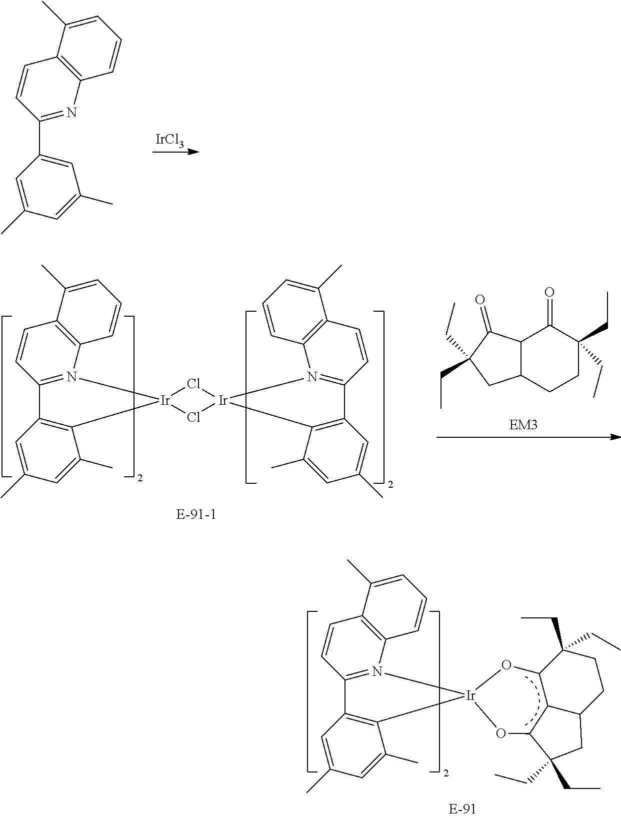

Synthesis of E-91-1: the synthesis method of E-91-1 was the same as that of A-10-1, except that 5-phenyl-2-methylquinoline was replaced with 2-(3,5-dimethylphenyl)-5-methylquinoline to gave E-91-1 (yield: 53%).

Synthesis of E-91: the synthesis method of E-91 was the same as that of A-10, except that A-10-1 and AM1 were replaced with E-91-1 and EM3 to gave E-91 of yellow-green solid (yield: 47%).

Anal. calcd.: C: 67.13%, H: 6.27%, N: 2.95%; found: C: 67.16%, H: 6.26%, N: 2.94%.

### Preparation E9: Preparation of Compound E-109

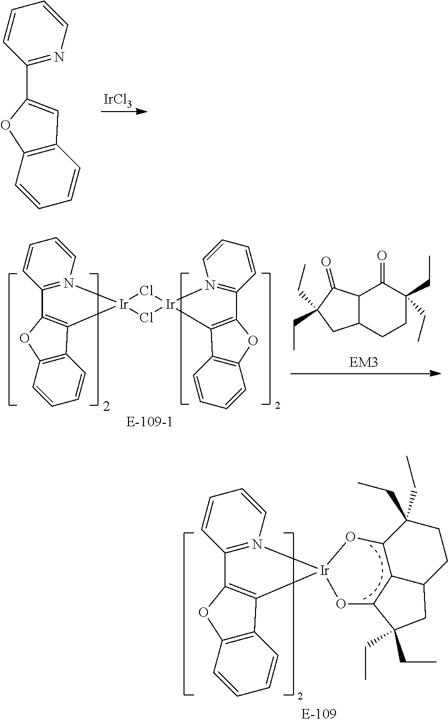

Synthesis of E-109-1: the synthesis method of E-109-1 was the same as that of A-10-1, except that 5-phenyl-2-methylquinoline was replaced with 2-(benzofuran-2-yl) pyridine to gave E-109-1 (yield: 52%).

Synthesis of E-109: the synthesis method of E-109 was the same as that of A-10, except that A-10-1 and AM1 were replaced with E-109-1 and EM3 to gave E-109 (yield: 44%).

Anal. calcd.: C: 61.19%, H: 5.14%, N: 3.32%; found: C: 61.21%, H: 5.16%, N: 3.36%.

### Preparation E10: Preparation of Compound E-126

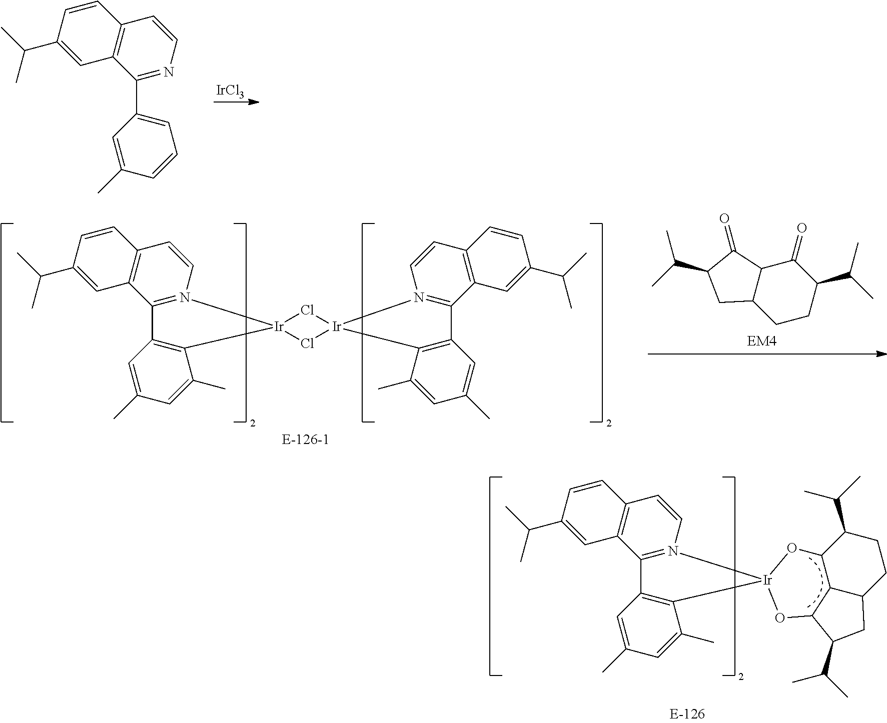

Synthesis of E-126-1: the synthesis method of E-126-1 was the same as that of A-10-1, except that 5-phenyl-2-methylquinoline was replaced with 1-(3,5-dimethylphenyl)-7-isopropylisoquinoline to gave E-126-1 (yield: 58%).

Synthesis of E-126: the synthesis method of E-126 was the same as that of A-10, except that A-10-1 and AM1 were replaced with E-126-1 and EM4 to gave E-126 of orange-red solid (yield: 47%).

Anal. calcd.: C: 67.66%, H: 6.50%, N: 2.87%; found: C: 67.68%, H: 6.53%, N: 2.84%.

The following compounds were prepared in a similar manner to the synthesis of compound E-4, except that the starting materials were replaced as appropriate.

Compound E-1: Anal. calcd.: C: 57.13%, H: 4.18%, N: 4.30%; found: C: 57.14%, H: 4.20%, N: 4.31%.

Compound E-11: Anal. calcd.: C: 64.65%, H: 5.18%, N: 3.35%; found: C: 64.66%, H: 5.15%, N: 3.37%.

Compound E-18: Anal. calcd.: C: 65.97%, H: 5.76%, N: 3.14%; found: C: 65.94%, H: 5.78%, N: 3.15%.

Compound E-27: Anal. calcd.: C: 63.92%, H: 4.87%, N: 3.47%; found: C: 63.90%, H: 4.86%, N: 3.48%.

Compound E-37: Anal. calcd.: C: 66.26%, H: 4.14%, N: 3.29%; found: C: 66.25%, H: 4.14%, N: 3.33%.

Compound E-52: Anal. calcd.: C: 65.97%, H: 5.76%, N: 3.14%; found: C: 65.95%, H: 5.77%, N: 3.18%.

Compound E-54: Anal. calcd.: C: 65.97%, H: 5.76%, N: 3.14%; found: C: 65.98%, H: 5.78%, N: 3.16%.

Compound E-71: Anal. calcd.: C: 65.33%, H: 5.48%, N: 3.24%; found: C: 65.31%, H: 5.47%, N: 3.27%.

Compound E-81: Anal. calcd.: C: 66.86%, H: 5.61%, N: 3.06%; found: C: 66.88%, H: 5.60%, N: 3.08%.

Compound E-88: Anal. calcd.: C: 67.13%, H: 6.27%, N: 2.95%; found: C: 67.16%, H: 6.28%, N: 2.93%.

Compound E-96: Anal. calcd.: C: 68.44%, H: 6.35%, N: 2.80%; found: C: 68.45%, H: 6.36%, N: 2.83%.

Compound E-98: Anal. calcd.: C: 67.13%, H: 6.27%, N: 2.95%; found: C: 67.16%, H: 6.25%, N: 2.94%.

Compound E-100: Anal. calcd.: C: 68.16%, H: 6.72%, N: 2.79%; found: C: 68.14%, H: 6.71%, N: 2.76%.

Compound E-106: Anal. calcd.: C: 66.57%, H: 6.02%, N: 3.04%; found: C: 66.56%, H: 6.05%, N: 3.02%.

Compound E-127: Anal. calcd.: C: 58.06%, H: 4.63%, N: 3.30%; found: C: 58.08%, H: 4.65%, N: 3.32%.

Compound E-132: Anal. calcd.: C: 67.23%, H: 5.25%, N: 5.50%; found: C: 67.25%, H: 5.27%, N: 5.48%.

### Preparation F1: Preparation of Compound of Formula FM1

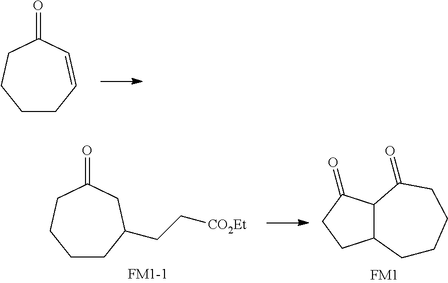

Synthesis of FM1-1: the synthesis method of FM1-1 was the same as that of AM1-1, except that ethyl 4-iodobutyrate and 2-cyclohexen-1-one were replaced with ethyl 3-iodopropionate and 2-cyclohepten-1-one to gave FM1-1 of white solid (yield: 72%).

Synthesis of FM1: the synthesis method of FM1 was the same as that of AM1, except that AM1-1 was replaced with FM1-1 to gave FM1 of white solid (yield: 73%).

MS for C₁₀H₁₄O₂: 166.1; found: 166.1.

Anal. calcd. for C₁₀H₁₄O₂: C: 72.26%, H: 8.49%; found: C: 72.28%, H: 8.52%.

### Preparation F2: Preparation of Compound of Formula FM2

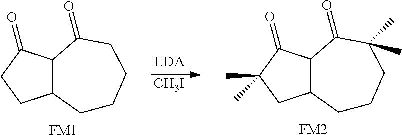

Synthesis of FM2: the synthesis method of FM2 was the same as that of BM2, except that BM1 was replaced with FM1 to gave FM2 as a white solid (yield: 59%).

MS for C₁₄H₂₂O₂: 222.16; found: 222.2.

Anal. calcd. for C₁₄H₂₂O₂: C: 75.63%, H: 9.97%; found: C: 75.65%, H: 9.99%.

### Preparation F3: Preparation of Compound of Formula FM3

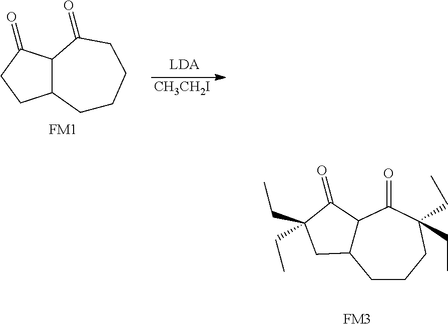

Synthesis of FM3: the synthesis method of FM3 was the same as that of BM2, except that BM1 and methyl iodide were replaced with FM1 and ethyl iodide to gave FM3 of white solid (yield: 54%).

MS for C₁₈H₃₀O₂: 278.22; found: 278.2.

Anal. calcd. for C₁₈H₃₀O₂: C: 77.65%, H: 10.86%; found: C: 77.68%, H: 10.83%.

### Preparation F4: Preparation of Compound of Formula FM4

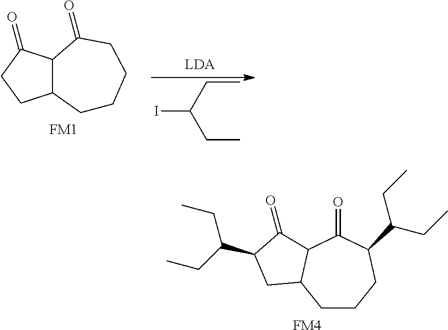

Synthesis of FM4: the synthesis method of FM4 was the same as that of BM4, except that BM1 and iodocyclopentane were replaced with FM1 and 3-iodopentane to gave FM4 of white solid (yield: 60%).

MS for C₂₀H₃₄O₂: 306.26; found: 306.3.

Anal. calcd. for C₂₀H₃₄O₂: C: 78.38%, H: 11.18%; found: C: 78.36%, H: 11.21%.

### Preparation F5: Preparation of Compound F-12

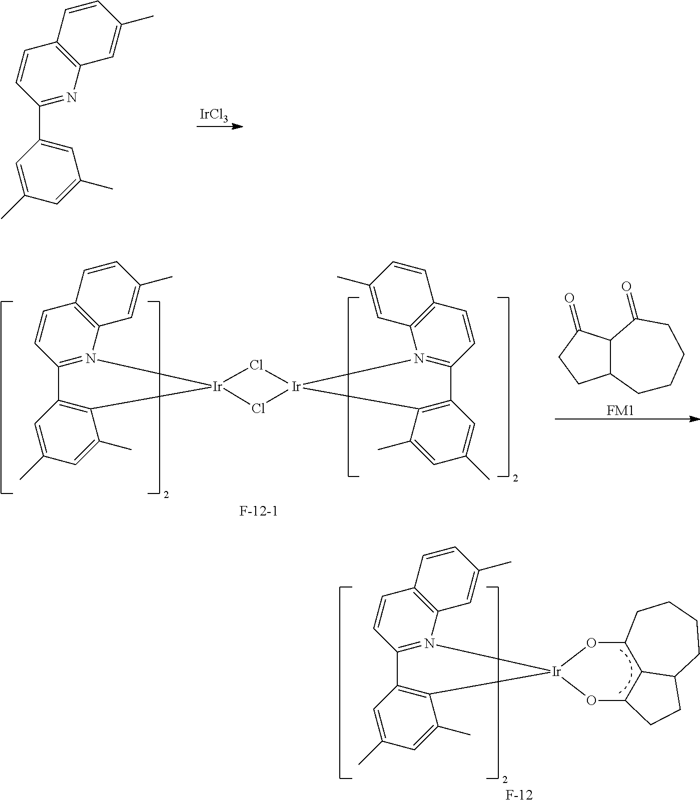

Synthesis of F-12-1: the synthesis method of F-12-1 was the same as that of A-10-1, except that 5-phenyl-2-methylquinoline was replaced with 2-(3,5-dimethylphenyl)-7-methylquinoline to gave F-12-1 (yield: 56%).

Synthesis of F-12: the synthesis method of F-12 was the same as that of A-10, except that A-10-1 and AM1 were replaced with F-12-1 and FM1 to gave F-12 of orange-red solid (yield: 50%).

Anal. calcd.: C: 64.99%, H: 5.34%, N: 3.30%; found: C: 64.97%, H: 5.36%, N: 3.28%.

### Preparation F6: Preparation of Compound F-70

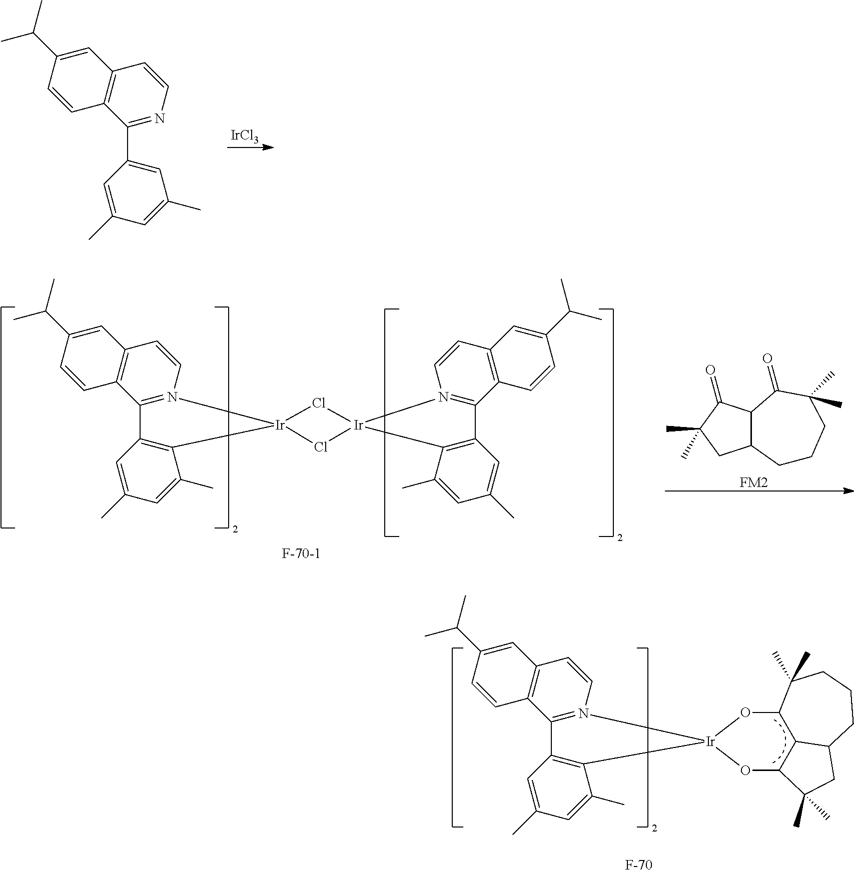

Synthesis of F-70-1: the synthesis method of F-70-1 was the same as that of A-10-1, except that 5-phenyl-2-methylquinoline was replaced with 1-(3,5-dimethylphenyl)-6-isopropylquinoline to gave F-70-1 (yield: 58%).

Synthesis of F-70: the synthesis method of F-70 was the same as that of A-10, except that A-10-1 and AM1 were replaced with F-70-1 and FM2 to gave F-70 of orange-red solid (yield: 46%).

Anal. calcd.: C: 67.40%, H: 6.39%, N: 2.91%; found: C: 67.43%, H: 6.36%, N: 2.90%.

### Preparation F7: Preparation of Compound F-106

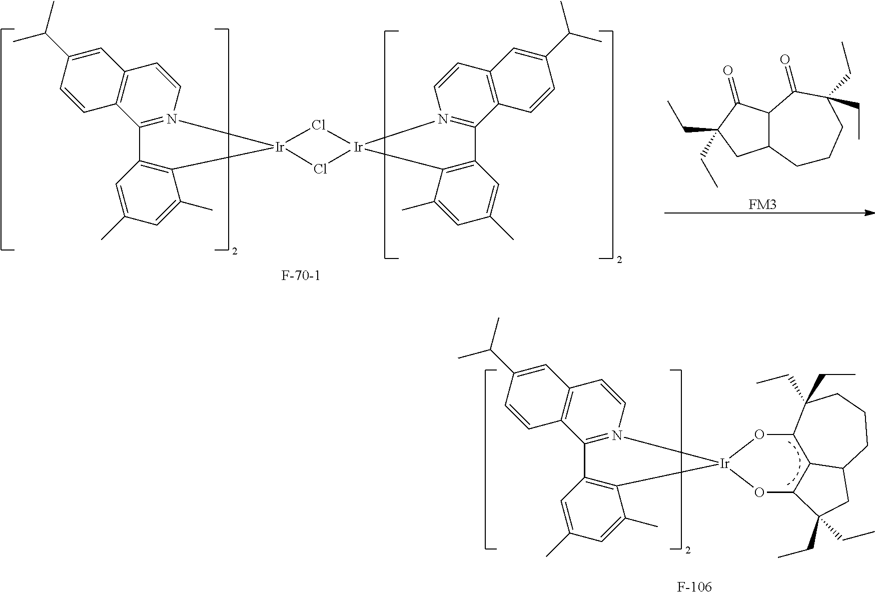

Synthesis of F-106: the synthesis method of F-106 was the same as that of A-10, except that A-10-1 and AM1 were replaced with F-70-1 and FM3 to gave F-106 of deep red solid (yield: 44%).

Anal. calcd.: C: 68.40%, H: 6.83%, N: 2.75%; found: C: 68.43%, H: 6.85%, N: 2.71%.

### Preparation F8: Preparation of Compound F-116

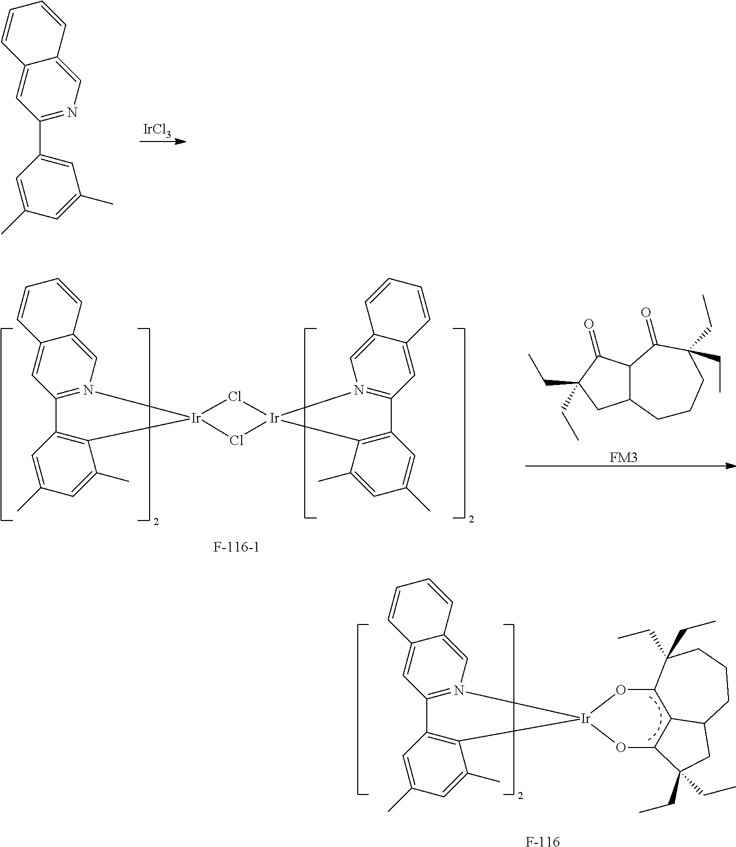

Synthesis of F-116-1: the synthesis method of F-116-1 was the same as that of A-10-1, except that 5-phenyl-2-methylquinoline was replaced with 3-(3,5-dimethylphenyl)isoquinoline to gave F-116-1 (yield: 55%).

Synthesis of F-116: the synthesis method of F-116 was the same as that of A-10, except that A-10-1 and AM1 were replaced with F-116-1 and FM3 to gave F-116 of orange-red solid (yield: 45%).

Anal. calcd.: C: 66.85%, H: 6.15%, N: 3.00%; found: C: 66.82%, H: 6.13%, N: 3.05%.

### Preparation F9: Preparation of Compound F-122

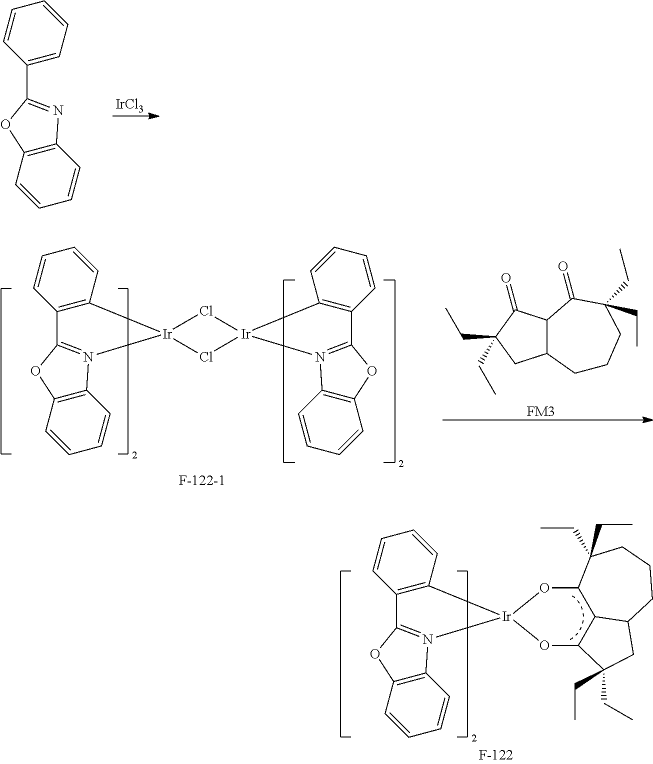

Synthesis of F-122-1: the synthesis method of F-122-1 was the same as that of A-10-1, except that 5-phenyl-2-methylquinoline was replaced with 2-phenylbenzoxazole to gave F-122-1 (yield: 52%).

Synthesis of F-122: the synthesis method of F-122 was the same as that of A-10, except that A-10-1 and AM1 were replaced with F-122-1 and FM3 to gave F-122 of orange-red solid (yield: 46%).

Anal. calcd.: C: 61.59%, H: 5.29%, N: 3.26%; found: C: 61.57%, H: 5.26%, N: 3.28%.

### Preparation F10: Preparation of Compound F-142

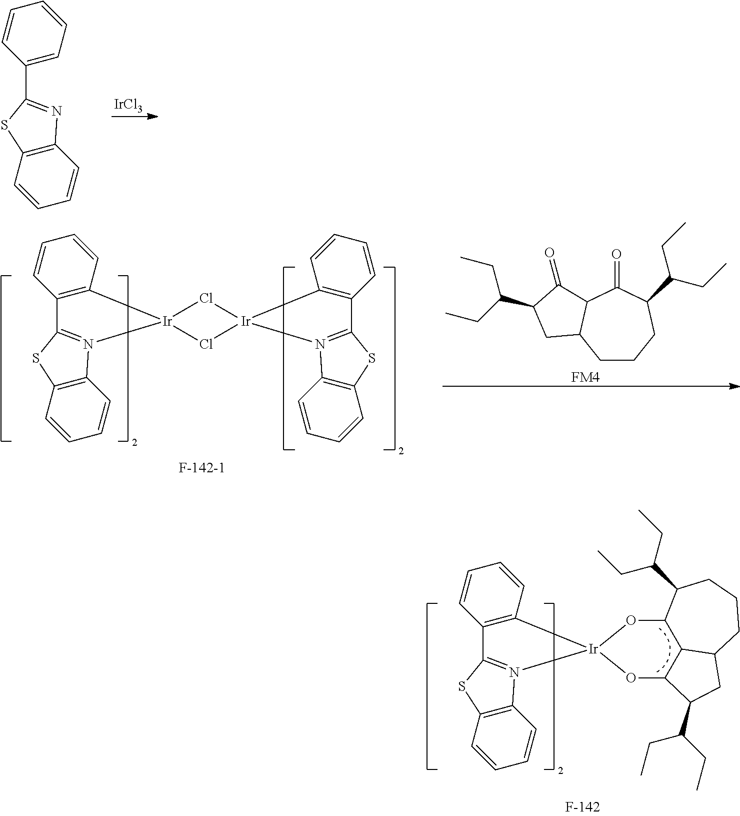

Synthesis of F-142-1: the synthesis method of F-142-1 was the same as that of A-10-1, except that 5-phenyl-2-methylquinoline was replaced with 2-phenylbenzo[d]thiazole to gave F-142-1 (yield: 57%).

Synthesis of F-142: the synthesis method of F-142 was the same as that of A-10, except that A-10-1 and AM1 were replaced with F-142-1 and FM4 to gave F-142 of yellow solid (yield: 46%).

Anal. calcd.: C: 60.17%, H: 5.38%, N: 3.05%; found: C: 60.19%, H: 5.38%, N: 3.02%.

The following compounds were prepared in a similar manner to the synthesis of compound F-12, except that the raw materials were replaced as appropriate.

Compound F-2: Anal. calcd.: C: 64.61%, H: 4.56%, N: 3.42%; found: C: 64.63%, H: 4.565%, N: 3.42%.

Compound F-3: Anal. calcd.: C: 62.73%, H: 4.34%, N: 3.66%; found: C: 62.75%, H: 4.34%, N: 3.68%.

Compound F-20: Anal. calcd.: C: 66.27%, H: 5.90%, N: 3.09%; found: C: 66.29%, H: 5.93%, N: 3.04%.

Compound F-25: Anal. calcd.: C: 64.99%, H: 5.34%, N: 3.30%; found: C: 64.96%, H: 5.37%, N: 3.31%.

Compound F-59: Anal. calcd.: C: 66.27%, H: 5.90%, N: 3.09%; found: C: 66.25%, H: 5.92%, N: 3.11%.

Compound F-60: Anal. calcd.: C: 66.85%, H: 6.15%, N: 3.00%; found: C: 66.83%, H: 6.19%, N: 3.02%.

Compound F-80: Anal. calcd.: C: 65.65%, H: 5.62%, N: 3.19%; found: C: 65.63%, H: 5.66%, N: 3.17%.

Compound F-85: Anal. calcd.: C: 61.75%, H: 5.83%, N: 3.60%; found: C: 61.74%, H: 5.84%, N: 3.62%.

Compound F-92: Anal. calcd.: C: 67.40%, H: 6.39%, N: 2.91%; found: C: 67.43%, H: 6.35%, N: 2.88%.

Compound F-94: Anal. calcd.: C: 67.40%, H: 6.39%, N: 2.91%; found: C: 67.38%, H: 6.37%, N: 2.95%.

Compound F-95: Anal. calcd.: C: 67.40%, H: 6.39%, N: 2.91%; found: C: 67.42%, H: 6.38%, N: 2.94%.

Compound F-105: Anal. calcd.: C: 66.85%, H: 6.15%, N: 3.00%; found: C: 66.87%, H: 6.17%, N: 3.02%.

Compound F-113: Anal. calcd.: C: 67.40%, H: 6.39%, N: 2.91%; found: C: 67.37%, H: 6.38%, N: 2.94%.

Compound F-133: Anal. calcd.: C: 58.85%, H: 4.79%, N: 4.04%; found: C: 58.83%, H: 4.78%, N: 4.05%.

Compound F-153: Anal. calcd.: C: 64.99%, H: 5.34%, N: 3.30%; found: C: 64.96%, H: 5.36%, N: 3.33%.

Compound F-168: Anal. calcd.: C: 67.40%, H: 6.39%, N: 2.91%; found: C: 67.38%, H: 6.36%, N: 2.95%.

### Device Preparation Example 1: Preparation of Organic Electroluminescent Devices

A glass substrate having indium tin oxide (ITO) electrodes (anode) was ultrasonically treated with deionized water and a mixed solvent of acetone and ethanol (acetone: ethanol (v: v)=1:1), the treated glass substrate was dried in a clean environment, washed with ultraviolet light and ozone, and bombarded with a low-energy cation beam on the surface of the glass substrate;
placing the glass substrate with the anode in a vacuum chamber, vacuumizing to 1×10⁻⁴ Pa, and evaporating a compound HAT-CN on the anode layer film to form a hole injection layer, wherein the evaporation rate was 0.1 nm/s, and the thickness was 5 nm;
evaporating a compound NPB on the hole injection layer film to form a hole transport layer, wherein the evaporation rate was 0.1 nm/s, and the thickness was 60 nm;
a host material compound RH and a guest material compound (listed in Table 1) were evaporated on the hole transport layer film by adopting a multi-source co-evaporation method to form a light-emitting layer, the evaporation rate of the host material was adjusted to be 0.1 nm/s, the evaporation rate of the guest material was 10% of the evaporation rate of the host material, and the thickness of the guest material was 30 nm;
evaporating a compound ET-1 and a compound ET-2 on the light-emitting layer film by adopting a multi-source co-evaporation method to form an electron transport layer, wherein the evaporation rate was 0.1 nm/s, and the thickness was 30 nm;
evaporating LiF on the electron transport layer film to form an electron injection layer with the thickness of 1 nm;
and evaporating A1 on the electron injection layer film to form a cathode with the thickness of 150 nm.

### Device Preparation Example 2

A glass substrate having indium tin oxide (ITO) electrodes (anode) was ultrasonically treated with deionized water and a mixed solvent of acetone and ethanol (acetone: ethanol (v: v)=1:1), the treated glass substrate was dried in a clean environment, washed with ultraviolet light and ozone, and bombarded with a low-energy cation beam on the surface of the glass substrate;
placing the glass substrate with the anode in a vacuum chamber, vacuumizing to 1×10⁻⁴ Pa, and evaporating a compound HAT-CN on the anode layer film to form a hole injection layer, wherein the evaporation rate was 0.1 nm/s, and the thickness was 5 nm;
evaporating a compound NPB on the hole injection layer film to form a hole transport layer, wherein the evaporation rate was 0.1 nm/s, and the thickness was 60 nm;
a host material compound GH and a guest material compound (listed in Table 2) were evaporated on the hole transport layer film by adopting a multi-source co-evaporation method to form a light-emitting layer, the evaporation rate of the host material was adjusted to be 0.1 nm/s, the evaporation rate of the guest material was 10% of the evaporation rate of the host material, and the thickness of the guest material was 30 nm;
evaporating a compound ET-1 and a compound ET-2 on the light-emitting layer film by adopting a multi-source co-evaporation method to form an electron transport layer, wherein the evaporation rate was 0.1 nm/s, and the thickness was 30 nm;
evaporating LiF on the electron transport layer film to form an electron injection layer with the thickness of 1 nm;
and evaporating Al on the electron injection layer film to form a cathode with the thickness of 150 nm.

Ref-1, Ref-2 and Ref-3 in table 1 and ARef-4, BRef-4, in table 2 have the following structures:

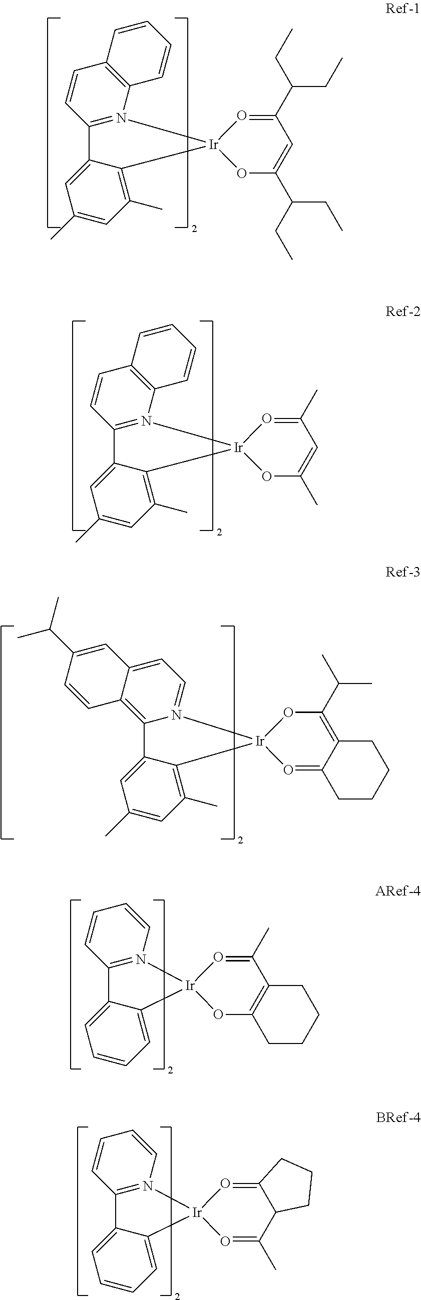

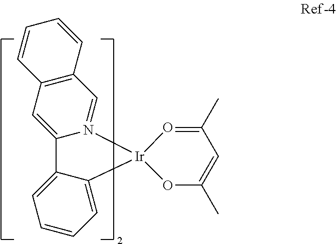

### Test Example 1

The driving voltage and current efficiency of the organic electroluminescent devices prepared as described above were measured at a luminance of 2000 cd/m², and the results were shown in table 1.

### Test Example 2

The driving voltage and current efficiency of the organic electroluminescent devices prepared as described above were measured at a luminance of 10000 cd/m², and the results were shown in table 2.

TABLE 1

| | Source of guest | Driving | Current efficiency | | |
|---|---|---|---|---|---|
| Number of | material | voltage (V) | (cd/A) | CIE | Colour(s) |
| 1 | Compound A-10 | 4.26 | 17.0 | (0.62, 0.37) | Orange |
| 2 | Compound A-15 | 4.33 | 16.7 | (0.60, 0.38) | Orange |
| 3 | Compound A-17 | 4.36 | 17.2 | (0.62, 0.38) | Orange |
| 4 | Compound A-73 | 4.23 | 17.6 | (0.61, 0.38) | Orange |
| 5 | Compound A-76 | 4.24 | 17.8 | (0.61, 0.39) | Orange |
| 6 | Compound A-80 | 4.33 | 17.5 | (0.60, 0.38) | Orange |
| 7 | Compound A-82 | 4.38 | 17.9 | (0.60, 0.39) | Orange |
| 8 | Compound A-127 | 4.37 | 18.2 | (0.59, 0.40) | Orange |
| 9 | Compound A-132 | 4.42 | 18.3 | (0.60, 0.39) | Orange |
| 10 | Compound A-177 | 4.32 | 17.5 | (0.61, 0.38) | Orange |
| 11 | Compound A-32 | 4.42 | 9.8 | (0.68, 0.32) | Red |
| 12 | Compound A-89 | 4.39 | 10.3 | (0.68, 0.32) | Red |
| 13 | Compound A-139 | 4.35 | 10.6 | (0.67, 0.33) | Red |
| 14 | Compound A-141 | 4.47 | 10.9 | (0.67, 0.32) | Red |
| 15 | Compound A-182 | 4.44 | 10.2 | (0.68, 0.33) | Red |
| 16 | Compound A-210 | 4.36 | 9.9 | (0.68, 0.33) | Red |
| 17 | Compound Ref-1 | 4.60 | 13.6 | (0.60, 0.38) | Orange |
| 18 | Compound Ref-2 | 4.67 | 12.0 | (0.60, 0.37) | Orange |
| 19 | Compound Ref-3 | 4.71 | 7.5 | (0.68, 0.32) | Red |
| 20 | Compound B-12 | 4.25 | 16.3 | (0.62, 0.40) | Orange |
| 21 | Compound B-35 | 4.27 | 16.4 | (0.60, 0.40) | Orange |
| 22 | Compound B-49 | 4.35 | 17.2 | (0.61, 0.39) | Orange |
| 23 | Compound B-55 | 4.49 | 17.4 | (0.61, 0.38) | Orange |
| 24 | Compound B-91 | 4.48 | 17.8 | (0.60, 0.38) | Orange |
| 25 | Compound B-95 | 4.52 | 17.9 | (0.59, 0.38) | Orange |
| 26 | Compound B-158 | 4.49 | 16.9 | (0.62, 0.39) | Orange |
| 27 | Compound B-161 | 4.33 | 16.7 | (0.61, 0.40) | Orange |
| 28 | Compound B-16 | 4.29 | 9.9 | (0.67, 0.32) | Red |
| 29 | Compound B-63 | 4.33 | 10.2 | (0.67, 0.31) | Red |
| 30 | Compound B-68 | 4.36 | 10.3 | (0.68, 0.31) | Red |
| 31 | Compound B-102 | 4.45 | 10.6 | (0.67, 0.33) | Red |
| 32 | Compound B-106 | 4.46 | 10.8 | (0.67, 0.32) | Red |
| 33 | Compound B-151 | 4.41 | 10.1 | (0.68, 0.32) | Red |
| 34 | Compound C-8 | 4.28 | 16.8 | (0.60, 0.37) | Orange |
| 35 | Compound C-11 | 4.23 | 16.7 | (0.61, 0.38) | Orange |
| 36 | Compound C-12 | 4.29 | 17.2 | (0.62, 0.37) | Orange |
| 37 | Compound C-42 | 4.33 | 17.7 | (0.60, 0.37) | Orange |
| 38 | Compound C-72 | 4.34 | 18.2 | (0.60, 0.38) | Orange |
| 39 | Compound C-77 | 4.38 | 18.5 | (0.62, 0.36) | Orange |
| 40 | Compound C-102 | 4.42 | 17.8 | (0.61, 0.37) | Orange |
| 41 | Compound C-139 | 4.39 | 17.3 | (0.60, 0.36) | Orange |
| 42 | Compound C-20 | 4.32 | 10.3 | (0.68, 0.32) | Red |
| 43 | Compound C-51 | 4.37 | 10.5 | (0.67, 0.30) | Red |
| 44 | Compound C-52 | 4.39 | 10.8 | (0.67, 0.33) | Red |
| 45 | Compound C-92 | 4.43 | 11.1 | (0.68, 0.31) | Red |
| 46 | Compound D-11 | 4.26 | 16.5 | (0.60, 0.38) | Orange |
| 47 | Compound D-40 | 4.33 | 17.1 | (0.61, 0.38) | Orange |
| 48 | Compound D-61 | 4.29 | 17.4 | (0.62, 0.37) | Orange |
| 49 | Compound D-75 | 4.37 | 17.8 | (0.61, 0.37) | Orange |
| 50 | Compound D-76 | 4.32 | 18.0 | (0.62, 0.39) | Orange |
| 51 | Compound D-128 | 4.38 | 16.8 | (0.62, 0.38) | Orange |
| 52 | Compound D-20 | 4.27 | 9.7 | (0.68, 0.31) | Red |
| 53 | Compound D-52 | 4.42 | 10.4 | (0.67, 0.30) | Red |
| 54 | Compound D-84 | 4.36 | 10.7 | (0.67, 0.30) | Red |
| 55 | Compound D-108 | 4.37 | 10.2 | (0.68, 0.32) | Red |
| 56 | Compound D-130 | 4.33 | 9.9 | (0.68, 0.33) | Red |
| 57 | Compound E-4 | 4.25 | 16.7 | (0.61, 0.39) | Orange |
| 58 | Compound E-11 | 4.33 | 16.8 | (0.61, 0.40) | Orange |
| 59 | Compound E-54 | 4.36 | 17.1 | (0.60, 0.39) | Orange |
| 60 | Compound E-88 | 4.29 | 17.5 | (0.60, 0.37) | Orange |
| 61 | Compound E-91 | 4.41 | 17.8 | (0.62, 0.38) | Orange |
| 62 | Compound E-18 | 4.28 | 9.9 | (0.67, 0.32) | Red |
| 63 | Compound E-63 | 4.34 | 10.1 | (0.68, 0.32) | Red |
| 64 | Compound E-96 | 4.33 | 10.5 | (0.67, 0.33) | Red |
| 65 | Compound E-98 | 4.37 | 10.4 | (0.66, 0.30) | Red |
| 66 | Compound E-100 | 4.42 | 10.7 | (0.66, 0.32) | Red |
| 67 | Compound E-126 | 4.39 | 9.9 | (0.67, 0.31) | Red |
| 68 | Compound F-3 | 4.26 | 16.8 | (0.61, 0.38) | Orange |
| 69 | Compound F-12 | 4.34 | 17.0 | (0.62, 0.38) | Orange |
| 70 | Compound F-59 | 4.40 | 17.7 | (0.60, 0.39) | Orange |
| 71 | Compound F-92 | 4.37 | 17.8 | (0.62, 0.37) | Orange |
| 72 | Compound F-94 | 4.42 | 18.1 | (0.61, 0.36) | Orange |
| 73 | Compound F-20 | 4.29 | 9.7 | (0.66, 0.32) | Red |
| 74 | Compound F-70 | 4.33 | 10.5 | (0.68, 0.33) | Red |
| 75 | Compound F-106 | 4.43 | 10.8 | (0.67, 0.31) | Red |
| 76 | Compound F-168 | 4.36 | 10.1 | (0.69, 0.30) | Red |

TABLE 2

| | Source of guest | Driving | Current | | |
|---|---|---|---|---|---|
| Number of | material | voltage (V) | efficiency (cd/A) | CIE | Colour(s) |
| 1 | Compound A-1 | 4.23 | 63.1 | (0.31, 0.64) | Green |
| 2 | Compound A-52 | 4.35 | 63.5 | (0.32, 0.65) | Green |
| 3 | Compound A-69 | 4.27 | 65.4 | (0.31, 0.65) | Green |
| 4 | Compound A-114 | 4.40 | 62.4 | (0.35, 0.60) | Green |
| 5 | Compound A-122 | 4.42 | 66.7 | (0.31, 0.64) | Green |
| 6 | Compound A-173 | 4.45 | 64.0 | (0.31, 0.64) | Green |
| 7 | Compound A-185 | 4.46 | 64.2 | (0.32, 0.65) | Green |
| 8 | Compound A-33 | 4.14 | 23.7 | (0.49, 0.51) | Yellow |
| 9 | Compound A-46 | 4.32 | 23.9 | (0.49, 0.53) | Yellow |
| 10 | Compound A-160 | 4.44 | 24.5 | (0.47, 0.54) | Yellow |
| 11 | Compound A-165 | 4.43 | 23.4 | (0.47, 0.52) | Yellow |
| 12 | Compound A-187 | 4.45 | 24.2 | (0.48, 0.51) | Yellow |
| 13 | Compound ARef-4 | 4.64 | 52.3 | (0.32, 0.62) | Green |
| 14 | Compound B-1 | 4.23 | 64.2 | (0.31, 0.64) | Green |
| 15 | Compound B-46 | 4.35 | 64.7 | (0.31, 0.63) | Green |
| 16 | Compound B-84 | 4.27 | 66.2 | (0.34, 0.60) | Green |
| 17 | Compound B-85 | 4.40 | 65.4 | (0.32, 0.63) | Green |
| 18 | Compound B-122 | 4.42 | 65.8 | (0.32, 0.62) | Green |
| 19 | Compound B-145 | 4.45 | 64.5 | (0.31, 0.64) | Green |
| 20 | Compound B-31 | 4.46 | 24.1 | (0.48, 0.50) | Yellow |
| 21 | Compound B-72 | 4.14 | 24.3 | (0.51, 0.49) | Yellow |
| 22 | Compound B-114 | 4.32 | 24.8 | (0.49, 0.51) | Yellow |
| 23 | Compound BRef-4 | 4.61 | 51.5 | (0.33, 0.60) | Green |
| 24 | Compound C-37 | 4.26 | 67.1 | (0.32, 0.64) | Green |
| 25 | Compound C-69 | 4.32 | 67.4 | (0.31, 0.62) | Green |
| 26 | Compound C-108 | 4.43 | 66.9 | (0.31, 0.63) | Green |
| 27 | Compound C-119 | 4.38 | 63.8 | (0.30, 0.62) | Green |
| 28 | Compound C-21 | 4.29 | 24.7 | (0.48, 0.51) | Yellow |
| 29 | Compound C-59 | 4.35 | 25.1 | (0.49, 0.50) | Yellow |
| 30 | Compound C-66 | 4.33 | 24.3 | (0.49, 0.52) | Yellow |
| 31 | Compound C-96 | 4.37 | 25.4 | (0.48, 0.53) | Yellow |
| 32 | Compound C-125 | 4.38 | 24.9 | (0.47, 0.53) | Yellow |
| 33 | Compound D-37 | 4.32 | 63.7 | (0.31, 0.63) | Green |
| 34 | Compound D-66 | 4.37 | 62.6 | (0.30, 0.61) | Green |
| 35 | Compound D-69 | 4.25 | 65.9 | (0.32, 0.62) | Green |
| 36 | Compound D-96 | 4.40 | 63.2 | (0.33, 0.63) | Green |
| 37 | Compound D-28 | 4.36 | 23.4 | (0.47, 0.53) | Yellow |
| 38 | Compound D-92 | 4.38 | 24.2 | (0.48, 0.53) | Yellow |
| 39 | Compound D-94 | 4.29 | 23.8 | (0.46, 0.51) | Yellow |
| 40 | Compound E-1 | 4.22 | 66.3 | (0.31, 0.63) | Green |
| 41 | Compound E-78 | 4.29 | 64.5 | (0.33, 0.62) | Green |
| 42 | Compound E-81 | 4.31 | 66.7 | (0.31, 0.60) | Green |
| 43 | Compound E-132 | 4.35 | 65.8 | (0.33, 0.63) | Green |
| 44 | Compound E-27 | 4.31 | 17.1 | (0.48, 0.50) | Yellow |
| 45 | Compound E-71 | 4.36 | 17.5 | (0.49, 0.52) | Yellow |
| 46 | Compound E-106 | 4.42 | 17.7 | (0.48, 0.53) | Green |
| 47 | Compound E-109 | 4.33 | 16.2 | (0.47, 0.51) | Green |
| 48 | Compound E-127 | 4.40 | 16.5 | (0.49, 0.52) | Green |
| 49 | Compound F-2 | 4.29 | 65.5 | (0.31, 0.63) | Green |
| 50 | Compound F-85 | 4.37 | 66.7 | (0.32, 0.64) | Green |
| 51 | Compound F-122 | 4.32 | 65.9 | (0.34, 0.62) | Green |
| 52 | Compound F-133 | 4.39 | 64.6 | (0.32, 0.64) | Green |
| 53 | Compound F-25 | 4.27 | 24.3 | (0.48, 0.51) | Yellow |
| 54 | Compound F-80 | 4.32 | 24.6 | (0.48, 0.52) | Yellow |
| 55 | Compound F-113 | 4.35 | 25.1 | (0.47, 0.52) | Yellow |
| 56 | Compound F-116 | 4.38 | 24.9 | (0.46, 0.54) | Yellow |
| 57 | Compound F-142 | 4.41 | 25.4 | (0.47, 0.53) | Yellow |

From the results in table 1, it can be seen that compared to the prior art, when the compound of the present invention is used as the guest material in the light-emitting layer of an organic electroluminescent device, the organic electroluminescent device prepared has a lower driving voltage and higher light-emitting efficiency.

From the results in table 2, it can be seen that compared to the prior art, when the compound of the present invention is used as the guest material in the light-emitting layer of an organic electroluminescent device, the organic electroluminescent device prepared has a lower driving voltage and higher light-emitting efficiency.

The preferred embodiments of the present invention have been described above in detail, but the present invention is not limited thereto. Within the scope of the technical idea of the invention, many simple modifications can be made to the technical solution of the invention, including various technical features being combined in any other suitable way, and these simple modifications and combinations should also be regarded as the disclosure of the invention, and all fall within the scope of the invention.

1. A compound containing a 1,3-diketone ligand having a structure represented by Ir (L_{A})(L_{B})₂, wherein L_{A} has a structure represented by formula (IA1), formula (IA2), formula (IA3), formula (IA4), formula (IA5), or formula (IA6), and L_{B} is a structure represented by formula (IB), formula L_{B310}, formula L_{B311}, formula L_{B312}, formula L_{B313}, or formula L_{B314}; 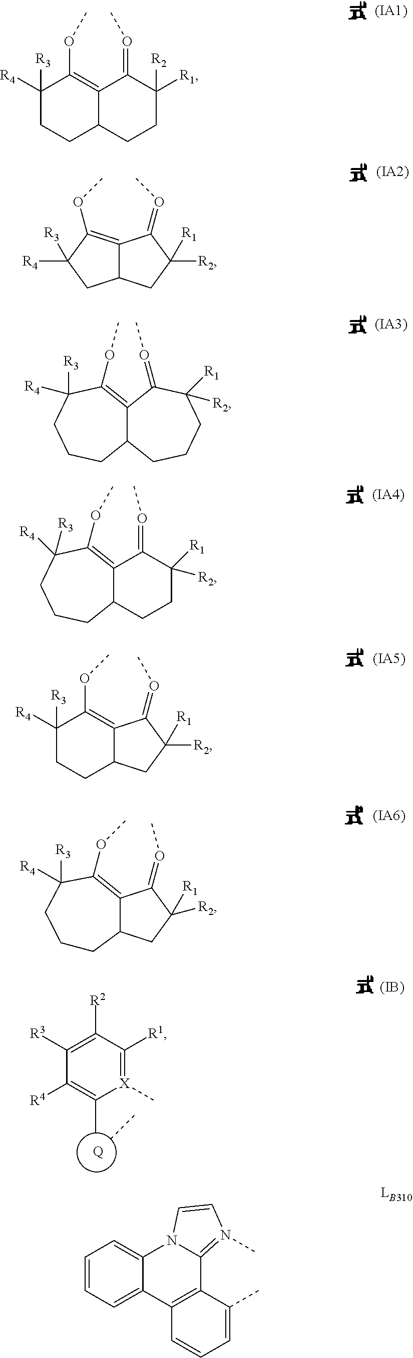 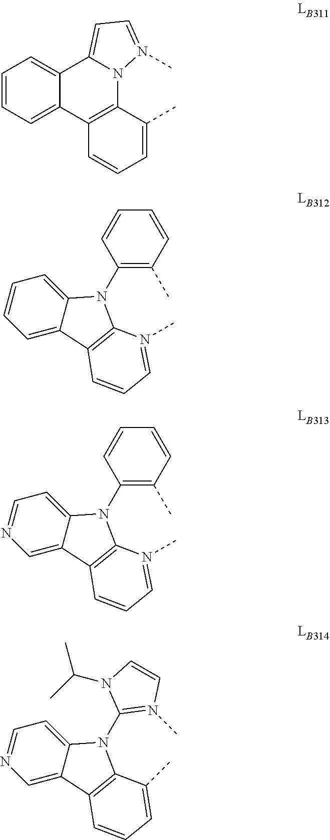
in formula (IA1), formula (IA2), formula (IA3), formula (IA4), formula (IA5) and formula (IA6), R₁, R₂, R₃, and R₄ are independently selected from H, C₁-C₂₀ alkyl, C₆-C₂₀ aryl; or at least one combination of each of R₁ and R₂ and each of R₃ and R₄ cyclized to form a 4-7 membered saturated ring;
in formula (IB), X is C or N,
the ring Q is selected from a substituted or unsubstituted benzene ring, a substituted or unsubstituted quinoline ring, a substituted or unsubstituted isoquinoline ring, a substituted or unsubstituted naphthalene ring, a substituted or unsubstituted phenanthrene ring, a substituted or unsubstituted benzothiophene ring, a substituted or unsubstituted benzofuran ring, a substituted or unsubstituted indole ring, a substituted or unsubstituted benzothiazole ring, a substituted or unsubstituted benzoxazole ring, a substituted or unsubstituted benzimidazole ring, a substituted or unsubstituted dibenzothiophene ring, a substituted or unsubstituted dibenzofuran ring, a substituted or unsubstituted benzofuropyridine ring, a substituted or unsubstituted benzothienopyridine ring, a substituted or unsubstituted benzindolopyridine ring, a substituted or unsubstituted pyridoindolopyridine ring, a substituted or unsubstituted imidazole ring, a substituted or unsubstituted pyrrolidine ring;
R¹, R², R³ and R⁴ are independently selected from H, C₁-C₂₀ alkyl, C₆-C₂₀ aryl; or any two adjacent of R¹, R², R³, and R⁴ are cyclized together to form at least one ring structure selected from a substituted or unsubstituted benzene ring, a substituted or unsubstituted naphthalene ring, a substituted or unsubstituted benzofuran ring, a substituted or unsubstituted pyridofuran ring, a substituted or unsubstituted benzothiophene ring, and a substituted or unsubstituted pyridothiophene ring; and
the optional substituents on the Q ring and the optional substituents on R¹, R², R³ and R⁴ are independently selected from at least one of C₁-C₁₀ alkyl and phenyl.

2. The compound according to claim 1, wherein, in the structure represented by Ir(L_{A})(L_{B})₂, L_{A} has a structure represented by formula (IA1), formula (IA2), formula (IA3), formula (IA4), formula (IA5), or formula (IA6), and L_{B} is a structure represented by formula (IB), formula L_{B310}, formula L_{B311}, formula L_{B312}, formula L_{B313}, or formula L_{B314};
in formula (IA1), formula (IA2), formula (IA3), formula (IA4), formula (IA5) and formula (IA6), R₁, R₂, R₃, and R₄ are independently selected from H, C₁-C₁₅ alkyl, C₆-C₁₅ aryl; or at least one combination of each of R₁ and R₂ and each of R₃ and R₄ cyclized to form a 4-7 membered saturated ring; and
in formula (IB), X is C or N,
the ring Q is selected from a substituted or unsubstituted benzene ring, a substituted or unsubstituted quinoline ring, a substituted or unsubstituted isoquinoline ring, a substituted or unsubstituted naphthalene ring, a substituted or unsubstituted phenanthrene ring, a substituted or unsubstituted benzothiophene ring, a substituted or unsubstituted benzofuran ring, a substituted or unsubstituted indole ring, a substituted or unsubstituted benzothiazole ring, a substituted or unsubstituted benzoxazole ring, a substituted or unsubstituted benzimidazole ring, a substituted or unsubstituted dibenzothiophene ring, a substituted or unsubstituted dibenzofuran ring, a substituted or unsubstituted benzofuropyridine ring, a substituted or unsubstituted benzothienopyridine ring, a substituted or unsubstituted benzindolopyridine ring, a substituted or unsubstituted pyridoindolopyridine ring, a substituted or unsubstituted imidazole ring, a substituted or unsubstituted pyrrolidine ring;
R¹, R², R³ and R⁴ are independently selected from H, C₁-C₁₅ alkyl, C₆-C₁₅ aryl; or any two adjacent of R¹, R², R³, and R⁴ are cyclized together to form at least one ring structure selected from a substituted or unsubstituted benzene ring, a substituted or unsubstituted naphthalene ring, a substituted or unsubstituted benzofuran ring, a substituted or unsubstituted pyridofuran ring, a substituted or unsubstituted benzothiophene ring, and a substituted or unsubstituted pyridothiophene ring; and
the optional substituents on the Q ring and the optional substituents on R¹, R², R³ and R⁴ are independently selected from at least one of C₁-C₈ alkyl and phenyl.

3. The compound according to claim 1, wherein, in the structure represented by Ir(L_{A})(L_{B})₂, L_{A} has a structure represented by formula (IA1), formula (IA2), formula (IA3), formula (IA4), formula (IA5), or formula (IA6), and L_{B} is a structure represented by formula (TB), formula L_{B310}, formula L_{B311}, formula L_{B312}, formula L_{B313}, or formula L_{B314};
in formula (IA1), formula (IA2), formula (IA3), formula (IA4), formula (IA5) and formula (IA6), R₁, R₂, R₃, and R₄ are independently selected from H, C₁-C₁₀ alkyl, C₆-C₁₂ aryl; or at least one combination of each of R₁ and R₂ and each of R₃ and R₄ cyclized to form a 4-7 membered saturated ring;
in formula (IB), X is C or N,
the ring Q is selected from a substituted or unsubstituted benzene ring, a substituted or unsubstituted quinoline ring, a substituted or unsubstituted isoquinoline ring, a substituted or unsubstituted naphthalene ring, a substituted or unsubstituted phenanthrene ring, a substituted or unsubstituted benzothiophene ring, a substituted or unsubstituted benzofuran ring, a substituted or unsubstituted indole ring, a substituted or unsubstituted benzothiazole ring, a substituted or unsubstituted benzoxazole ring, a substituted or unsubstituted benzimidazole ring, a substituted or unsubstituted dibenzothiophene ring, a substituted or unsubstituted dibenzofuran ring, a substituted or unsubstituted benzofuropyridine ring, a substituted or unsubstituted benzothienopyridine ring, a substituted or unsubstituted benzindolopyridine ring, a substituted or unsubstituted pyridoindolopyridine ring, a substituted or unsubstituted imidazole ring, a substituted or unsubstituted pyrrolidine ring;
R¹, R², R³ and R⁴ are independently selected from H, C₁-C₁₀ alkyl, C₆-C₁₂ aryl; or any two adjacent of R¹, R², R³, and R⁴ are cyclized together to form at least one ring structure selected from a substituted or unsubstituted benzene ring, a substituted or unsubstituted naphthalene ring, a substituted or unsubstituted benzofuran ring, a substituted or unsubstituted pyridofuran ring, a substituted or unsubstituted benzothiophene ring, and a substituted or unsubstituted pyridothiophene ring; and
the optional substituents on the Q ring and the optional substituents on R¹, R², R³ and R⁴ are independently selected from at least one of C₁-C₆ alkyl and phenyl.

4. The compound according to claim 3, wherein, in the structure represented by Ir(L_{A})(L_{B})₂, in formula (IA1), formula (IA2), formula (IA3), formula (IA4), formula (IA5) and formula (IA6), R₁, R₂, R₃, and R₄ are independently selected from H, C₁-C₈ alkyl, C₆-C₁₀ aryl; or at least one combination of each of R₁ and R₂ and each of R₃ and R₄ cyclized to form a 4-7 membered saturated ring.

5. The compound according to claim 4, wherein, in the structure represented by Ir(L_{A})(L_{B})₂, in formula (IA1), formula (IA2), formula (IA3), formula (IA4), formula (IA5) and formula (IA6), R₁, R₂, R₃, and R₄ are independently selected from H, methyl, ethyl, C₃ straight chain alkyl, C₃ branched chain alkyl, C₃ cycloalkyl, C₄ straight chain alkyl, C₄ branched chain alkyl, C₄ cycloalkyl, C₅ straight chain alkyl, C₅ branched chain alkyl, C₅ cycloalkyl, C₆ straight chain alkyl, C₆ branched chain alkyl, C₆ cycloalkyl, C₇ straight chain alkyl, C₇ branched chain alkyl, C₇ cycloalkyl, C₈ straight chain alkyl, C₈ branched chain alkyl, C₈ cycloalkyl, phenyl; or at least one combination of each of R₁ and R₂ and each of R₃ and R₄ cyclized to form a 4-7 membered saturated ring.

6. The compound according to claim 5, wherein, in the structure represented by Ir(L_{A})(L_{B})₂, L_{A} is selected from the group consisting of the following structures:

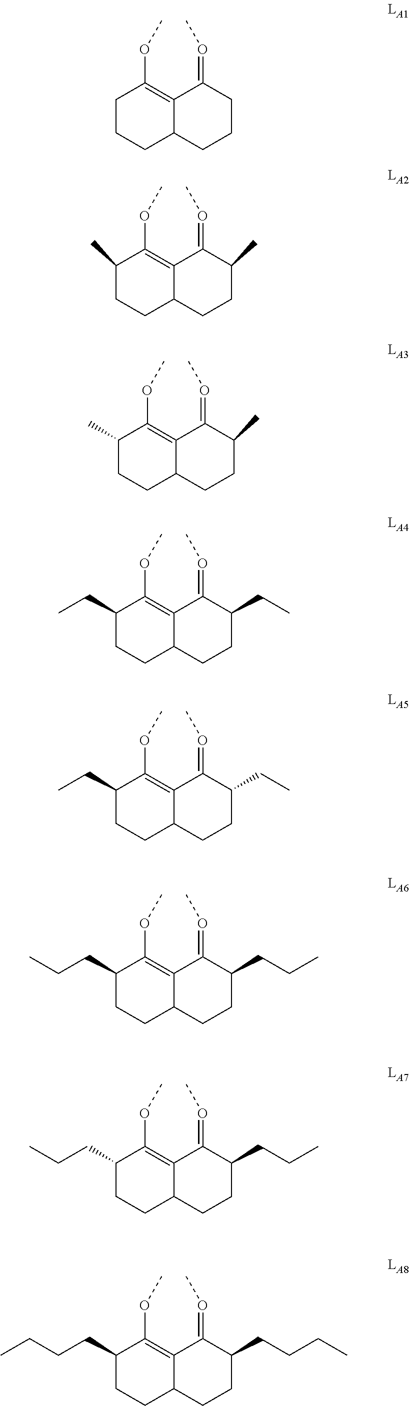

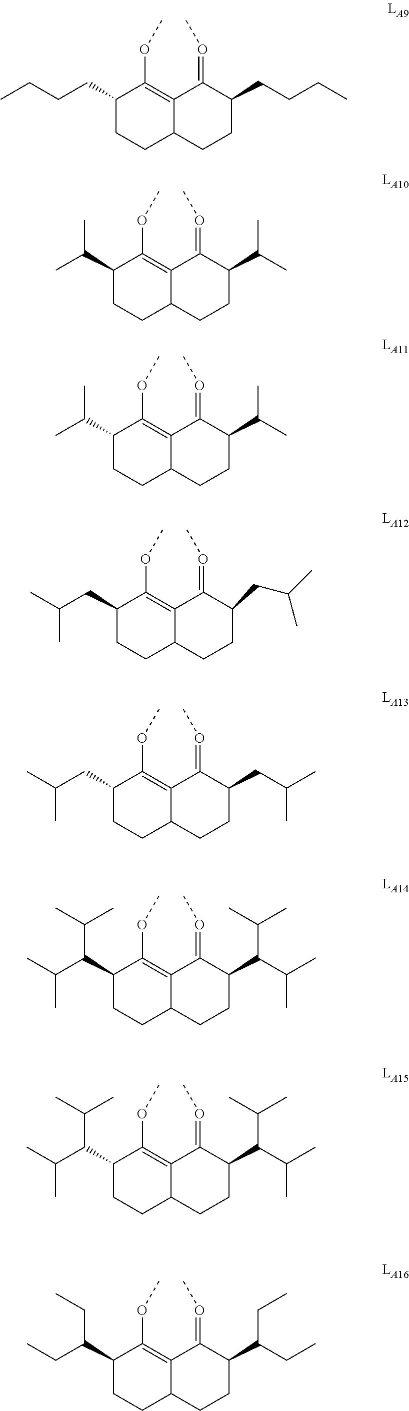

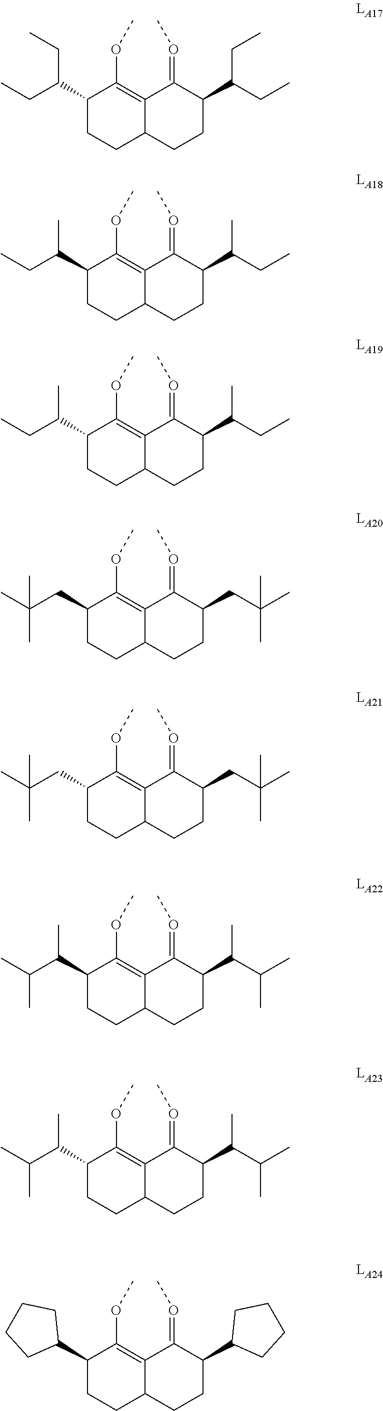

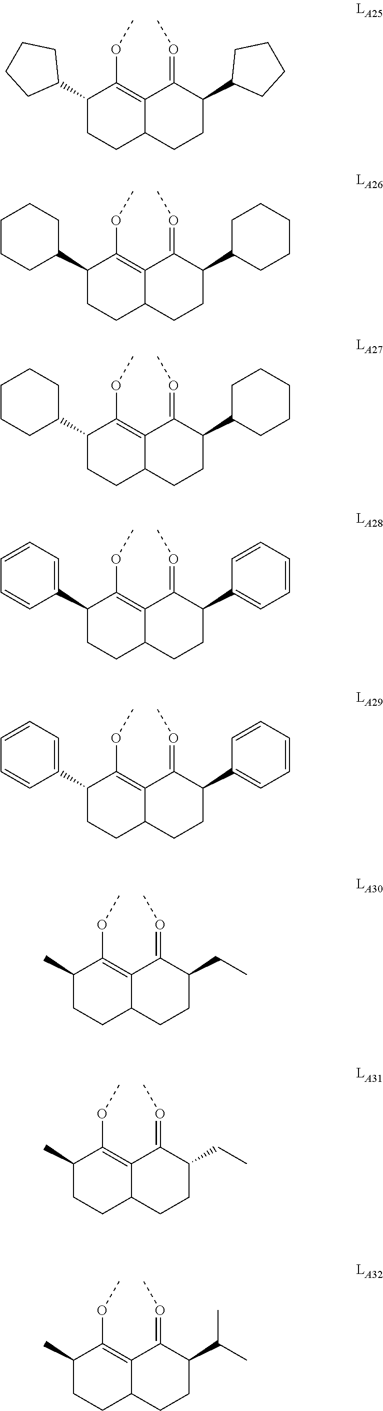

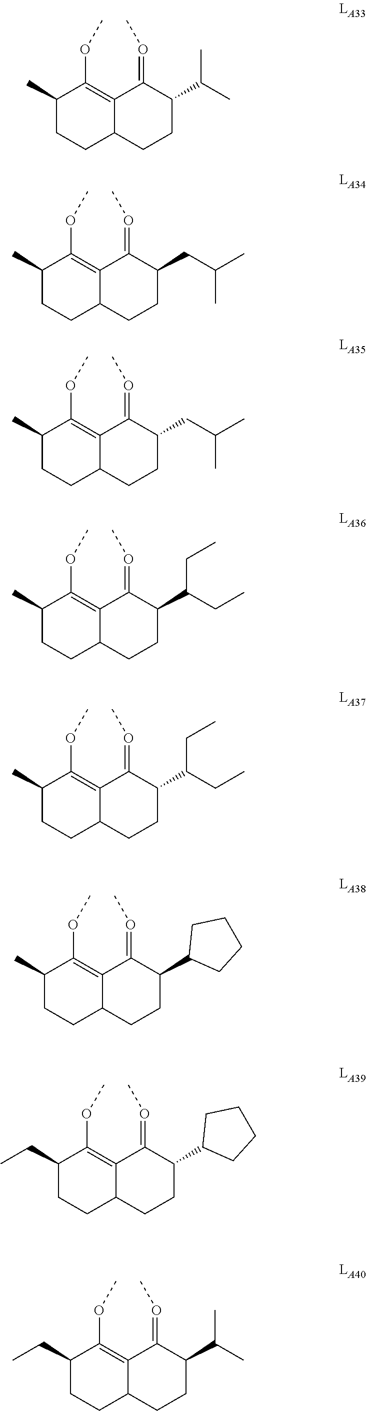

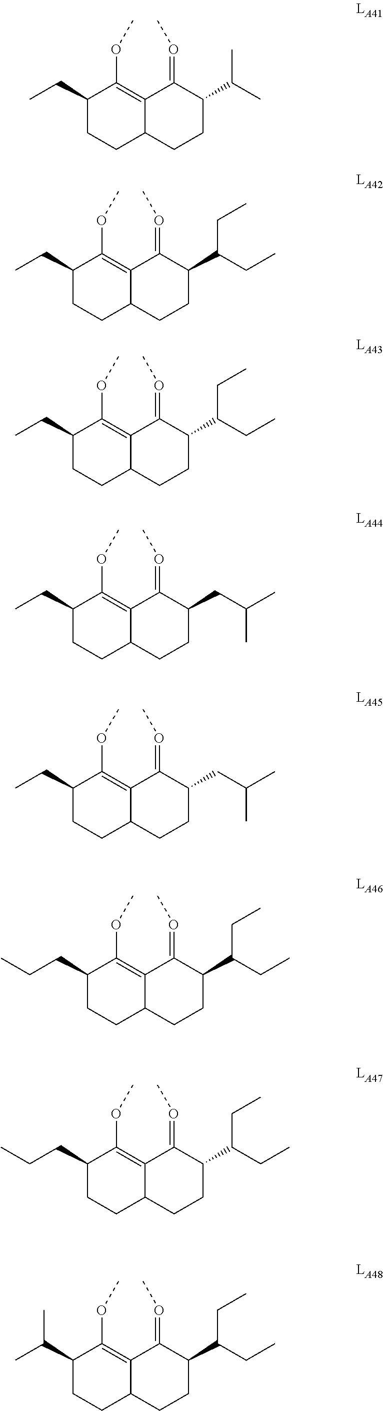

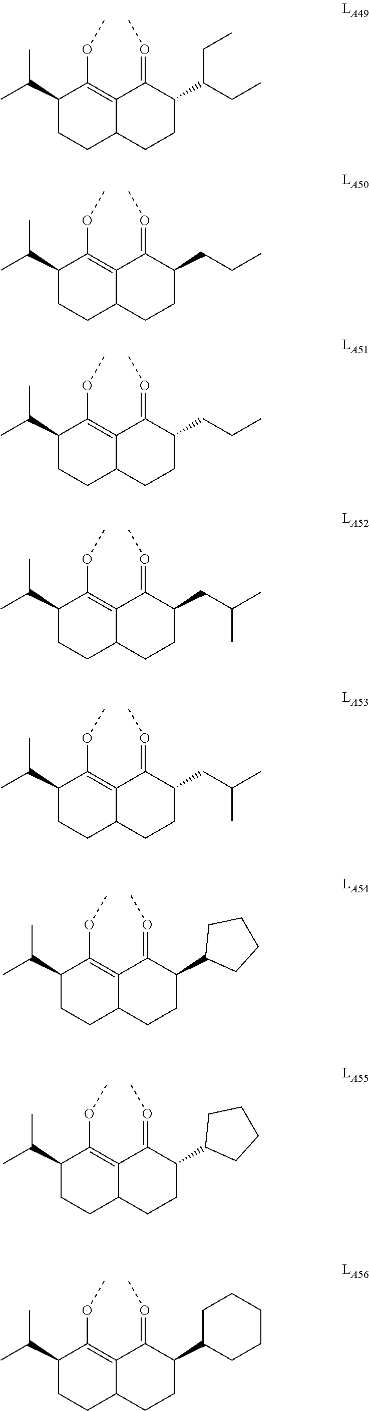

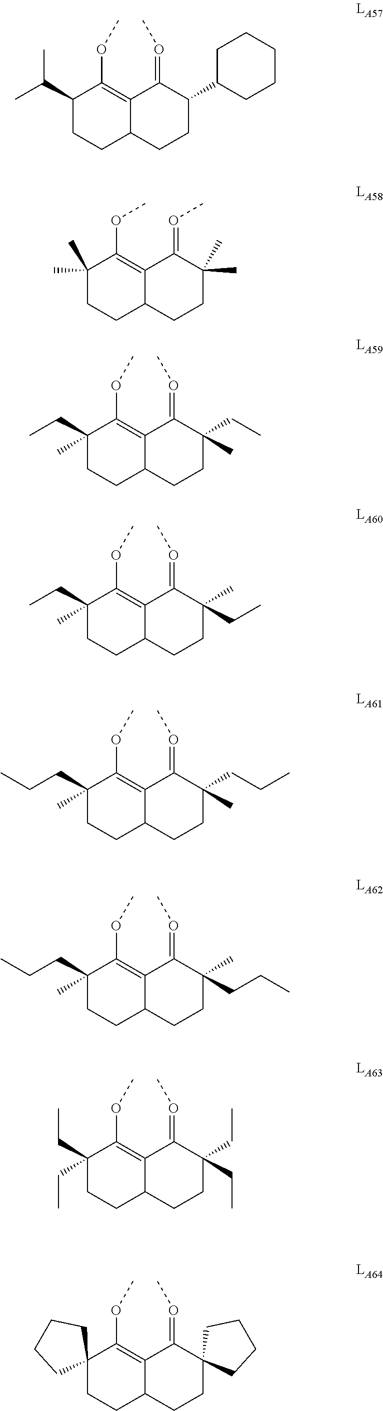

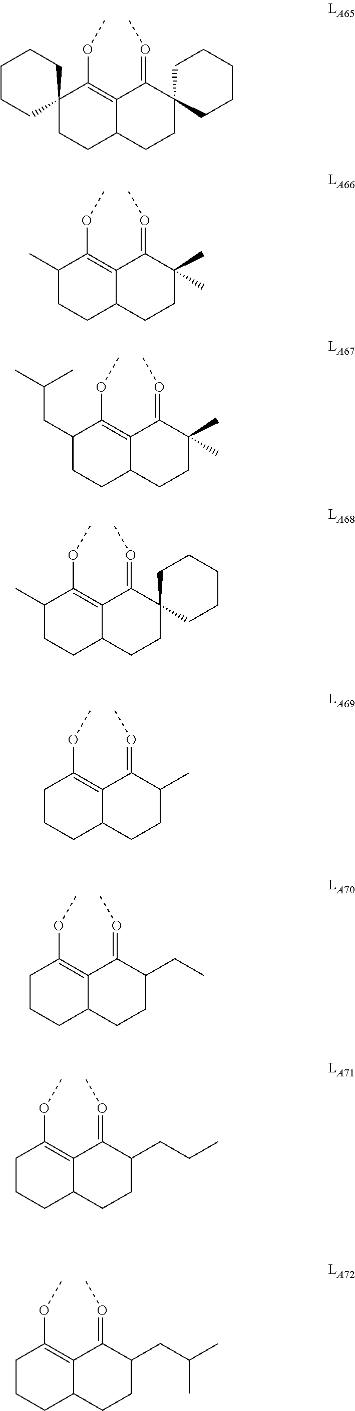

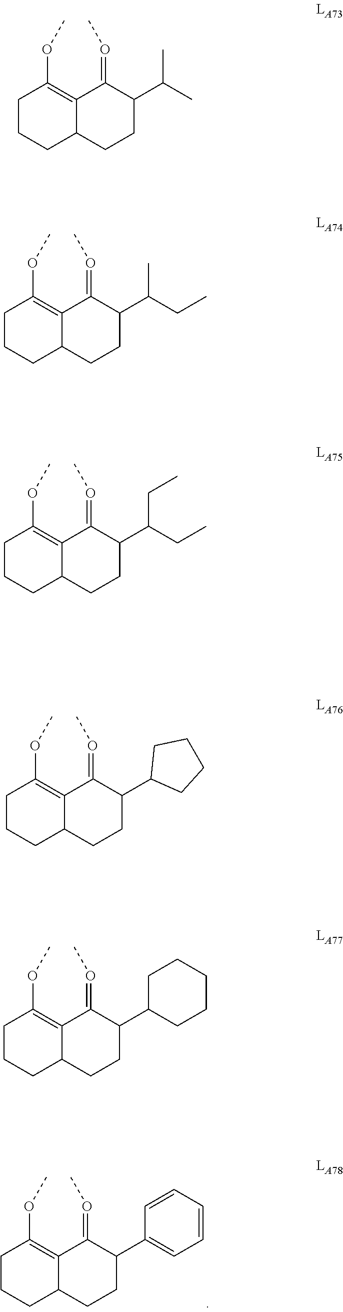

7. The compound according to claim 5, wherein, in the structure represented by Ir(L_{A})(L_{B})₂, L_{A} is selected from the group consisting of the following structures:

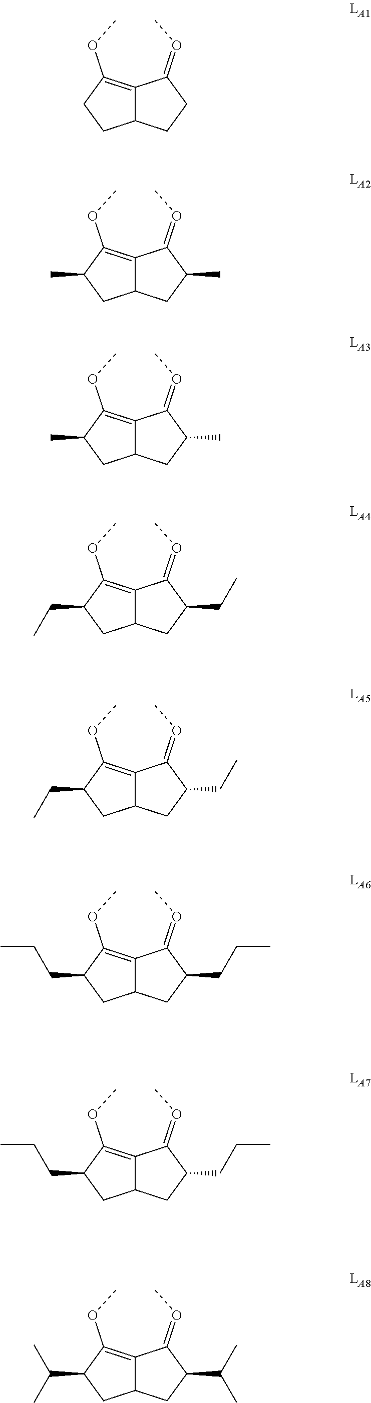

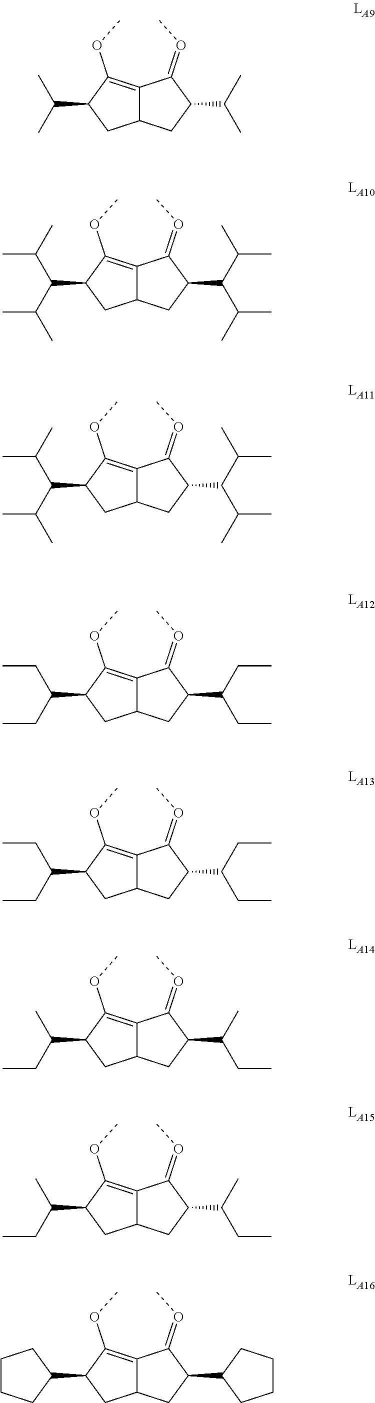

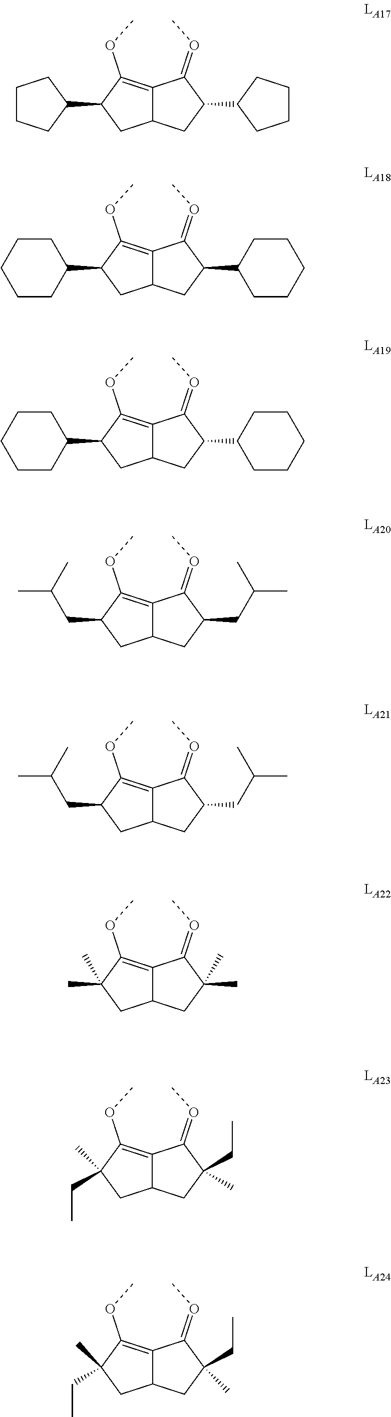

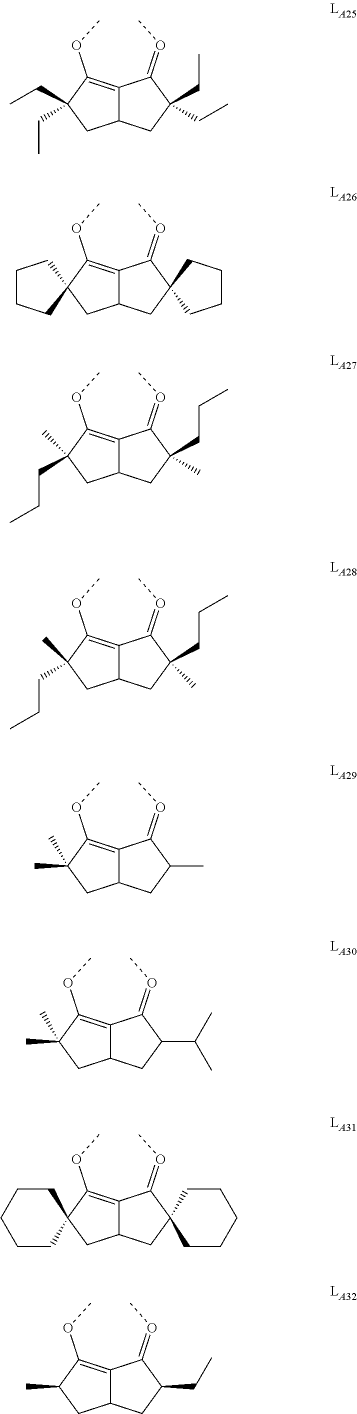

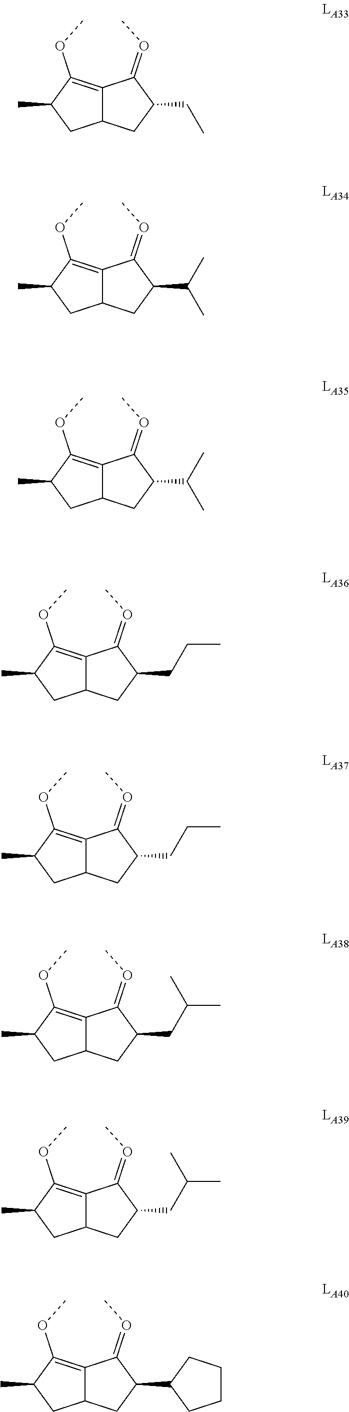

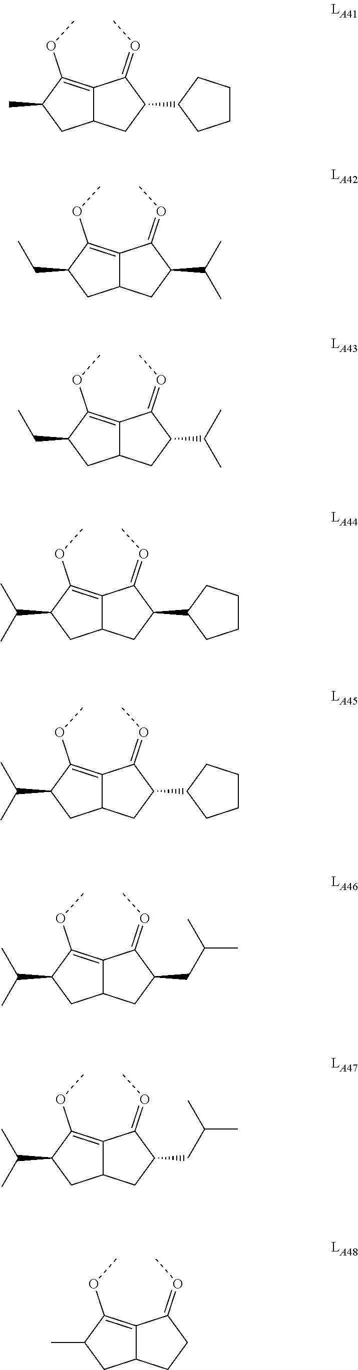

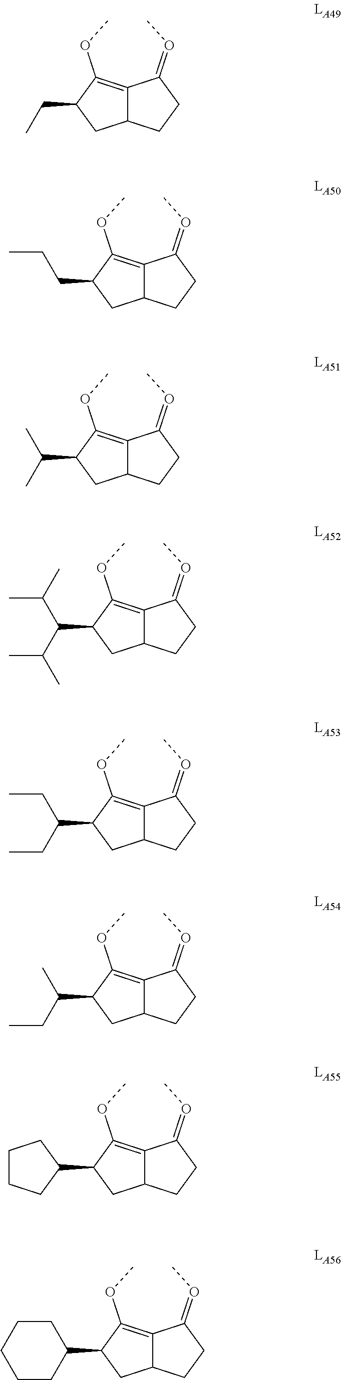

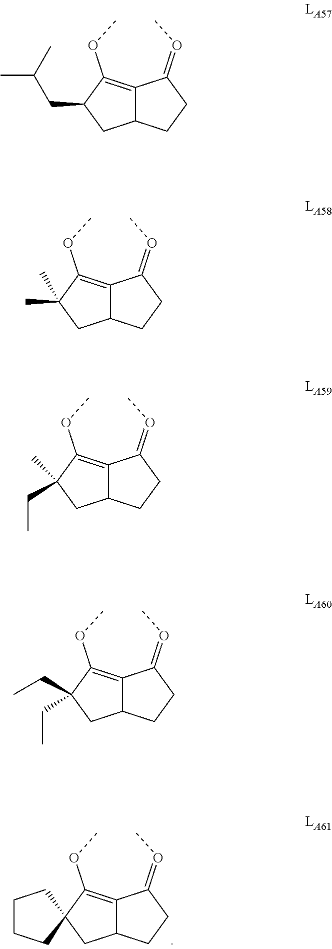

8. The compound according to claim 5, wherein, in the structure represented by Ir(L_{A})(L_{B})₂, L_{A} is selected from the group consisting of the following structures:

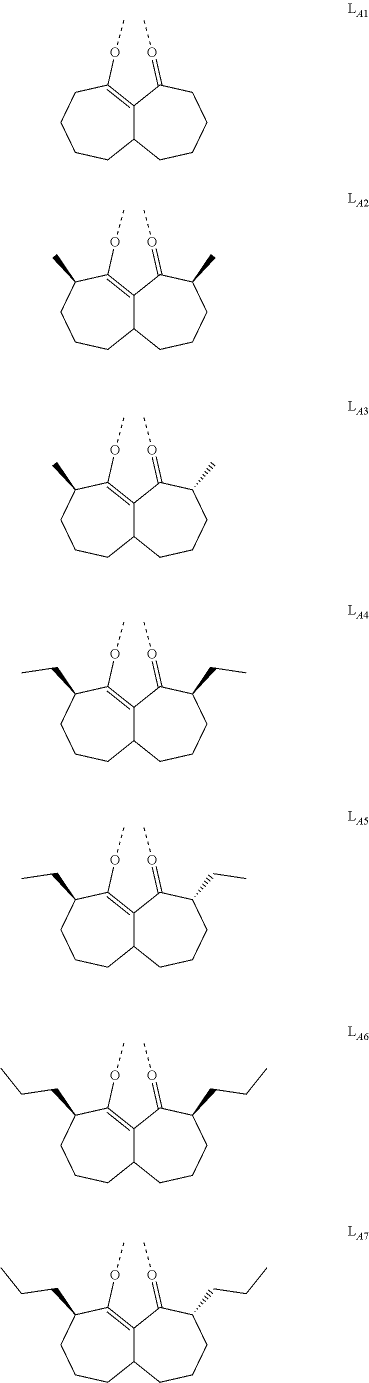

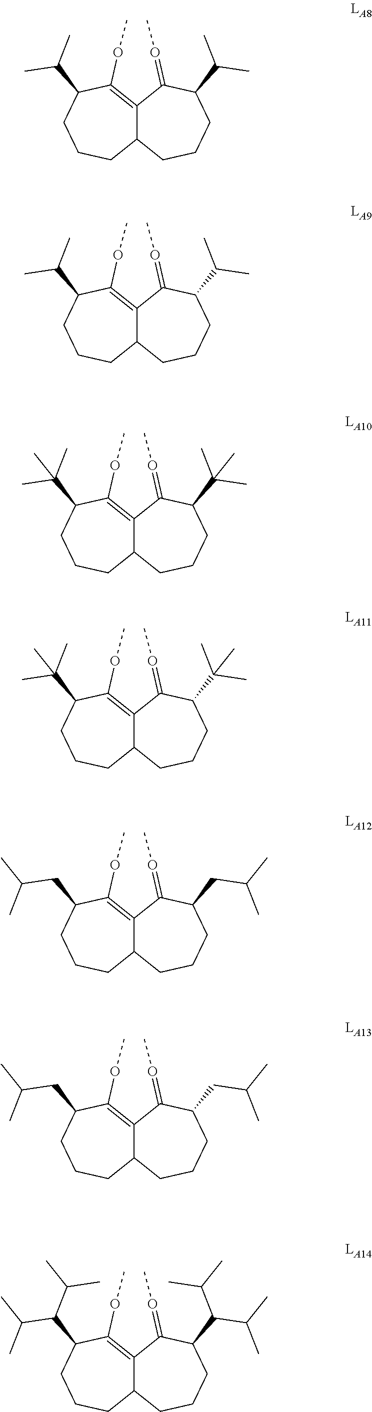

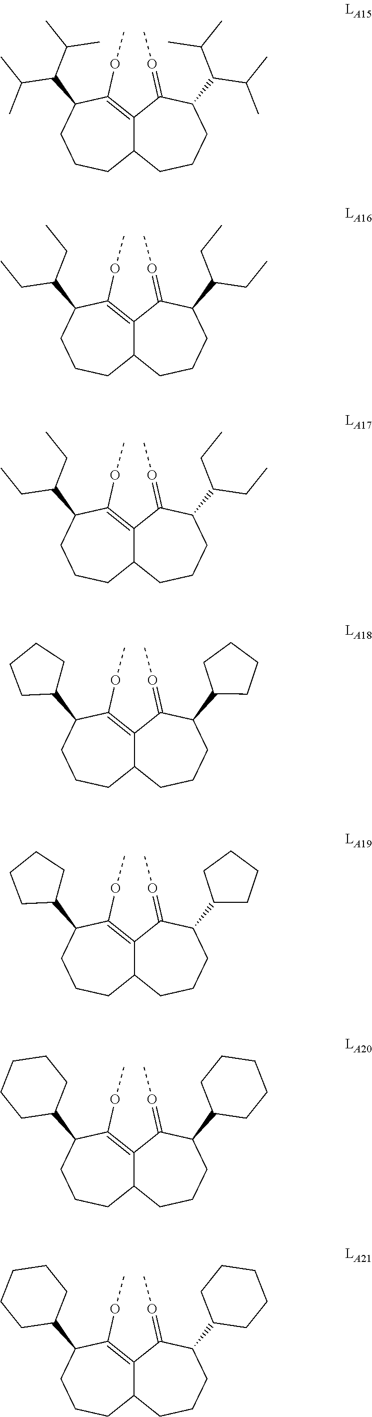

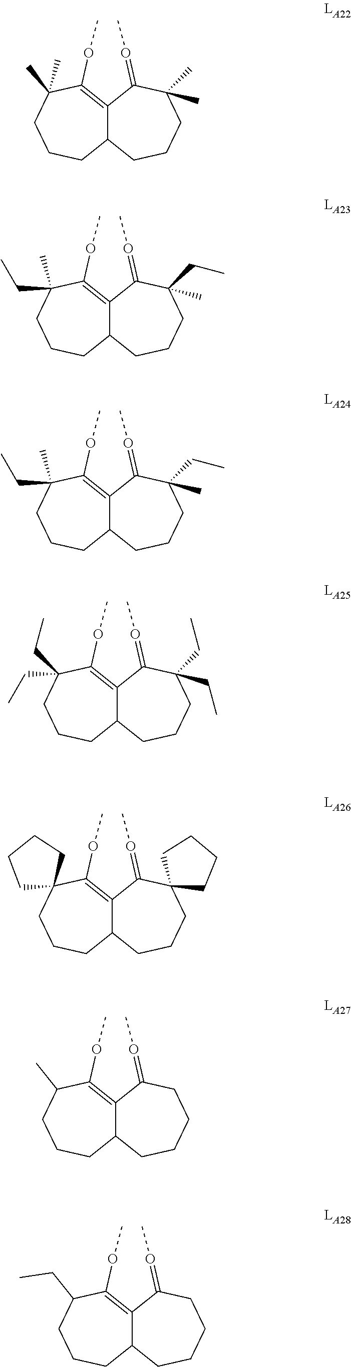

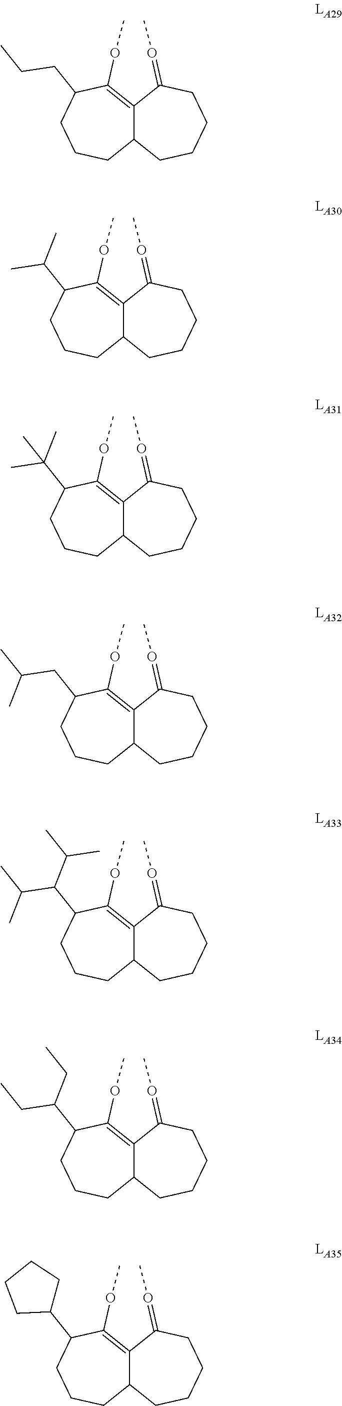

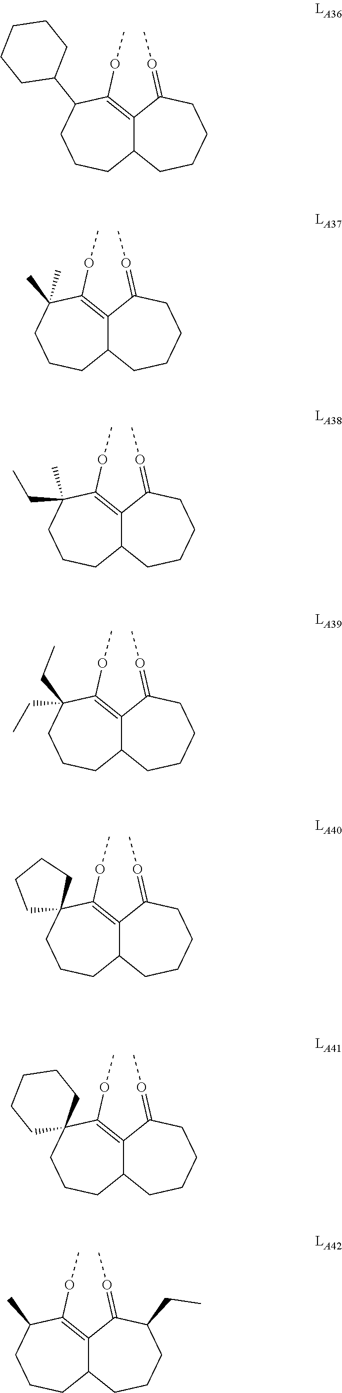

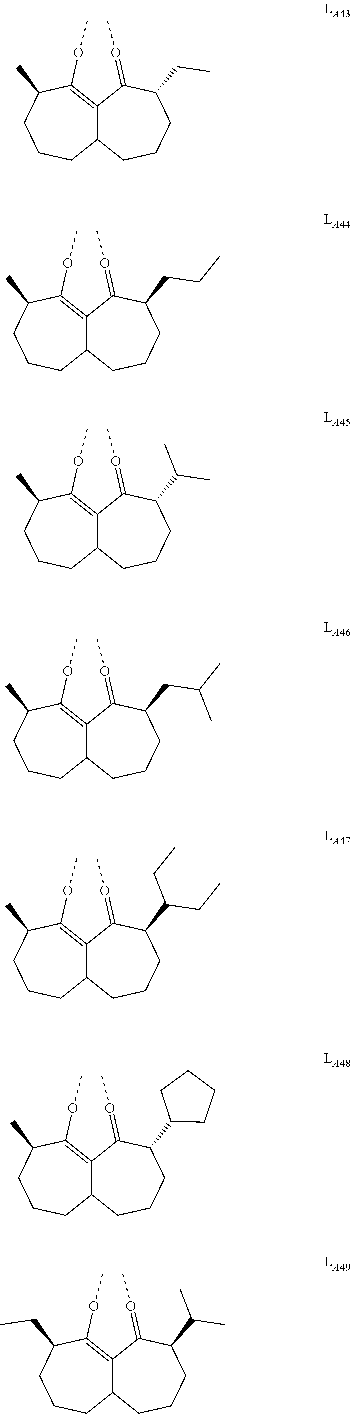

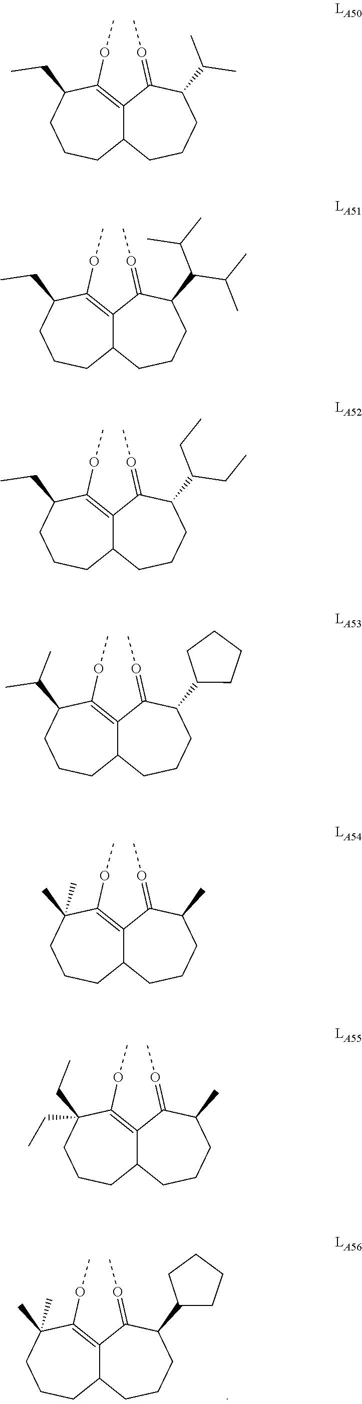

9. The compound according to claim 5, wherein, in the structure represented by Ir(L_{A})(L_{B})₂, L_{A} is selected from the group consisting of the following structures:

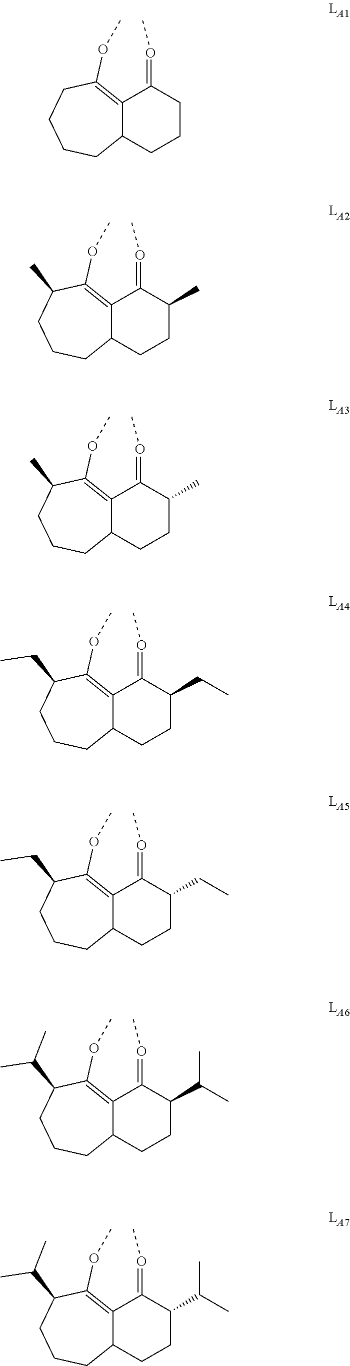

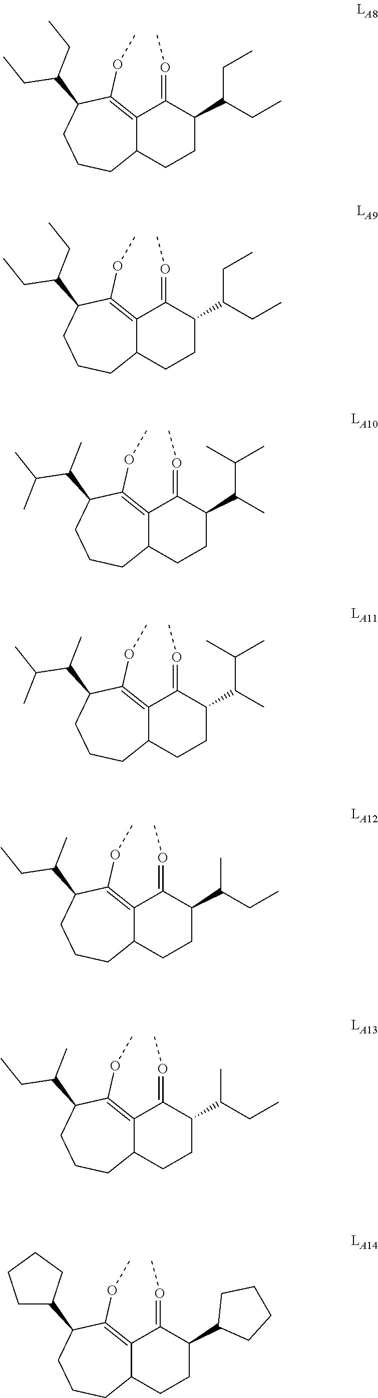

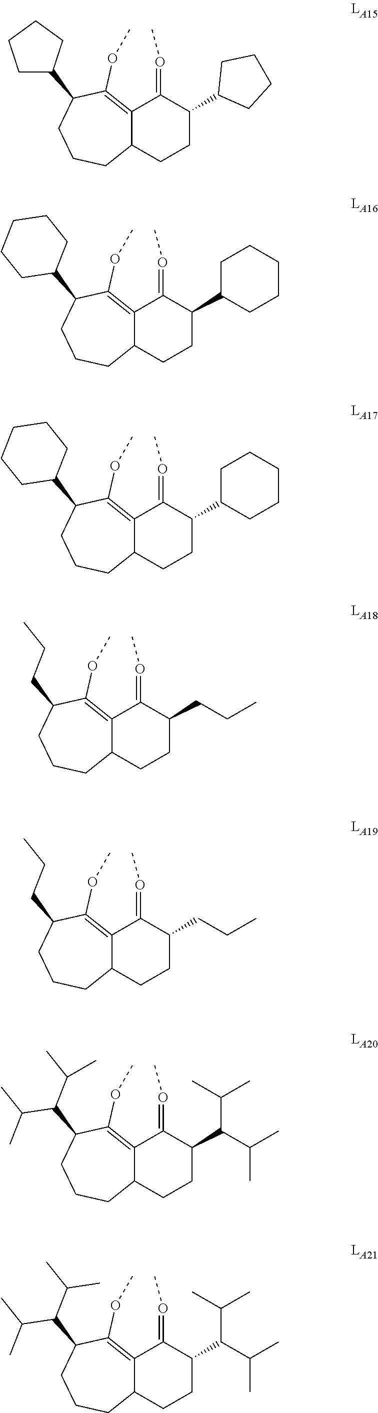

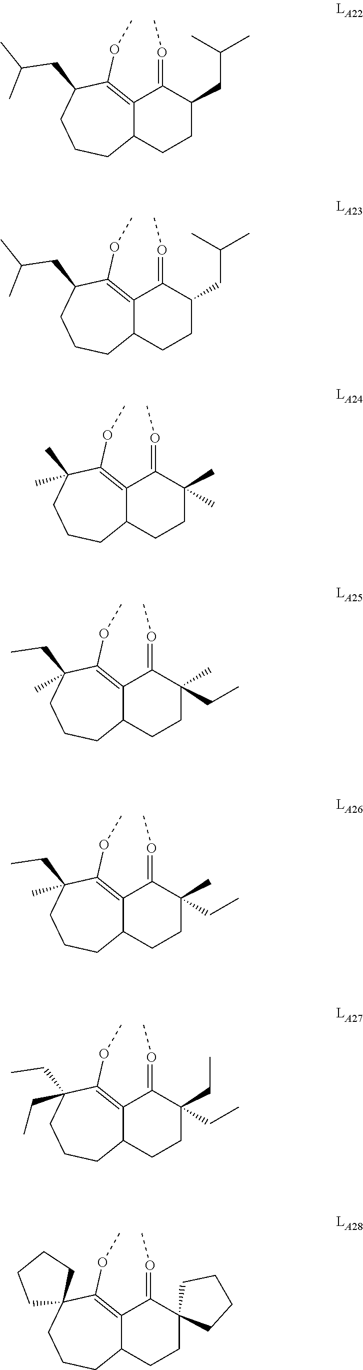

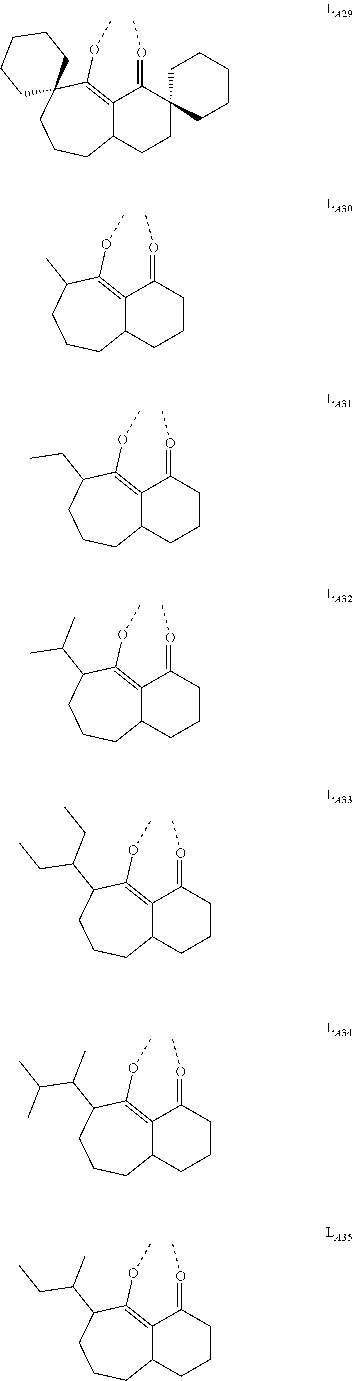

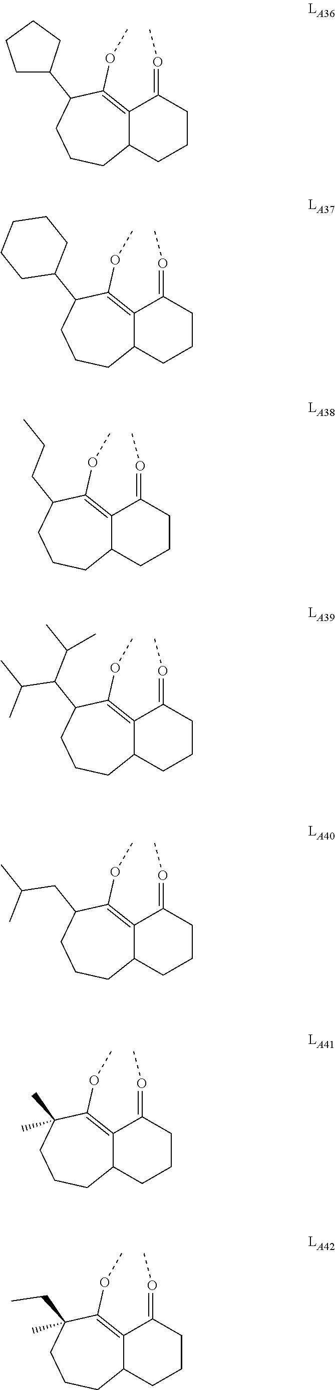

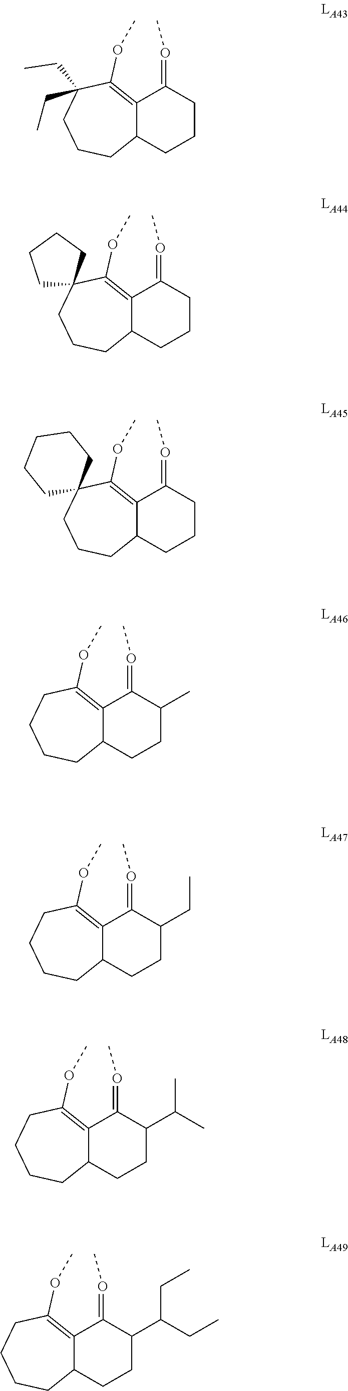

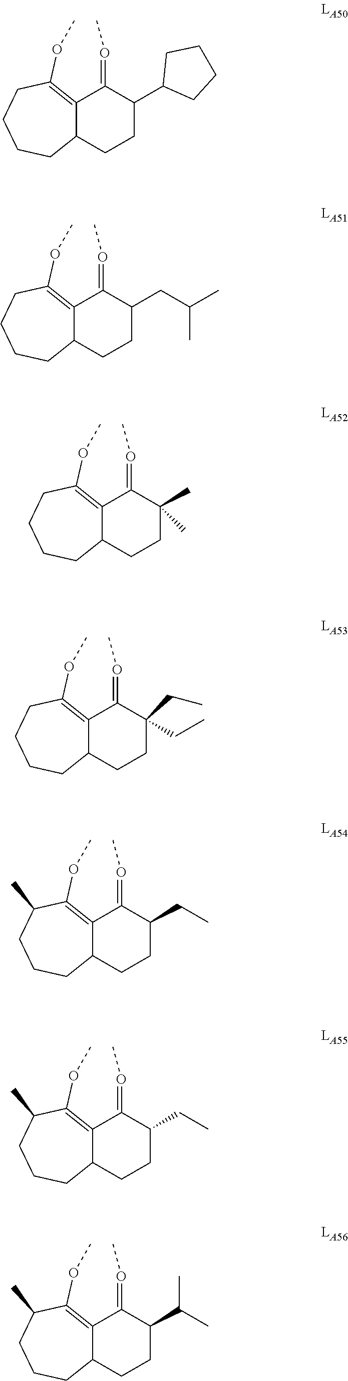

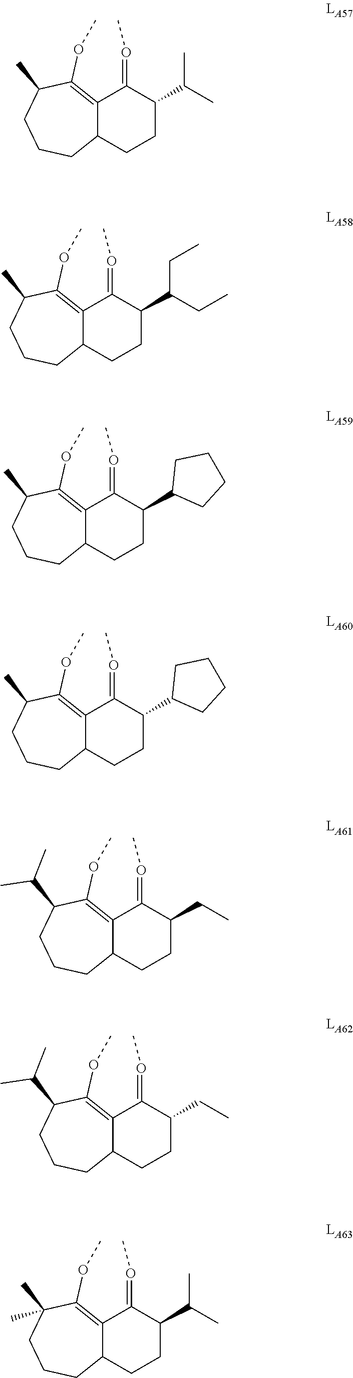

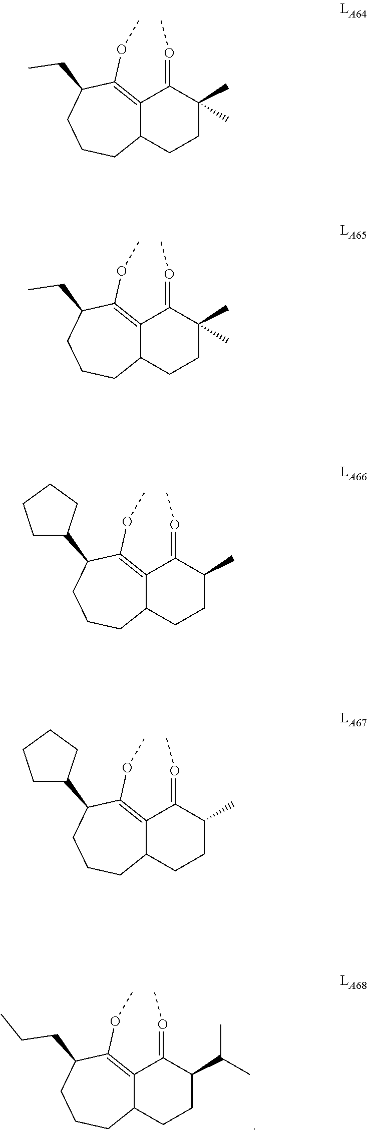

10. The compound according to claim 5, wherein, in the structure represented by Ir(L_{A})(L_{B})₂, L_{A} is selected from the group consisting of the following structures:

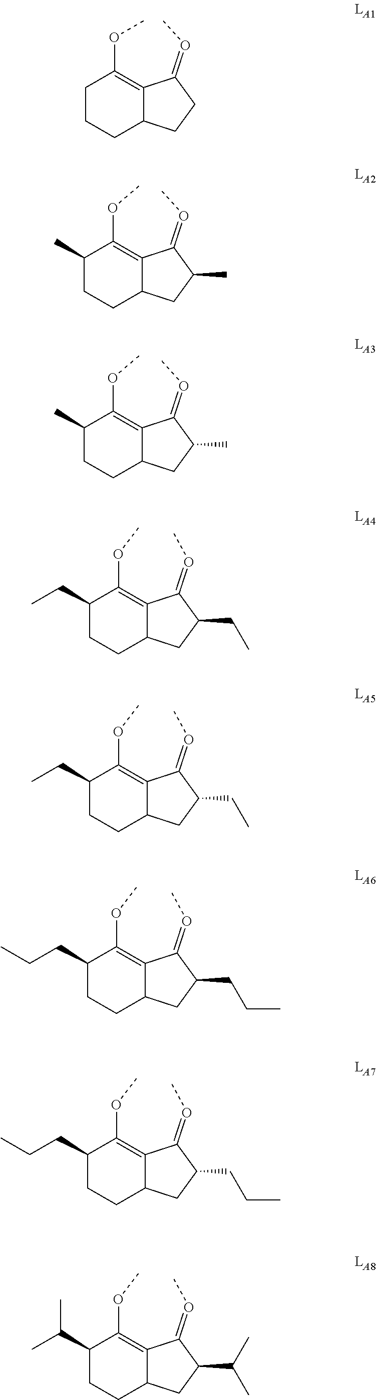

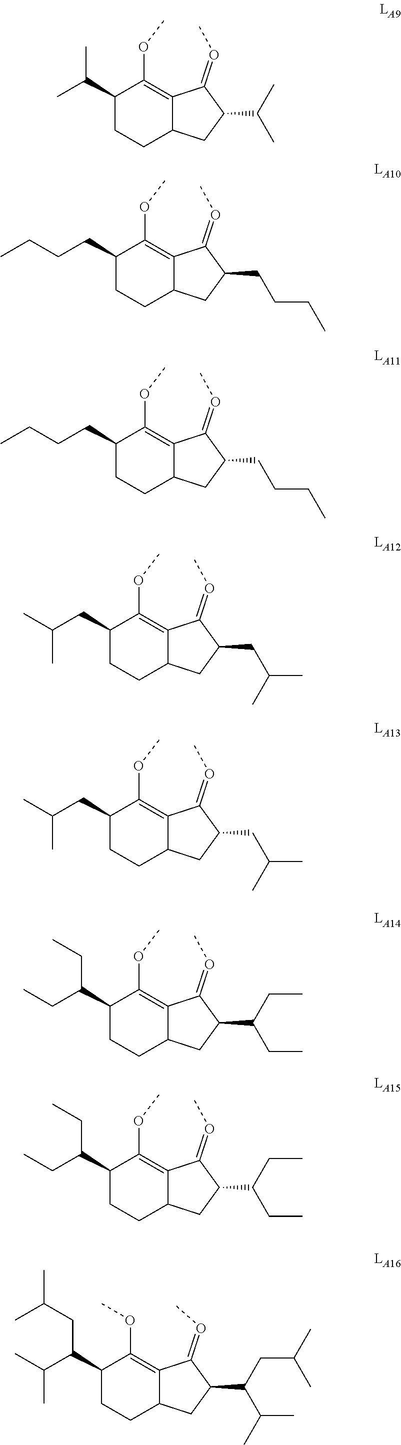

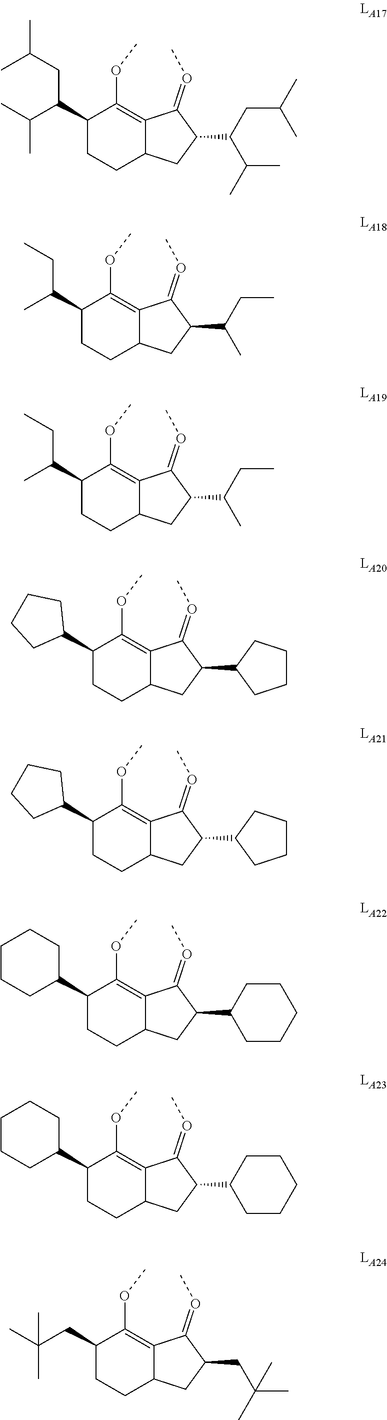

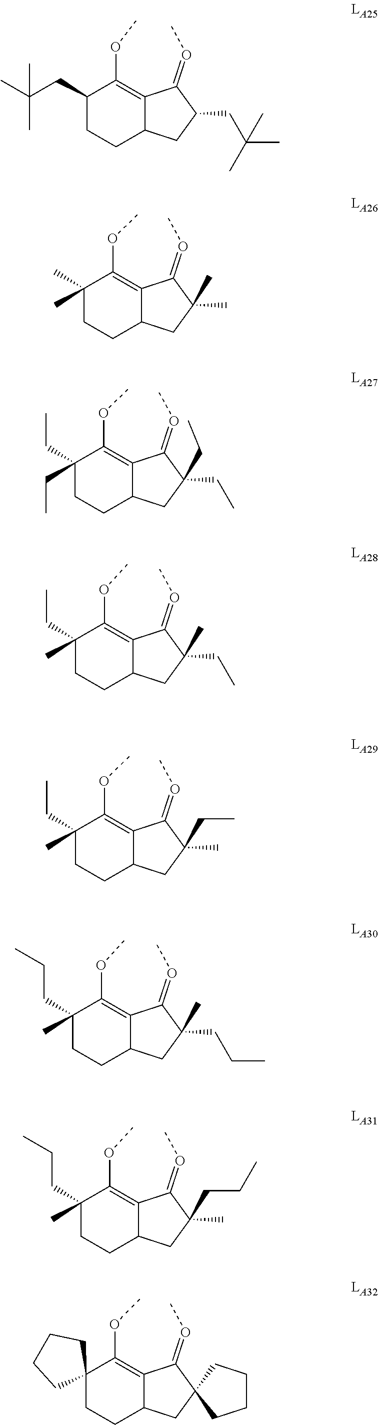

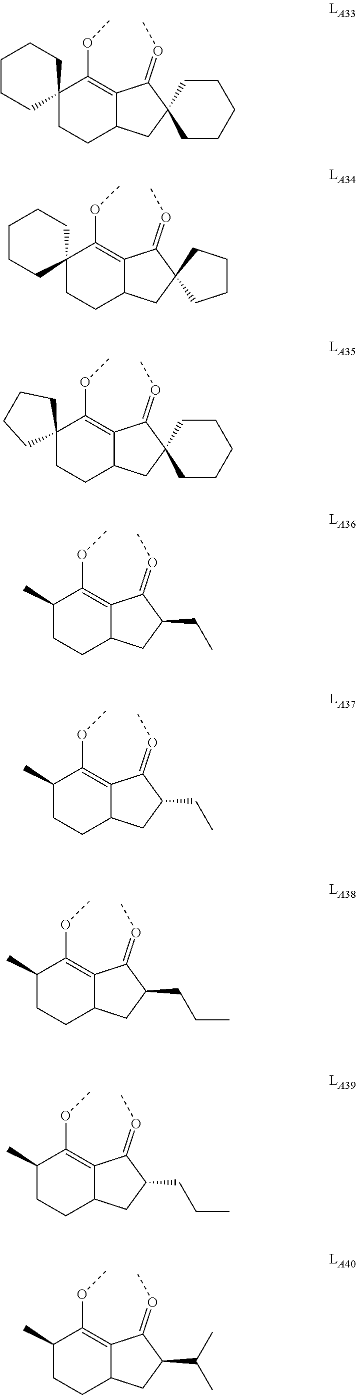

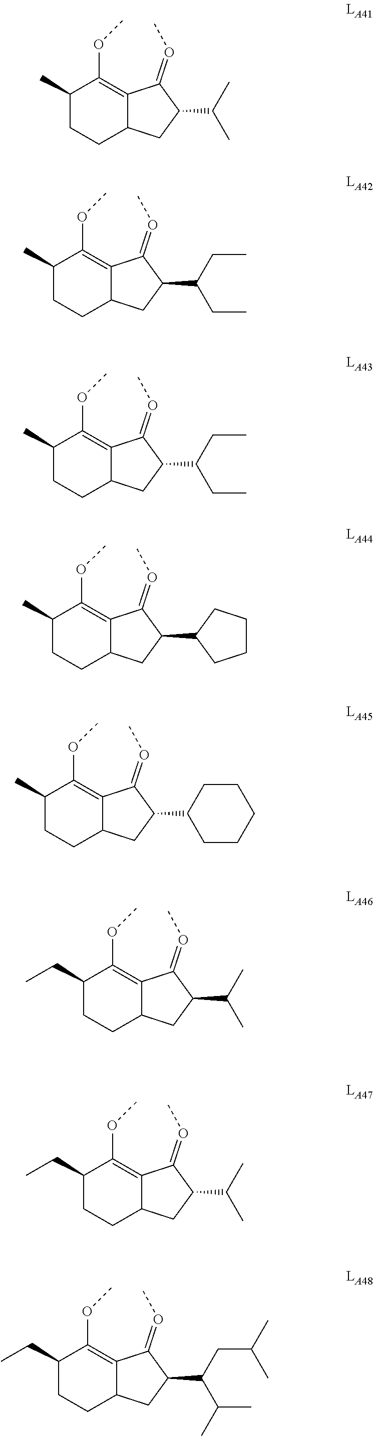

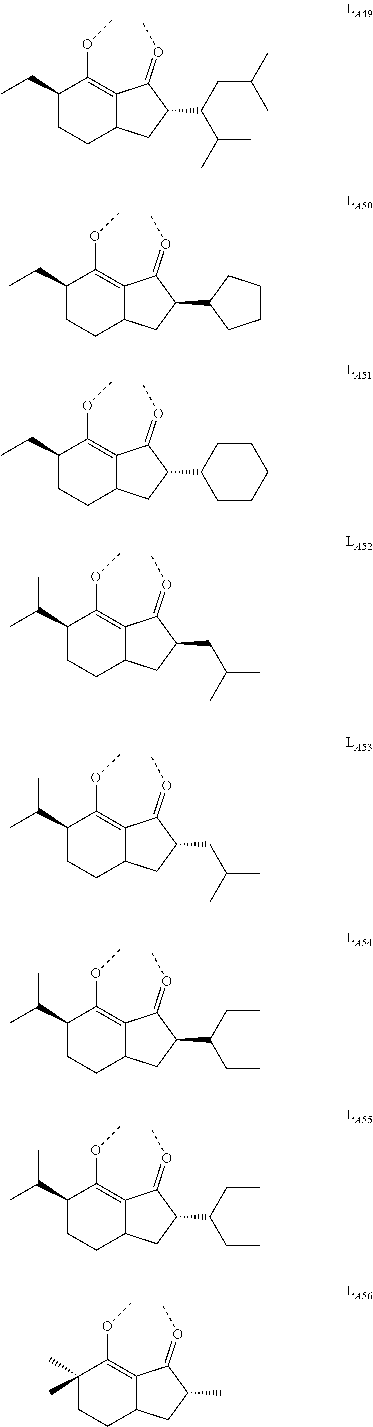

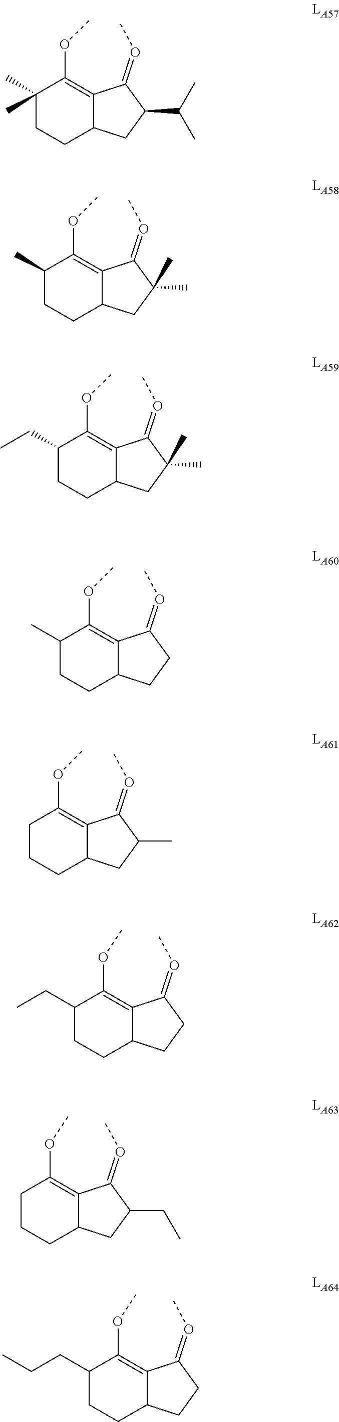

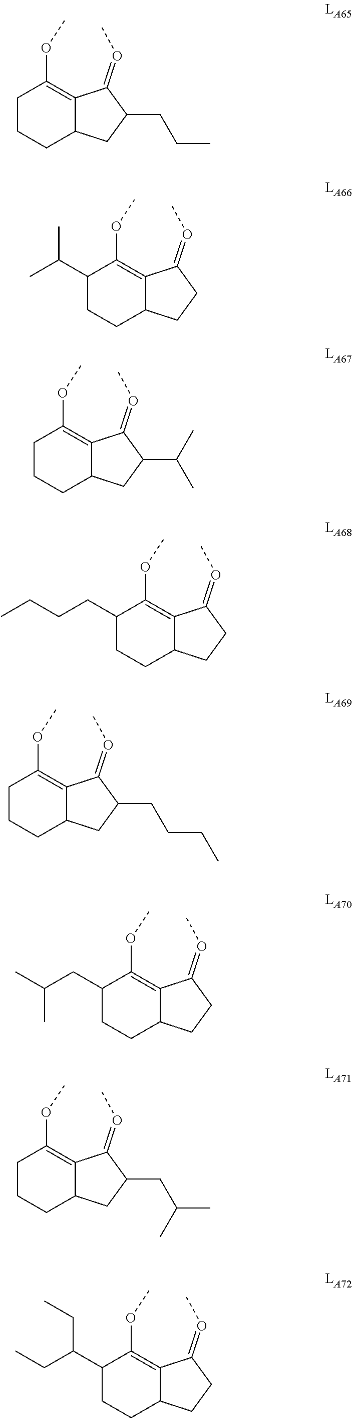

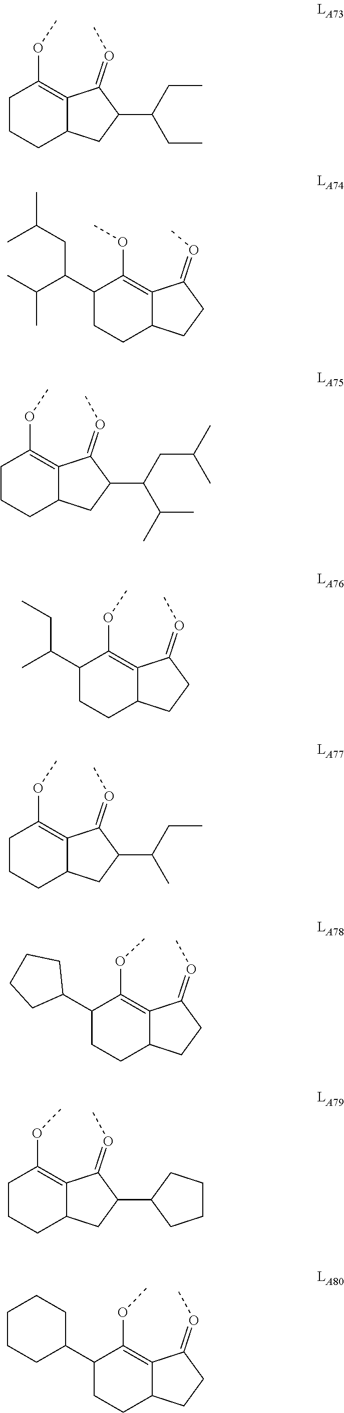

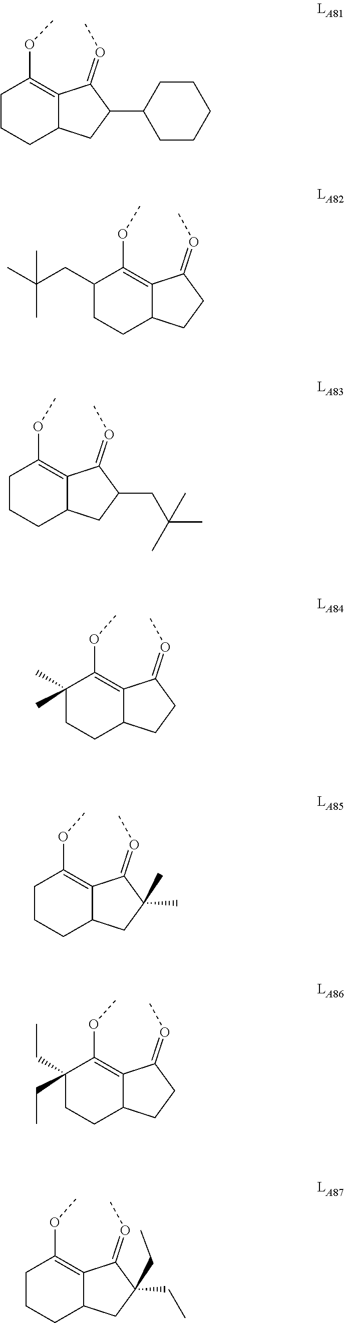

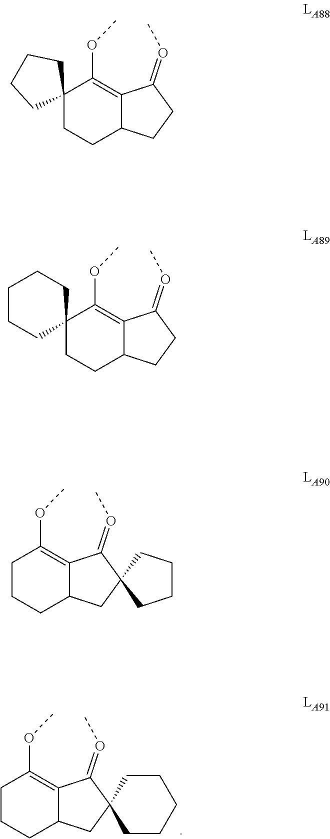

11. The compound according to claim 5, wherein, in the structure represented by Ir(L_{A})(L_{B})₂, L_{A} is selected from the group consisting of the following structures:

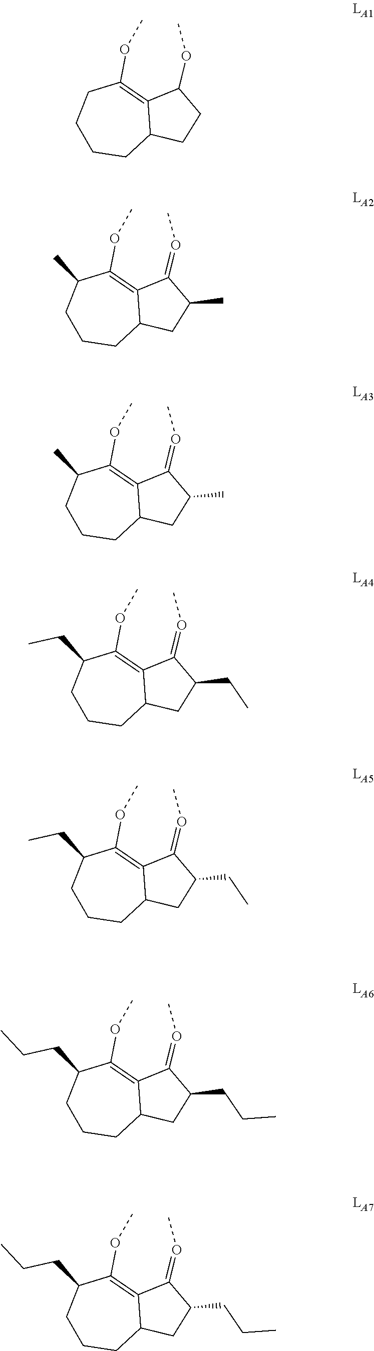

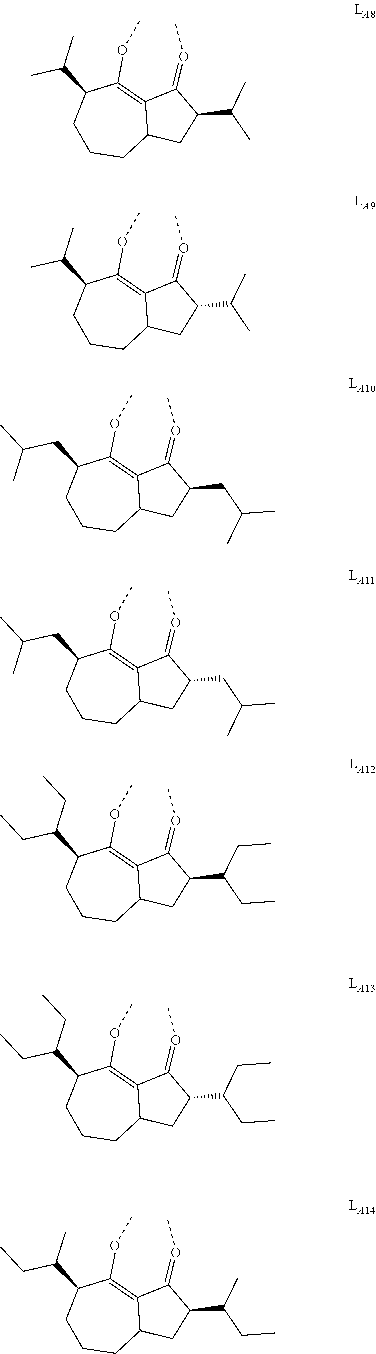

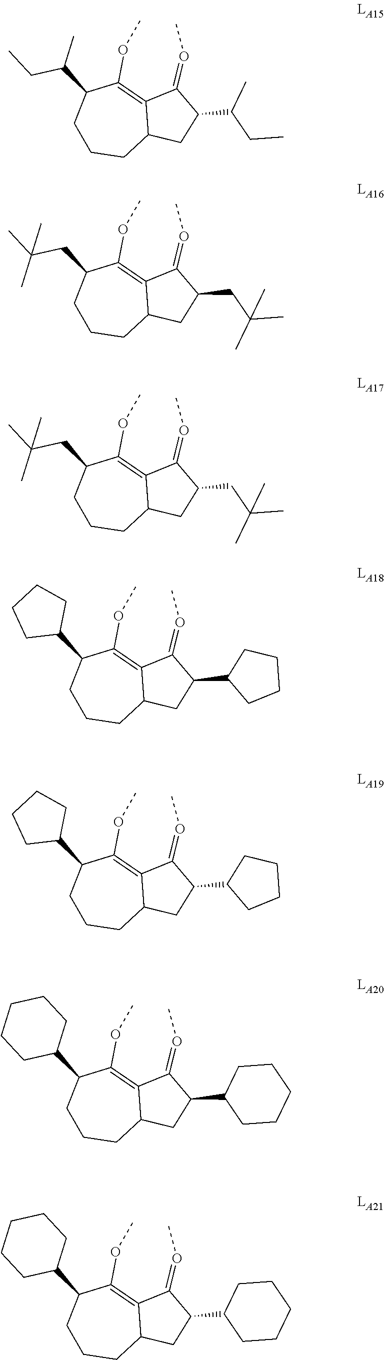

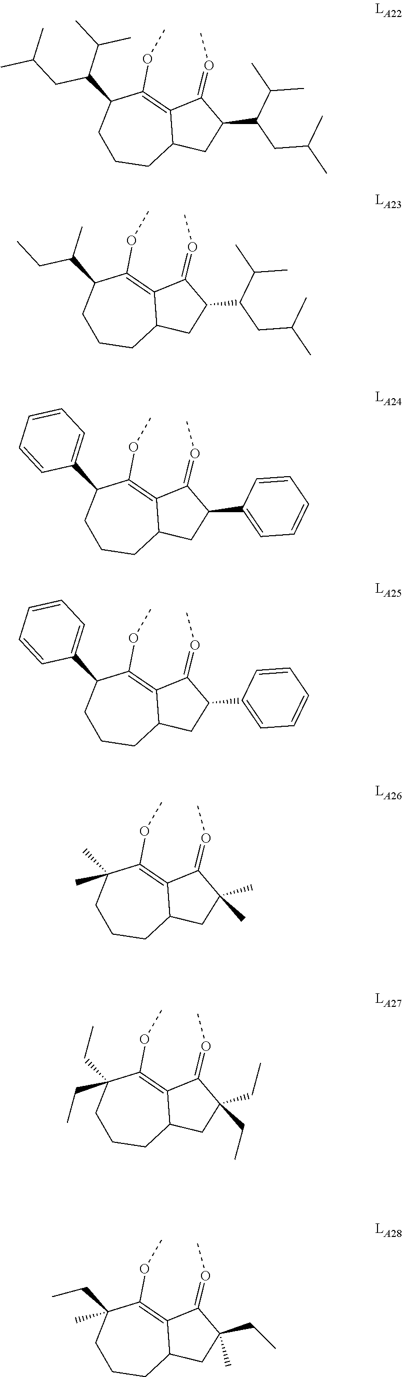

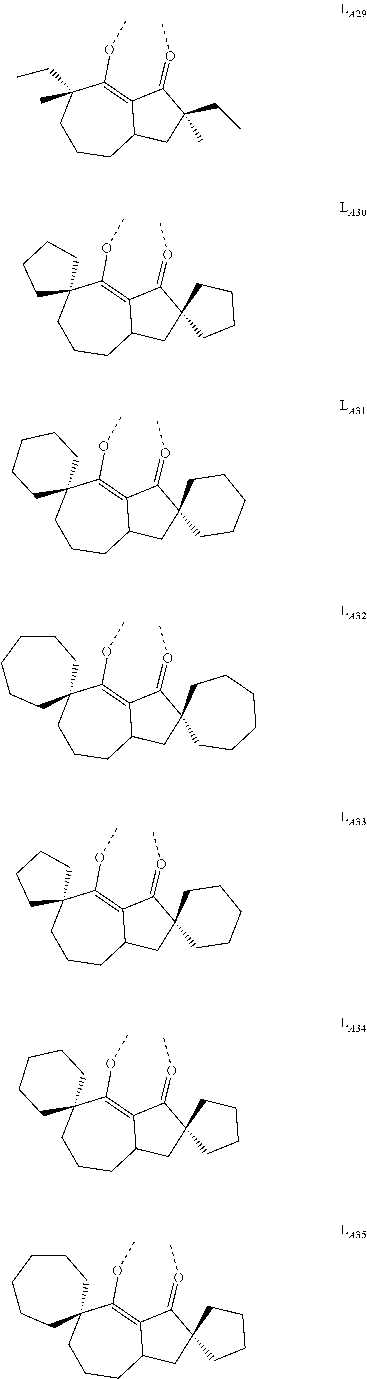

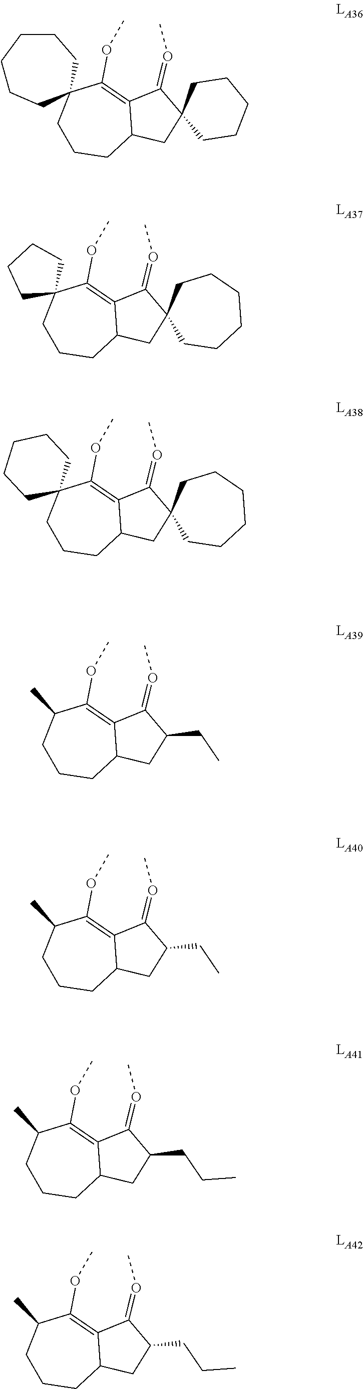

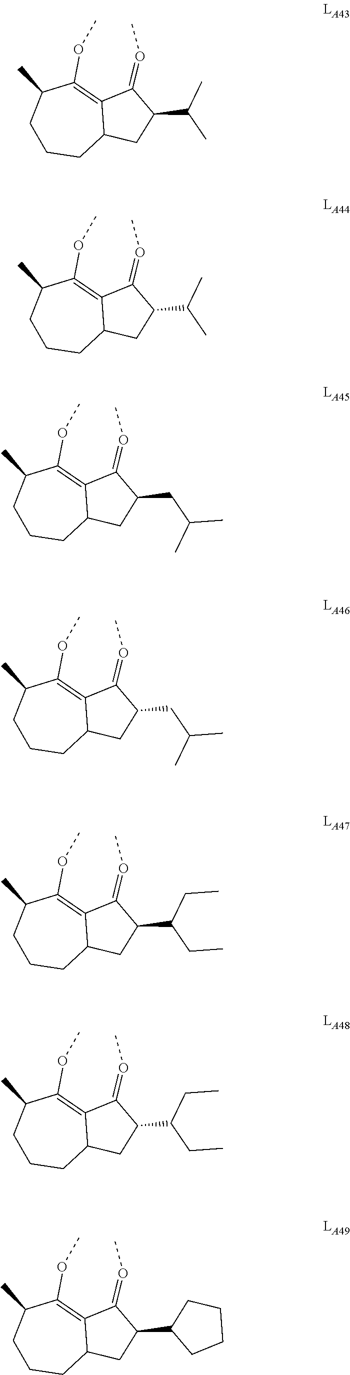

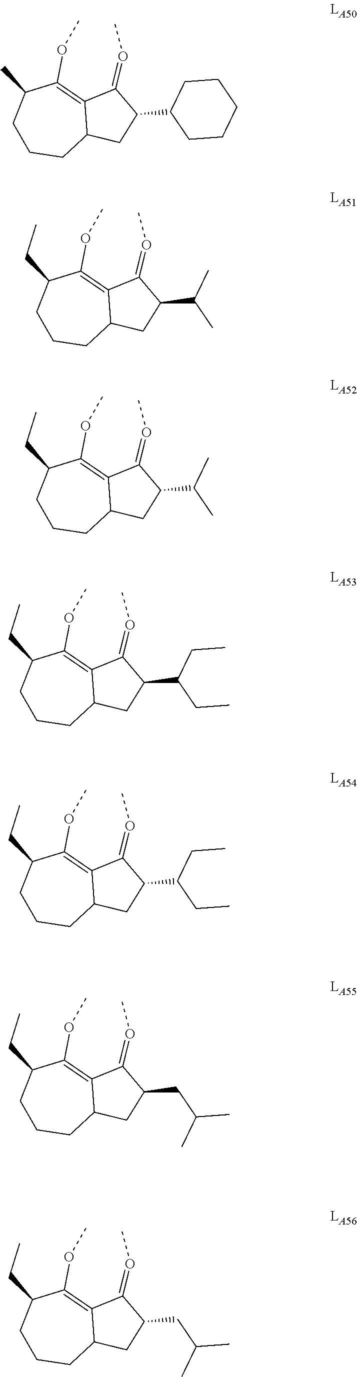

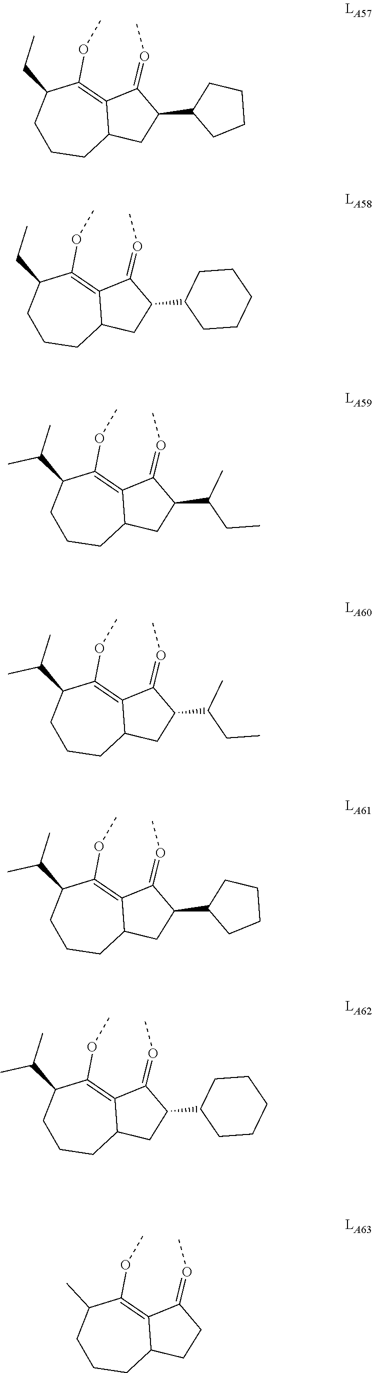

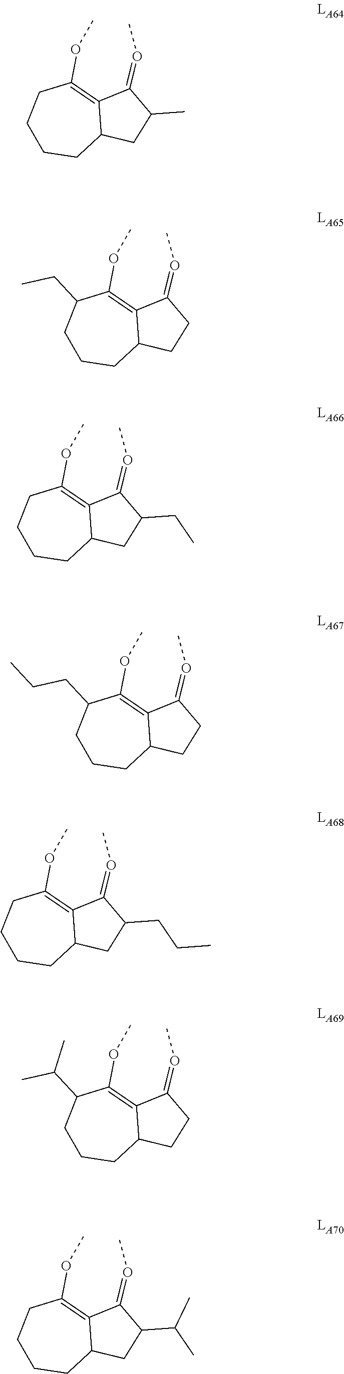

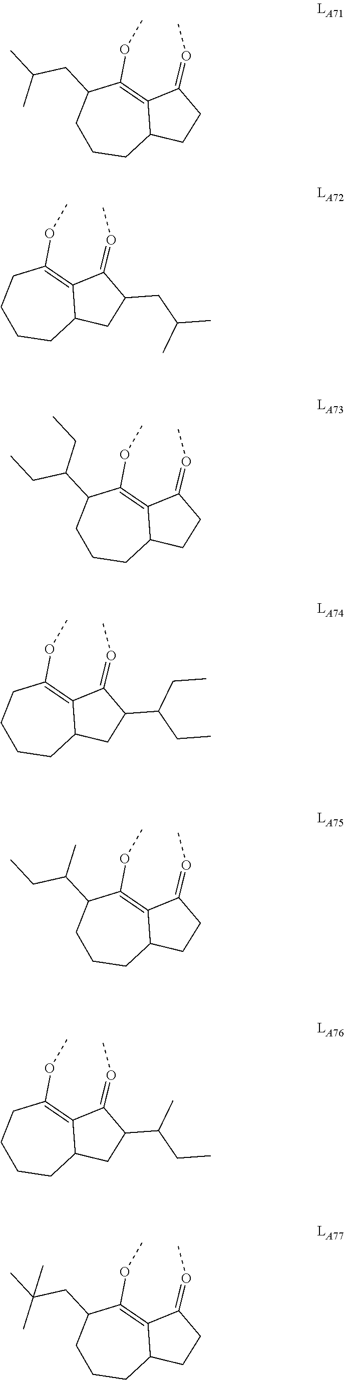

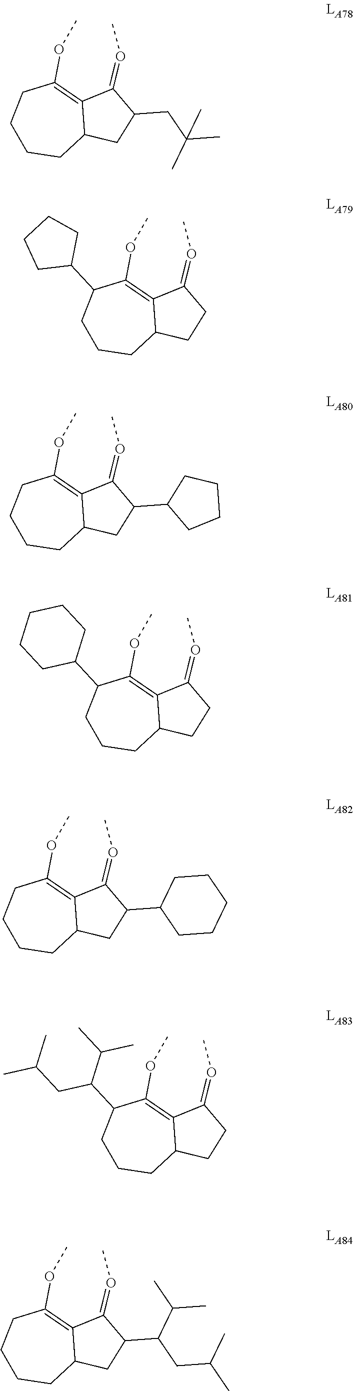

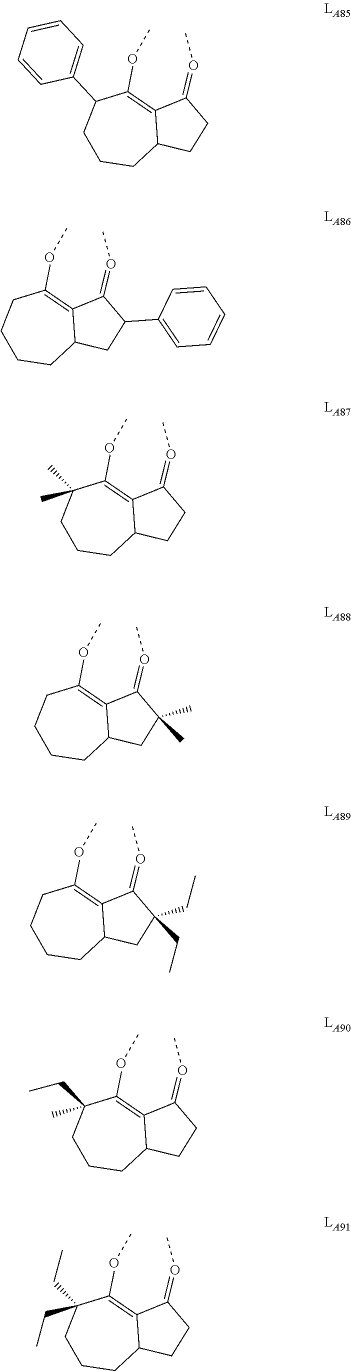

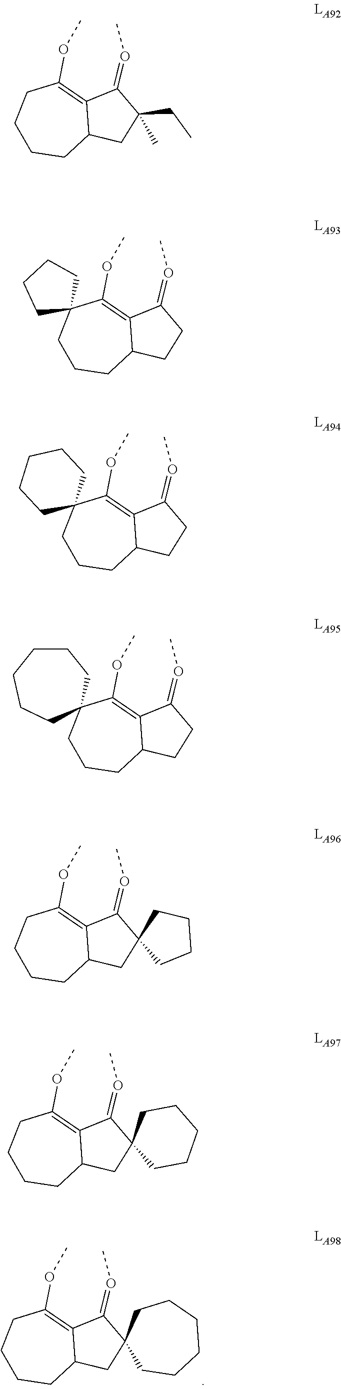

12. The compound according to claim 1, wherein, in the structure represented by Ir(L_{A})(L_{B})₂, L_{B} is selected from the group consisting of the following structures:

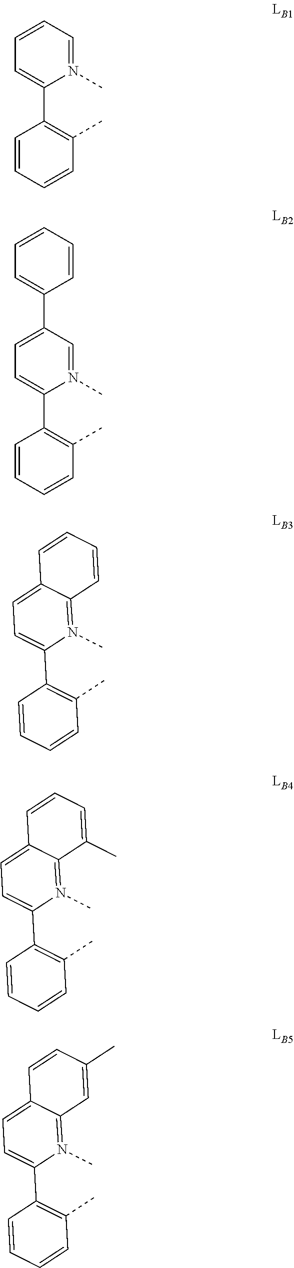

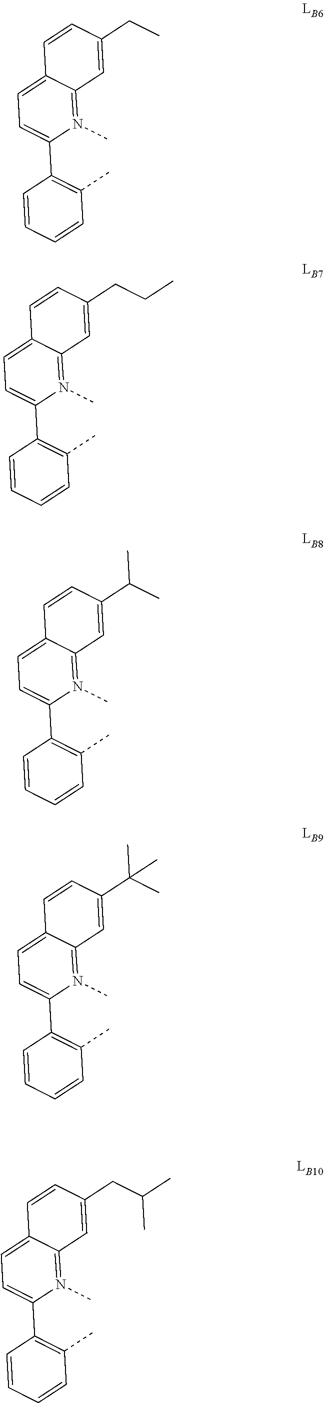

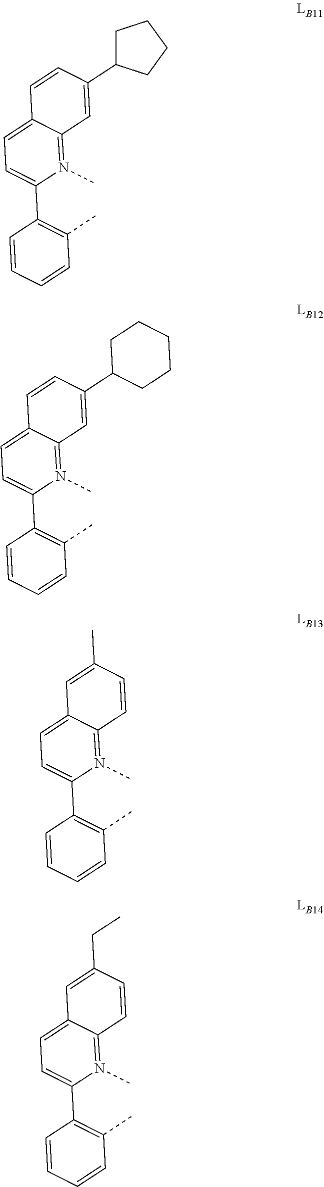

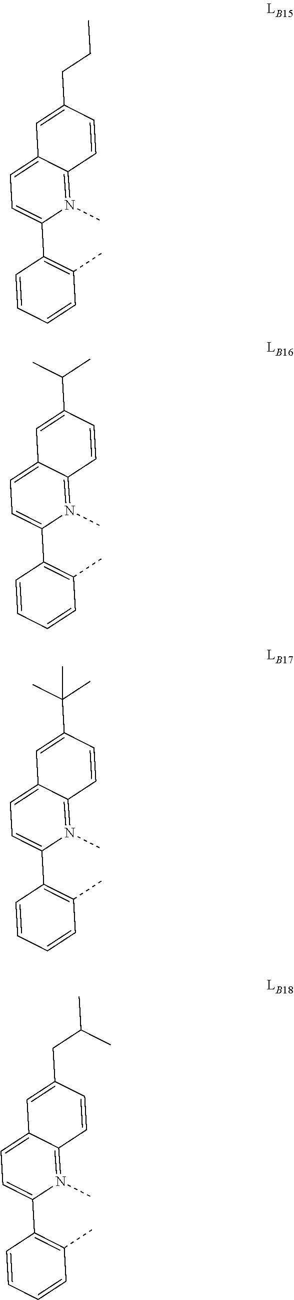

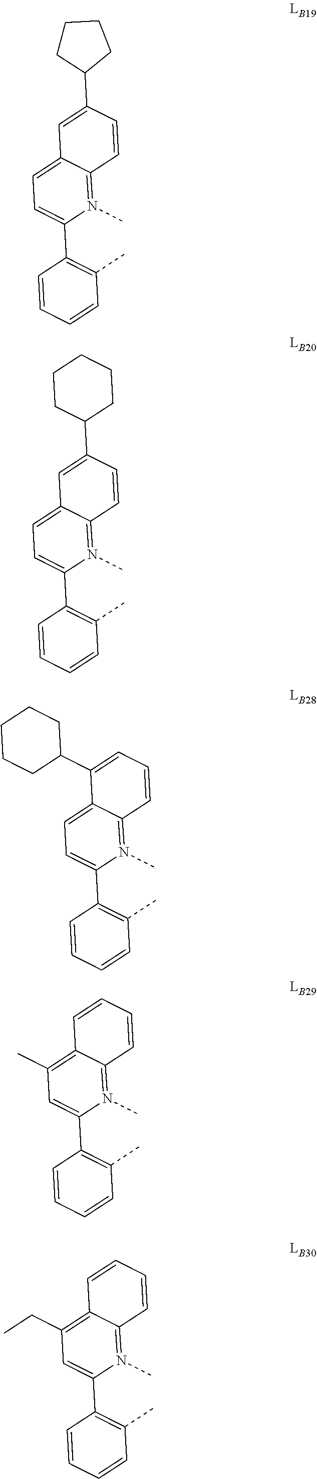

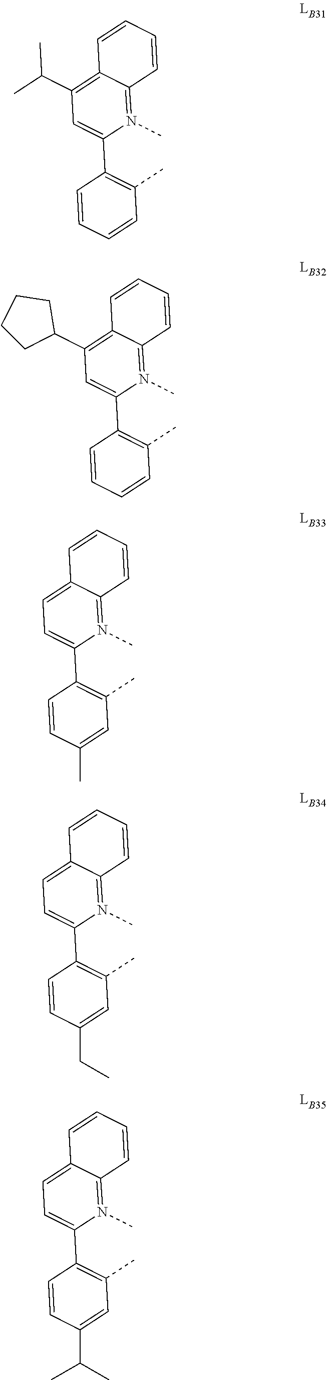

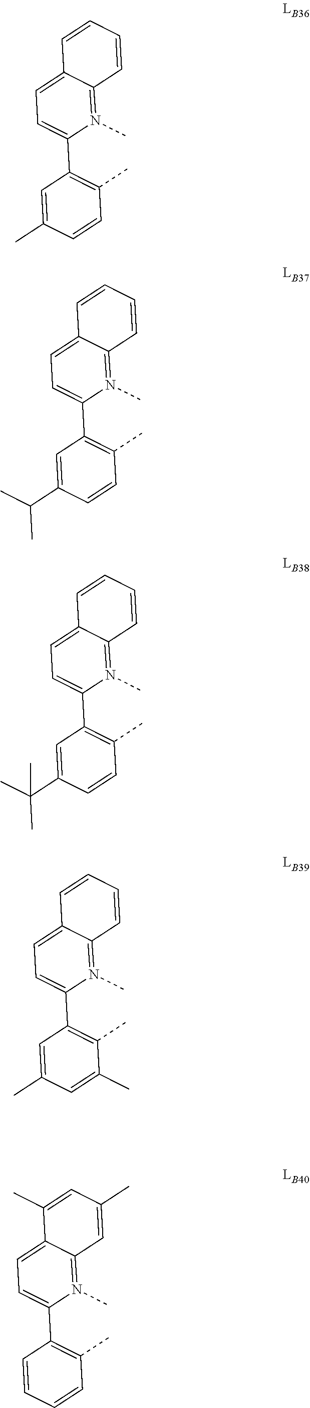

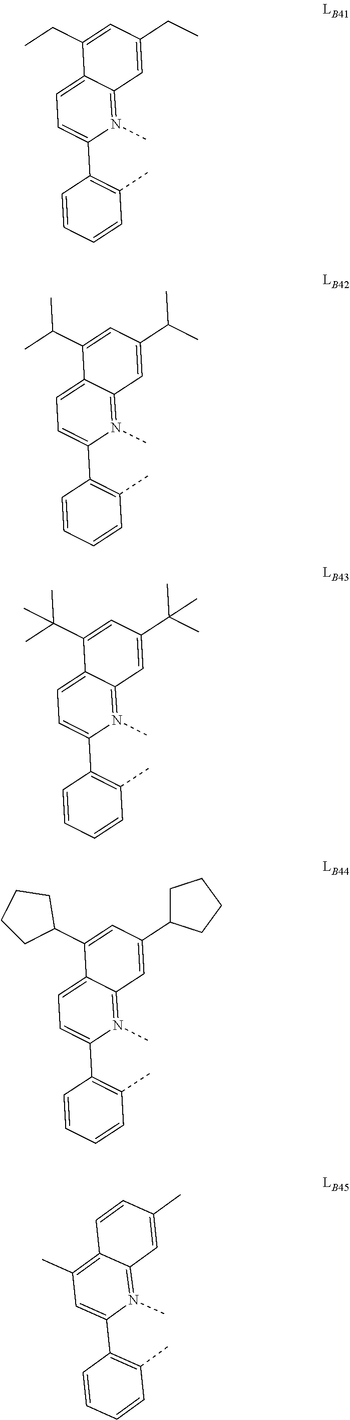

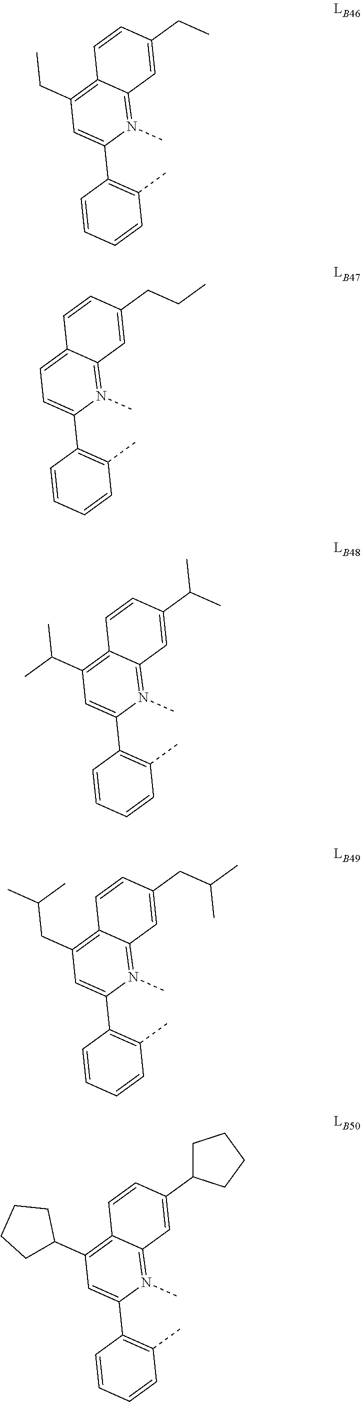

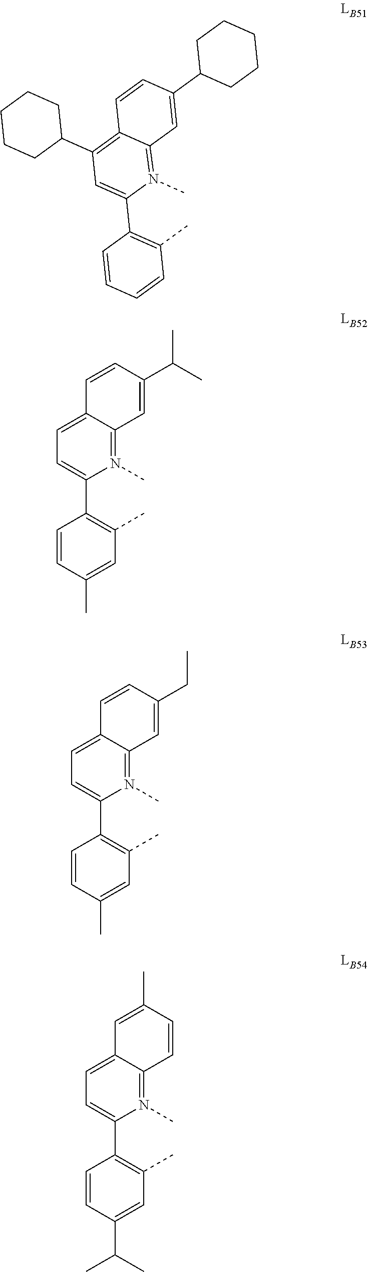

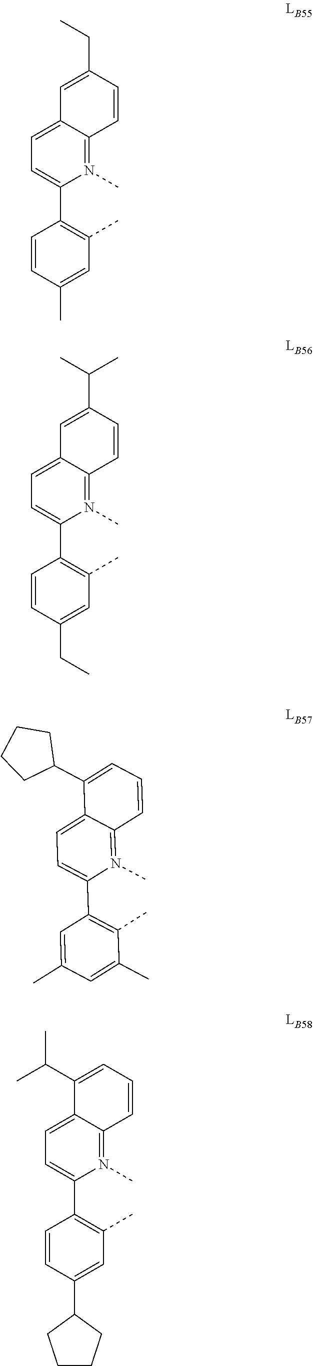

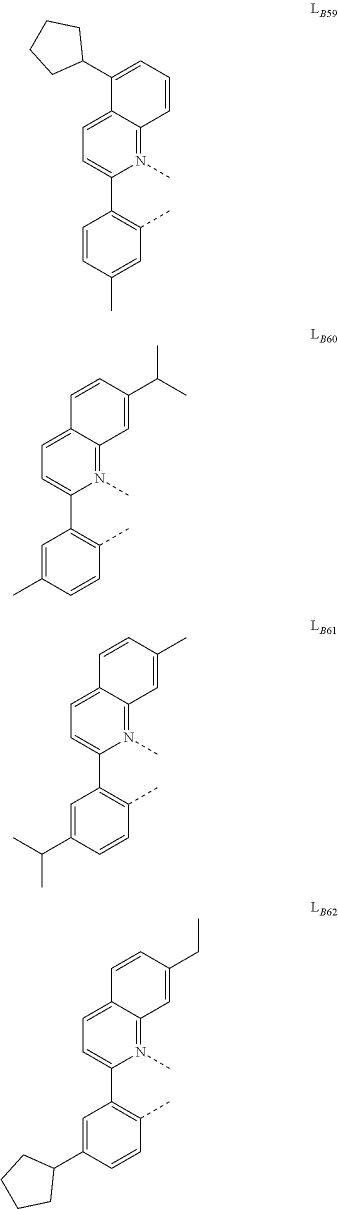

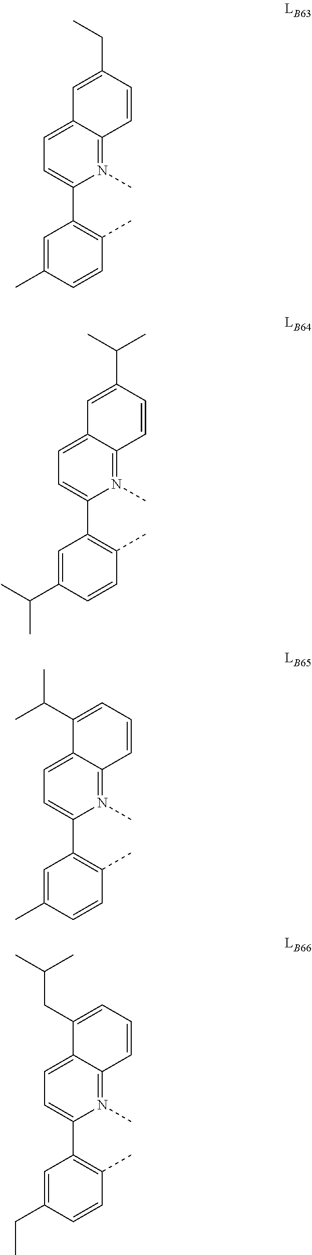

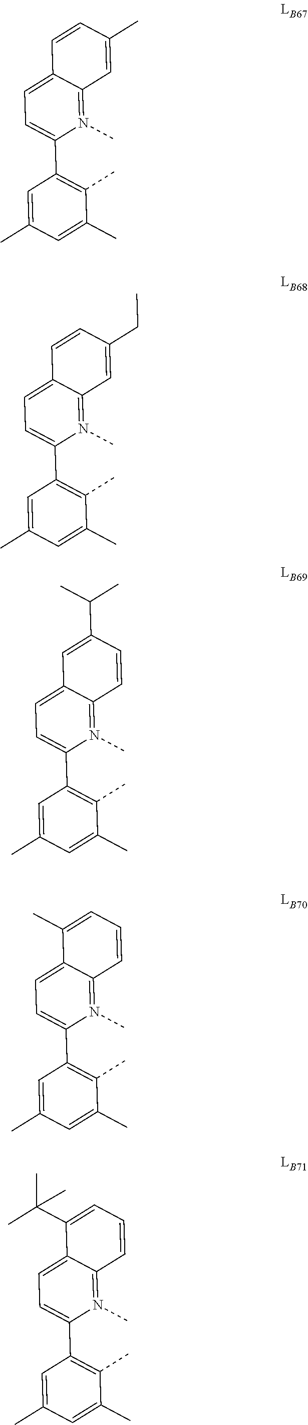

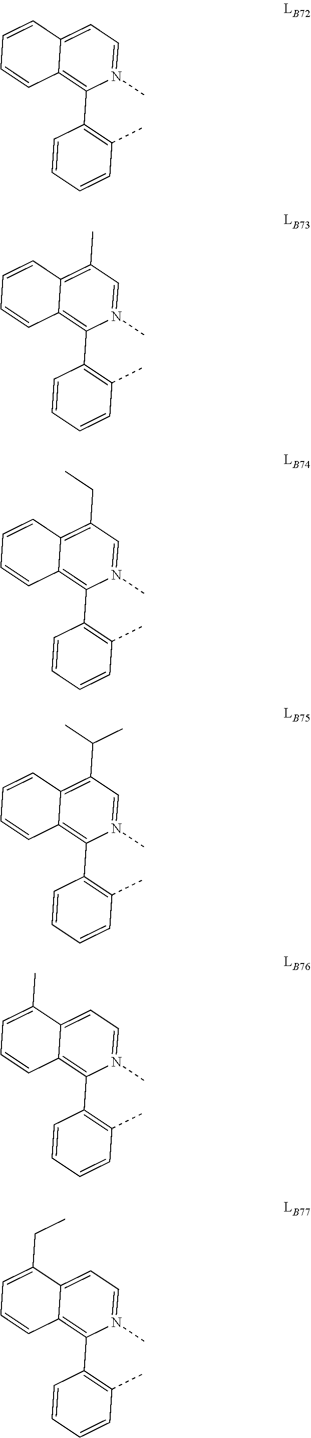

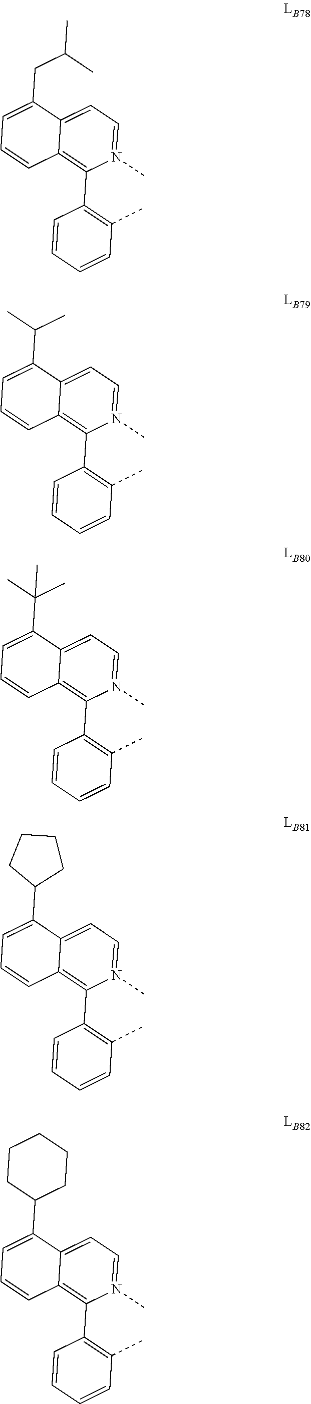

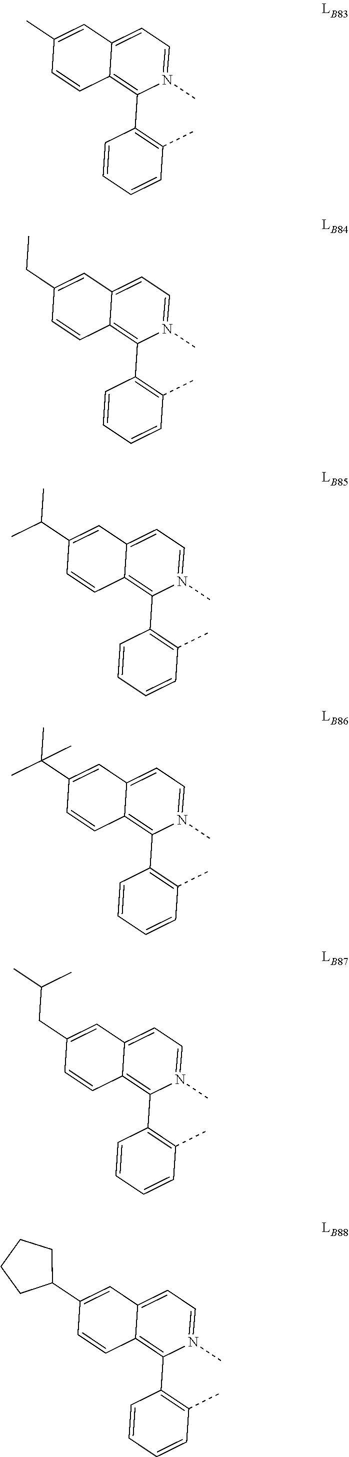

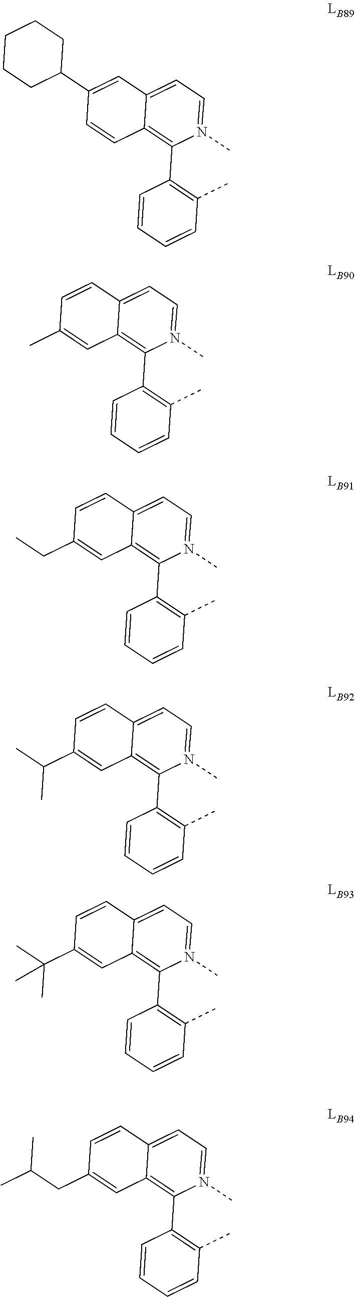

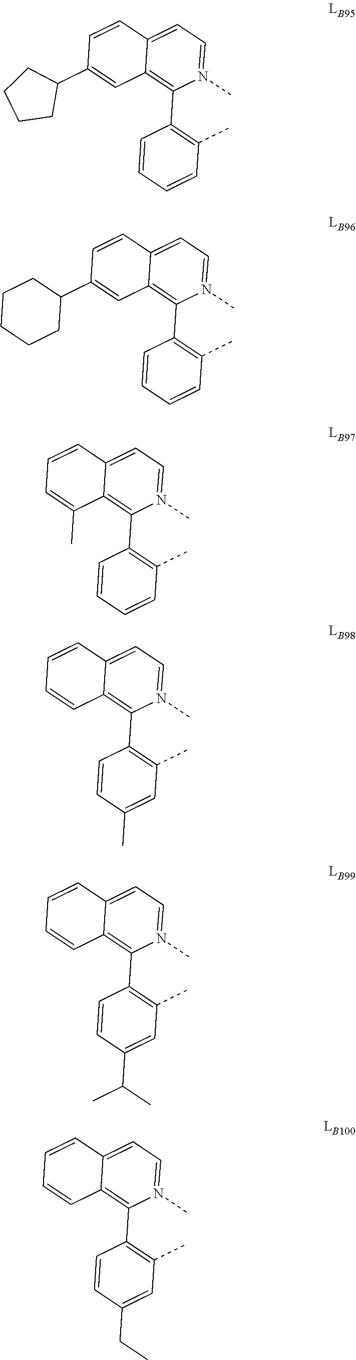

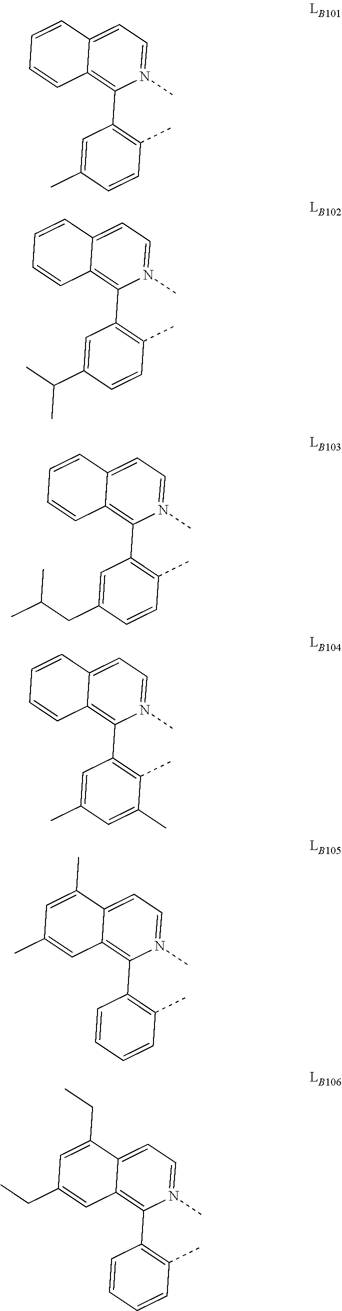

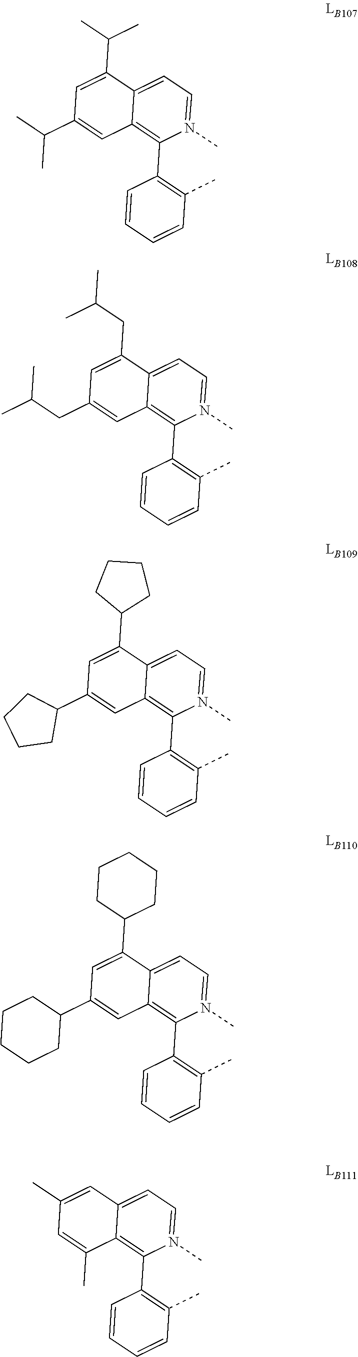

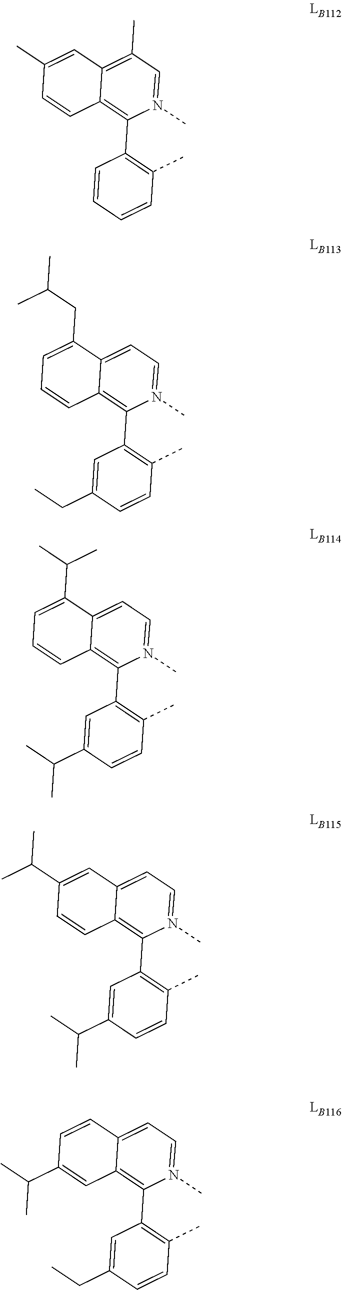

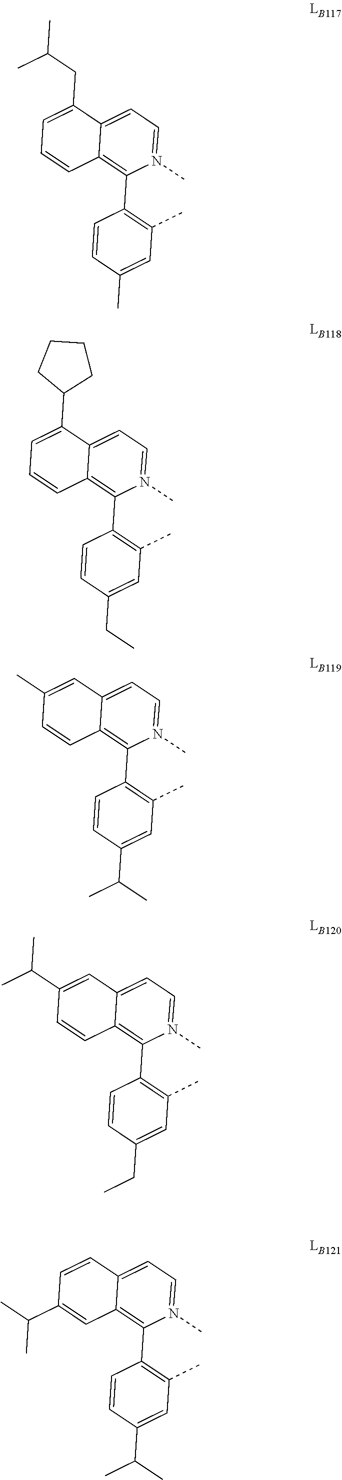

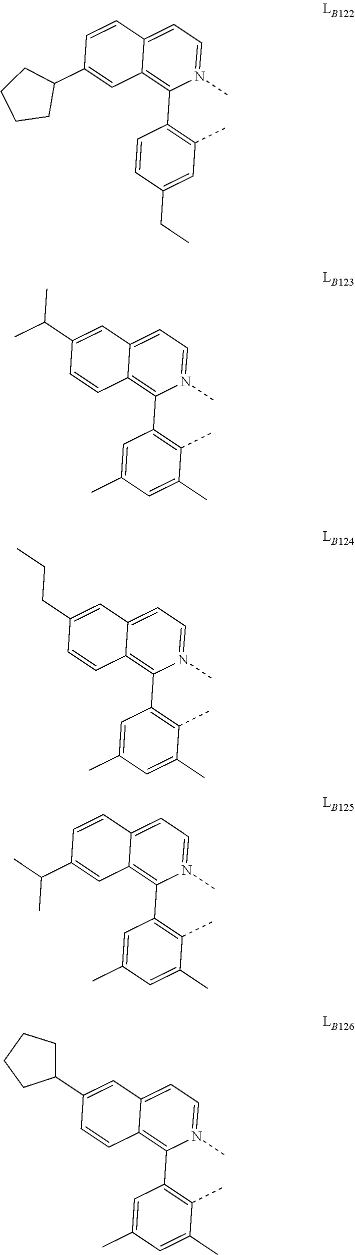

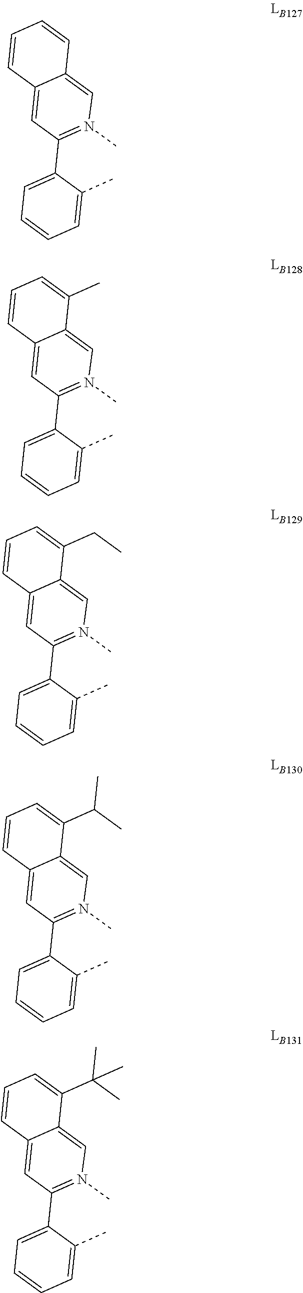

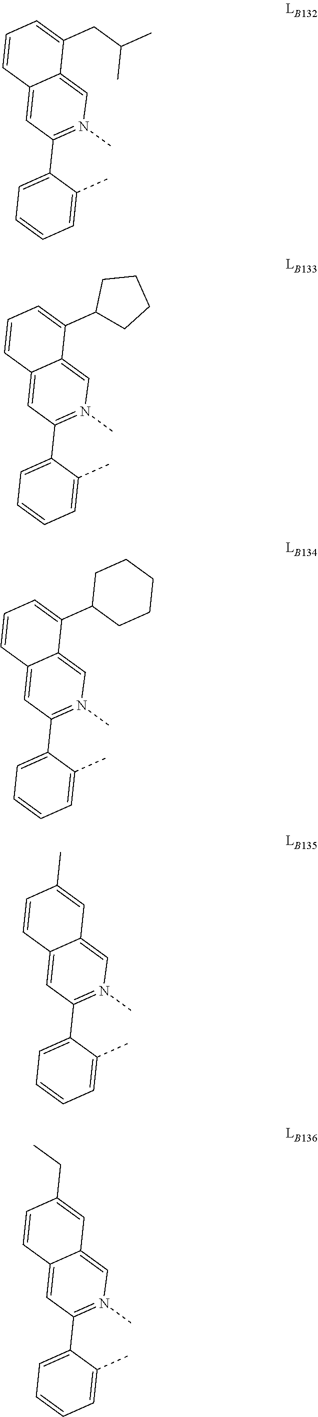

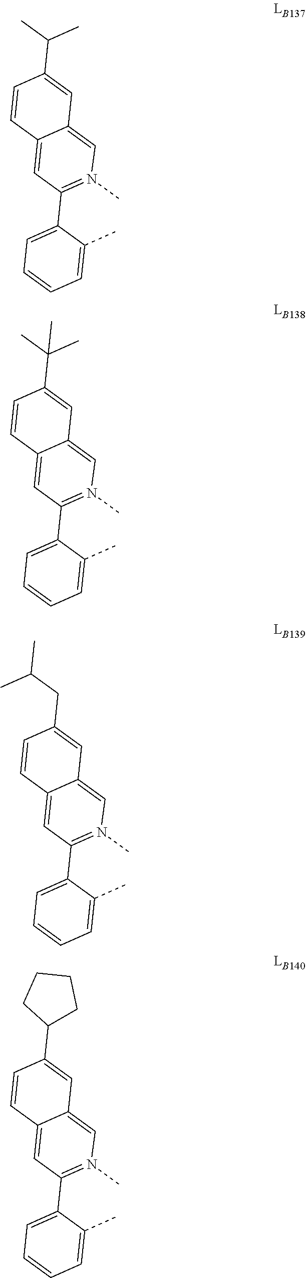

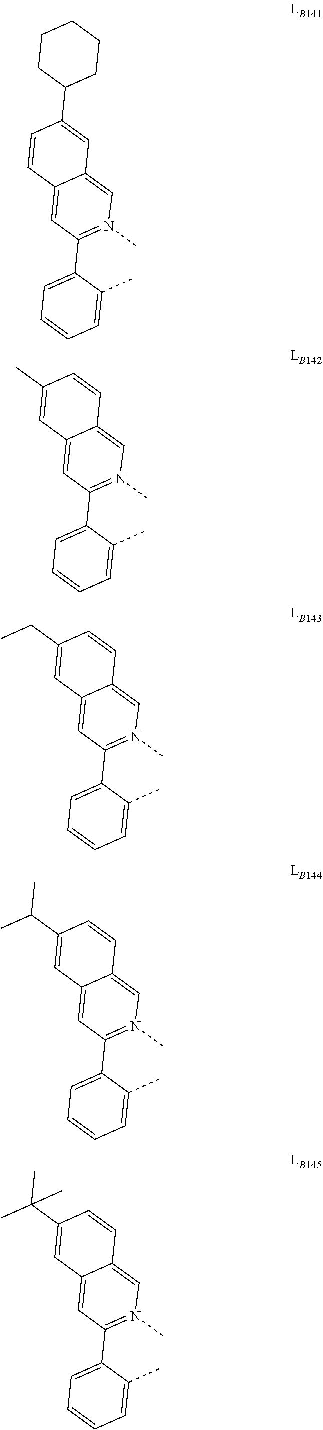

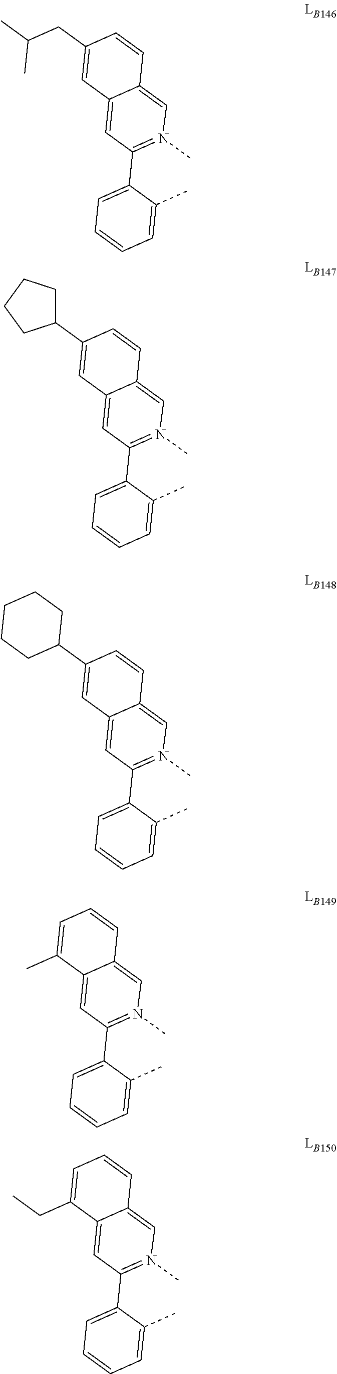

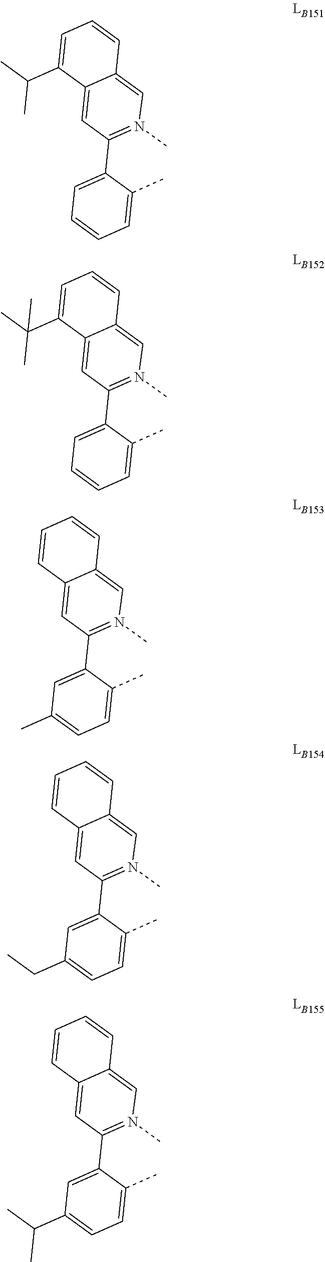

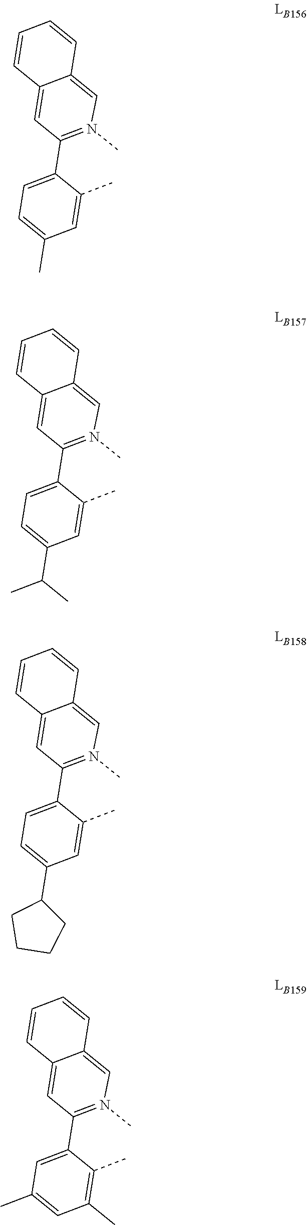

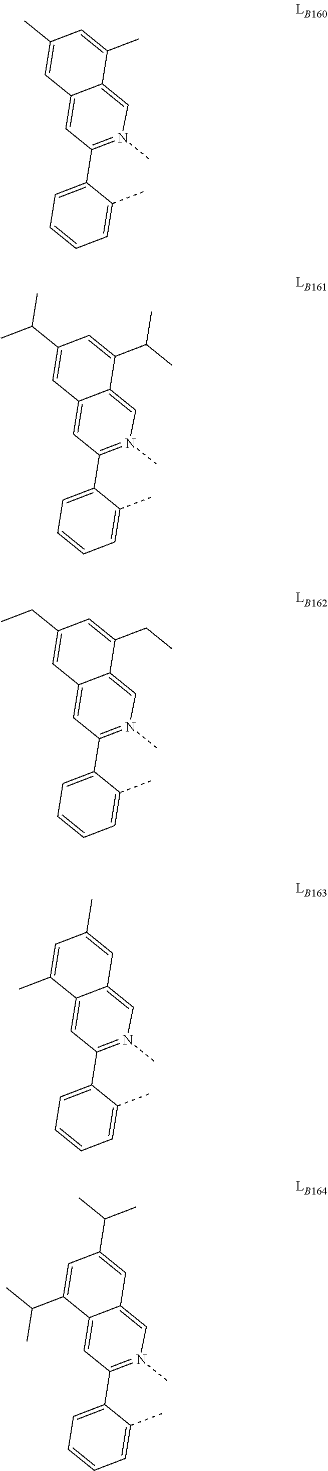

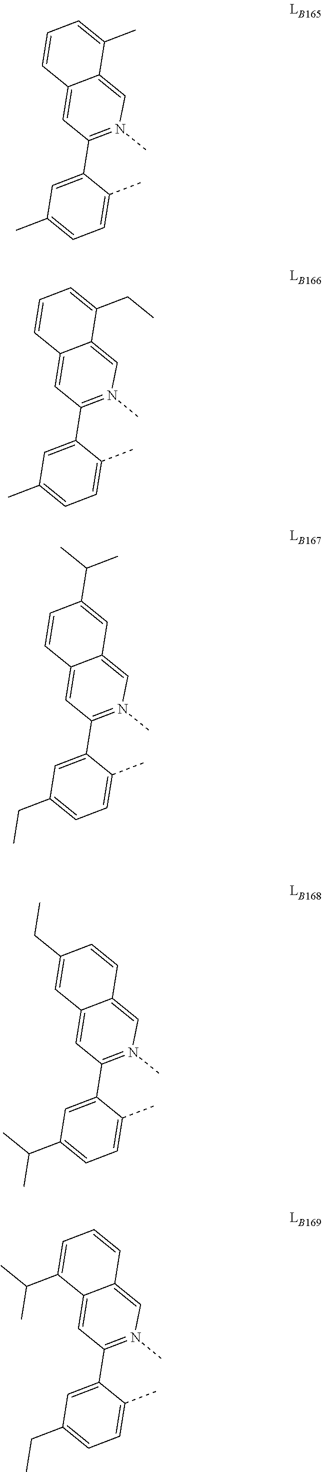

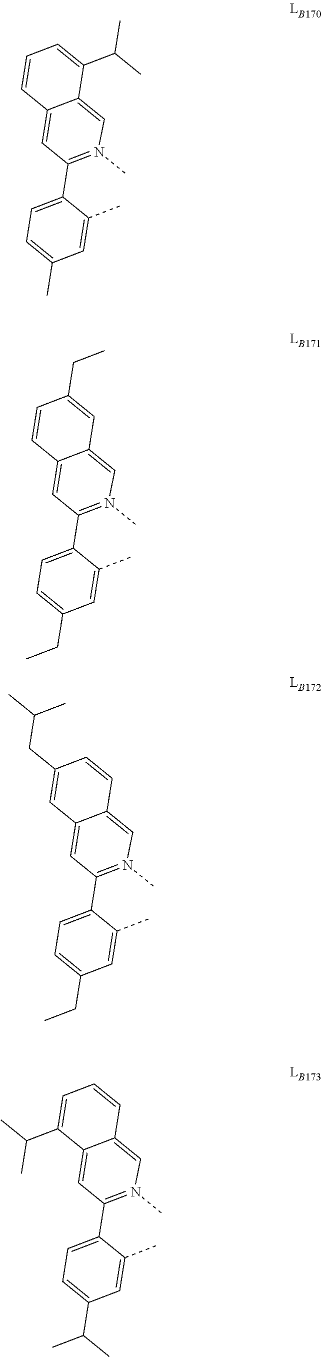

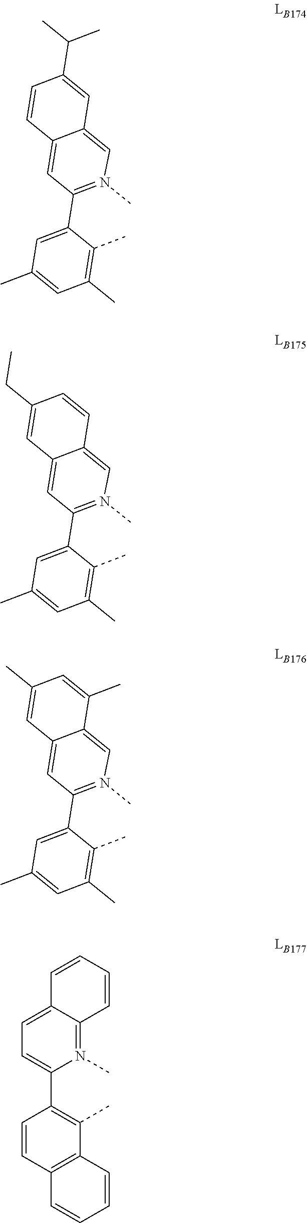

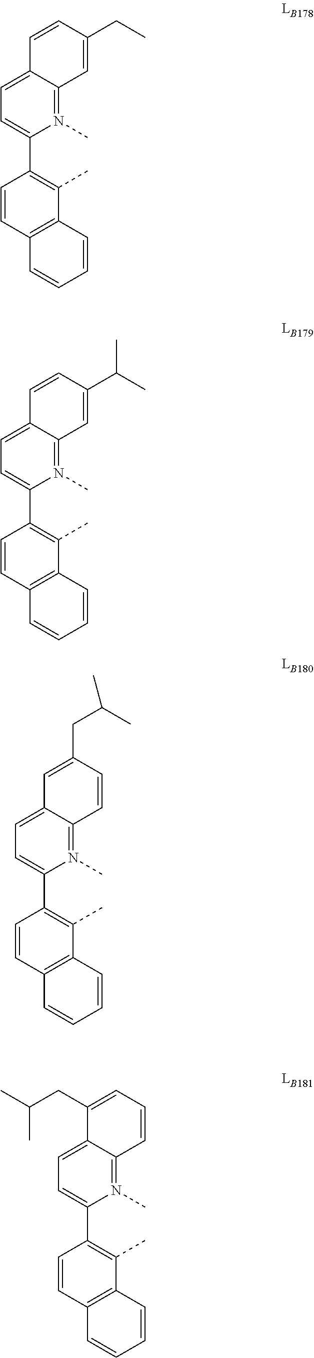

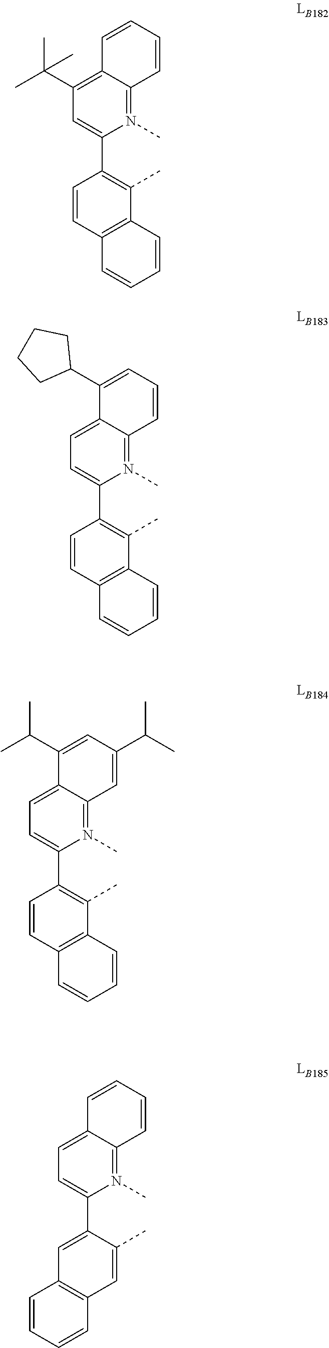

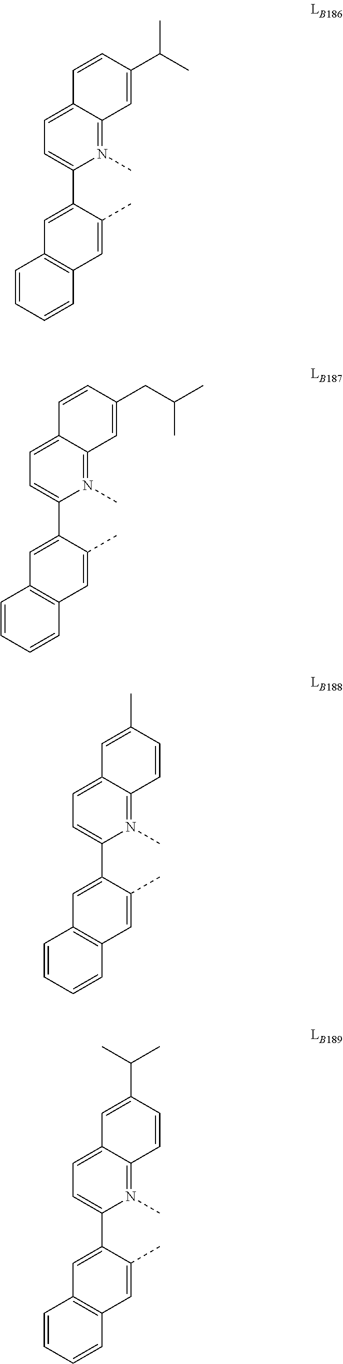

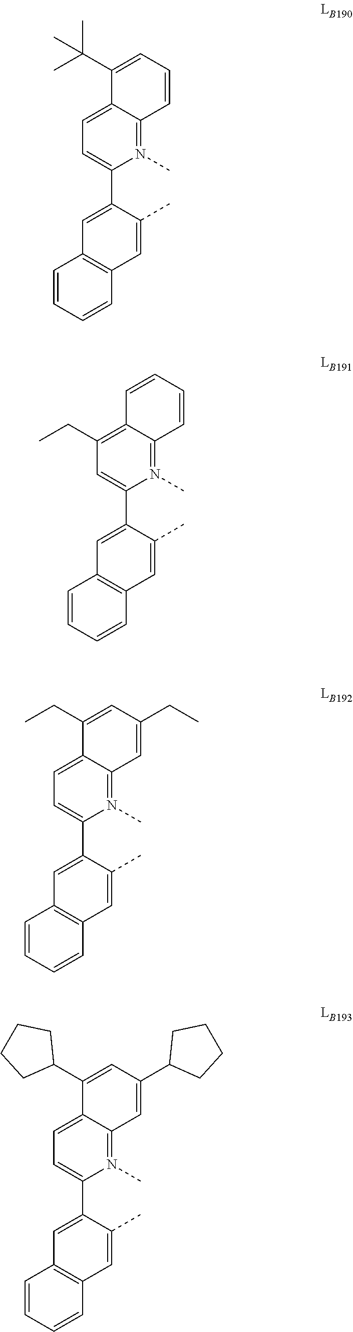

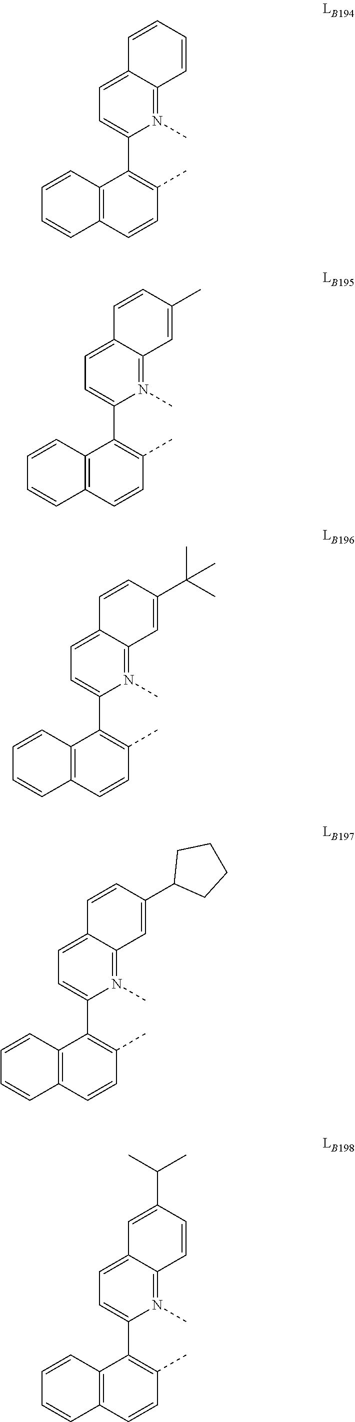

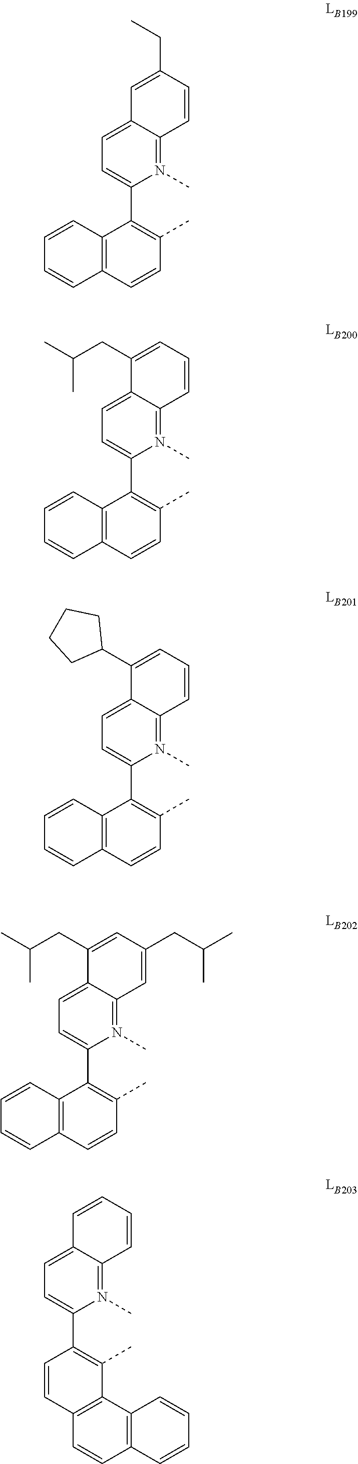

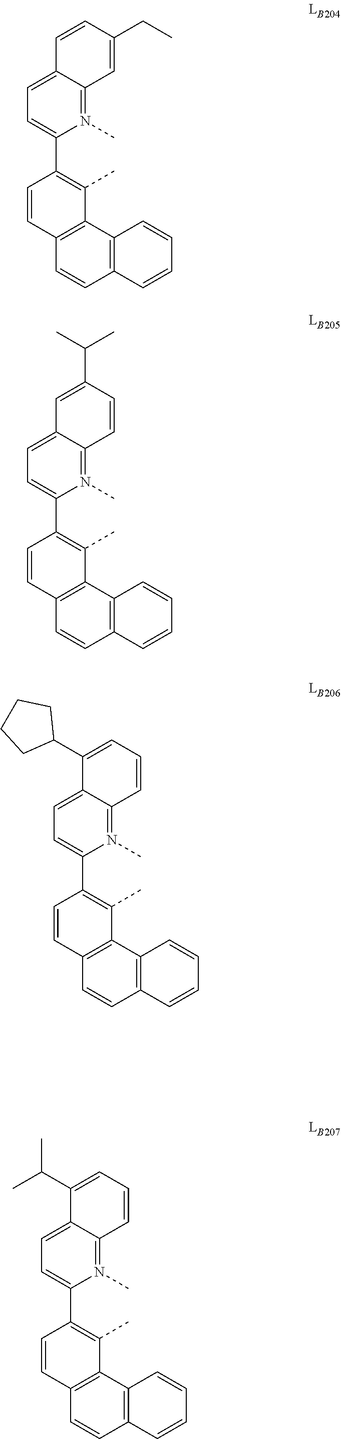

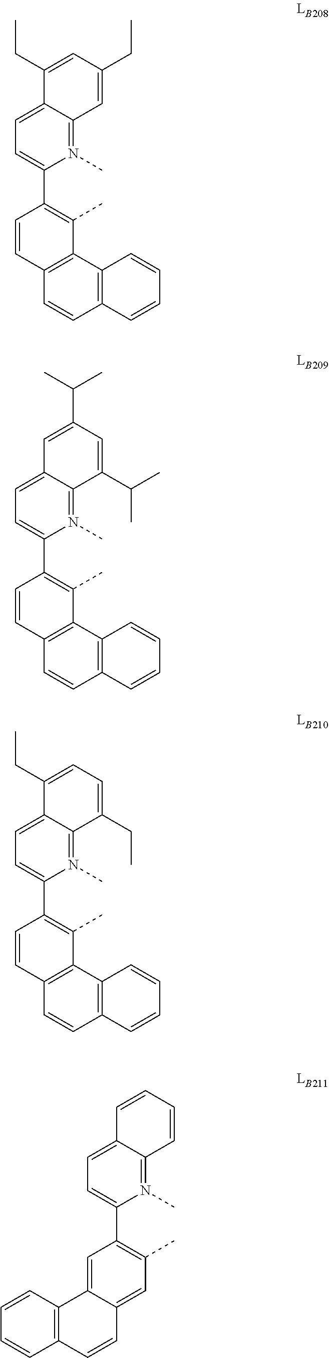

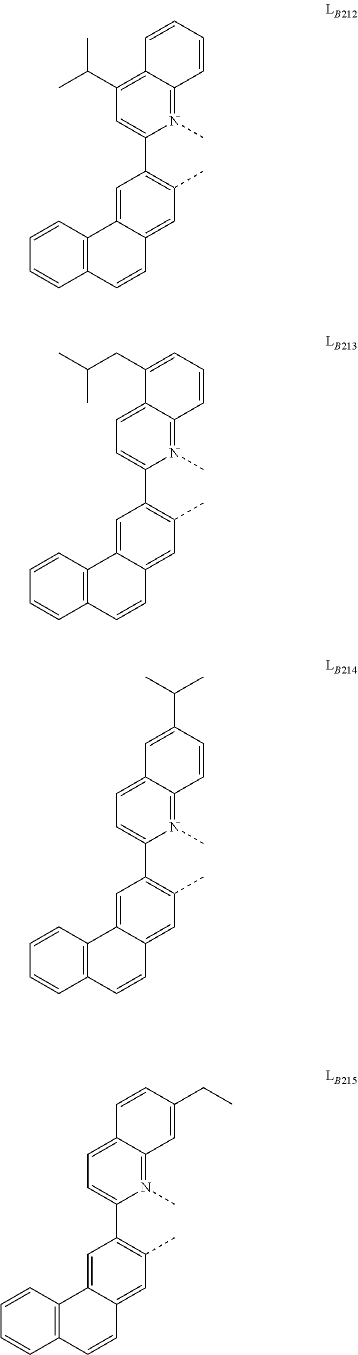

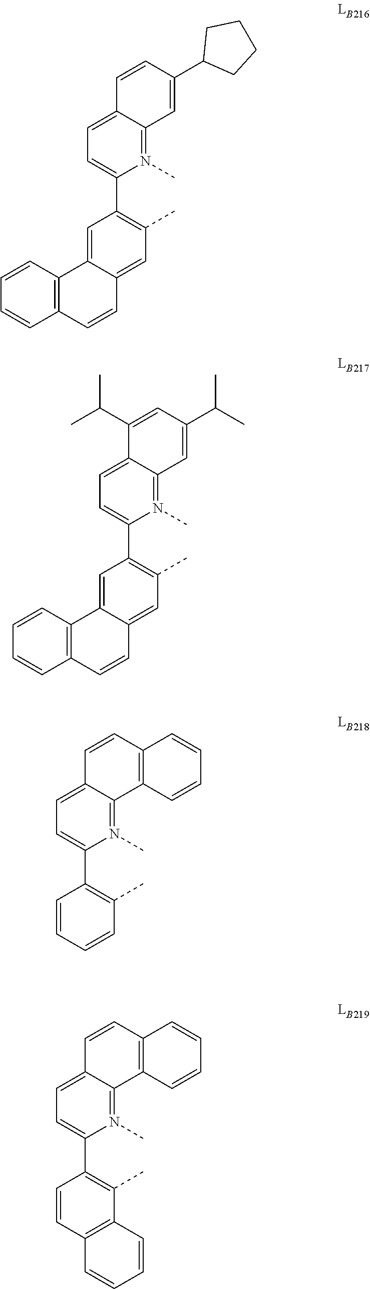

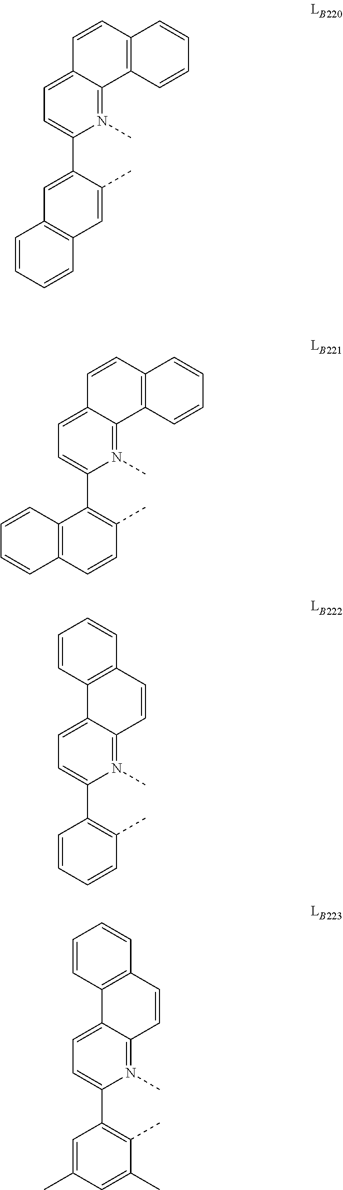

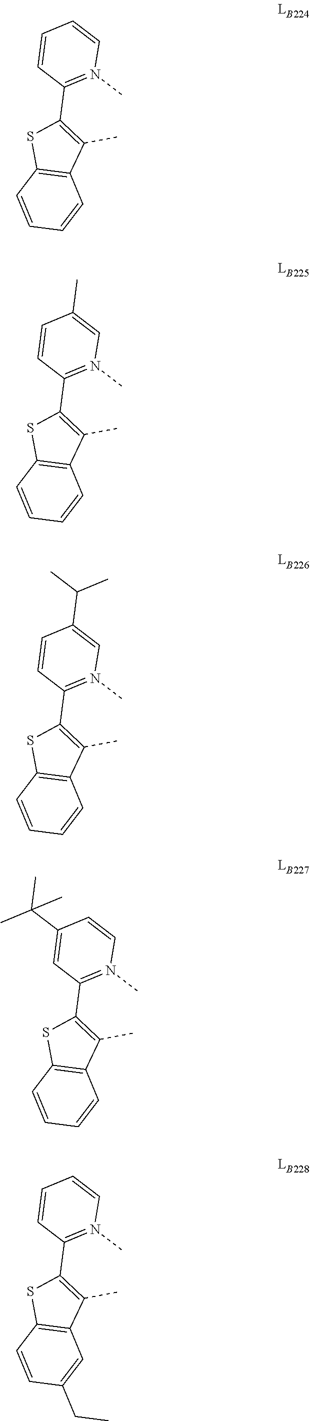

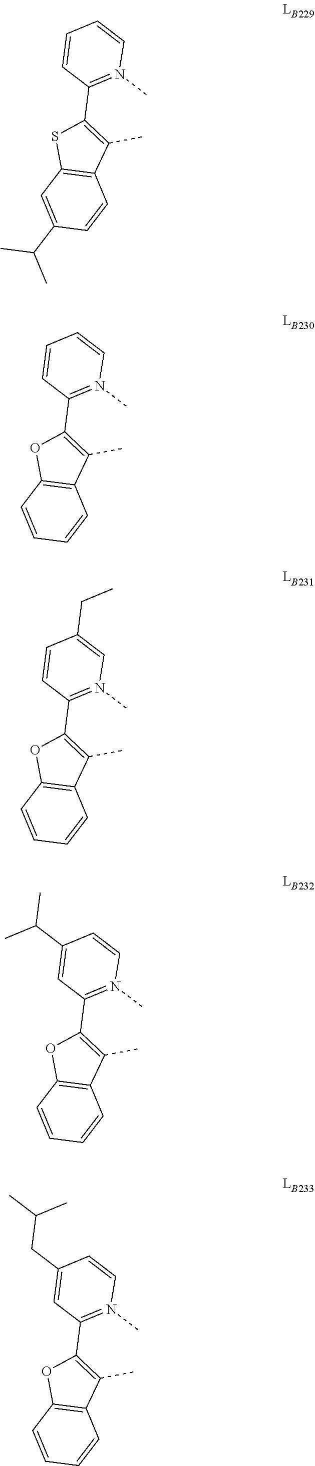

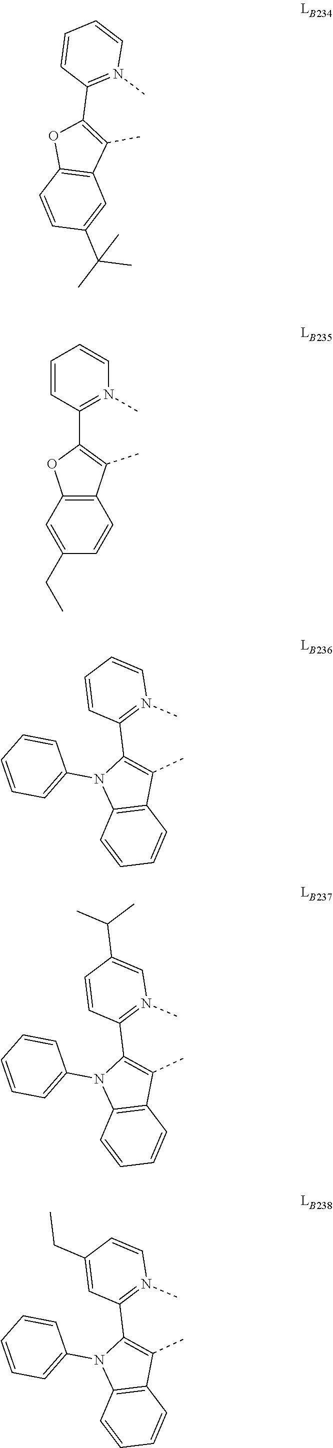

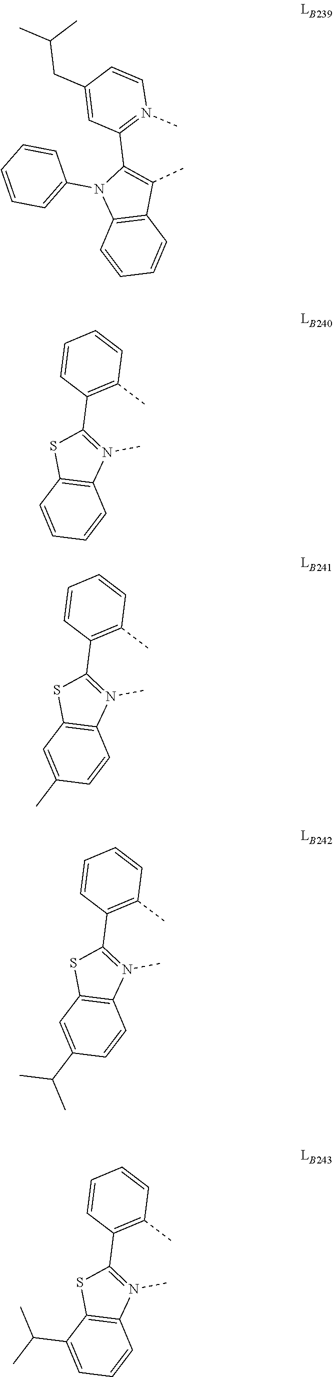

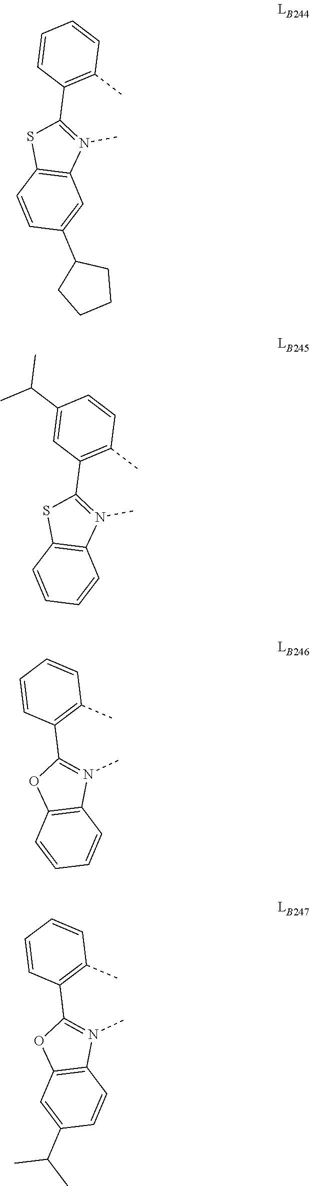

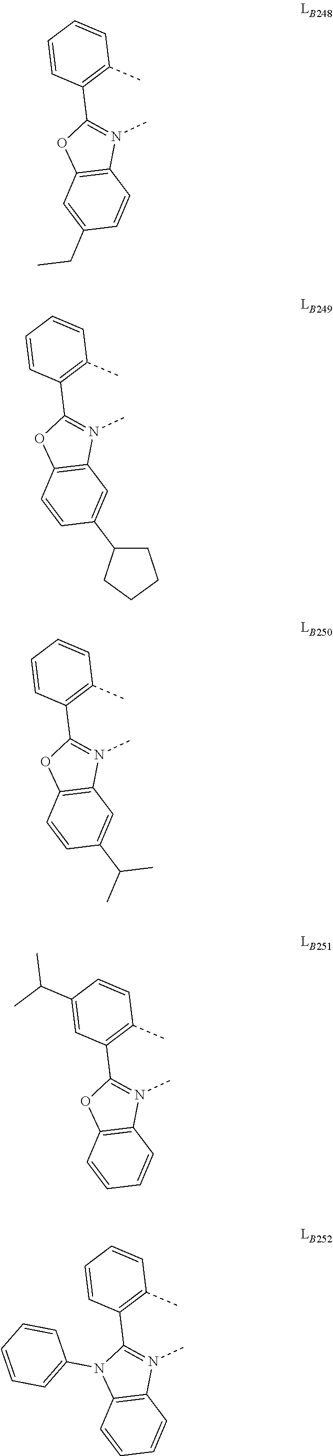

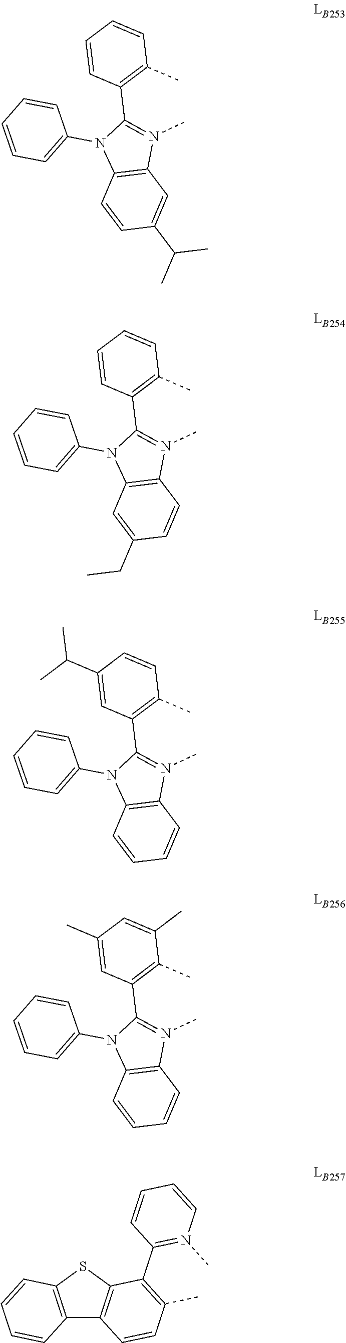

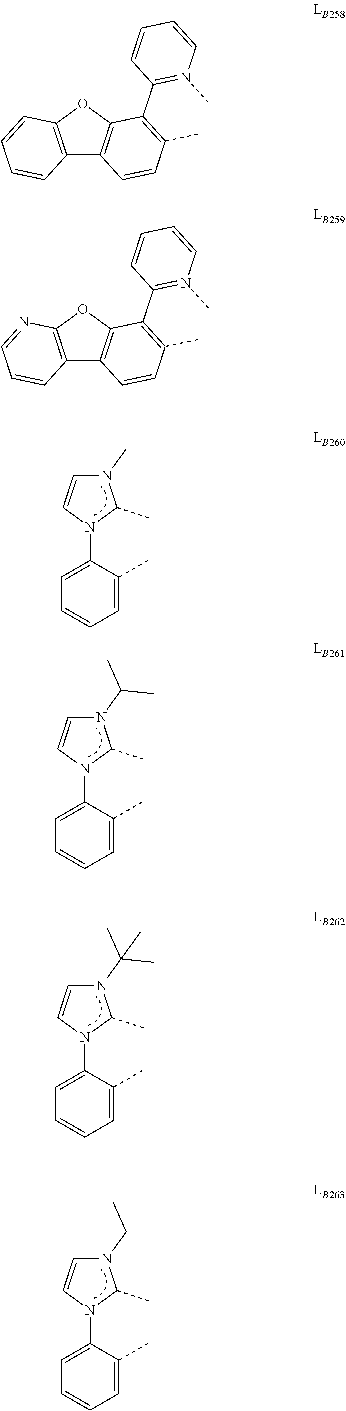

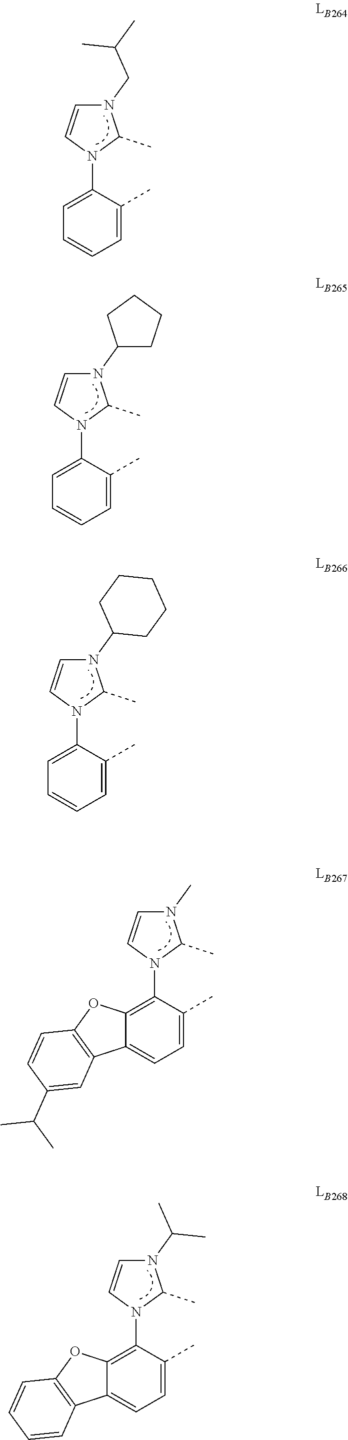

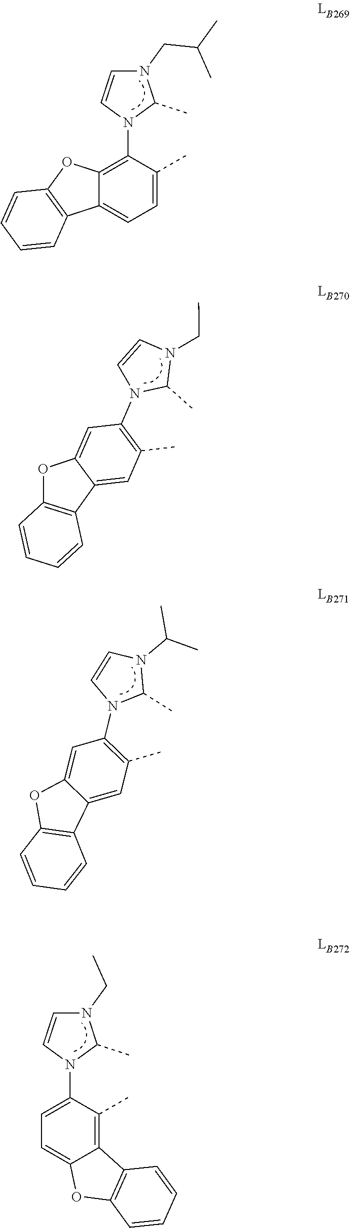

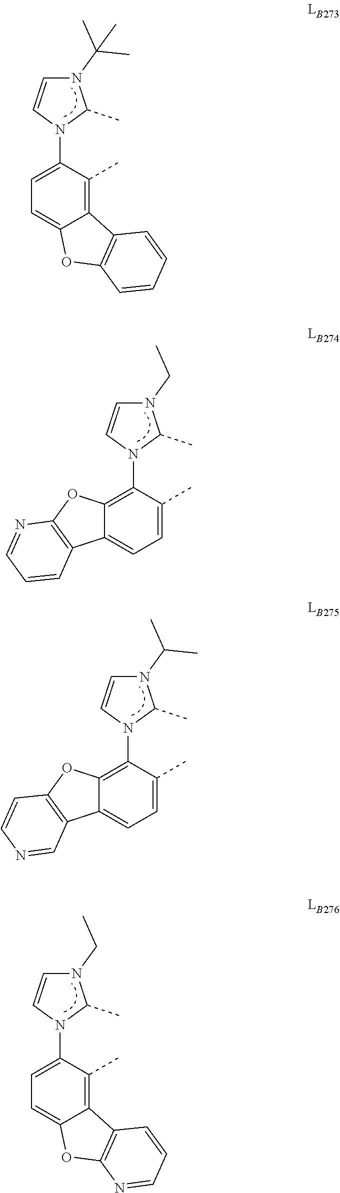

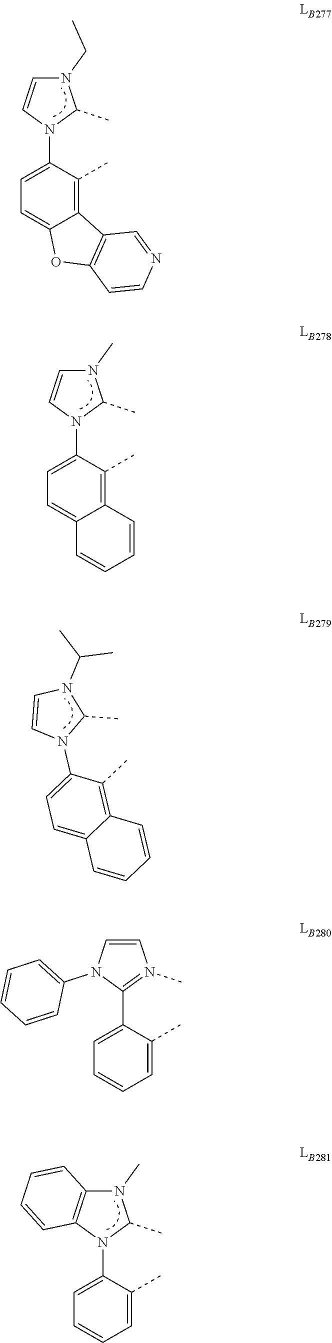

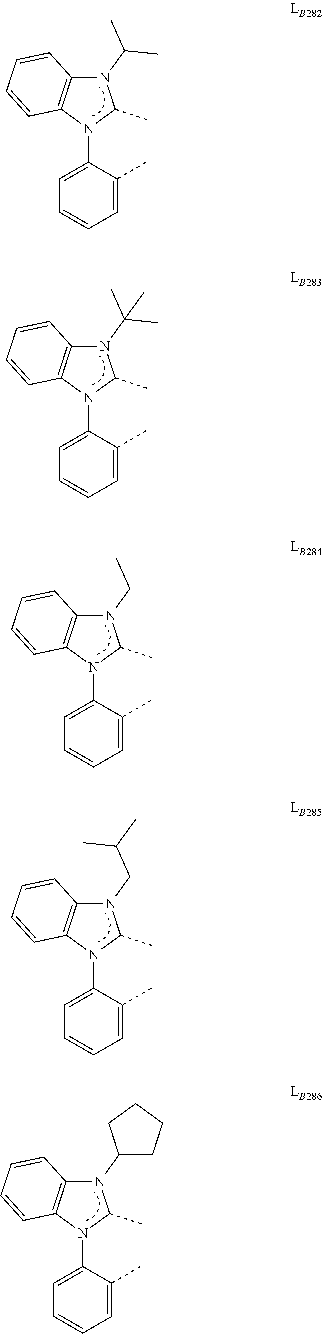

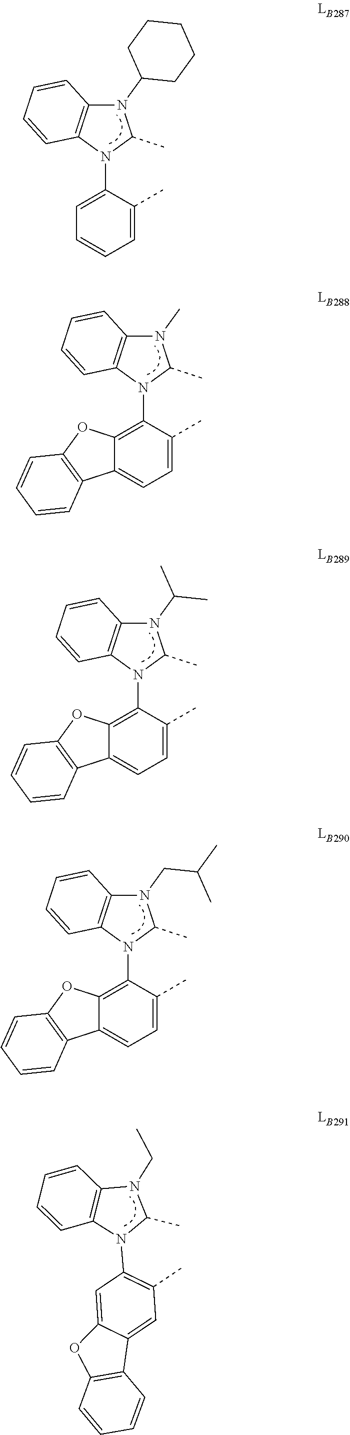

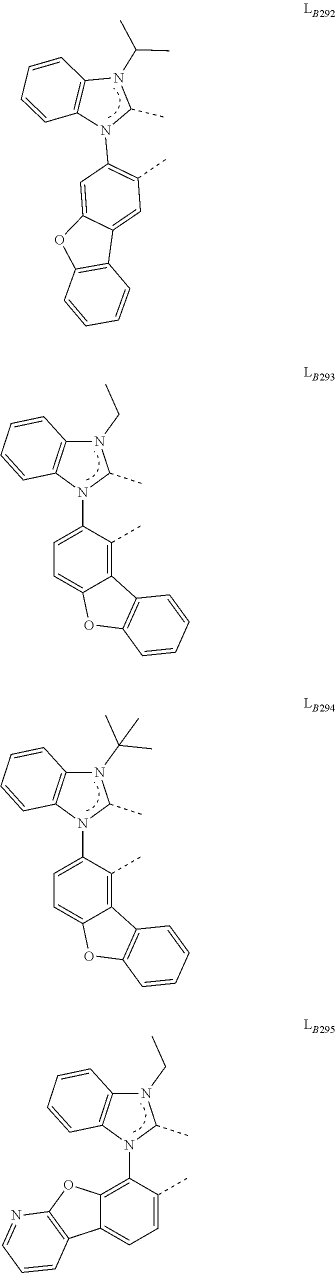

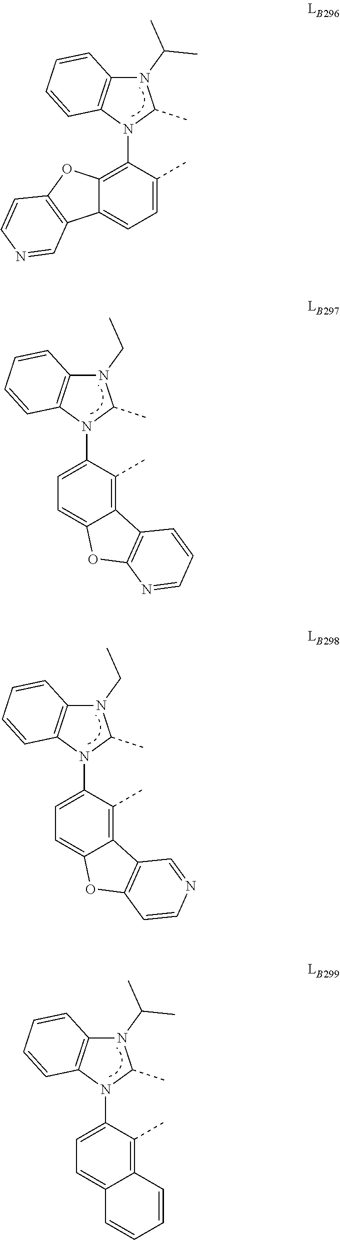

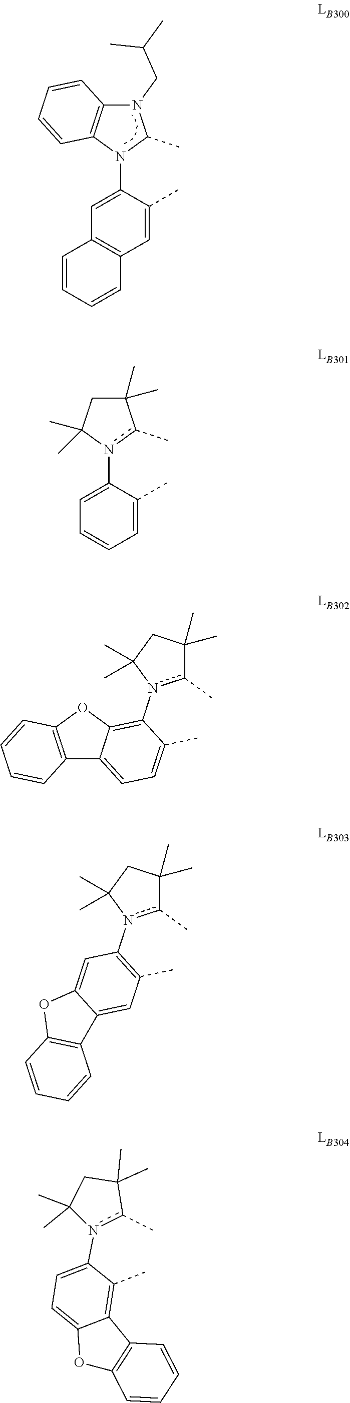

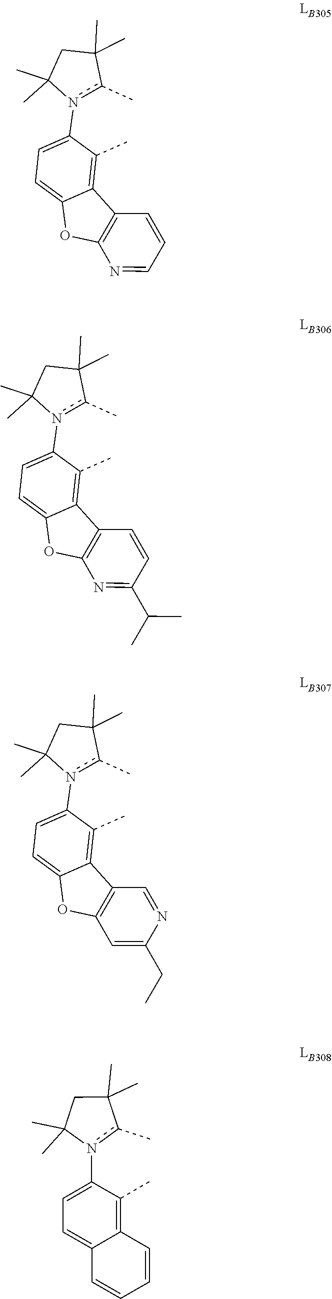

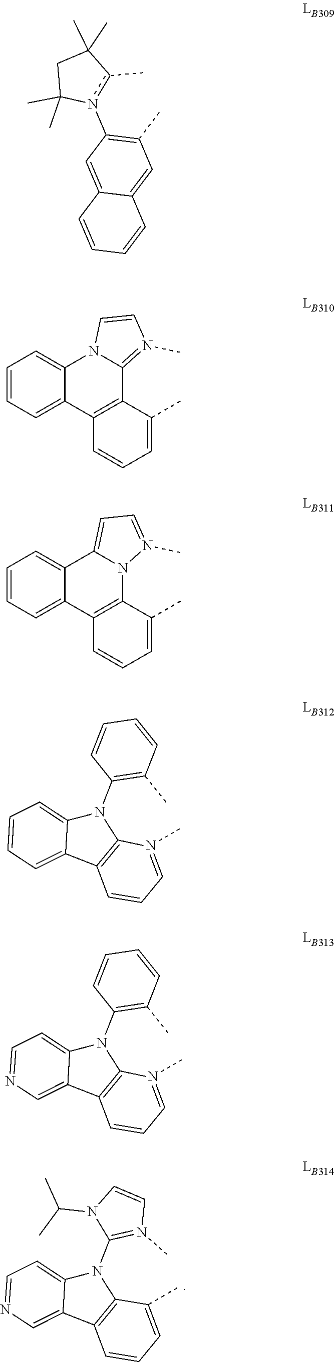

13. The compound according to claim 1, wherein, the structures represented by Ir(L_{A})(L_{B})₂ is selected from the group consisting of the following structures:

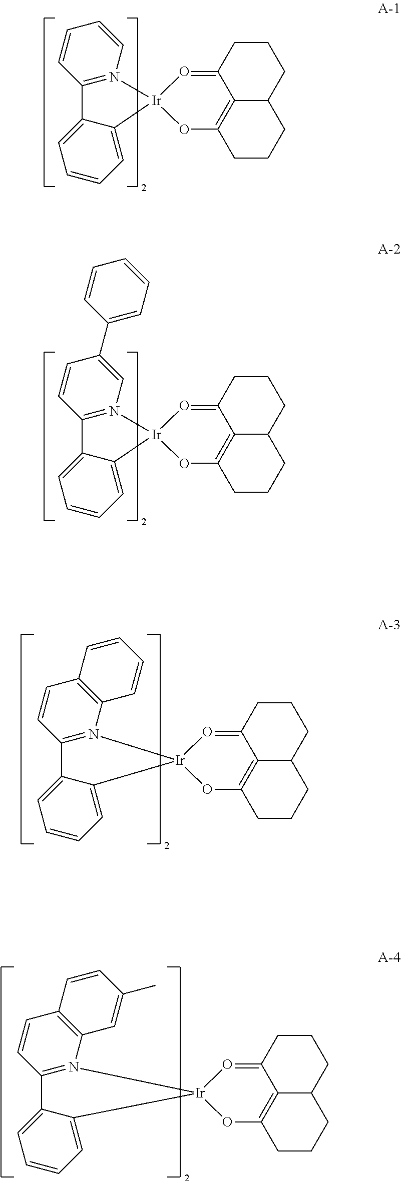

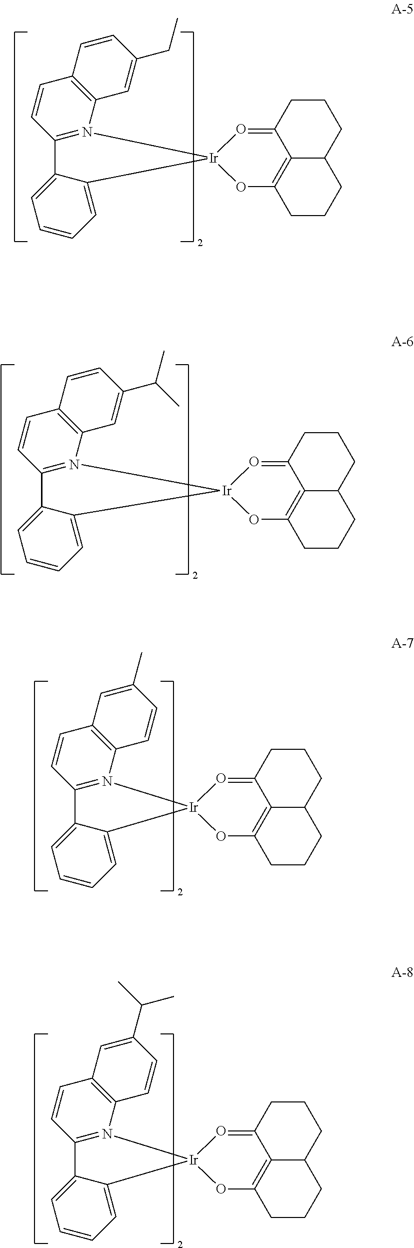

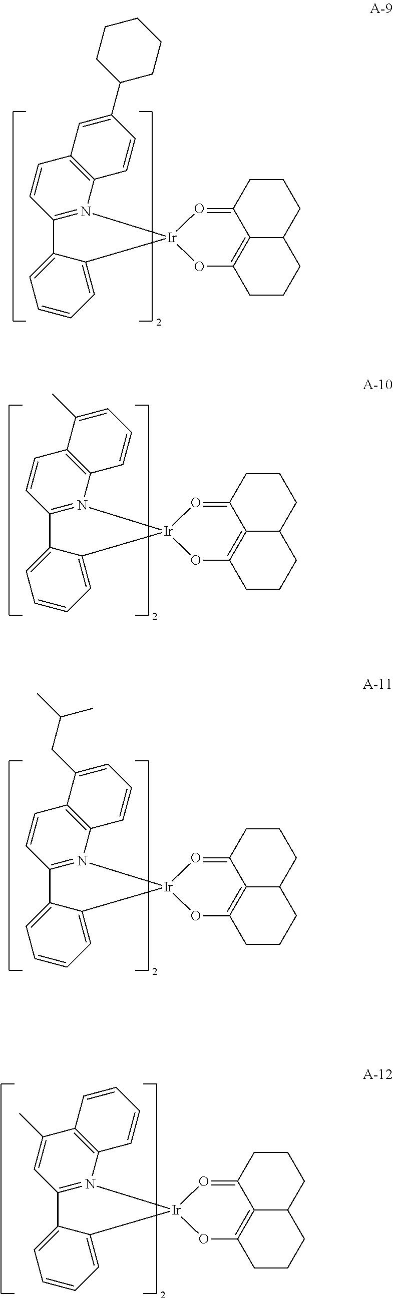

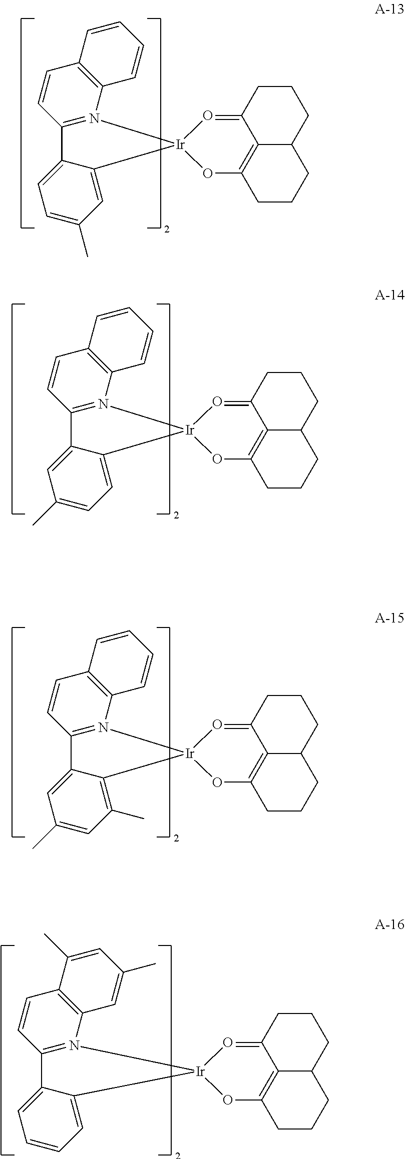

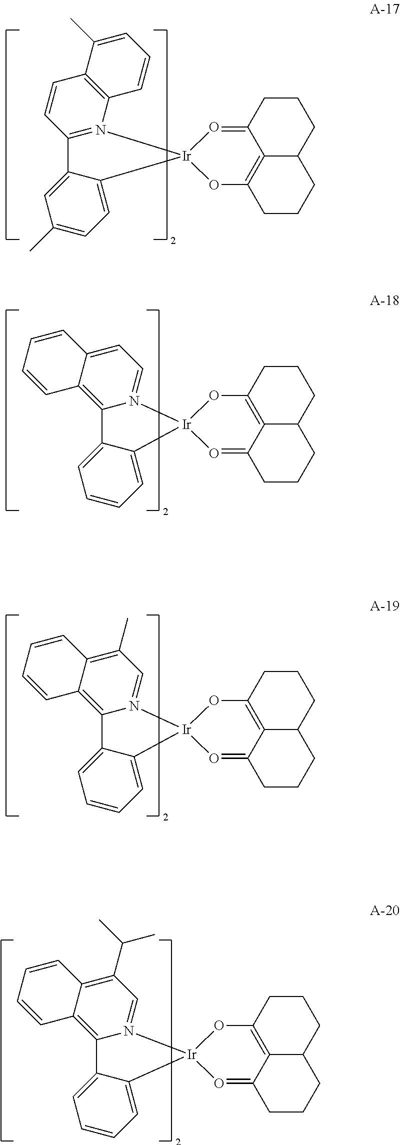

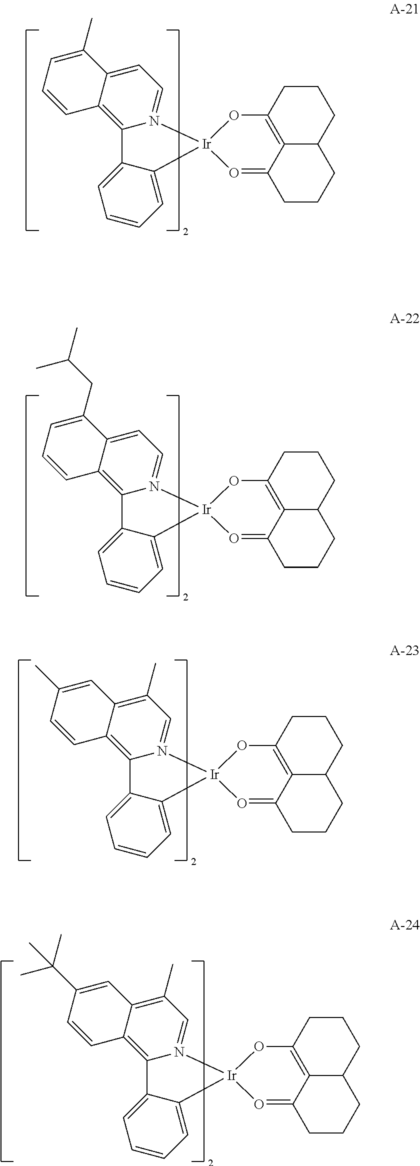

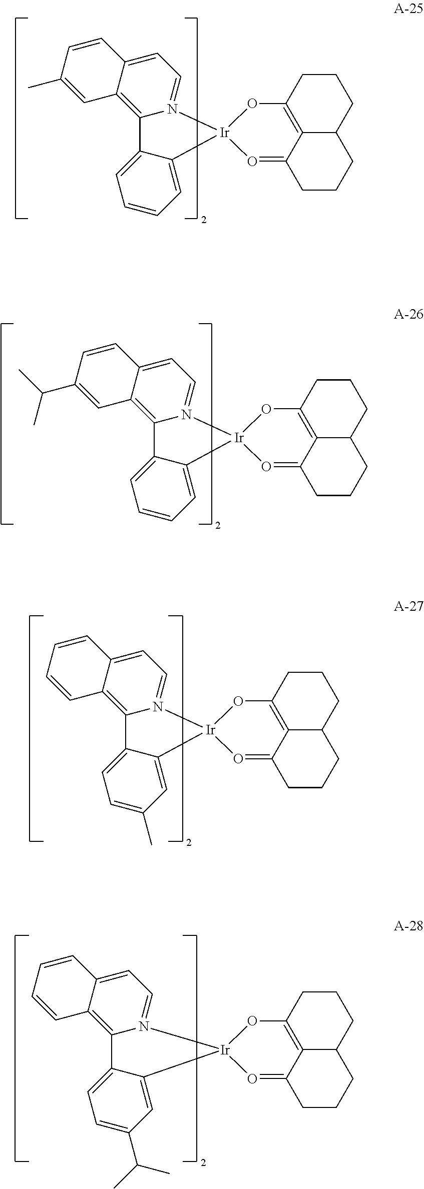

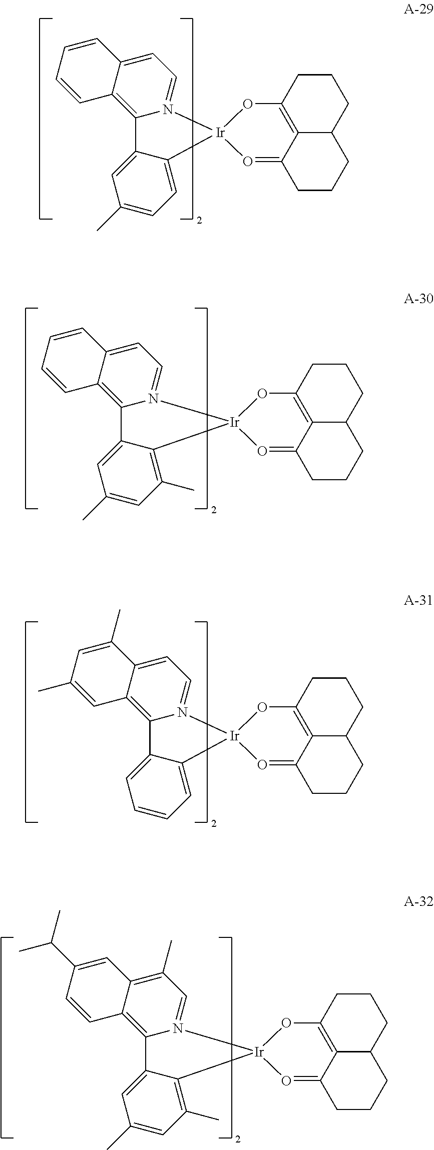

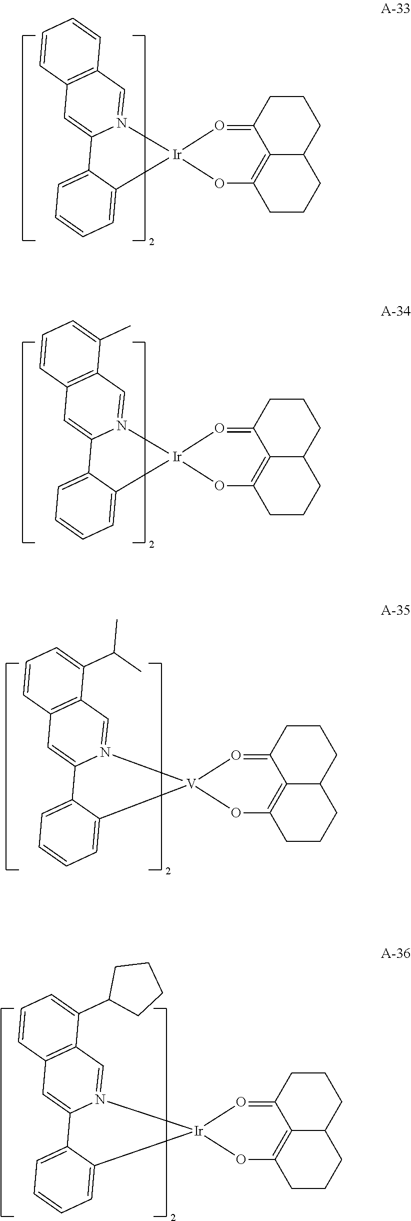

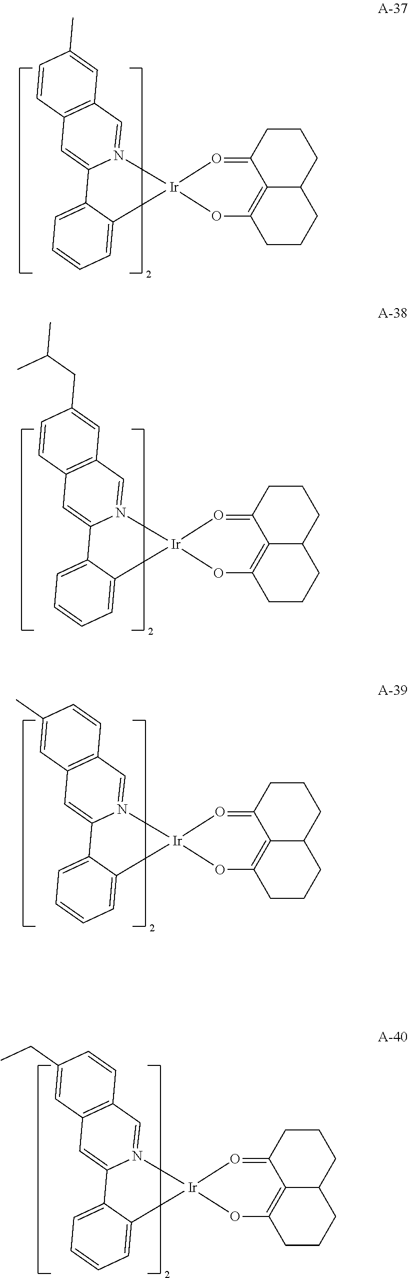

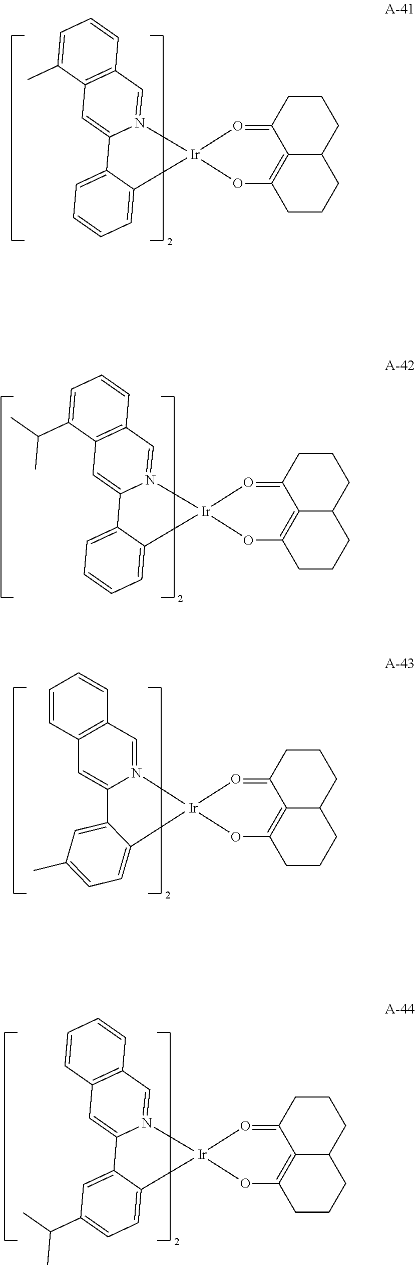

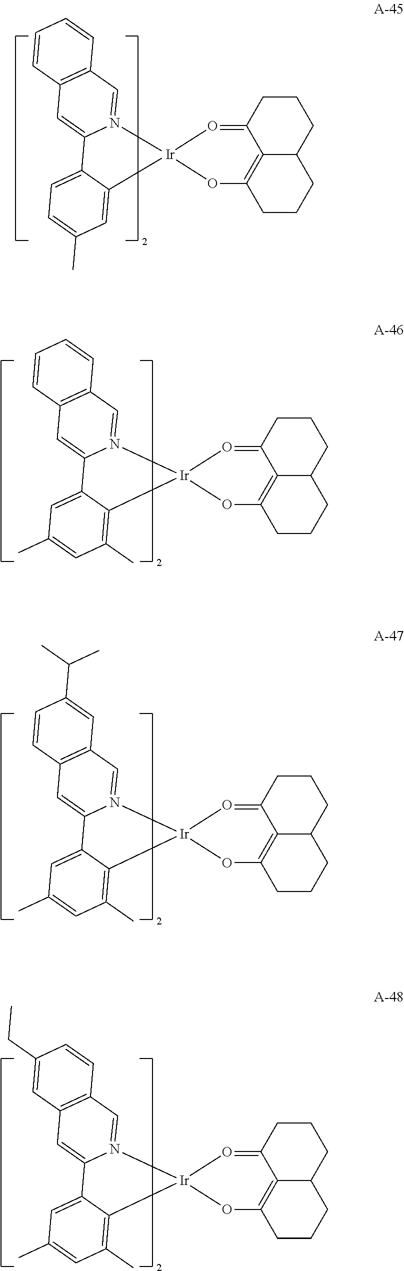

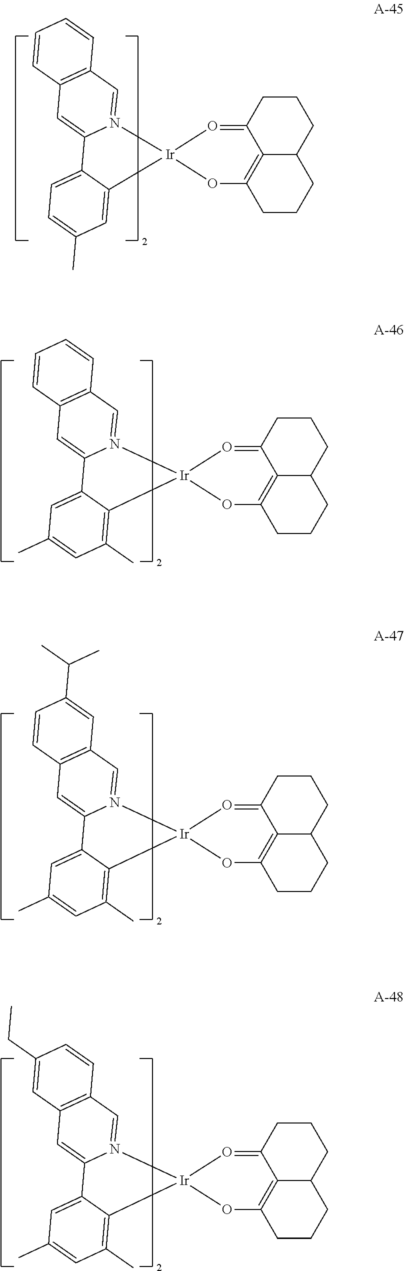

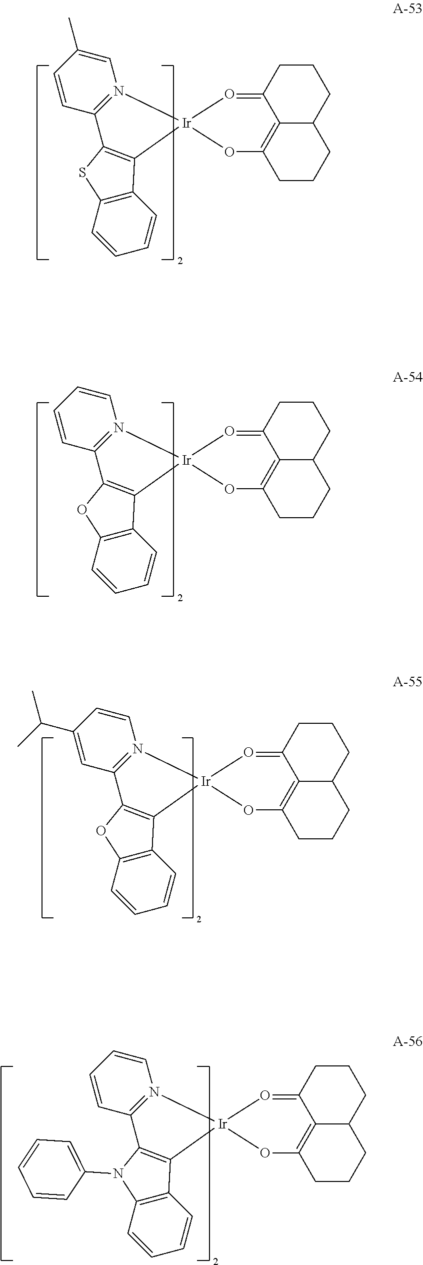

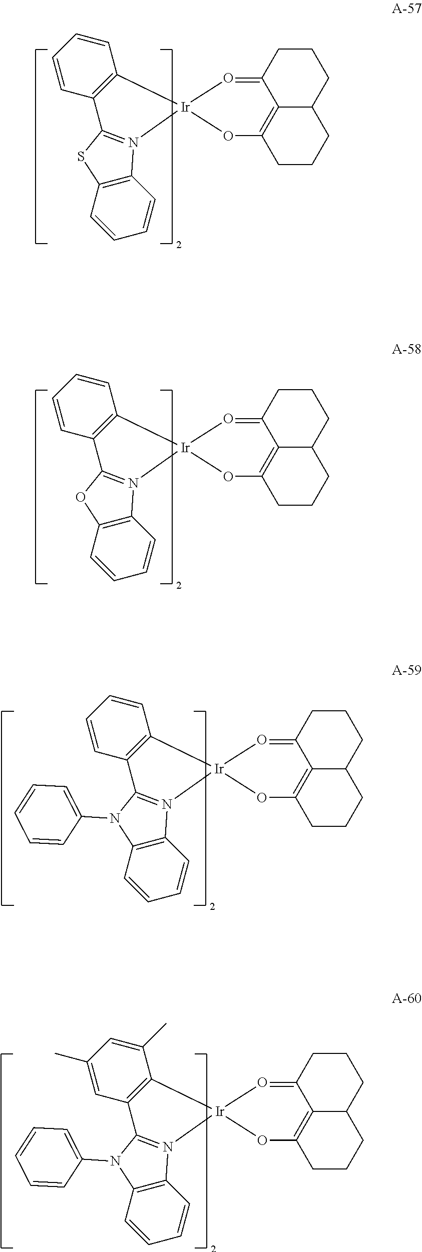

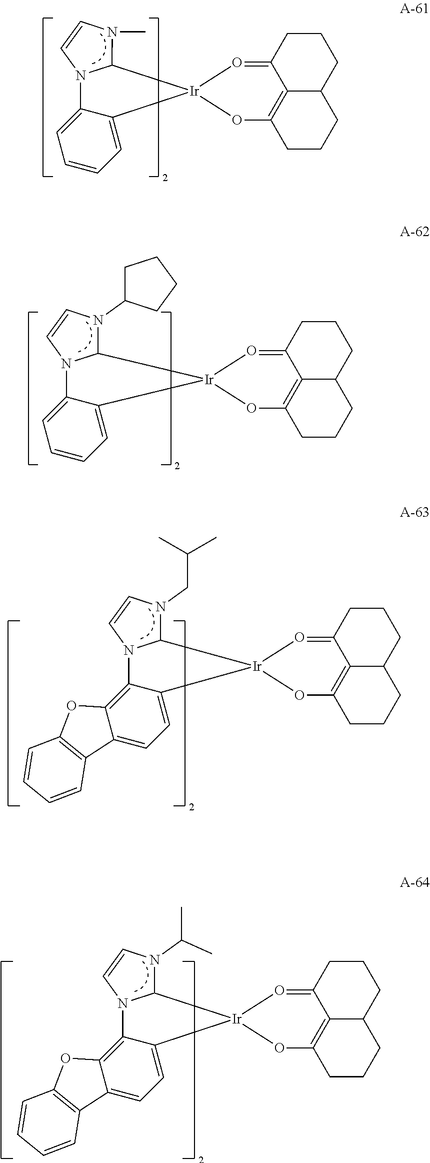

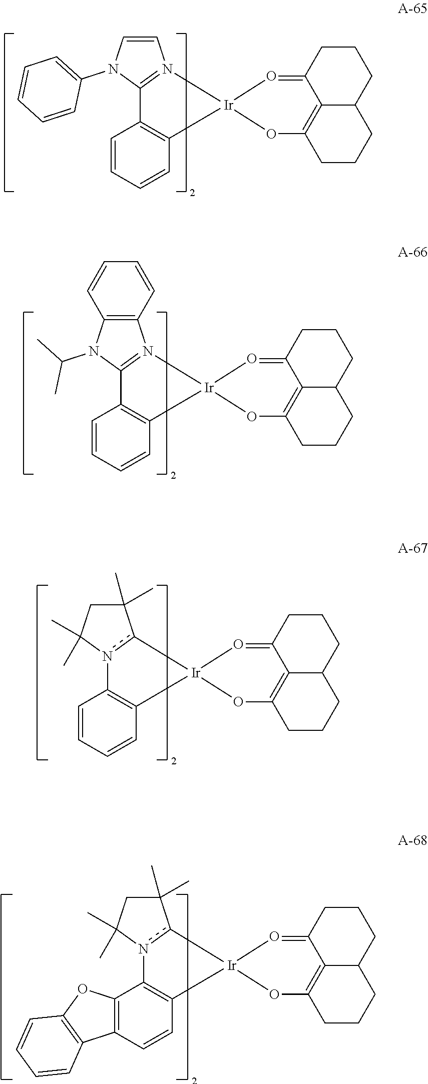

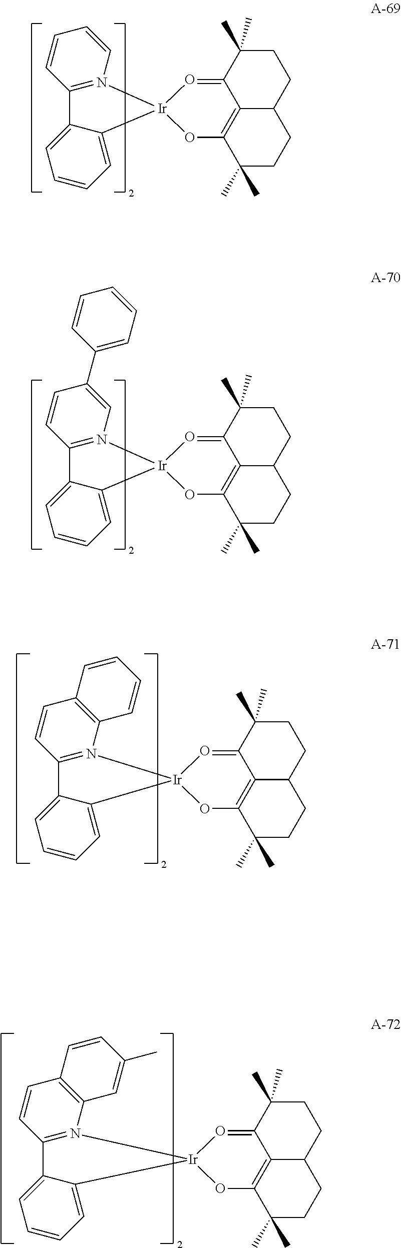

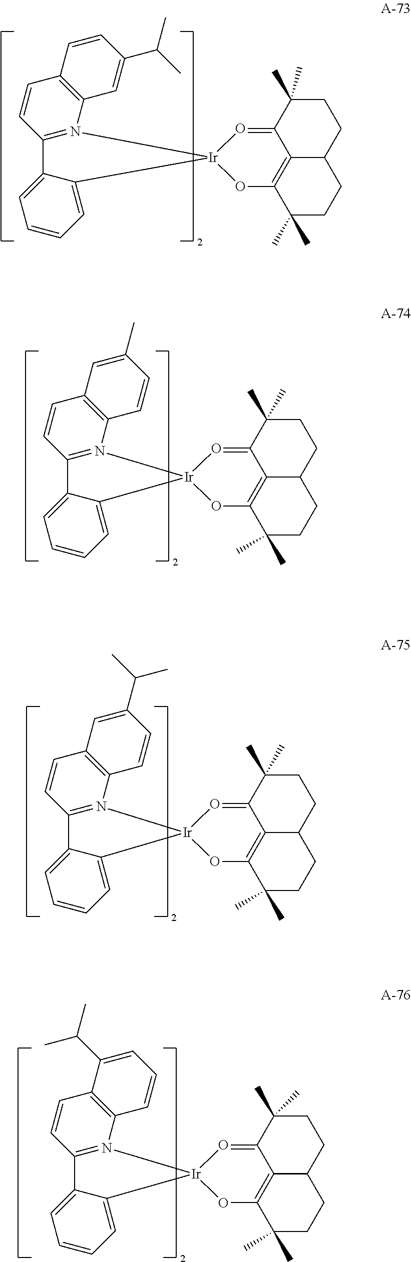

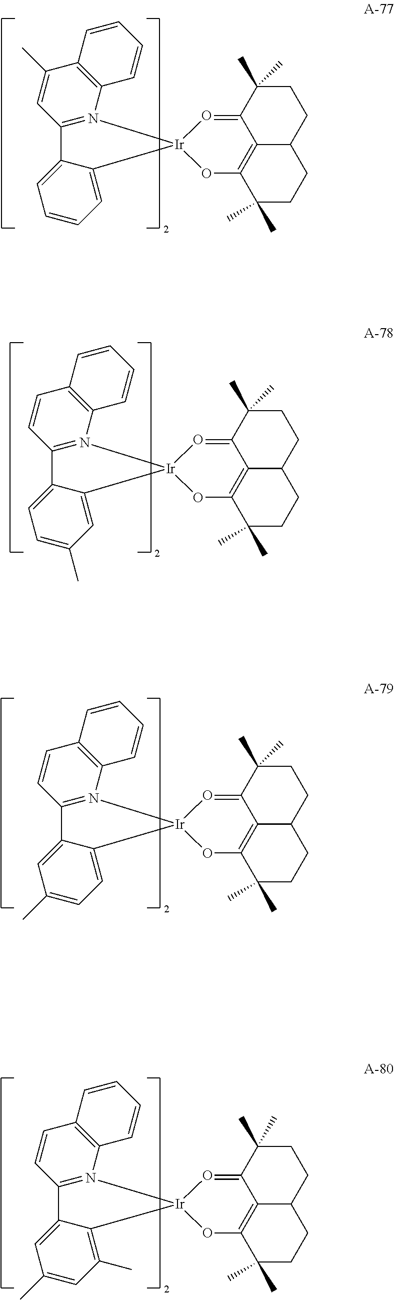

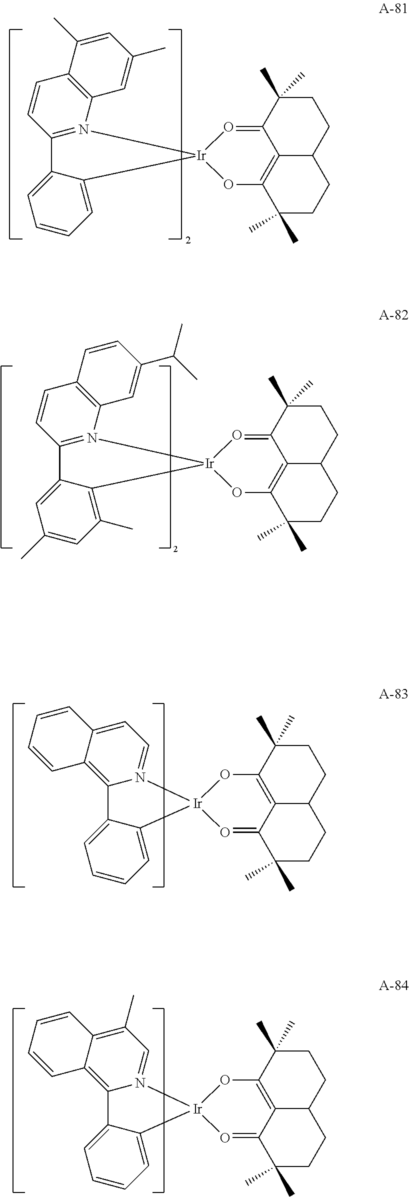

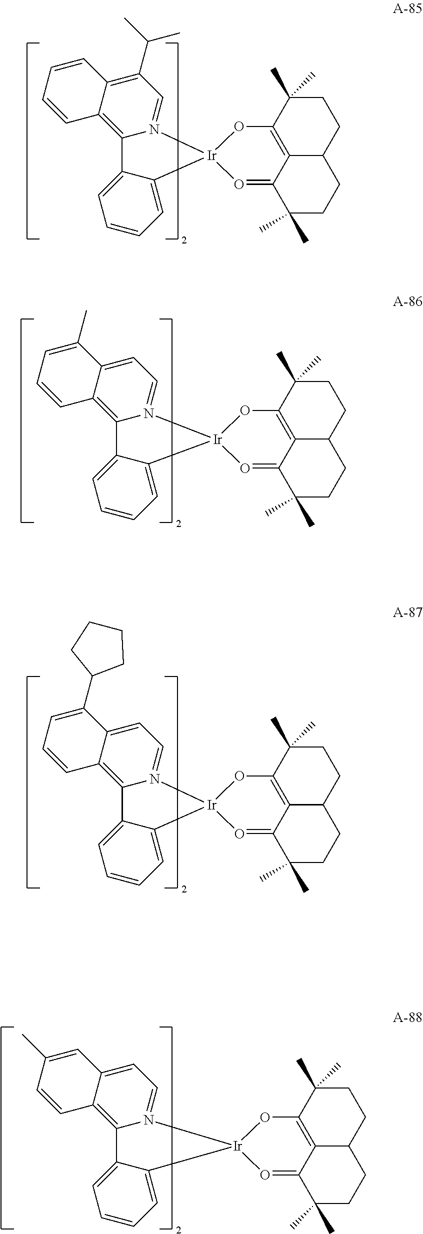

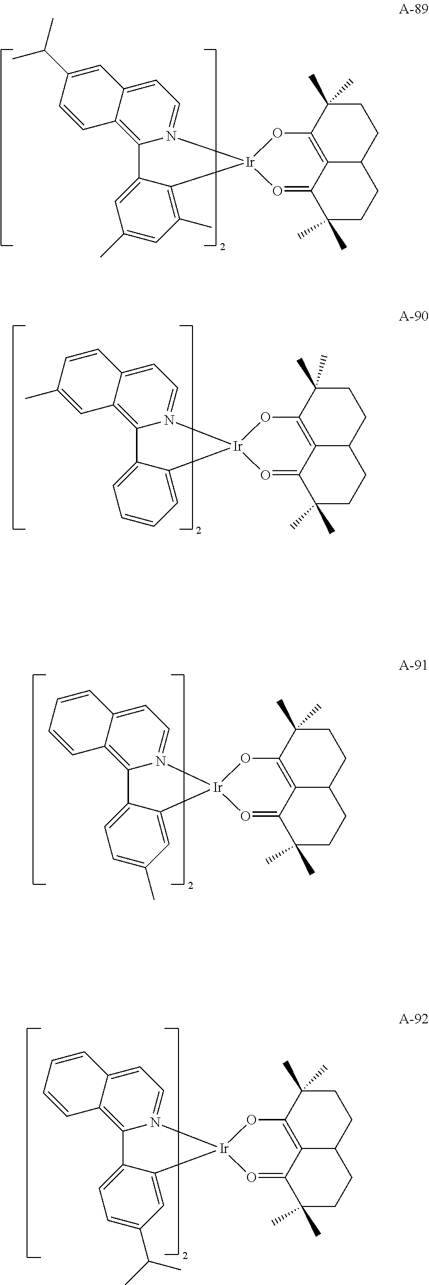

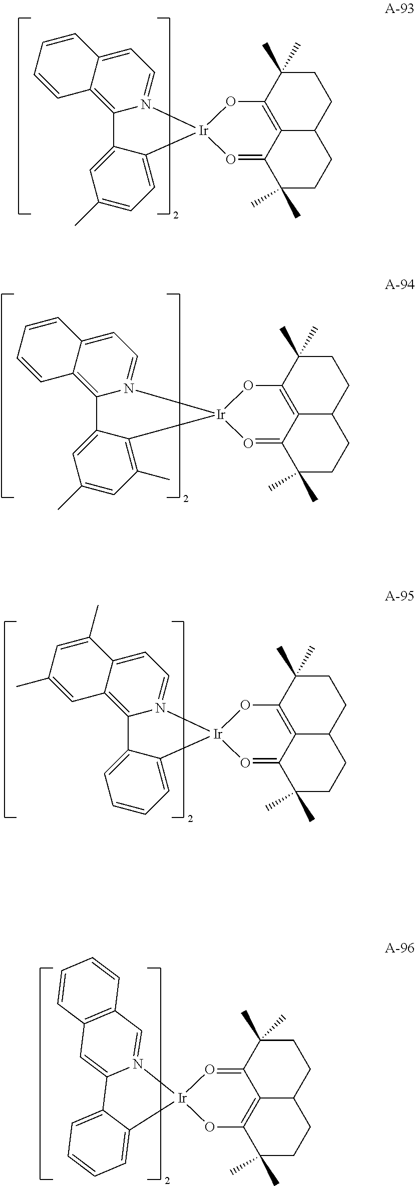

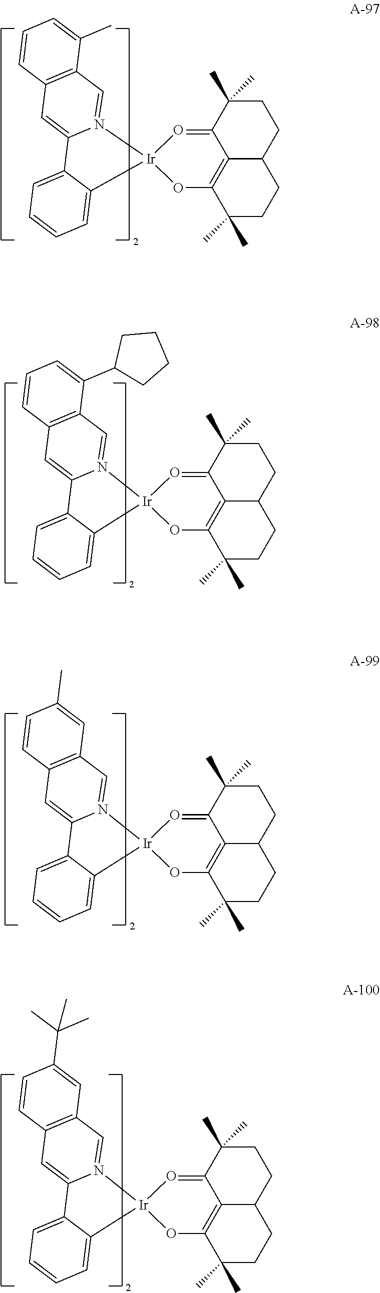

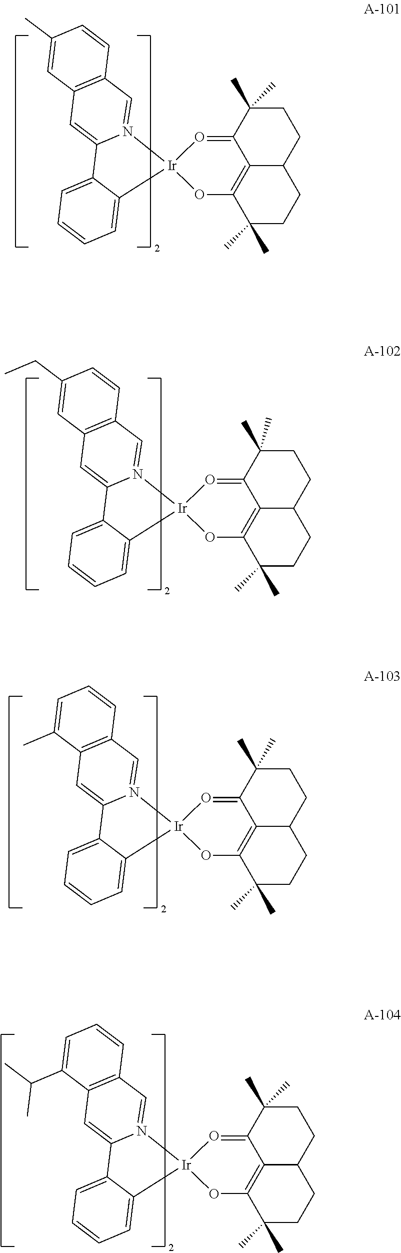

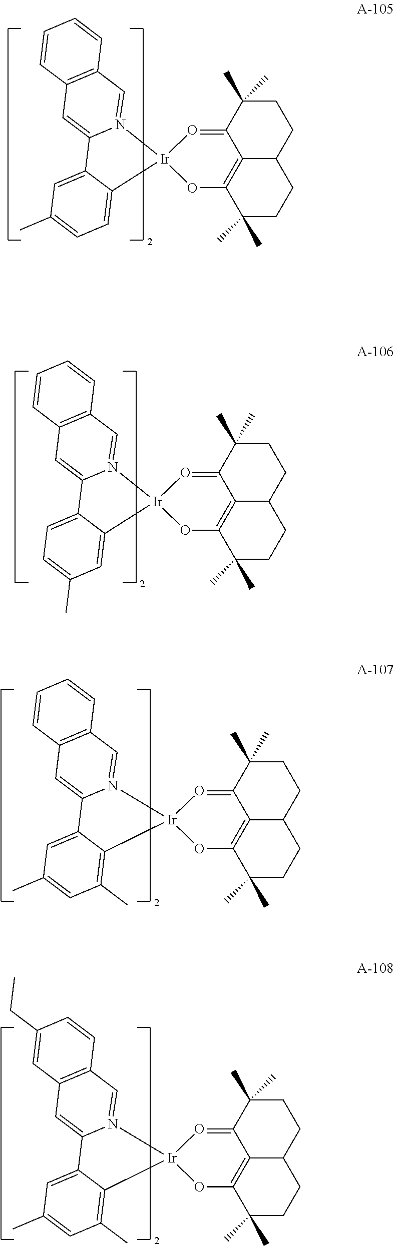

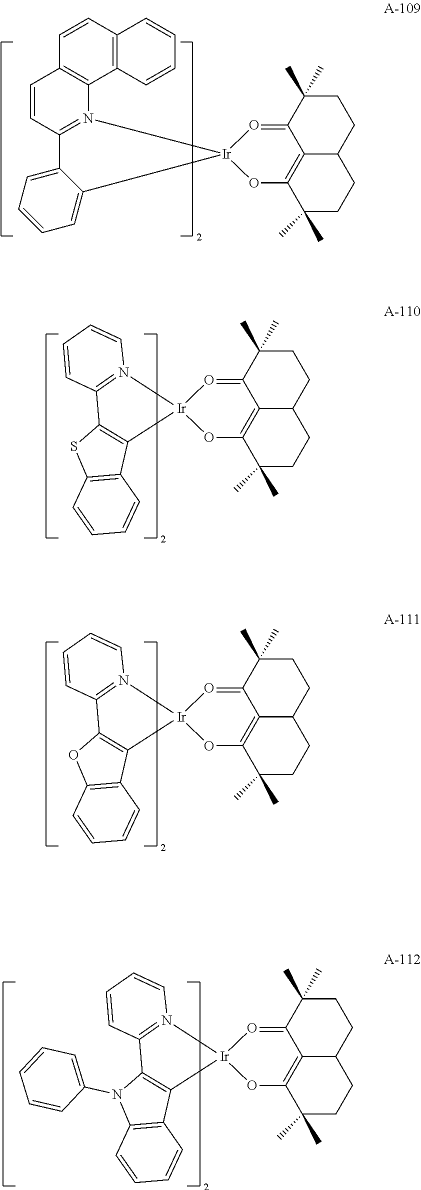

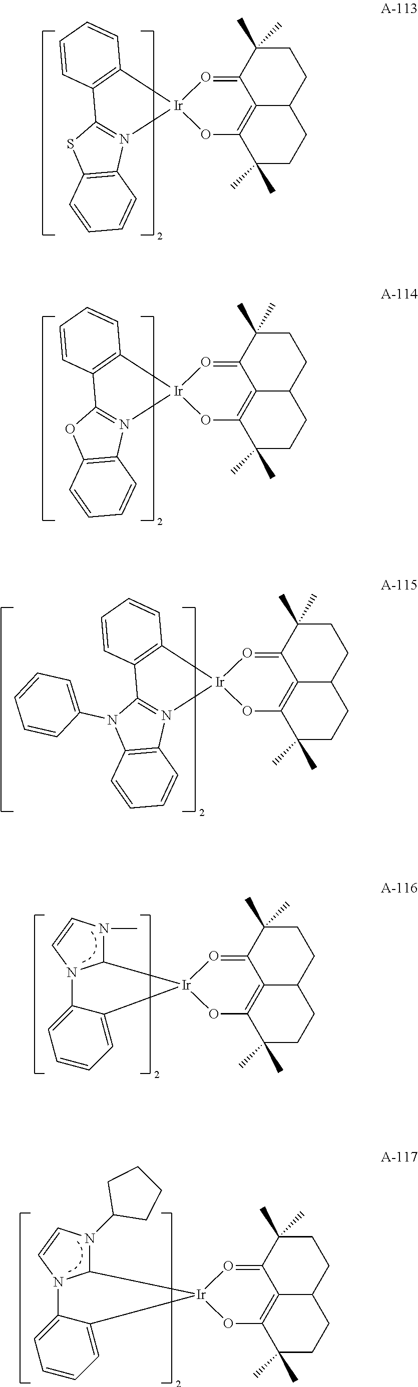

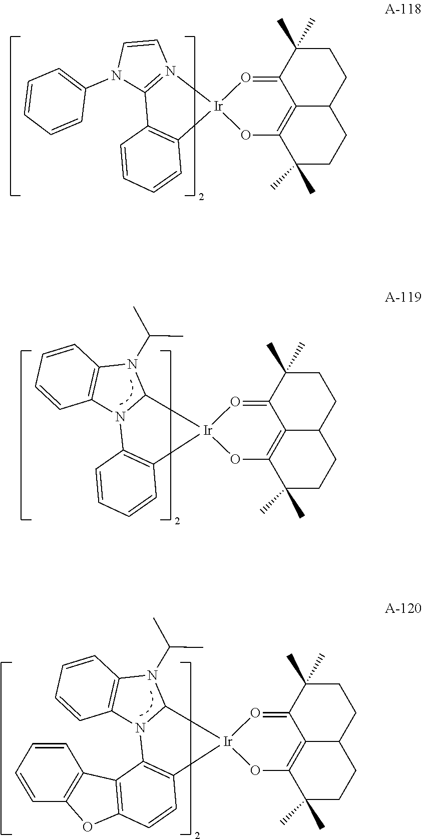

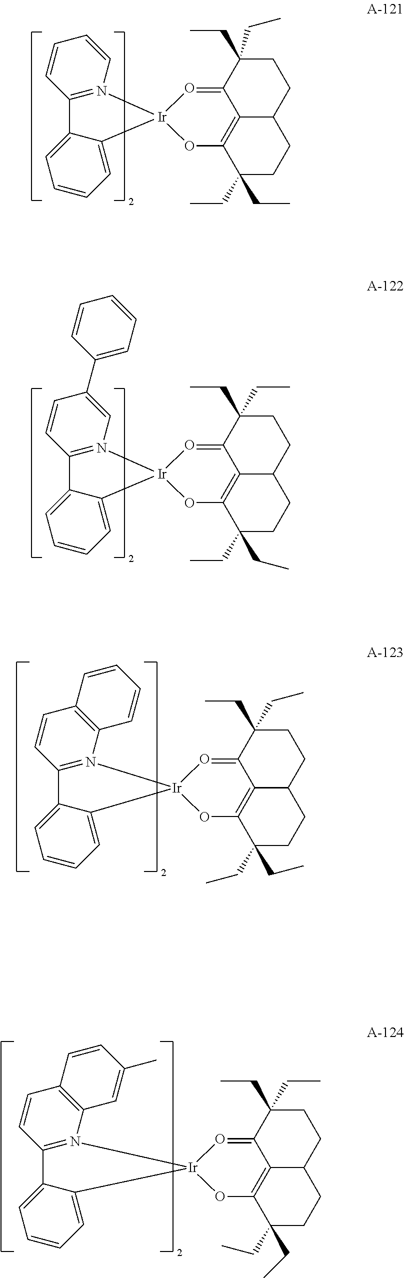

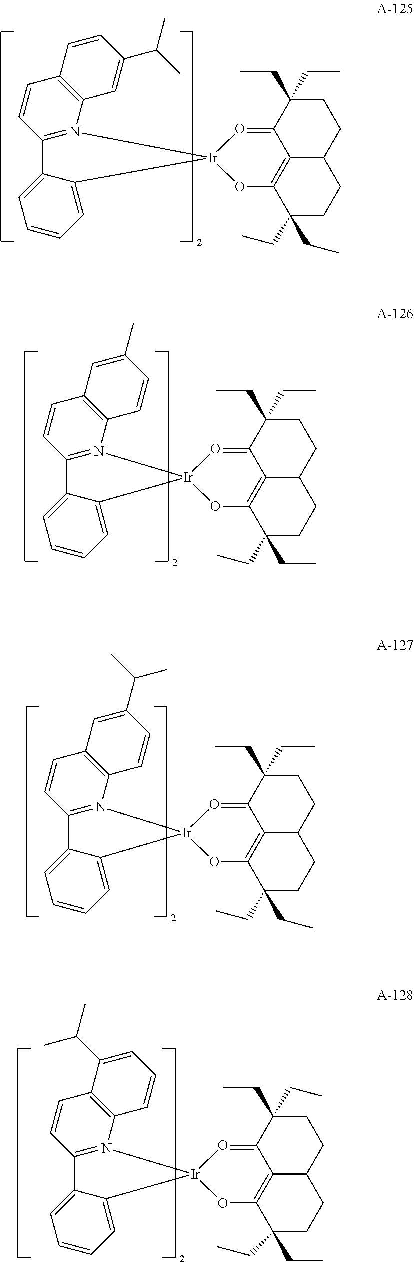

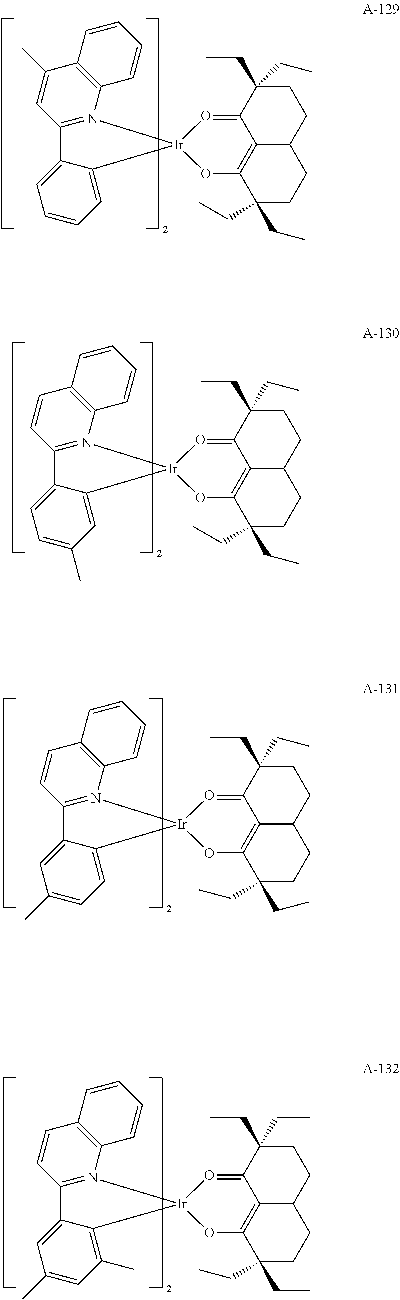

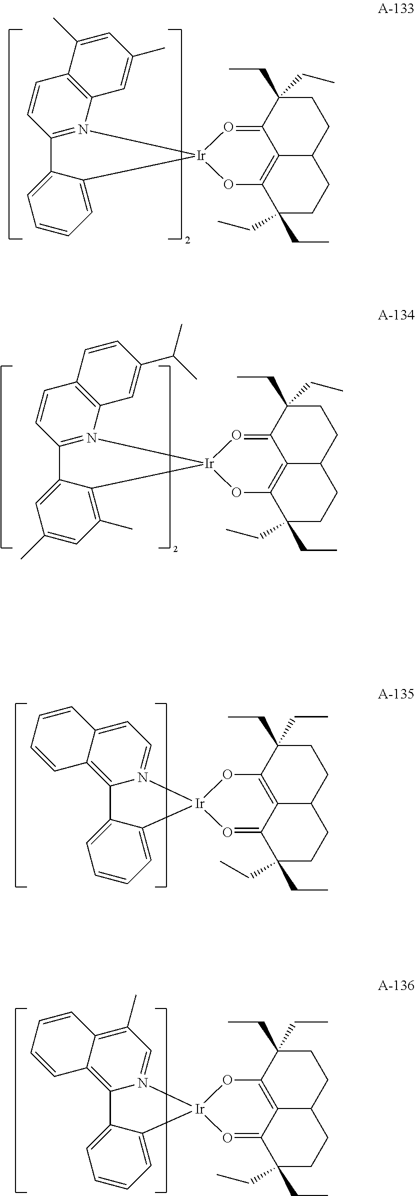

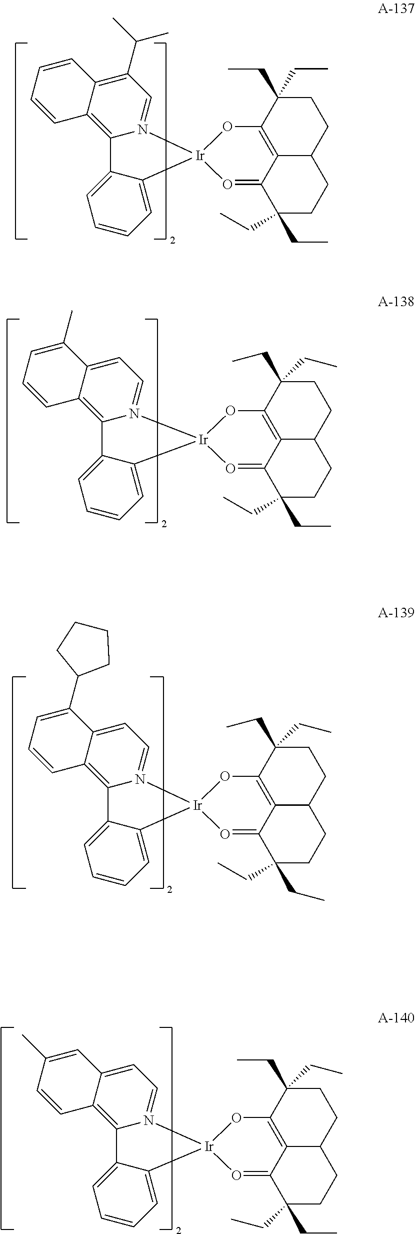

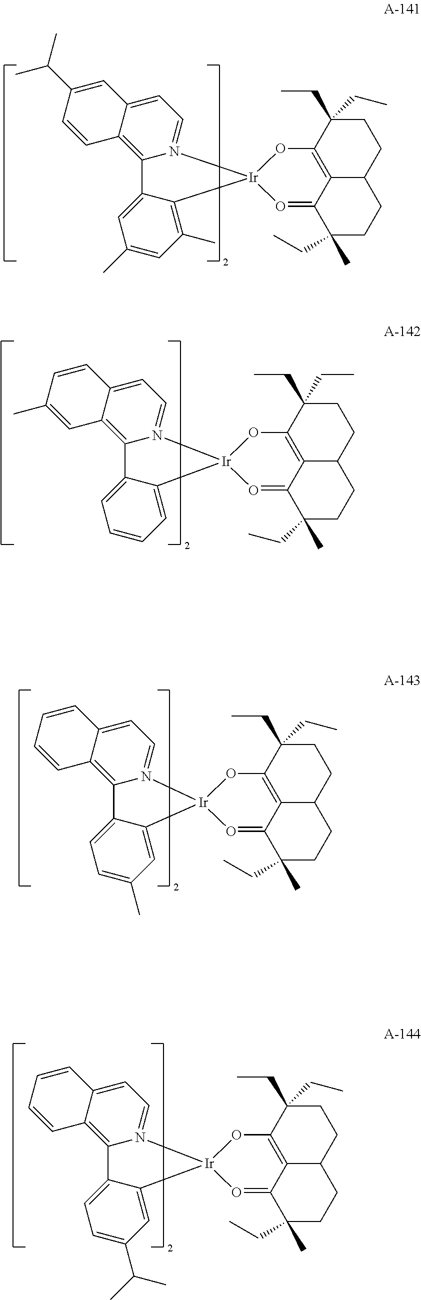

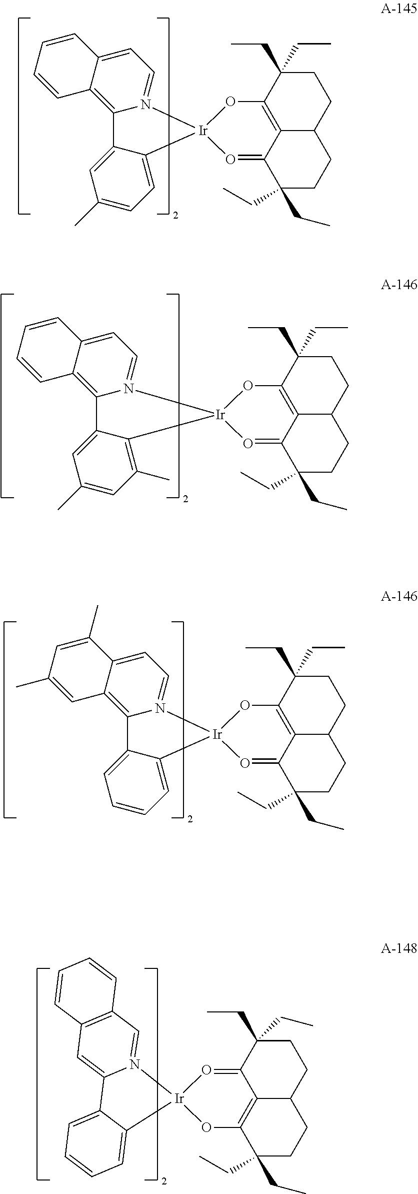

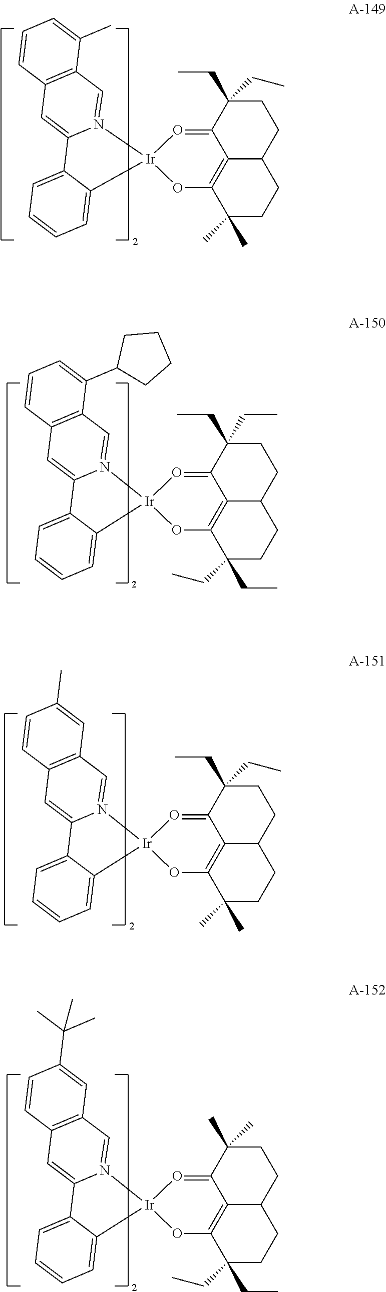

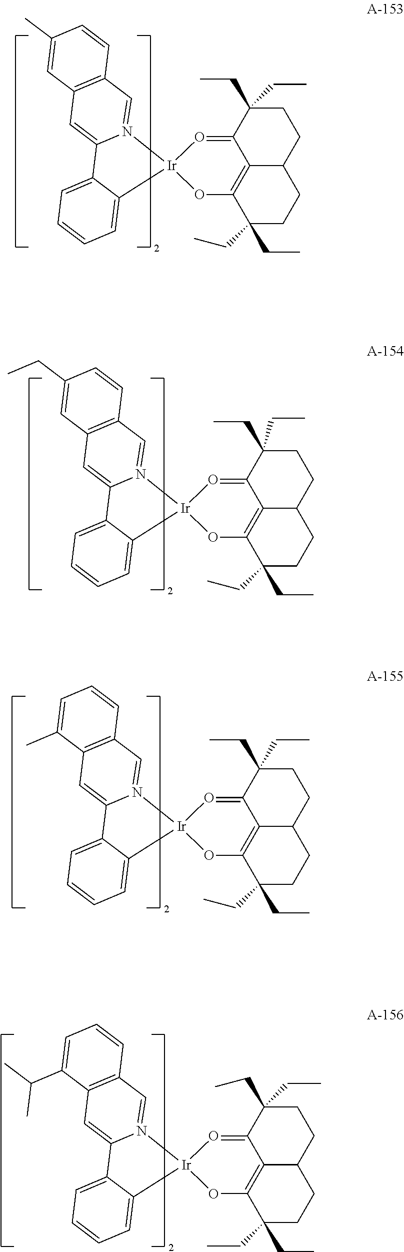

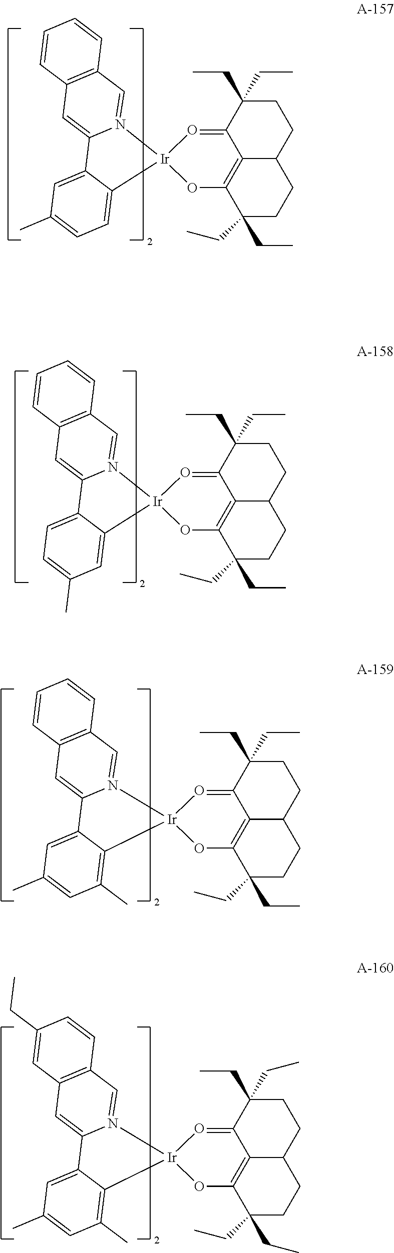

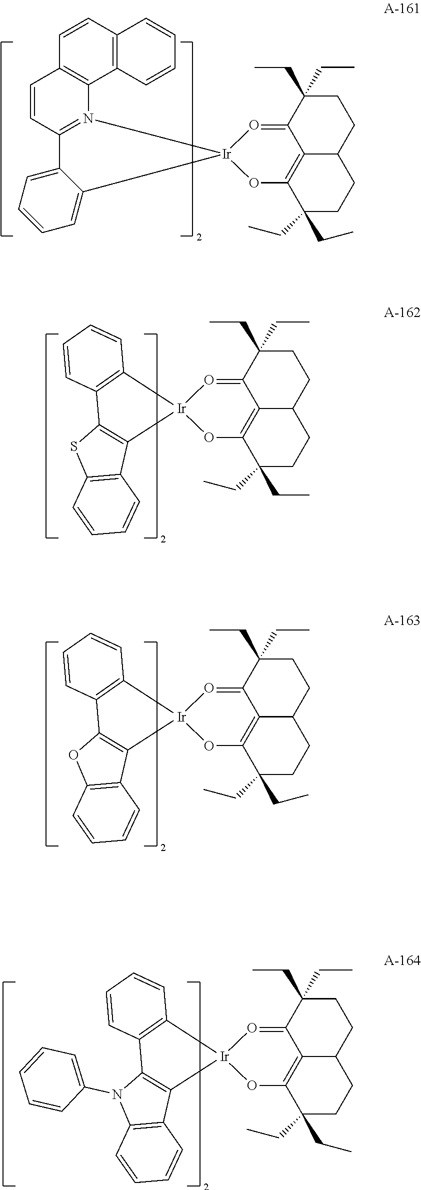

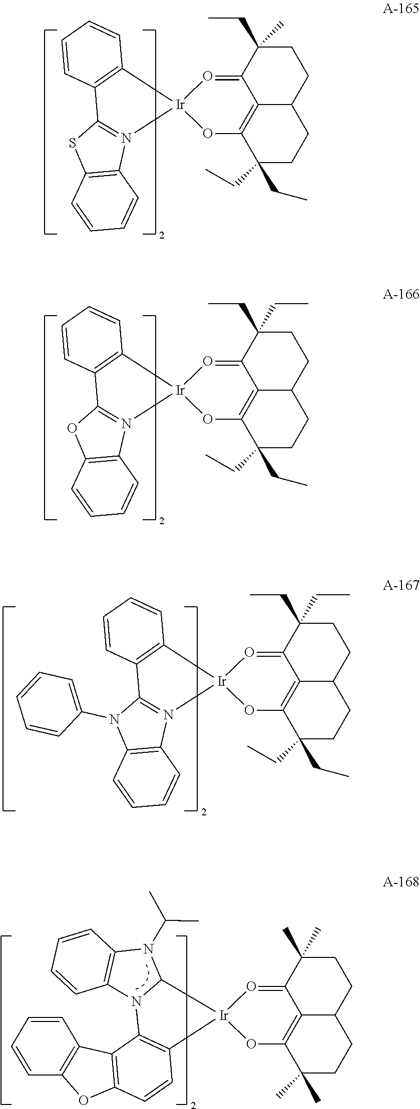

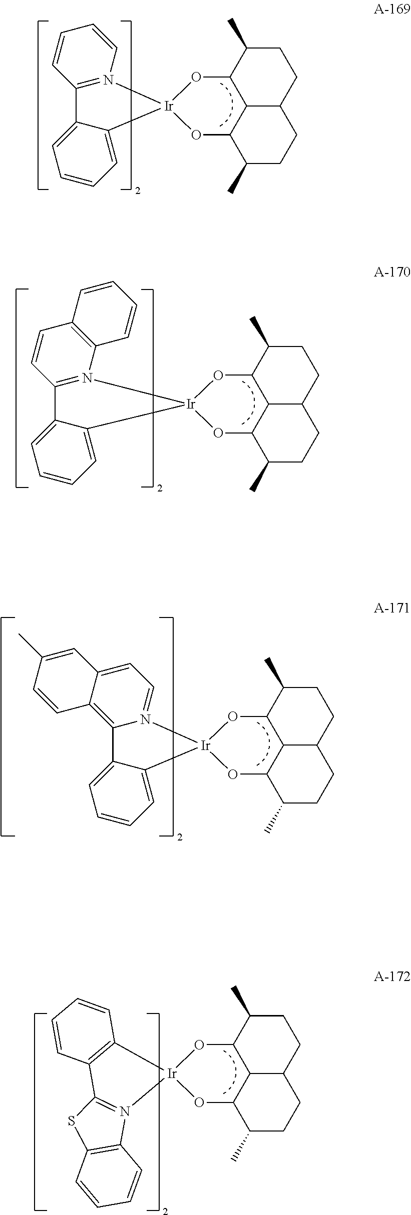

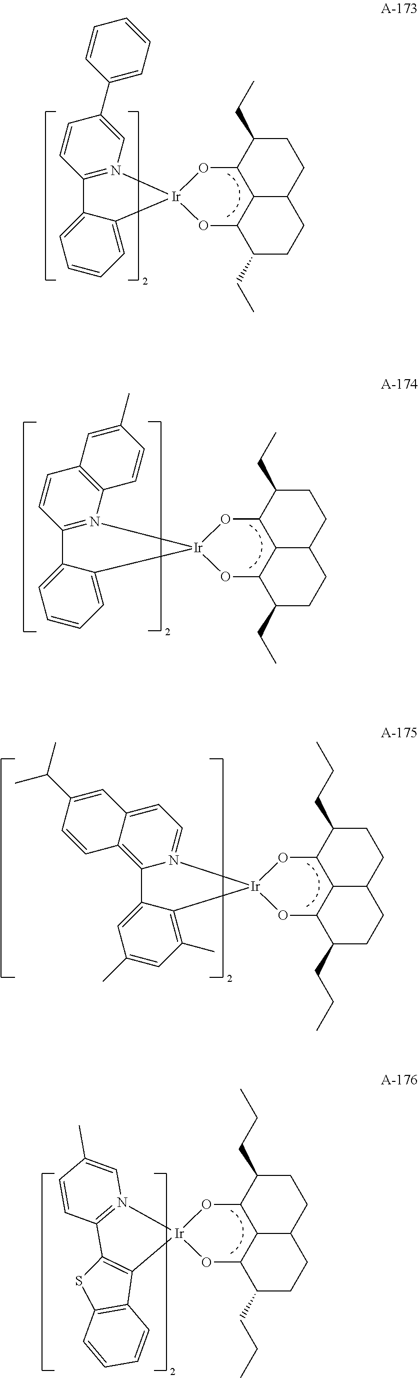

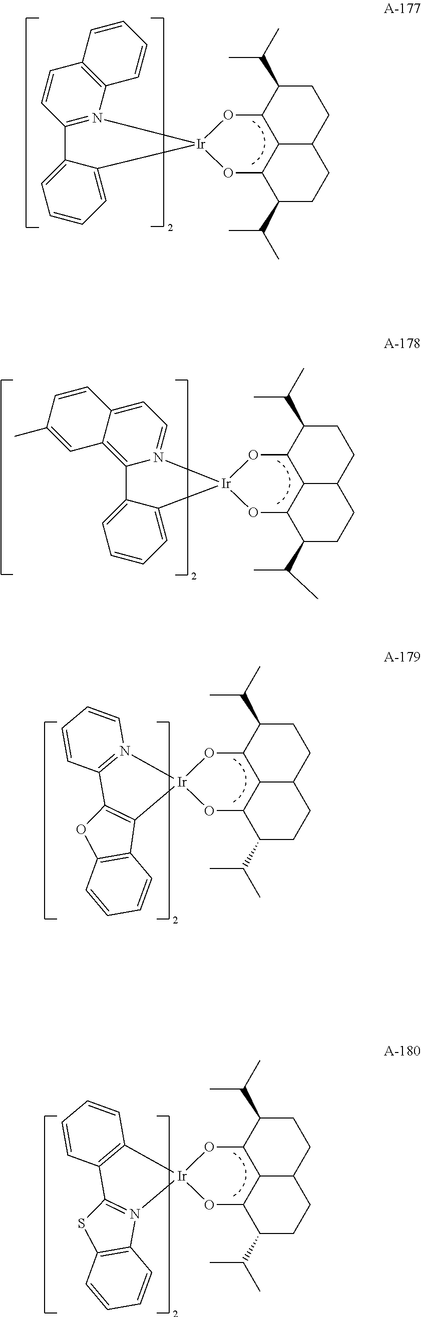

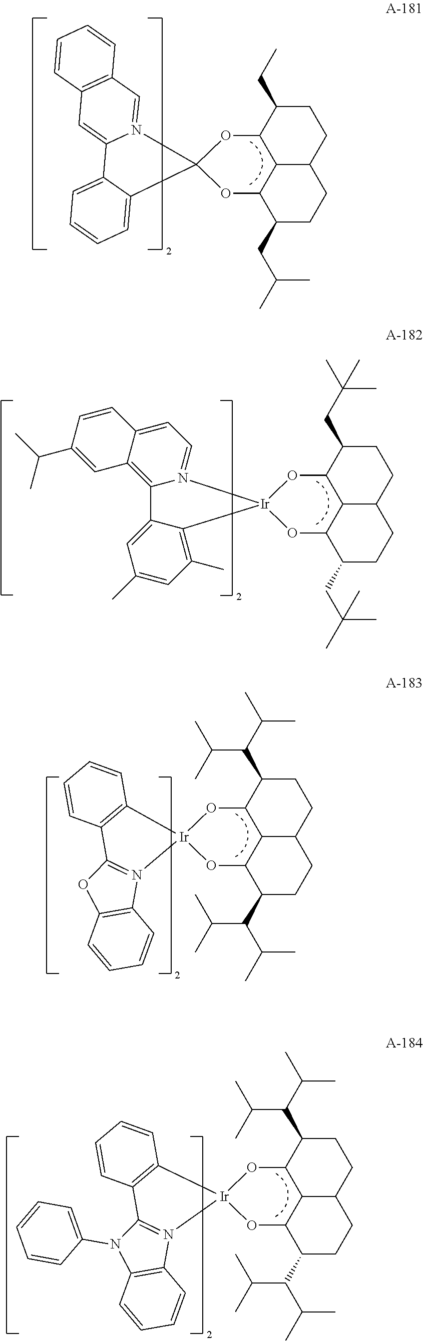

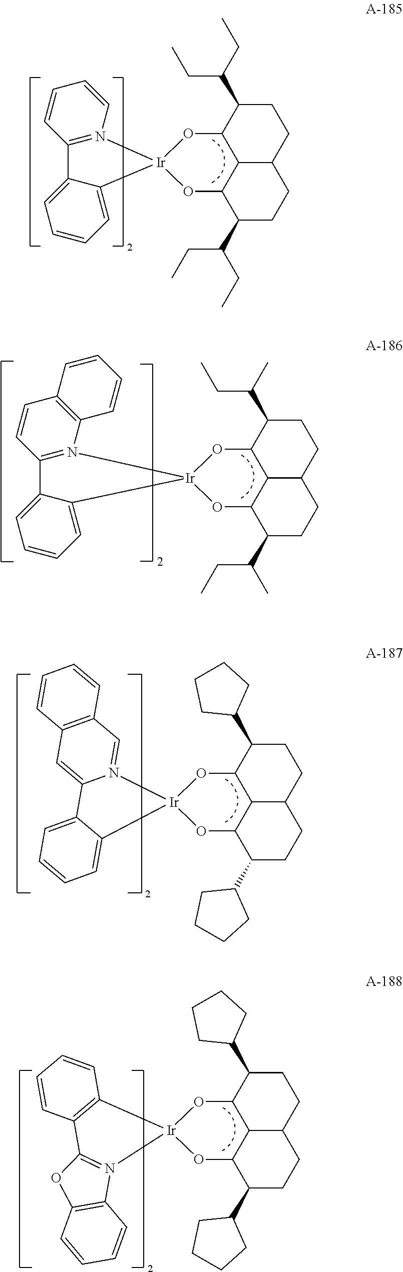

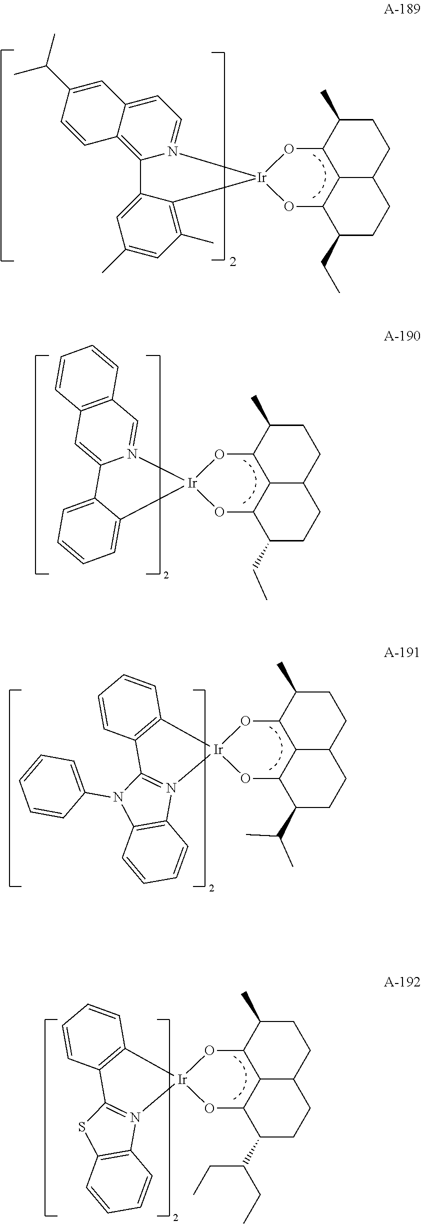

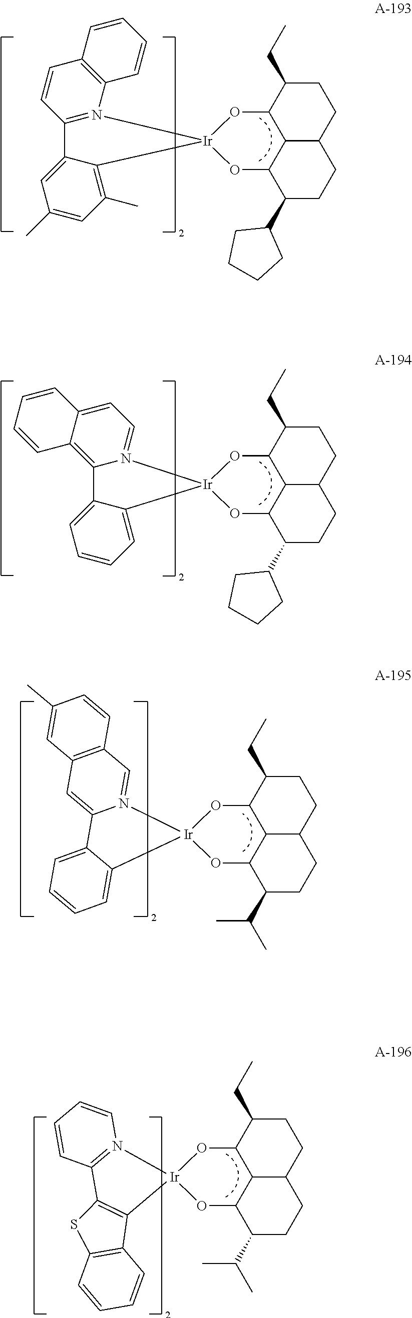

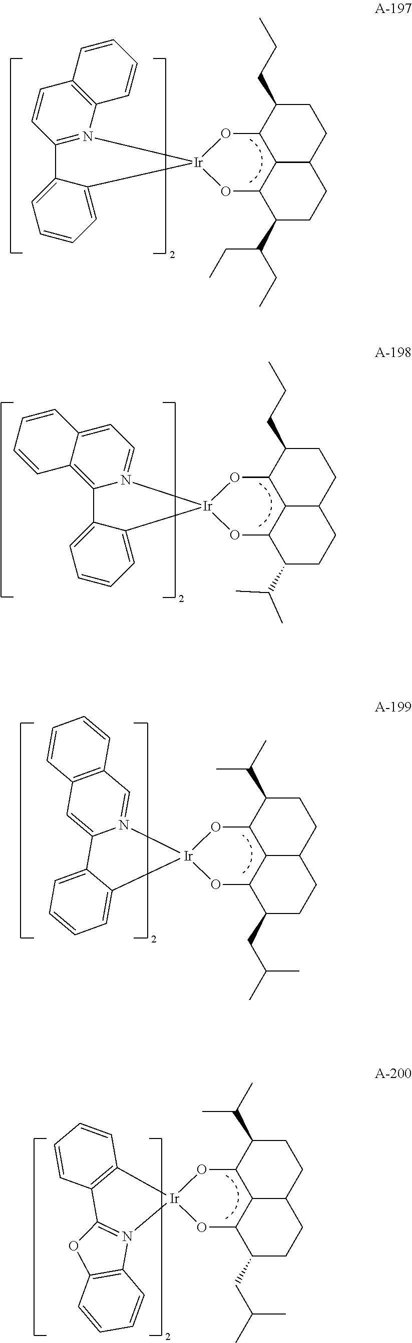

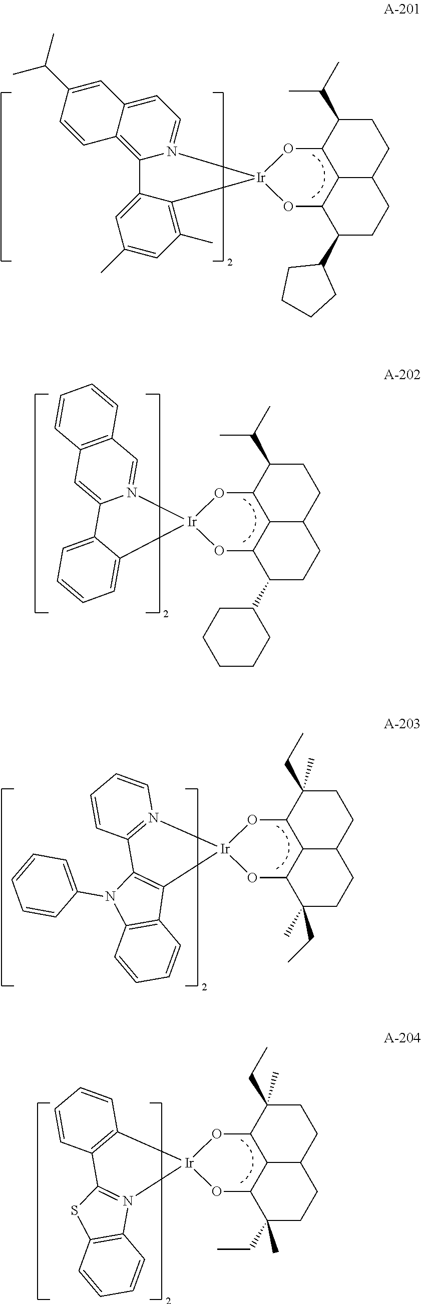

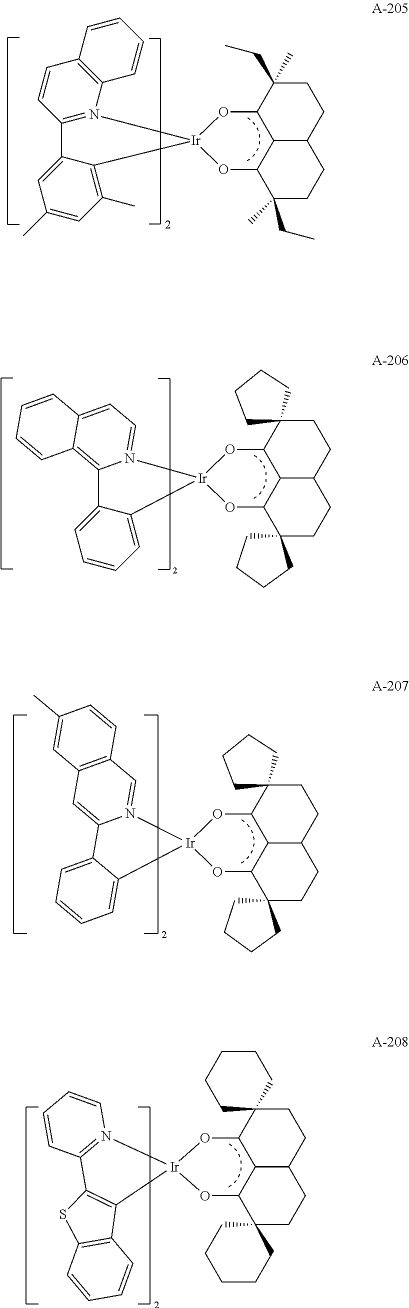

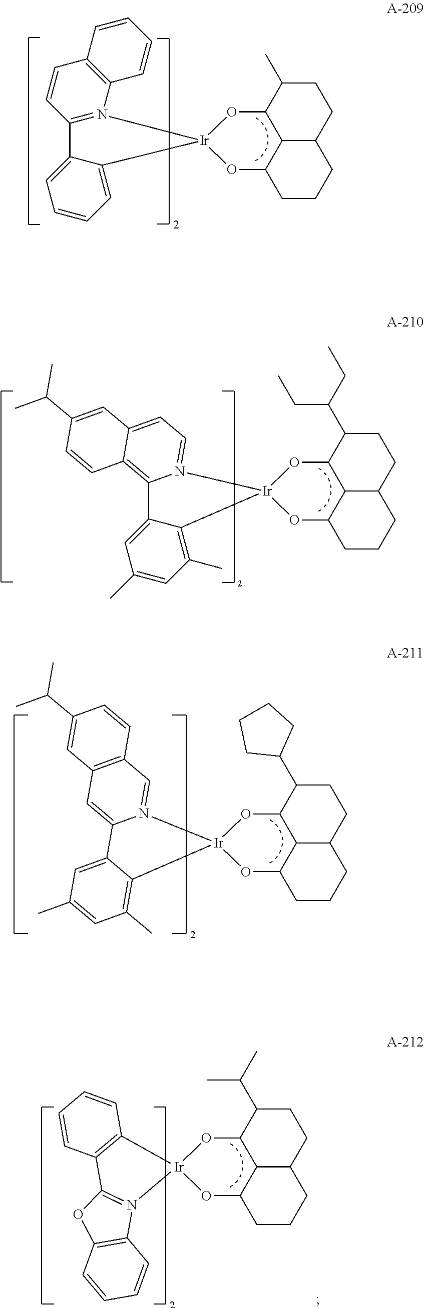

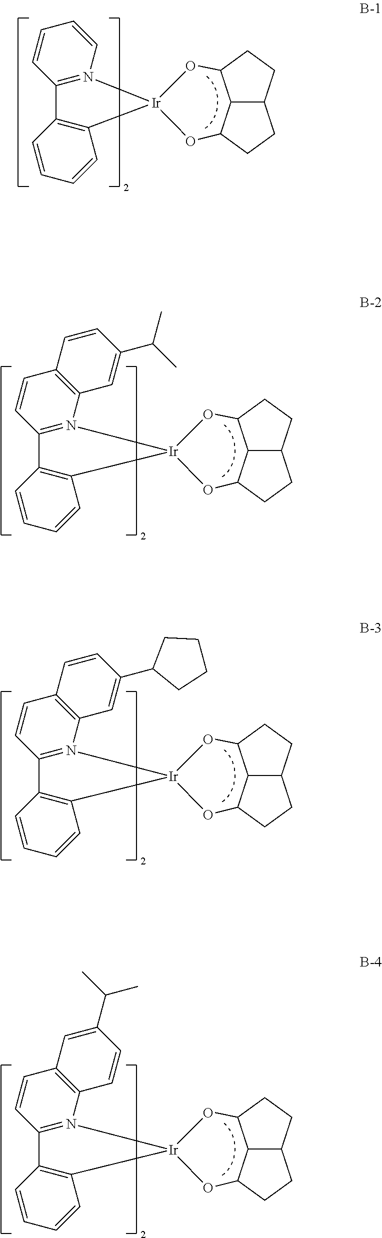

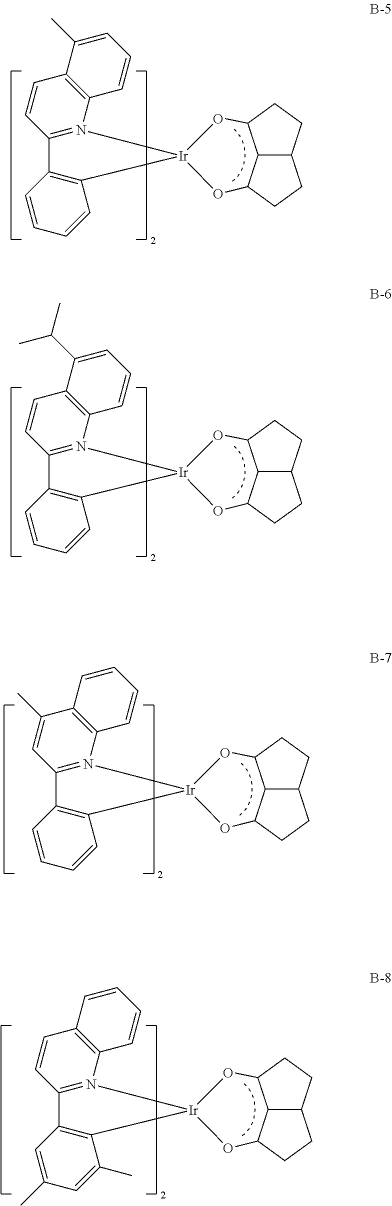

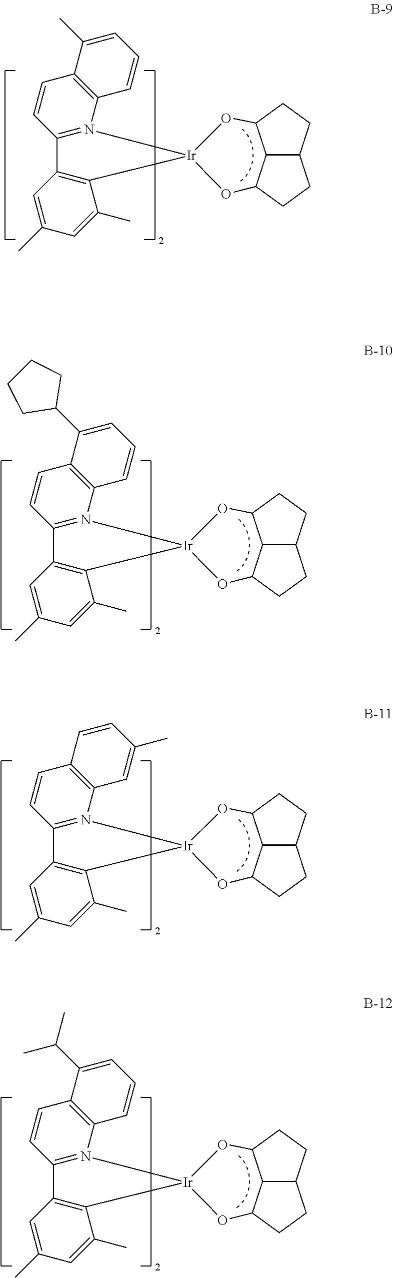

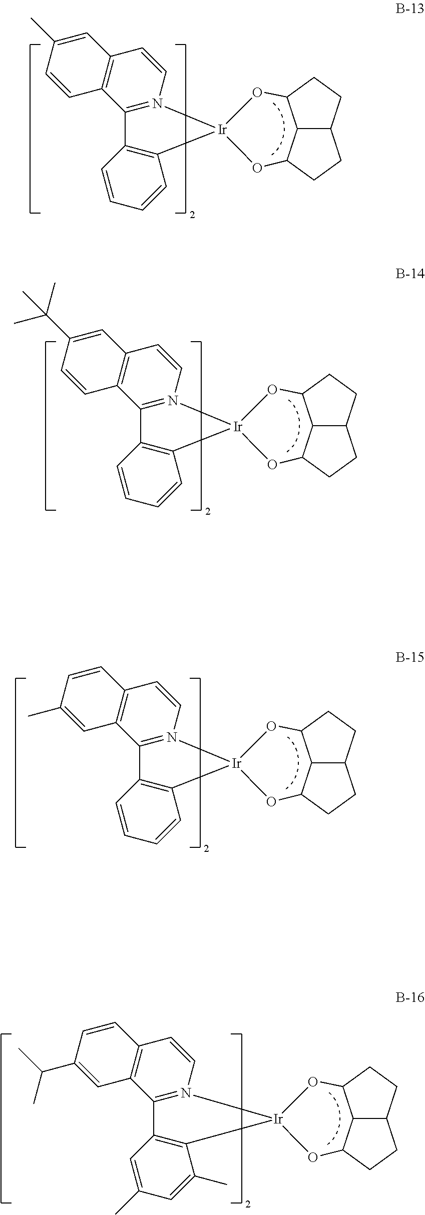

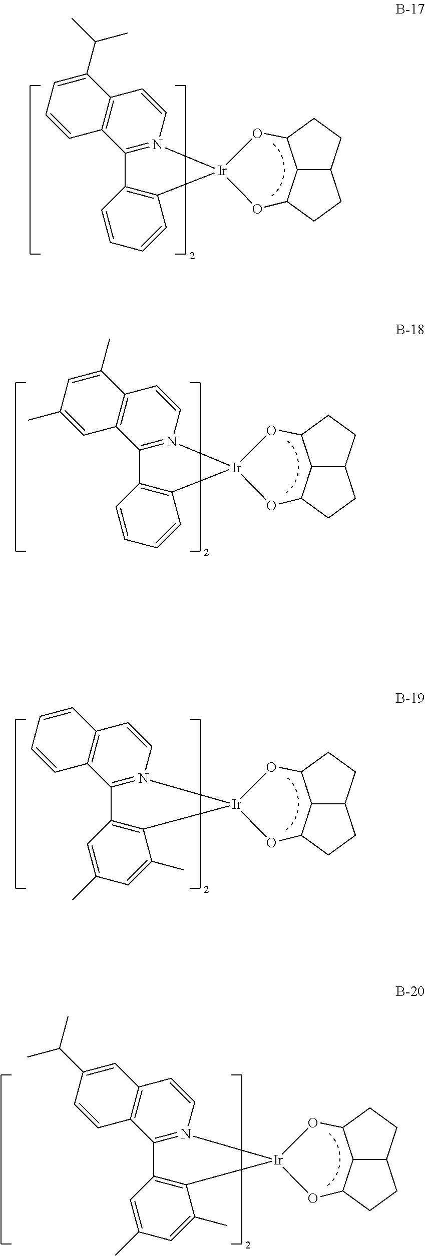

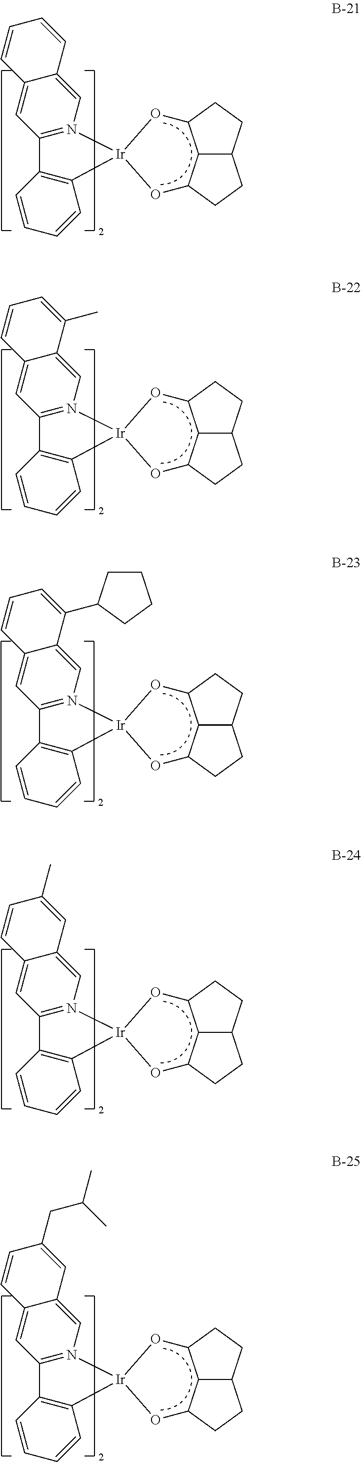

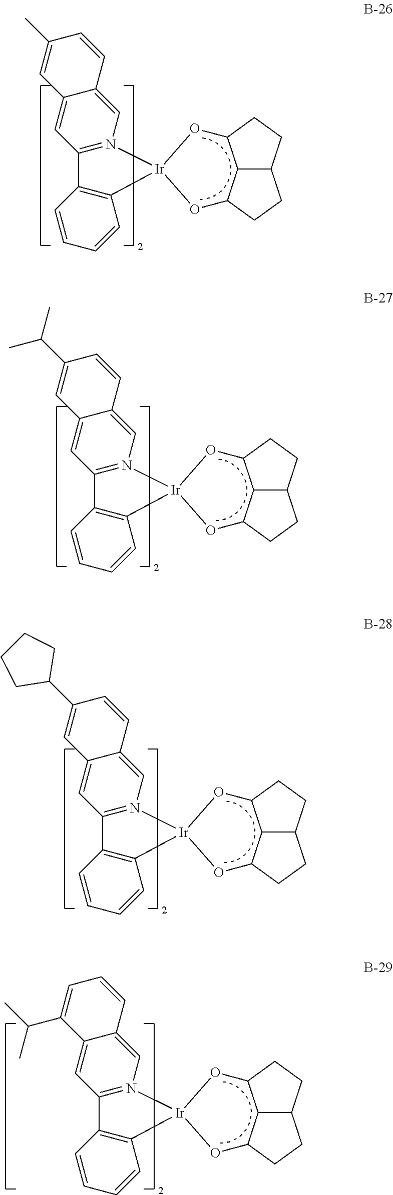

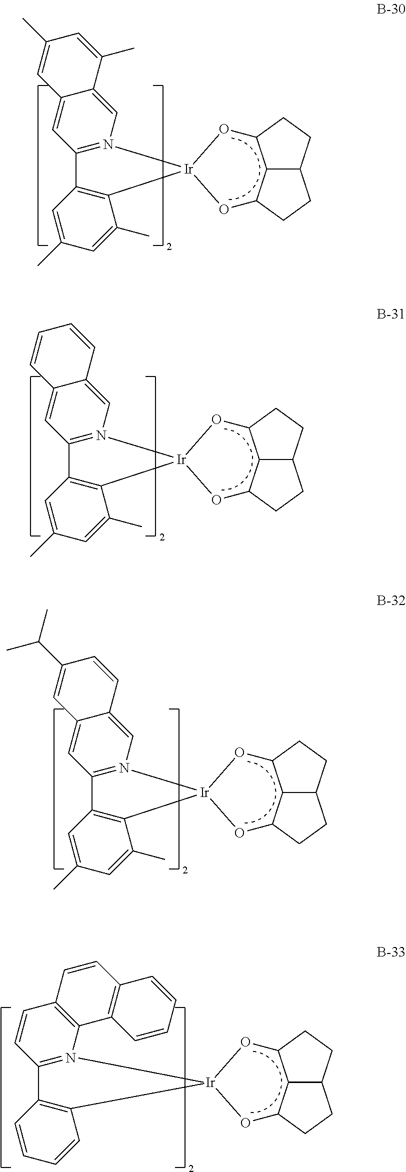

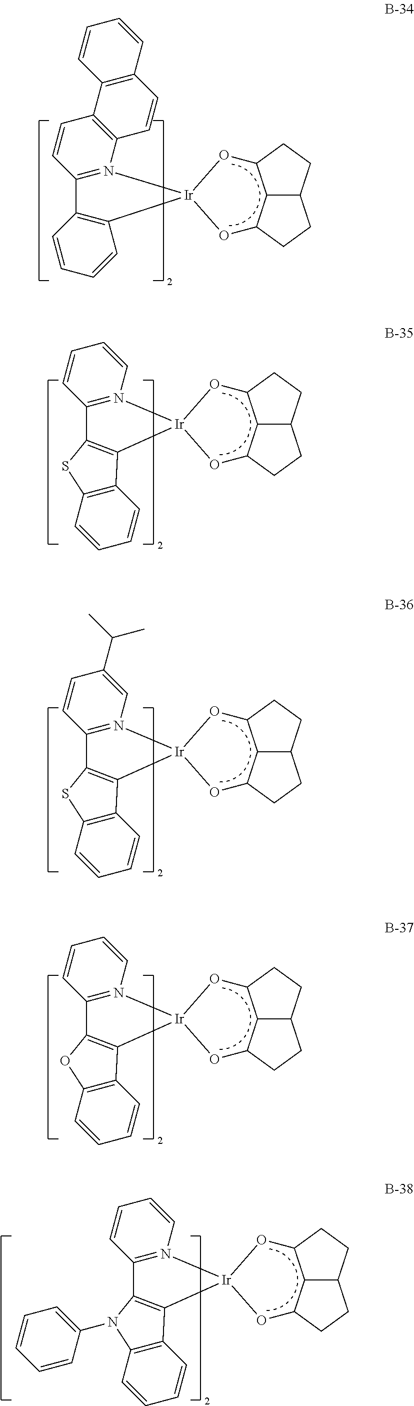

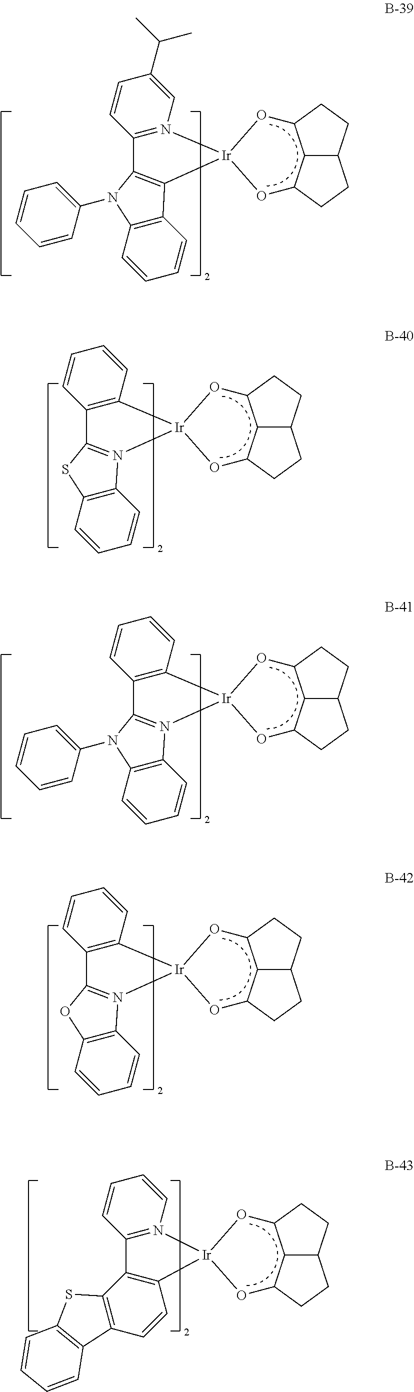

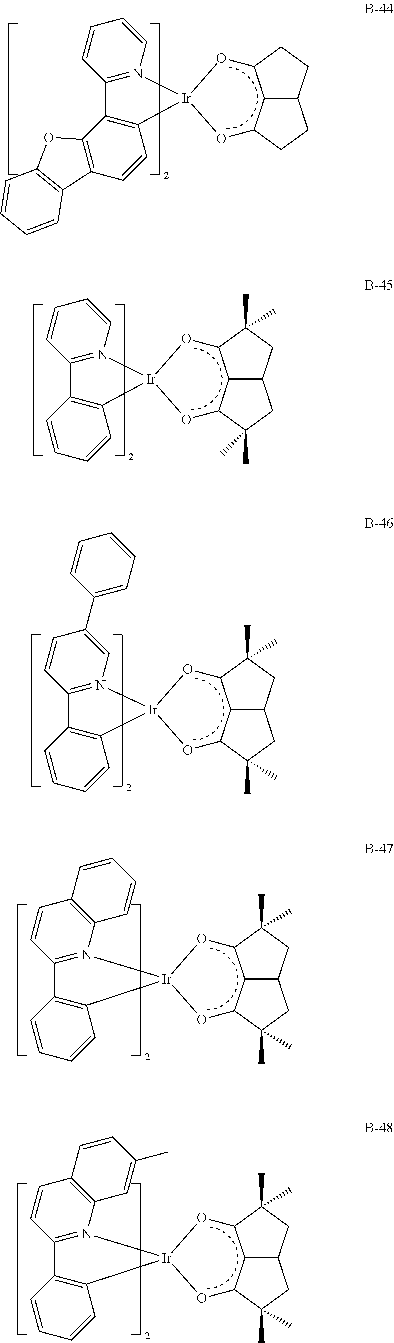

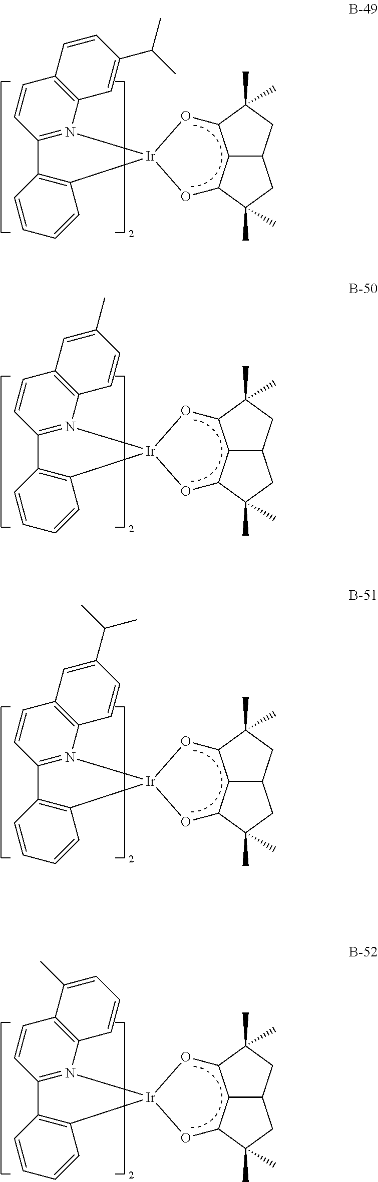

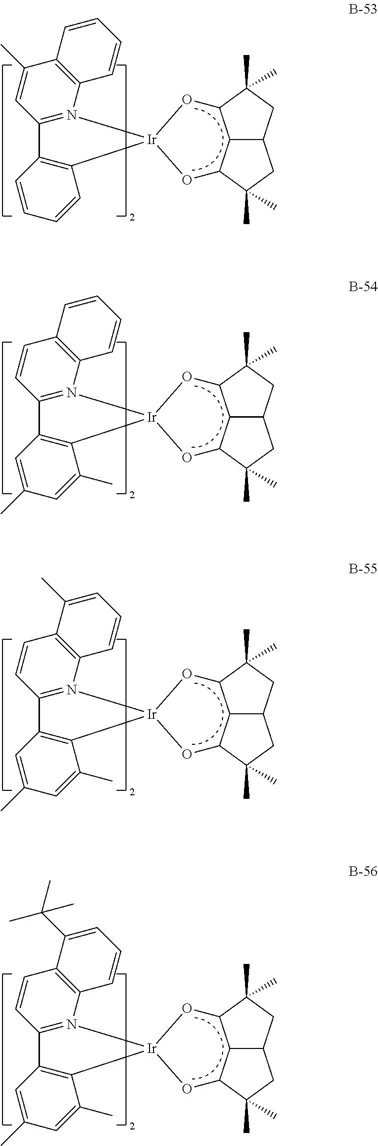

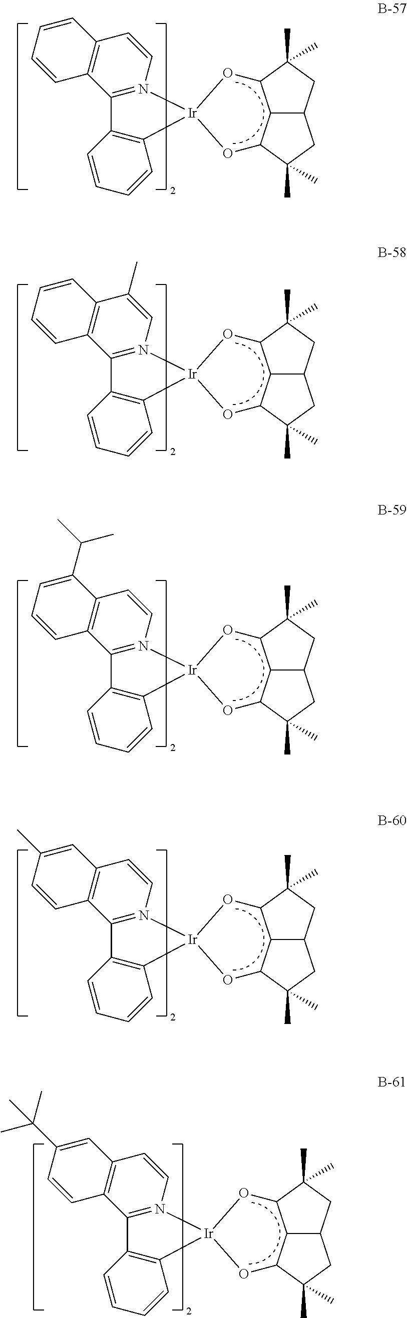

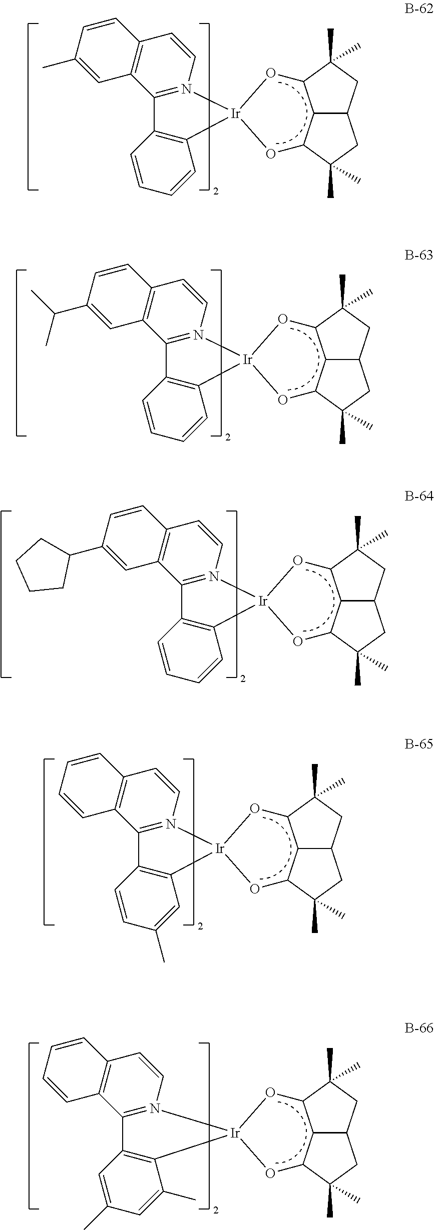

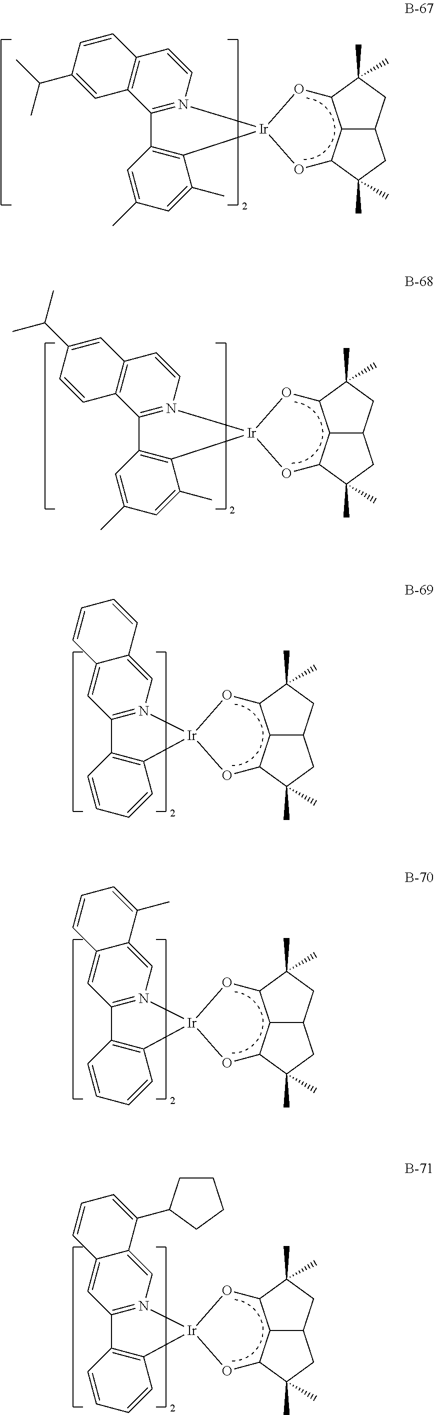

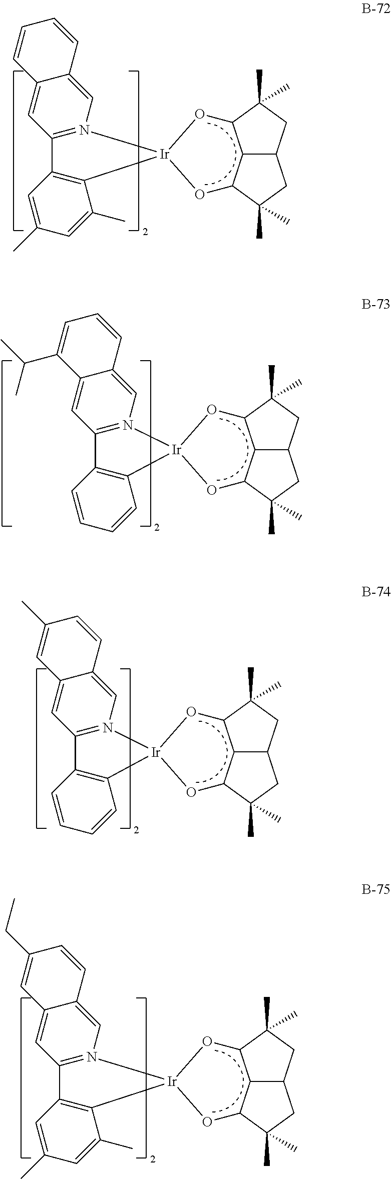

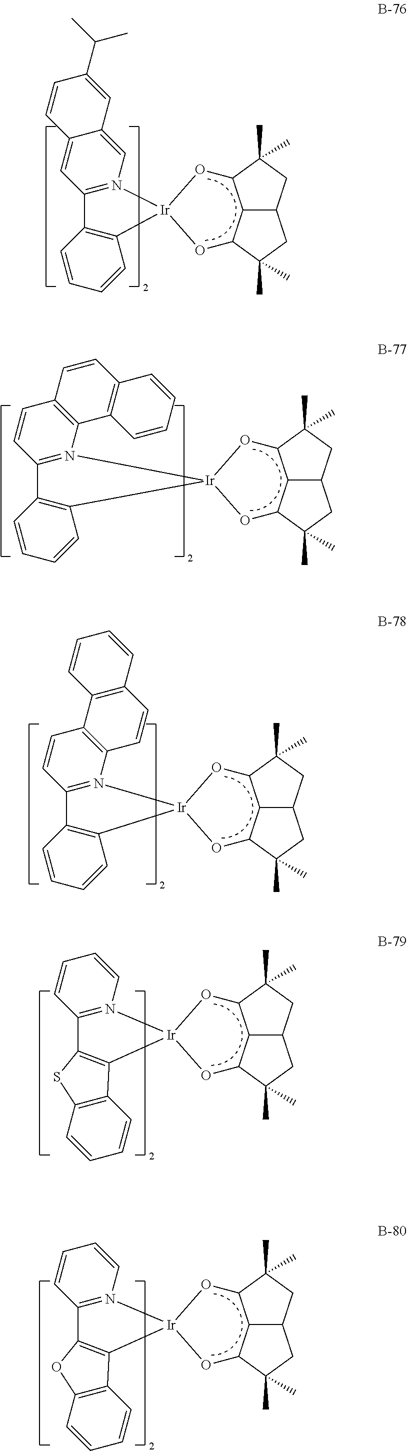

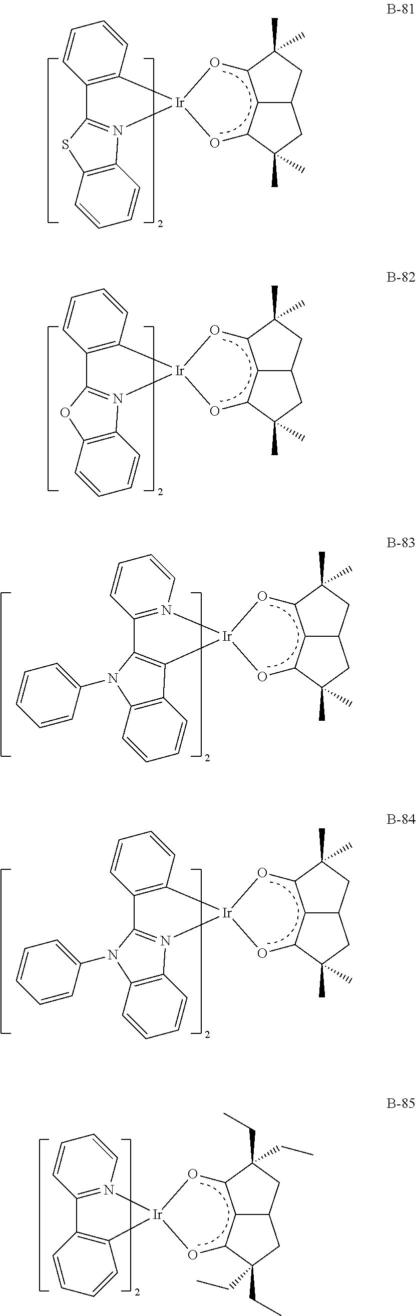

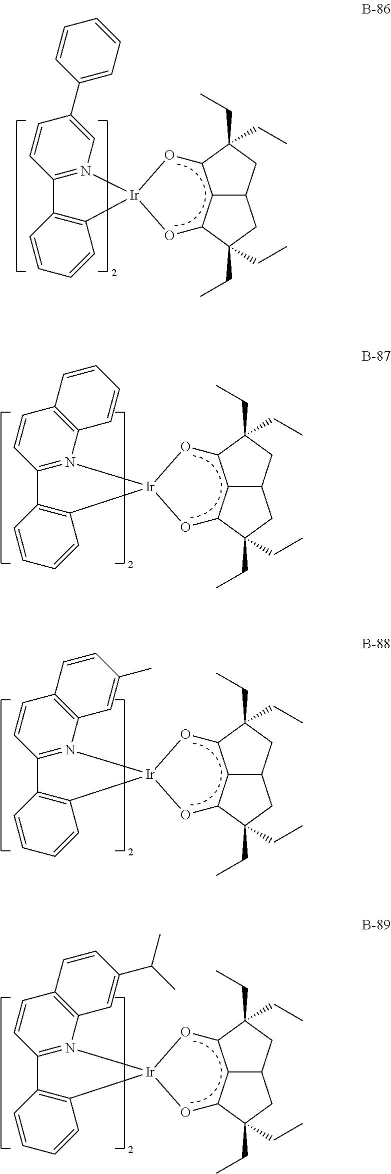

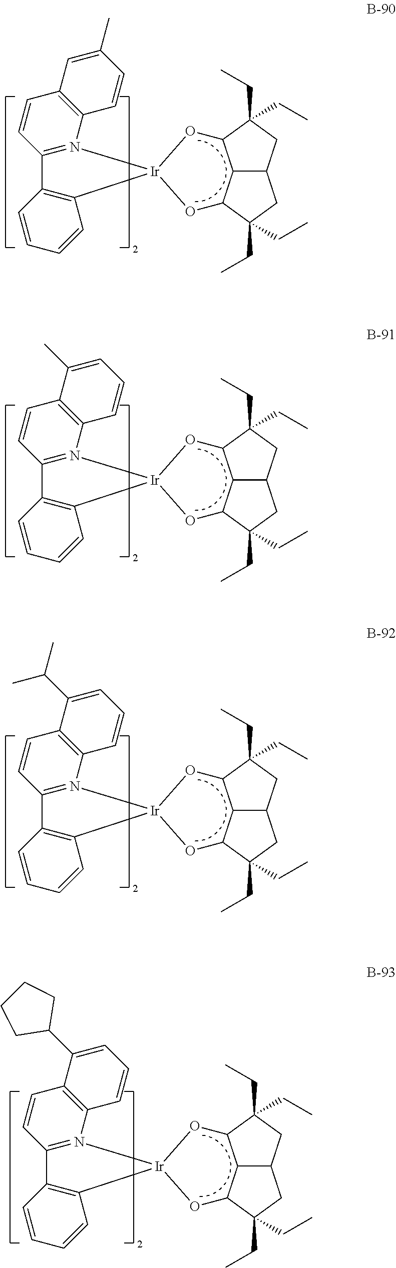

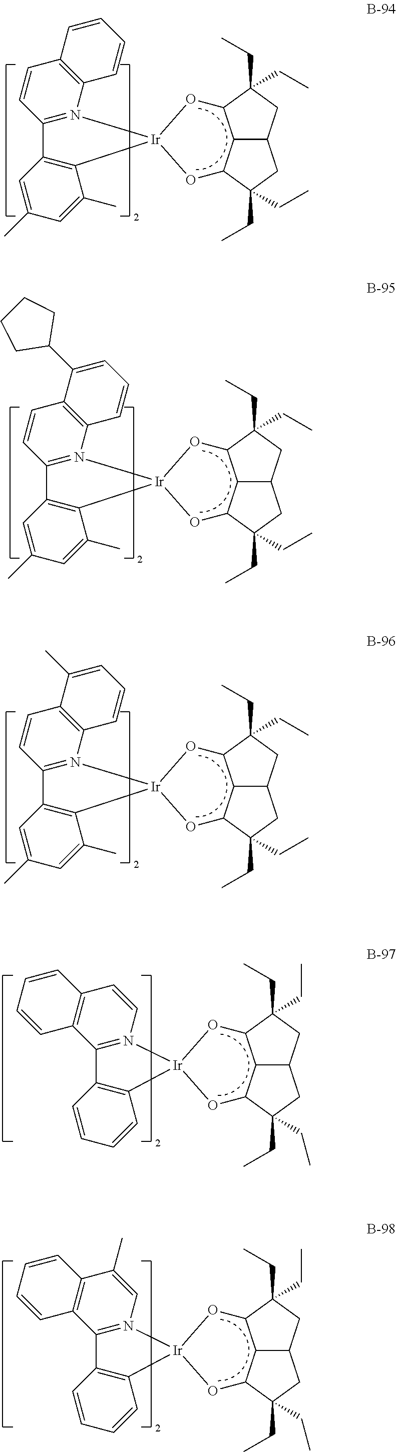

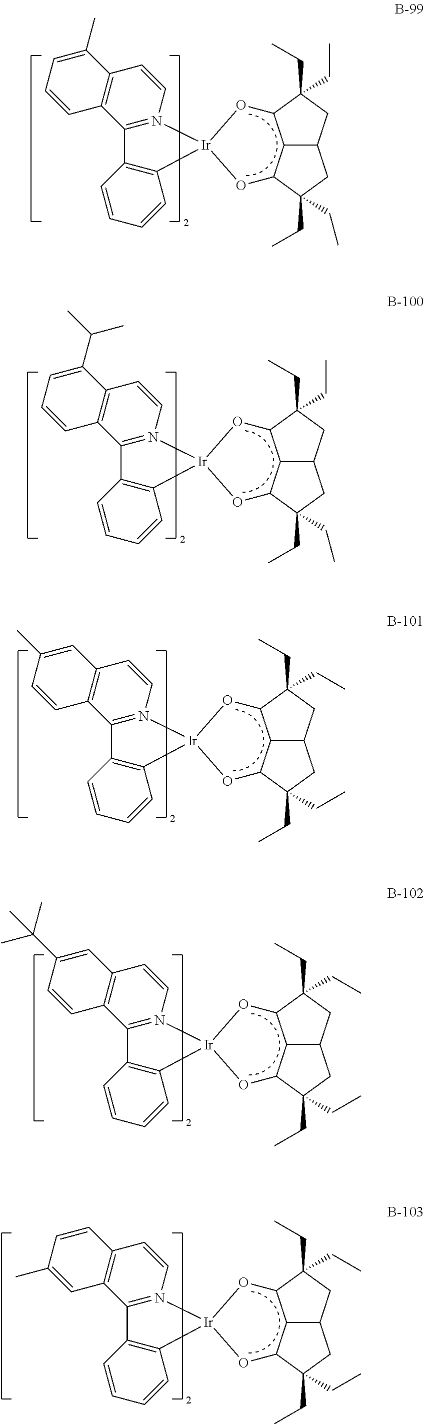

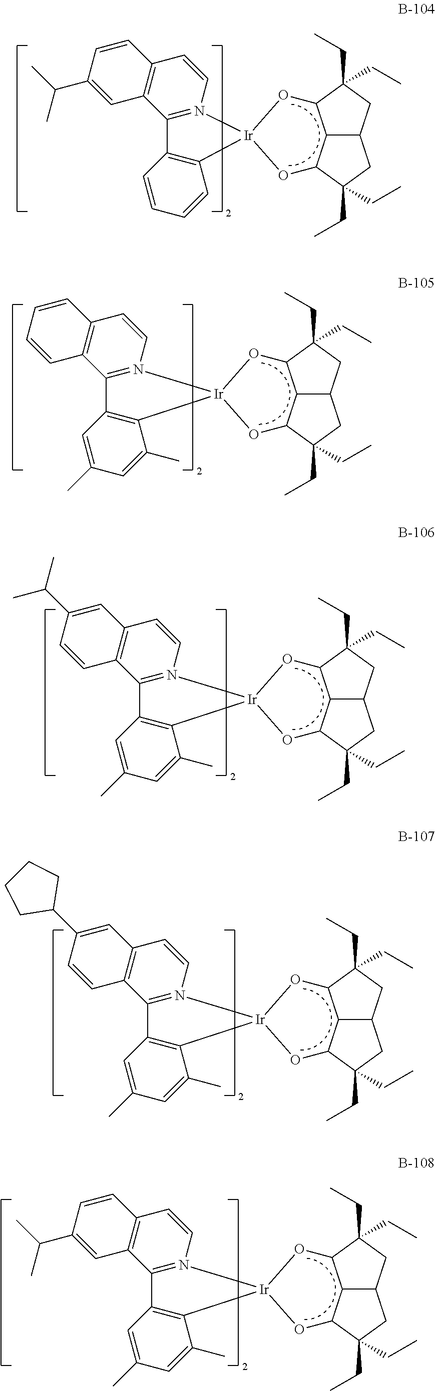

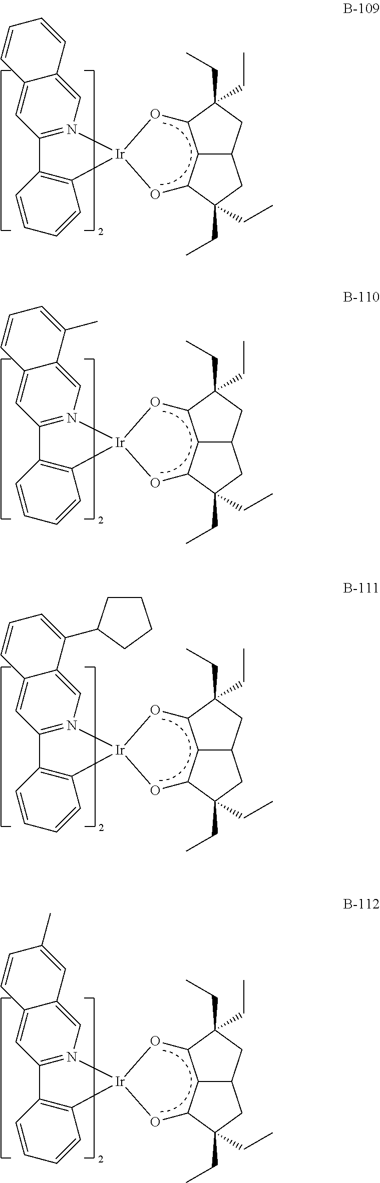

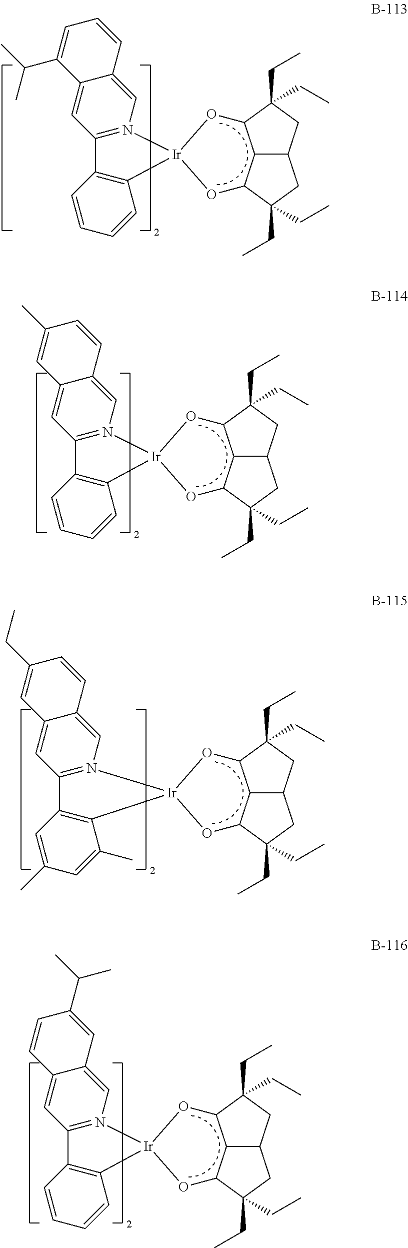

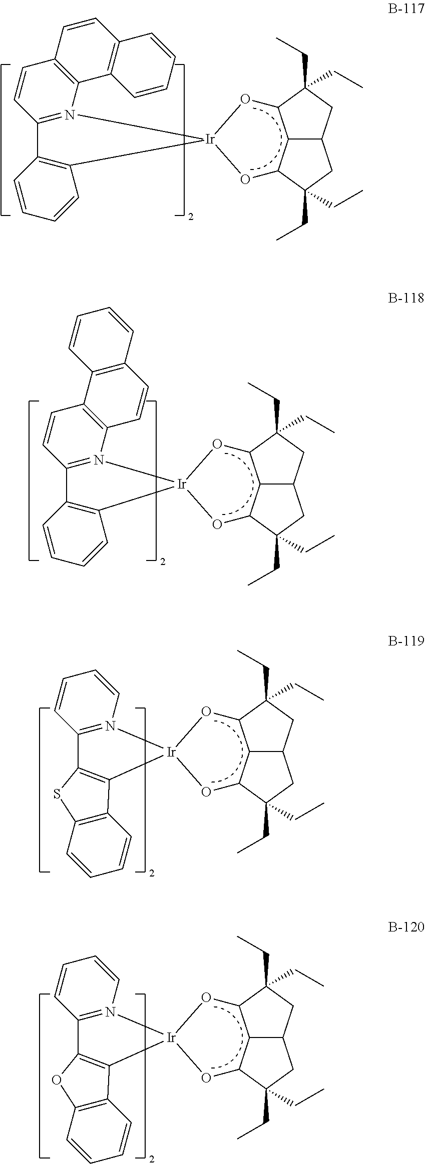

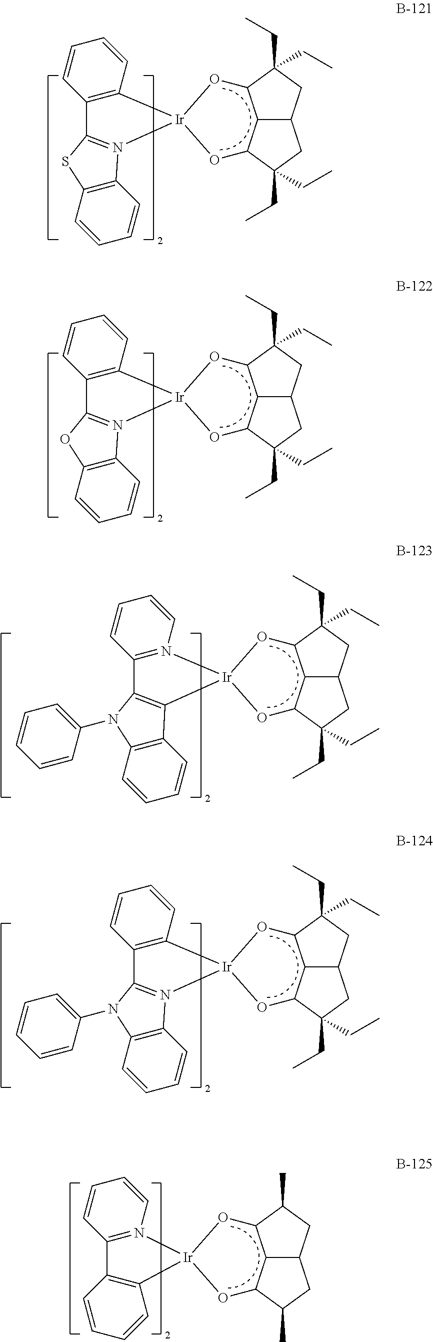

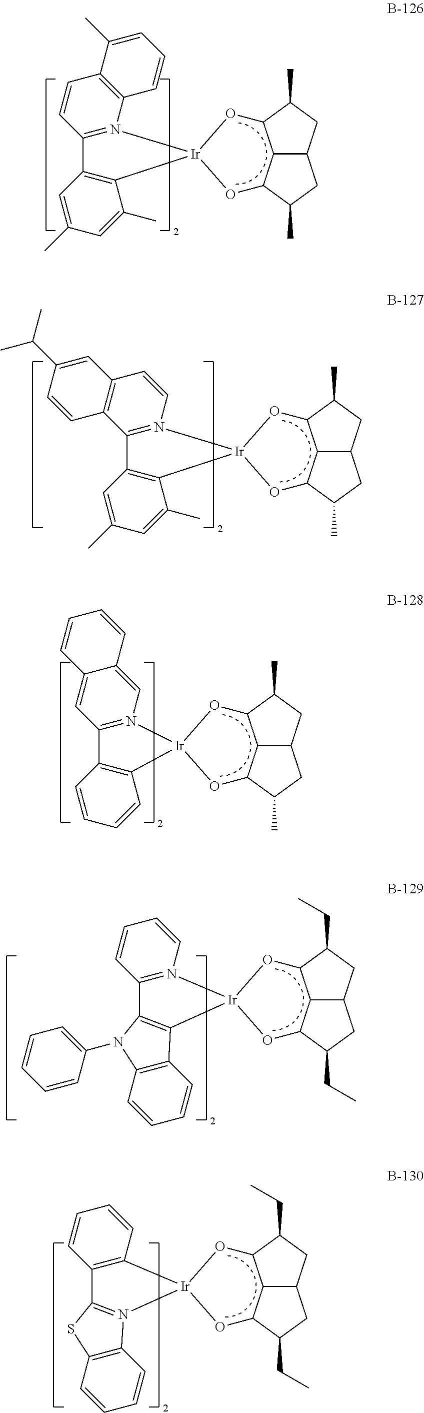

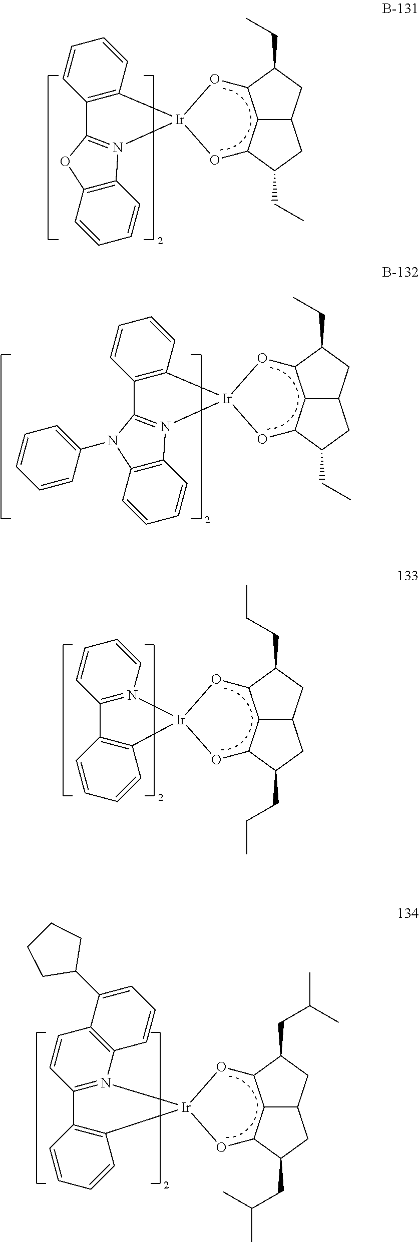

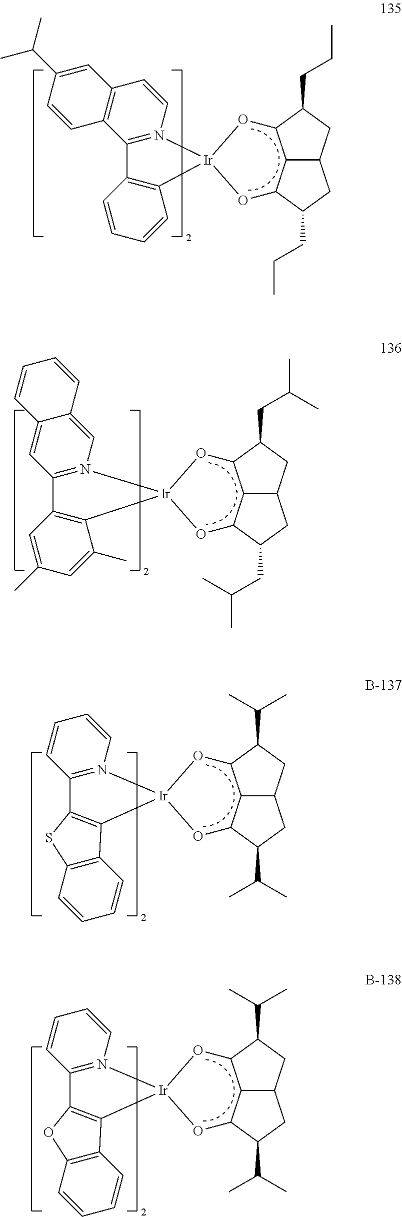

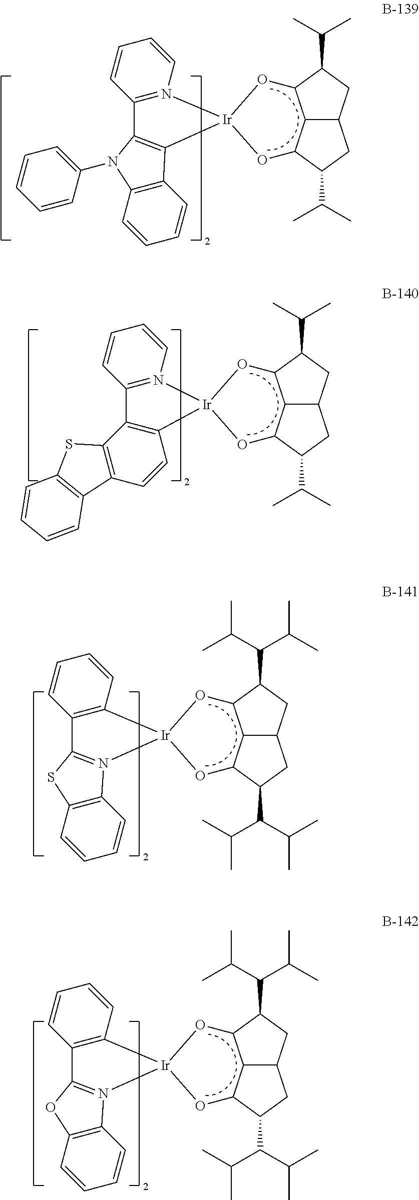

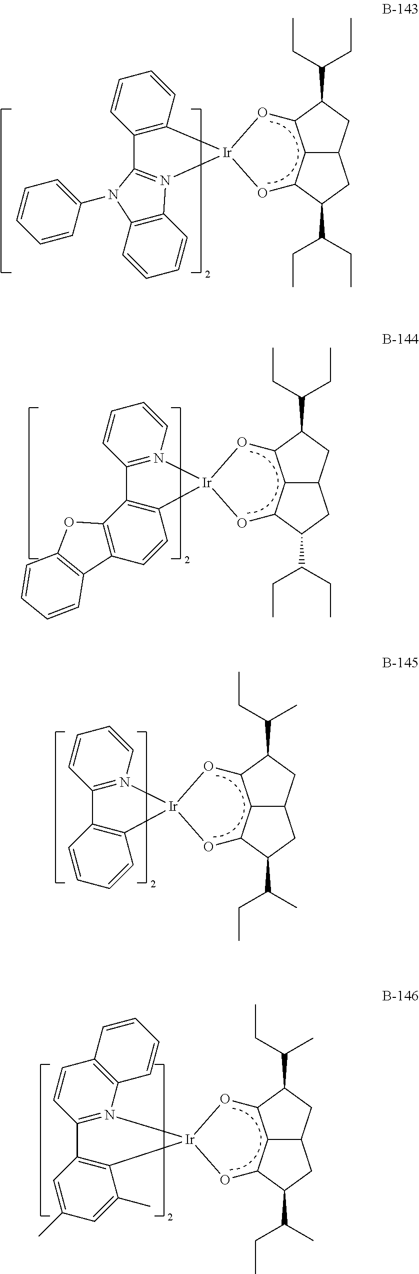

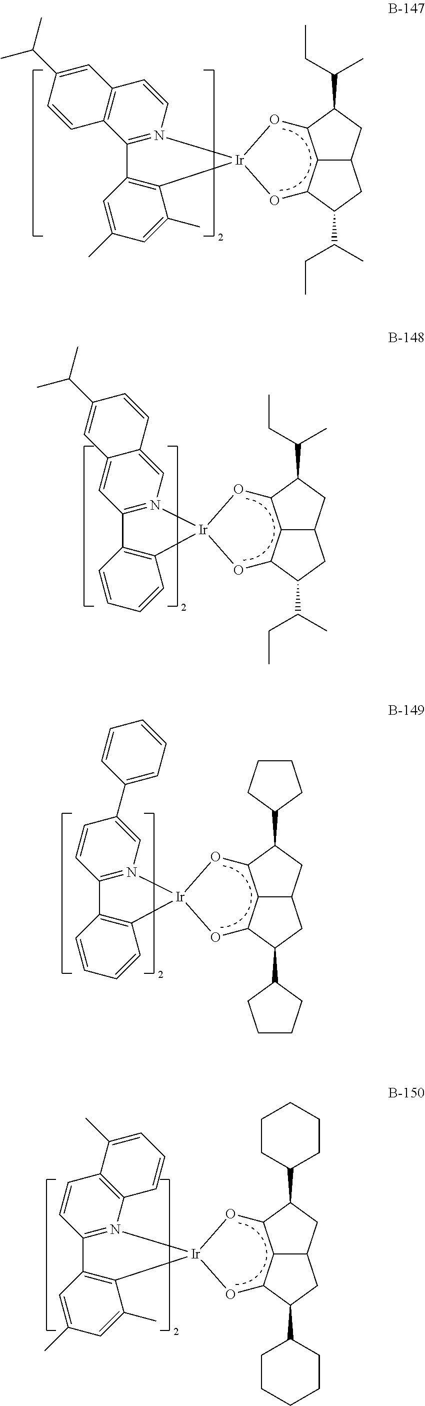

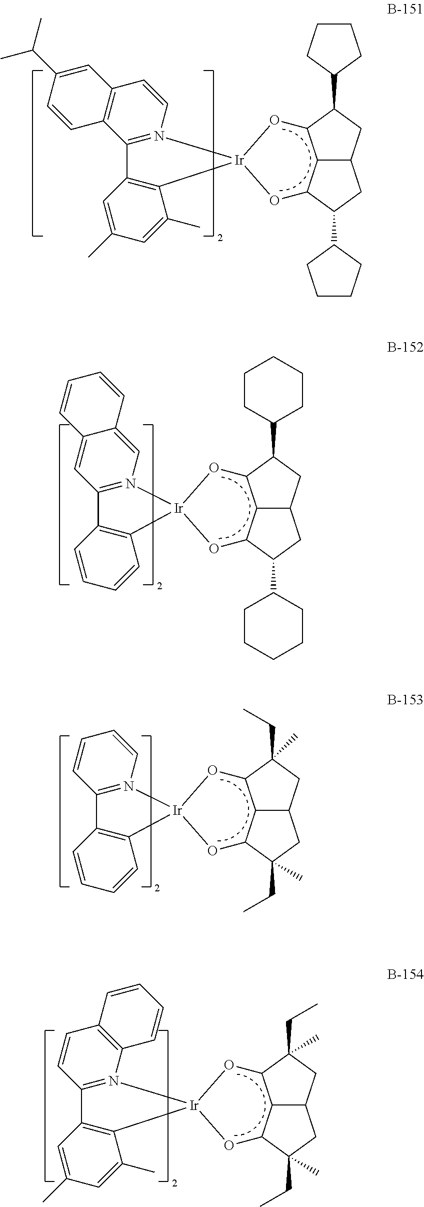

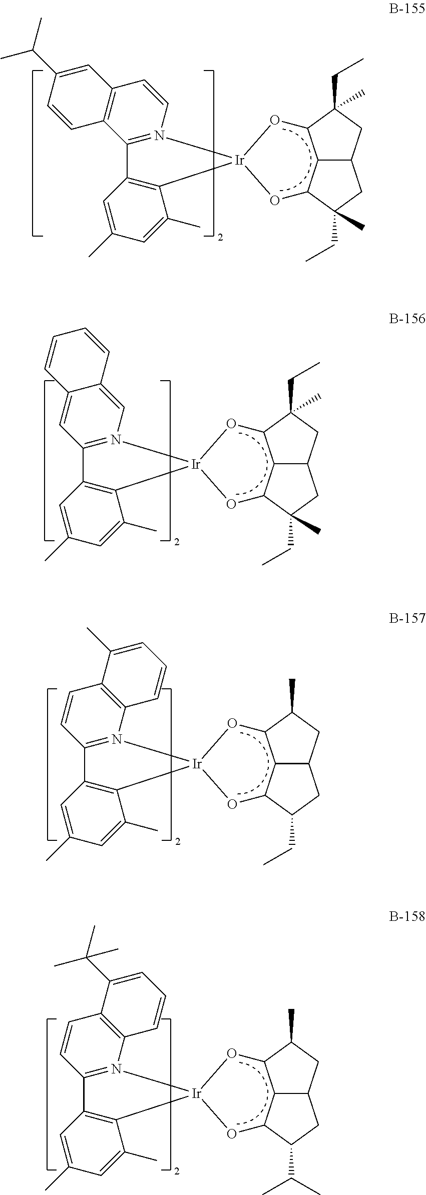

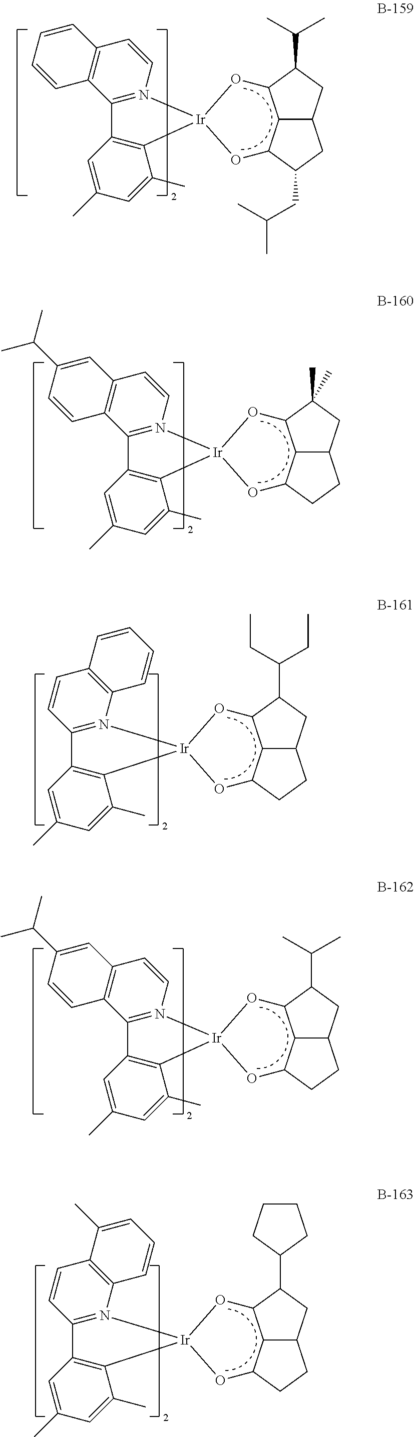

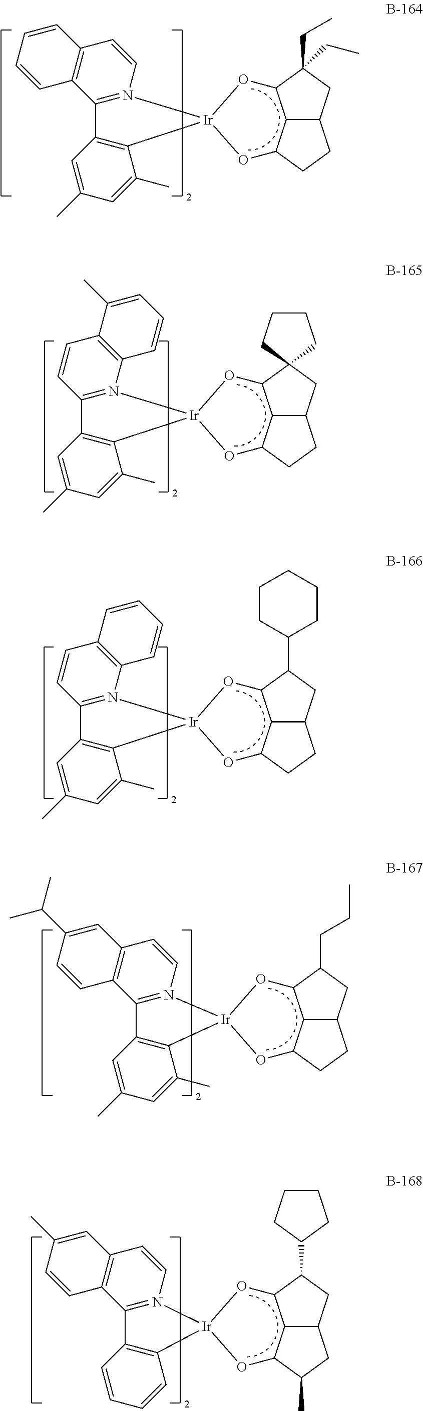

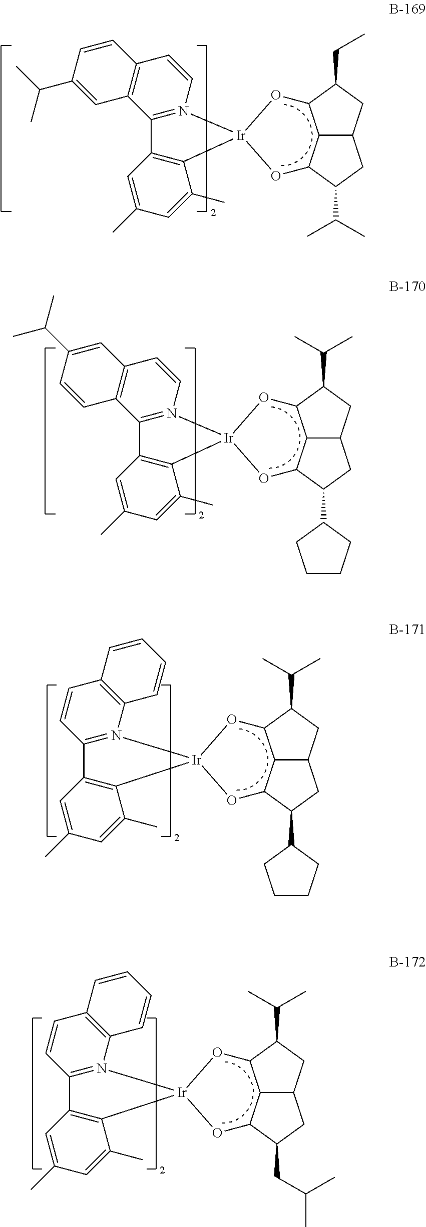

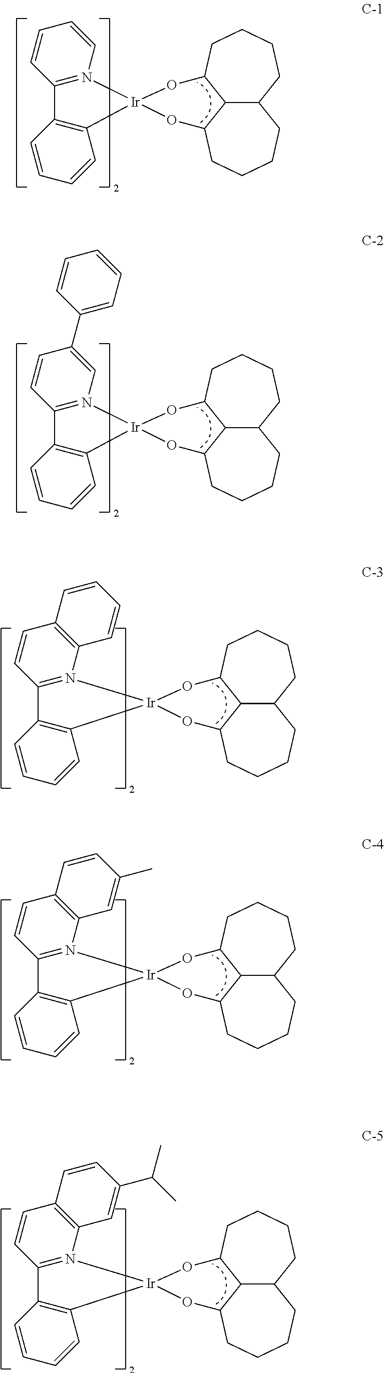

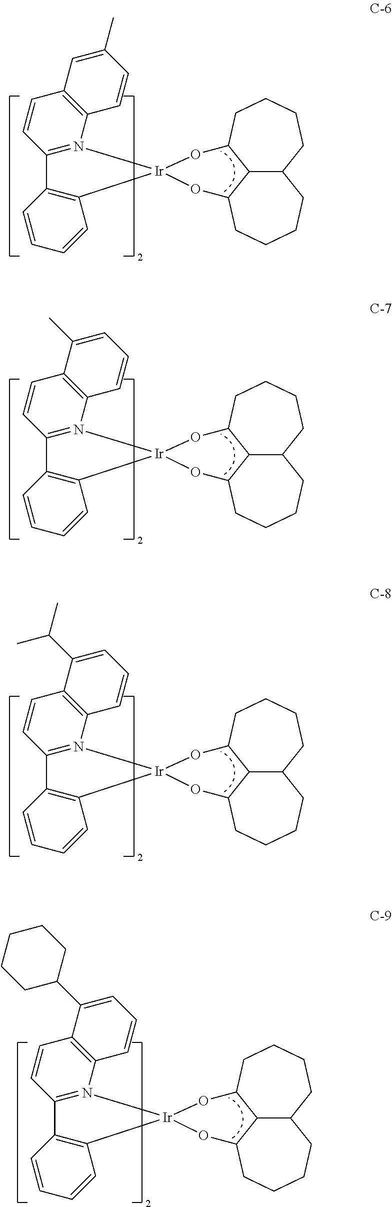

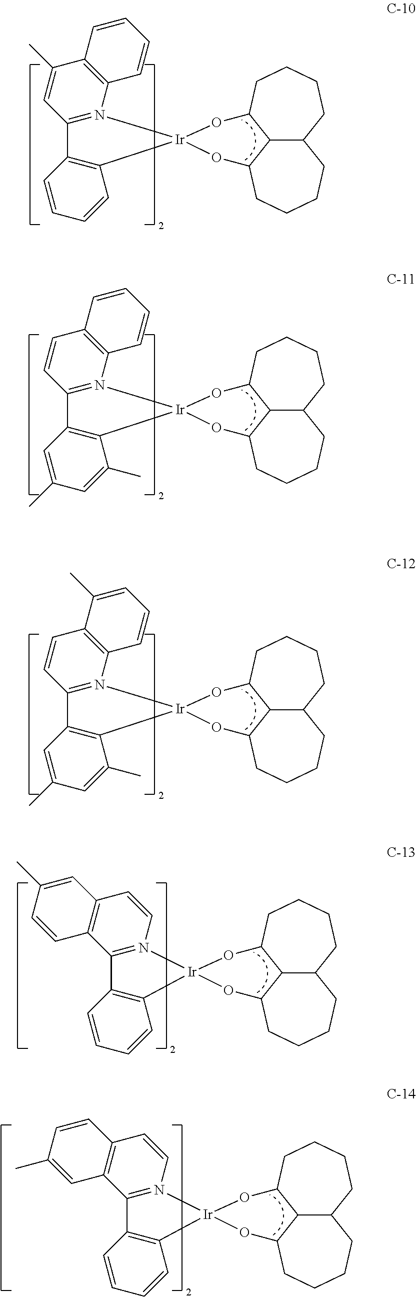

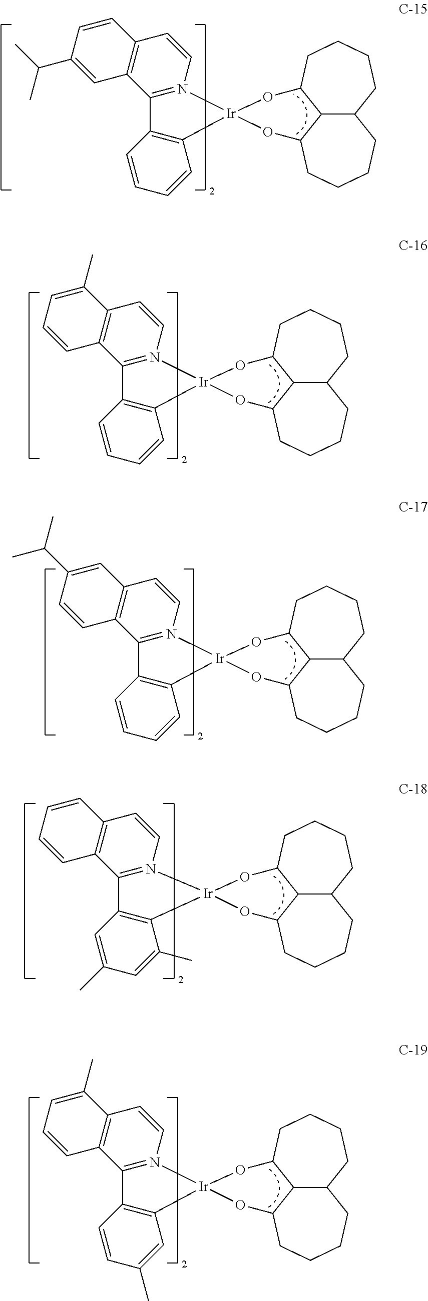

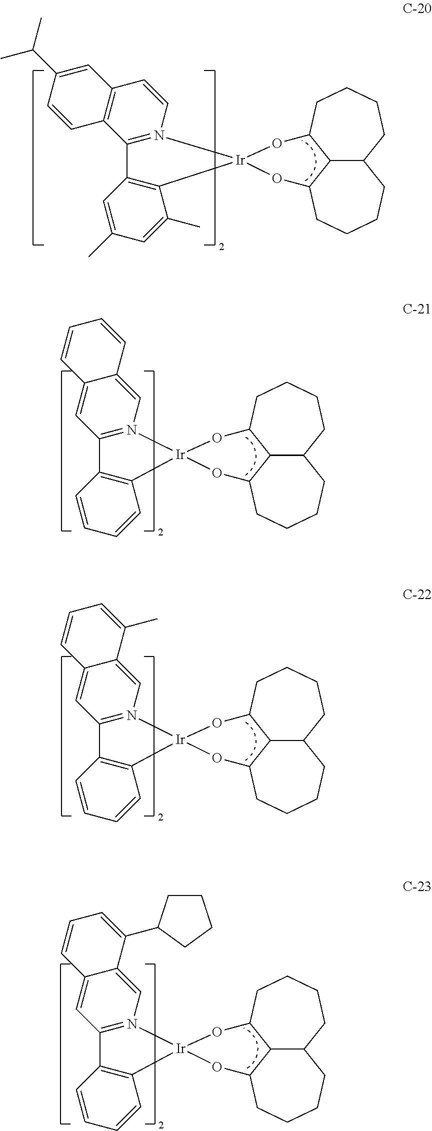

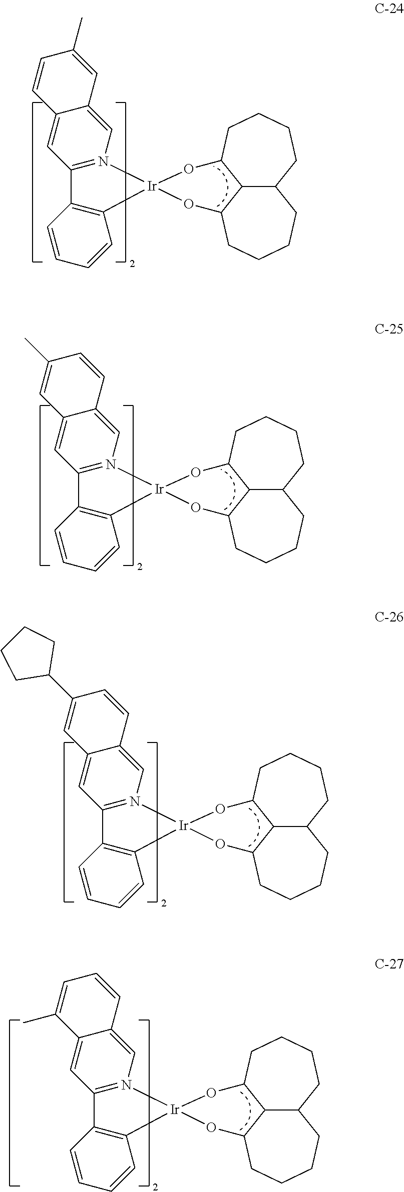

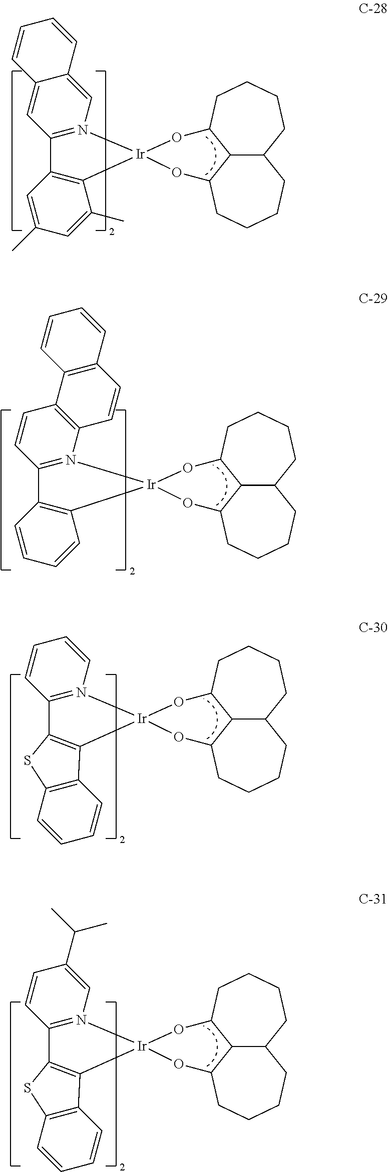

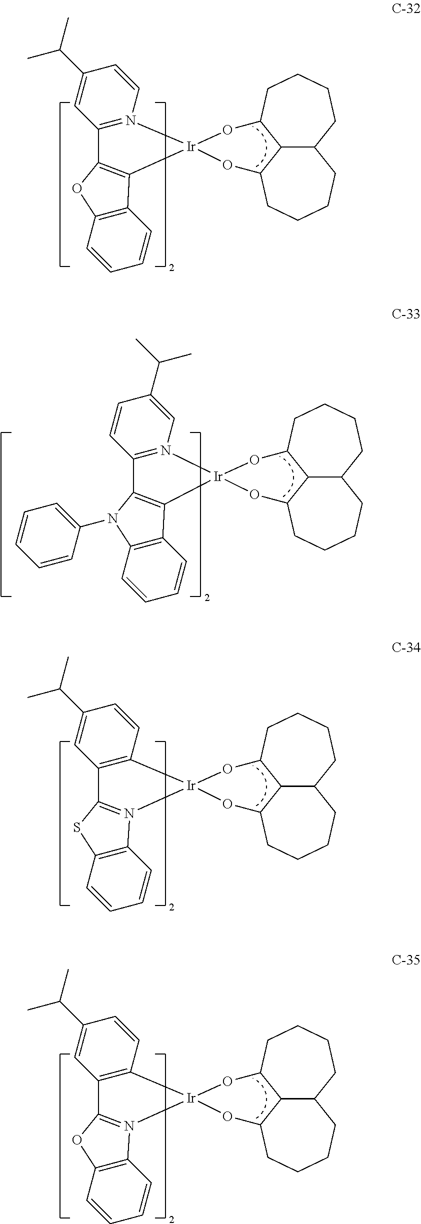

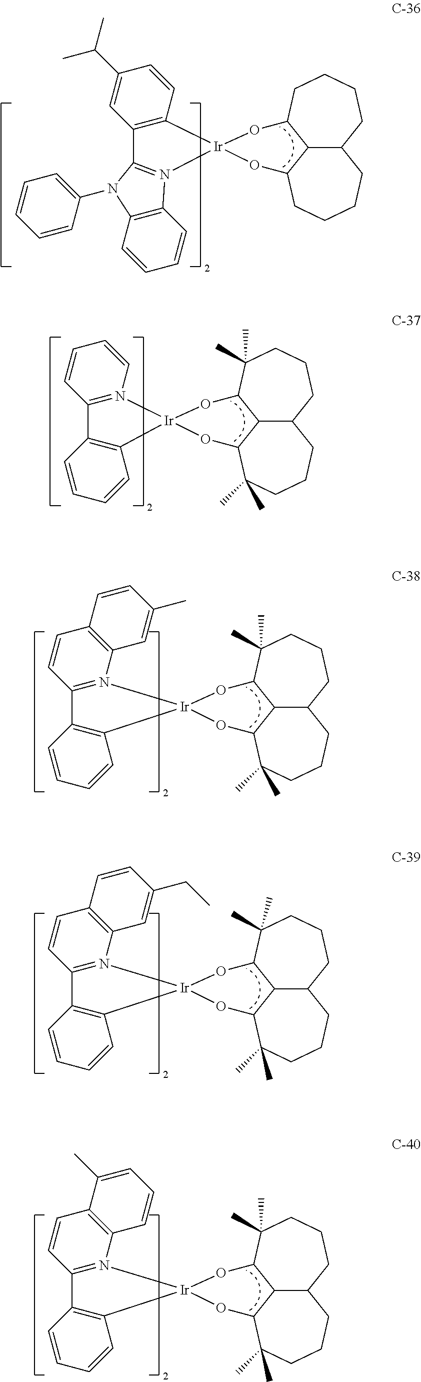

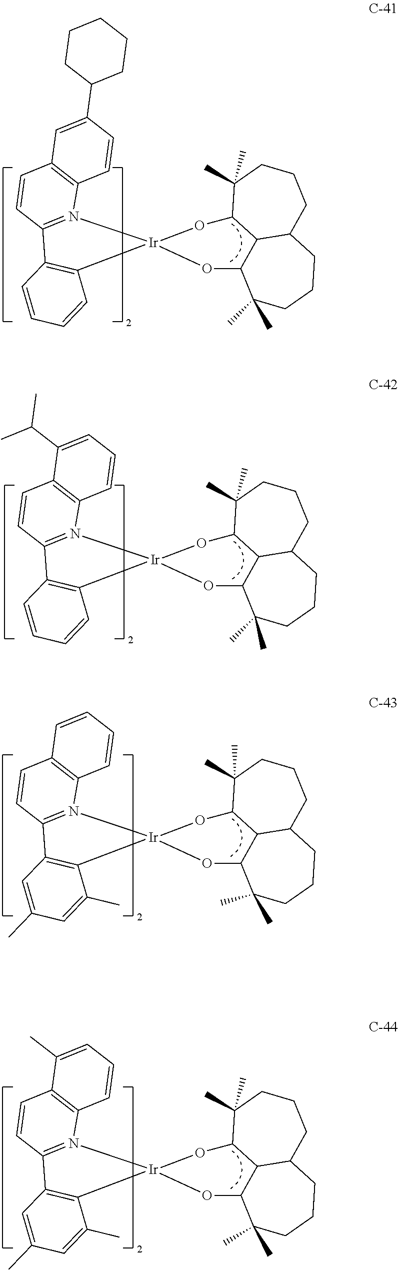

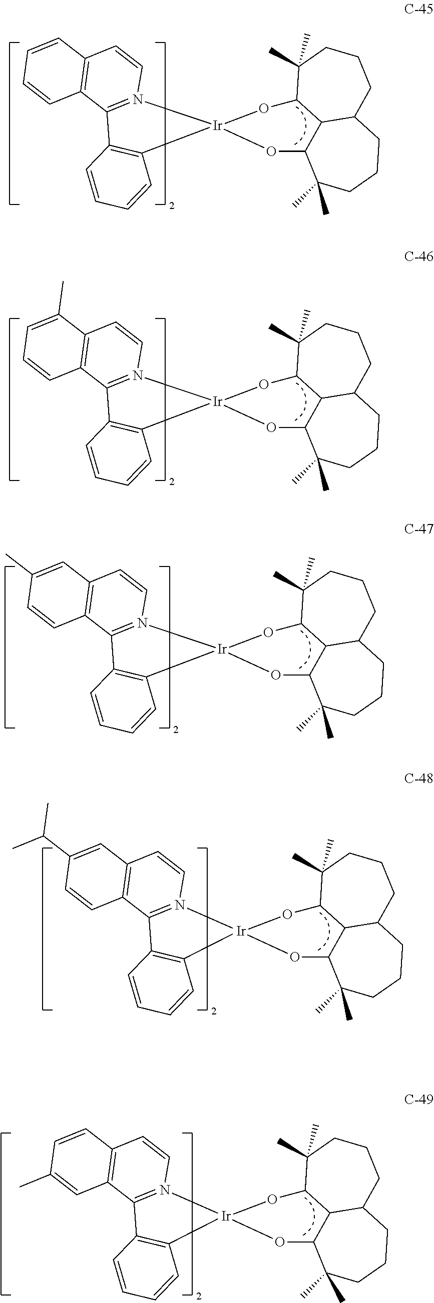

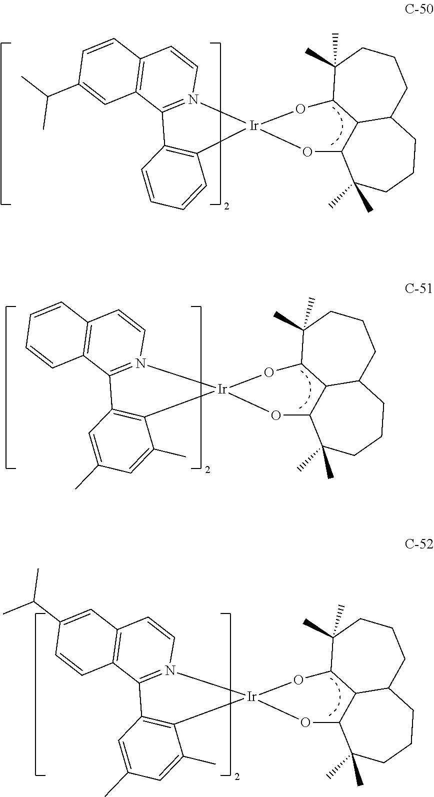

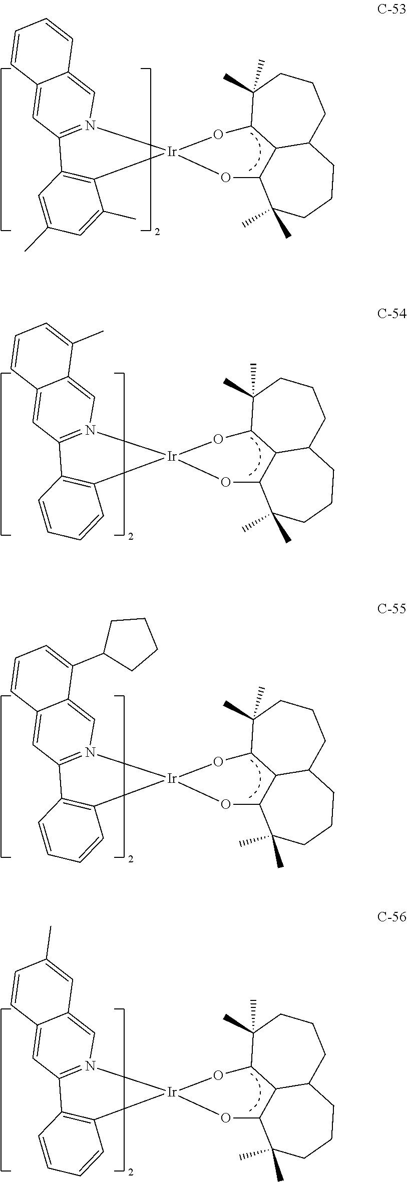

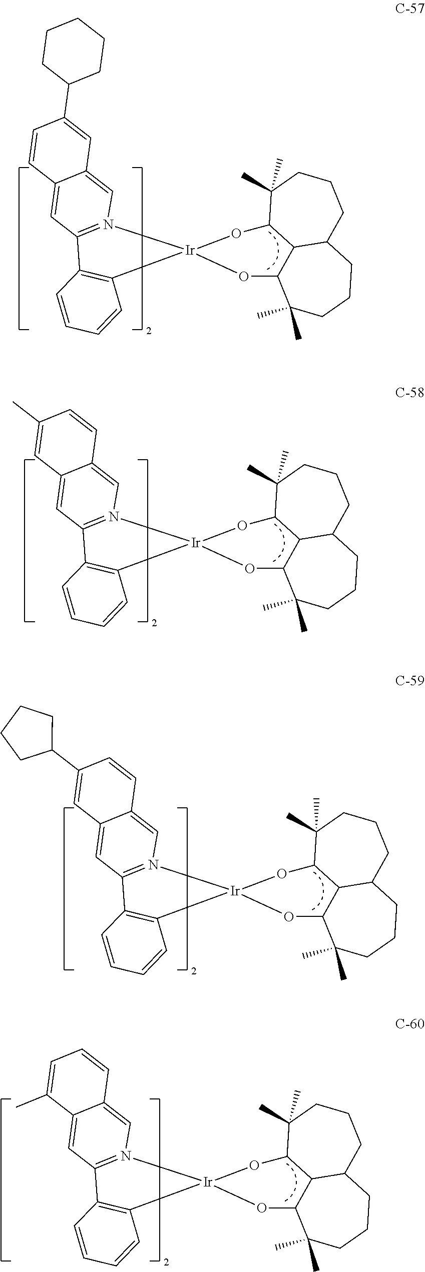

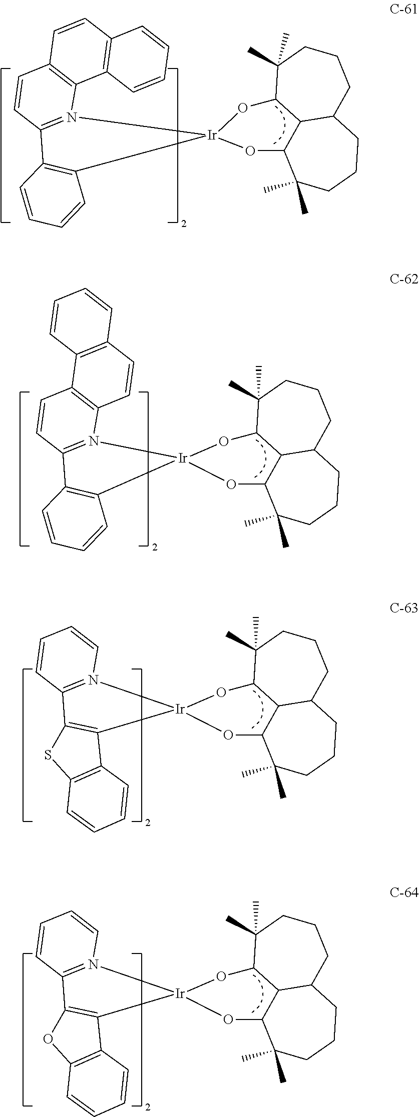

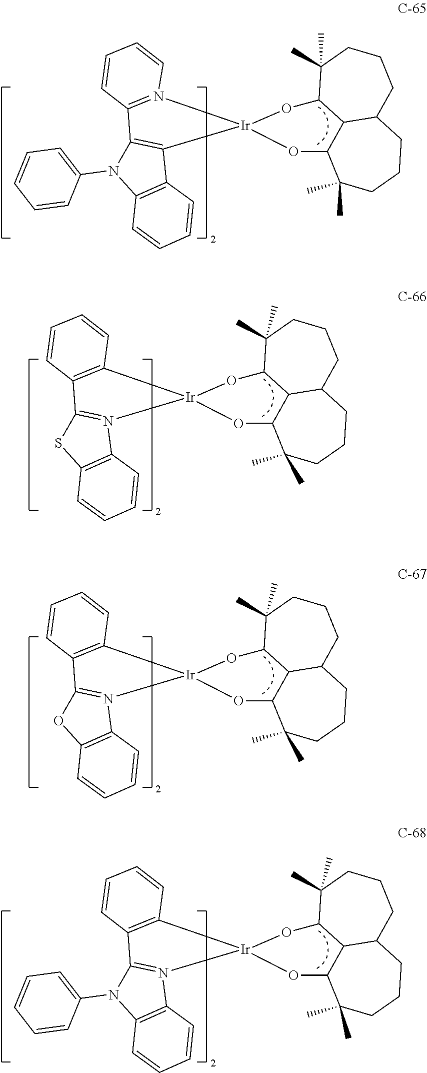

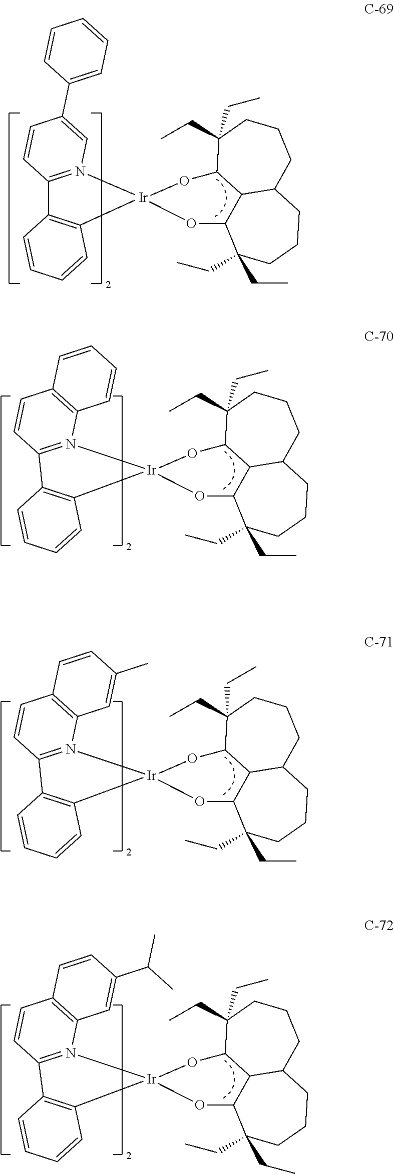

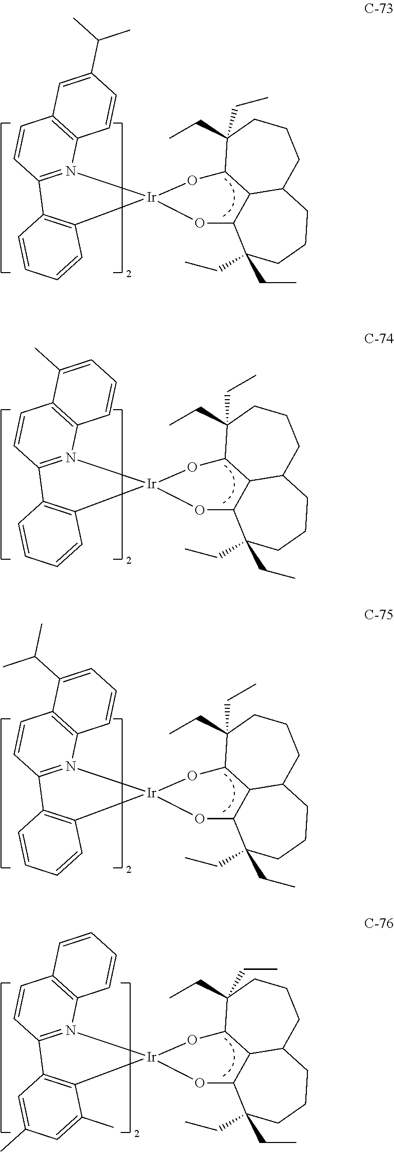

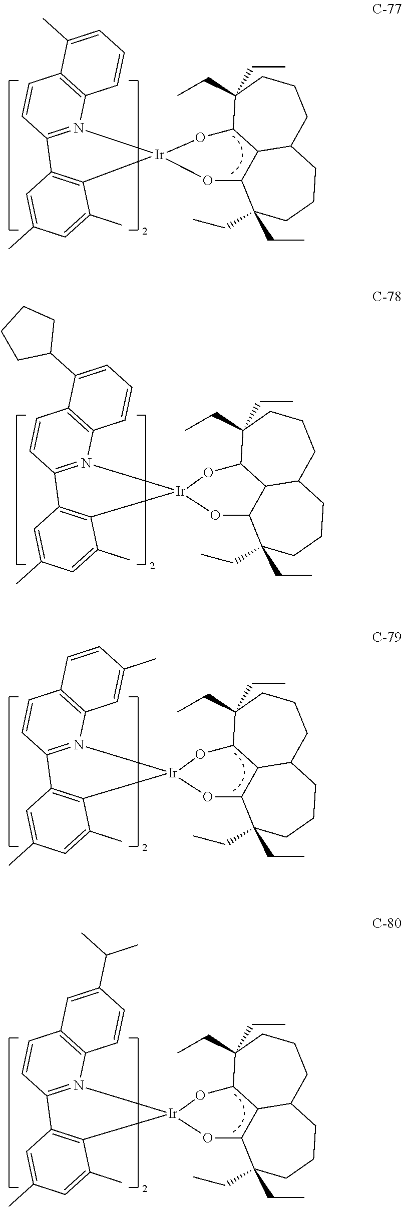

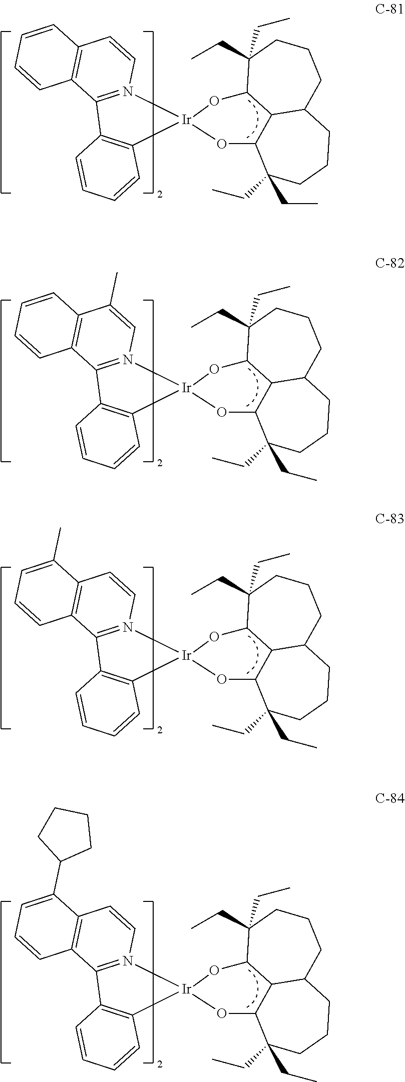

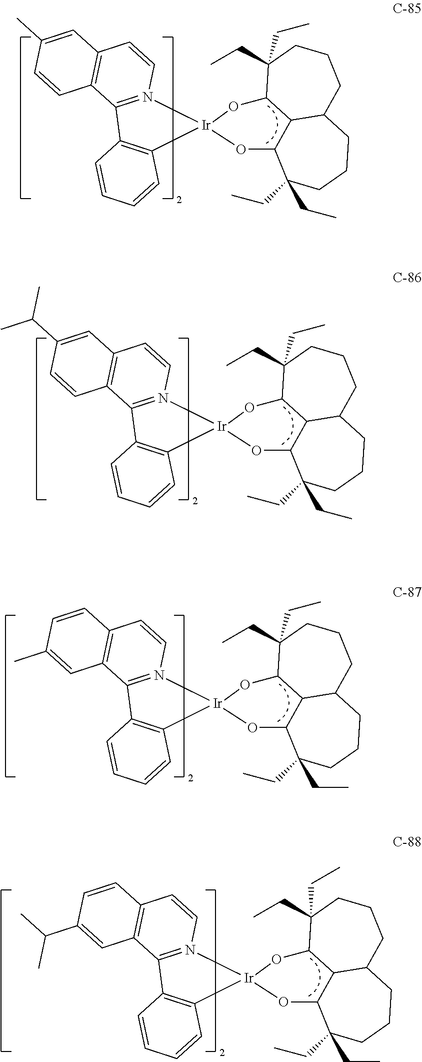

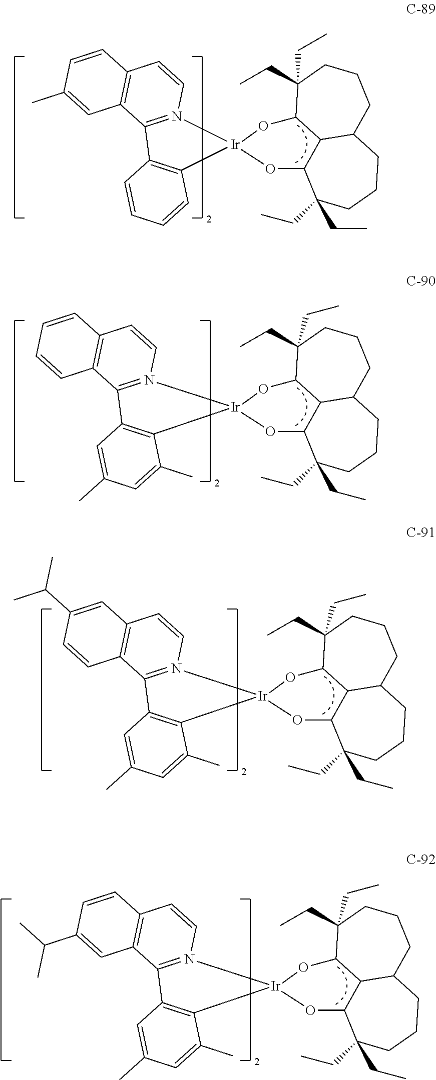

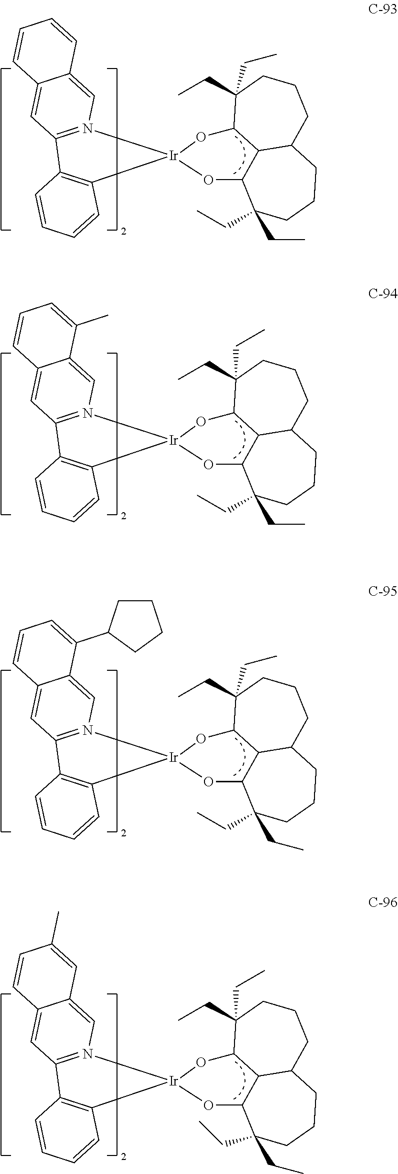

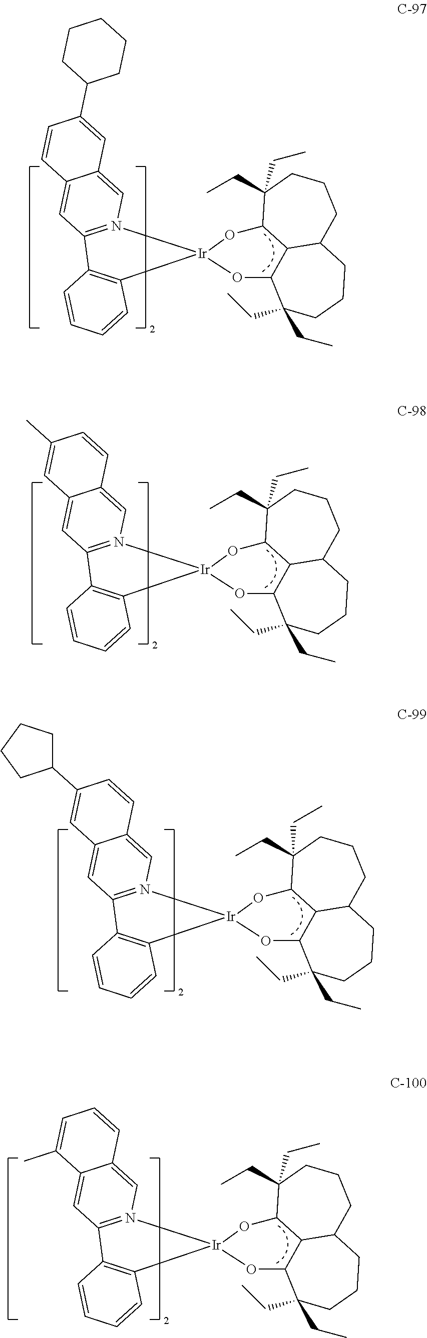

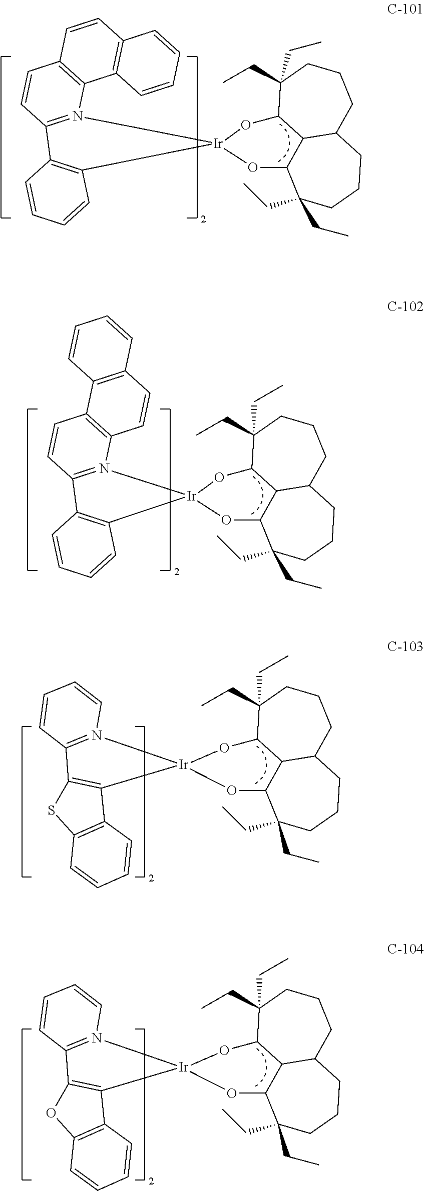

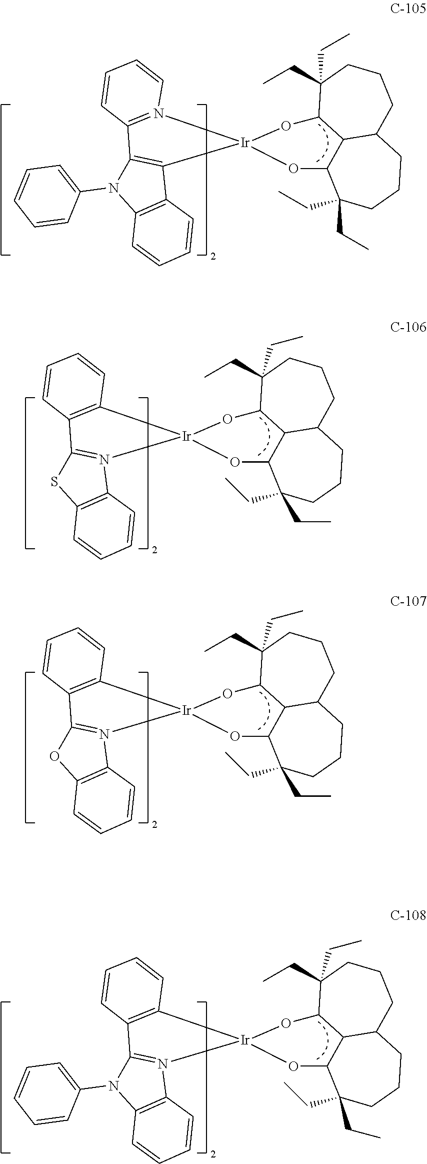

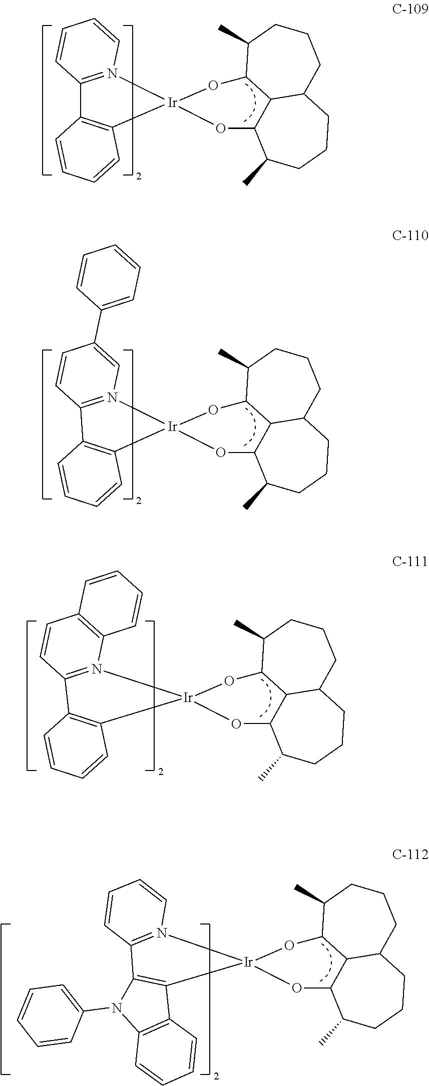

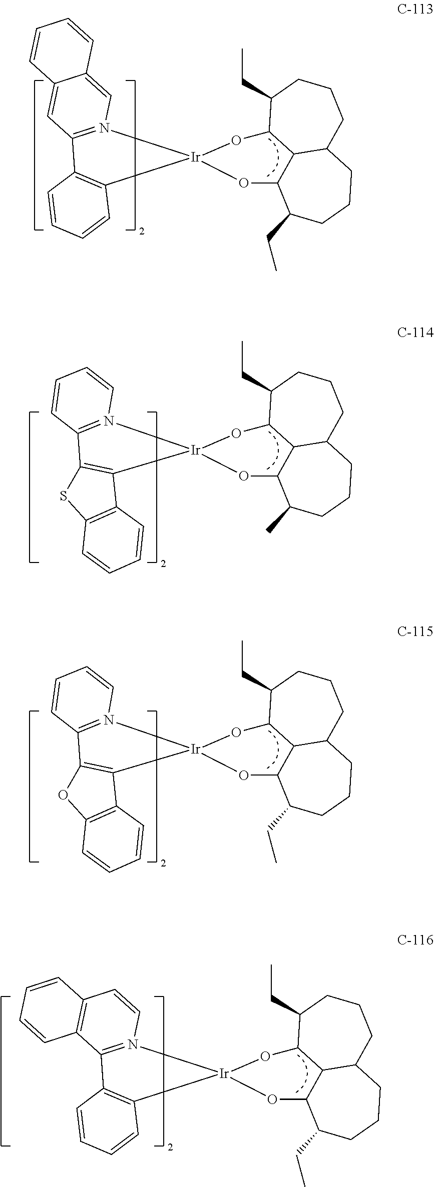

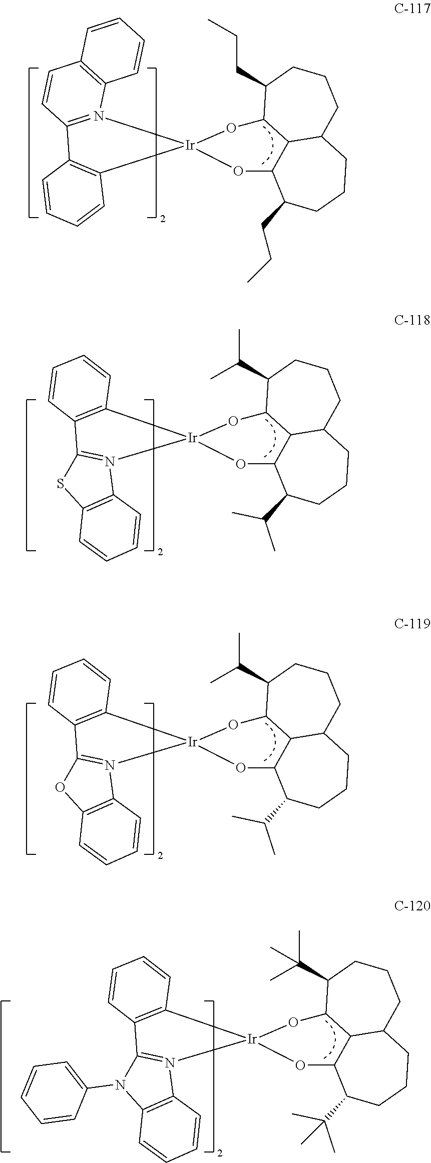

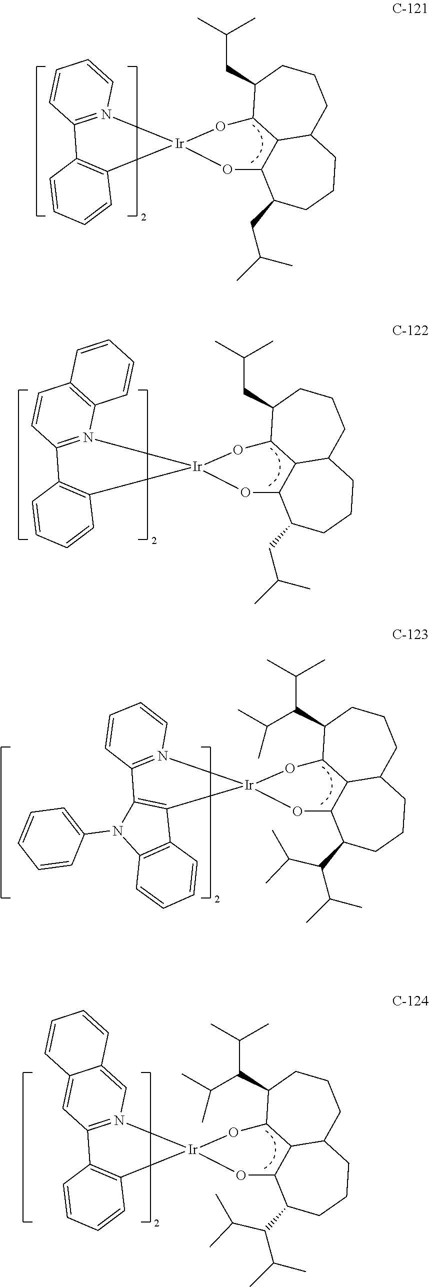

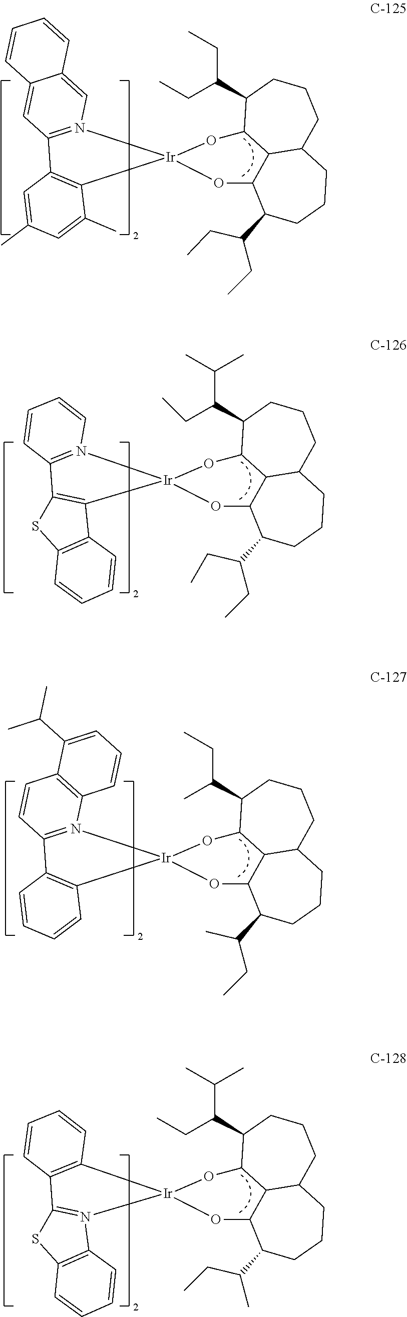

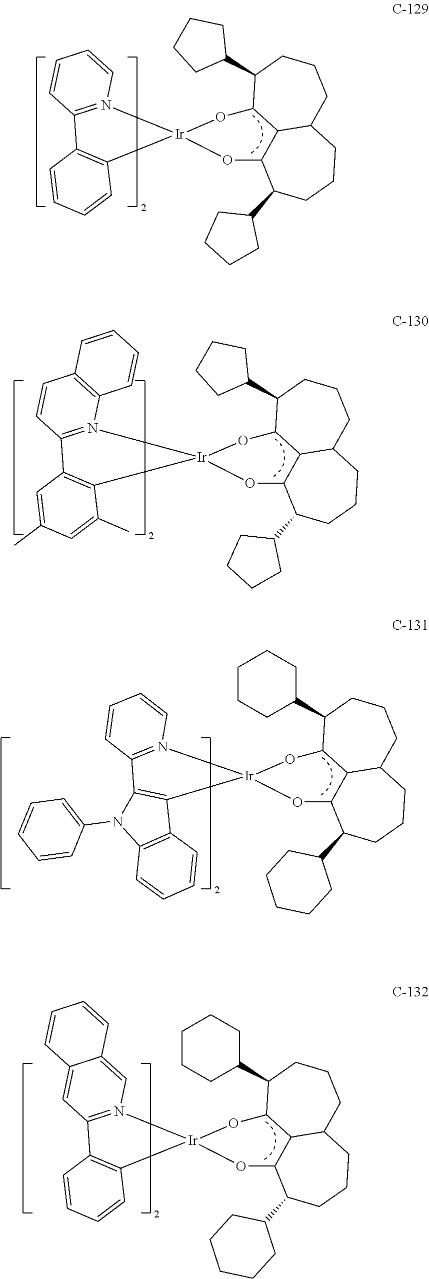

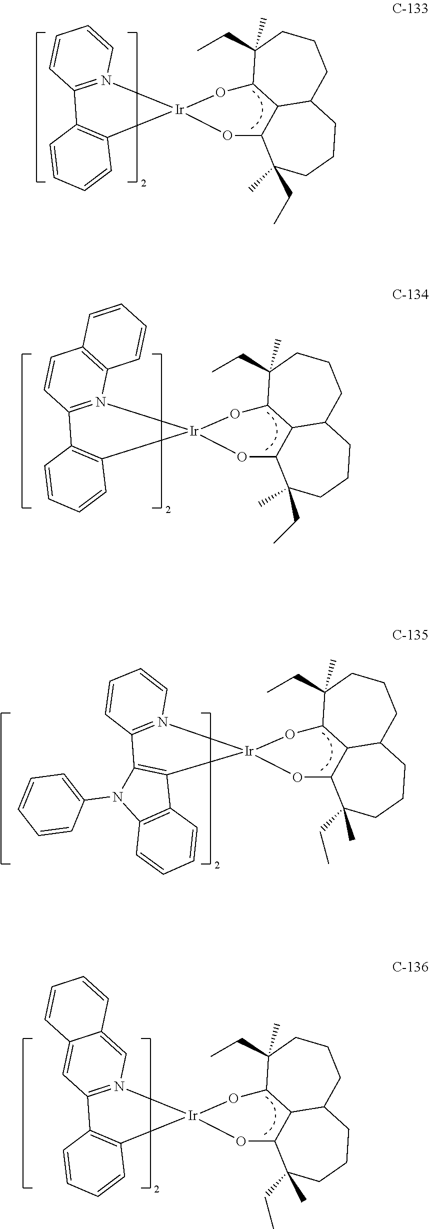

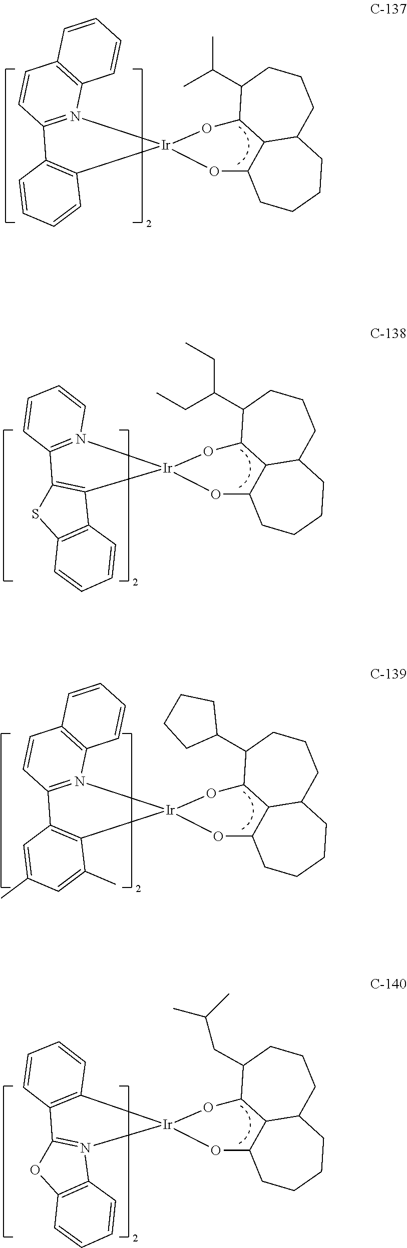

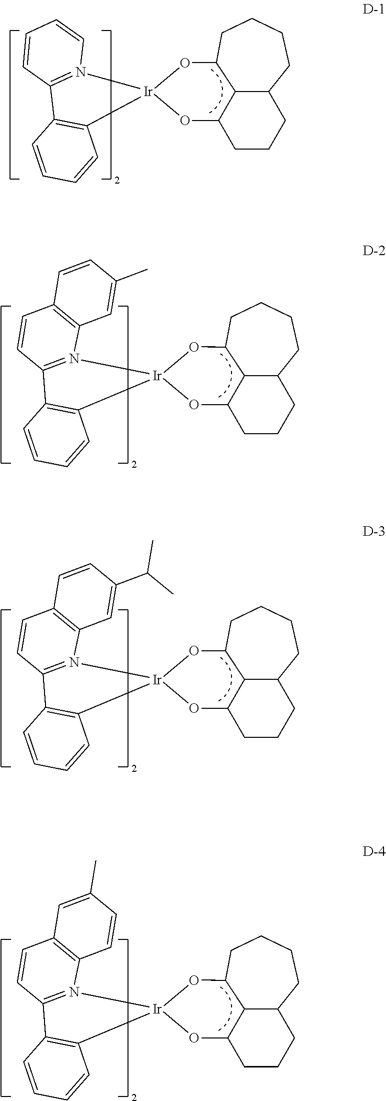

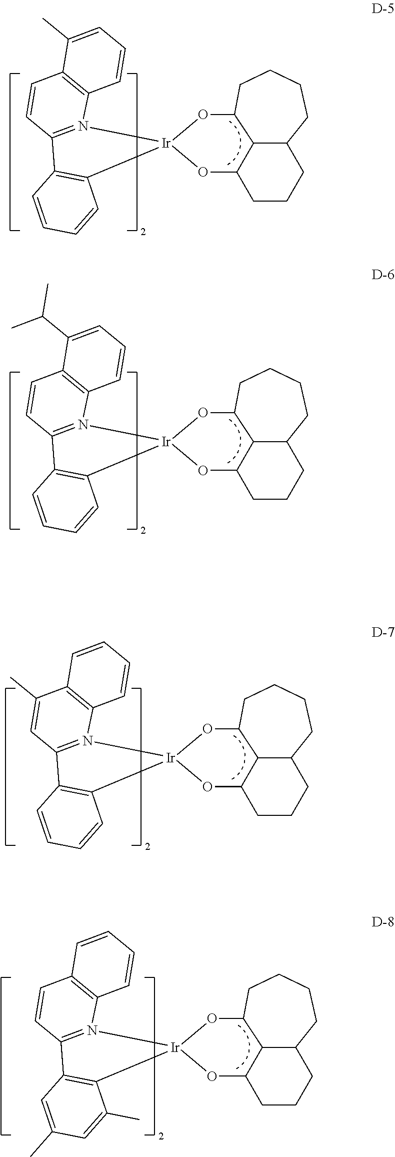

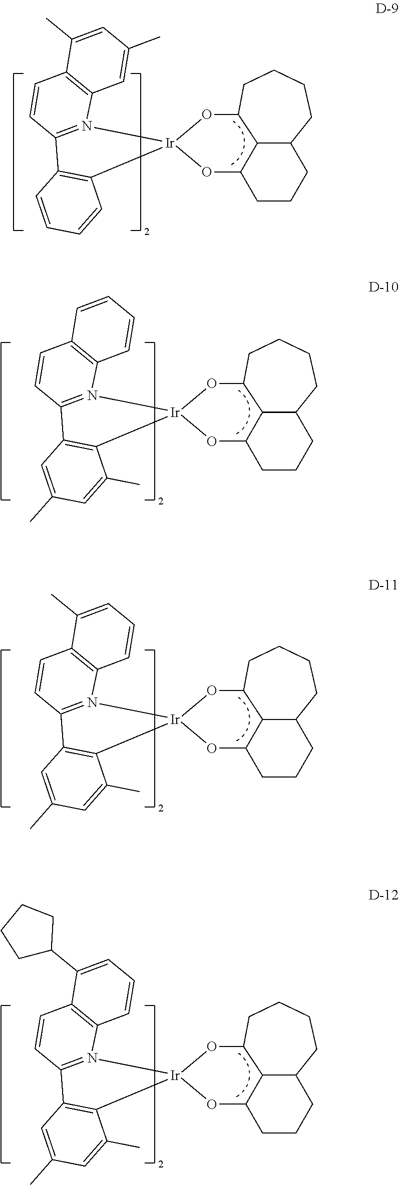

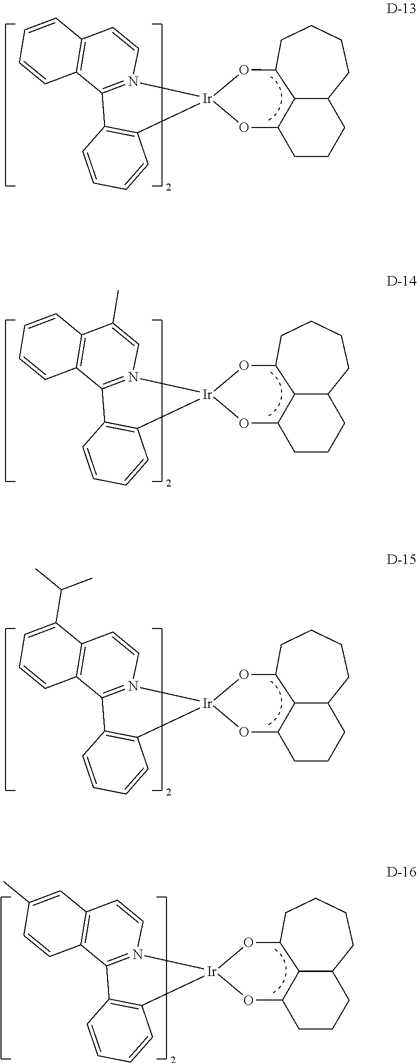

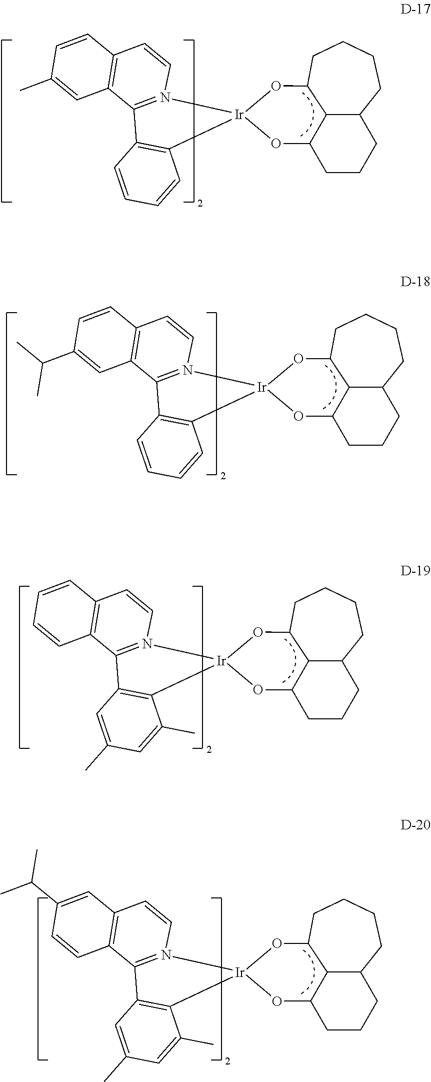

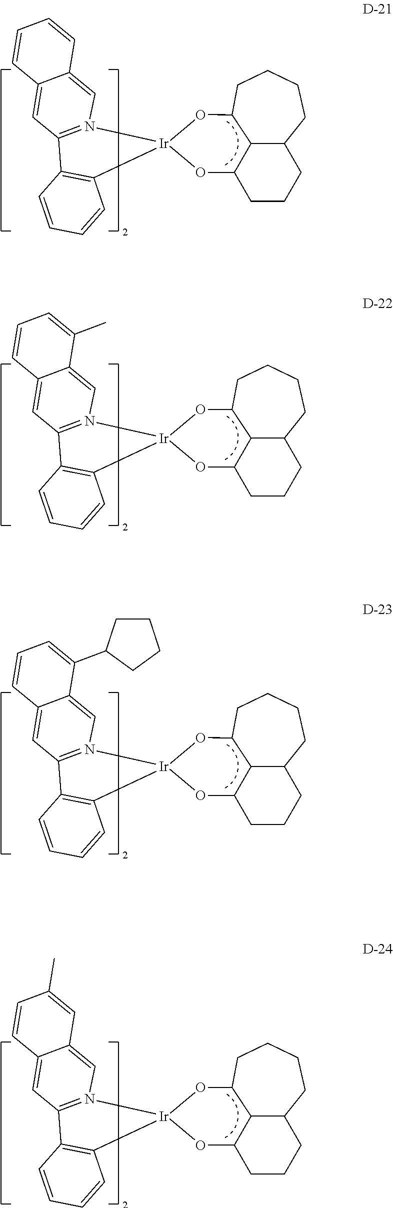

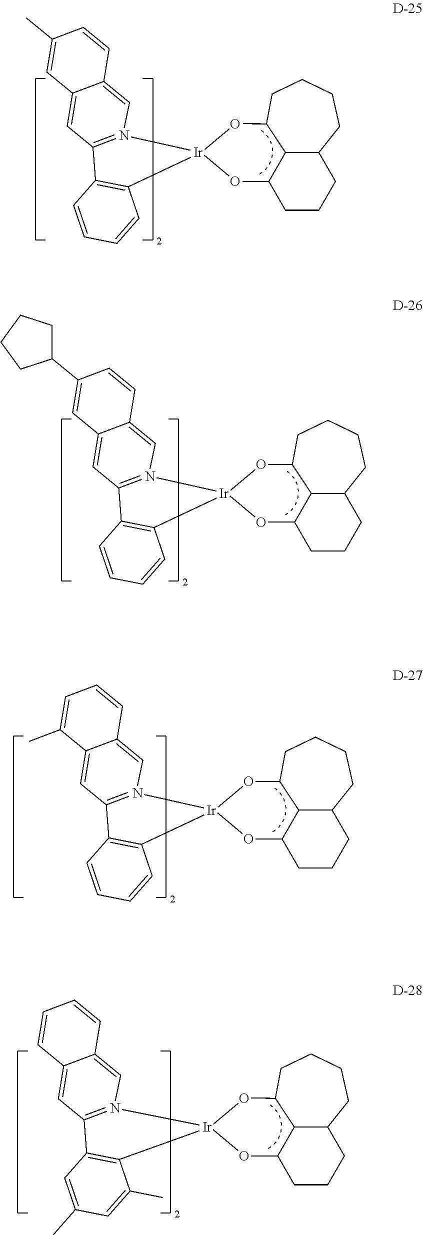

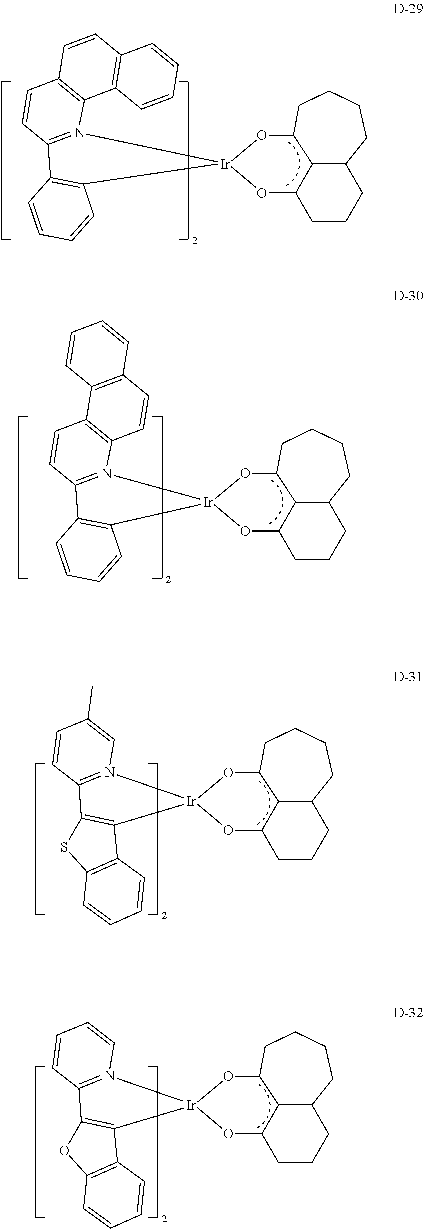

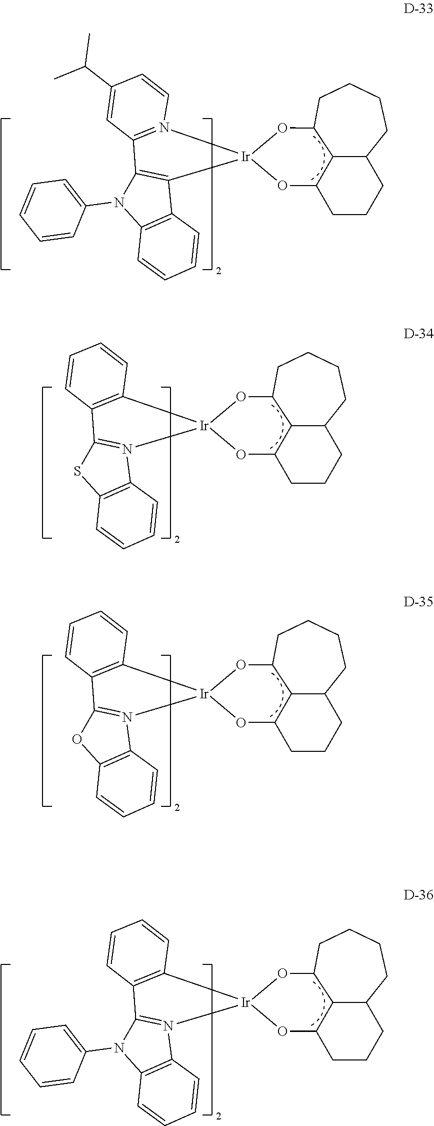

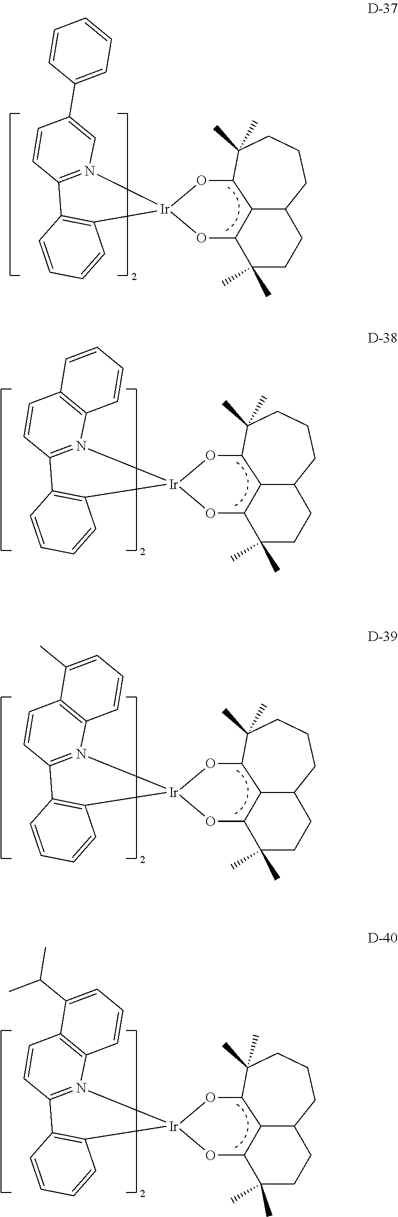

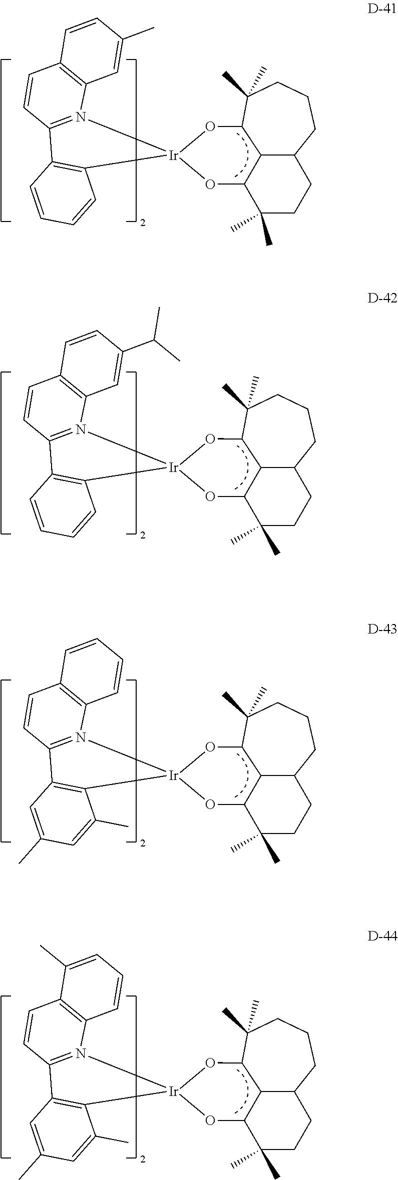

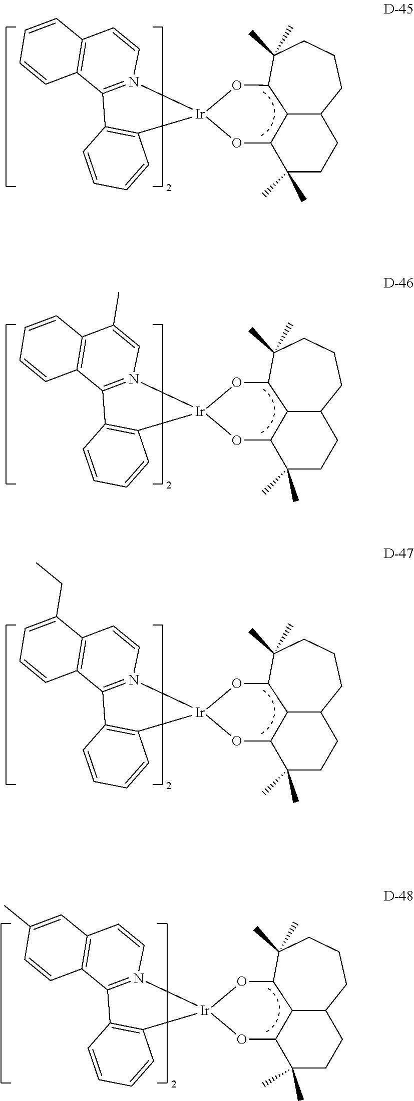

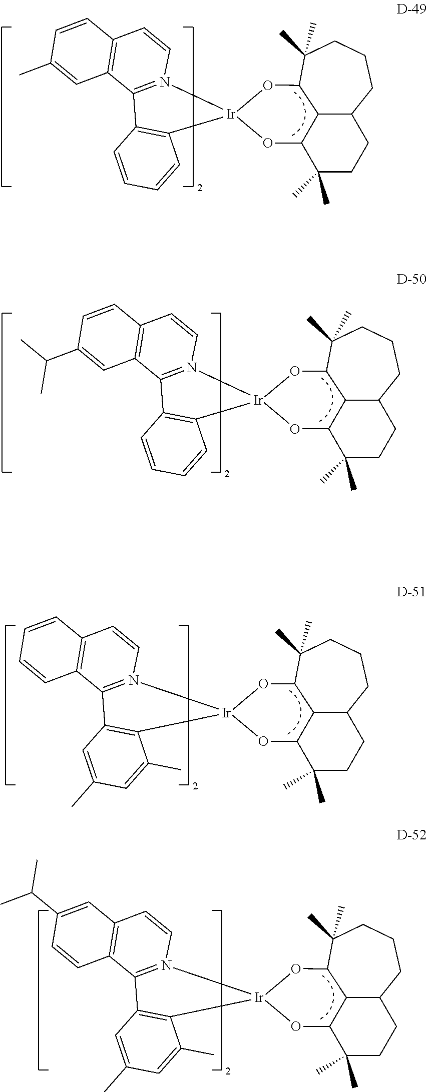

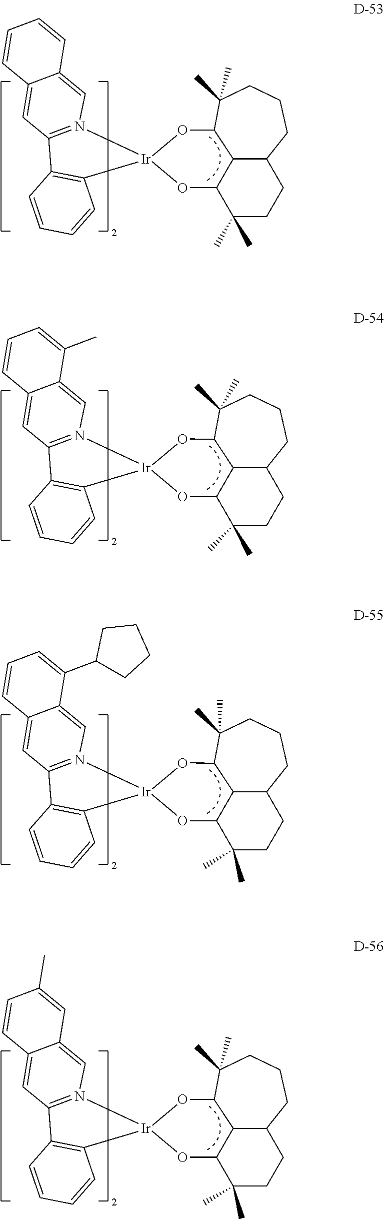

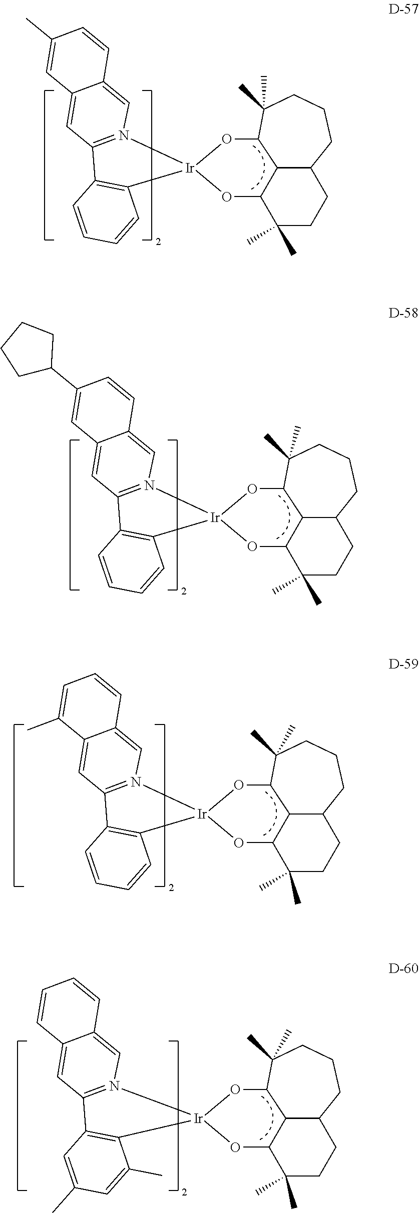

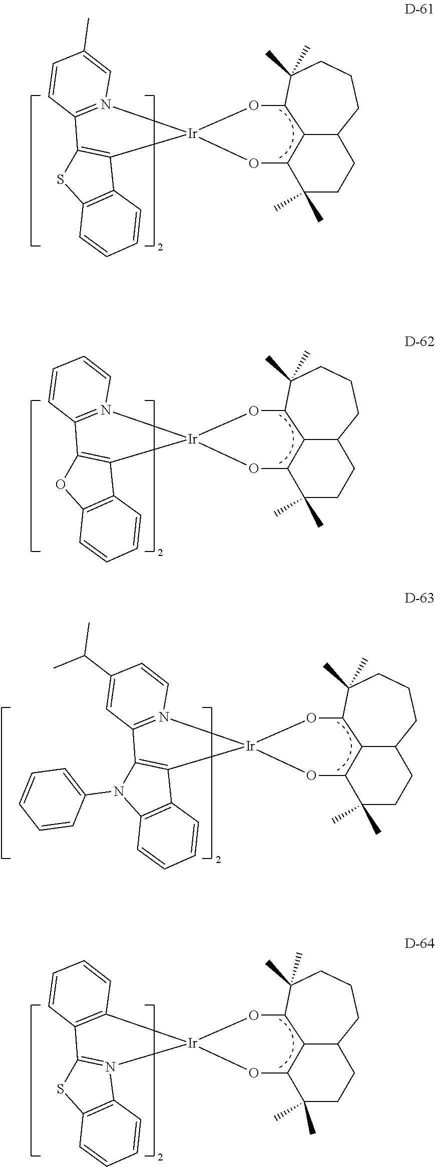

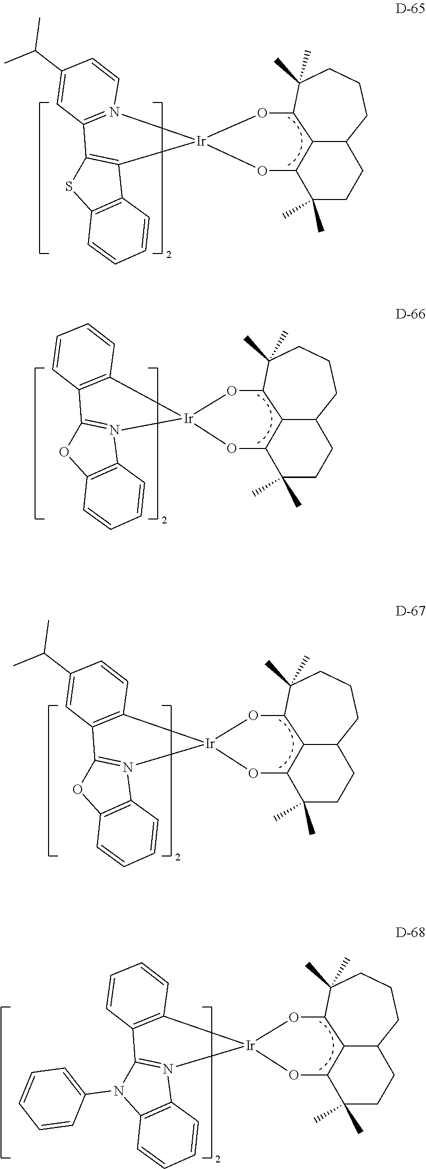

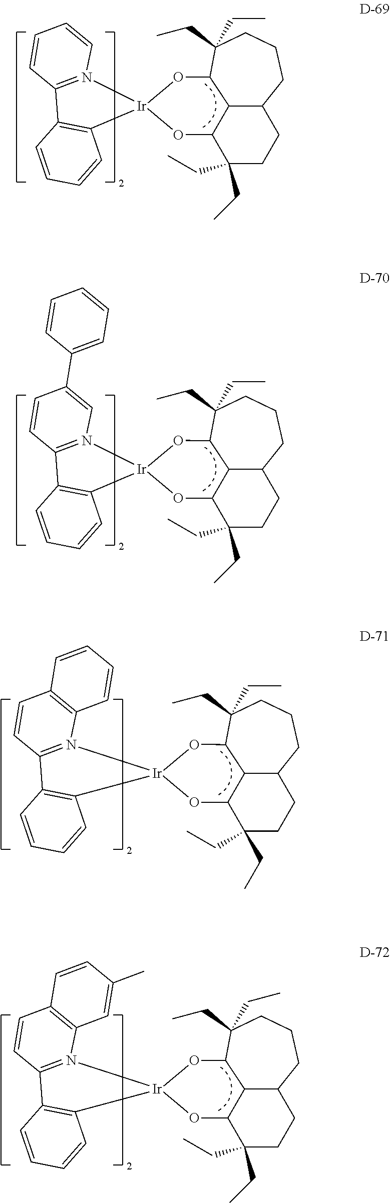

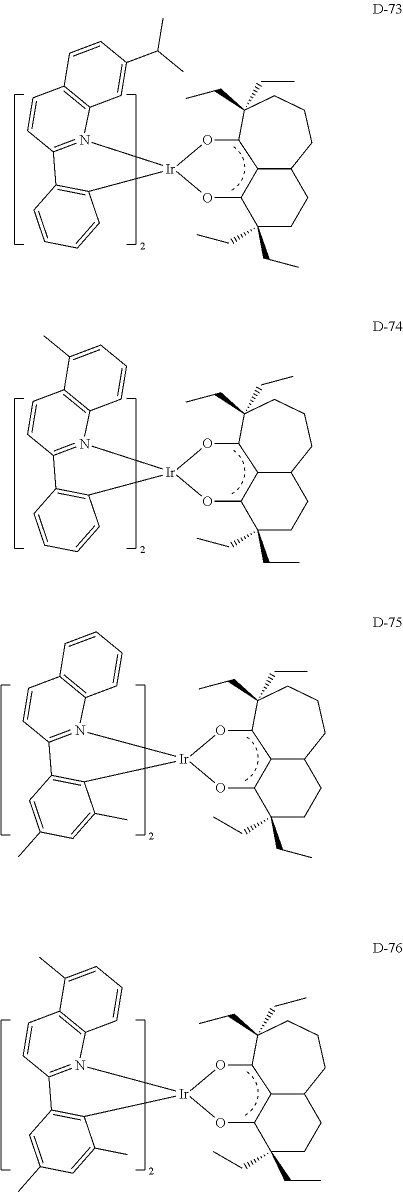

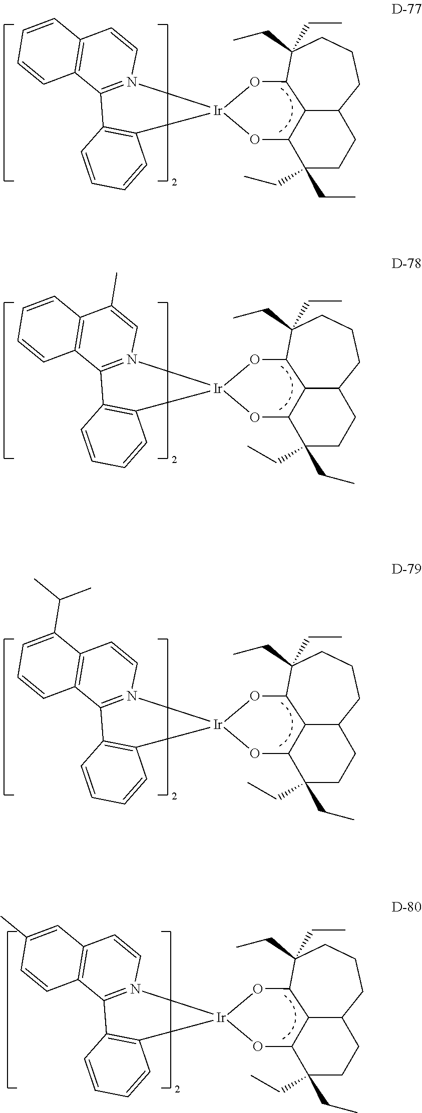

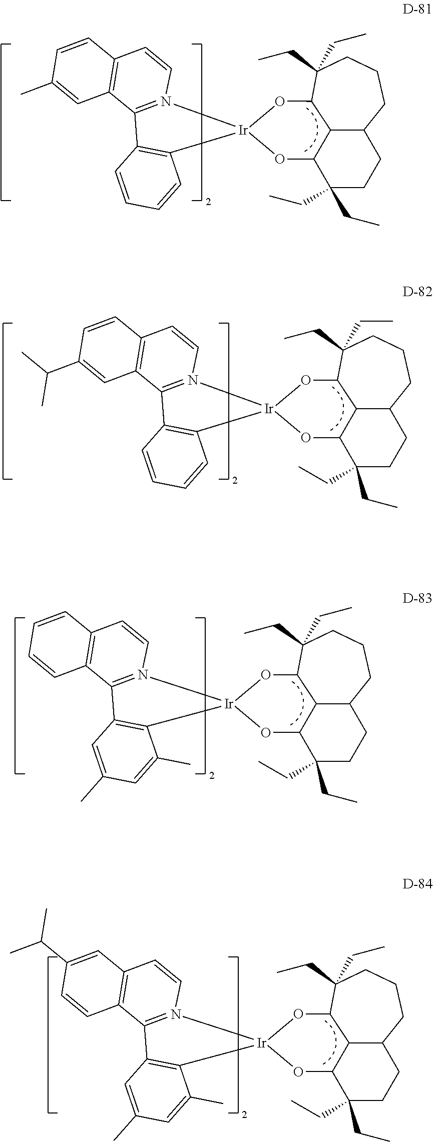

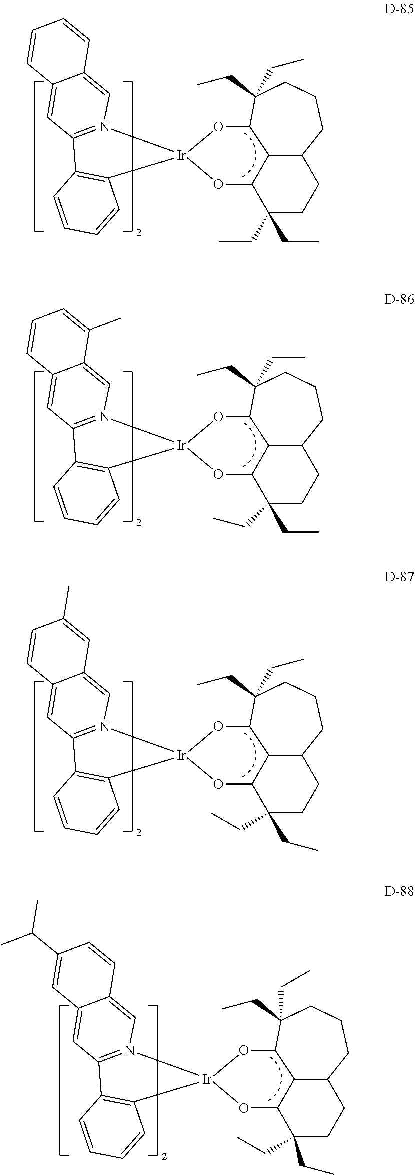

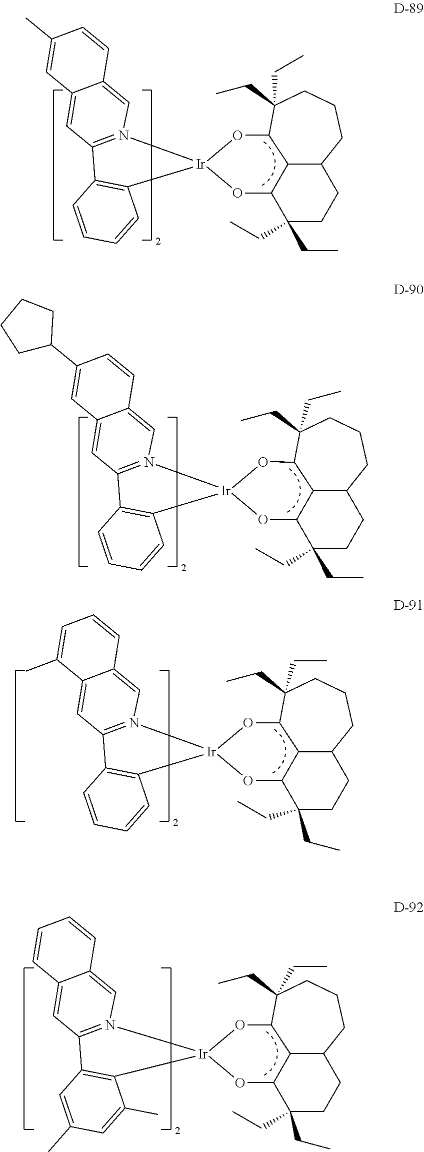

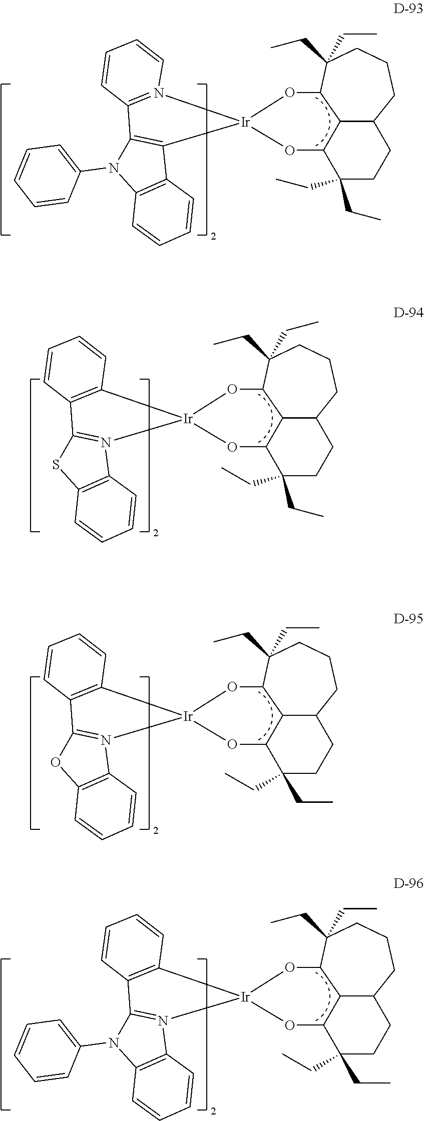

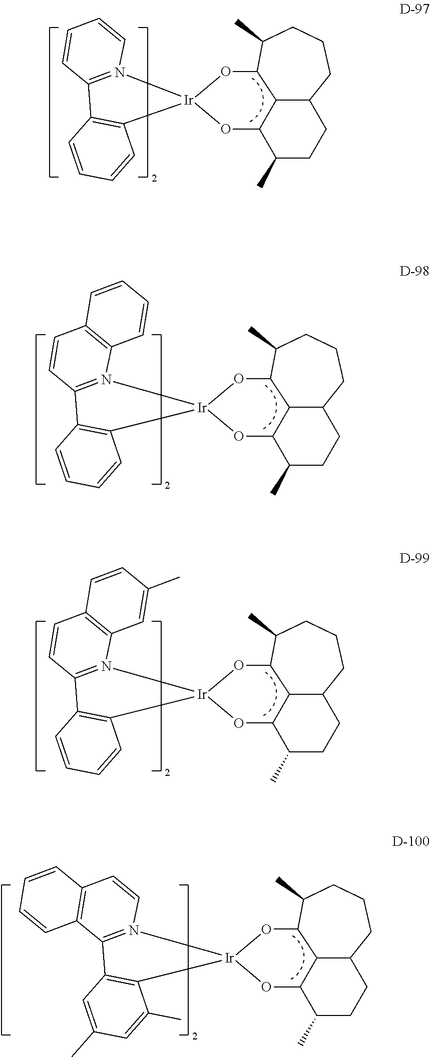

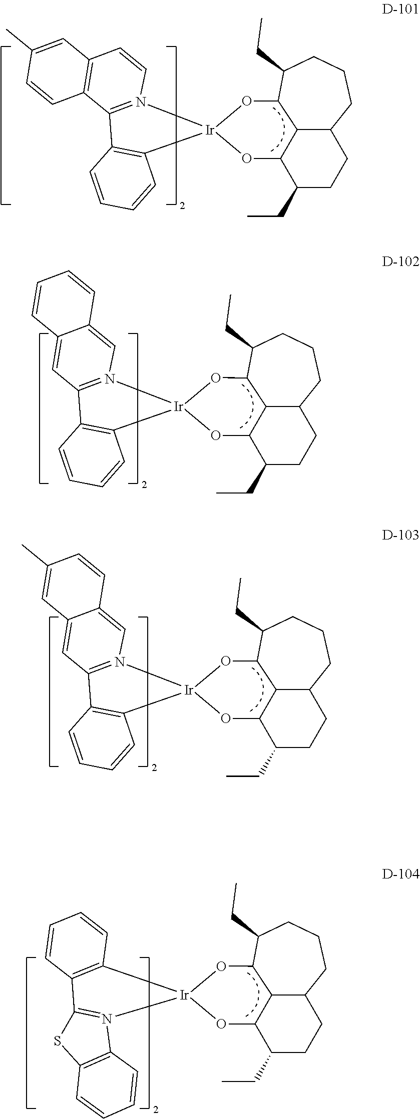

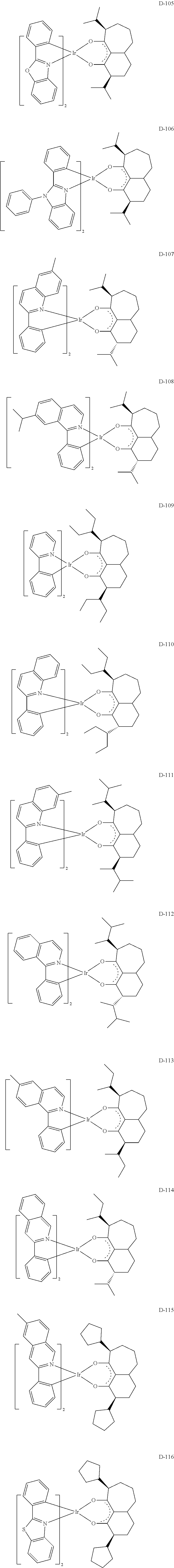

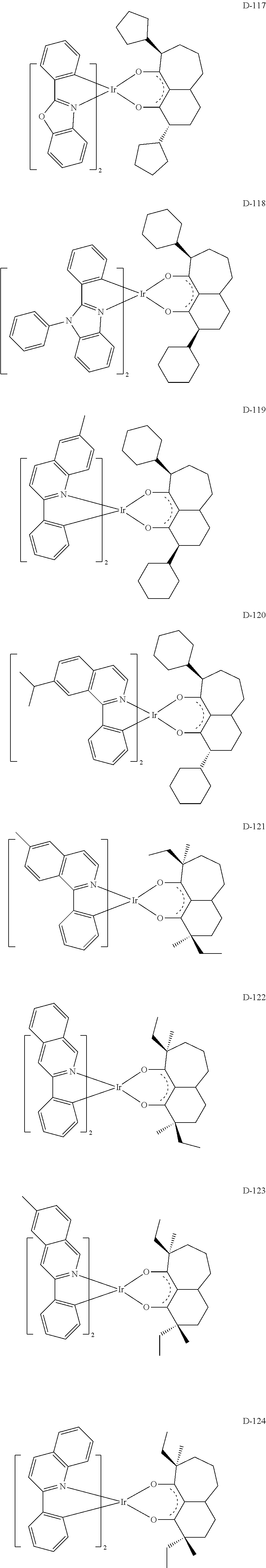

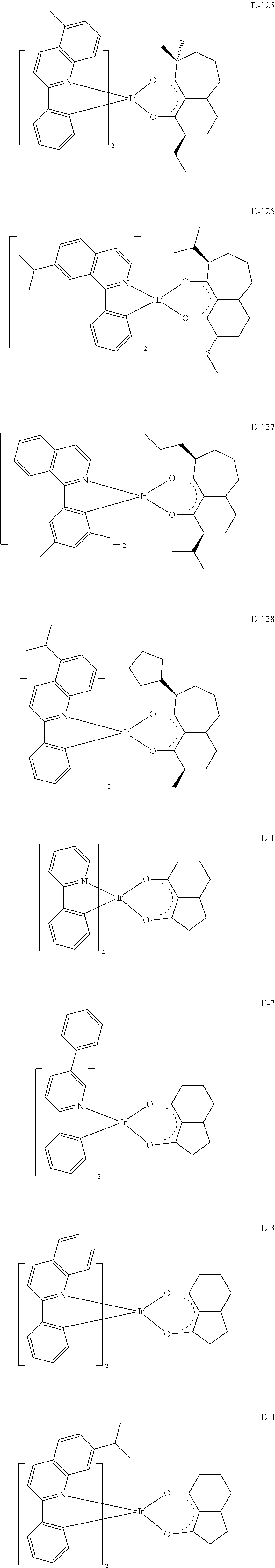

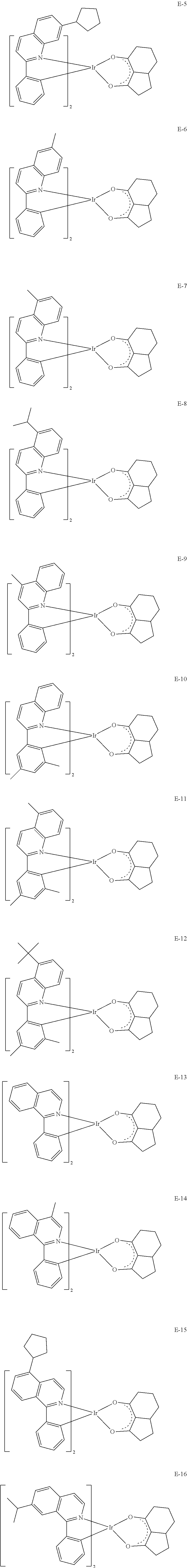

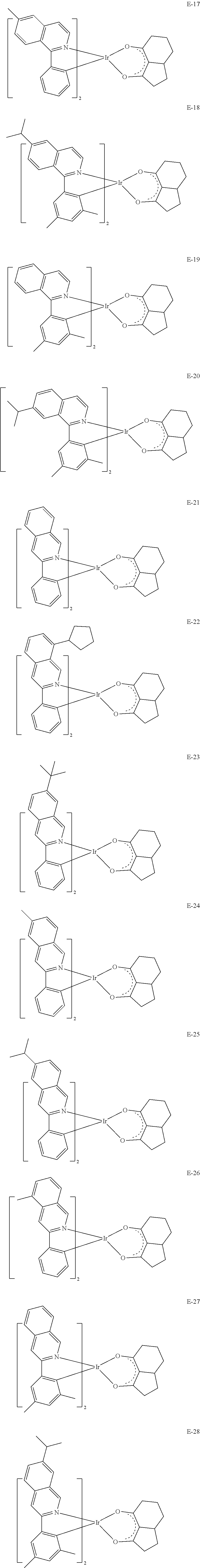

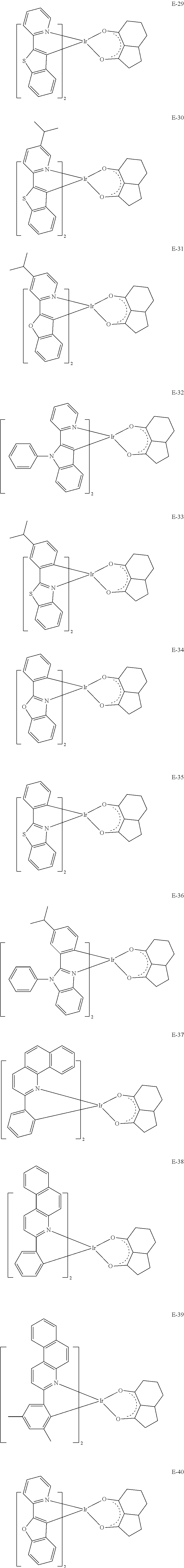

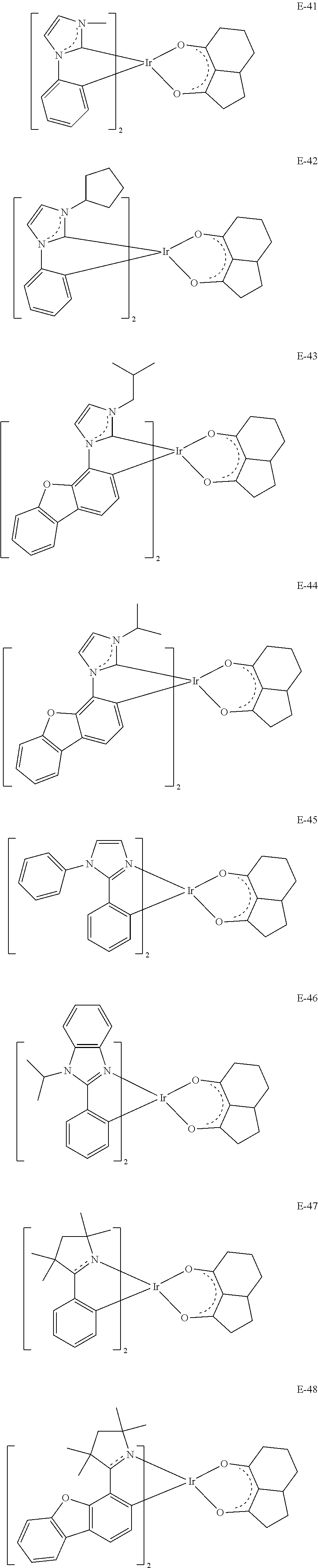

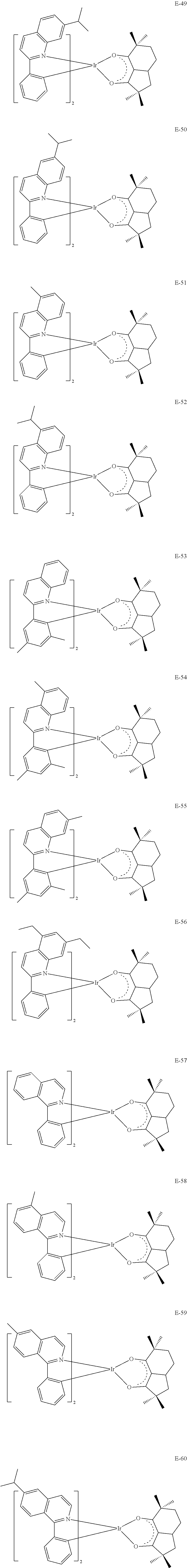

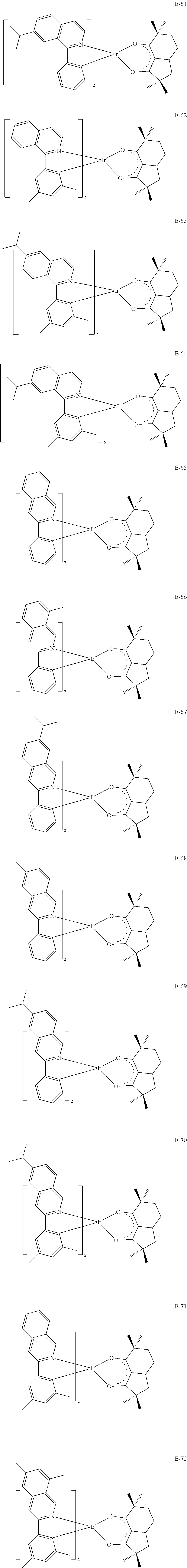

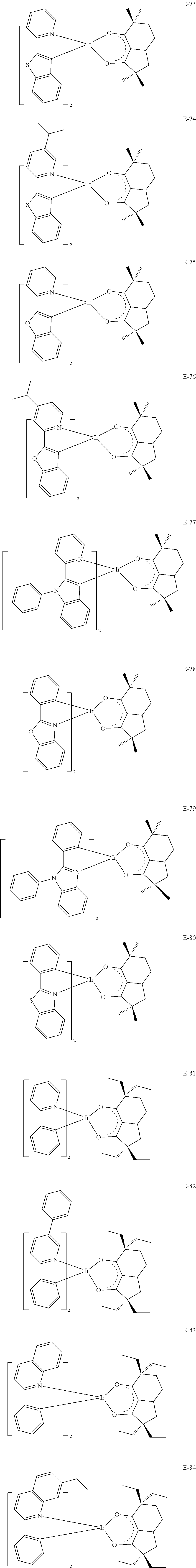

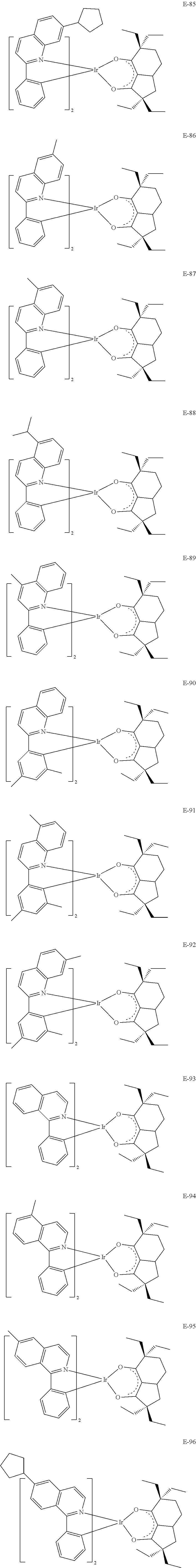

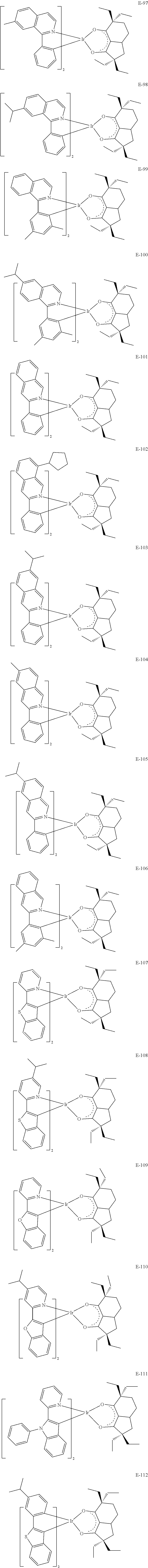

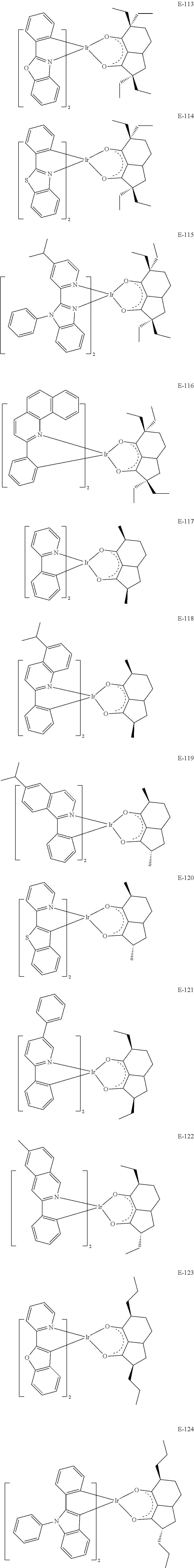

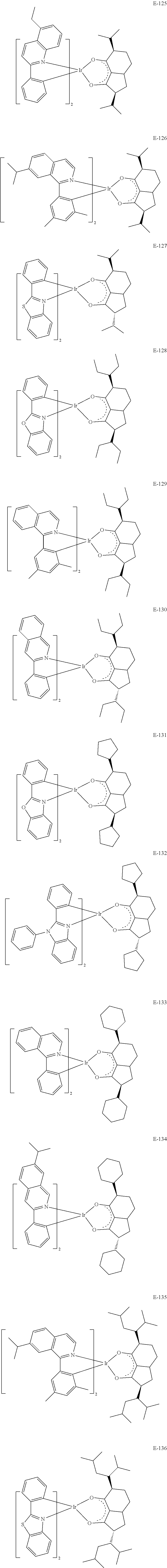

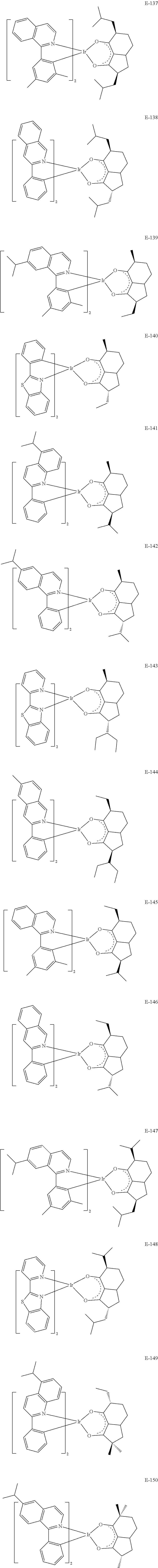

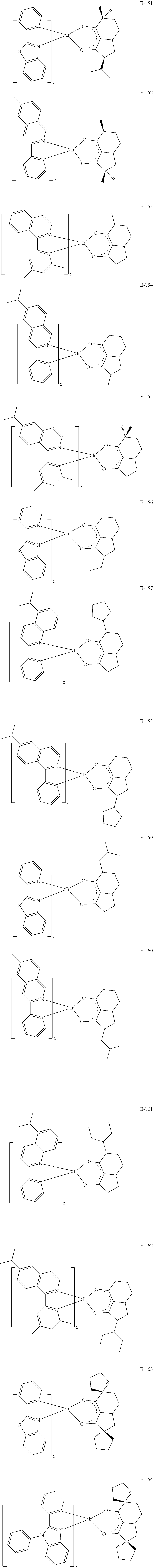

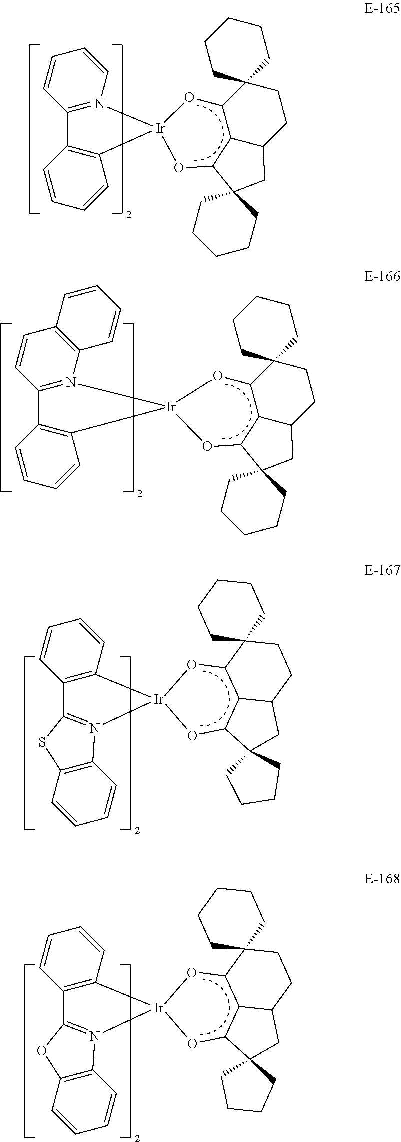

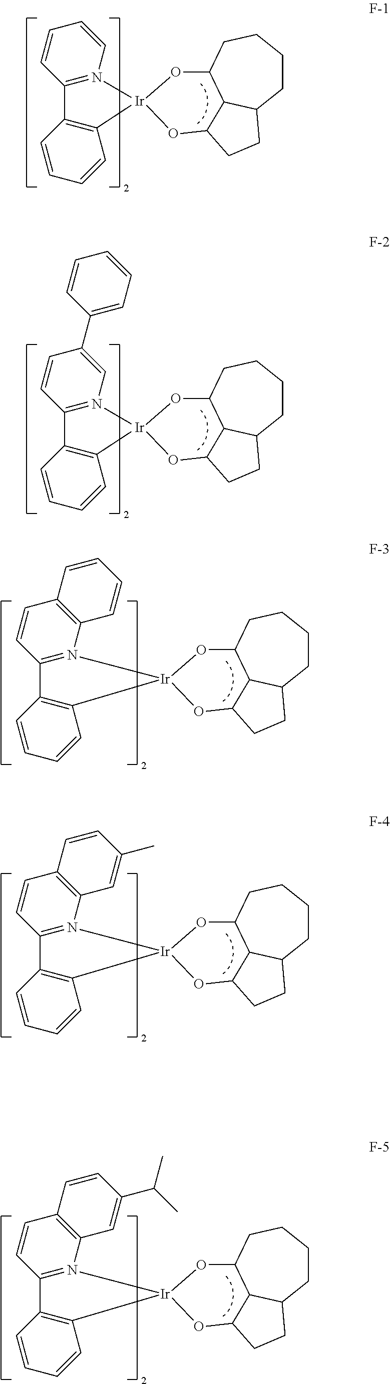

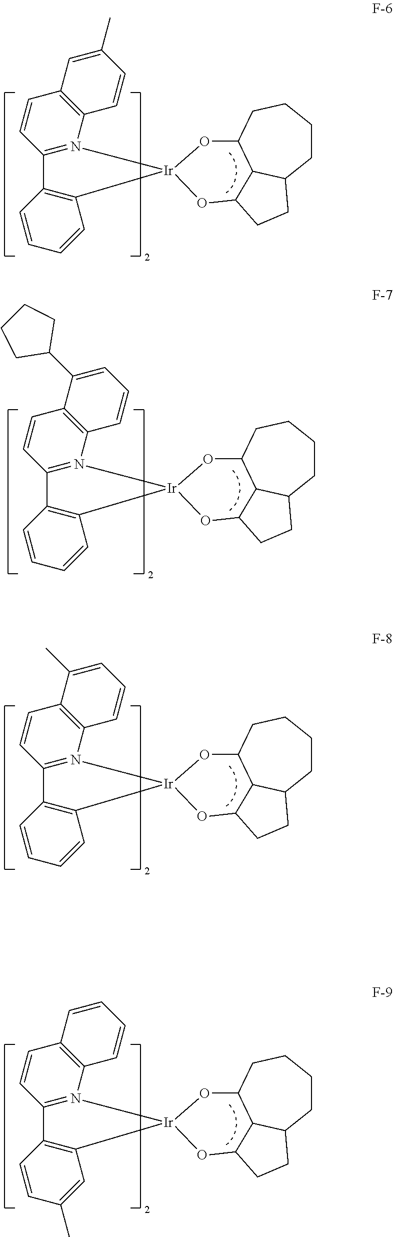

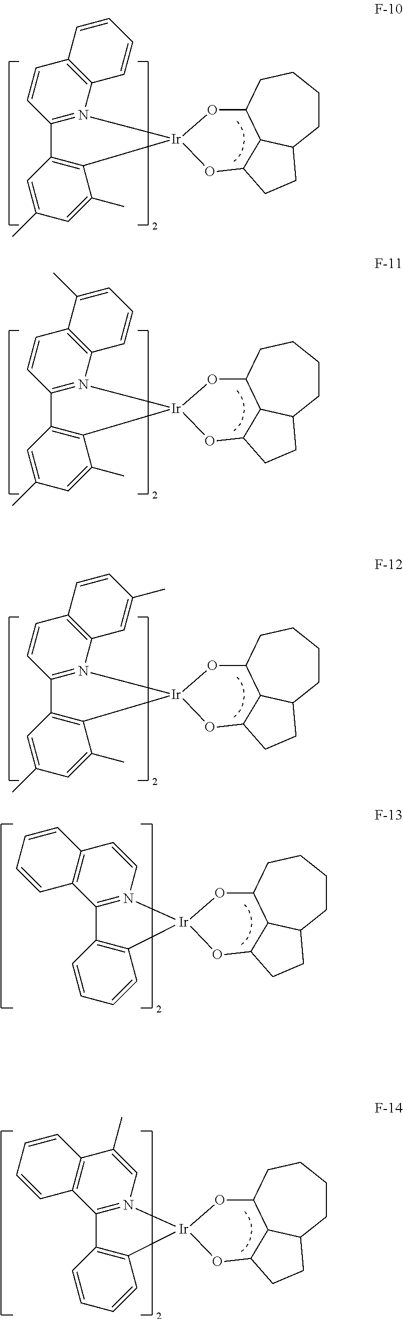

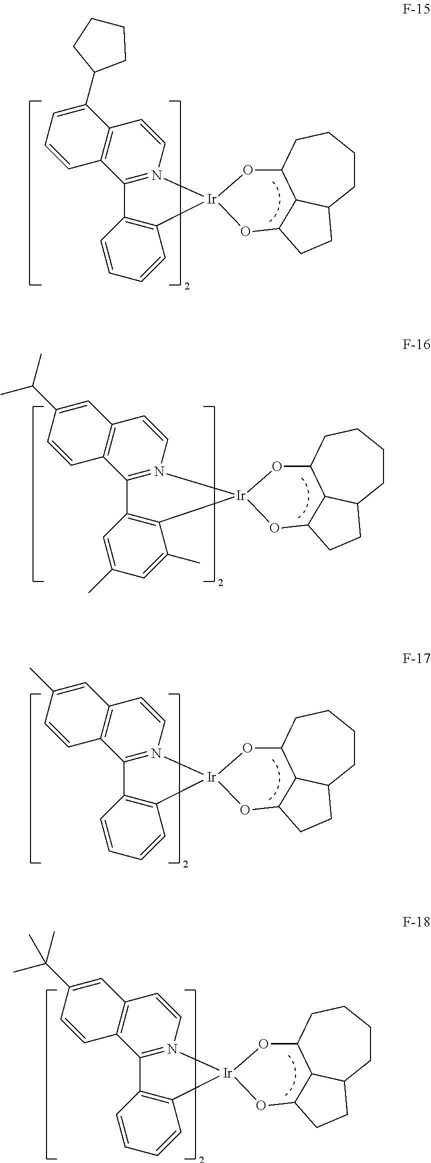

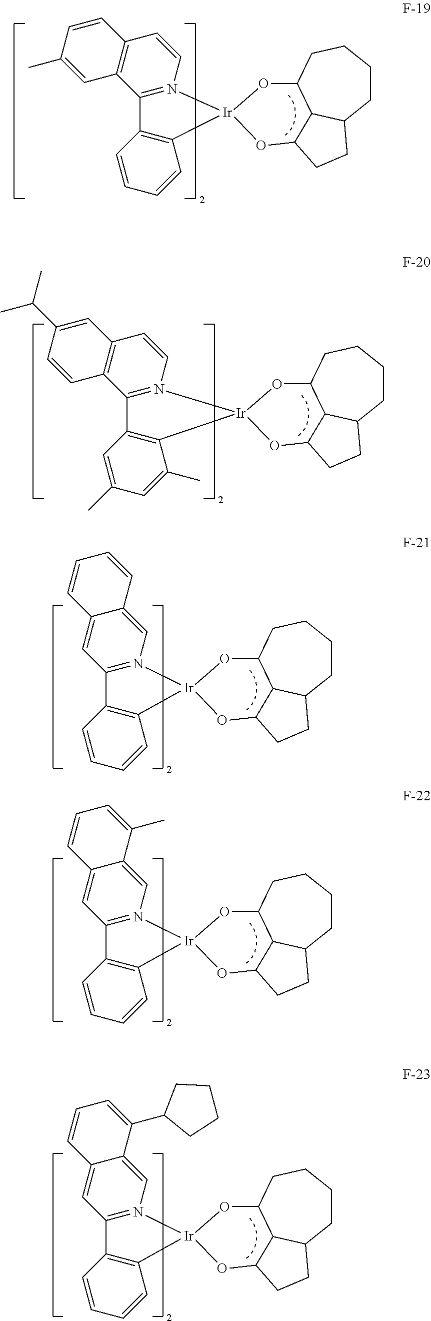

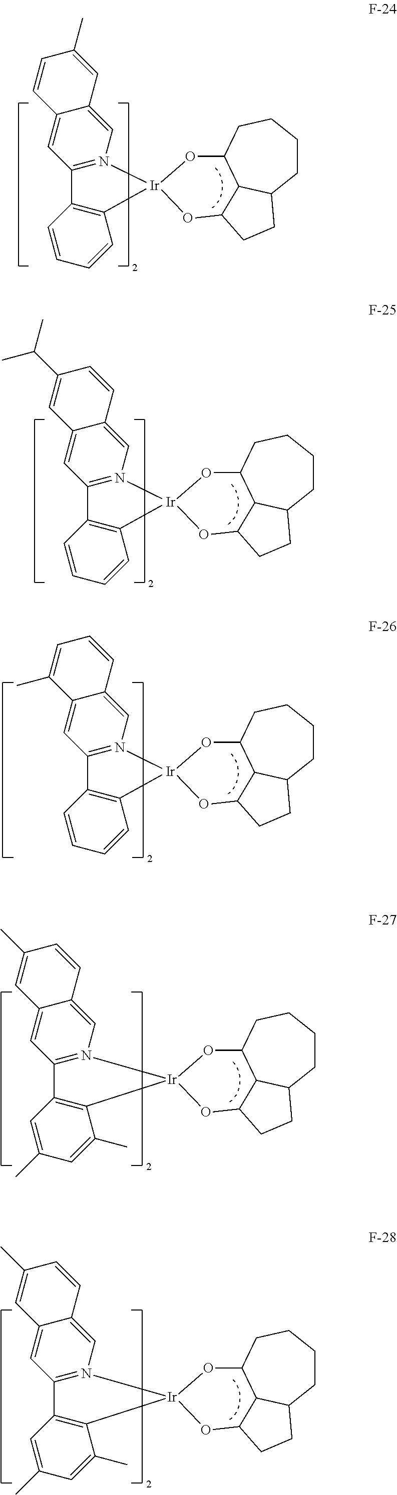

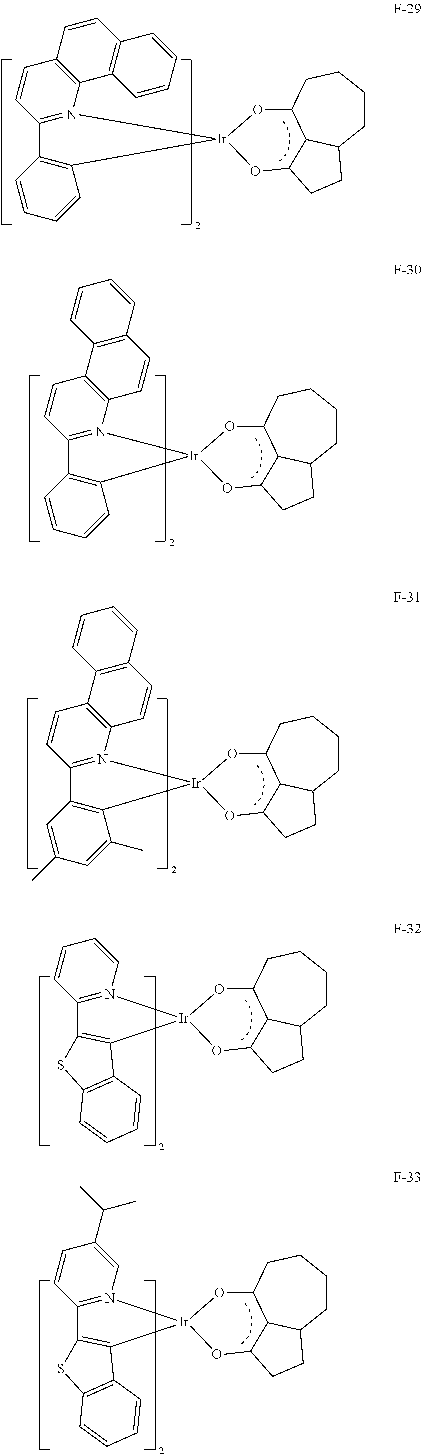

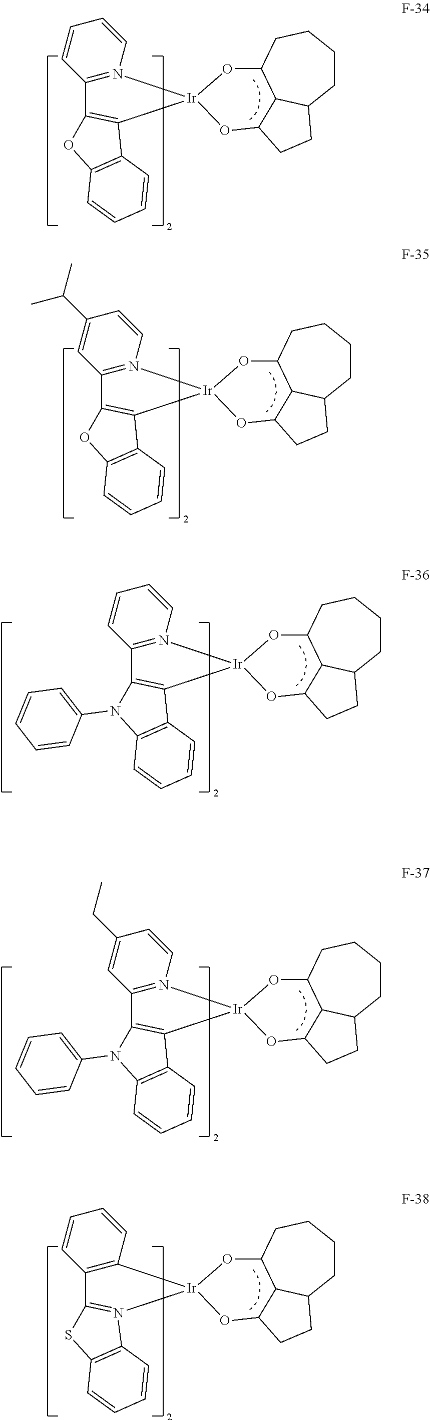

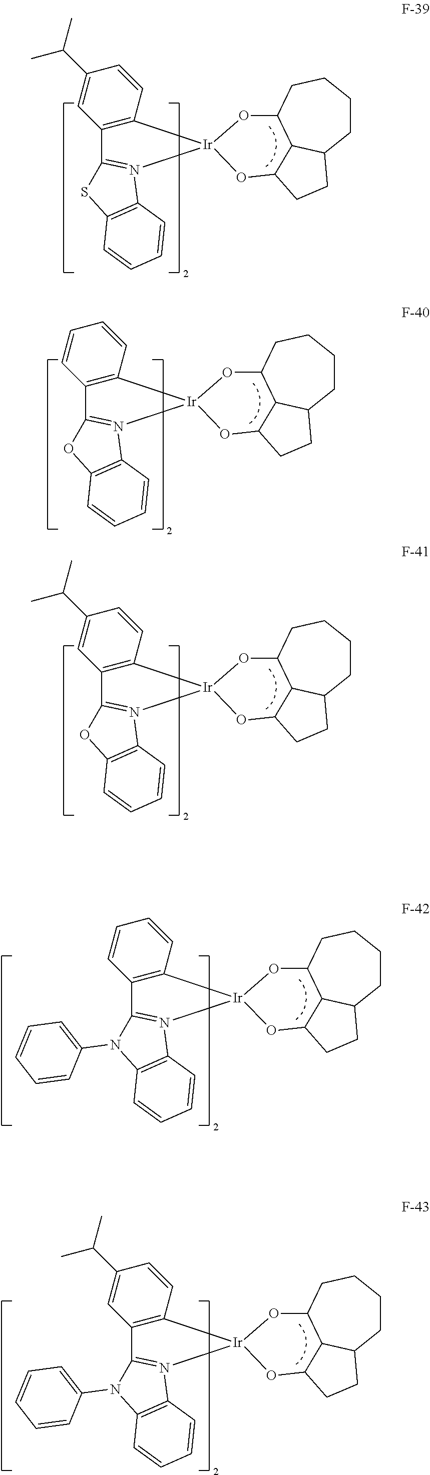

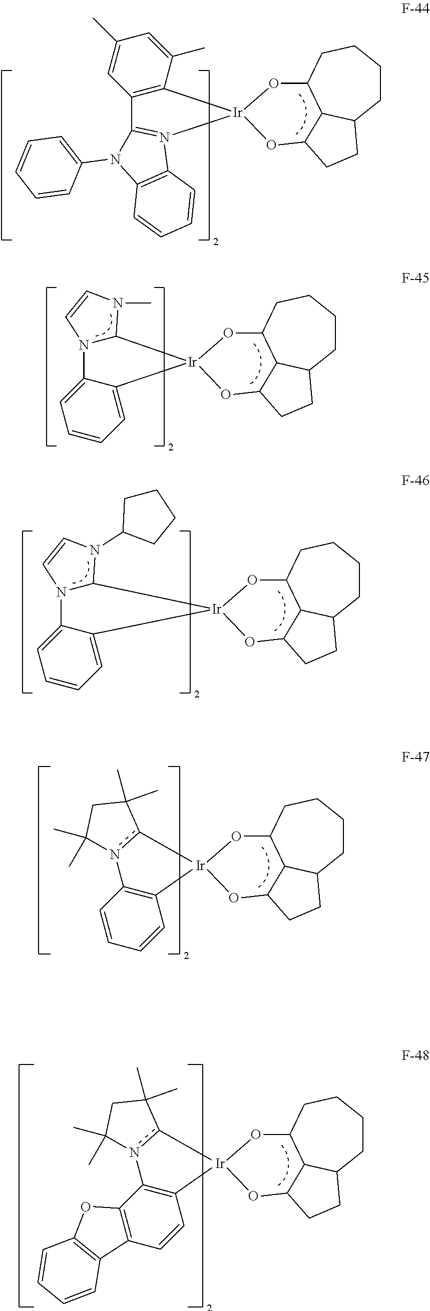

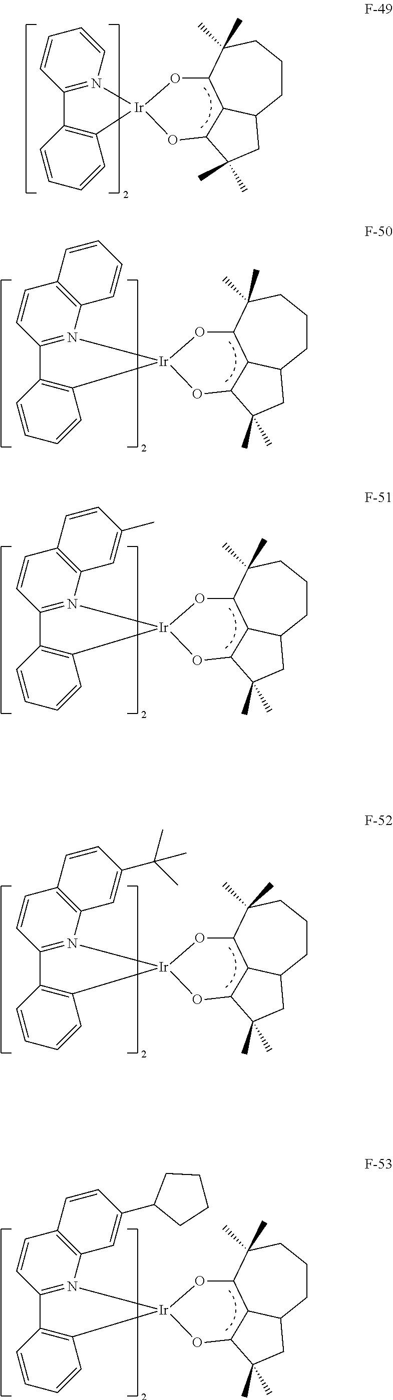

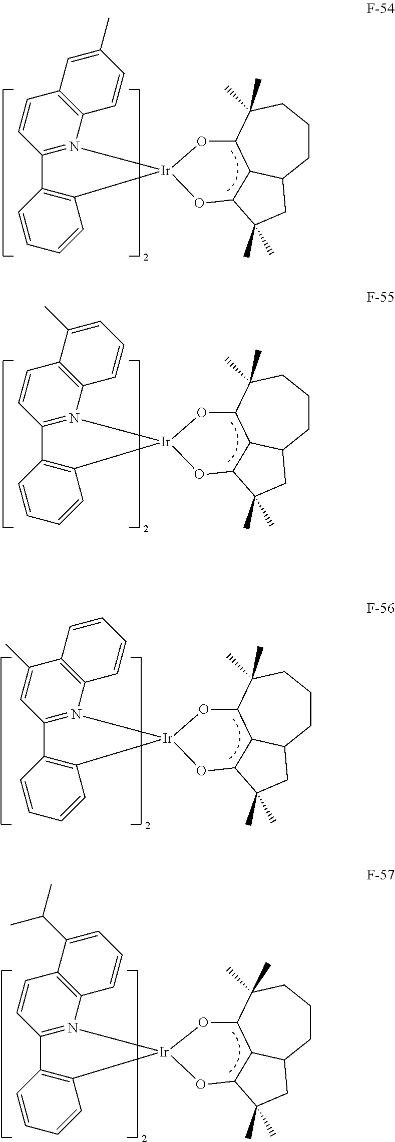

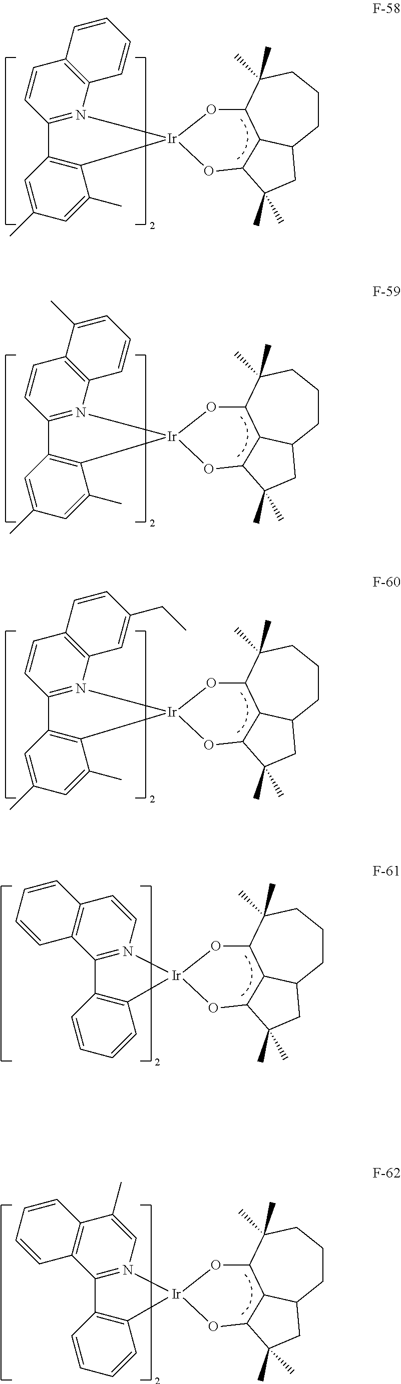

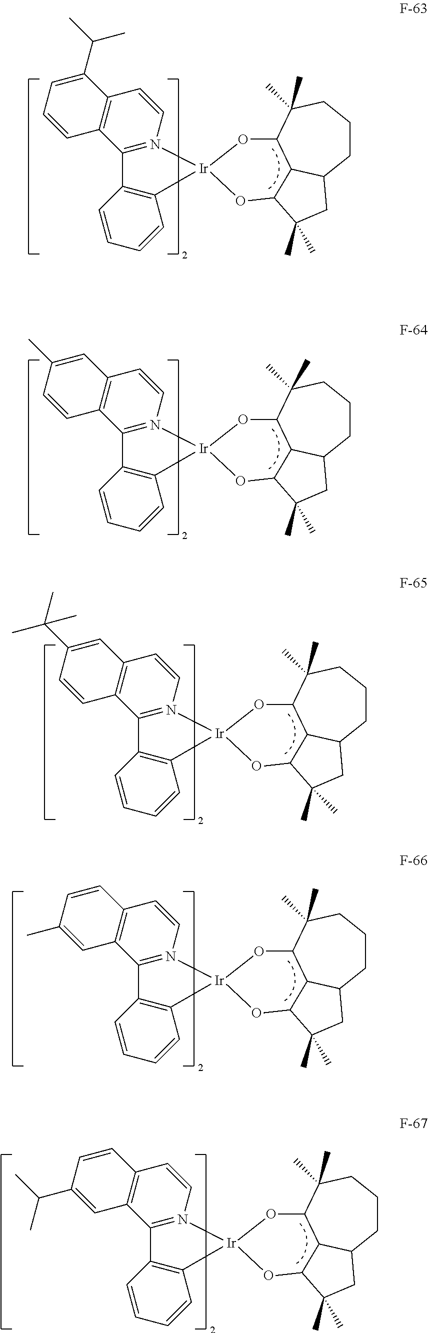

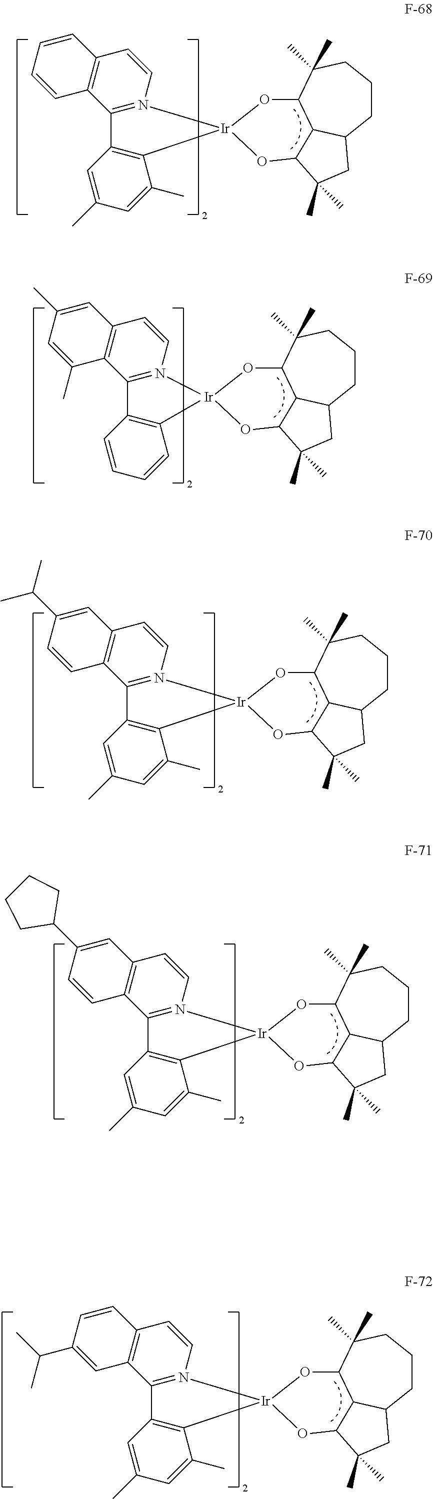

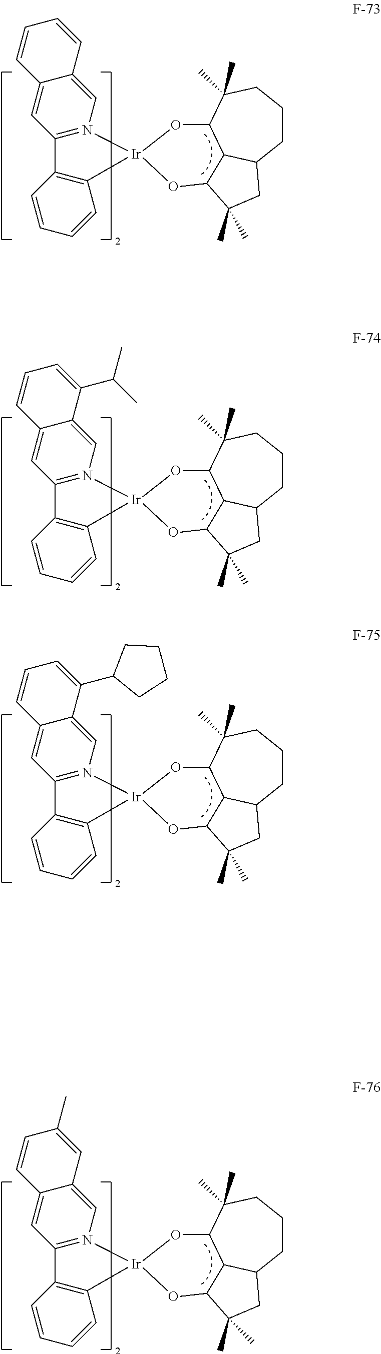

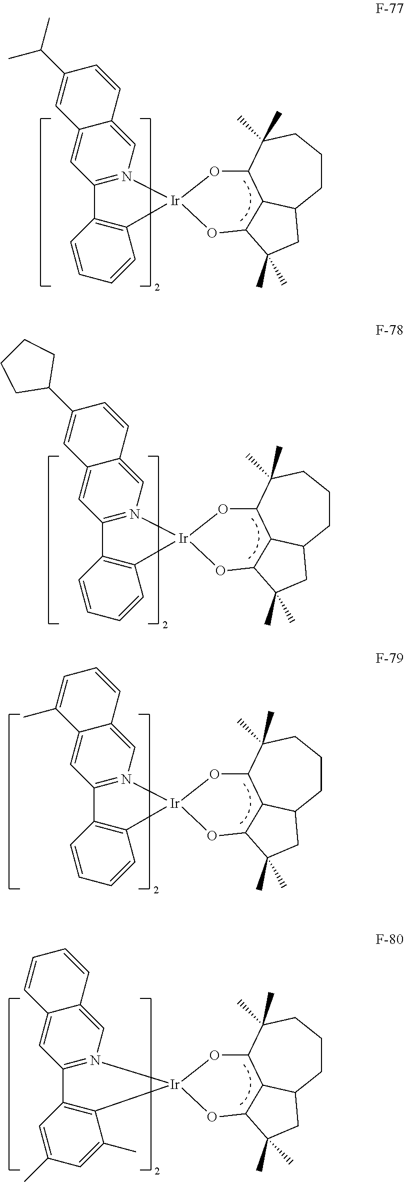

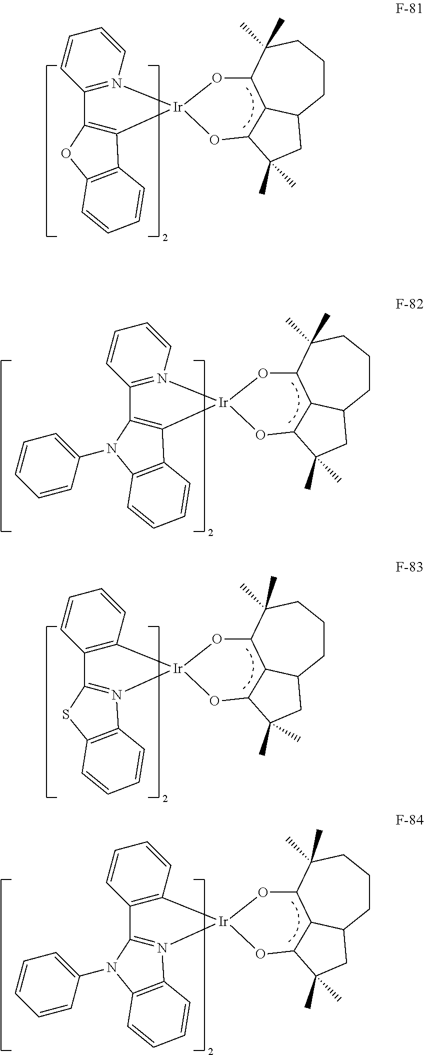

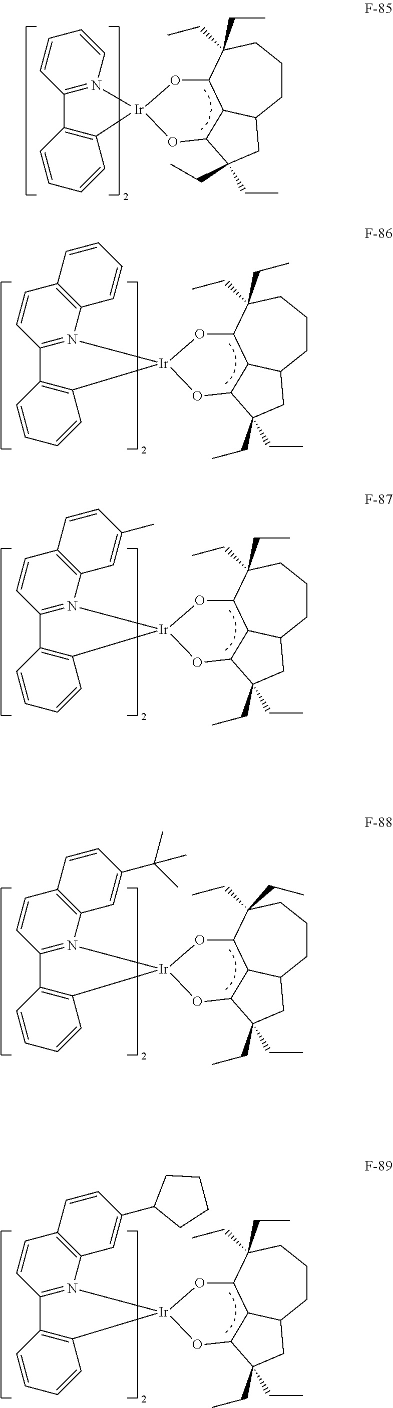

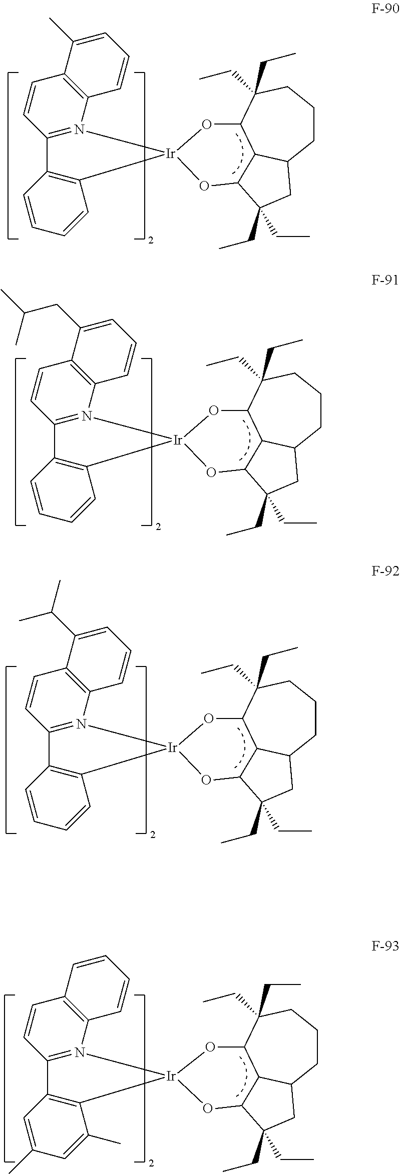

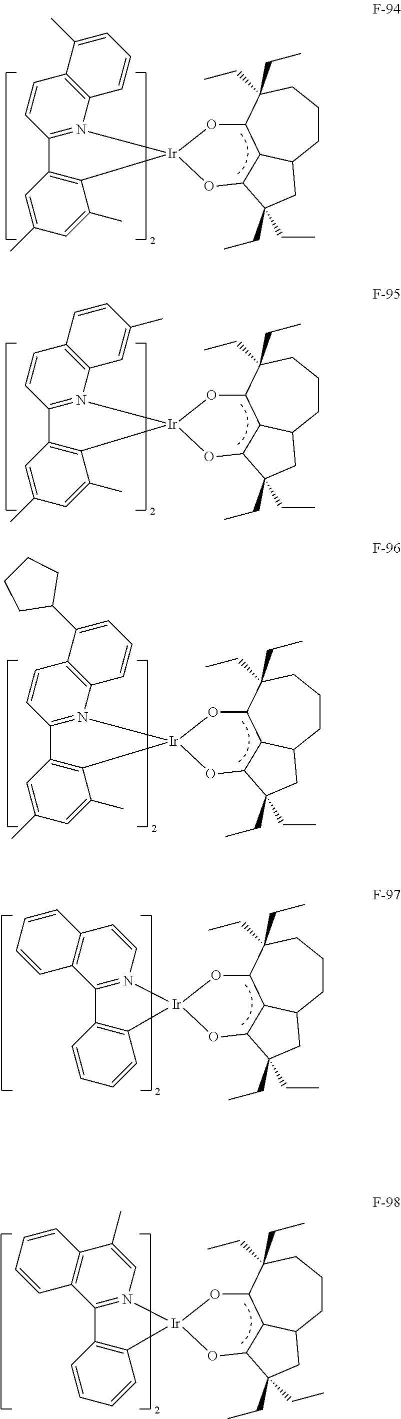

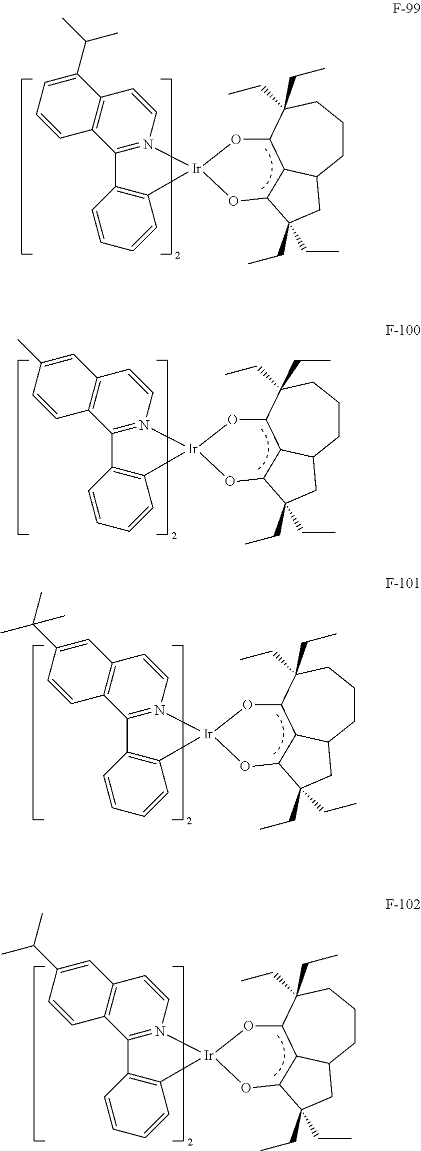

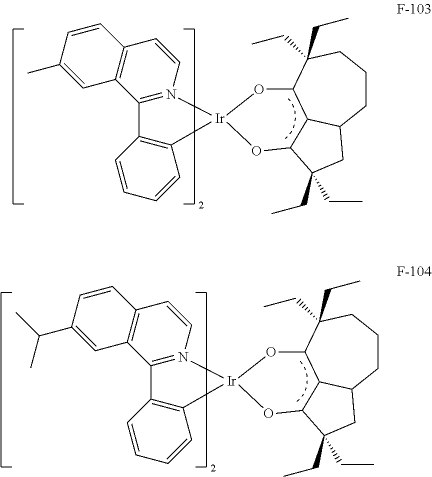

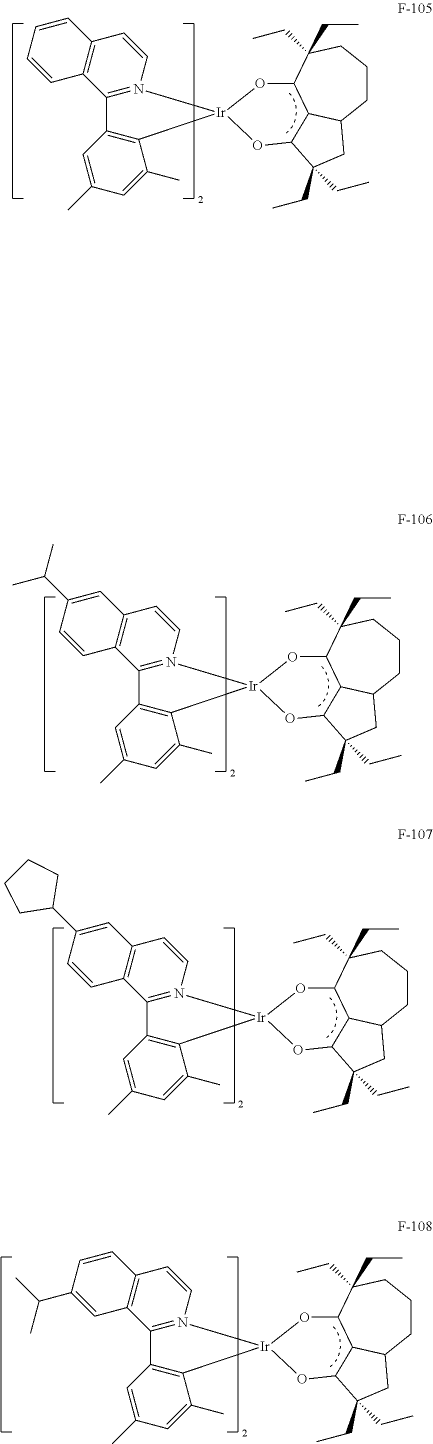

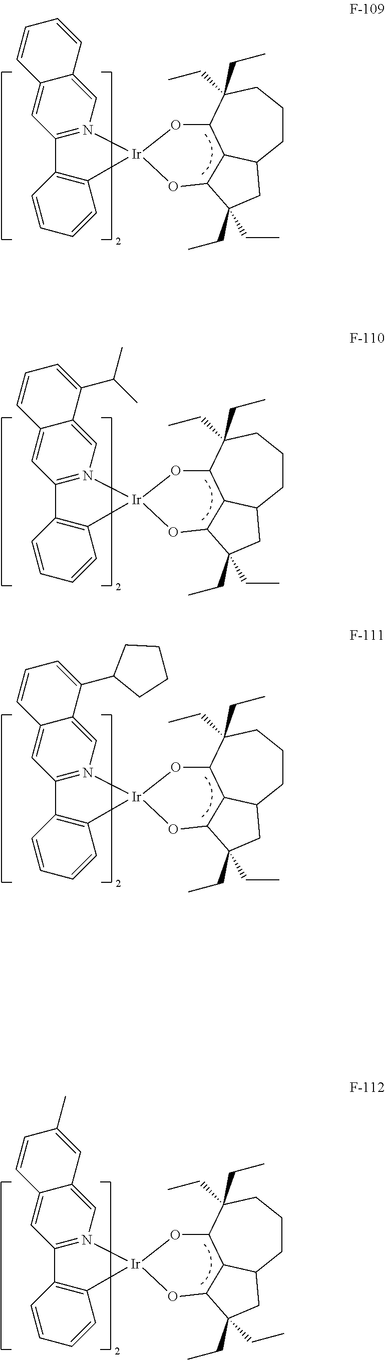

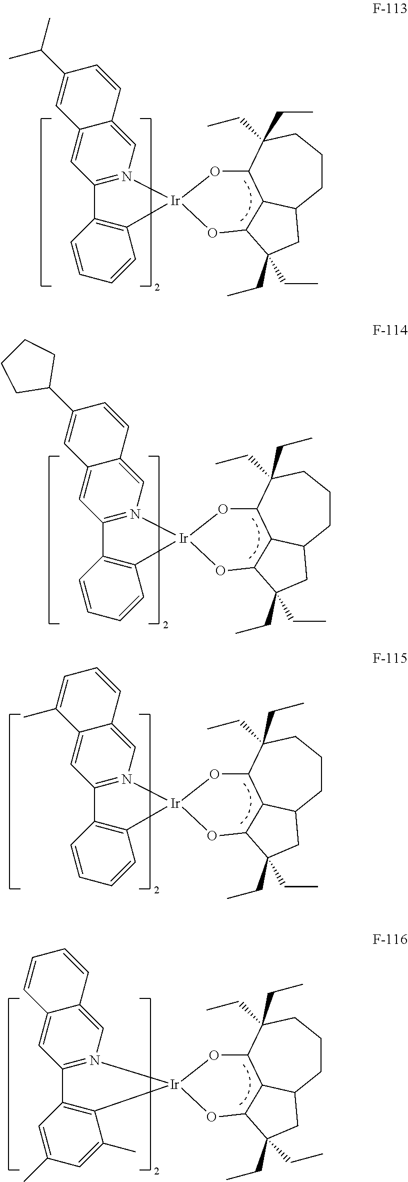

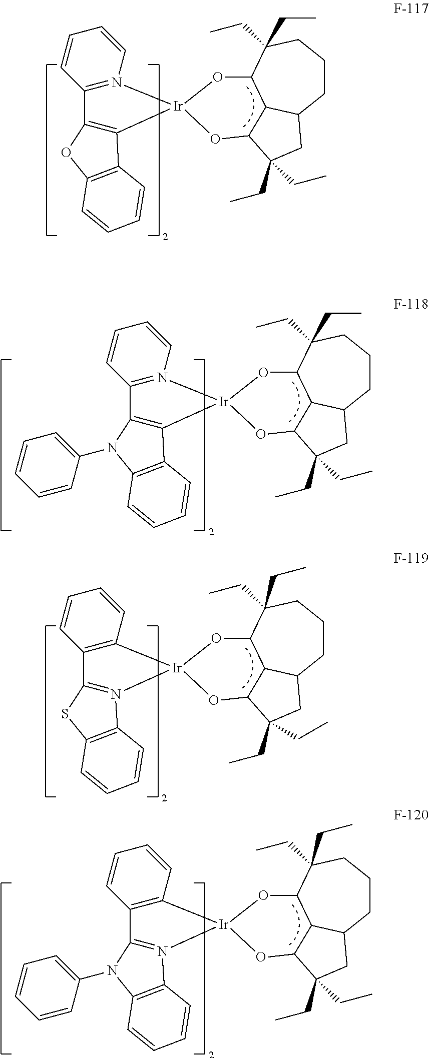

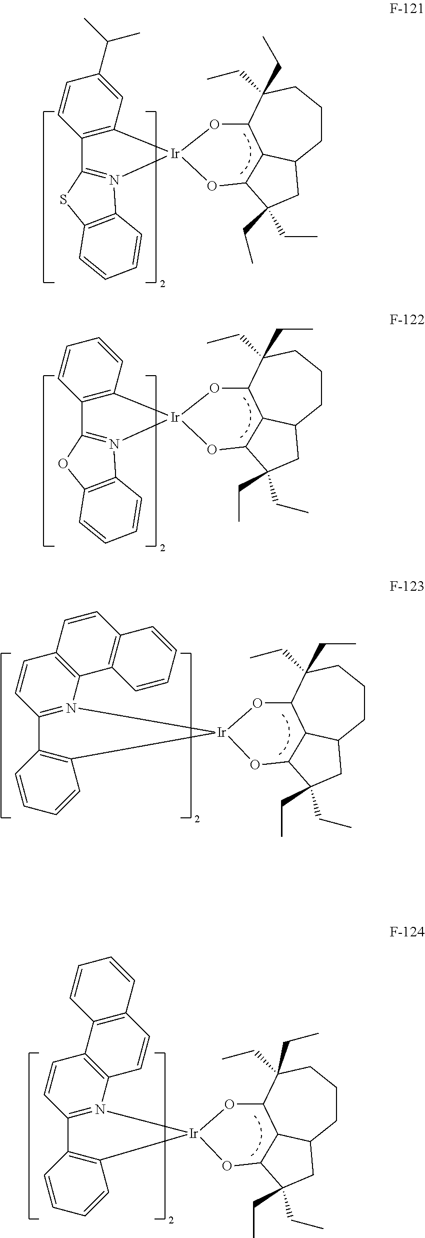

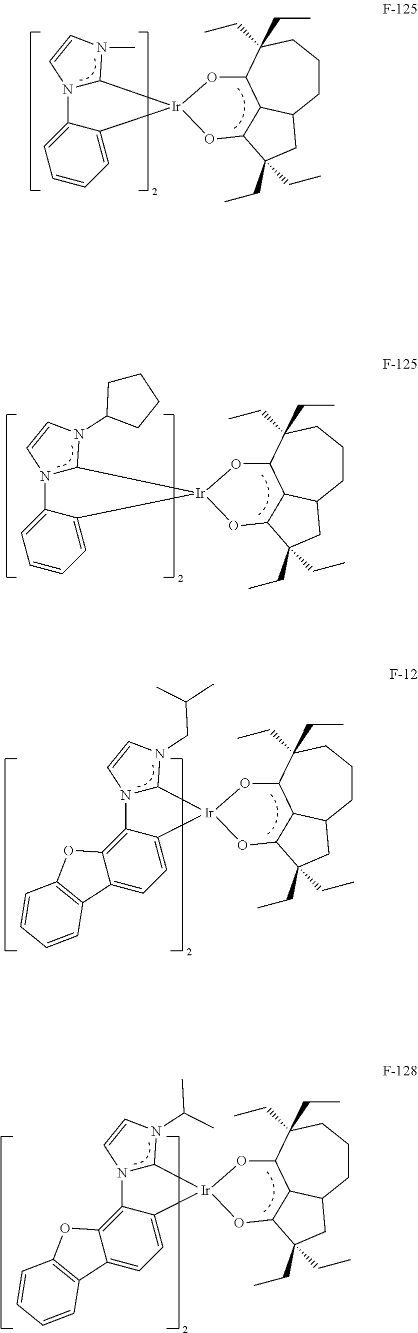

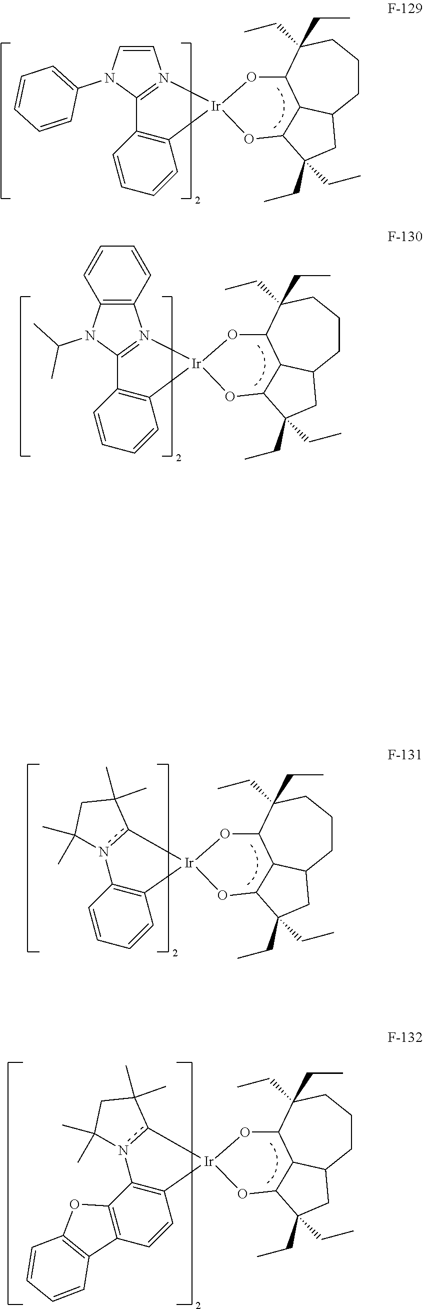

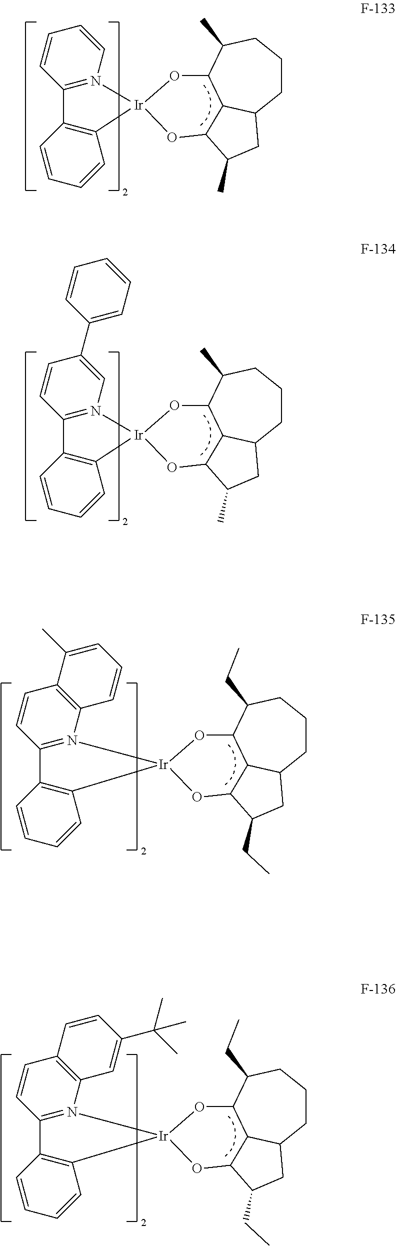

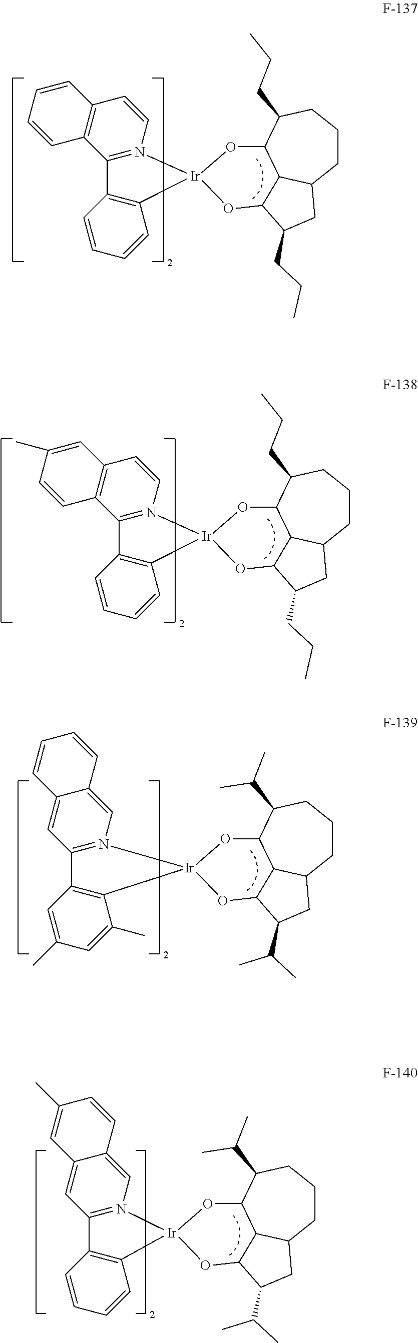

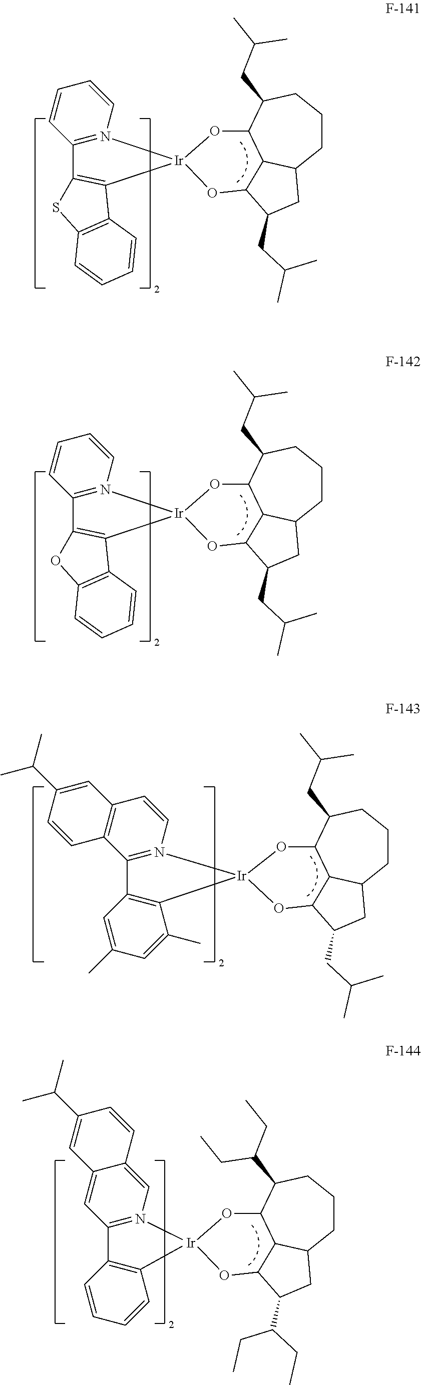

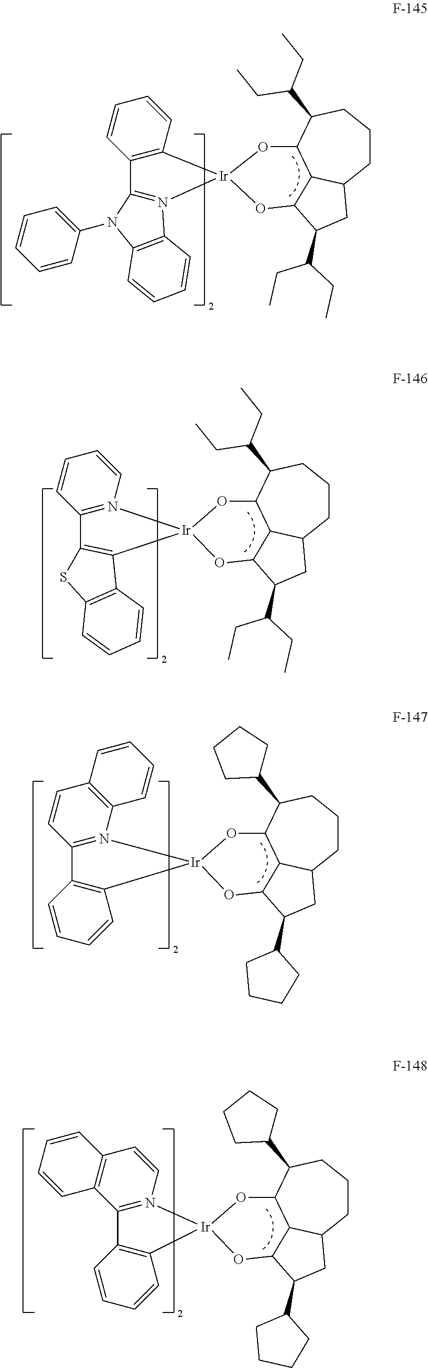

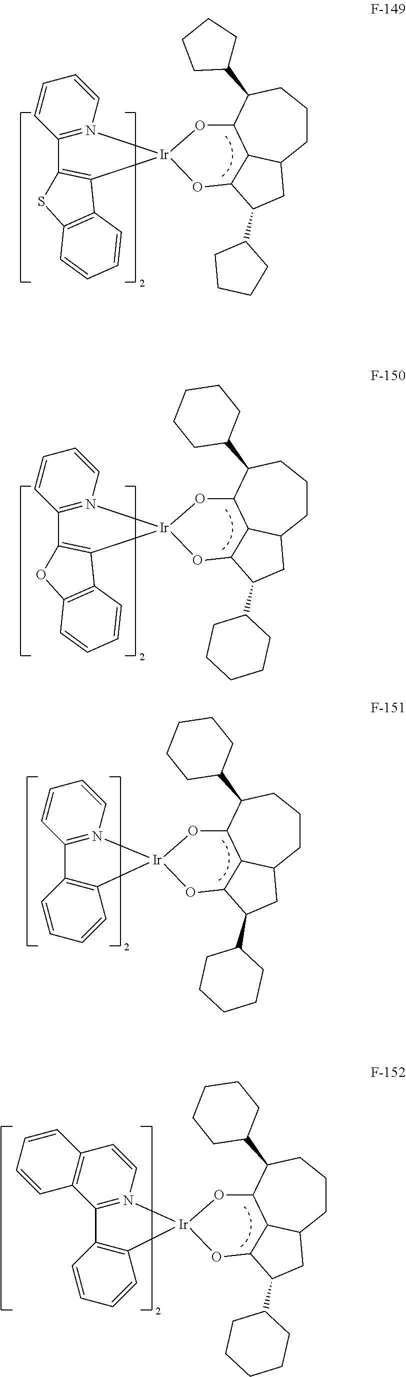

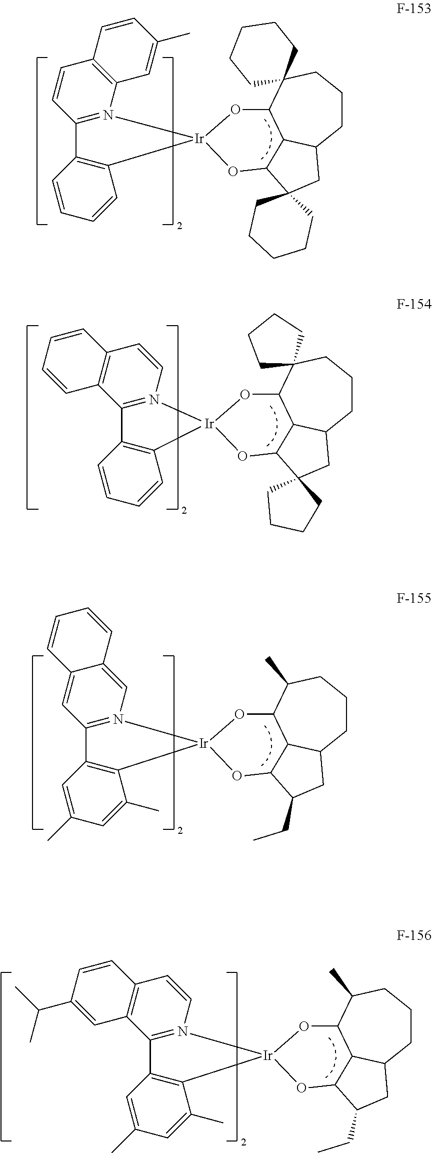

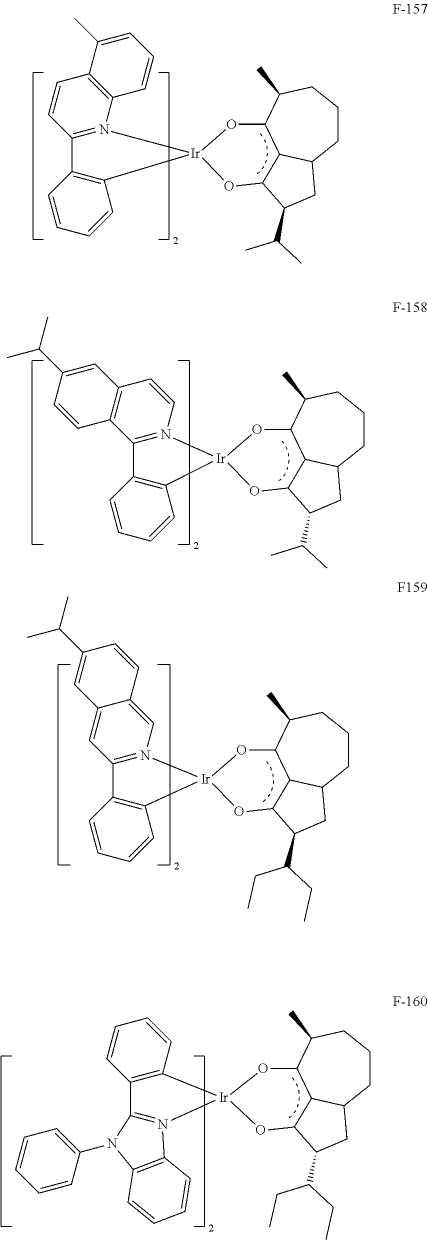

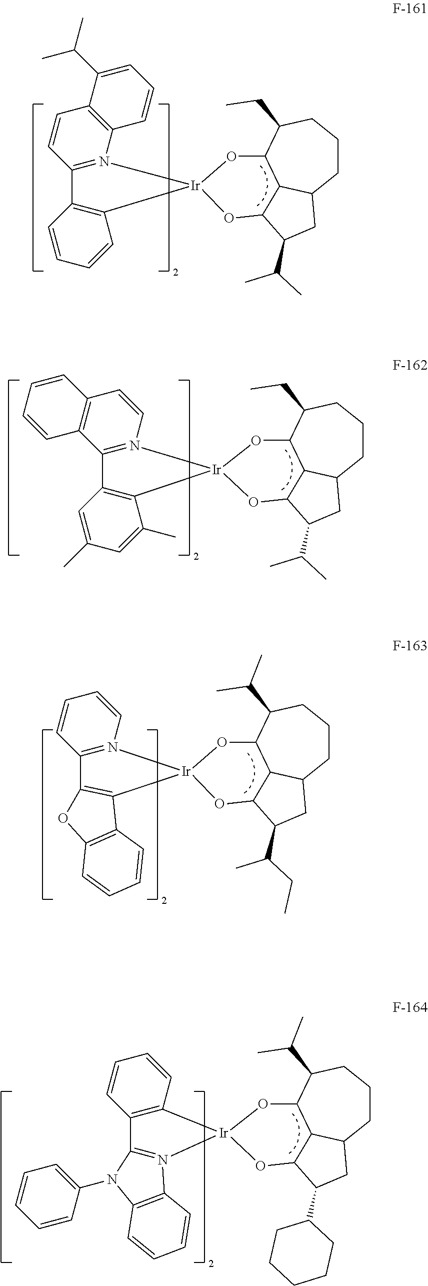

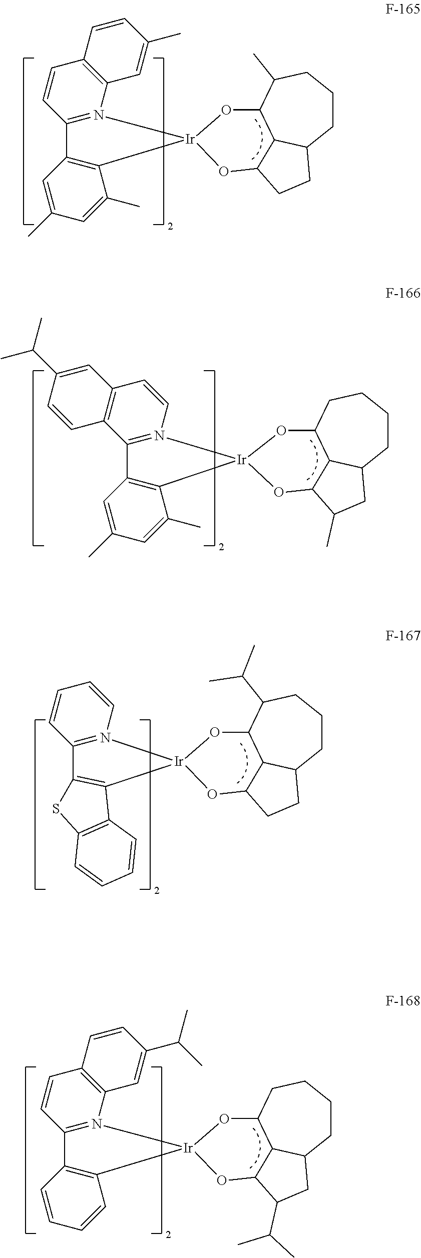

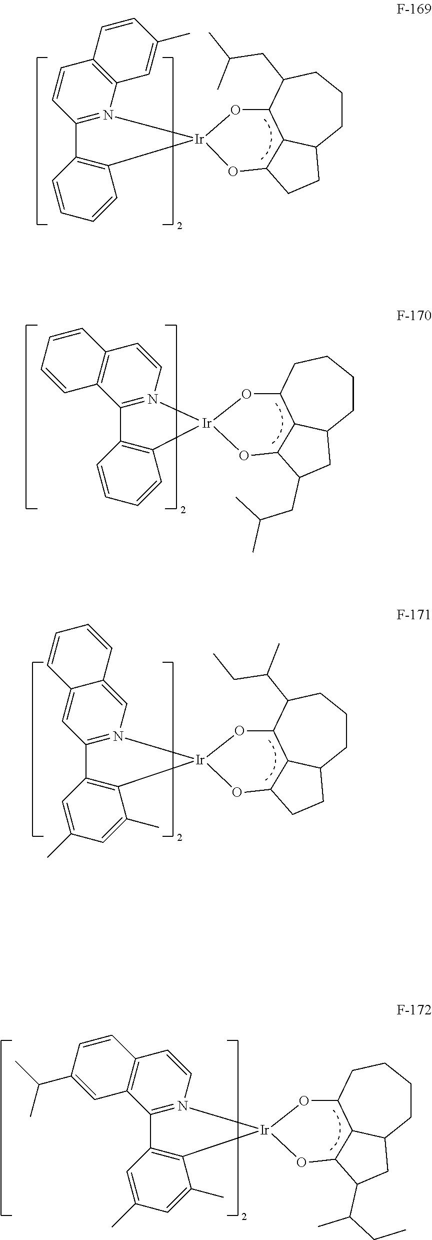

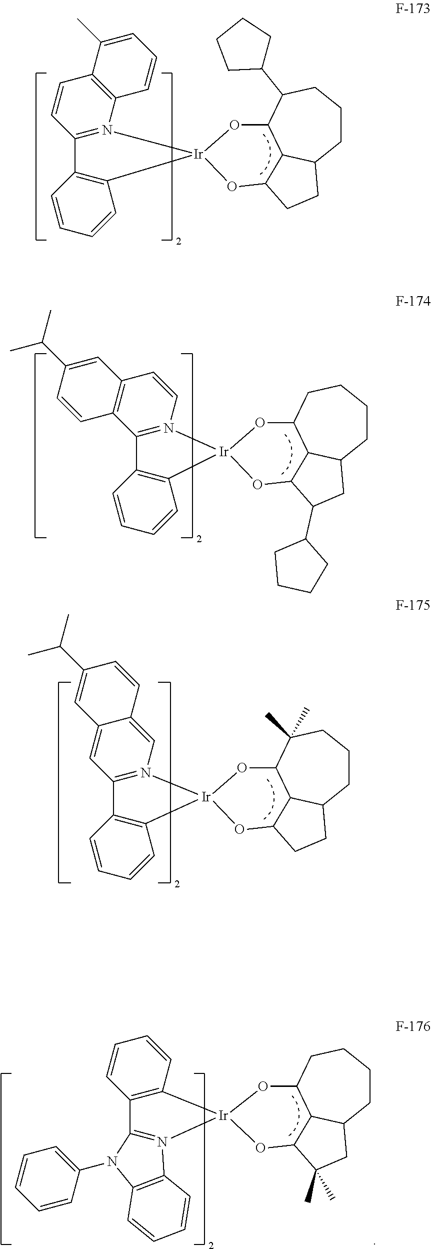

14. Use of the compound containing the 1,3-diketone ligand of claim 1 as an organic electrophosphorescent material.

15. (canceled)

16. The use according to claim 14, wherein the organic electrophosphorescent material is an organic electrophosphorescent material in an organic electroluminescent device.

17. An organic electroluminescent device comprising the compound containing the 1,3-diketone ligand of claim 1.

18. The organic electroluminescent device according to claim 17, wherein the compound containing the 1,3-diketone ligand is present in the light-emitting layer of the organic electroluminescent device.

19. The organic electroluminescent device according to claim 17, wherein the compound containing the 1,3-diketone ligand is a guest material in a light-emitting layer of the organic electroluminescent device.

20. The organic electroluminescent device according to claim 17, wherein the organic electroluminescent device comprises an anode, a hole injection layer, a hole transport layer, an electron blocking layer, a light-emitting layer, a hole blocking layer, an electron transport layer, an electron injection layer and a cathode.
